(19) United States
(12) Patent Application Publication
(10) Pub. No.: US 2023/0172053 A1
(43) Pub. Date: Jun. 1, 2023

(54) COMPOSITION, LIGHT-EMITTING DEVICE, ELECTRONIC APPARATUS, CONSUMER PRODUCT, AND ORGANOMETALLIC COMPOUND

(71) Applicant: Samsung Display Co., Ltd., Yongin-si (KR)

(72) Inventors: Soobyung Ko, Yongin-si (KR); Sujin Shin, Yongin-si (KR); Hyunjung Lee, Yongin-si (KR); Sungbum Kim, Yongin-si (KR); Eunsoo Ahn, Yongin-si (KR); Mina Jeon, Yongin-si (KR); Jinhee Ju, Yongin-si (KR)

(21) Appl. No.: 18/058,467

(22) Filed: Nov. 23, 2022

(30) Foreign Application Priority Data
Nov. 30, 2021 (KR) 10-2021-0169402

(51) Int. Cl. H01L 51/00; C07F 15/00; C09K 11/06

(52) U.S. Cl. CPC H01L 51/0087; C07F 15/0086; C09K 11/06; C07B 2200/05; C09K 2211/185; H01L 51/5012; C09K 2211/1044

(57) ABSTRACT

Provided are a composition and a light-emitting device including an organometallic compound represented by Formula 1, an electronic apparatus and a consumer product including the light-emitting device. The detailed description of Formula 1 is the same as described in the present specification. Also provided is the organometallic compound represented by Formula 1 below:

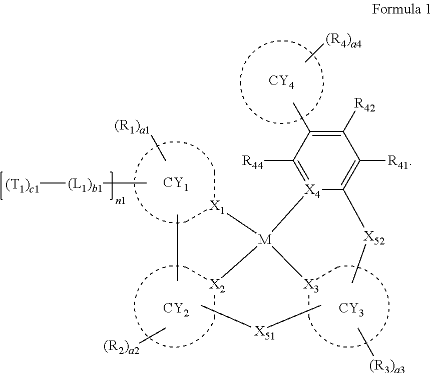

### CROSS-REFERENCE TO RELATED APPLICATION

This application claims priority to and the benefit of Korean Patent Application No. 10-2021-0169402, filed on Nov. 30, 2021, in the Korean Intellectual Property Office, the entire content of which is hereby incorporated by reference.

### BACKGROUND

### 1. Field

One or more embodiments of the present disclosure relate to a composition, a light-emitting device, an electronic apparatus including the light-emitting device, a consumer product, and an organometallic compound.

### 2. Description of the Related Art

Self-emissive devices (for example, organic light-emitting devices) in light-emitting devices have wide viewing angles, high contrast ratios, short response times, and excellent characteristics in terms of luminance, driving voltage, and response speed.

In a light-emitting device, a first electrode is on a substrate, and a hole transport region, an emission layer, an electron transport region, and a second electrode are sequentially on the first electrode. Holes provided from the first electrode may move toward the emission layer through the hole transport region, and electrons provided from the second electrode may move toward the emission layer through the electron transport region. Carriers, such as holes and electrons, may recombine in such an emission layer to produce excitons. These excitons transition from an excited state to a ground state to thereby generate light.

### SUMMARY

Provided are a composition capable of providing high luminescence efficiency and a long lifespan, an organometallic compound, a light-emitting device having high luminescence efficiency and a long lifespan, an electronic apparatus including the light-emitting device, and a consumer product.

Additional aspects of embodiments will be set forth in part in the description which follows and, in part, will be apparent from the description, or may be learned by practice of the presented embodiments of the disclosure.

According to one or more embodiments,

provided is a composition including an organometallic compound represented by Formula 1 below, and

a second compound including at least one π electron-deficient nitrogen-containing C₁-C₆₀ cyclic group, a third compound including a group represented by Formula 3 below, a fourth compound capable of emitting delayed fluorescence, or any combination thereof,

wherein the organometallic compound, the second compound, the third compound, and the fourth compound are different from each other.

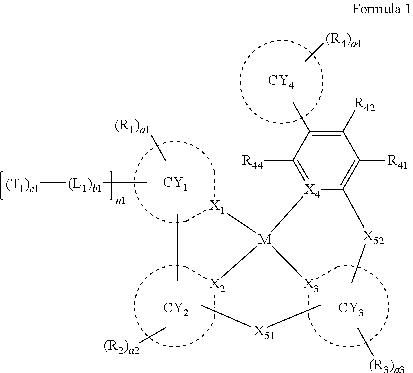

In Formula 1,

M may be platinum (Pt), palladium (Pd), gold (Au), nickel (Ni), silver (Ag), or copper(Cu),

X₁ to X₄ may each independently be C or N,

i) a bond between X₁ and M may be a coordinate bond, and ii) one selected from a bond between X₂ and M, a bond between X₃ and M, and a bond between X₄ and M may be a coordinate bond, and the other two may each be a covalent bond,

rings CY1, CY2, CY3, and CY4 may each independently be a C₃-C₆₀ carbocyclic group or a C₁-C₆₀ heterocyclic group,

X₅₁ may be a single bond, *—N(R₅₁ₐ)—*′, *—B(R₅₁ₐ)—*′, *—P(R₅₁ₐ)—*′, *—C(R₅₁ₐ)(R_{51b})—*′, *—Si(R₅₁ₐ)(R_{51b})—*′, *—Ge(R₅₁ₐ)(R_{51b})—*′, *—S—*′, *—Se—*′, *—O—*′, *—C(═O)—*′, *—S(═O)—*′, *—S(═O)₂—*′, *—C(R₅₁ₐ)═*′, *′═C(R₅₁ₐ)—*′, *—C(R₅₁ₐ)═C(R_{51b})—*′, *—C(═S)—*′, or *—C≡C—*′,

X₅₂ may be a single bond, *—N(R₅₂ₐ)—*′, *—B(R₅₂ₐ)—*′, *—P(R₅₂ₐ)—*′, *—C(R₅₂ₐ)(R_{52b})—*′, *—Si(R₅₂ₐ)(R_{52b})—*′, *—Ge(R₅₂ₐ)(R_{52b})—*′, *—S—*′, *—Se—*′, *—O—*′, *—C(═O)—*′, *—S(═O)—*′, *—S(═O)₂—*′, *—C(R₅₂ₐ)═*′, *═C(R₅₂ₐ)—*′, *—C(R₅₂ₐ)═C(R_{52b})—*′, *—C(═S)—*′, or *—C≡C—*′,

L₁ may be a C₃-C₆₀ carbocyclic group unsubstituted or substituted with at least one R₁₀ₐ or a C₁-C₆₀ heterocyclic group unsubstituted or substituted with at least one R₁₀ₐ,

b1 may be an integer selected from 1 to 5,

R₁ to R₄, R₄₂, R₅₁ₐ, R_{51b}, R₅₂ₐ, R_{52b}, and T₁ may each independently be hydrogen, deuterium, —F, —CI, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ aryl alkyl group unsubstituted or substituted with at least one R₁₀ₐ, a C₂-C₆₀ heteroaryl alkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), wherein R₄₂ is neither hydrogen nor deuterium,

R₄₁ and R₄₄ may each independently be hydrogen or deuterium,

a1, a2, a3, a4, c1, and n1 may each independently be an integer selected from 0 to 20,

two or more of R₁(s) in the number of a1 may optionally be bonded to each other to form a C₃-C₆₀ carbocyclic group unsubstituted or substituted with at least one

R₁₀ₐ or a C₁-C₆₀ heterocyclic group unsubstituted or substituted with at least one R₁₀ₐ,

two or more of R₂(s) in the number of a2 may optionally be bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,

two or more of R₃(s) in the number of a3 may optionally be bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,

two or more of R₄(5) in the number of a4 may optionally be bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,

two or more of R₁ to R₄, R₅₁ₐ, R_{51b}, R₅₂ₐ, and R_{52b} may optionally be bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,

R₁₀ₐ may be:

deuterium (—D), —F, —Cl, —Br, —I, a hydroxyl group, a cyano group, or a nitro group,

a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof,

a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof, or

—O(Q₃₁), —S(Q₃₁), —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), or —P(═O)(Q₃₁)(Q₃₂), and

Q₁ to Q₃, Q₁₁ to Q₁₃, Q₂₁ to Q₂₃, and Q₃₁ to Q₃₃ may each independently be hydrogen, deuterium, —F, —CI, —Br, —I, a hydroxyl group, a cyano group, a nitro group, or a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

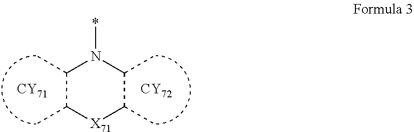

In Formula 3,

ring CY71 and ring CY72 may each independently be a π electron-rich C₃-C₆₀ cyclic group or a pyridine group,

X₇₁ may be a single bond or a linking group including O, S, N, B, C, Si, or any combination thereof, and

* indicates a binding site to a neighboring atom in Formula 3.

According to one or more embodiments,

provided is a light-emitting device including a first electrode,

a second electrode facing the first electrode,

an interlayer between the first electrode and the second electrode and including an emission layer, and

the organometallic compound represented by Formula 1.

According to one or more embodiments, provided is an electronic apparatus including the light-emitting device.

According to one or more embodiments, provided is a consumer product including the light-emitting device.

According to one or more embodiments, provided is the organometallic compound represented by Formula 1.

According to one or more embodiments, provided is an organometallic compound including platinum (Pt), and

a tetradentate ligand,

wherein the tetradentate ligand includes:

a pyridine group, and

a carbazole group or an azacarbazole group,

N in the pyridine group is bonded to the platinum,

N in the carbazole group or the azacarbazole group is bonded to a carbon in the 2-position of the pyridine group,

a carbon in the 3-position and a carbon in the 6-position of the pyridine group are each bonded to hydrogen or deuterium,

a substituent bonded to a carbon in the 4-position of the pyridine group is neither hydrogen nor deuterium,

a substituent bonded to a carbon in the 5-position of the pyridine group is a phenyl group, a naphthyl group, a dibenzofuranyl group, or a dibenzothiophenyl group (or, a dibenzothienyl group), each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, or any combination thereof, and

an absolute value (ΔCS) of a difference between a chemical shift value of hydrogen or deuterium bonded to the carbon in the 6-position of the pyridine group and a chemical shift value of hydrogen or deuterium bonded to the carbon in the 3-position of the pyridine group of the organometallic compound, as measured by proton nuclear magnetic resonance (NMR) spectroscopy, is in a range of 480 Hz to 600 Hz.

### BRIEF DESCRIPTION OF THE DRAWINGS

The above and other aspects and features of certain embodiments of the disclosure will be more apparent from the following description taken in conjunction with the accompanying drawings, in which:

FIG. 1 is a schematic view of a structure of a light-emitting device according to an embodiment;

FIG. 2 is a schematic cross-sectional view of a structure of an electronic apparatus according to an embodiment;

FIG. 3 is a schematic cross-sectional view of a structure of an electronic apparatus according to another embodiment;

FIG. 4 is a phase transition diagram of each of i) Compound ETH18, ii) Compound BD02, and iii) a mixture obtained by mixing Compound ETH18 and Compound BD02 together at a weight ratio of 2.7:1;

FIG. 5 shows an electroluminescence (EL) spectrum of each of organic light-emitting devices manufactured in Examples 1 to 4;

FIG. 6 shows an electroluminescence spectrum of each of organic light-emitting devices manufactured in Examples 5 to 8;

FIG. 7 shows an electroluminescence spectrum of each of organic light-emitting devices manufactured in Examples 9 to 11;

FIG. 8 shows an electroluminescence spectrum of each of organic light-emitting devices manufactured in Examples 12 and 13;

FIG. 9 shows an electroluminescence spectrum of each of organic light-emitting devices manufactured in Comparative Examples A to C;

FIG. 10 shows a graph of luminance versus luminescence efficiency of each of organic light-emitting devices manufactured in Examples 1 to 4;

FIG. 11 shows a graph of luminance versus luminescence efficiency of each of organic light-emitting devices manufactured in Examples 5 to 8;

FIG. 12 shows a graph of luminance versus luminescence efficiency of each of organic light-emitting devices manufactured in Examples 9 to 11;

FIG. 13 shows a graph of luminance versus luminescence efficiency of each of organic light-emitting devices manufactured in Examples 12 and 13;

FIG. 14 shows a graph of luminance versus luminescence efficiency of each of organic light-emitting devices manufactured in Comparative Examples A to C;

FIG. 15 shows a graph of time versus luminance of each of organic light-emitting devices manufactured in Examples 1 to 4;

FIG. 16 shows a graph of time versus luminance of each of organic light-emitting devices manufactured in Examples 5 to 8;

FIG. 17 shows a graph of time versus luminance of each of organic light-emitting devices manufactured in Examples 9 to 11;

FIG. 18 shows a graph of time versus luminance of each of organic light-emitting devices manufactured in Examples 12 and 13; and

FIG. 19 shows a graph of time versus luminance of each of organic light-emitting devices manufactured in Comparative Examples A to C.

### DETAILED DESCRIPTION

Reference will now be made in more detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of embodiments of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

According to one or more embodiments,

provided is a composition including: an organometallic compound represented by Formula 1 below or an organometallic compound including platinum (Pt) and a tetradentate ligand; and

a second compound including at least one π electron-deficient nitrogen-containing C₁-C₆₀ cyclic group, a third compound including a group represented by Formula 3 below, a fourth compound capable of emitting delayed fluorescence, or any combination thereof, and

the organometallic compound, the second compound, the third compound, and the fourth compound are different from each other:

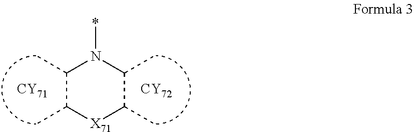

wherein, in Formula 3,

ring CY71 and ring CY72 may each independently be a π electron-rich C₃-C₆₀ cyclic group or a pyridine group,

X₇₁ may be a single bond or a linking group including O, S, N, B, C, Si, or any combination thereof, and

* indicates a binding site to a neighboring atom in Formula 3.

In an embodiment, the composition may be included in a layer including 1) the organometallic compound and 2) the second compound, the third compound, the fourth compound, or any combination thereof. The layer including the composition may include a mixture including 1) the organometallic compound and 2) the second compound, the third compound, the fourth compound, or any combination thereof. Therefore, the layer including the composition is clearly differentiated from, for example, a double layer including 1) a first layer including the organometallic compound and 2) a second layer including the second compound, the third compound, the fourth compound, or any combination thereof.

In an embodiment, the composition may be a composition prepared to form a layer including 1) the organometallic compound and 2) the second compound, the third compound, the fourth compound, or any combination thereof by using various suitable methods such as a deposition method and/or a wet process. In an embodiment, the composition may be a pre-mixed mixture prepared for use in a deposition method (for example, a vacuum deposition method). The pre-mixed mixture may be charged, for example, into a deposition source within a vacuum chamber, and two or more compounds included in the pre-mixed mixture may be co-deposited.

In an embodiment, the composition may include:

the organometallic compound; and

the second compound.

In an embodiment, an absolute value of a difference between a phase transition temperature of the organometallic compound represented by Formula 1 under a pressure of about 5.0×10⁻⁵ torr to about 1.0×10⁻³ torr and a phase transition temperature of the second compound under a pressure of about 5.0×10⁻⁵ torr to about 1.0×10⁻³ torr may be in a range of about 10° C. or less, about 0° C. to about 10° C., about 1° C. to about 10° C., about 2° C. to about 10° C., about 3° C. to about 10° C., about 4° C. to about 10° C., about 0° C. to about 8° C., about 1° C. to about 8° C., about 2° C. to about 8° C., about 3° C. to about 8° C., about 4° C. to about 8° C., about 0° C. to about 5 ° C., about 1° C. to about 5° C., about 2° C. to about 5° C., about 3° C. to about 5° C., about 4° C. to about 5° C., about 0° C. to about 4.5° C., about 1° C. to about 4.5° C., about 2° C. to about 4.5° C., about 3° C. to about 4.5° C., or about 4° C. to about 4.5° C. (for example, see Evaluation Example 5 and Table 7 below).

In an embodiment, an absolute value of a difference between a phase transition temperature of the organometallic compound represented by Formula 1 and a phase transition temperature of the second compound may be in a range of about 10° C. or less, about 0° C. to about 10° C., about 1° C. to about 10° C., about 2° C. to about 10° C., about 3° C. to about 10° C., about 4° C. to about 10° C., about 0° C. to about 8° C., about 1° C. to about 8° C., about 2° C. to about 8° C., about 3° C. to about 8° C., about 4° C. to about 8° C., about 0° C. to about 5° C., about 1° C. to about 5° C., about 2° C. to about 5° C., about 3° C. to about 5° C., about 4° C. to about 5° C., about 0° C. to about 4.5° C., about 1° C. to about 4.5° C., about 2° C. to about 4.5° C., about 3° C. to about 4.5° C., or about 4° C. to about 4.5° C., the phase transition temperature is evaluated under the same pressure, and the pressure may be in a range of about 5.0×10⁻⁵ torr to about 1.0×10⁻³ torr.

The organometallic compound and the second compound satisfy a phase transition temperature relationship as described above, and thus, phase transitions of the organometallic compound and the second compound in the composition (for example, a pre-mixed mixture) including the organometallic compound and the second compound may be made at substantially the same temperature within the range of the pressure. Therefore, when a deposition process is performed after the composition including the organometallic compound and the second compound is charged to a deposition source, the organometallic compound and the second compound in the composition may be vaporized at substantially the same temperature, and thus, the organometallic compound and the second compound may be effectively co-deposited, and various suitable electrical characteristics and durability of a layer prepared as a result of the co-deposition may be improved.

In an embodiment, a weight ratio of the organometallic compound to the second compound in the composition may be in a range of 2:1 to 4:1, or 2.5:1 to 3.5:1.

According to one or more embodiments,

provided is a light-emitting device including: a first electrode;

a second electrode facing the first electrode;

an interlayer between the first electrode and the second electrode and including an emission layer; and

an organometallic compound represented by Formula 1 below or an organometallic compound including platinum (Pt) and a tetradentate ligand:

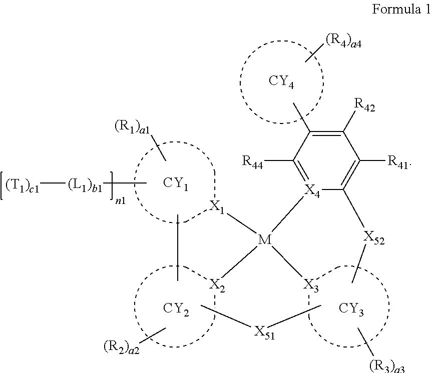

Formula 1 is the same as described in the present specification.

The tetradentate ligand in the organometallic compound is the same as described in the present specification.

The light-emitting device includes an organometallic compound represented by Formula 1 below or an organometallic compound including platinum (Pt) and a tetradentate ligand, and thus, may have excellent luminescence efficiency and long lifespan characteristics.

In an embodiment, the interlayer in the light-emitting device may include the organometallic compound.

In an embodiment, the emission layer in the light-emitting device may include the organometallic compound.

In an embodiment, the light-emitting device may further include a second compound including at least one π electron-deficient nitrogen-containing C₁-C₆₀ cyclic group, a third compound including a group represented by Formula 3 below, a fourth compound capable of emitting delayed fluorescence, or any combination thereof, and

the organometallic compound, the second compound, the third compound, and the fourth compound in the light-emitting device may be different from each other.

The second compound to the fourth compound in the composition and the light-emitting device are respectively the same as described in the present specification.

In an embodiment, the organometallic compound may include at least one deuterium.

In an embodiment, the second compound to the fourth compound may each include at least one deuterium.

In an embodiment, the composition and the light-emitting device (for example, the emission layer in the light-emitting device) may each further include a second compound, in addition to the organometallic compound. At least one selected from the organometallic compound and the second compound may include at least one deuterium. In an embodiment, the composition and the light-emitting device (for example, the emission layer in the light-emitting device) may each further include a third compound, a fourth compound, or any combination thereof, in addition to the organometallic compound and the second compound.

In an embodiment, the composition and the light-emitting device (for example, the emission layer in the light-emitting device) may each further include a third compound, in addition to the organometallic compound. At least one selected from the organometallic compound and the third compound may include at least one deuterium. In an embodiment, the composition and the light-emitting device (for example, the emission layer in the light-emitting device) may each further include a second compound, a fourth compound, or any combination thereof, in addition to the organometallic compound and the third compound.

In an embodiment, the composition and the light-emitting device (for example, the emission layer in the light-emitting device) may each further include a fourth compound, in addition to the organometallic compound. At least one selected from the organometallic compound and the fourth compound may include at least one deuterium. The fourth compound may serve to improve color purity, luminescence efficiency, and lifespan characteristics of the light-emitting device. In an embodiment, the composition and the light-emitting device (for example, the emission layer in the light-emitting device) may each further include a second compound, a third compound, or any combination thereof, in addition to the organometallic compound and the fourth compound.

In an embodiment, the composition and the light-emitting device (for example, the emission layer in the light-emitting device) may each further include a second compound and a third compound, in addition to the organometallic compound. The second compound and the third compound may form an exciplex. At least one selected from the organometallic compound, the second compound, and the third compound may include at least one deuterium.

In an embodiment, a highest occupied molecular orbital (HOMO) energy level of the organometallic compound may be in a range of about −5.35 eV to about −5.15 eV or about −5.30 eV to about −5.20 eV.

In an embodiment, a lowest unoccupied molecular orbital (LUMO) energy level of the organometallic compound may be in a range of about −2.20 eV to about −1.80 eV or about −2.15 eV to about −1.90 eV.

The HOMO and LUMO energy levels may be evaluated via cyclic voltammetry analysis (for example, Evaluation Example 1) for the organometallic compound.

In an embodiment, a maximum emission wavelength (or an emission peak wavelength) of a photoluminescence spectrum in a film including the organometallic compound may be in a range of about 430 nm to about 475 nm, about 440 nm to about 475 nm, about 450 nm to about 475 nm, about 430 nm to about 470 nm, about 440 nm to about 470 nm, about 450 nm to about 470 nm, about 430 nm to about 465 nm, about 440 nm to about 465 nm, about 450 nm to about 465 nm, about 430 nm to about 460 nm, about 440 nm to about 460 nm, or about 450 nm to about 460 nm.

In an embodiment, an emission full width at half maximum (FWHM) of a photoluminescence spectrum in a film including the organometallic compound may be in a range of about 40 nm or less, about 5 nm to about 40 nm, about 10 nm to about 40 nm, about 15 nm to about 40 nm, about 20 nm to about 40 nm, about 5 nm to about 35 nm, about 10 nm to about 35 nm, about 15 nm to about 35 nm, about 20 nm to about 35 nm, about 5 nm to about 30 nm, about 10 nm to about 30 nm, about 15 nm to about 30 nm, about 20 nm to about 30 nm, about 5 nm to about 25 nm, about 10 nm to about 25 nm, about 15 nm to about 25 nm, or about 20 nm to about 25 nm.

In an embodiment, a photoluminescence quantum yield (PLQY) in a film including the organometallic compound may be in a range of about 90% to about 99% or about 90% to about 97%.

In an embodiment, a decay time of the organometallic compound may be in a range of about 2.42 μs to about 3.5 μs, about 2.42 μs to about 3.0 μs, about 2.50 μs to about 3.5 μs, or about 2.50 μs is to about 3.0 μs.

The maximum emission wavelength, emission FWHM, PLQY, and decay time of the organometallic compound were evaluated for a film including the organometallic compound, and an evaluation method thereof is the same as described in connection with, for example, Evaluation Examples 2 and 3.

In an embodiment, the emission layer of the light-emitting device may include: i) the organometallic compound; and ii) the second compound, the third compound, the fourth compound, or any combination thereof, and the emission layer may emit blue light.

In an embodiment, a maximum emission wavelength of the blue light may be in a range of about 430 nm to about 475 nm, about 440 nm to about 475 nm, about 450 nm to about 475 nm, about 430 nm to about 470 nm, about 440 nm to about 470 nm, about 450 nm to about 470 nm, about 430 nm to about 465 nm, about 440 nm to about 465 nm, or about 450 nm to about 465 nm.

In an embodiment, an emission FWHM of the blue light may be in a range of about 40 nm or less, about 5 nm to about 40 nm, about 10 nm to about 40 nm, about 15 nm to about 40 nm, about 20 nm to about 40 nm, about 5 nm to about 35 nm, about 10 nm to about 35 nm, about 15 nm to about 35 nm, about 20 nm to about 35 nm, about 5 nm to about 30 nm, about 10 nm to about 30 nm, about 15 nm to about 30 nm, about 20 nm to about 30 nm, about 5 nm to about 25 nm, about 10 nm to about 25 nm, about 15 nm to about 25 nm, or about 20 nm to about 25 nm.

In an embodiment, the blue light may be deep blue light.

In an embodiment, a CIE_x coordinate (for example, a bottom emission CIE_x coordinate) of the blue light may be in a range of about 0.125 to about 0.140 or about 0.130 to about 0.140.

In an embodiment, a CIE_y coordinate (for example, a bottom emission CIE_y coordinate) of the blue light may be in a range of about 0.120 to about 0.200.

Examples of the maximum emission wavelength and the CIE_x and CIE_y coordinates of the blue light may be referred to Table 9 in the present specification.

In an embodiment, the second compound may include a pyridine group, a pyrimidine group, a pyrazine group, a pyridazine group, a triazine group, or any combination thereof.

In an embodiment, the following compounds may be excluded from the third compound.

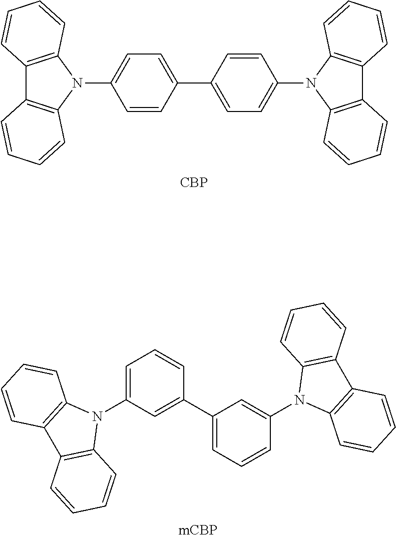 [SMILES: c1ccc2c(c1)c1ccccc1n2-c1ccc(-c2ccc(-n3c4ccccc4c4ccccc43)cc2)cc1 ; "CBP" ; c1cc(-c2cccc(-n3c4ccccc4c4ccccc43)c2)cc(-n2c3ccccc3c3ccccc32)c1]

In an embodiment, a difference between a triplet energy level (eV) of the fourth compound and a singlet energy level (eV) of the fourth compound may be about 0 eV or higher and about 0.5 eV or lower (or, about 0 eV or higher and about 0.3 eV or lower).

In an embodiment, the fourth compound may be a compound including at least one cyclic group including each of boron (B) and nitrogen (N) as a ring-forming atom.

In an embodiment, the fourth compound may be a C₈-C₆₀ polycyclic group-containing compound including at least two condensed cyclic groups that share boron (B).

In an embodiment, the fourth compound may include a condensed ring in which at least one third ring may be condensed together with at least one fourth ring,

the third ring may be a cyclopentane group, a cyclohexane group, a cycloheptane group, a cyclooctane group, a cyclopentene group, a cyclohexene group, a cycloheptene group, a cyclooctene group, an adamantane group, a norbornene group, a norbornane group, a bicyclo[1.1.1]pentane group, a bicyclo[2.1.1]hexane group, a bicyclo[2.2.2]octane group, a benzene group, a pyridine group, a pyrimidine group, a pyridazine group, a pyrazine group, or a triazine group, and

the fourth ring may be a 1,2-azaborinine group, a 1,3-azaborinine group, a 1,4-azaborinine group, a 1,2-dihydro-1,2-azaborinine group, a 1,4-oxaborinine group, a 1,4-thiaborinine group, or a 1,4-dihydroborinine group.

In an embodiment, the third compound may not include a compound represented by Formula 3-1 described in the present specification.

In an embodiment, the second compound may include a compound represented by Formula 2:

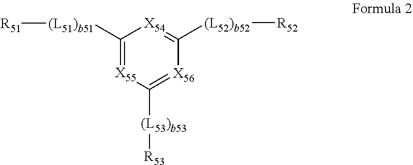

wherein, in Formula 2,

L₅₁ to L₅₃ may each independently be a single bond, a C₃-C₆₀ carbocyclic group unsubstituted or substituted with at least one R₁₀ₐ, or a C₁-C₆₀ heterocyclic group unsubstituted or substituted with at least one R₁₀ₐ,

b51 to b53 may each independently be an integer selected from 1 to 5,

X₅₄ may be N or C(R₅₄), X₅₅ may be N or C(R₅₅), X₅₆ may be N or C(R₅₆), and at least one selected from X₅₄ to X₅₆ may be N, and

R₅₁ to R₅₆ and R₁₀ₐ are respectively the same as described in the present specification.

In an embodiment, the third compound may include a compound represented by Formula 3-1, a compound represented by Formula 3-2, a compound represented by Formula 3-3, a compound represented by Formula 3-4, a compound represented by Formula 3-5, or any combination thereof:

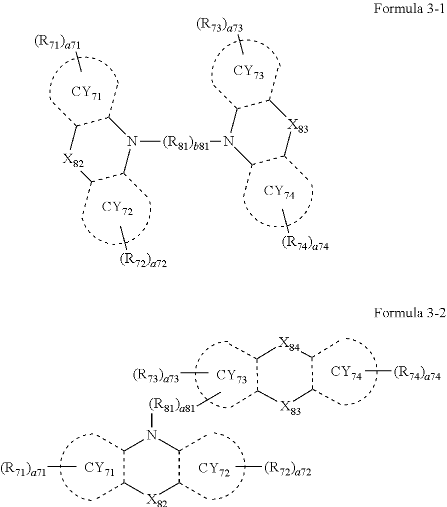

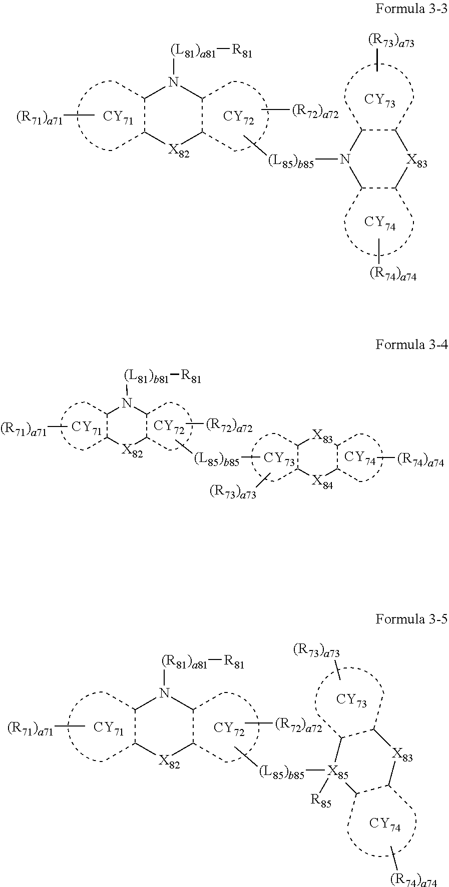

wherein, in Formulae 3-1 to 3-5,

ring CY71 to ring CY74 may each independently be a π electron-rich C₃-C₆₀ cyclic group or a pyridine group,

X₈₂ may be a single bond, O, S, N—[(L₈₂)_{b82}-R₈₂], C(R₈₂ₐ)(R_{82b}), or Si(R₈₂ₐ)(R_{82b}),

X₈₃ may be a single bond, O, S, N—[(L₈₃)_{b83}-R₈₃], C(R₈₃ₐ)(R_{83b}), or Si(R₈₃ₐ)(R_{83b}),

X₈₄ may be O, S, N—[(L₈₄)_{b84}-R₈₄], C(R₈₄ₐ)(R_{84b}), or Si(R₈₄ₐ)(R_{84b}),

X₈₅ may be C or Si,

L₈₁ to L₈₅ may each independently be a single bond, *—C(Q₄)(Q₆)—*′, *—Si(Q₄)(Q₆)—*′, a 7 electron-rich C₃-C₆₀ cyclic group unsubstituted or substituted with at least one R₁₀ₐ, or a pyridine group unsubstituted or substituted with at least one R₁₀ₐ, wherein Q₄ and Q₅ may each be understood by referring to the description of Q₁ provided herein,

b81 to b85 may each independently be an integer selected from 1 to 5,

R₇₁ to R₇₄, R₈₁ to R₈₅, R₈₂ₐ, R_{82b}, R₈₃ₐ, R_{83b}, R₈₄ₐ, and R_{84b} are respectively the same as described in the present specification,

a71 to a74 may each independently be an integer selected from 0 to 20, and

R₁₀ₐ may be the same as described in the present specification.

In an embodiment, the fourth compound may be a compound represented by

Formula 502, a compound represented by Formula 503, or any combination thereof:

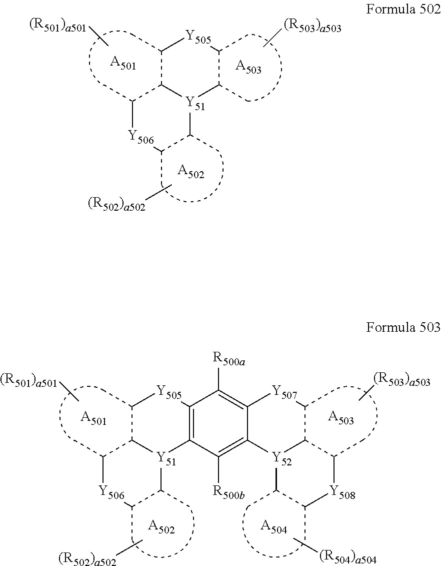

wherein, in Formulae 502 and 503,

ring A₅₀₁ to ring A₅₀₄ may each independently be a C₃-C₆₀ carbocyclic group or a C₁-C₆₀ heterocyclic group,

Y₅₀₅ may be O, S, N(R₅₀₅), B(R₅₀₅), C(R₅₀₅ₐ)(R_{505b}), or Si(R₅₀₅ₐ)(R_{505b}),

Y₅₀₆ may be O, S, N(R₅₀₆), B(R₅₀₆), C(R₅₀₆ₐ)(R_{506b}), or Si(R₅₀₆ₐ)(R_{506b}),

Y₅₀₇ may be O, S, N(R₅₀₇), B(R₅₀₇), C(R₅₀₇ₐ)(R_{507b}), or Si(R₅₀₇ₐ)(R_{507b}),

Y₅₀₈ may be O, S, N(R₅₀₈), B(R₅₀₈), C(R₅₀₈ₐ)(R_{508b}), or Si(R₅₀₈ₐ)(R_{508b}),

Y₅₁ and Y₅₂ may each independently be B, P(═O), or S(═O),

R₅₀₀ₐ, R_{500b}, R₅₀₁ to R₅₀₈, R₅₀₅ₐ, R_{505b}, R₅₀₆ₐ, R_{506b}, R₅₀₇ₐ, R_{507b}, R₅₀₈ₐ, and

R_{508b} are respectively the same as described in the present specification, and

a501 to a504 may each independently be an integer selected from 0 to 20.

In an embodiment, the light-emitting device may satisfy at least one selected from Conditions 1 to 4:

### Condition 1

LUMO energy level (eV) of third compound>LUMO energy level (eV) of organometallic compound

### Condition 2

LUMO energy level (eV) of organometallic compound>LUMO energy level (eV) of second compound

### Condition 3

HOMO energy level (eV) of organometallic compound>HOMO energy level (eV) of third compound

### Condition 4

HOMO energy level (eV) of the third compound>HOMO energy level (eV) of the second compound

wherein each of the HOMO energy level and the LUMO energy level of each of the organometallic compound, the second compound, and the third compound may be a negative value, and may be measured according to any suitable method generally used in the art. In some embodiments, a method described in Evaluation Example 1 in the present specification may be used to measure each of the HOMO energy level and the LUMO energy level of each of the organometallic compound, the second compound, and the third compound.

In an embodiment, an absolute value of a difference between a LUMO energy level of the organometallic compound and a LUMO energy level of the second compound may be about 0.1 eV or higher and about 1.0 eV or lower, an absolute value of a difference between a LUMO energy level of the organometallic compound and a LUMO energy level of the third compound may be about 0.1 eV or higher and about 1.0 eV or lower, an absolute value of a difference between a HOMO energy level of the organometallic compound and a HOMO energy level of the second compound may be about 1.25 eV or lower (for example, about 1.25 eV or lower and about 0.2 eV or higher), and an absolute value of a difference between a HOMO energy level of the organometallic compound and a HOMO energy level of the third compound may be about 1.25 eV or lower (for example, about 1.25 eV or lower and about 0.2 eV or higher).

When the relationships between LUMO energy level and HOMO energy level satisfy the conditions as described above, the balance between holes and electrons injected into the emission layer can be made.

The light-emitting device may have a structure of a first embodiment or a second embodiment.

### First Embodiment

According to the first embodiment, the organometallic compound may be included in the emission layer in the interlayer of the light-emitting device, wherein the emission layer may further include a host, the organometallic compound may be different from the host, and the emission layer may emit phosphorescence or fluorescence emitted from the organometallic compound. According to the first embodiment, the organometallic compound may be a dopant or an emitter. In an embodiment, the organometallic compound may be a phosphorescent dopant or a phosphorescent emitter.

Phosphorescence or fluorescence emitted from the organometallic compound may be blue light.

The emission layer may further include an auxiliary dopant. The auxiliary dopant may serve to improve luminescence efficiency from the first compound by effectively transferring energy to the organometallic compound as a dopant or an emitter.

The auxiliary dopant may be different from the organometallic compound and the host.

In some embodiments, the auxiliary dopant may be a delayed fluorescence-emitting compound.

In some embodiments, the auxiliary dopant may be a compound including at least one cyclic group including each of boron (B) and nitrogen (N) as a ring-forming atom.

### Second Embodiment

According to the second embodiment, the organometallic compound may be included in the emission layer in the interlayer of the light-emitting device, wherein the emission layer may further include a host and a dopant, the organometallic compound, the host and the dopant may be different from one another, and the emission layer may emit phosphorescence or fluorescence (e.g., delayed fluorescence) from the dopant.

In an embodiment, the organometallic compound in the second embodiment may serve as an auxiliary dopant that transfers energy to a dopant (or an emitter), not as a dopant.

In an embodiment, the organometallic compound in the second embodiment may serve as an emitter and as an auxiliary dopant that transfers energy to a dopant (or an emitter).

In an embodiment, phosphorescence or fluorescence emitted from the dopant (or the emitter) in the second embodiment may be blue phosphorescence or blue fluorescence (e.g., blue delayed fluorescence).

The dopant (or the emitter) in the second embodiment may be any phosphorescent dopant material (e.g., the organometallic compound represented by Formula 1, the organometallic compound represented by Formula 401, or any combination thereof) or any fluorescent dopant material (e.g., the compound represented by Formula 501, the compound represented by Formula 502, the compound represented by Formula 503, or any combination thereof).

In the first embodiment and the second embodiment, the blue light may have a maximum emission wavelength in a range of about 390 nm to about 500 nm, about 410 nm to about 490 nm, about 430 nm to about 480 nm, about 430 nm to about 475 nm, about 440 nm to about 475 nm, or about 455 nm to about 470 nm.

The auxiliary dopant in the first embodiment may include, for example, the fourth compound represented by Formula 502 or 503.

The host in the first embodiment and the second embodiment may be any suitable host material (e.g., the compound represented by Formula 301, the compound represented by 301-1, the compound represented by Formula 301-2, or any combination thereof).

In some embodiments, the host in the first embodiment and the second embodiment may be the second compound, the third compound, or any combination thereof described in the present specification.

In an embodiment, the light-emitting device may further include a capping layer outside the first electrode and/or outside the second electrode.

In an embodiment, the light-emitting device may further include at least one selected from a first capping layer outside the first electrode and a second capping layer outside the second electrode, and the at least one selected from the first capping layer and the second capping layer may include the organometallic compound represented by Formula 1. More details for the first capping layer and/or second capping layer are the same as described in the present specification.

In an embodiment, the light-emitting device may further include:

a first capping layer outside the first electrode and including the organometallic compound represented by Formula 1;

a second capping layer outside the second electrode and including the organometallic compound represented by Formula 1; or

the first capping layer and the second capping layer.

The expression “(interlayer and/or capping layer) includes the organometallic compound represented by Formula 1,” as used herein, may be understood as “(interlayer and/or capping layer) may include one kind of organometallic compound represented by Formula 1 or two or more different kinds of organometallic compounds, each represented by Formula 1.”

In an embodiment, the interlayer and/or capping layer may include only Compound BD01 as the organometallic compound. In this regard, Compound BD02 may exist in the emission layer of the light-emitting device. In some embodiments, the interlayer may include, as the organometallic compound, Compound BD02 and Compound BD04. In this regard, Compound BD02 and Compound BD04 may exist in an identical layer (for example, Compound BD02 and Compound BD04 may all exist in an emission layer), or different layers (for example, Compound BD02 may exist in an emission layer and Compound BD04 may exist in an electron transport region).

The term “interlayer,” as used herein, refers to a single layer and/or all of a plurality of layers between the first electrode and the second electrode of the light-emitting device.

According to one or more embodiments, provided is an electronic apparatus including the light-emitting device. The electronic apparatus may further include a thin-film transistor. In an embodiment, the electronic apparatus may further include a thin-film transistor including a source electrode and a drain electrode, wherein the first electrode of the light-emitting device may be electrically connected to the source electrode or the drain electrode. In an embodiment, the electronic apparatus may further include a color filter, a color conversion layer, a touch screen layer, a polarizing layer, or any combination thereof. More details for the electronic apparatus are as described in the present specification.

According to one or more embodiments, provided is a consumer product including the light-emitting device.

In an embodiment, the consumer product may be one selected from a flat panel display, a curved display, a computer monitor, a medical monitor, a television, a billboard, an indoor or outdoor light and/or light for signal, a head-up display, a fully or partially transparent display, a flexible display, a rollable display, a foldable display, a stretchable display, a laser printer, a telephone, a portable phone, a tablet personal computer, a phablet, a personal digital assistant (PDA), a wearable device, a laptop computer, a digital camera, a camcorder, a viewfinder, a micro display, a three-dimensional (3D) display, a virtual reality or augmented reality display, a vehicle, a video wall with multiple displays tiled together, a theater or stadium screen, a phototherapy device, and a signboard.

According to one or more embodiments, provided is the organometallic compound represented by Formula 1. Formula 1 is the same as described in the present specification.

According to one or more embodiments, provided is an organometallic compound including platinum and a tetradentate ligand.

Methods of synthesizing the organometallic compound may be easily understood to those of ordinary skill in the art by referring to Synthesis Examples and/or Examples described herein.

### Description of Formula

In Formula 1, M may be platinum (Pt), palladium (Pd), gold (Au), nickel (Ni), silver (Ag), or copper (Cu).

In an embodiment, M may be Pt.

In Formula 1, X₁ to X₄ may each independently be C or N.

In an embodiment, X₁ may be C. In an embodiment, X₁ in Formula 1 may be C, and C may be carbon of a carbene moiety.

In an embodiment, X₁ in Formula 1 may be N.

In an embodiment, X₂ and X₃ may each be C, and X₄ may be N.

In Formula 1, i) a bond between X₁ and M may be a coordinate bond, and ii) one selected from a bond between X₂ and M, a bond between X₃ and M, and a bond between X₄ and M may be a coordinate bond, and the other two may each be a covalent bond. As described herein, “a coordinate bond” may also be referred to as a coordinate covalent bond or a dative bond.

In an embodiment, a bond between X₂ and M and a bond between X₃ and M may each be a covalent bond, and a bond between X₄ and M may be a coordinate bond.

In an embodiment, X₄ may be N, and a bond between X₄ and M may be a coordinate bond.

In Formula 1, rings CY1, CY2, CY3, and CY4 may each independently be a C₃-C₆₀ carbocyclic group or a C₁-C₆₀ heterocyclic group.

In an embodiment, ring CY1 may be a C₁-C₆₀ nitrogen-containing heterocyclic group.

Ring CY1 in Formula 1 may be i) an X₁-containing 5-membered ring, ii) an X₁-containing 5-membered ring in which at least one 6-membered ring is condensed, or iii) an X₁-containing 6-membered ring. In an embodiment, ring CY1 in Formula 1 may be i) an X₁-containing 5-membered ring or ii) an X₁-containing 5-membered ring in which at least one 6-membered ring is condensed. In some embodiments, ring CY1 may include a 5-membered ring bonded to M in Formula 1 via X₁. Here, the X₁-containing 5-membered ring may be a pyrrole group, a pyrazole group, an imidazole group, a triazole group, an oxazole group, an iso-oxazole group, a thiazole group, an isothiazole group, an oxadiazole group, or a thiadiazole group, and the X₁-containing 6-membered ring and the 6-membered ring which may be optionally condensed to the X₁-containing 5-membered ring may each independently be a benzene group, a pyridine group, or a pyrimidine group.

In an embodiment, ring CY1 may be an X₁-containing 5-membered ring, and the X₁-containing 5-membered ring may be an imidazole group or a triazole group.

In an embodiment, ring CY1 may be an X₁-containing 5-membered ring in which at least one 6-membered ring is condensed, and the X₁-containing 5-membered ring in which the at least one 6-membered ring is condensed may be a benzimidazole group or an imidazopyridine group.

In an embodiment, ring CY1 may be an imidazole group, a triazole group, a benzimidazole group, or an imidazopyridine group.

Rings CY2, CY3, and CY4 in Formula 1 may each independently be a C₃-C₆₀ carbocyclic group or a C₁-C₆₀ heterocyclic group.

In an embodiment, rings CY2, CY3, and CY4 may each independently be a benzene group, a pyridine group, a pyrimidine group, a naphthalene group, a dibenzofuran group, a dibenzothiophene group, a carbazole group, a fluorene group, a dibenzosilole group, a naphthobenzofuran group, a naphthobenzothiophene group, a benzocarbazole group, a benzofluorene group, a naphthobenzosilole group, a dinaphthofuran group, a dinaphthothiophene group, a dibenzocarbazole group, a dibenzofluorene group, a dinaphthosilole group, an azadibenzofuran group, an azadibenzothiophene group, an azacarbazole group, an azafluorene group, an azadibenzosilole group, an azanaphthobenzofuran group, an azanaphthobenzothiophene group, an azabenzocarbazole group, an azabenzofluorene group, an azanaphthobenzosilole group, an azadinaphthofuran group, an azadinaphthothiophene group, an azadibenzocarbazole group, an azadibenzofluorene group, or an azadinaphthosilole group.

In an embodiment, ring CY2 may be a benzene group, a pyridine group, a pyrimidine group, a naphthalene group, a dibenzofuran group, a dibenzothiophene group, a carbazole group, a fluorene group, or a dibenzosilole group.

X₅₁ in Formula 1 may be a single bond, *—N(R₅₁ₐ)—*′, *—B(R₅₁ₐ)—*′, *—P(R₆₁ₐ)—*′, *—C(R₆₁ₐ)(R_{61b})—*′, *—Si(R₆₁ₐ)(R_{61b})—*′, *—Ge(R₆₁a)(R_{61b})—*′, *—S—*′, *—Se—*′, *—O—*′, *—C(═O)—*′, *—S(═O)—*′, *—S(═O)₂—*′, *—C(R₆₁ₐ)═*′, *′2 C(R₆₁ₐ)—*′, *—C(R₆₁ₐ)═C(R_{61b})—*′, *—C(═S)—*′, or *—C═C—*′. R₆₁ₐ and R_{51b} are respectively the same as described in the present specification. R₅₁ₐ and R_{51b} may optionally be bonded together to form a C₃-C₆₀ carbocyclic group unsubstituted or substituted with at least one R₁₀ₐ or a C₁-C₆₀ heterocyclic group unsubstituted or substituted with at least one R₁₀ₐ.

In an embodiment, X₅₁ may be *—N(R₅₁ₐ)—*′, *—B(R₅₁ₐ)—*′, *—P(R₅₁ₐ)—*′, *—C(R₅₁ₐ)(R_{51b})—*′, *—Si(R₅₁ₐ)(R_{51b})—*′, *—Ge(R₅₁ₐ)(R_{51b})—*′, *—S—*′, *—Se—*′, or *—O—*′.

X₅₂ in Formula 1 may be a single bond, *—N(R₅₂ₐ)—*′, *—B(R₅₂ₐ)—*′, *—P(R₅₂ₐ)—*′, *—C(R₅₂ₐ)(R_{52b})—*′, *—Si(R₅₂ₐ)(R_{52b})—*′, *—Ge(R₅₂ₐ)(R_{52b})—*′, *—S—*′, *—Se—*′, *—O—*′, *—C(═O)—*′, *—S(═O)—*′, *—S(═O)₂—*′, *—C(R₅₂ₐ)═*′, *═C(R₅₂ₐ)—*′, *—C(R₅₂ₐ)═C(R_{52b})—*′, *—C(═S)—*′, or *—C≡C—*′. R₅₂a and R_{52b} are respectively the same as described in the present specification.

X₅₂ in Formula 1 may be a single bond, *—N(R₅₂ₐ)—*′, *—B(R₅₂ₐ)—*′, *—P(R₅₂ₐ)—*′, *—C(R₅₂ₐ)(R_{52b})—*′, *—Si(R₅₂ₐ)(R_{52b})—*′, *—Ge(R₅₂ₐ)(R_{52b})—*′, *—S—*′, *—Se—*′, or *—O—*′.

In an embodiment, in Formula 1,

i) X₅₂ may be a single bond, and a group represented by

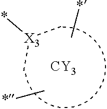

in Formula 1 may be a group represented by Formula CY3A or CY3B below,

ii) X₅₂ may not be a single bond, and a group represented by

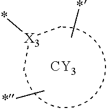

in Formula 1 may be a group represented by Formula CY3C below, or

iii) X₅₂ may be *—N(R₅₂ₐ)—*′, and R₅₂ₐ and R₃ may be bonded to form a C₃-C₆₀ carbocyclic group unsubstituted or substituted with at least one R₁₀ₐ or a C₁-C₆₀ heterocyclic group unsubstituted or substituted with at least one R₁₀ₐ:

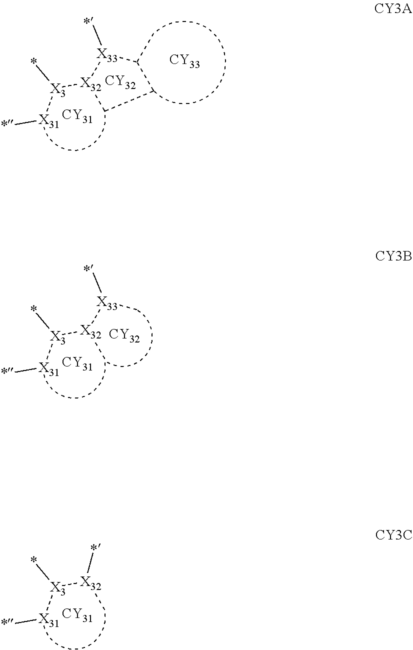

wherein, in Formulae CY3A to CY3C,

X₃ and X₃₁ to X₃₃ may each independently be C or N,

rings CY31, CY32, and CY33 are respectively the same as described in connection with ring CY3 in the present specification,

a bond between X₃₁ and X₃, a bond between X₃ and X₃₂, and a bond between X₃₂ and X₃₃ may each be a chemical bond,

*″ indicates a binding site to X_{51,}

* indicates a binding site to M in Formula 1, and

*′ indicates a binding site to X₅₂.

In an embodiment, X₃₁, X₃, and X₃₂ in Formulae CY3A and CY3B may each be C, and X₃₃ may be N.

In an embodiment, X₃₁, X₃, and X₃₂ in Formula CY3C may each be C.

In Formula 1, L₁ may be a C₃-C₆₀ carbocyclic group unsubstituted or substituted with at least one R₁₀ₐ or a C₁-C₆₀ heterocyclic group unsubstituted or substituted with at least one R₁₀ₐ.

In an embodiment, L₁ may be a benzene group, a naphthalene group, a dibenzofuran group, or a dibenzothiophene group, each unsubstituted or substituted with at least one R₁₀ₐ.

b1 in Formula 1 indicates the number of L₁(s), and may be an integer selected from 1 to 5. When b1 is 2 or more, two or more of L₁(s) may be identical to or different from each other. In an embodiment, b1 may be 1 or 2.

In Formula 1, R₁ to R₄, R₄₂, R₅₁ₐ, R_{51b}, R₅₂ₐ, R_{52b}, and T₁ may each independently be hydrogen, deuterium, —F, —CI, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ aryl alkyl group unsubstituted or substituted with at least one R₁₀ₐ, a C₂-C₆₀ heteroaryl alkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(a), or —P(═O)(Q₁)(Q₂), wherein R₄₂ is neither hydrogen nor deuterium.

In Formula 1, R₄₁ and R₄₄ may each independently be hydrogen or deuterium.

In an embodiment, R₁ to R₄, R₅₁ₐ, R_{51b}, R₅₂ₐ, R_{52b}, and T₁ in Formula 1 may each independently be:

hydrogen, deuterium, —F, or a cyano group;

a C₁-C₂₀ alkyl group or a C₃-C₁₀ cycloalkyl group, each unsubstituted or substituted with deuterium, —F, a cyano group, or any combination thereof; or

a phenyl group, a naphthyl group, a dibenzofuranyl group, or a dibenzothiophenyl group (or a thienyl group), each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl) phenyl group, or any combination thereof.

In an embodiment, R₄₂ in Formula 1 may be a C₁-C₂₀ alkyl group unsubstituted or substituted with deuterium, —F, a cyano group, or any combination thereof.

In an embodiment, R₄₂ in Formula 1 may be a group represented by *—C(R₄₂ₐ)(R_{42b})(R_{42c}), and R₄₂ₐ, R_{42b}, and R_{42c} may each independently be a C₁-C₂₀ alkyl group unsubstituted or substituted with deuterium, —F, a cyano group, or any combination thereof, wherein at least one selected from R₄₂ₐ, R_{42b}, and R_{42c} may be hydrogen or deuterium. Therefore, an angular deviation between a plane including ring CY4 in Formula 1 and a plane including R₄₂ in Formula 1 may be minimized or reduced to improve electrical characteristics and/or thermostability of the organometallic compound represented by Formula 1.

In an embodiment, T₁ in Formula 1 may be a phenyl group, a naphthyl group, a dibenzofuranyl group, or a dibenzothiophenyl group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl) phenyl group, or any combination thereof.

a1, a2, a3, a4, c1, and n1 in Formula 1 may respectively indicate the numbers of groups represented by R₁, R₂, R₃, R₄, T1, and *—(Lᵢ)_{b1}—(T₁)_{c1}, and may each independently be an integer selected from 0 to 20.

In an embodiment, a1, a2, a3, and a4 may each independently be 0, 1, 2, 3, 4, or 5.

In an embodiment, c1 may be 1 or 2.

In an embodiment, n1 may be 0 or 1.

In an embodiment, c1 may be 2, and n1 may be 1.

In an embodiment, the organometallic compound may be represented by Formula 1-1 or 1-2:

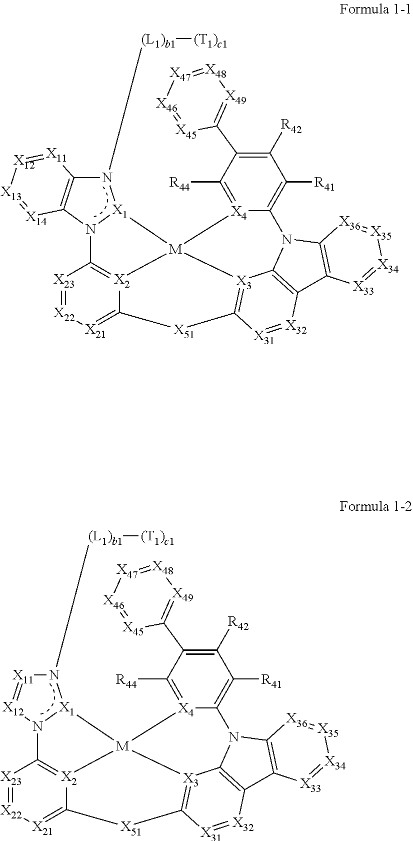

wherein, in Formulae 1-1 and 1-2,

M, X₁ to X₄, X₅₁, L₁, b1, T₁, c1, R₄₁, R₄₂, and R₄₄ are respectively the same as described in the present specification,

X₁₁ may be C(R₁₁) or N, X₁₂ may be C(R₁₂) or N, X₁₃ may be C(R₁₃) or N, and X₁₄ may be C(R₁₄) or N,

R₁₁ to R₁₄ are respectively the same as described in connection with R₁ in the present specification, and two or more of R₁₁ to R₁₄ may optionally be bonded together to form a C₃-C₆₀ carbocyclic group unsubstituted or substituted with at least one R₁₀ₐ or a C₁-C₆₀ heterocyclic group unsubstituted or substituted with at least one R₁₀ₐ,

X₂₁ may be C(R₂₁) or N, X₂₂ may be C(R₂₂) or N, and X₂₃ may be C(R₂₃) or N,

R₂₁ to R₂₃ are respectively the same as described in connection with R₂ in the present specification, and two or more of R₂₁ to R₂₃ may optionally be bonded together to form a C₃-C₆₀ carbocyclic group unsubstituted or substituted with at least one R₁₀ₐ or a C₁-C₆₀ heterocyclic group unsubstituted or substituted with at least one R₁₀ₐ,

X₃₁ may be C(R₃₁) or N, X₃₂ may be C(R₃₂) or N, X₃₃ may be C(R₃₃) or N, X₃₄ may be C(R₃₄) or N, X₃₅ may be C(R₃₅) or N, and X₃₆ may be C(R₃₆) or N,

R₃₁ to R₃₆ are respectively the same as described in connection with R₃ in the present specification, and two or more of R₃₁ to R₃₆ may optionally be bonded together to form a C₃-C₆₀ carbocyclic group unsubstituted or substituted with at least one R₁₀ₐ or a C₁-C₆₀ heterocyclic group unsubstituted or substituted with at least one R₁₀ₐ,

X₄₅ may be C(R₄₅) or N, X₄₆ may be C(R₄₆) or N, X₄₇ may be C(R₄₇) or N, X₄₈ may be C(R₄₈) or N, and X₄₉ may be C(R₄₉) or N, and

R₄₅ to R₄₉ are respectively the same as described in connection with R₄ in the present specification, and two or more of R₄₅ to R₄₉ may optionally be bonded together to form a C₃-C₆₀ carbocyclic group unsubstituted or substituted with at least one R₁₀ₐ or a C₁-C₆₀ heterocyclic group unsubstituted or substituted with at least one R₁₀ₐ.

In an embodiment, a group represented by

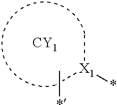

in Formula 1 may be a group represented by one selected from Formulae CY1-1 to CY1-42:

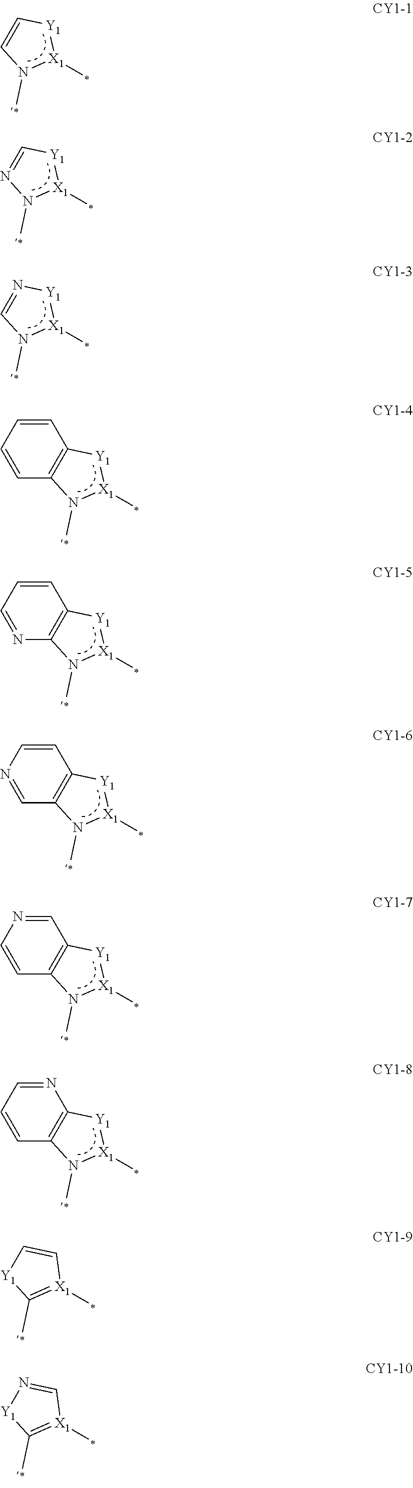

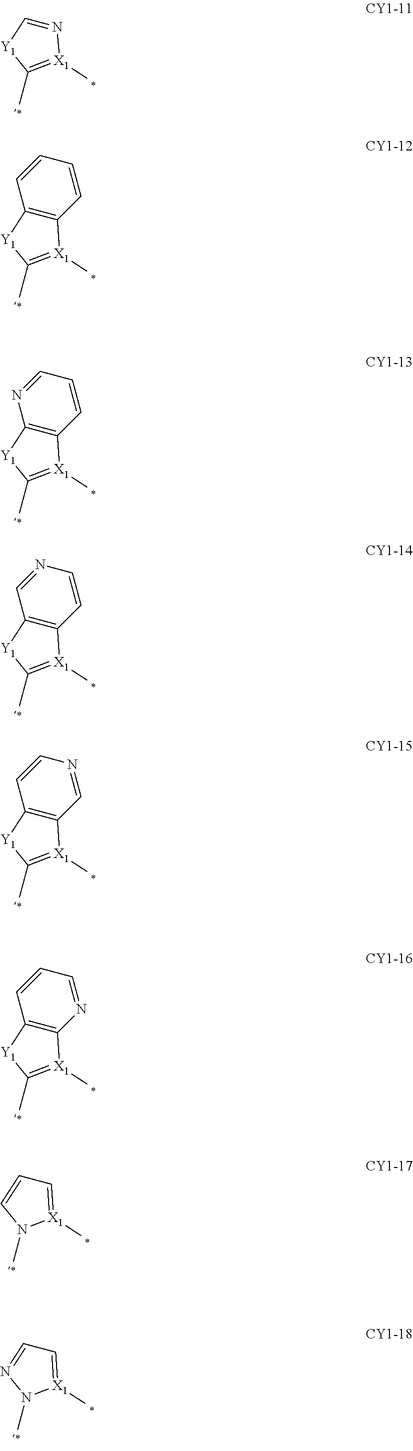

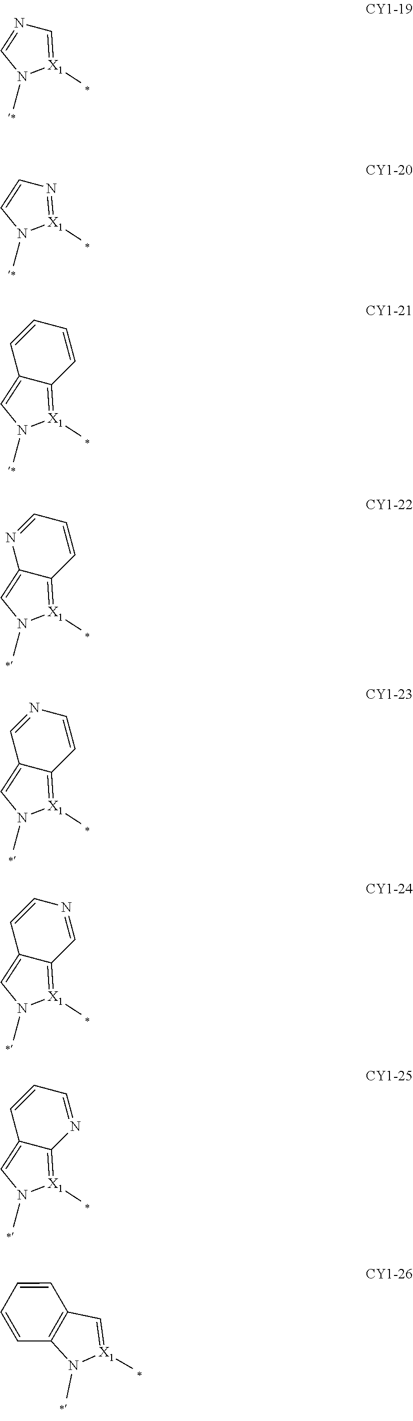

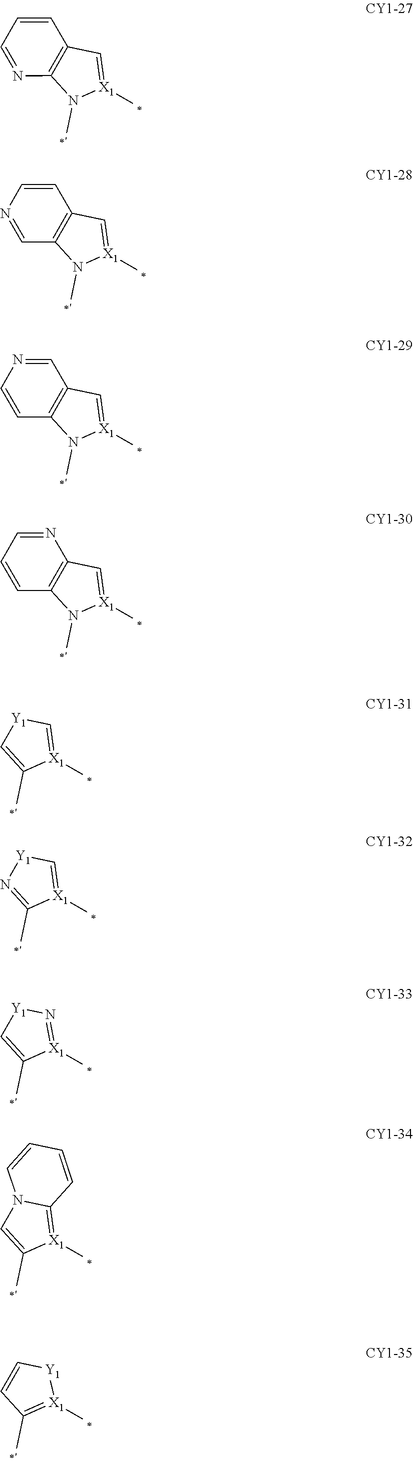

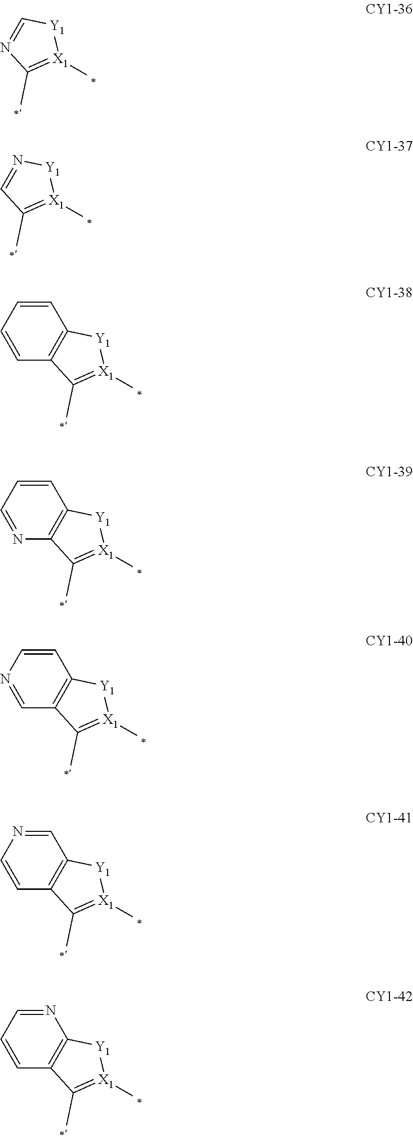

wherein, in Formulae CY1-1 to CY1-42,

X₁ is the same as described in the present specification,

Y₁ may include O, S, N, C, or Si,

* indicates a binding site to M in Formula 1, and

*′ indicates a binding site to ring CY2 in Formula 1.

In an embodiment, X₁ in Formulae CY1-1 to CY1-8 may be C, and X₁ in Formulae CY1-9 to CY1-42 may be N.

In an embodiment, a group represented by

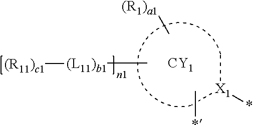

in Formula 1 may be a group represented by one selected from Formulae CY1(1) to CY1(8):

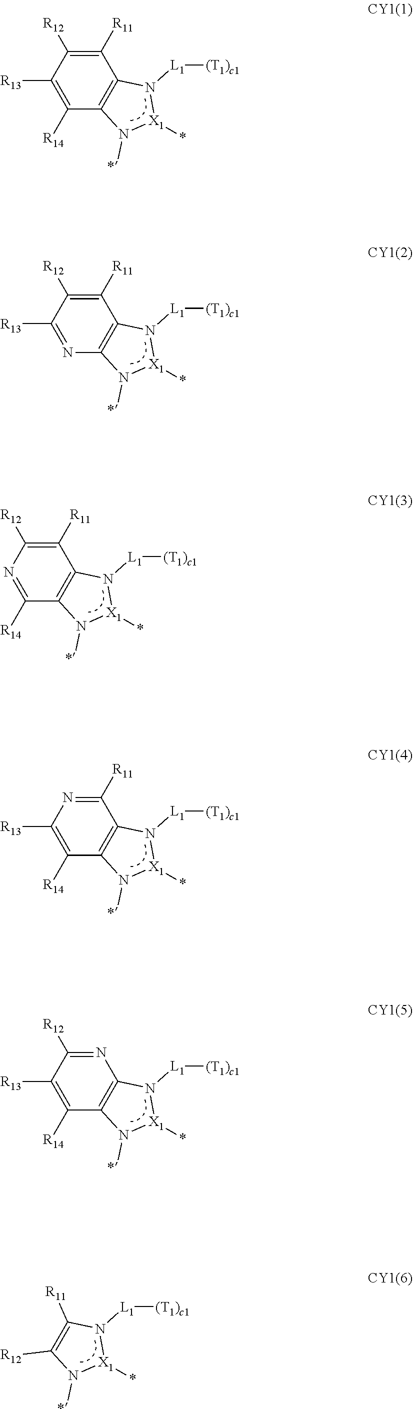

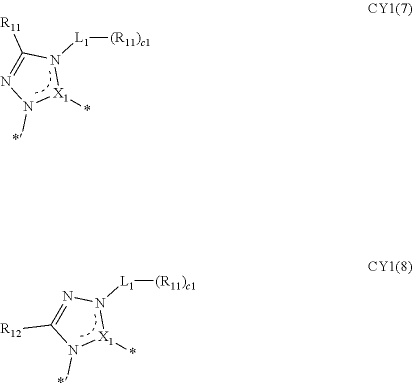

wherein, in Formulae CY1(1) to CY1(8),

X₁ may be C,

L₁, T₁, and c1 are respectively the same as described in the present specification,

R₁₁ to R₁₄ are respectively the same as described in connection with R₁ in the present specification,

* indicates a binding site to M in Formula 1, and

*′ indicates a binding site to ring CY2 in Formula 1.

In an embodiment, a group represented by *—(L₁)_{b1}-(T₁)_{c1} in Formula 1 may be a group represented by Formula CY1A:

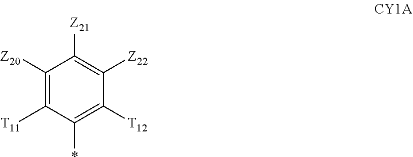

wherein, in Formula CY1A,

Z₂₀ to Z₂₂ may each independently be hydrogen, or are respectively the same as described in connection with R₁₀ₐ in the present specification,

T₁₁ and T₁₂ are respectively the same as described in connection with T₁ in the present specification, and

* indicates a binding site to ring CY1.

In an embodiment, T₁₁ and T₁₂ may each independently be a phenyl group, a naphthyl group, a dibenzofuranyl group, or a dibenzothiophenyl group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, or any combination thereof.

In an embodiment, a group represented by *—(L₁)_{b1}-(T₁)_{c1} in Formula 1 may be a group represented by Formula CY1(A):

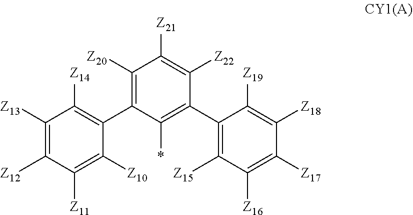

wherein, in Formula CY1(A),

Z₁₀ to Z₂₂ may each independently be hydrogen, or are respectively the same as described in connection with R₁₀ₐ in the present specification, and

* indicates a binding site to ring CY1.

In an embodiment, Z₁₀ to Z₂₂ may each independently be hydrogen, deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, or a (C₁-C₂₀ alkyl)phenyl group.

In an embodiment, a group represented by

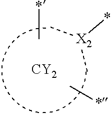

in Formula 1 may be a group represented by one selected from Formulae CY2-1 to CY2-11:

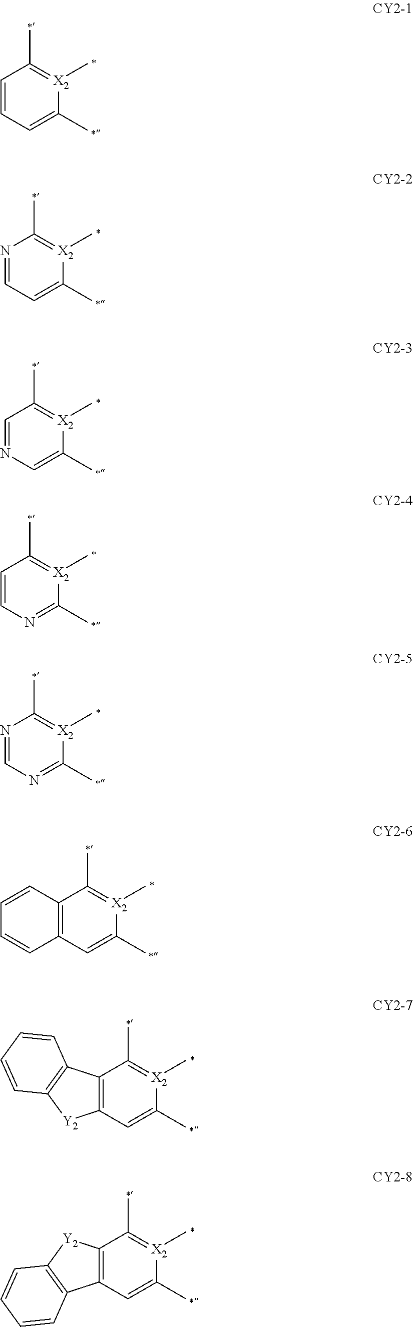

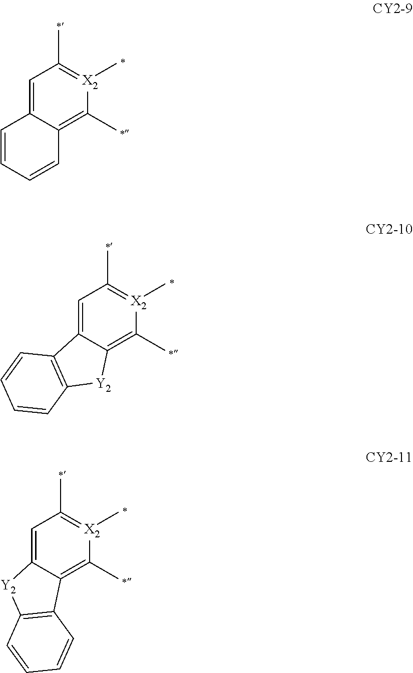

wherein, in Formulae CY2-1 to CY2-11,

X₂ is the same as described in the present specification,

Y₂ may include O, S, N, C, or Si,

* indicates a binding site to M in Formula 1,

*′ indicates a binding site to ring CY₁ in Formula 1, and

*″ indicates a binding site to X₅₁ in Formula 1.

In an embodiment, a group represented by

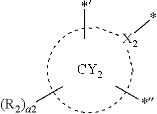

in Formula 1 and a group represented by

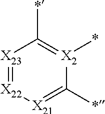

in Formulae 1-1 and 1-2 may each independently be a group represented by one selected from Formulae CY2(1) to CY2(26):

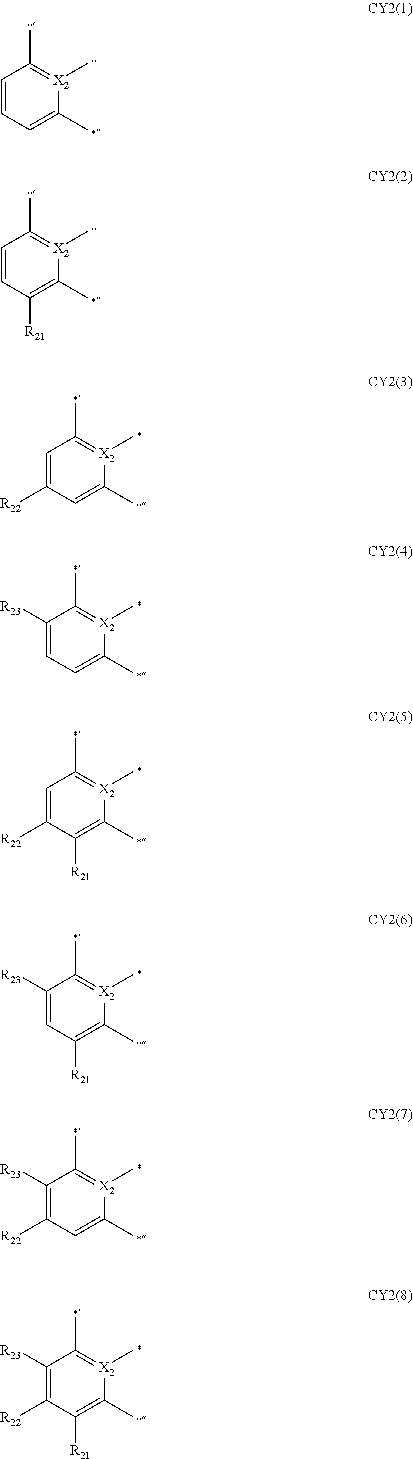

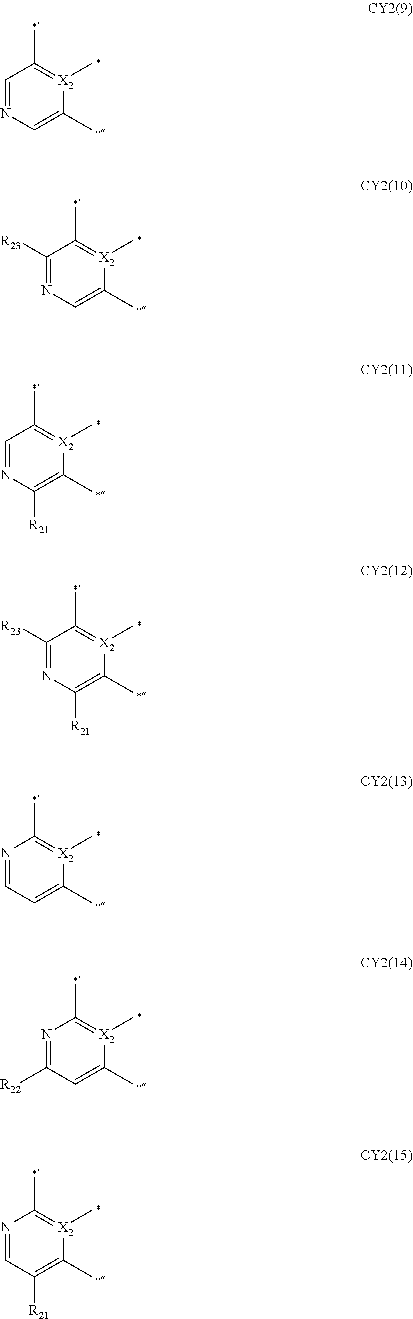

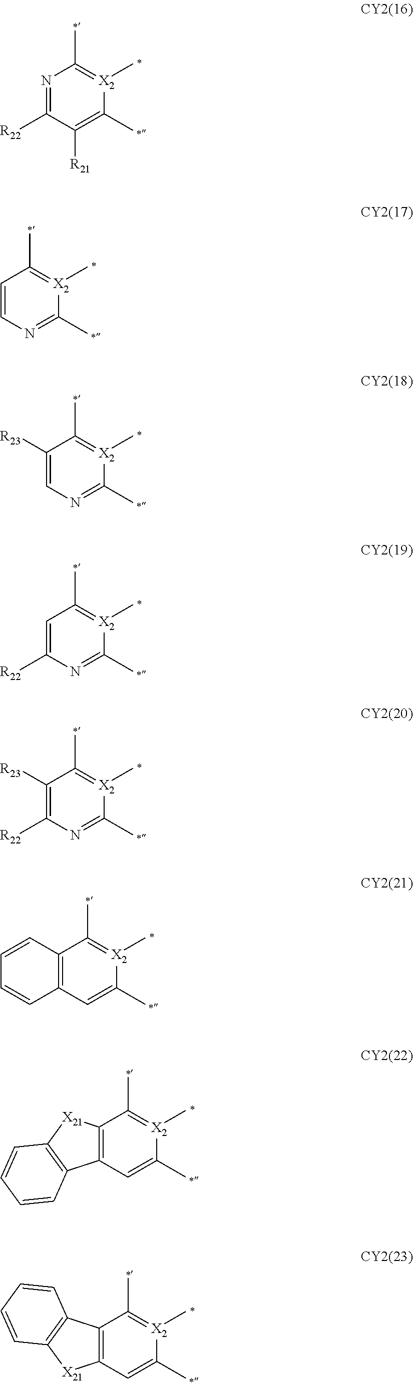

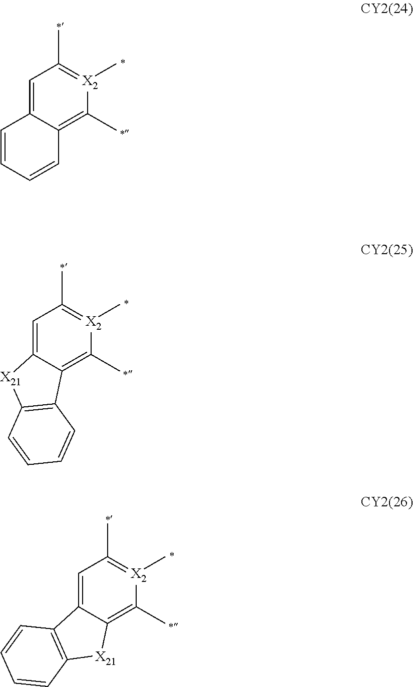

wherein, in Formulae CY2(1) to CY2(26),

X₂ is the same as described in the present specification,

X₂₁ may be O, S, N(R₂₀), C(R₂₀ₐ)(R_{20b}), or Si(R₂₀ₐ)(R_{20b}),

R₂₀, R₂₀ₐ, R_{20b}, and R₂₁ to R₂₃ are respectively the same as described in connection with R₂ in the present specification, and R₂₁ to R₂₃ may each not be hydrogen,

* indicates a binding site to M in Formula 1,

*′ indicates a binding site to ring CY₁ in Formula 1, and

*″ indicates a binding site to X₅₁ in Formula 1.

In an embodiment, a group represented by

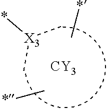

in Formula 1 may be a group represented by one selected from Formulae CY3-1 to CY3-23:

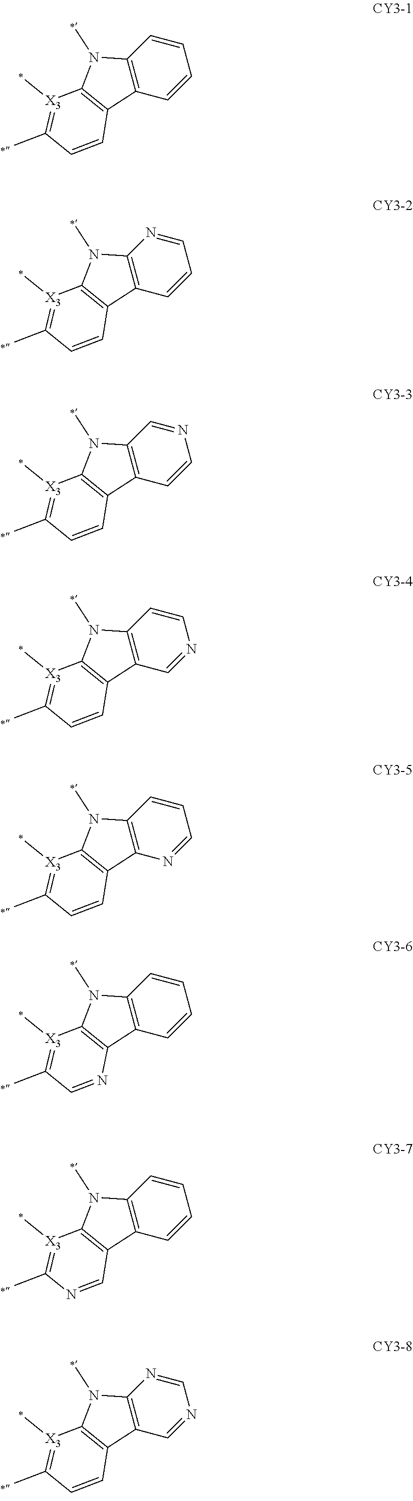

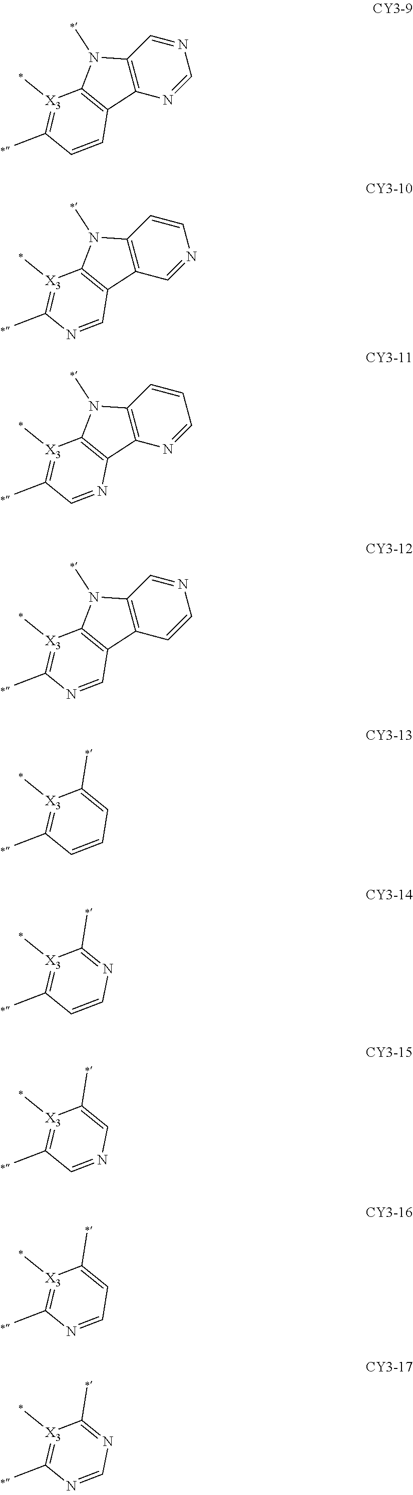

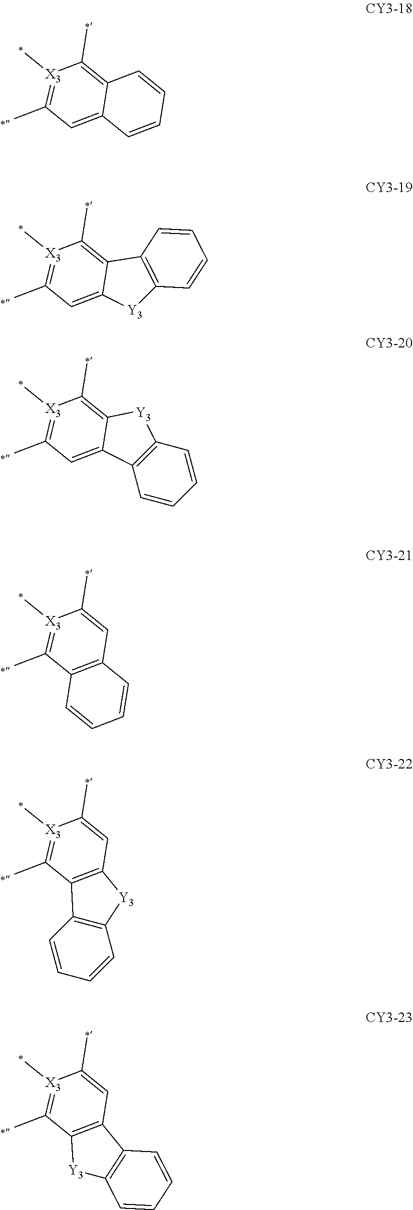

wherein, in Formulae CY3-1 to CY3-23,

X₃ is the same as described in the present specification,

Y₃ may include O, S, N, C, or Si,

* indicates a binding site to M in Formula 1,

*′ indicates a binding site to X₅₂ in Formula 1, and

*″ indicates a binding site to X₅₁ in Formula 1.

In an embodiment, a group represented by

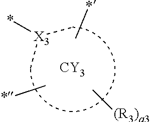

in Formula 1 may be a group represented by one selected from Formulae CY3(1) to CY3(20), and a group represented by

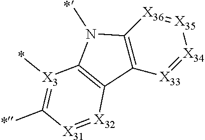

in Formulae 1-1 and 1-2 may be a group represented by one selected from Formulae CY3(1) to CY3(12):

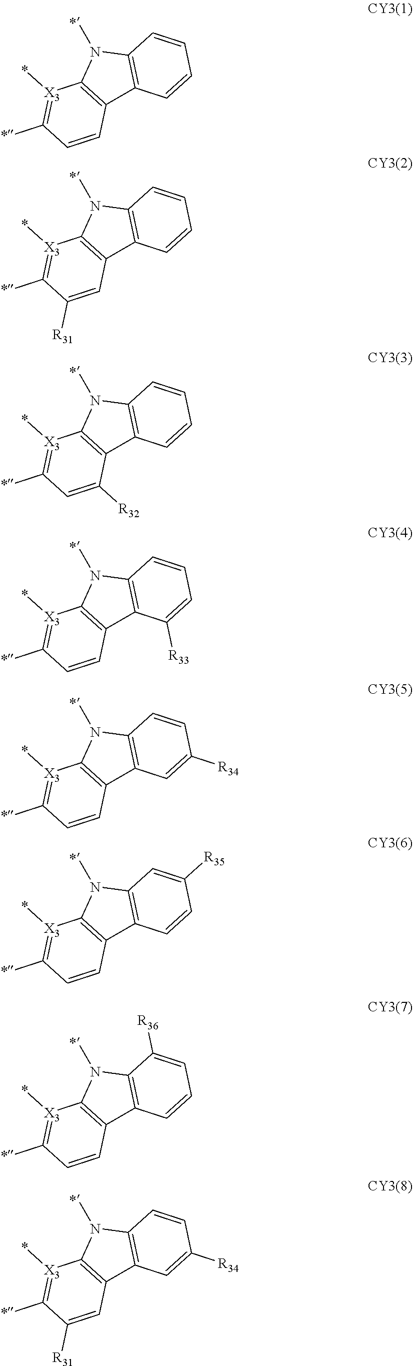

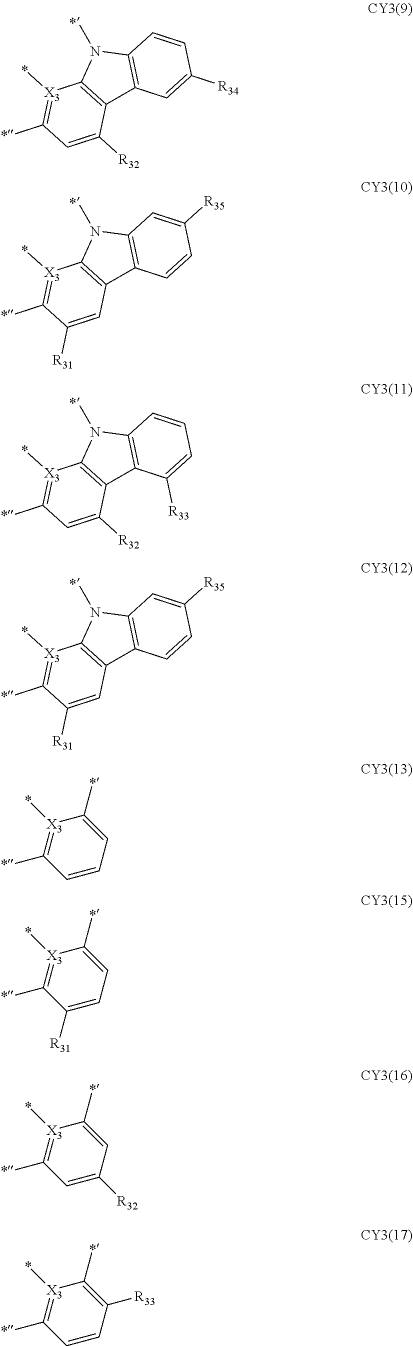

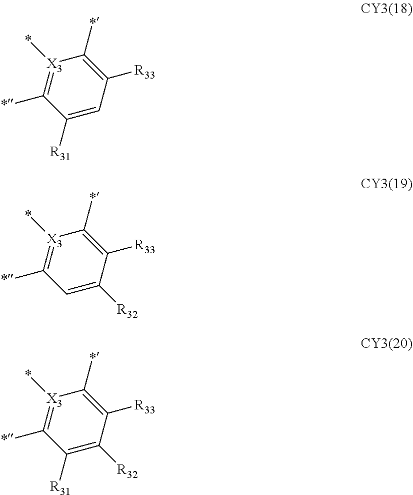

wherein, in Formulae CY3(1) to CY3(20),

X₃ is the same as described in the present specification,

R₃₁ to R₃₆ are respectively the same as described in connection with R₃ in the present specification, wherein R₃₁ to R₃₆ may each not be hydrogen,

* indicates a binding site to M in Formula 1,

*′ indicates a binding site to X₅₂ in Formula 1, and

*″ indicates a binding site to X₅₁ in Formula 1.

In an embodiment, a group represented by

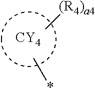

in Formula 1 and a group represented by

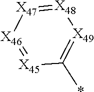

in Formulae 1-1 and 1-2 may each independently be a phenyl group, a naphthyl group, a dibenzofuranyl group, or a dibenzothiophenyl group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, or any combination thereof.

An absolute value (ΔCS) of a difference between a chemical shift value of R₄₄ and a chemical shift value of R₄₁ of the organometallic compound, as measured by proton nuclear magnetic resonance (NMR) spectroscopy, may be in a range of about 480 Hz to about 600 Hz (for example, about 500 Hz to about 600 Hz or about 510 Hz to about 600 Hz). Therefore, a maximum emission wavelength (or an emission peak wavelength) of the organometallic compound may be relatively decreased (e.g., a maximum emission wavelength may be blue-shifted). Examples of ΔCS are shown in Tables 8 and 9 in the present specification.

According to one or more embodiments, the organometallic compound includes:

platinum (Pt); and

a tetradentate ligand,

wherein the tetradentate ligand includes:

a pyridine group; and

a carbazole group or an azacarbazole group,

N in the pyridine group is bonded to the platinum,

N in the carbazole group or the azacarbazole group is bonded to a carbon in the 2-position of the pyridine group,

a carbon of the 3-position and a carbon of the 6-position in the pyridine group are each bonded to hydrogen or deuterium,

a substituent bonded to a carbon of the 4-position in the pyridine group is neither hydrogen nor deuterium,

a substituent bonded to a carbon of the 5-position in the pyridine group is a phenyl group, a naphthyl group, a dibenzofuranyl group, or a dibenzothiophenyl group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, or any combination thereof, and

an absolute value (ΔCS) of a difference between a chemical shift value of hydrogen or deuterium bonded to the carbon of the 6-position in the pyridine group and a chemical shift value of hydrogen or deuterium bonded to the carbon in the 3-position of the pyridine group of the organometallic compound, as measured by proton nuclear magnetic resonance (NMR) spectroscopy, is in a range of about 480 Hz to about 600 Hz (for example, about 500 Hz to about 600 Hz or about 510 Hz to about 600 Hz). Examples of ΔCS are shown in Table 8 in the present specification.

In an embodiment, the substituent bonded to the carbon of the 4-position in the pyridine group may be a C₁-C₂₀ alkyl group unsubstituted or substituted with deuterium, —F, a cyano group, or any combination thereof.

In an embodiment, the tetradentate ligand may further include a carbene-containing cyclic group (for example, an imidazole group, a triazole group, a benzimidazole group, or an imidazopyridine group) having 3 to 60 carbon atoms, and C of carbene in the carbene-containing cyclic group having 3 to 60 carbon atoms is bonded to the platinum.

The carbene-containing cyclic group having 3 to 60 carbon atoms may be substituted with a bulky cyclic group having 3 to 60 carbon atoms.

The bulky cyclic group having 3 to 60 carbon atoms may include three or more phenyl groups linked to each other via a single bond.

In an embodiment, the bulky cyclic group having 3 to 60 carbon atoms may be a group represented by Formula CY1(A) described in the present specification.

The organometallic compound represented by Formula 1 may include i) ring CY₄, ii) R₄₂ may not be hydrogen, and iii) R₄₁ and R₄₄ may each independently be hydrogen or deuterium (see Formula 1), thereby inducing an increase in electron density localization between R₄₁ and R₄₄ in Formula 1. In an embodiment, in the tetradentate ligand of the organometallic compound including the platinum and the tetradentate ligand, i) the substituent bonded to the carbon in the 5-position of the pyridine group may be a phenyl group, a naphthyl group, a dibenzofuranyl group, or a dibenzothiophenyl group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, or any combination thereof, ii) the substituent bonded to the carbon in the 4-position of the pyridine group may neither be hydrogen nor deuterium, and iii) the carbon in the 3-position and the carbon in the 6-position of the pyridine group may each be bonded to hydrogen or deuterium, and thus the organometallic compound including the platinum and the tetradentate ligand may have increased electron density localization between hydrogen or deuterium bonded to the carbon in the 6-position of the pyridine group and hydrogen or deuterium bonded to the carbon in the 3-position of the pyridine group in the tetradentate ligand.

Therefore, the maximum emission wavelength, emission FWHM, and dipole moment of light emitted from the organometallic compound may be relatively decreased, color purity may be improved, and a radiative decay rate (Kr) may be increased. Also, the steric shielding effect (SSE) of the organometallic compound may be improved to substantially suppress or reduce excimer formation and/or exciplex formation with a host material in a light-emitting device including the organometallic compound, and thus, the internal quantum efficiency of the light-emitting device may be improved.

Furthermore, the organometallic compound may have a relatively large TS_{M(migration)} energy (kcal/mol). In an embodiment, a TS_{M(migration)} energy of the organometallic compound may be in a range of about 28 kcal/mol or more, about 28 kcal/mol to about 40 kcal/mol, about 28 kcal/mol to about 35 kcal/mol, or about 28 kcal/mol to about 32 kcal/mol. The TS_{M(migration)} energy may be energy for ligand migration, which is an intermediate process of degradation between a metal and a ligand in the transition state of the organometallic compound, and may be an energy barrier for ligand migration. In an embodiment, the TS_{M(migration)} energy may be calculated by using a density functional theory (DFT) method based on a lowest excitation triplet (T₁) energy of the organometallic compound (for example, see Evaluation Example 4 and Table 6). As described above, the organometallic compound has a relatively large TS_{M(migration)} energy, and thus, material stability may be improved by minimizing or reducing intrinsic degradation during an energy transition process in the organometallic compound. Therefore, an electronic device, for example, a light-emitting device, including the organometallic compound may have excellent luminescence efficiency and/or lifespan.

b51 to b53 in Formula 2 indicate numbers of L₅₁ to L₅₃, respectively, and may each be an integer selected from 1 to 5. When b51 is 2 or more, two or more of L₅₁ (s) may be identical to or different from each other, when b52 is 2 or more, two or more of L₅₂(s) may be identical to or different from each other, and when b53 is 2 or more, two or more of L₅₃(s) may be identical to or different from each other. In an embodiment, b51 to b53 may each independently be 1 or 2.

L₅₁ to L₅₃ in Formula 2 may each independently be:

a single bond; or

a benzene group, a naphthalene group, an anthracene group, a phenanthrene group, a triphenylene group, a pyrene group, a chrysene group, a cyclopentadiene group, a furan group, a thiophene group, a silole group, an indene group, a fluorene group, an indole group, a carbazole group, a benzofuran group, a dibenzofuran group, a benzothiophene group, a dibenzothiophene group, a benzosilole group, a dibenzosilole group, an azafluorene group, an azacarbazole group, an azadibenzofuran group, an azadibenzothiophene group, an azadibenzosilole group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a dibenzooxacilline group, a dibenzothiacilline group, a dibenzodihydroazacilline group, a dibenzodihydrodicilline group, a dibenzodihydrocilline group, a dibenzodioxane group, a dibenzooxathiene group, a dibenzooxazine group, a dibenzopyran group, a dibenzodithiine group, a dibenzothiazine group, a dibenzothiopyran group, a dibenzocyclohexadiene group, a dibenzodihydropyridine group, or a dibenzodihydropyrazine group, each unsubstituted or substituted with deuterium, —F, —CI, —Br, —I, a hydroxyl group, a cyano group, a nitro group, a C₁-C₂₀ alkyl group, a C₁-C₂₀ alkoxy group, a phenyl group, a naphthyl group, a pyridinyl group, a pyrimidinyl group, a triazinyl group, a fluorenyl group, a dimethylfluorenyl group, a diphenylfluorenyl group, a carbazolyl group, a phenylcarbazolyl group, a dibenzofuranyl group, a dibenzothiophenyl group, a dibenzosilolyl group, a dimethyldibenzosilolyl group, a diphenyldibenzosilolyl group, —O(Q₃₁), —S(Q₃₁), —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), —P(═O)(Q₃₁)(Q₃₂), or any combination thereof,

wherein Q₃₁ to Q₃₃ may each independently be hydrogen, deuterium, a C₁-C₂₀ alkyl group, a C₁-C₂₀ alkoxy group, a phenyl group, a biphenyl group, a terphenyl group, a pyridinyl group, a pyrimidinyl group, a pyridazinyl group, a pyrazinyl group, or a triazinyl group.

In an embodiment, in Formula 2, a bond between L₅₁ and R₅₁, a bond between L₅₂ and R₅₂, a bond between L₅₃ and R₅₃, a bond between two or more L₅₁(s), a bond between two or more L₅₂(s), a bond between two or more L₅₃(s), a bond between L₅₁ and carbon between X₅₄ and X₅₅ in Formula 2, a bond between L₅₂ and carbon between X₅₄ and X₅₆ in Formula 2, and a bond between L₅₃ and carbon between X₅₅ and X₅₆ in Formula 2 may each be a “carbon-carbon single bond”.

In Formula 2, X₅₄ may be N or C(R₅₄), X₅₅ may be N or C(R₅₅), X₅₆ may be N or C(R₅₆), and at least one selected from X₅₄ to X₅₆ may be N. R₅₄ to R₅₆ are respectively the same as described in the present specification. In an embodiment, two or three of X₅₄ to X₅₆ may be N.

R₅₁ to R₅₆, R₇₁ to R₇₄, R₈₁ to R₈₅, R₈₂ₐ, R_{82b}, R₈₃ₐ, R_{83b}, R₈₄ₐ, R_{84b}, R₅₀₀ₐ, R_{500b}, R₅₀₁ to R₅₀₈, R₅₀₅ₐ, R_{505b}, R₅₀₆ₐ, R_{506b}, R₅₀₇ₐ, R_{507b}, R₅₀₈ₐ, and R_{508b} in the present specification may each independently be hydrogen, deuterium, —F, —CI, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ aryl alkyl group unsubstituted or substituted with at least one R₁₀ₐ, a C₂-C₆₀ heteroaryl alkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(a), or —P(═O)(Q₁)(Q₂). Q₁ to Q₃ are respectively the same as described in the present specification.

In an embodiment, i) R₁ to R₄, R₄₂, R₅₁ₐ, R_{51b}, R₅₂ₐ, R_{52b}, and T₁ in Formula 1, ii) R₅₁ to R₅₆, R₇₁ to R₇₄, R₈₁ to R₈₅, R₈₂ₐ, R_{82b}, R₈₃ₐ, R_{83b}, R₈₄ₐ, R_{84b}, R₅₀₀ₐ, R_{500b}, R₅₀₁ to R₅₀₈, R₅₀₅ₐ, R_{505b}, R₅₀₆ₐ, R_{506b}, R₅₀₇ₐ, R_{507b}, R₅₀₈a, and R₅₀₈b in Formulae 2, 3-1 to 3-5, 502, and 503, and iii) R₁₀ₐ may each independently be:

hydrogen, deuterium, —F, —CI, —Br, —I, a hydroxyl group, a cyano group, a nitro group, a C₁-C₂₀ alkyl group, or a C₁-C₂₀ alkoxy group;

a C₁-C₂₀ alkyl group or a C₁-C₂₀ alkoxy group, each substituted with deuterium, —F, —CI, —Br, —I, —CD₃, —CD₂H, —CDH₂, —CF₃, —CF₂H, —CFH₂, a hydroxyl group, a cyano group, a nitro group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, or any combination thereof;

a cyclopentyl group, a cyclohexyl group, a cycloheptyl group, a cyclooctyl group, an adamantanyl group, a norbornanyl group, a nornornenyl group, a cyclopentenyl group, a cyclohexenyl group, a cycloheptenyl group, a phenyl group, a biphenyl group, a C₁-C₁₀ alkylphenyl group, a naphthyl group, a fluorenyl group, a phenanthrenyl group, a anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isozazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a cinnolinyl group, a carbazolyl group, a phenanthrolinyl group, a benzoimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, a azadibenzothiophenyl group, an azafluorenyl group, an azadibenzosilolyl group, or a group represented by formula 91, each unsubstituted or substituted with deaterium, —F, —CI, —Br, —I, —CD₃, —CD₂H, —CDH₂, —CF₃, —CF₂H, —CFH₂, a hydroxyl group, a cyano group, a nitro group, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a phyrenyl group, a chrysenyl group, a pyrrolyl group, a thiophenyl group, a furanyl group, a imidazolyl group, a pyrazolyl group, a thiazolyl group, an isothiazolyl group, an oxazolyl group, an isozazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, a benzothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —O(Q₃₁), —S(Q₃₁), —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), —P(═O)(Q₃₁), —P(═O)(Q₃₁)(Q₃₂), or any combination thereof; or

—C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and

Q₁ to Q₃ and Q₃₁ to Q₃₃ may each independently be:

—CH₃, —CD₃, —CD₂H, —CDH₂, —CH₂CH₃, —CH₂CD₃, —CH₂CD₂H, —CH₂CDH2, —CHDCH₃, —CHDCD₂H, —CHDCDH₂, —CHDCD₃, —CD₂CD₃, —CD₂CD₂H, or —CD₂CDH₂; or

an n-propyl group, an iso-propyl group, an n-butyl group, an isobutyl group, a sec-butyl group, a tert-butyl group, an n-pentyl group, an isopentyl group, a sec-pentyl group, a tert-pentyl group, a phenyl group, a naphthyl group, a pyridinyl group, a pyrimidinyl group, a pyridazinyl group, a pyrazinyl group, or a triazinyl group, each unsubstituted or substituted with deuterium, a C₁-C₁₀ alkyl group, a phenyl group, a biphenyl group, a pyridinyl group, a pyrimidinyl group, a pyridazinyl group, a pyrazinyl group, a triazinyl group, or any combination thereof:

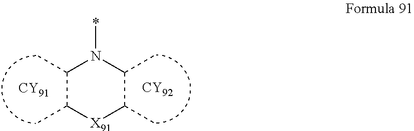

wherein, in Formula 91,

ring CY₉₁ and ring CY₉₂ may each independently be a C₅-C₃₀ carbocyclic group unsubstituted or substituted with at least one R₁₀ₐ or a C₁-C₃₀ heterocyclic group unsubstituted or substituted with at least one R₁₀ₐ,

X₉₁ may be a single bond, O, S, N(R₉₁), B(R₉₁), C(R₉₁ₐ)(R_{91b}), or Si(R₉₁ₐ)(R_{91b}),

R₉₁, R₉₁ₐ, and R_{91b} may respectively be understood by referring to the descriptions of R₈₂, R₈₂ₐ, and R_{82b} provided herein,

R₁₀ₐ may be the same as described in the present specification, provided that R₁₀ₐ is not hydrogen, and

* indicates a binding site to an adjacent atom.

In an embodiment, in Formula 91,

ring CY₉₁ and ring CY₉₂ may each independently be a benzene group, a pyridine group, a pyrimidine group, a pyrazine group, a pyridazine group, or a triazine group, each unsubstituted or substituted with at least one R₁₀ₐ, and

R₉₁, R₉₁ₐ, and R_{91b} may each independently be:

hydrogen or a C₁-C₁₀ alkyl group; or

a phenyl group, a pyridinyl group, a pyrimidinyl group, a pyridazinyl group, a pyrazinyl group, or a triazinyl group, each unsubstituted or substituted with deuterium, a C₁-C₁₀ alkyl group, a phenyl group, a biphenyl group, a pyridinyl group, a pyrimidinyl group, a pyridazinyl group, a pyrazinyl group, a triazinyl group, or any combination thereof.

In an embodiment, i) R₁ to R₄, R₄₂, R₅₁ₐ, R_{51b}, R₅₂ₐ, R_{52b}, and T₁ in Formula 1 ii) R₅₁ to R₅₆, R₇₁ to R₇₄, R₈₁ to R₈₅, R₈₂ₐ, R_{82b}, R₈₃ₐ, R_{83b}, R₈₄ₐ, R_{84b}, R₅₀₀ₐ, R_{500b}, R₅₀₁ to R₅₀₈, R₅₀₅ₐ, R_{505b}, R₅₀₆ₐ, R_{506b}, R₅₀₇ₐ, R_{507b}, R₅₀₈ₐ, and R_{508b} in Formulae 2, 3-1 to 3-5, 502, and 503, and iii) R₁₀ₐ may each independently be hydrogen, deuterium, —F, a cyano group, a nitro group, —CH₃, —CD₃, —CD₂H, —CDH₂, —CF₃, —CF₂H, —CFH₂, a group represented by one selected from Formulae 9-1 to 9-19 below, a group represented by one selected from Formulae 10-1 to 10-246, —C(Q₁)(Q₂)(Q₃), —Si(Q₁)(Q₂)(Q₃), or —P(═O)(Q₁)(Q₂) (wherein Q₁ to Q₃ are respectively the same as those described above):

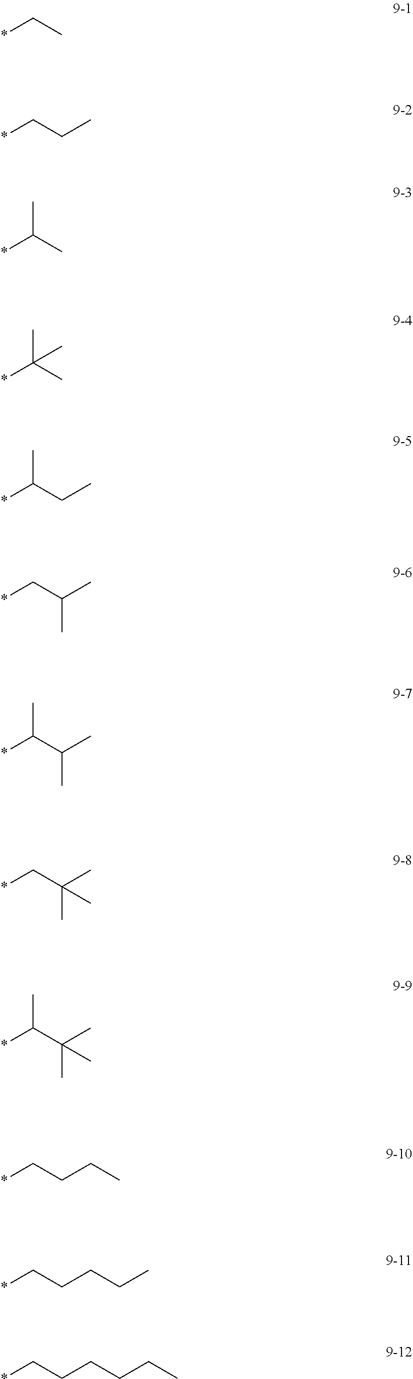

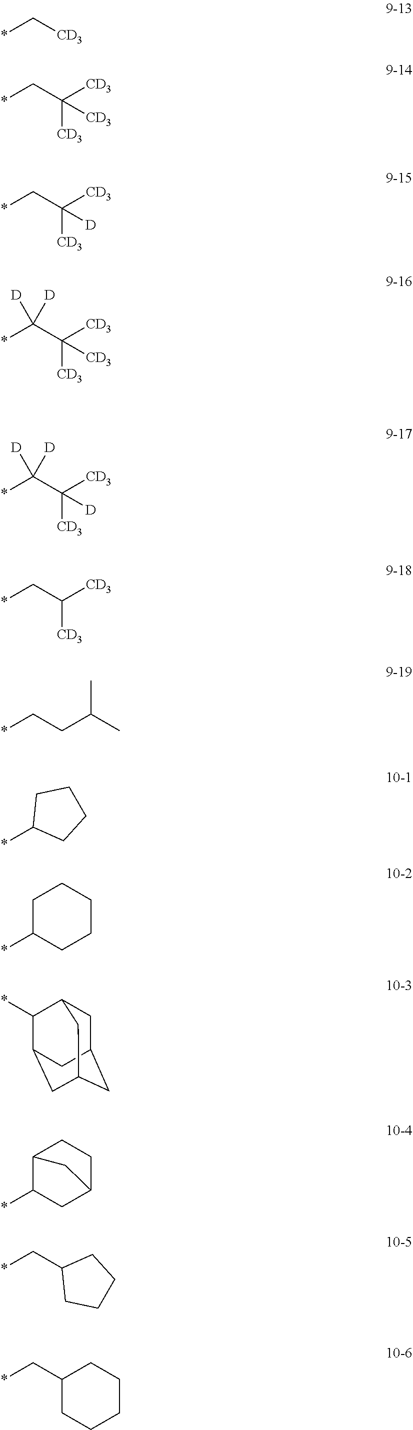

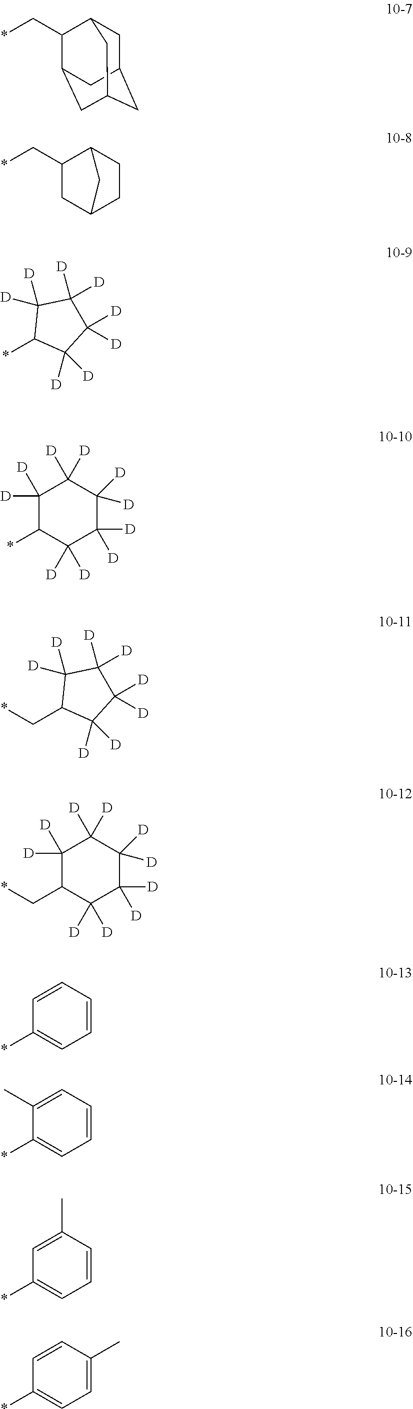

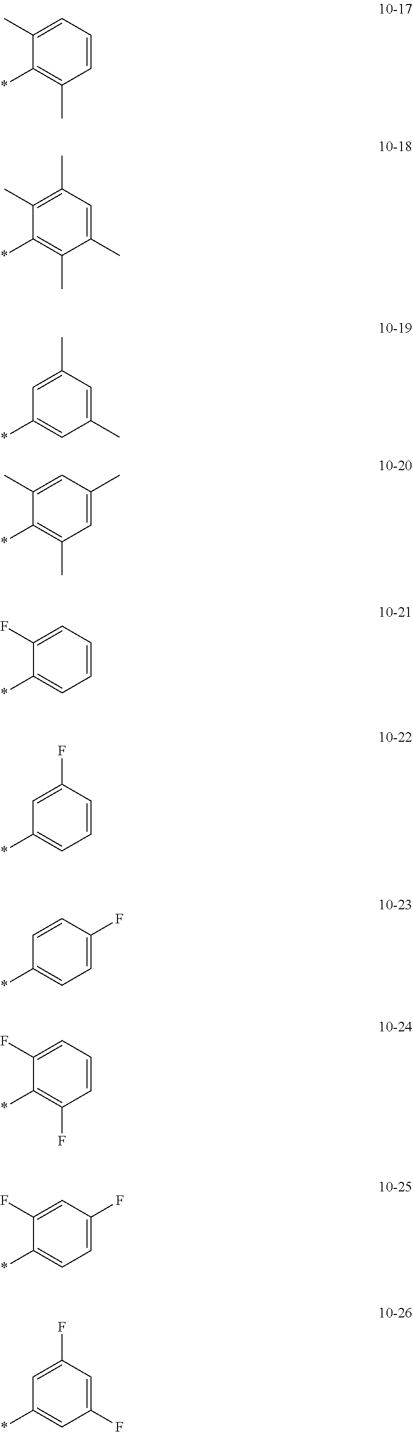

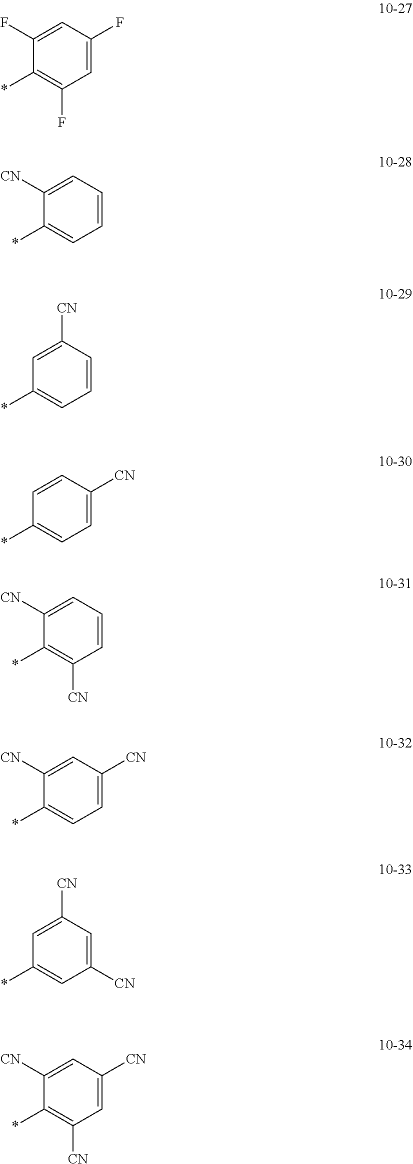

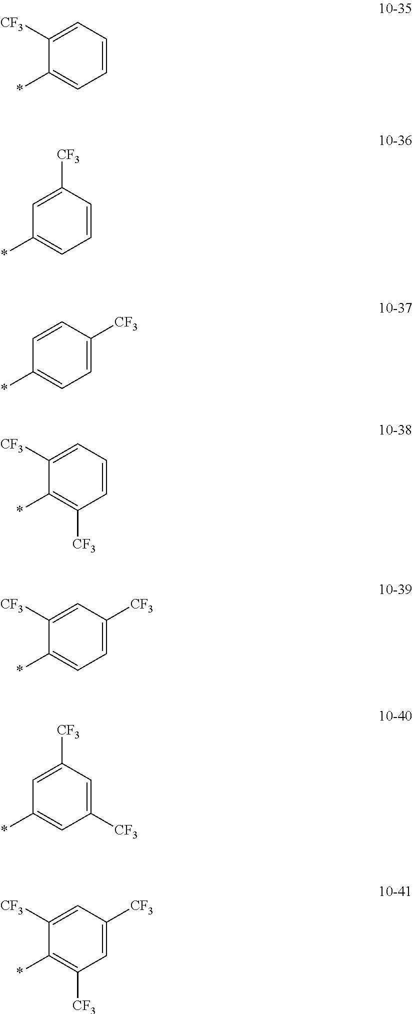

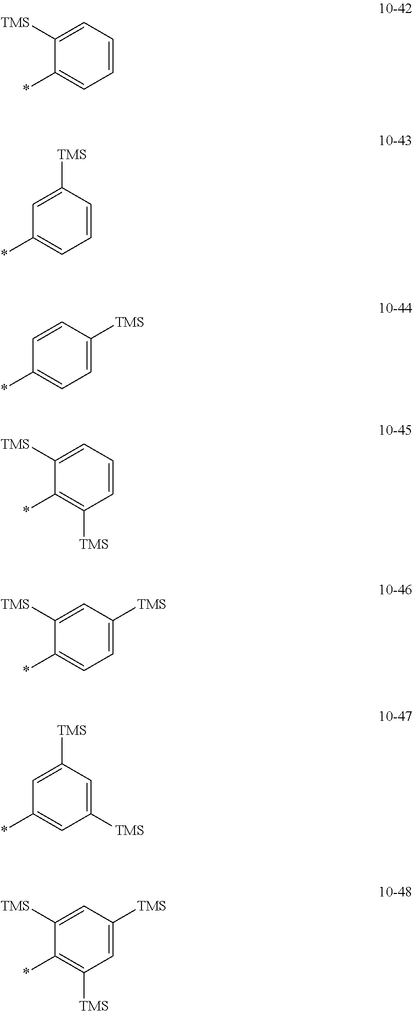

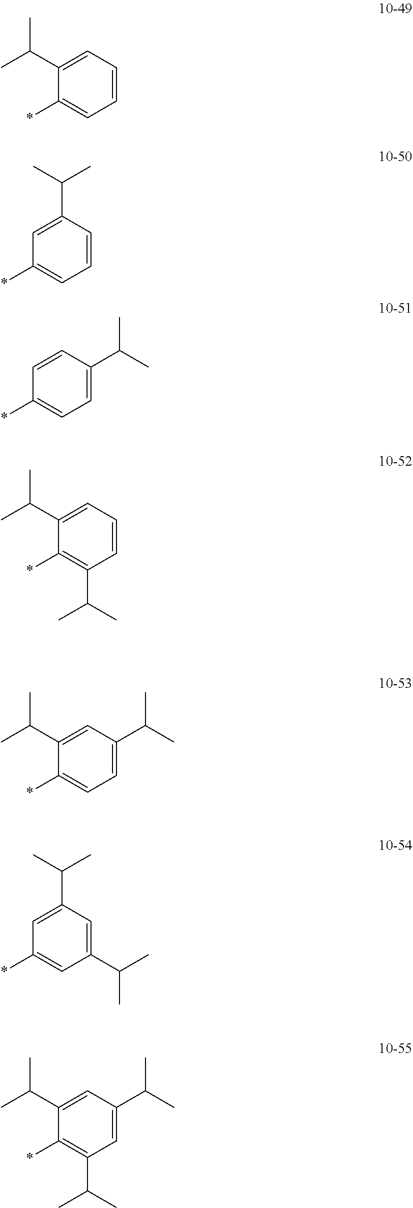

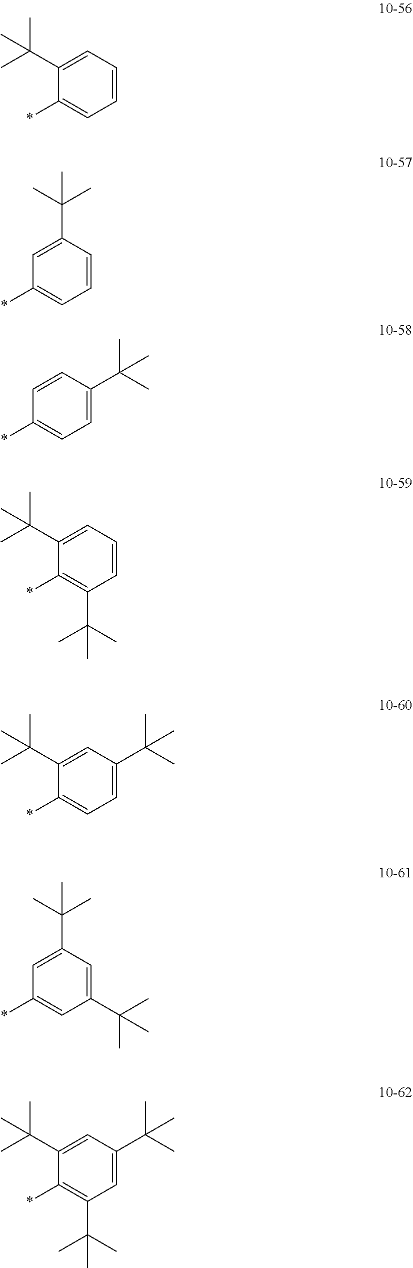

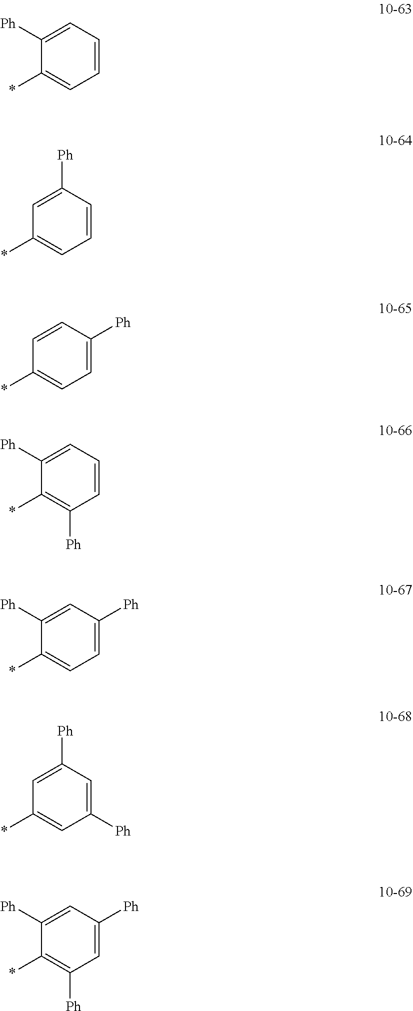

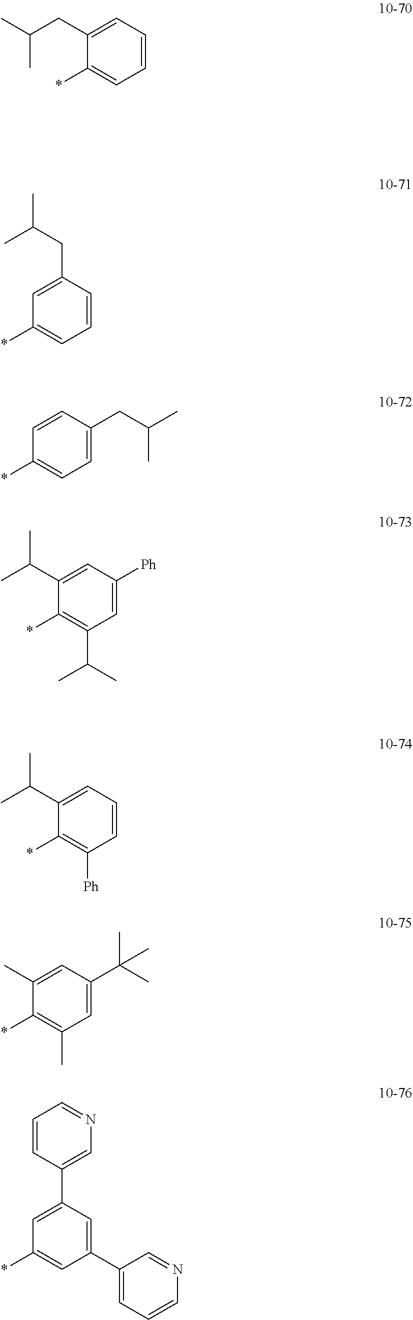

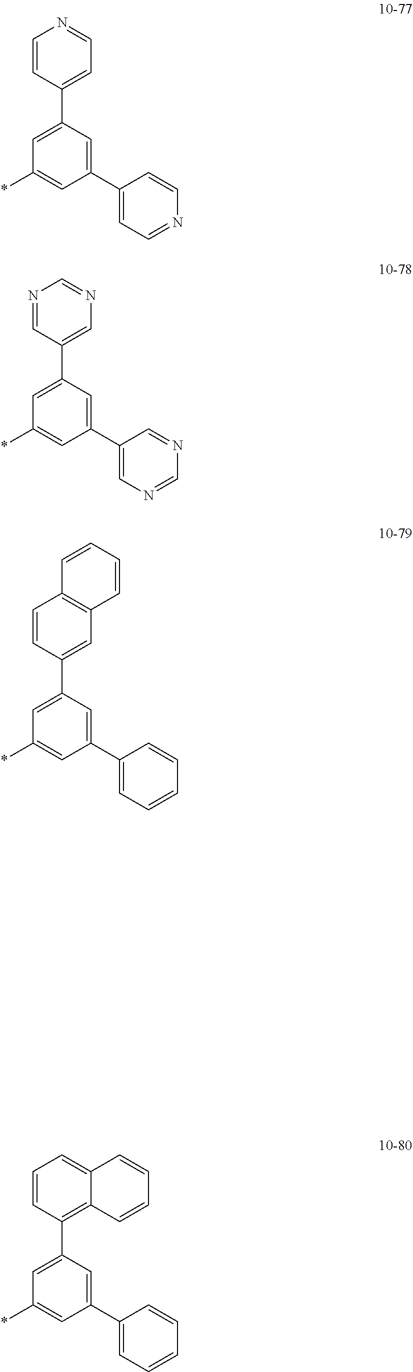

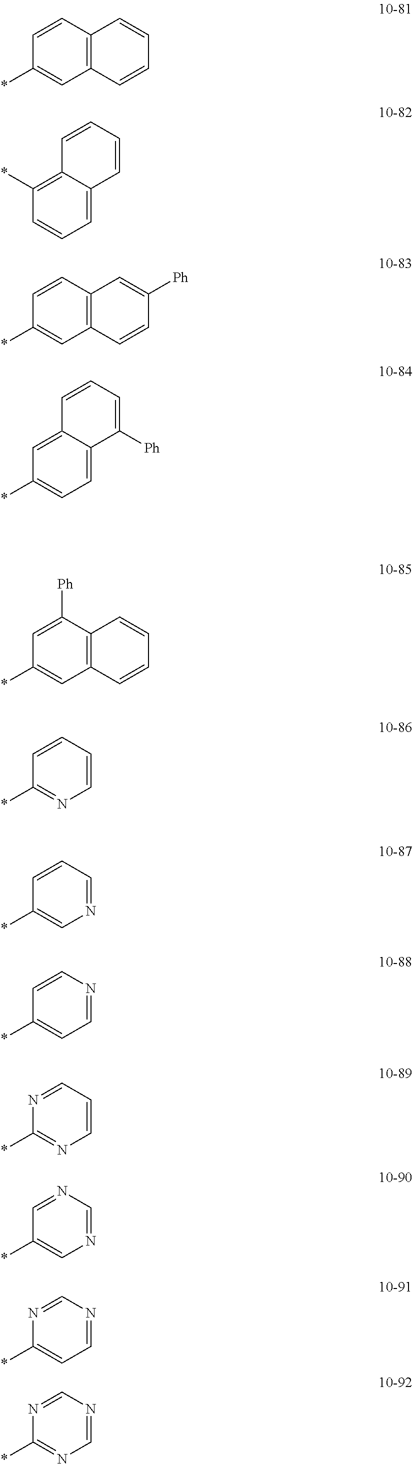

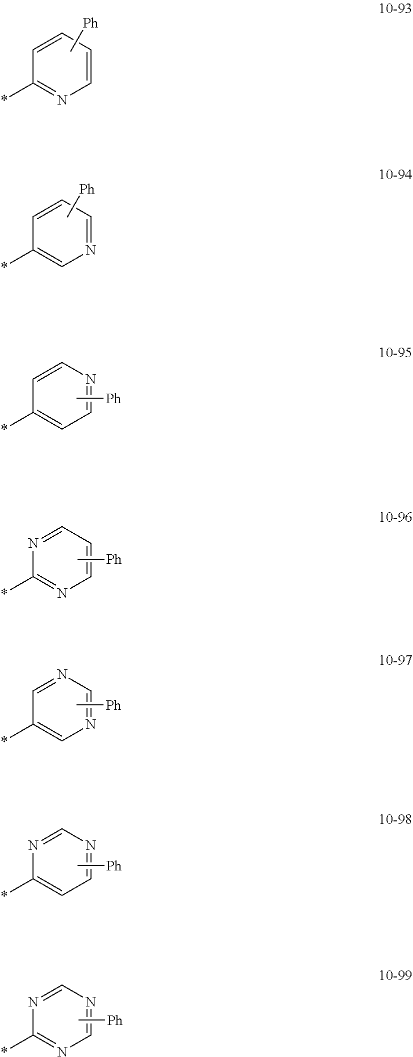

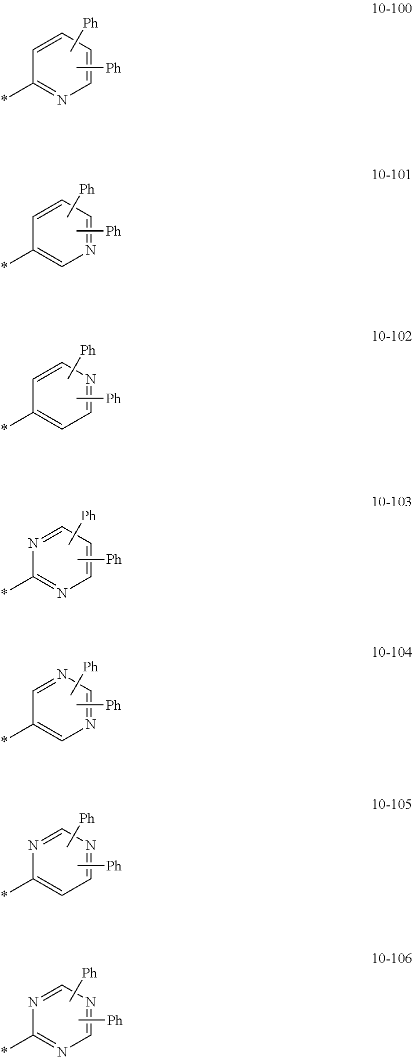

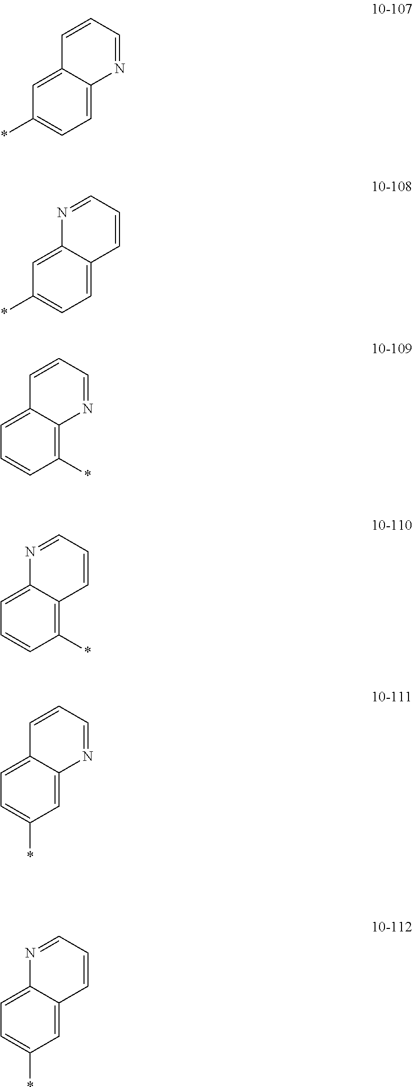

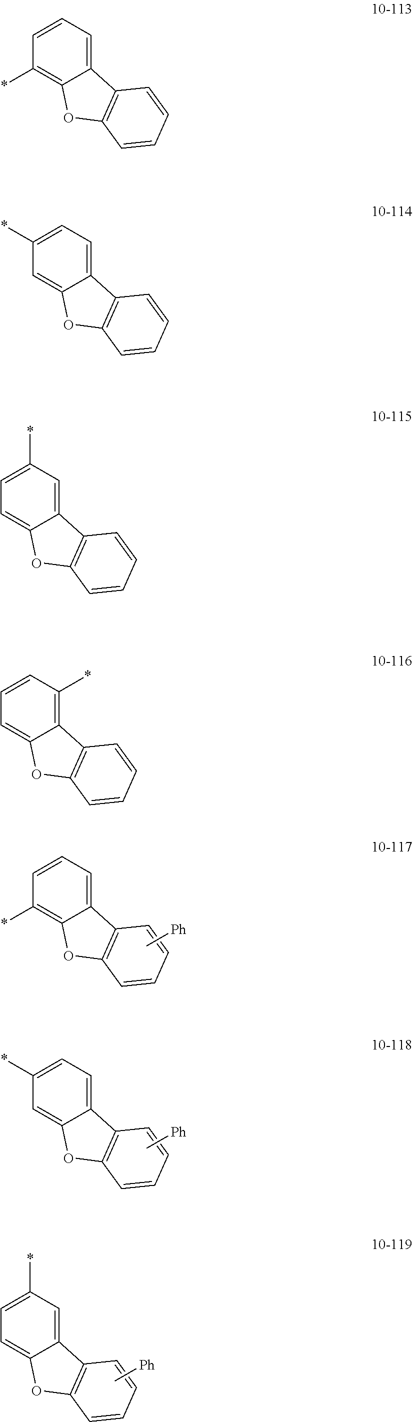

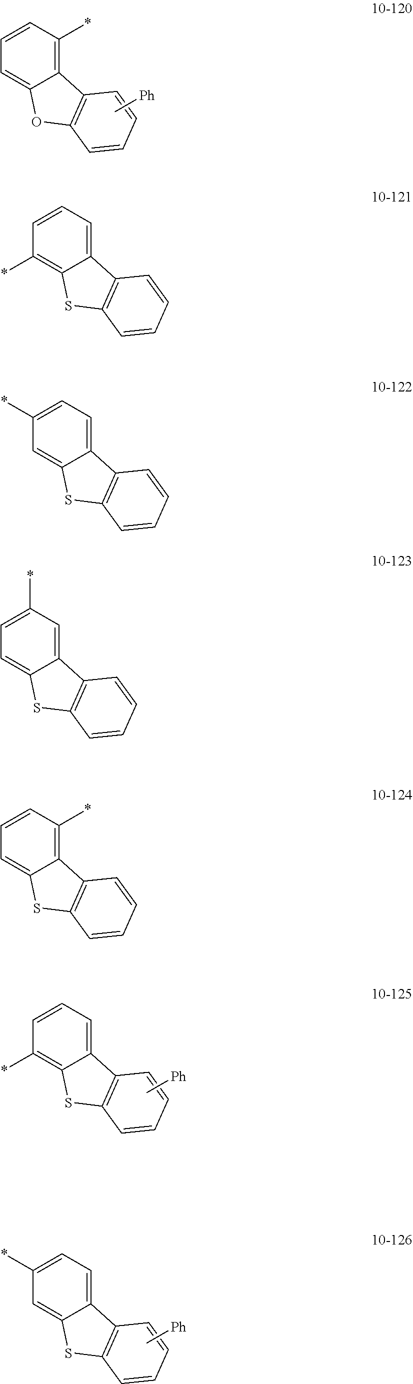

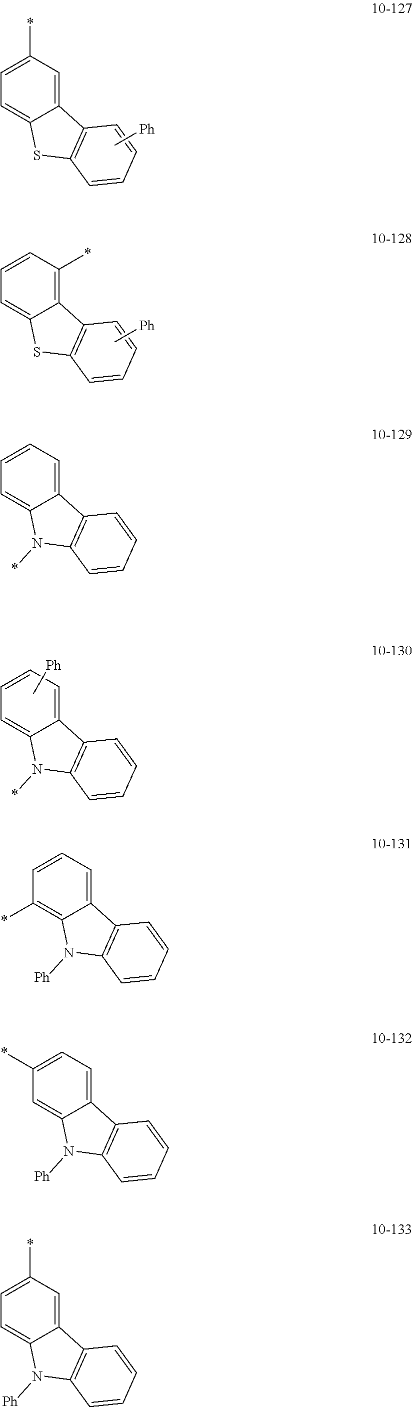

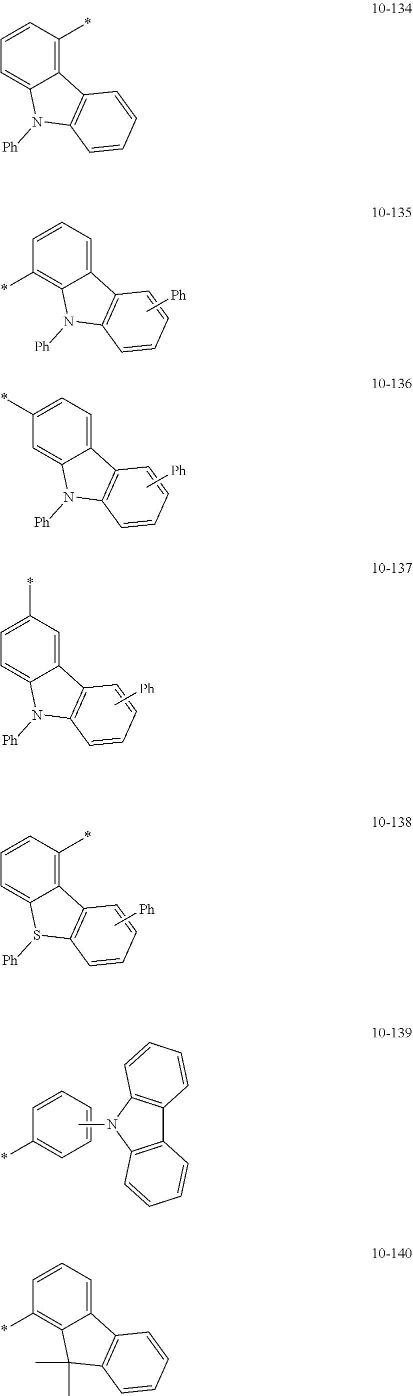

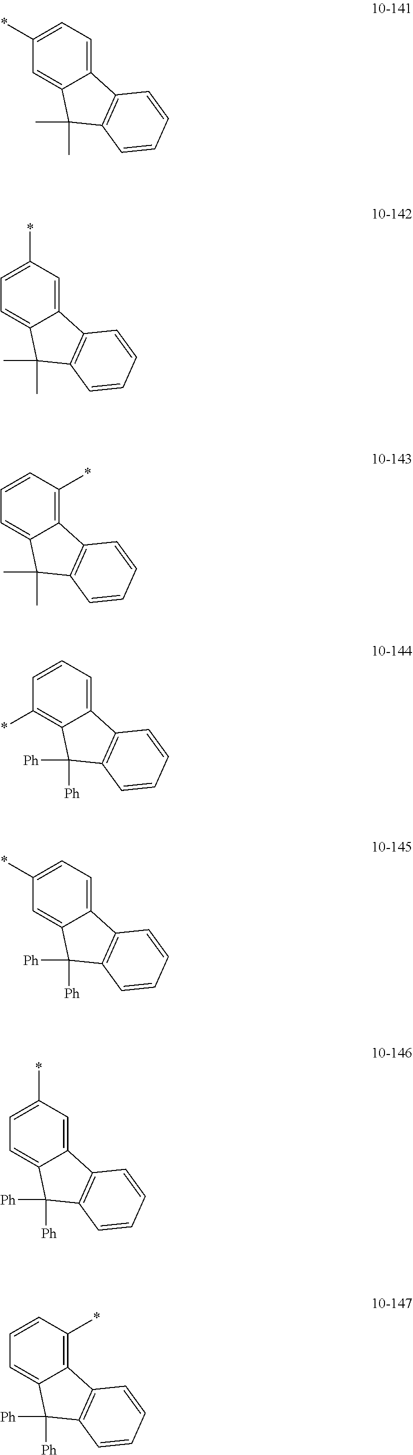

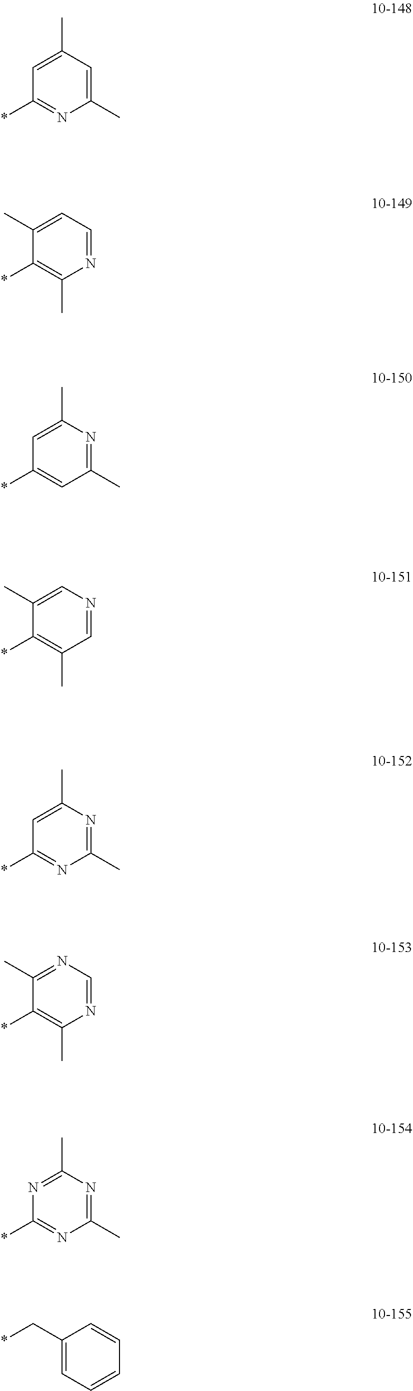

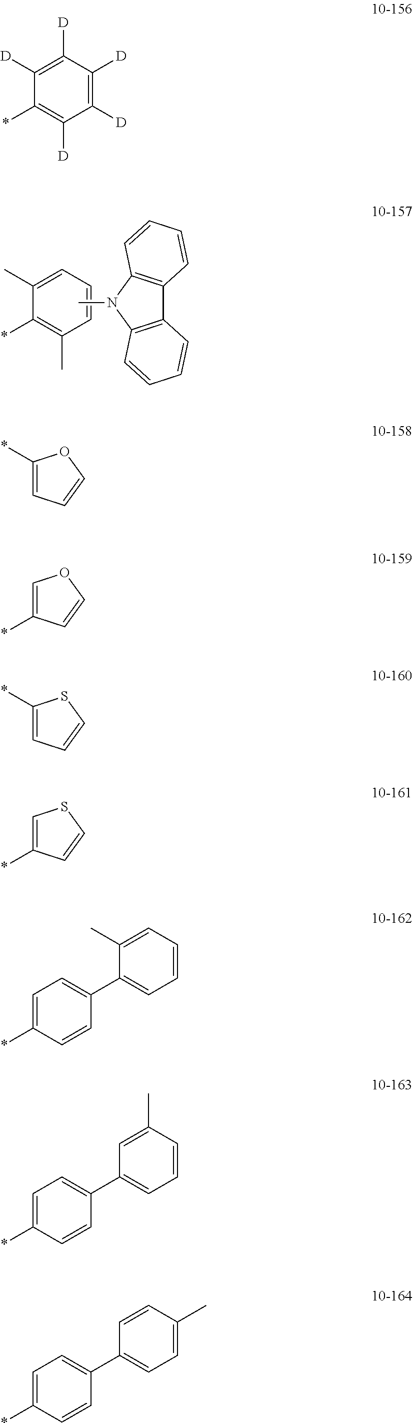

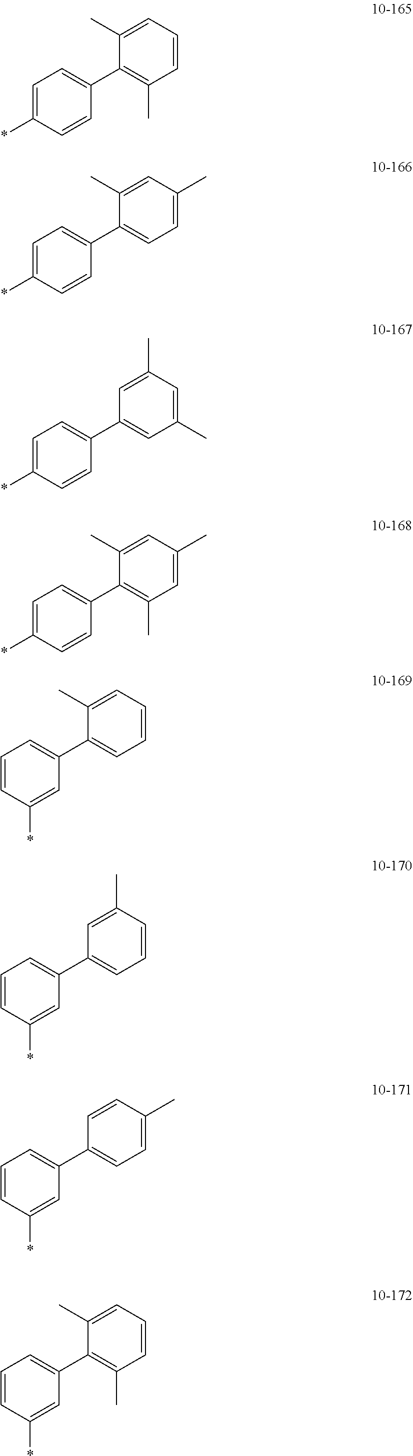

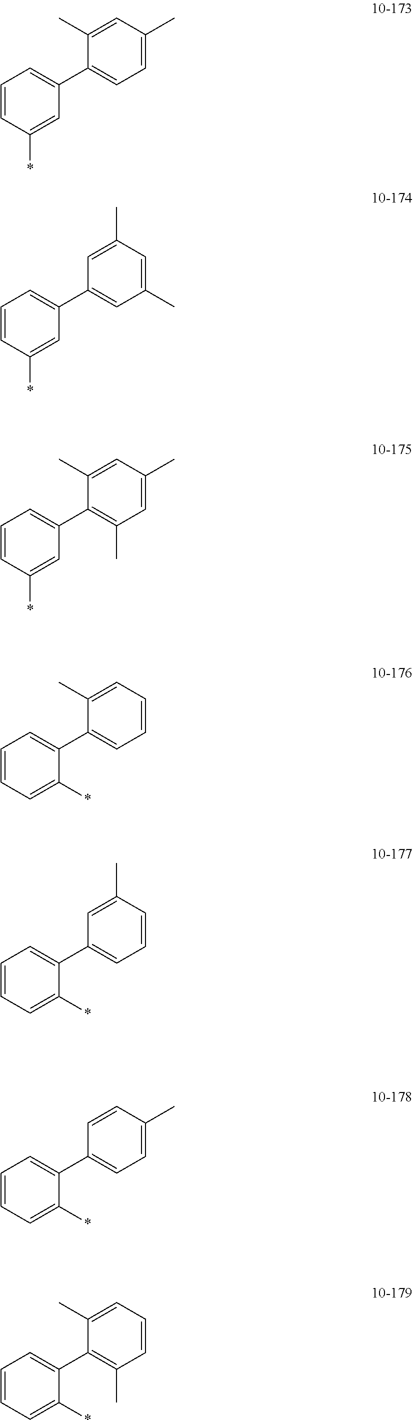

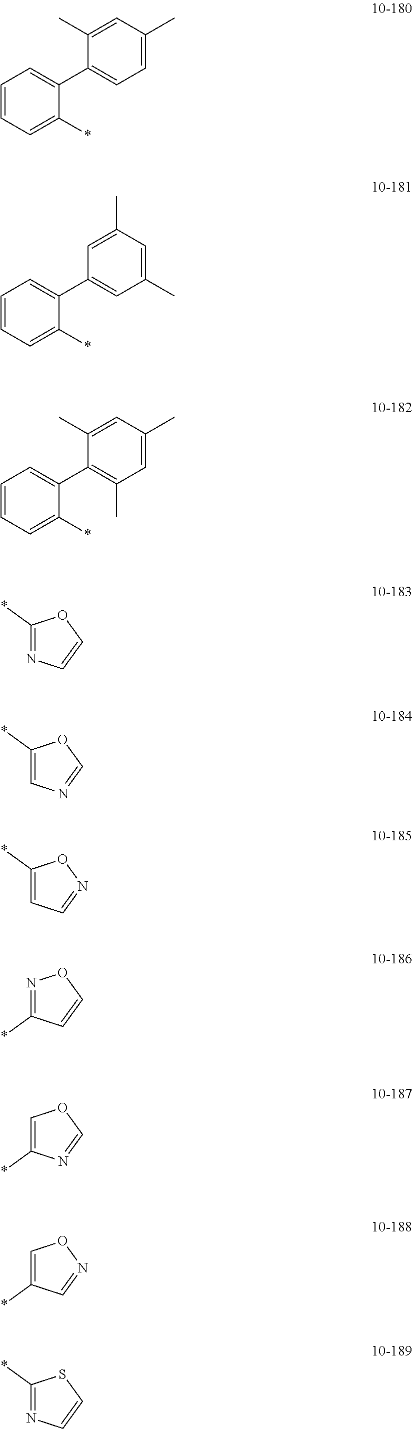

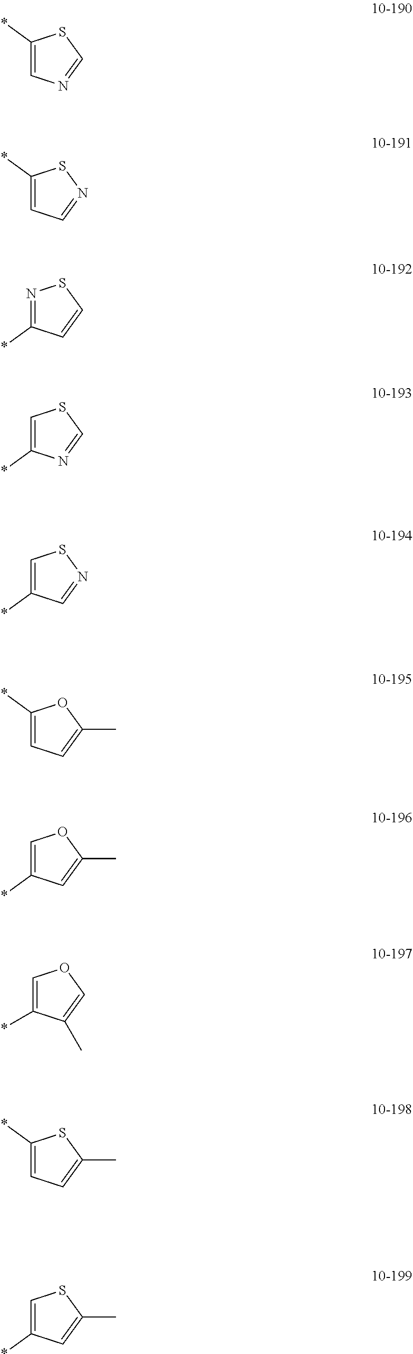

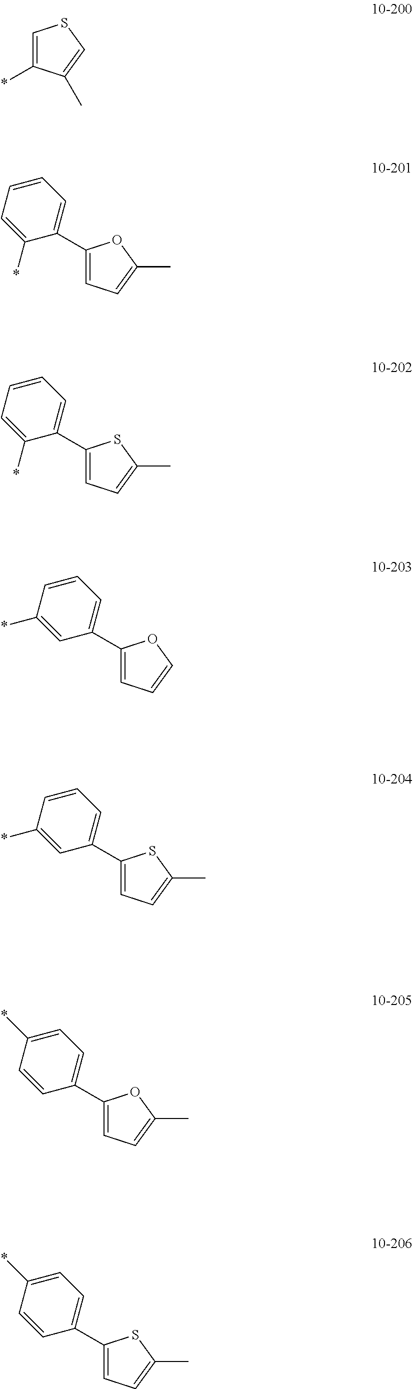

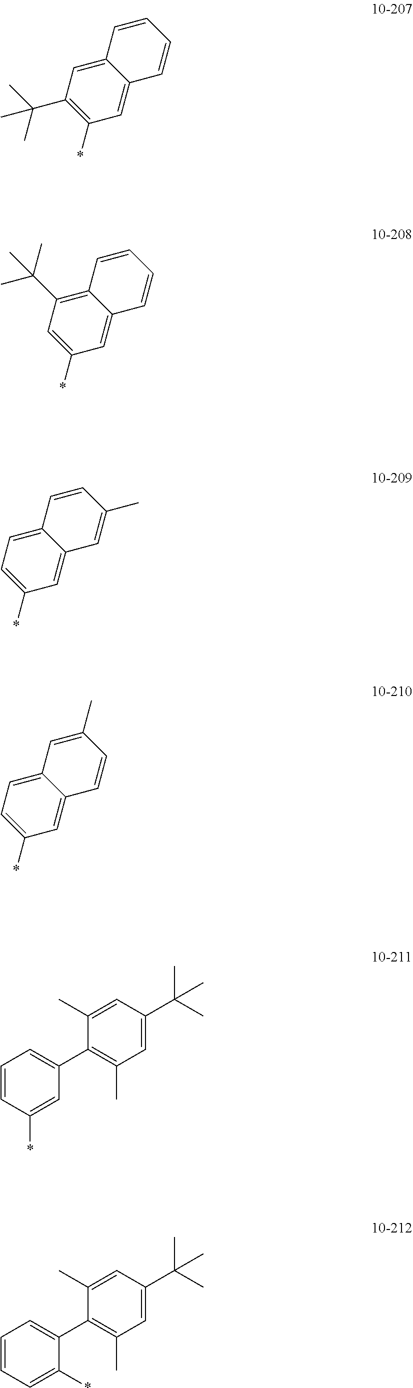

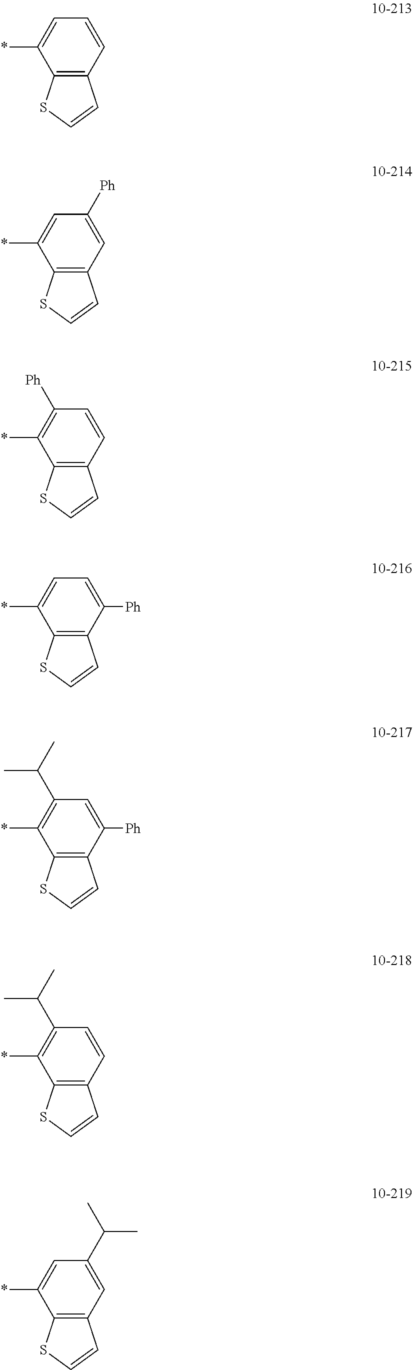

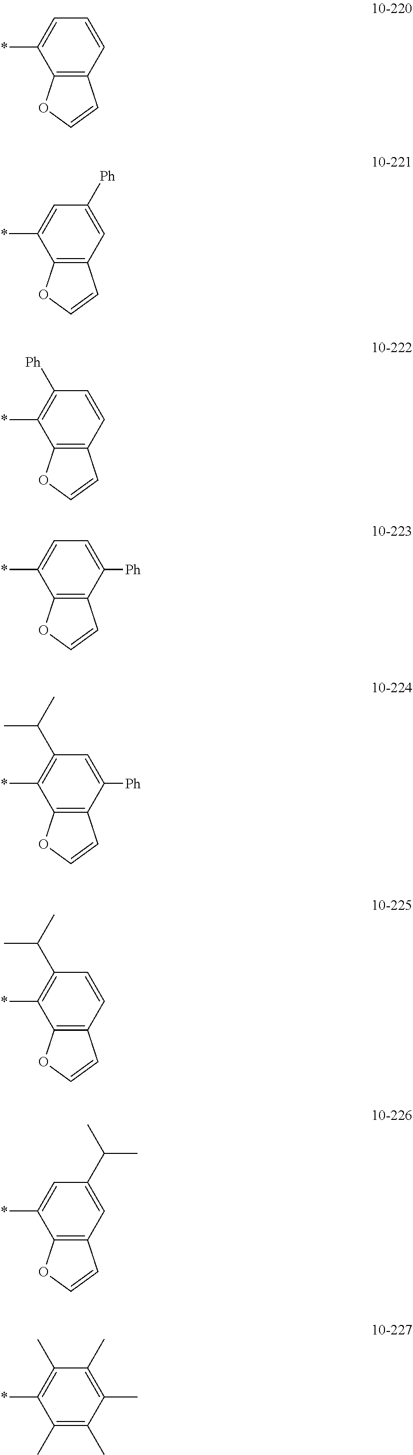

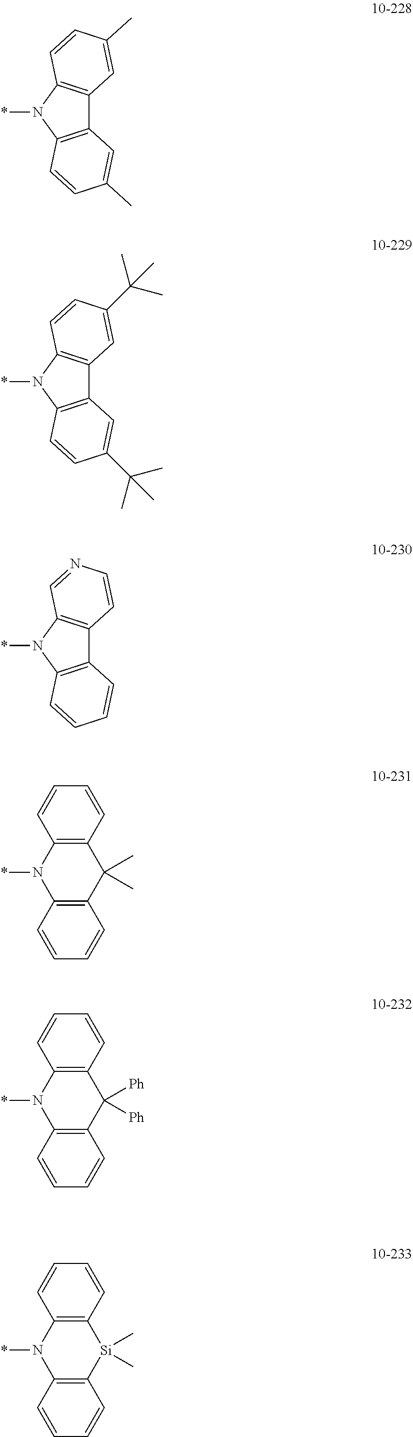

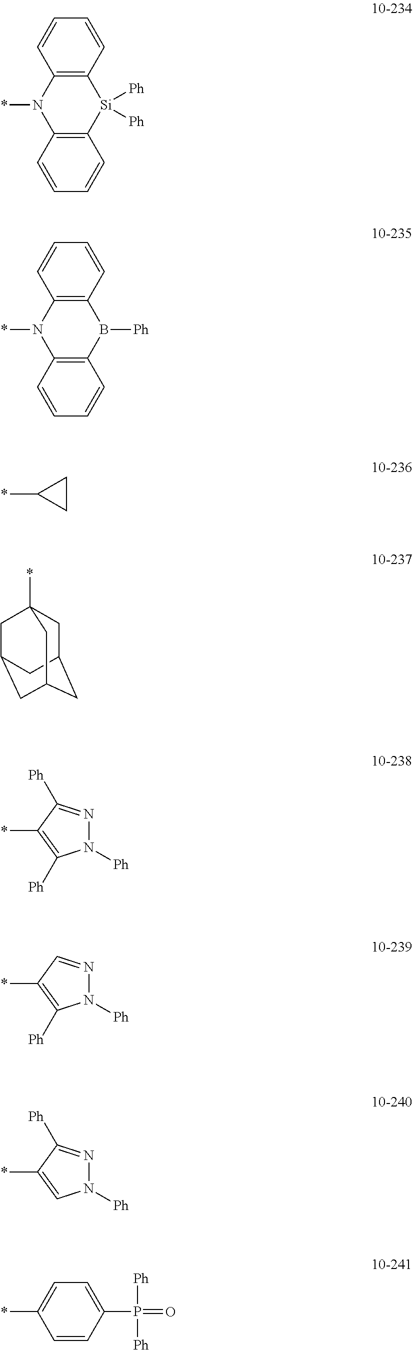

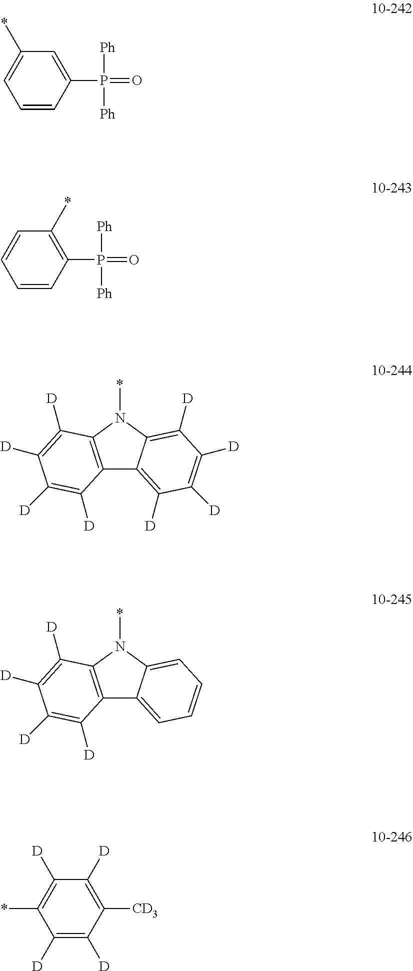

wherein, in Formulae 9-1 to 9-19 and 10-1 to 10-246, * indicates a binding site to an adjacent atom, “Ph” represents a phenyl group, and “TMS” represents a trimethylsilyl group.

In Formulae 3-1 to 3-5, 502, and 503, a71 to a74 and a501 to a504 may respectively indicate the number of R₇₁(s) to R₇₄(s) and R₅₀₁(s) to R₅₀₄(s), and a71 to a74 and a501 to a504 may each independently be an integer selected from 0 to 20. When a71 is 2 or greater, at least two R₇₁ (s) may be identical to or different from each other, when a72 is 2 or greater, at least two R₇₂(s) may be identical to or different from each other, when a73 is 2 or greater, at least two R₇₃(s) may be identical to or different from each other, when a74 is 2 or greater, at least two R₇₄(s) may be identical to or different from each other, when a501 is 2 or greater, at least two R₅₀₁(s) may be identical to or different from each other, when a502 is 2 or greater, at least two R₅₀₂(S) may be identical to or different from each other, when a503 is 2 or greater, at least two R₅₀₃(s) may be identical to or different from each other, and when a504 is 2 or greater, at least two R₅₀₄(s) may be identical to or different from each other. a71 to a74 and a501 to a504 may each independently be an integer selected from 0 to 8.

In Formula 1, i) two or more of R₁(s) in the number of al may optionally be bonded together to form a C₃-C₆₀ carbocyclic group unsubstituted or substituted with at least one R₁₀ₐ or a C₁-C₆₀ heterocyclic group unsubstituted or substituted with at least one R₁₀ₐ, ii) two or more of R₂(s) in the number of a2 may optionally be bonded together to form a C₃-C₆₀ carbocyclic group unsubstituted or substituted with at least one R₁₀ₐ or a C₁-C₆₀ heterocyclic group unsubstituted or substituted with at least one R₁₀ₐ, iii) two or more of R₃(s) in the number of a3 may optionally be bonded together to form a C₃-C₆₀ carbocyclic group unsubstituted or substituted with at least one R₁₀ₐ or a C₁-C₆₀ heterocyclic group unsubstituted or substituted with at least one R₁₀ₐ, iv) two or more of R₄(s) in the number of a4 may optionally be bonded together to form a C₃-C₆₀ carbocyclic group unsubstituted or substituted with at least one R₁₀ₐ or a C₁-C₆₀ heterocyclic group unsubstituted or substituted with at least one R₁₀ₐ, and v) two or more of R₁ to R₄, R₅₁ₐ, R_{51b}, R₅₂ₐ, and R_{52b} may optionally bonded together to form a C₃-C₆₀ carbocyclic group unsubstituted or substituted with at least one R₁₀ₐ or a C₁-C₆₀ heterocyclic group unsubstituted or substituted with at least one R₁₀ₐ.

In an embodiment, a group represented by *—(L₅₁)_{b51}-R₅₁ and a group represented by *—(L₅₂)_{b52}-R₅₂ in Formula 2 may each not be a phenyl group.

In an embodiment, a group represented by *—(L₅₁)_{b51}-R₅₁ and a group represented by *—(L₅₂)_{b52}-R₅₂ in Formula 2 may be identical to each other.

In an embodiment, a group represented by *—(L₅₁)_{b51}-R₅₁ and a group represented by *—(L₅₂)_{b52}-R₅₂ in Formula 2 may be different from each other.

In an embodiment, b51 and b52 in Formula 2 may each be 1, 2, or 3, and L₅₁ and L₅₂ may each independently be a benzene group, a pyridine group, a pyrimidine group, a pyridazine group, a pyrazine group, or a triazine group, each unsubstituted or substituted with at least one Rioa.

In an embodiment, R₅₁ and R₅₂ in Formula 2 may each independently be a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —C(Q₁)(Q₂)(Q₃), or —Si(Q₁)(Q₂)(Q₃), and

wherein Q₁ to Q₃ may each independently be a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

In an embodiment,

a group represented by *—(L₅₁)_{b5}-R₅₁ in Formula 2 may be a group represented by one selected from Formulae CY51-1 to CY51-26, and/or

a group represented by *—(L₅₂)_{b52}-R₅₂ in Formula 2 may be a group represented by one selected from Formulae CY52-1 to CY52-26, and/or

a group represented by *—(L₅₃)_{b53}-R₅₃ in Formula 2 may be a group represented by one selected from Formulae CY53-1 to CY53-27, —C(Q₁)(Q₂)(Q₃), or —SI(Q₁)(Q₂)(Q₃):

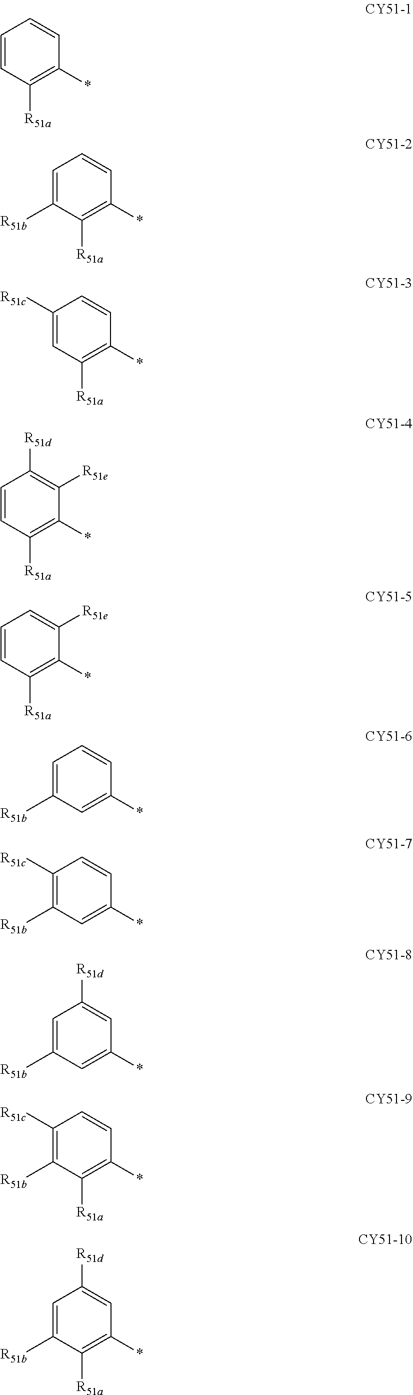

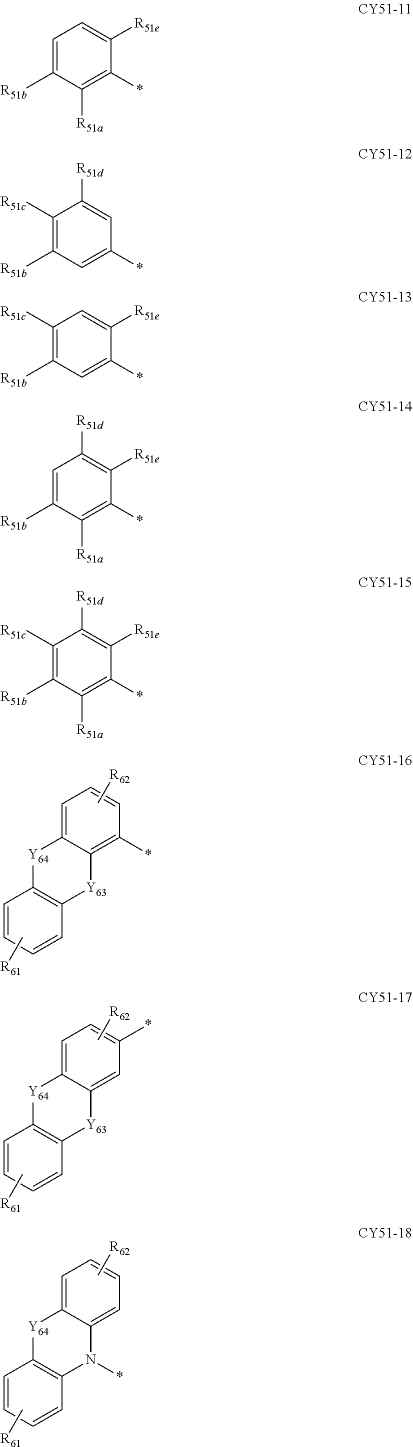

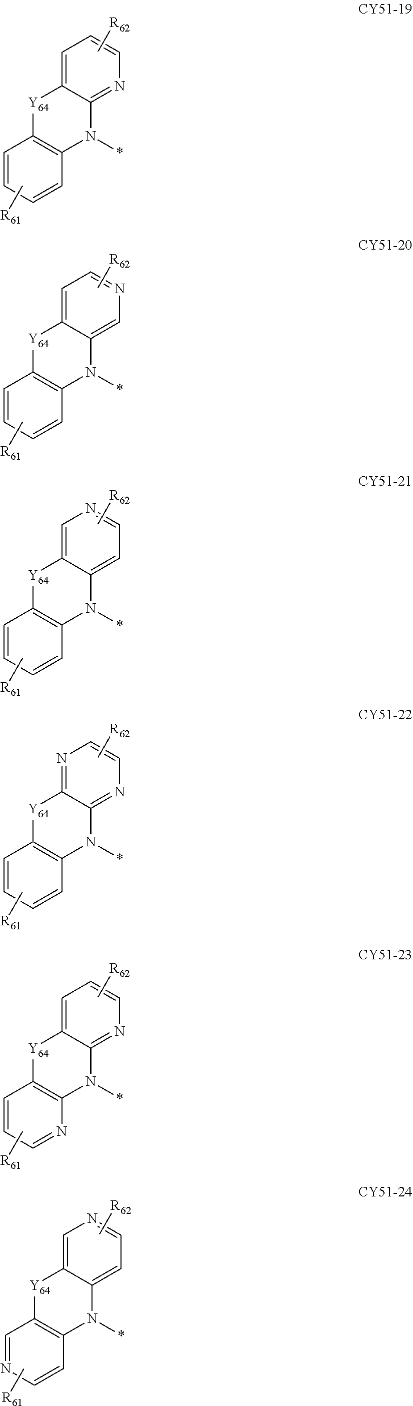

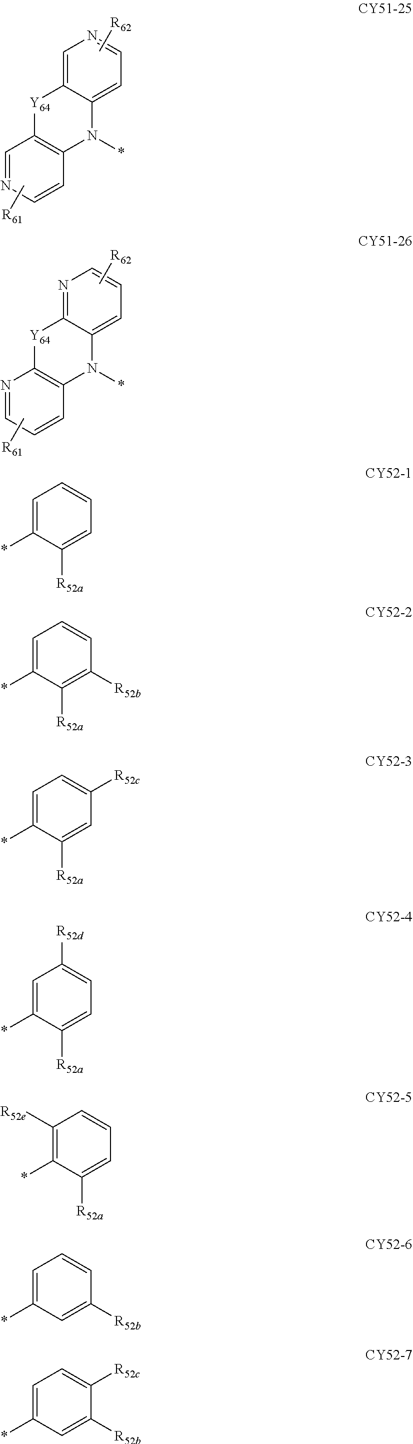

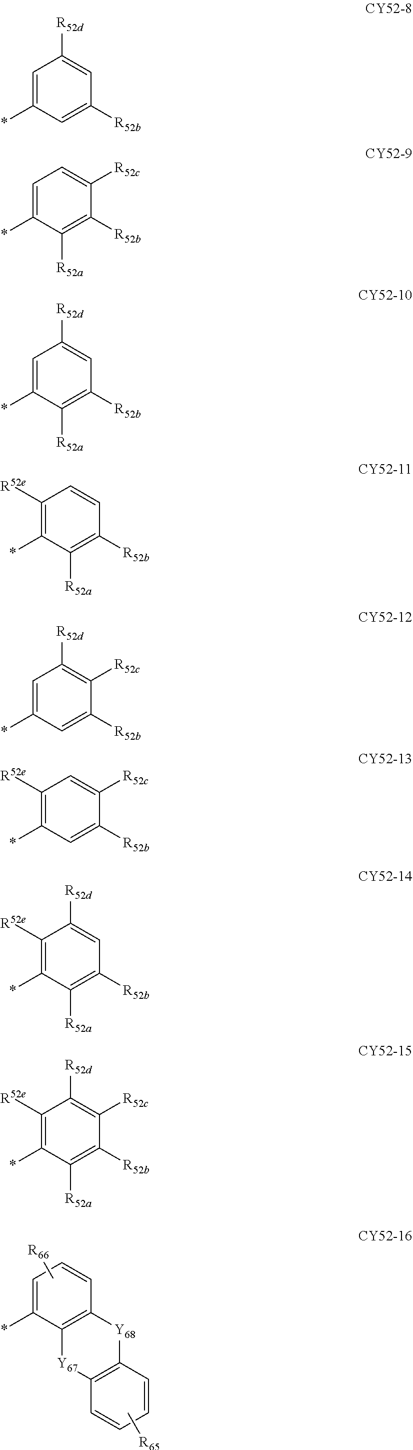

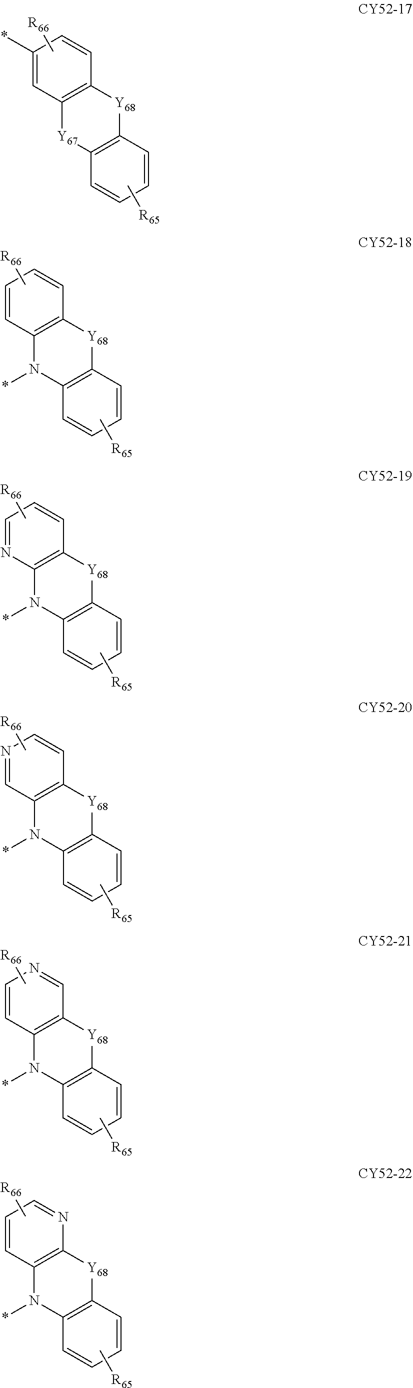

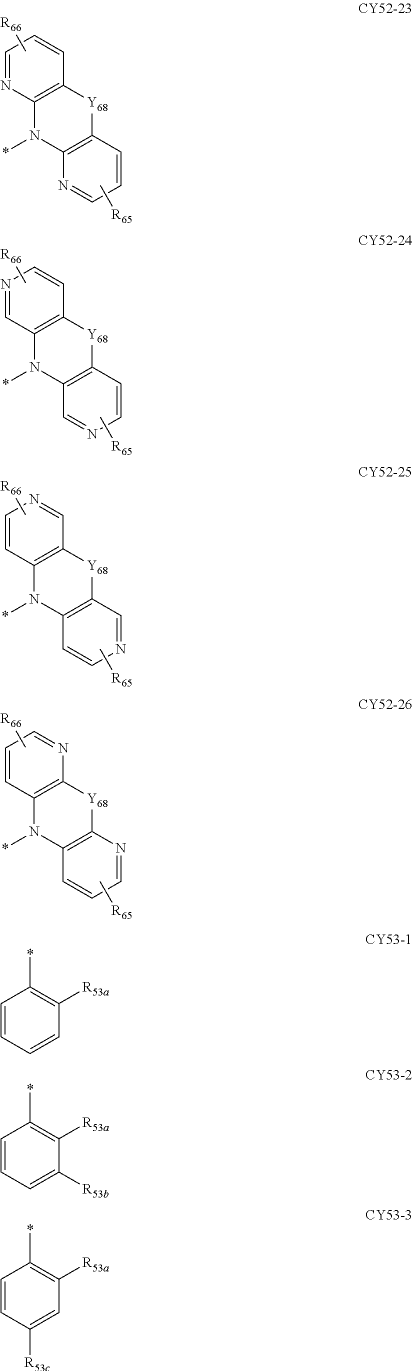

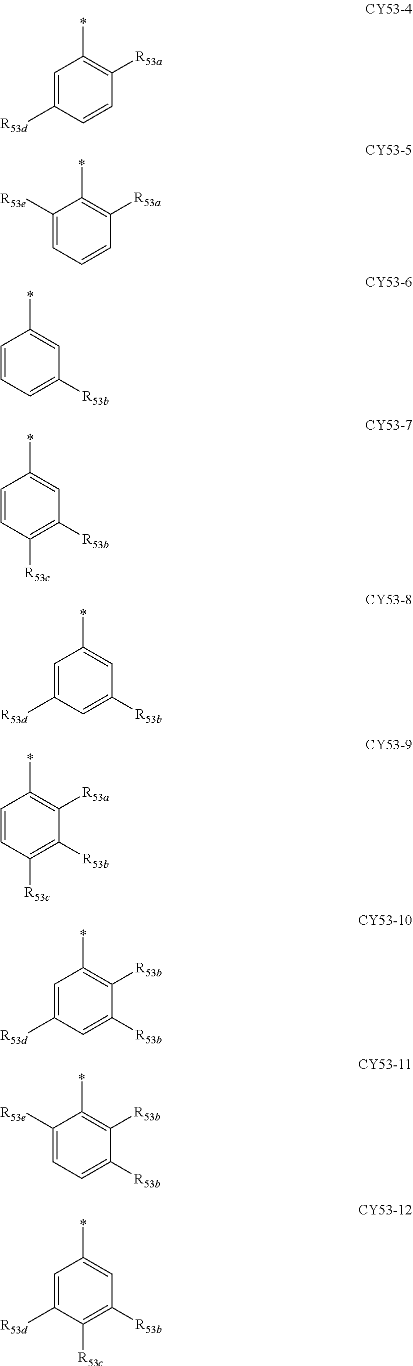

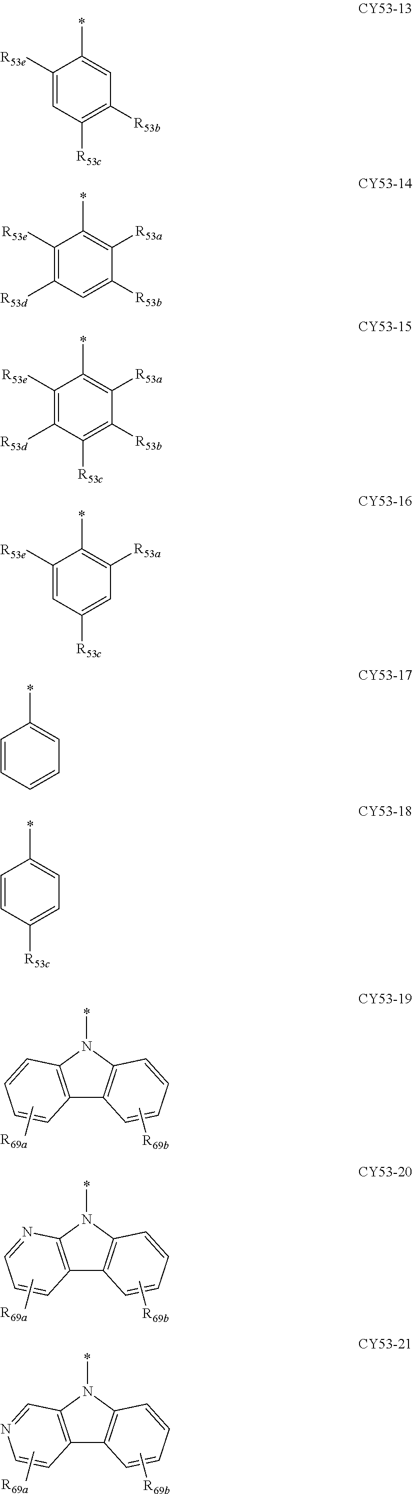

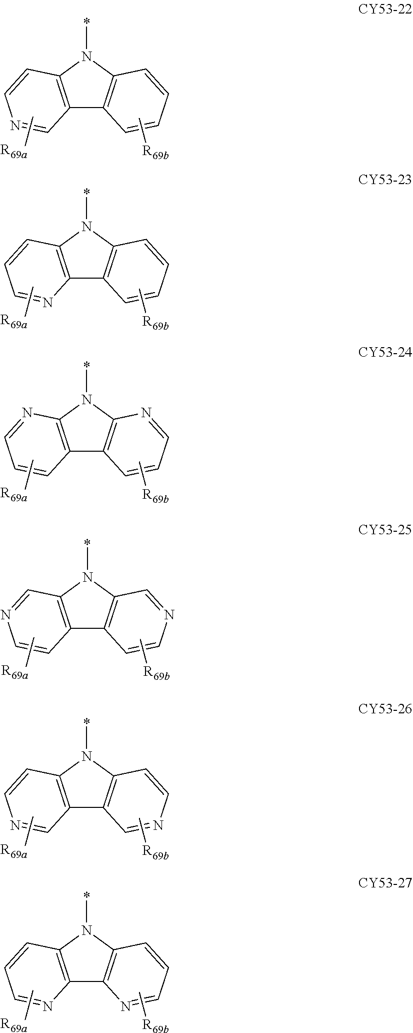

wherein, in Formulae CY51-1 to CY51-26, CY52-1 to CY52-26, and CY53-1 to CY53-27,

Y₆₃ may be a single bond, O, S, N(R₆₃), B(R₆₃), C(R₆₃ₐ)(R_{63b}), or Si (R₆₃ₐ) (R_{63b}),

Y₆₄ may be a single bond, O, S, N(R₆₄), B(R₆₄), C(R₆₄ₐ)(R_{64b}), or Si(R₆₄ₐ)(R_{64b}),

Y₆₇ may be a single bond, O, S, N(R₆₇), B(R₆₇), C(R₆₇ₐ)(R_{67b}), or Si(R₆₇ₐ)(R_{67b}),

Y₆₈ may be a single bond, O, S, N(R₆₈), B(R₆₈), C(R₆₈ₐ)(R_{68b}), or Si(R₆₈ₐ)(R_{68b}),

Y₆₃ and Y₆₄ in Formulae CY51-16 and CY51-17 may each not be a single bond,

Y₆₇ and Y₆₈ in Formulae CY52-16 and CY52-17 may each not be a single bond,

R₅₁ₐ to R₅₁ₑ, R₆₁ to R₆₄, R₆₃ₐ, R_{63b}, R₆₄ₐ, and R_{64b} are respectively the same as described in connection with R₅₁ in the present specification, and R₅₁ₐ to R₅₁ₑ may each not be hydrogen,

R₅₂ₐ to R₅₂ₑ, R₆₅ to R₆₈, R₆₇ₐ, R_{67b}, R₆₈ₐ, and R_{68b} are respectively the same as described in connection with R₅₂ in the present specification, and R₅₂ₐ to R₅₂ₑ may each not be hydrogen,

R₅₃ₐ to R₅₃ₑ , R₆₉ₐ, and R_{69b} are respectively the same as described in connection with R₅₃ in the present specification, and R₅₃ₐ to R₅₃ₑ may each not be hydrogen, and

* indicates a binding site to a neighboring atom.

In an embodiment,

R₅₁ₐ to R₅₁ₑ and R₅₂ₐ to R₅₂ₑ in Formulae CY51-1 to CY51-26 and Formulae CY52-1 to CY52-26 may each independently be:

a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl

group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, a isoxazolyl group, a pyridinyl group, a ppyrazinyl group, a biphenyl group, a C₁-C₁₀ alkylphenyl group, a naphthyl group, a fluorenyl group, a phenanthrenyl group, a anthracenyl group, a fluoranthenyl group, a triphenylenyl pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, a azadibenzothiophenyl group, an azafluorenyl group, an azadibenzosilolyl group, or a group represented by formula 91, each unsubstituted or substituted with deaterium, —F, —CI, —Br, —I, —CD₃, —CD₂H, —CDH₂, —CF₃, —CF₂H, —CFH₂, a hydroxyl group, a cyano group, a nitro group, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a phyrenyl group, a chrysenyl group, a pyrrolyl group, a thiophenyl group, a furanyl group, a imidazolyl group, a pyrazolyl group, a thiazolyl group, an isothiazolyl group, an oxazolyl group, an isozazolyl group, a pyridinyl group, a pyrazinyl group, a pyrimidinyl, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzoimidazolyl group, a benzofuranyl group, a benzothiophenyl group, a benzoisothiazolyl group, a benzoxazolyl group, a benzoisoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, or any combination thereof; or

—C(Q₁)(Q₂)(Q₃) or —Si(Q₁)(Q₂)(Q₃),

Q₁ to Q₃ may each independently be a phenyl group, a naphthyl group, a pyridinyl group, a pyrimidinyl group, a pyridazinyl group, a pyrazinyl group, or a triazinyl group, each unsubstituted or substituted with deuterium, a C₁-C₁₀ alkyl group, a phenyl group, a biphenyl group, a pyridinyl group, a pyrimidinyl group, a pyridazinyl group, a pyrazinyl group, a triazinyl group, or any combination thereof,

in Formulae CY51-16 and CY51-17, i) Y₆₃ may be O or S and Y₆₄ may be Si(R₆₄ₐ)(R_{64b}), or ii) Y₆₃ may be Si(R₆₃ₐ)(R_{63b}) and Y₆₄ may be O or S, and

in Formulae CY52-16 and CY52-17, i) Y₆₇ may be O or S, and Y₆₈ may be Si(R₆₈ₐ)(R_{68b}), or ii) Y₆₇ may be Si(R₆₇ₐ)(R_{67b}), and Y₆₈ may be O or S.

In an embodiment, L₈₁ to L₈₅ in Formulae 3-1 to 3-5 may each independently be:

a single bond; or

*—C(Q₄)(Q₅)—*′ or *—Si(Q₄)(Q₅)—*′; or

a benzene group, a naphthalene group, an anthracene group, a phenanthrene group, a triphenylene group, a pyrene group, a chrysene group, a cyclopentadiene group, a furan group, a thiophene group, a silole group, an indene group, a fluorene group, an indole group, a carbazole group, a benzofuran group, a dibenzofuran group, a benzothiophene group, a dibenzothiophene group, a benzosilole group, a dibenzosilole group, an azafluorene group, an azacarbazole group, an azadibenzofuran group, an azadibenzothiophene group, an azadibenzosilole group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzoxazole group, a benzothiazole group, a benzoxadiazole group, or a benzothiadiazole group, each unsubstituted or substituted with deuterium, —F, —CI, —Br, —I, a hydroxyl group, a cyano group, a nitro group, a C₁-C₂₀ alkyl group, a C₁-C₂₀ alkoxy group, a phenyl group, a naphthyl group, a pyridinyl group, a pyrimidinyl group, a triazinyl group, a fluorenyl group, a dimethylfluorenyl group, a diphenylfluorenyl group, a carbazolyl group, a phenylcarbazolyl group, a dibenzofuranyl group, a dibenzothiophenyl group, a dibenzosilolyl group, a dimethyldibenzosilolyl group, a diphenyldibenzosilolyl group, —O(Q₃₁), —S(Q₃₁), —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), —P(═O)(Q₃₁)(Q₃₂), or any combination thereof,

wherein Q₄, Q₅, and Q₃₁ to Q₃₃ may each independently be hydrogen, deuterium, a C₁-C₂₀ alkyl group, a C₁-C₂₀ alkoxy group, a phenyl group, a biphenyl group, a terphenyl group, a pyridinyl group, a pyrimidinyl group, a pyridazinyl group, a pyrazinyl group, or a triazinyl group.

In an embodiment, a group represented by

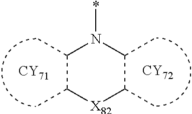

in Formulae 3-1 and 3-2 may be a group represented by one selected from Formulae CY71-1(1) to CY71-1 (8),

a group represented by

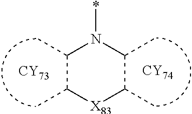

in Formulae 3-1 and 3-3 may be a group represented by one selected from Formulae CY71-2(1) to CY71-2(8),

a group represented by

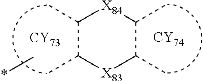

in Formulae 3-2 and 3-4 may be a group represented by one selected from Formulae CY71-3(1) to CY71-3(32),

a group represented by

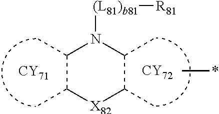

in Formulae 3-3 to 3-5 may be a group represented by one selected from Formulae CY71-4(1) to CY71-4(32), and/or

a group represented by

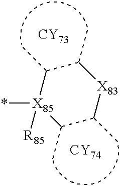

in Formula 3-5 may be a group represented by one selected from Formulae CY71-5(1) to CY71-5(8):

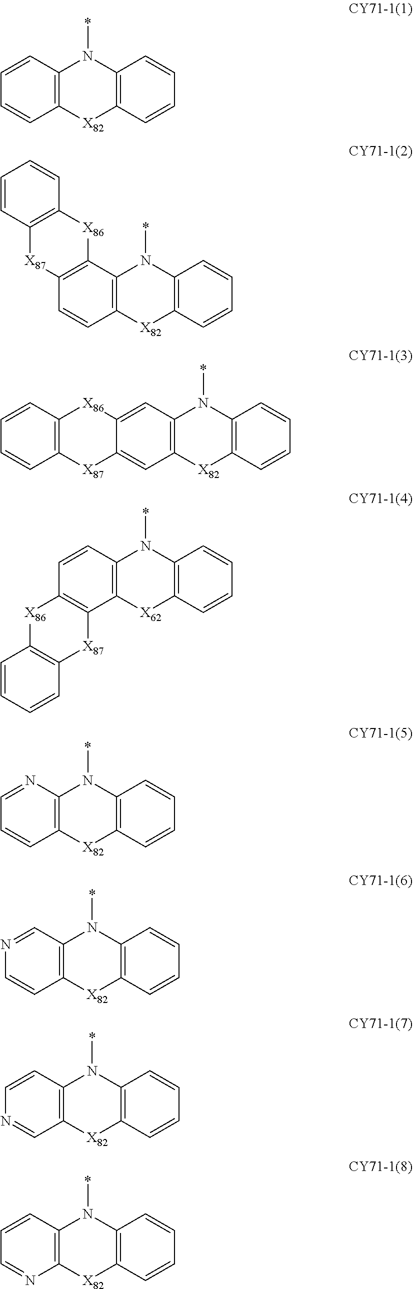

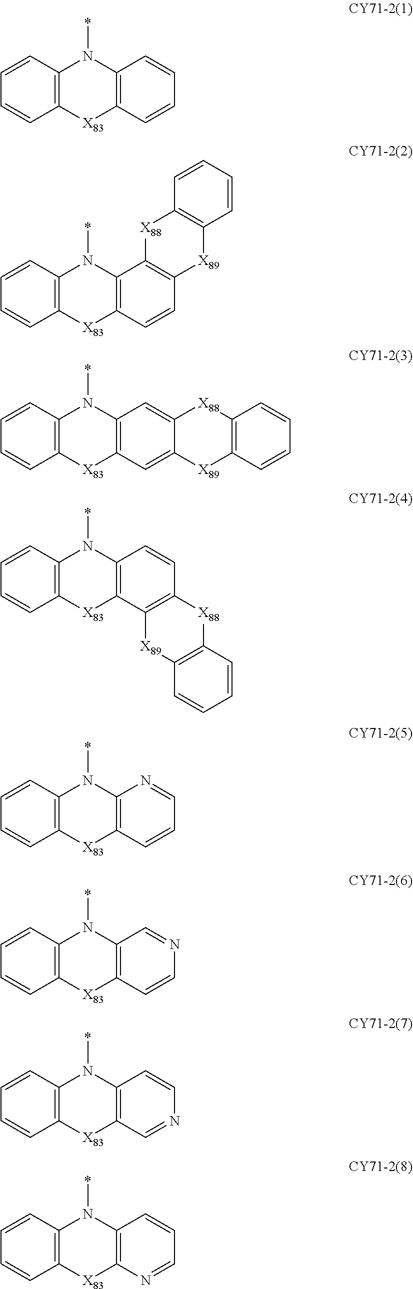

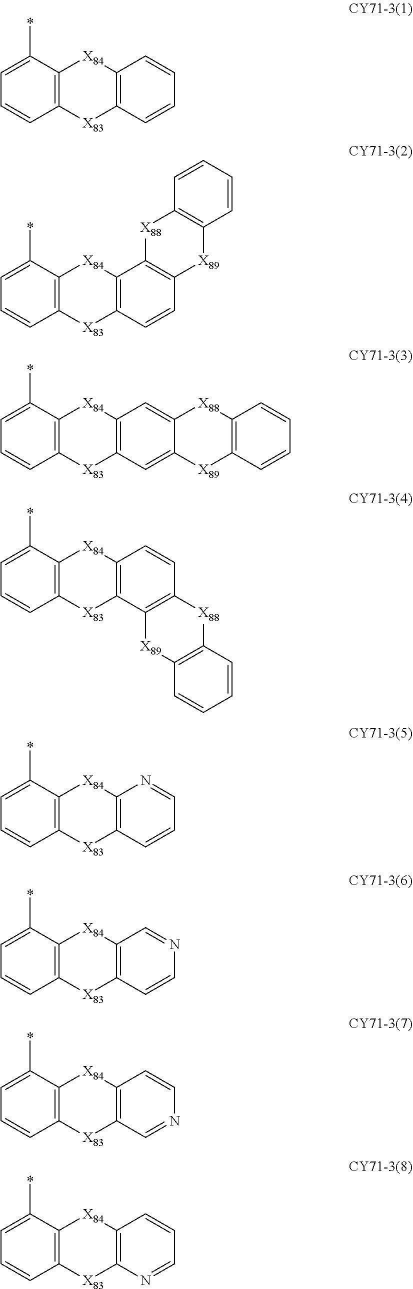

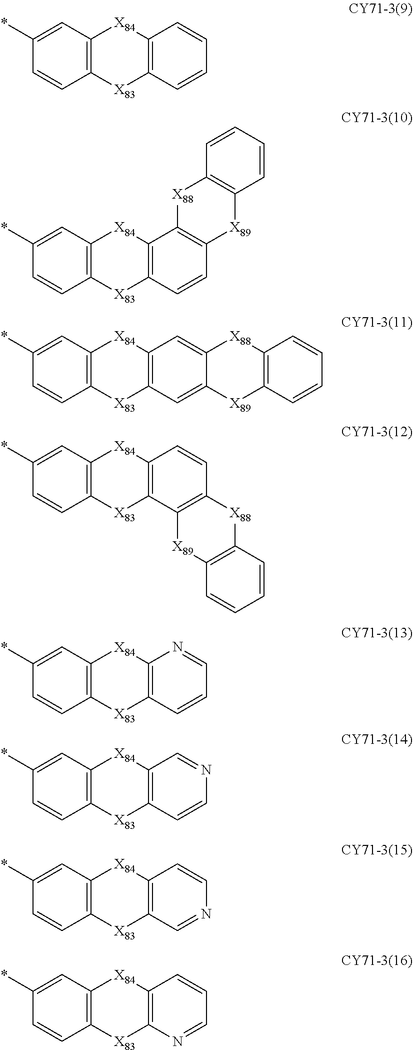

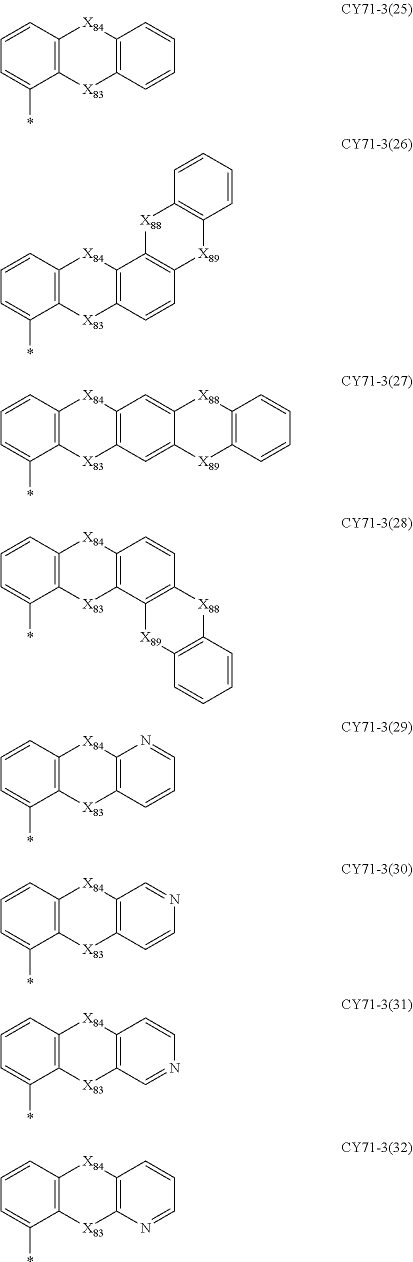

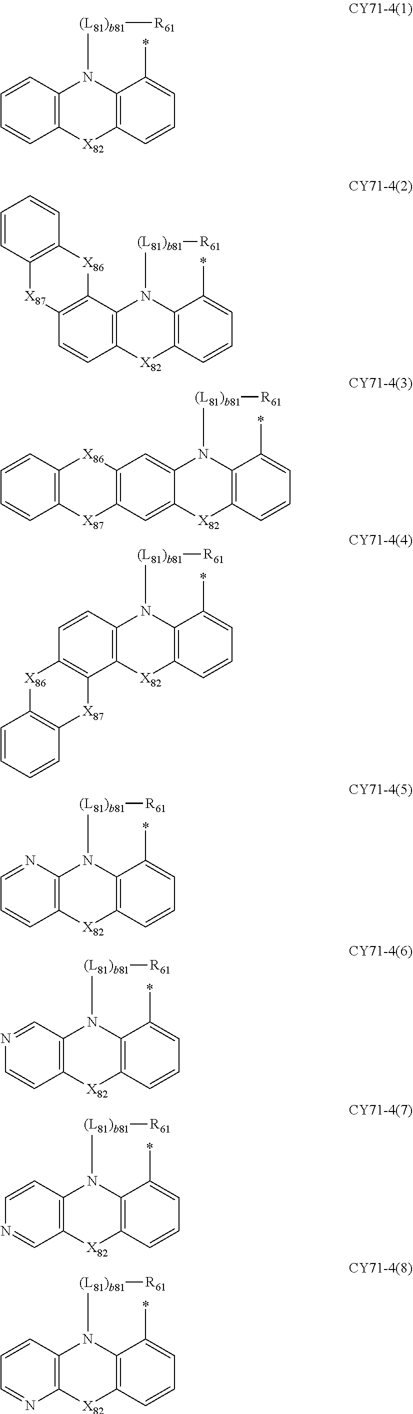

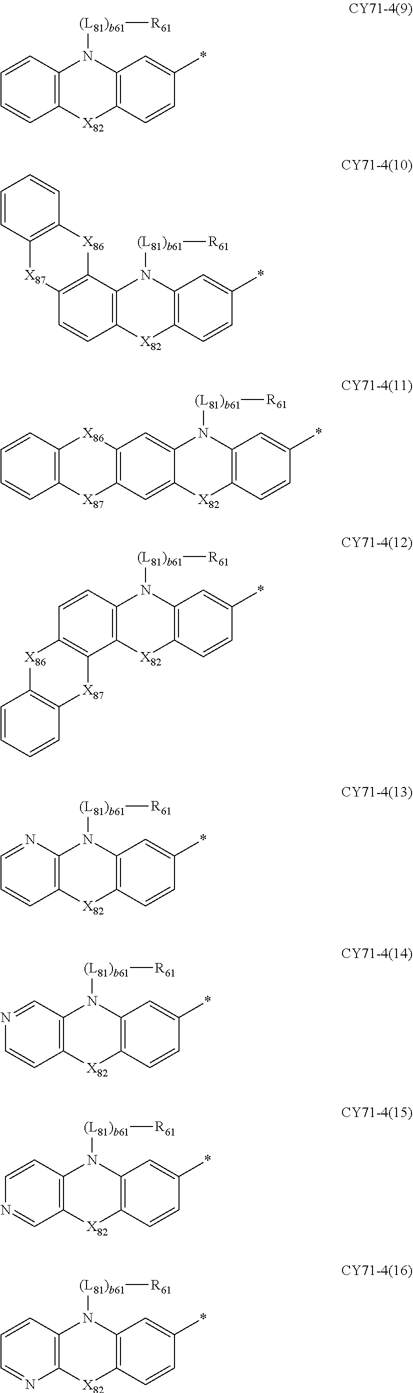

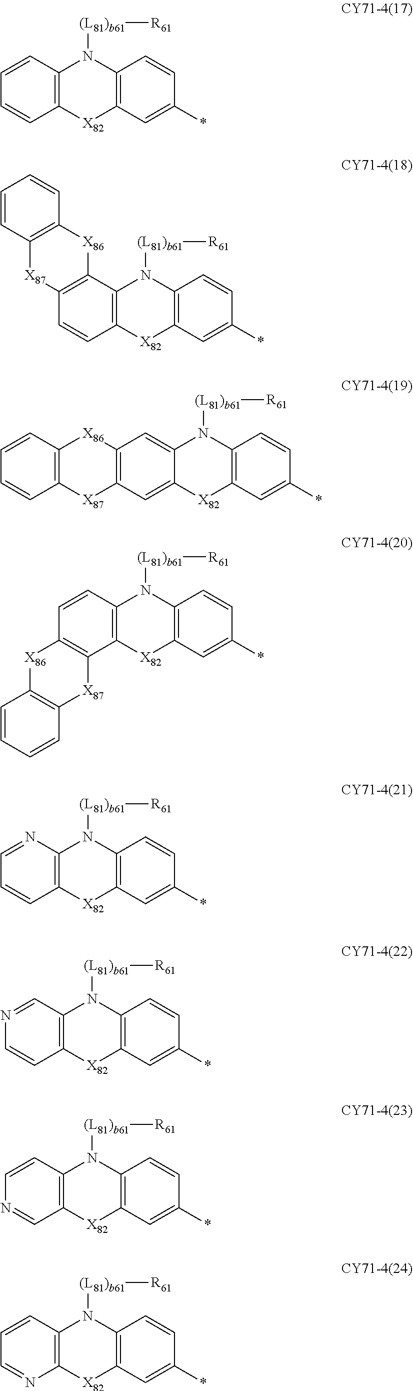

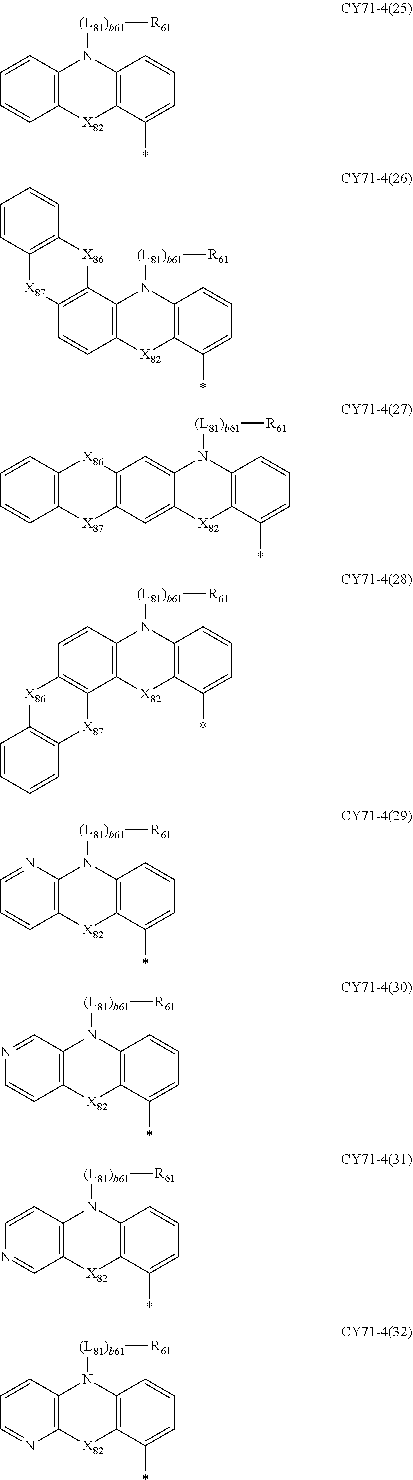

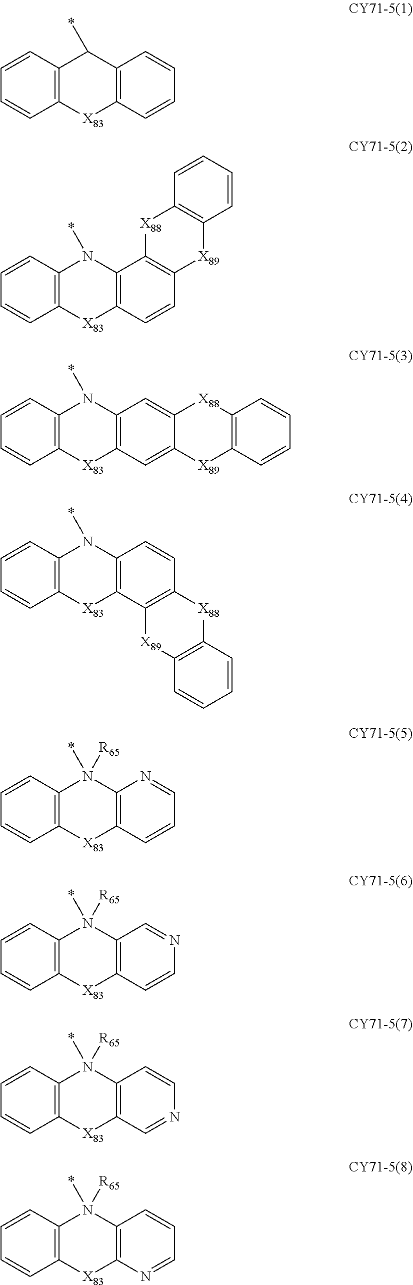

wherein, in Formulae CY71-1(1) to CY71-1 (8), CY71-2(1) to CY71-2(8), CY71-3(1) to CY71-3(32), CY71-4(1) to CY71-4(32), and CY71-5(1) to CY71-5(8),

X₈₂ to X₈₅, L₈₁, b81, R₈₁, and R₈₅ may respectively be the same as described in the present specification,

X₈₆ may be a single bond, O, S, N(R₈₆), B(R₈₆), C(R₈₆ₐ)(R_{86b}), or Si(R₈₆ₐ)(R_{86b}),

X₈₇ may be a single bond, O, S, N(R₈₇), B(R₈₇), C(R₈₇ₐ)(R_{87b}), or Si(R₈₇ₐ)(R_{87b}),

in Formulae CY71-1(1) to CY71-1(8) and CY71-4(1) to CY71-4(32), X₈₆ and X₈₇ may not be a single bond, simultaneously,

X₈₈ may be a single bond, O, S, N(R₈₈), B(R₈₈), C(R₈₈ₐ)(R_{88b}), or Si(R₈₈ₐ)(R_{88b}),

X₈₉ may be a single bond, O, S, N(R₈₉), B(R₈₉), C(R₈₉ₐ)(R_{89b}), or Si(R₈₉ₐ)(R_{89b}),

in Formulae CY71-2(1) to CY71-2(8), CY71-3(1) to CY71-3(32), and CY71-5(1) to CY71-5(8), X₈₈ and X₈₉ may not be a single bond, simultaneously, and

R₈₆ to R₈₉, R₈₆ₐ, R_{86b}, R₈₇ₐ, R_{87b}, R₈₈ₐ, R_{88b}, R₈₉ₐa, and R_{89b} may respectively the same as described in connection with R₈₁ in the present specification.

### Examples of Compounds

In an embodiment, the organometallic compound represented by Formula 1 may be one selected from Compounds BD01 to BD334 below:

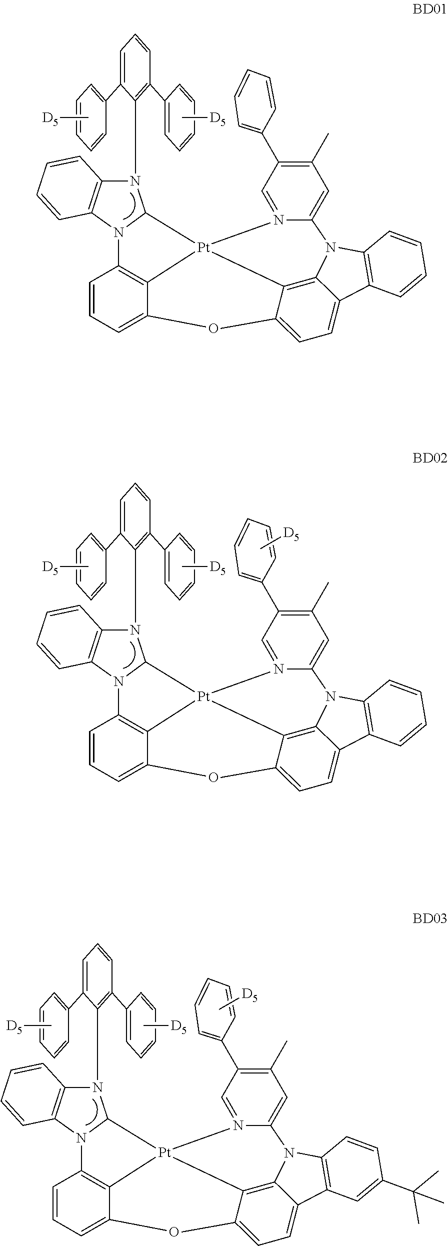

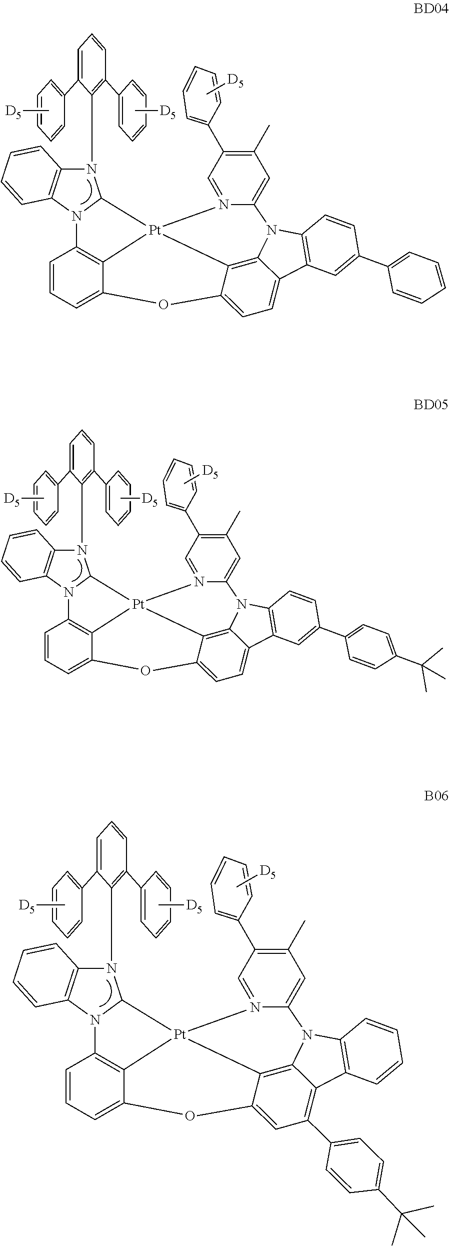

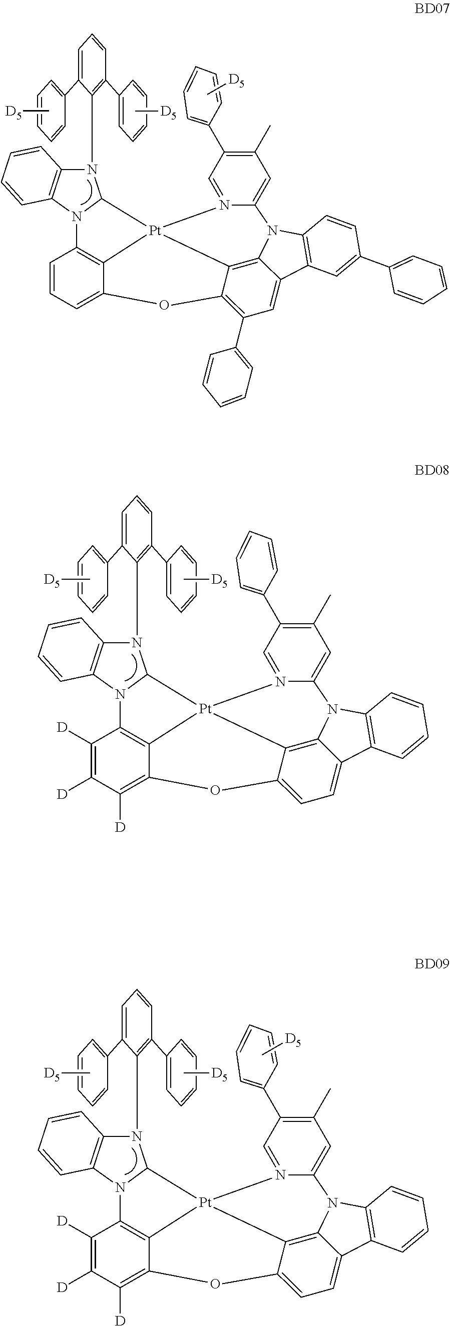

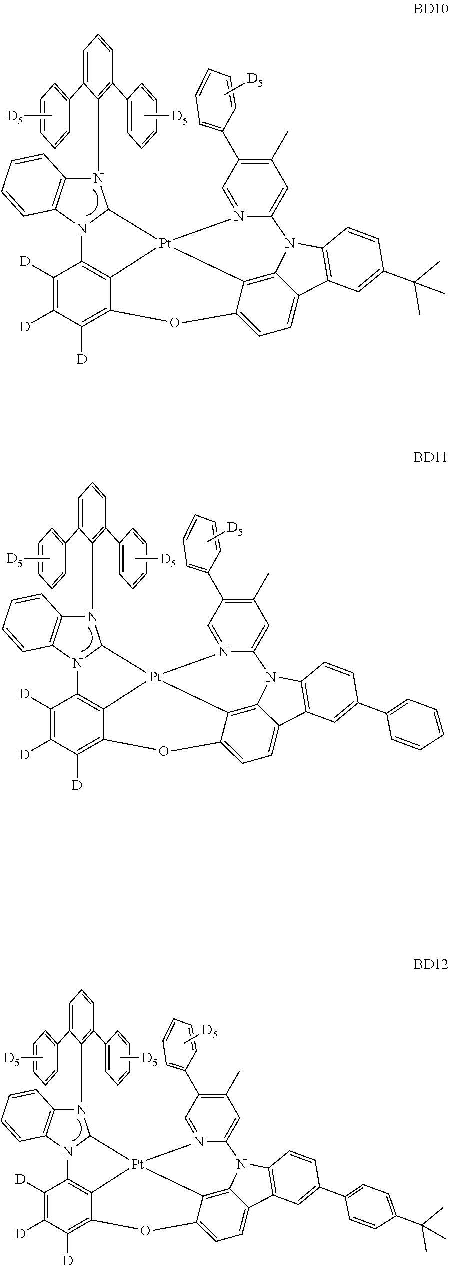

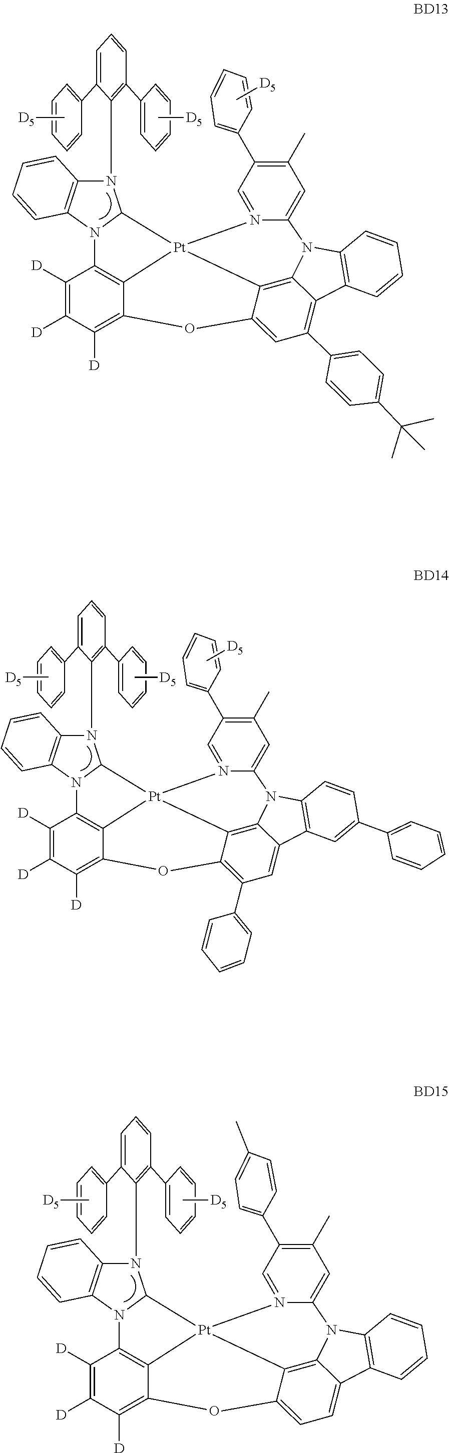

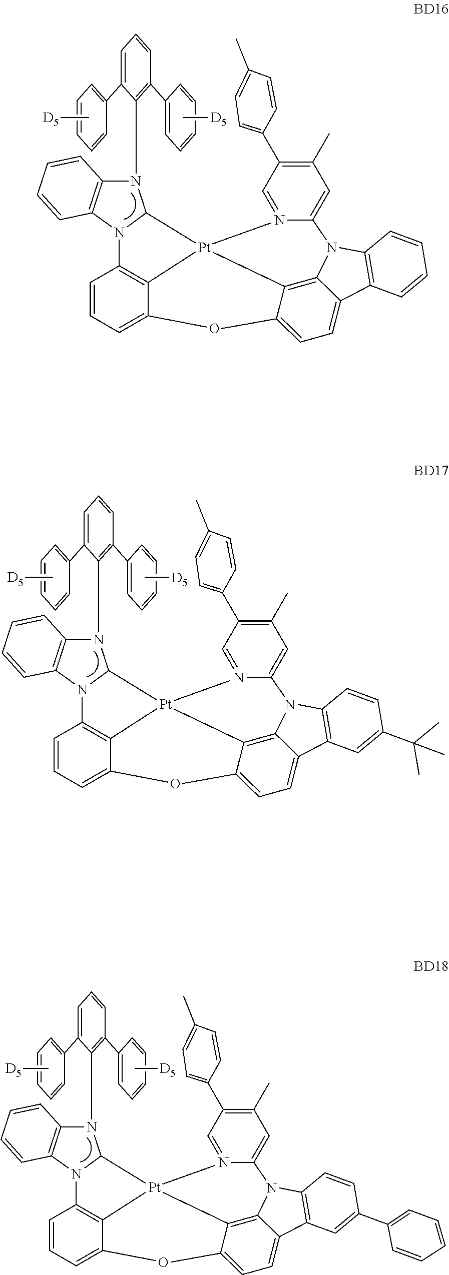

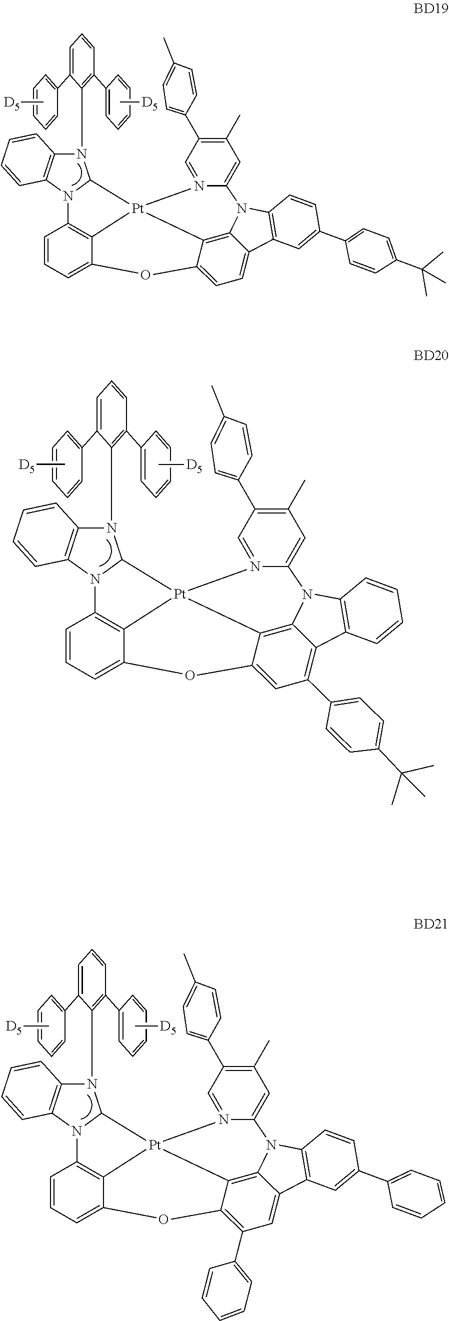

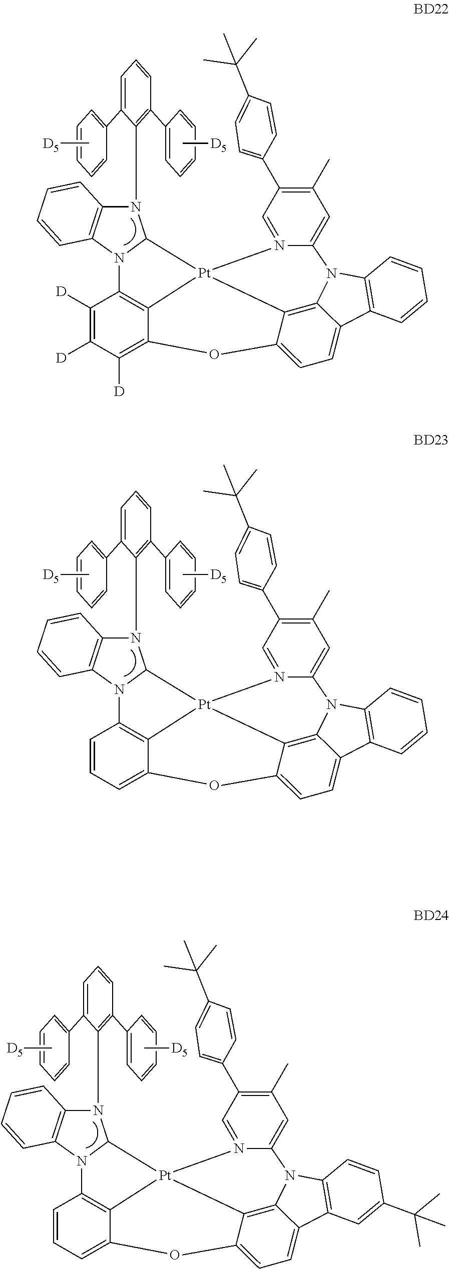

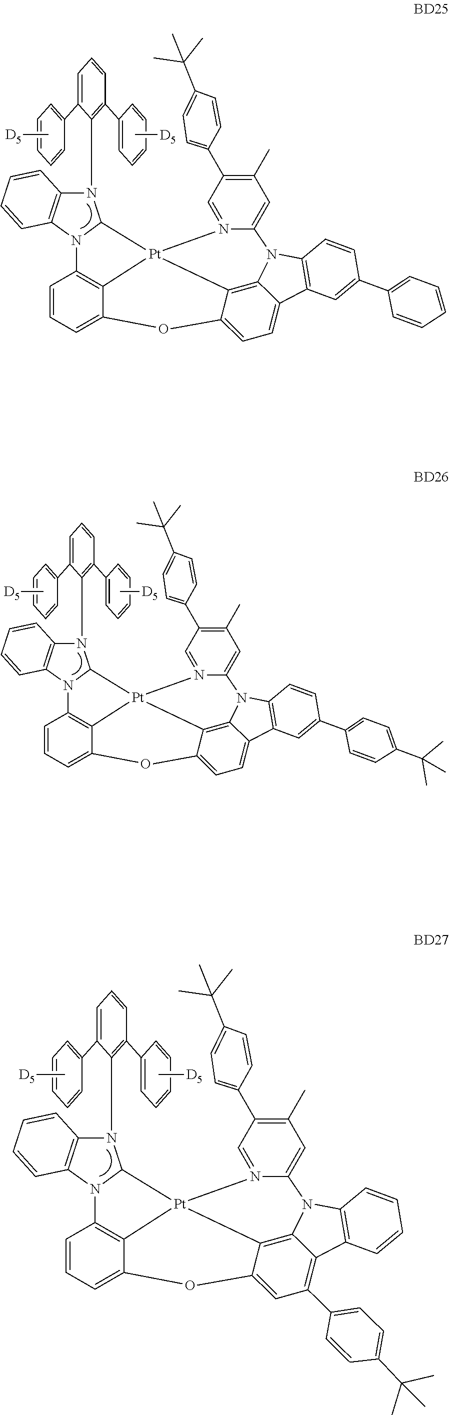

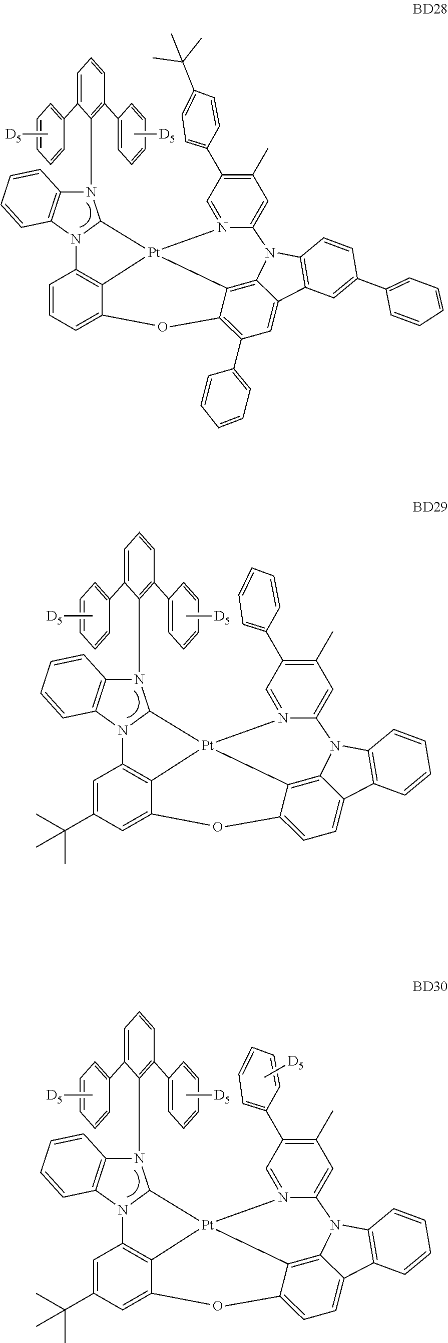

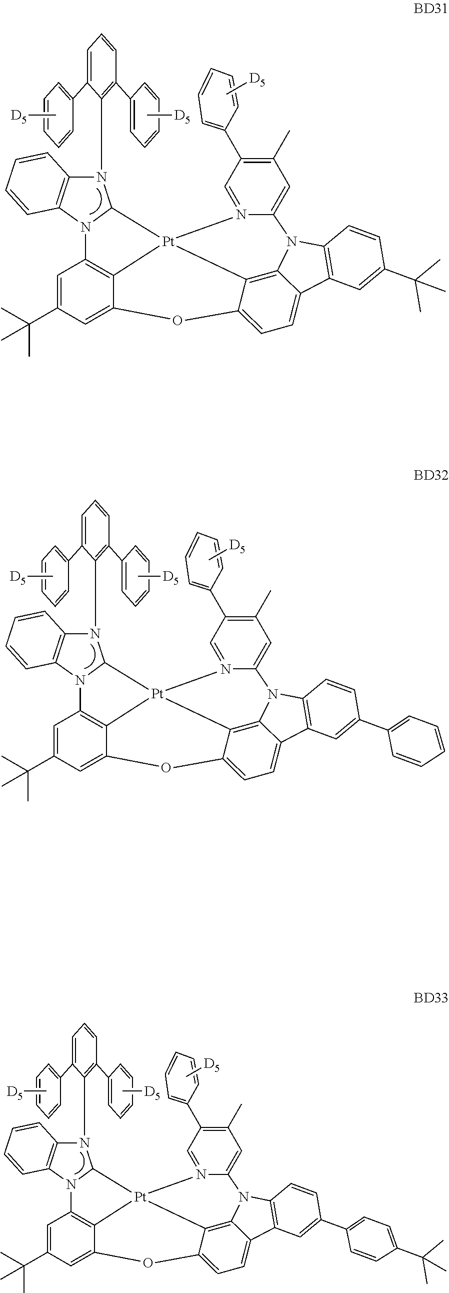

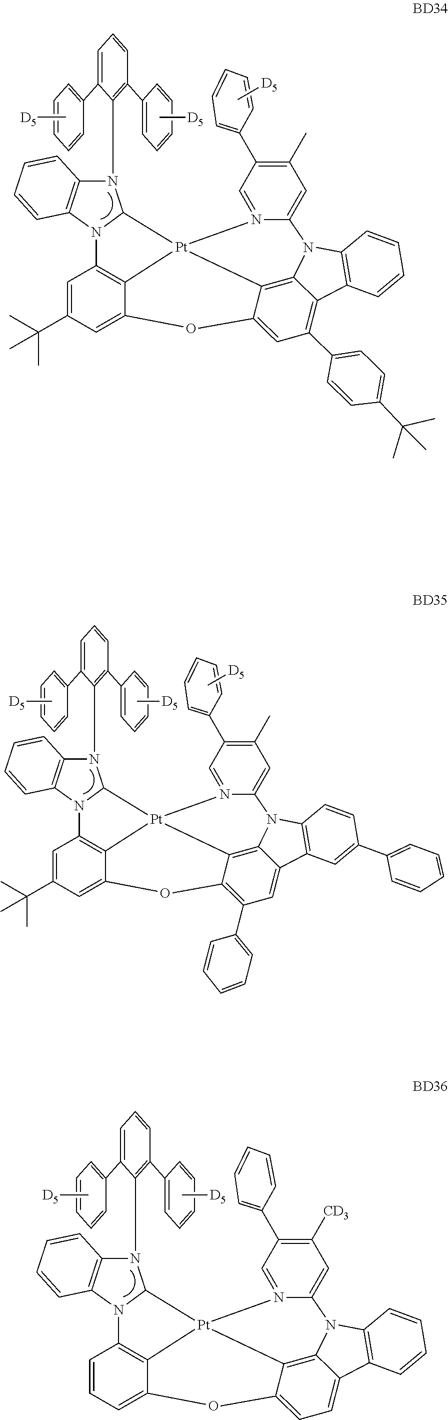

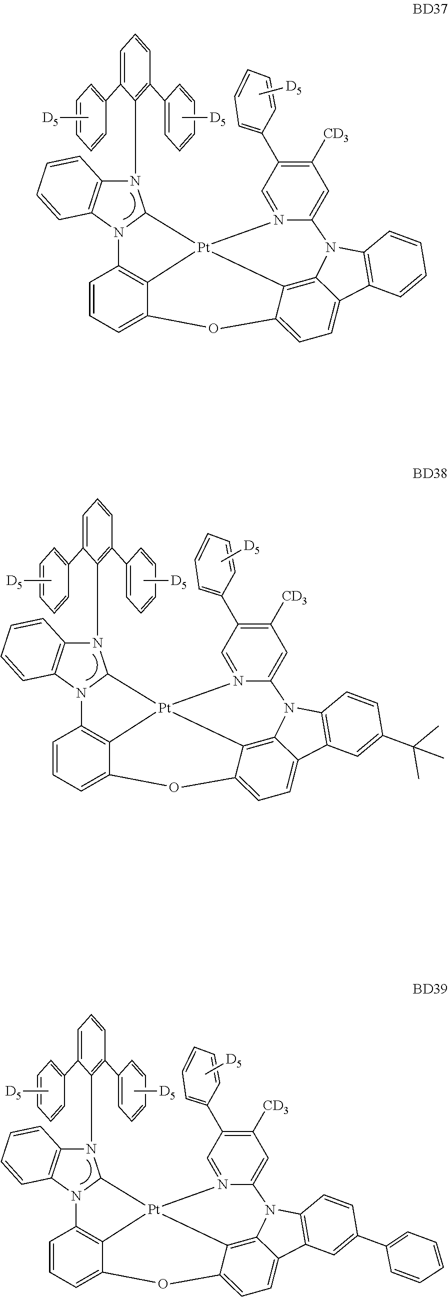

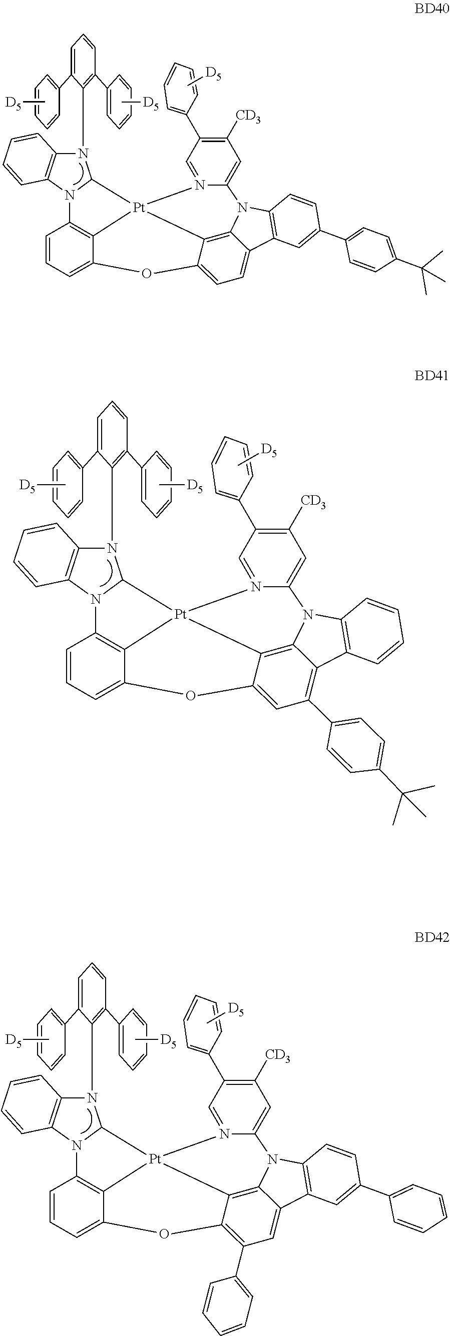

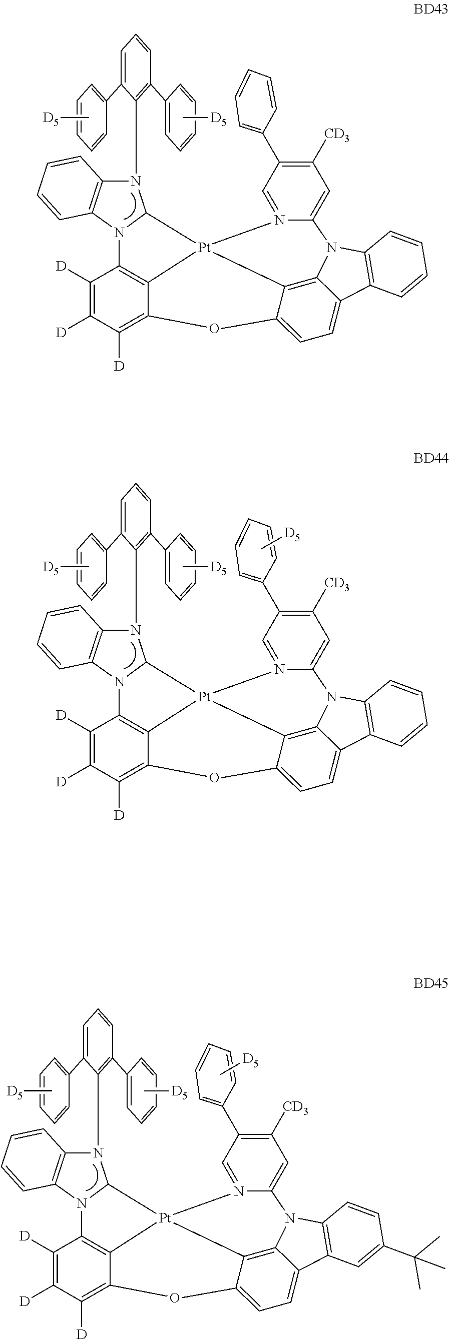

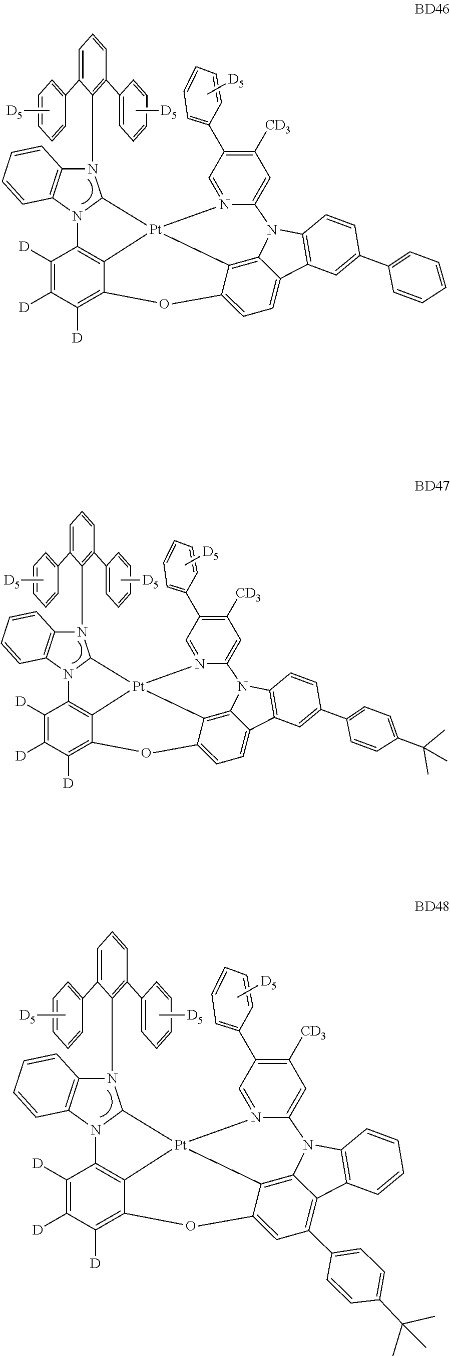

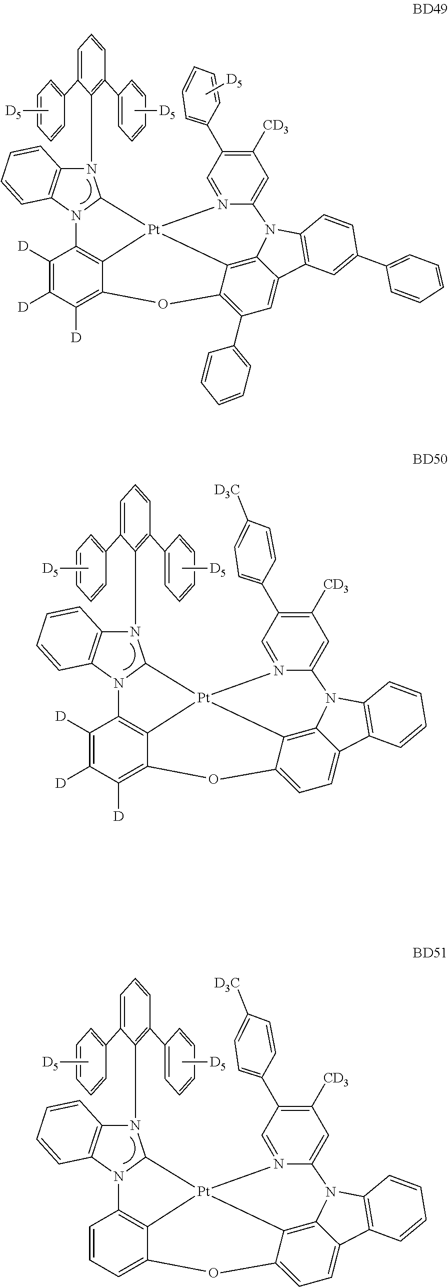

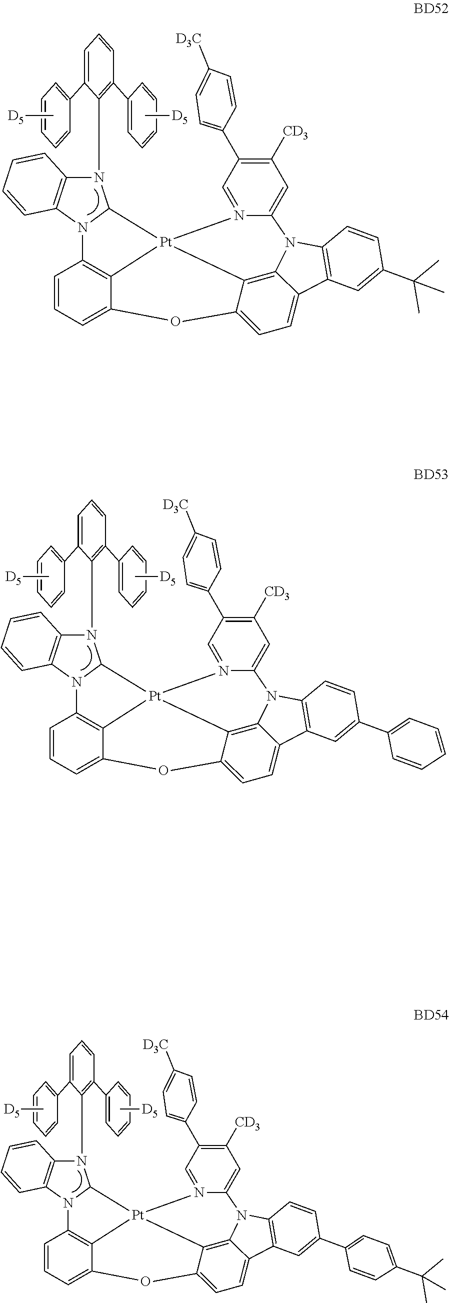

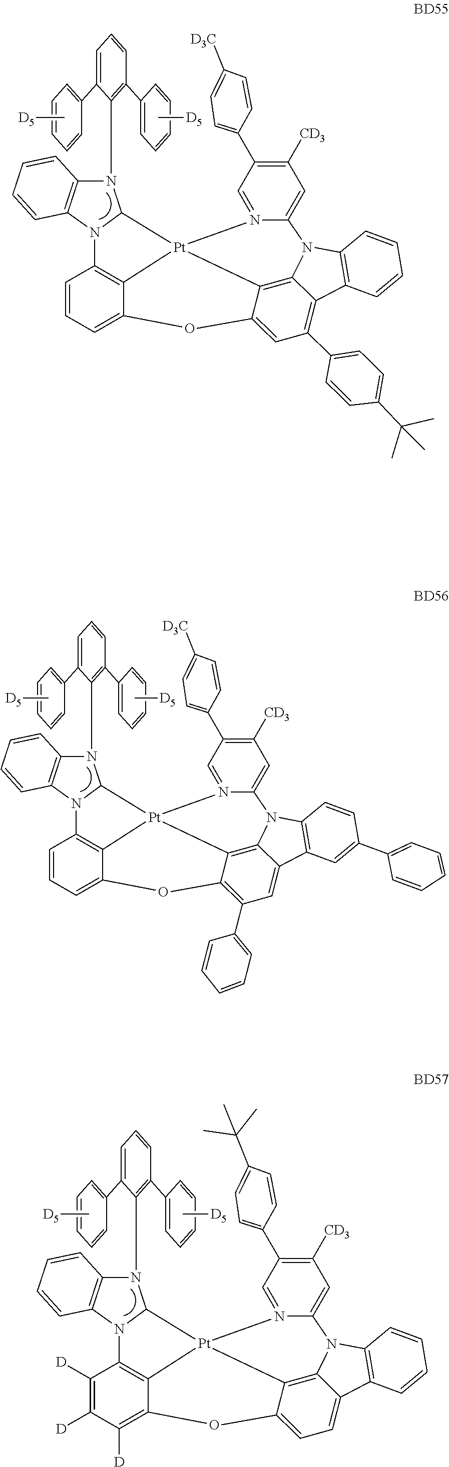

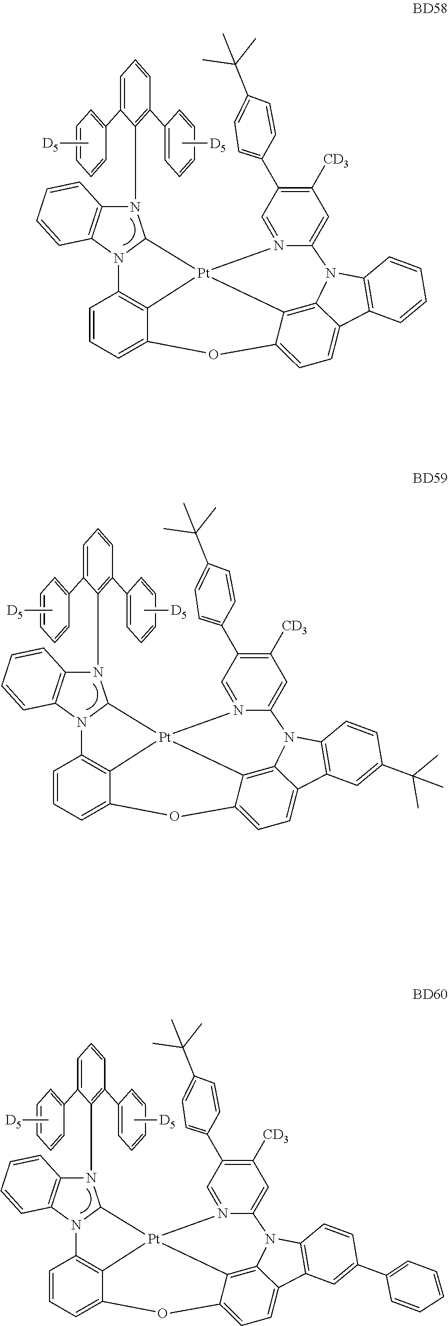

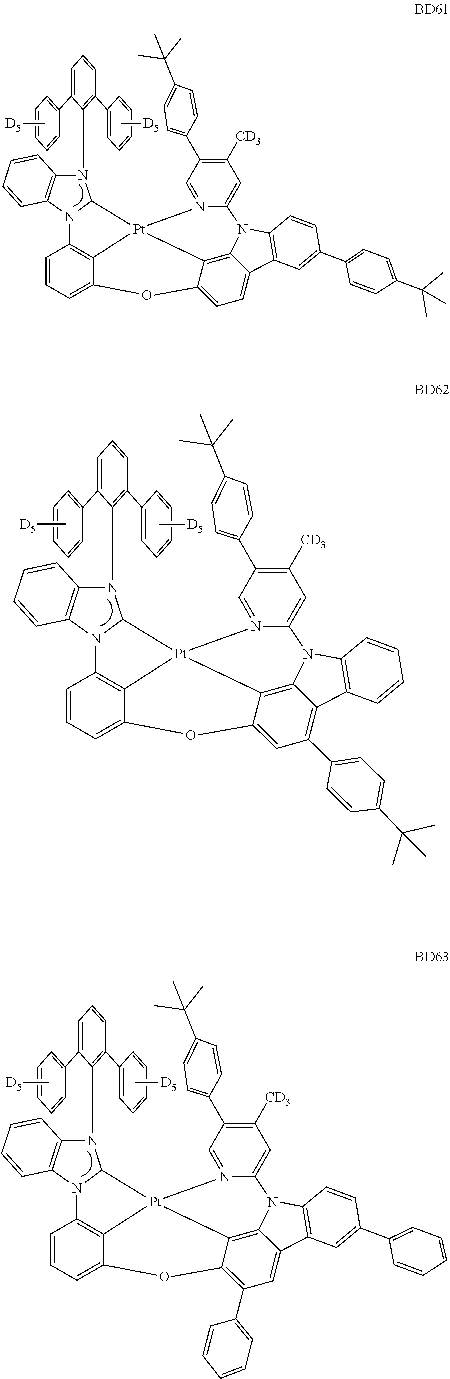

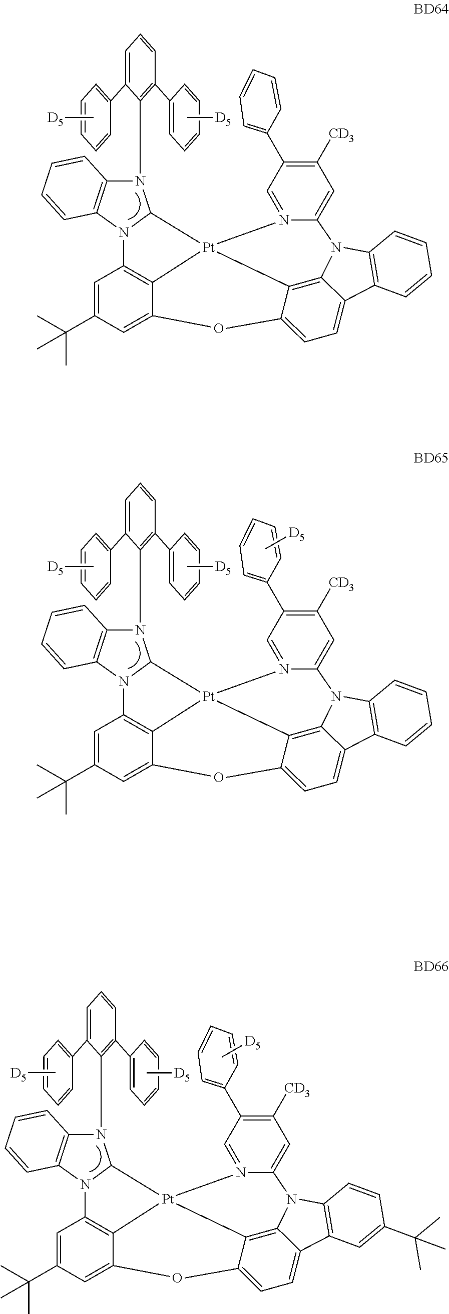

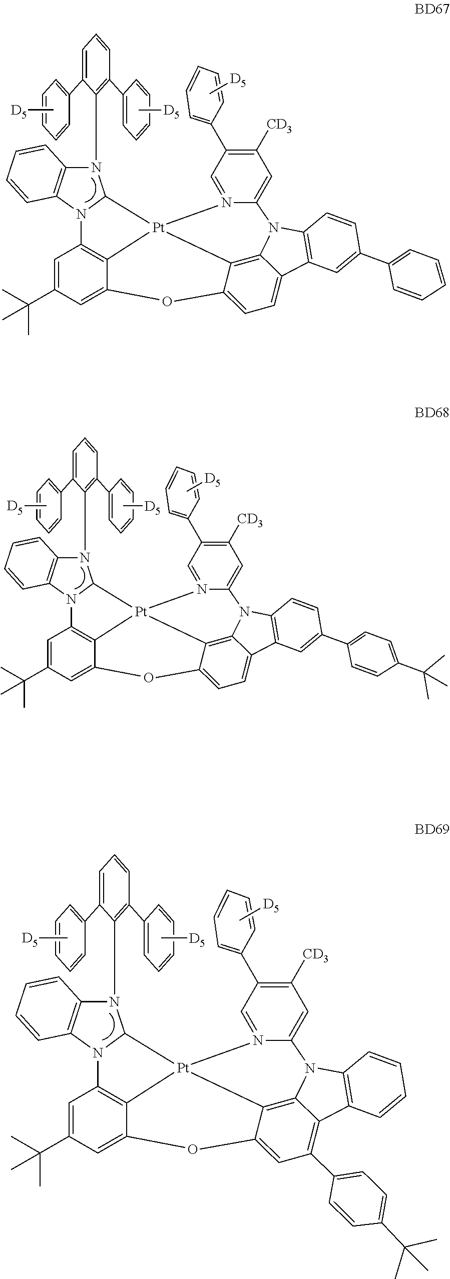

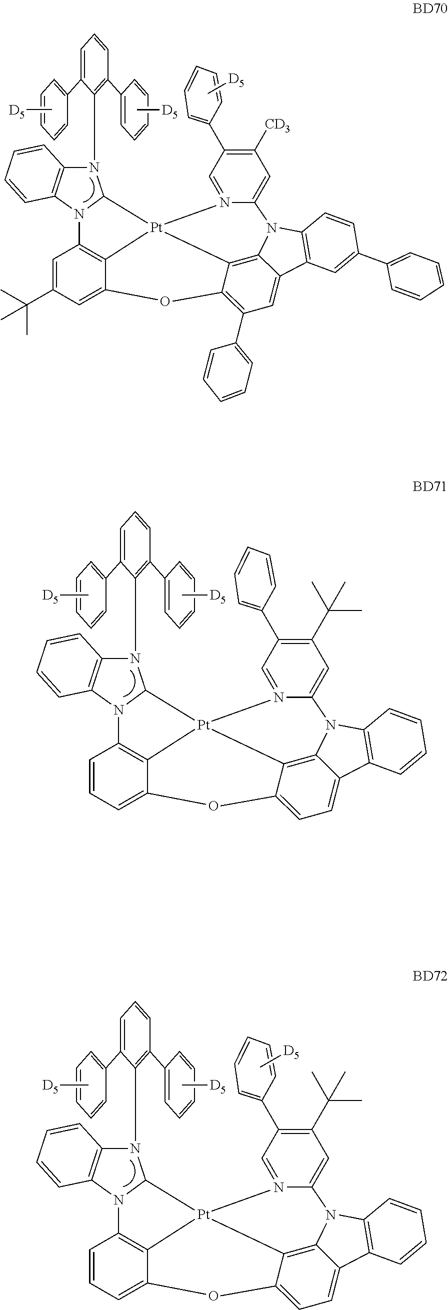

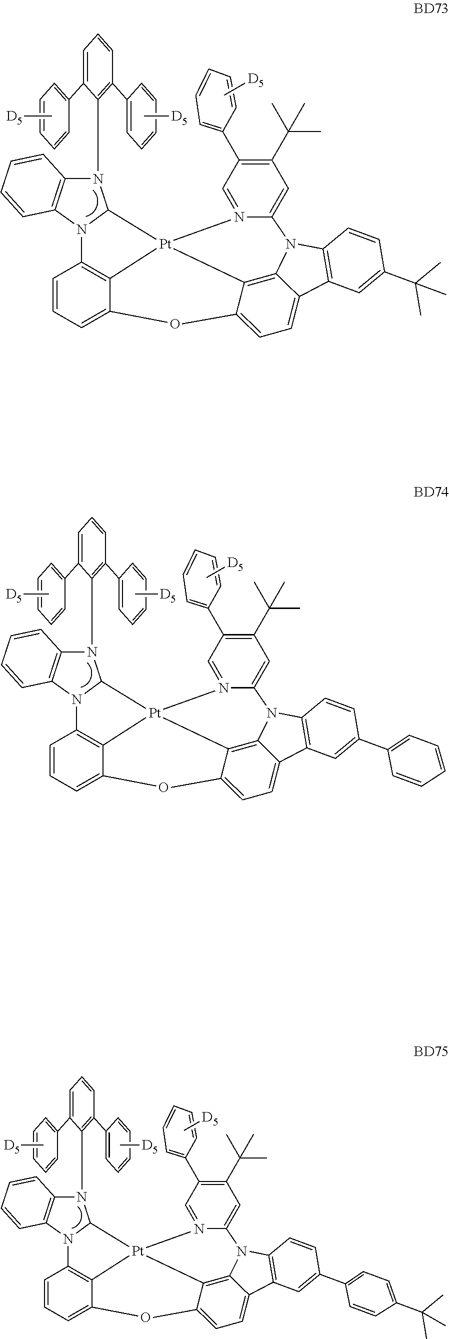

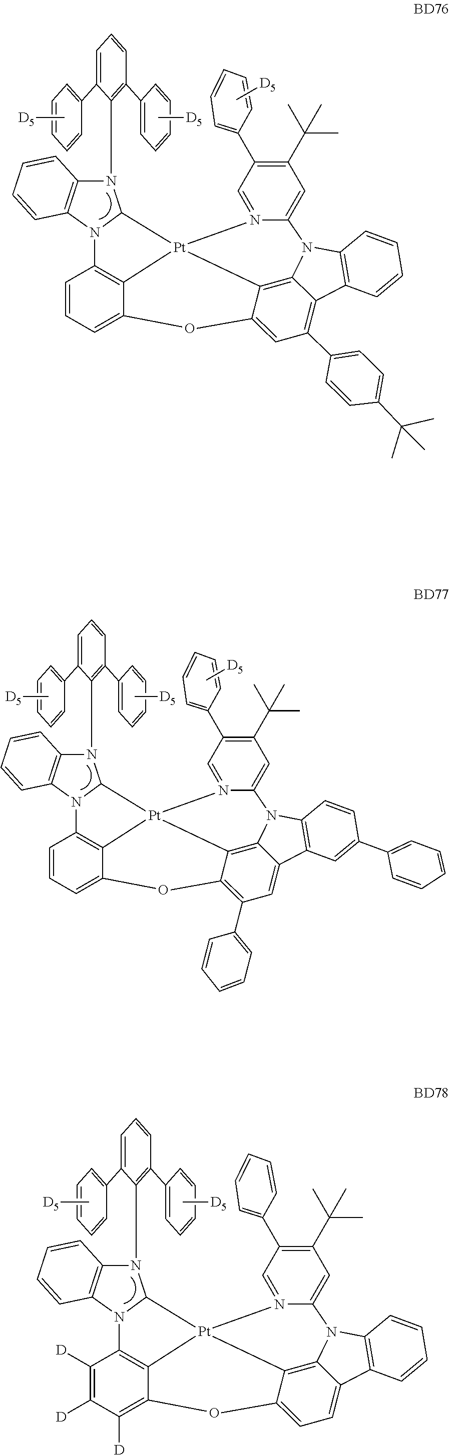

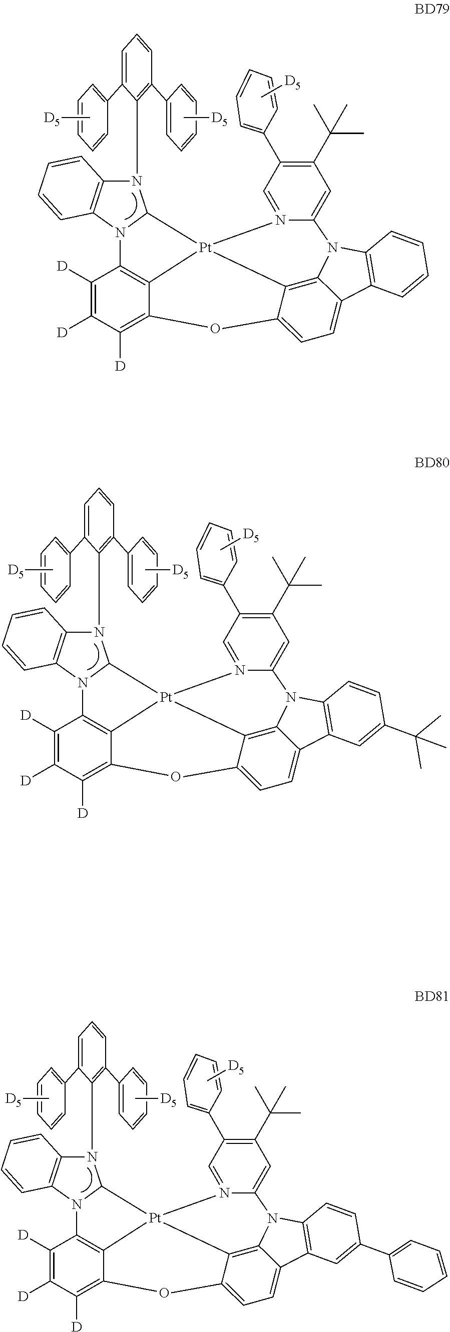

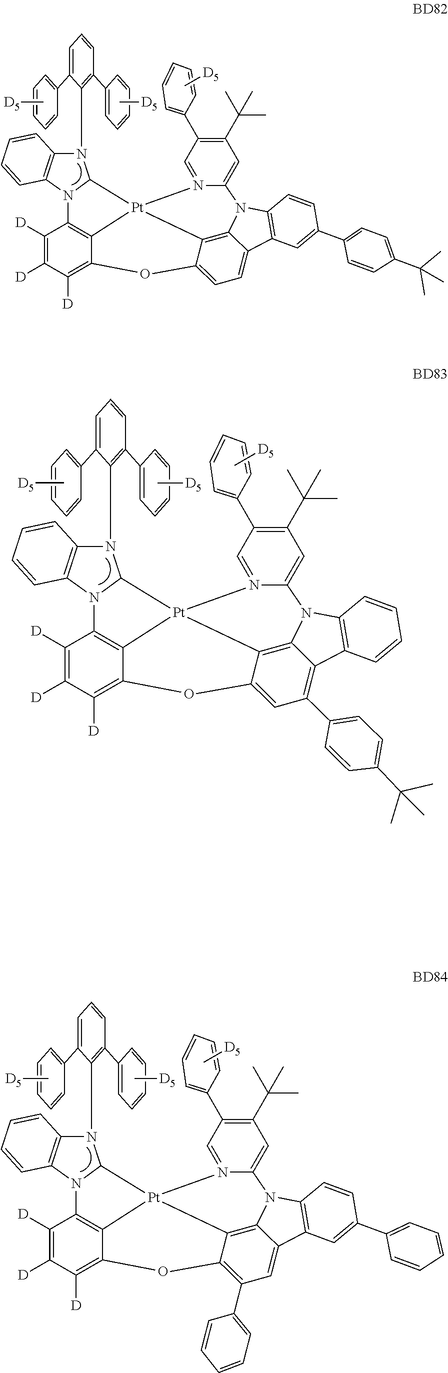

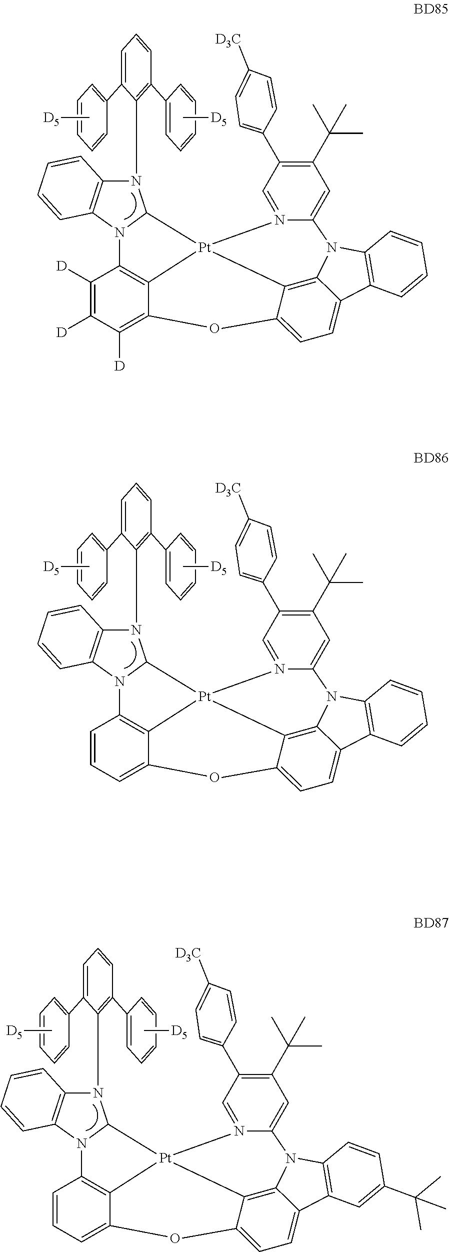

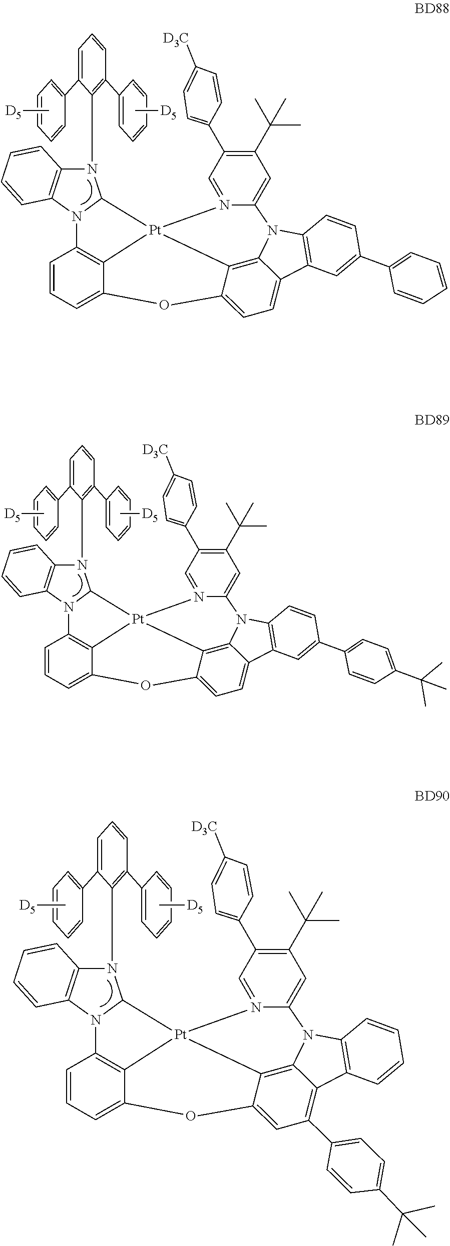

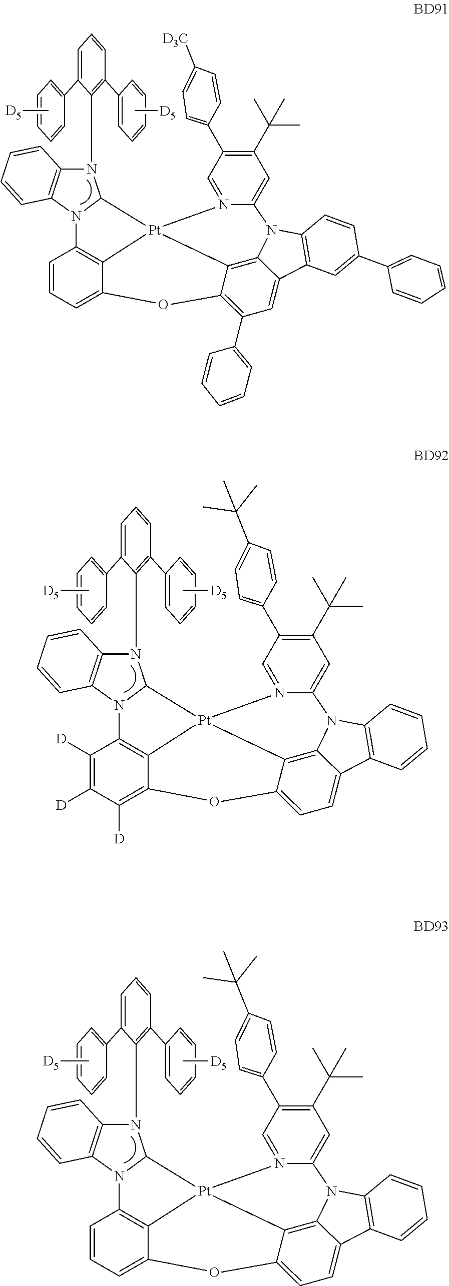

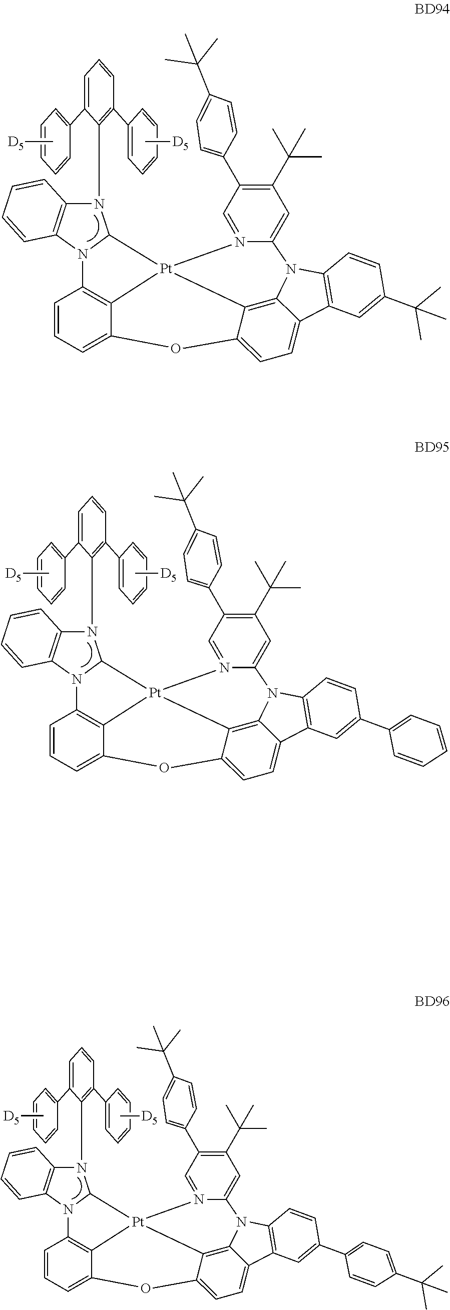

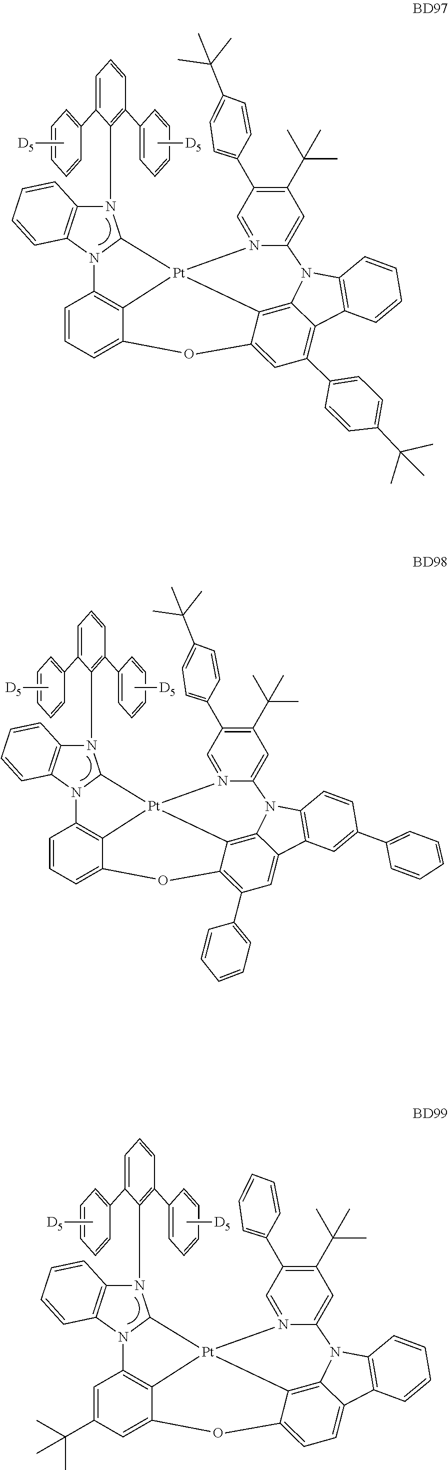

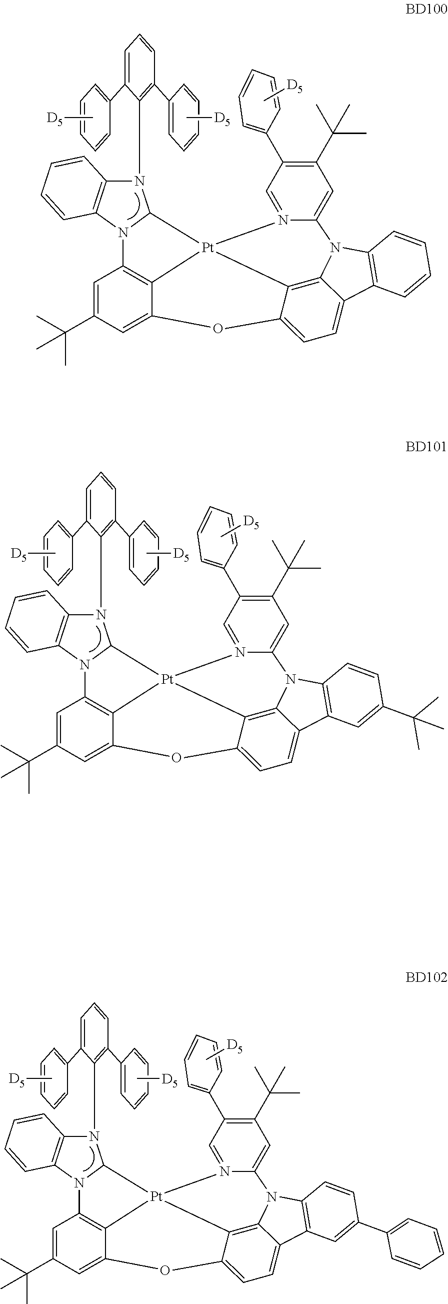

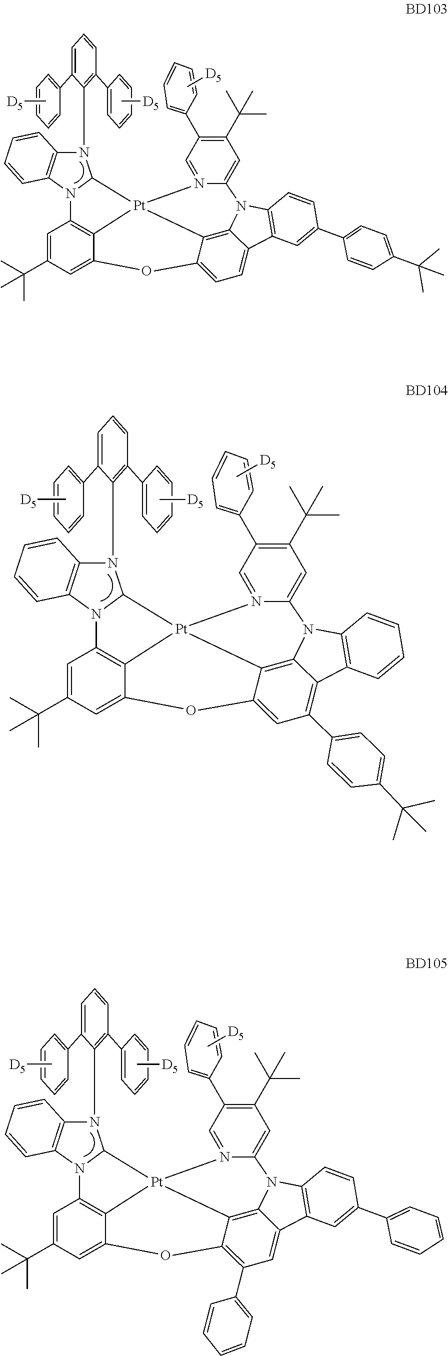

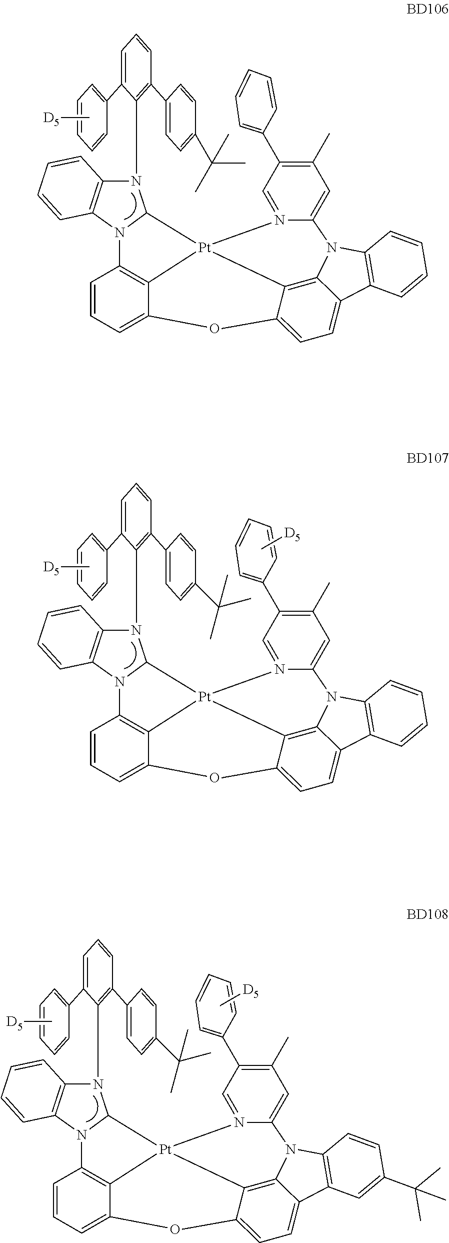

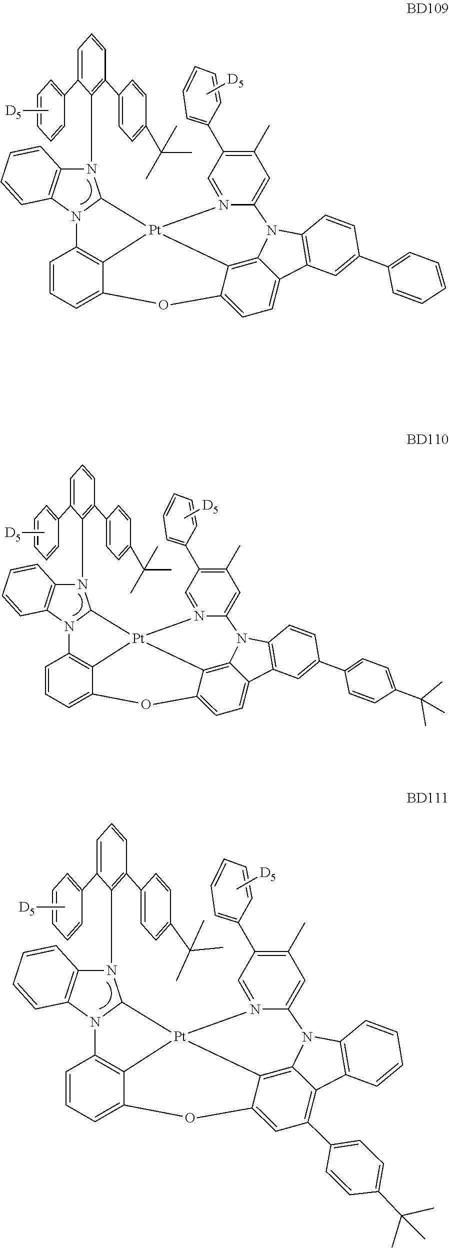

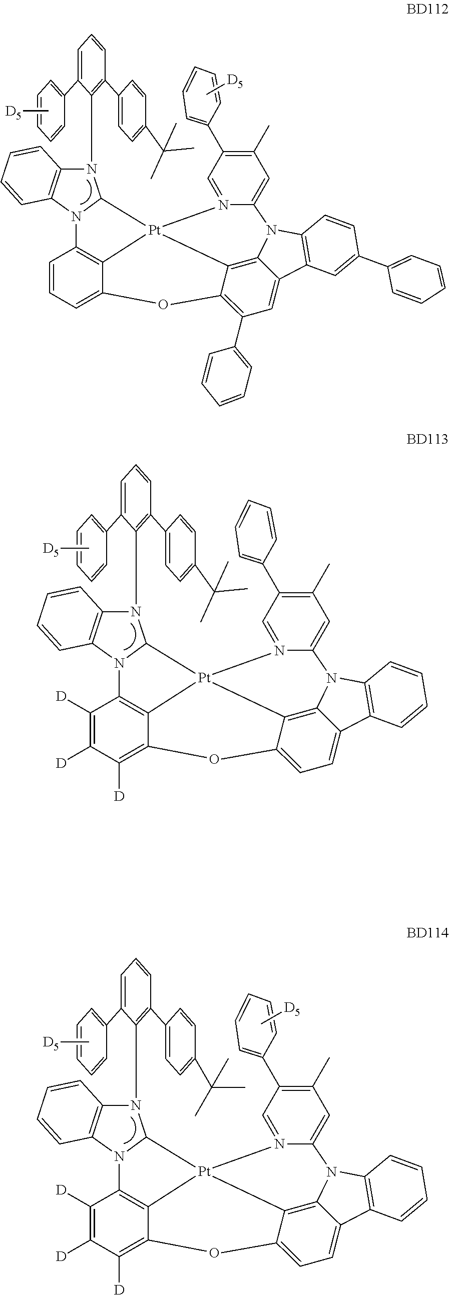

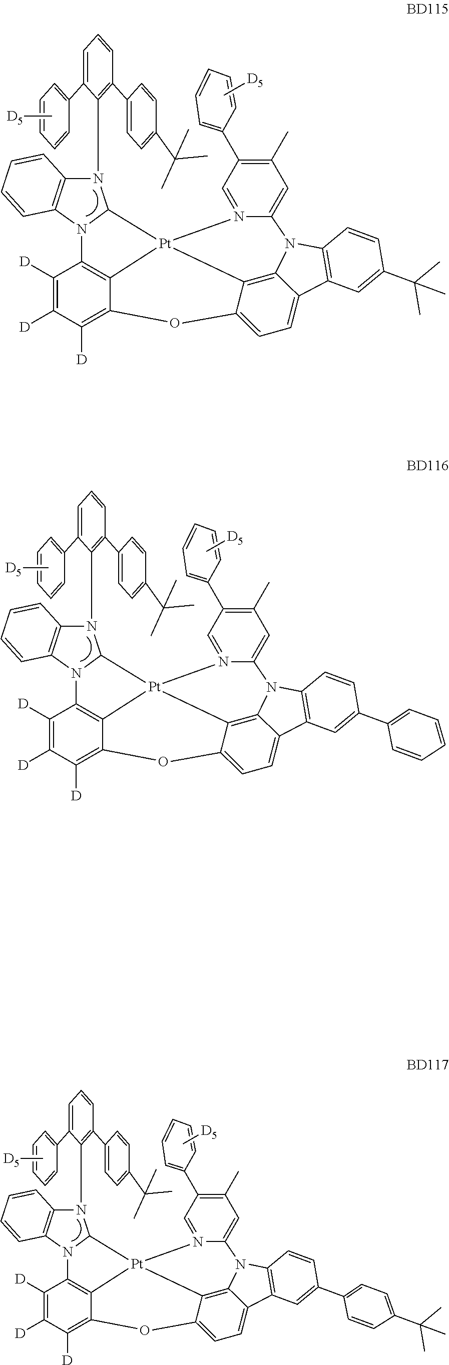

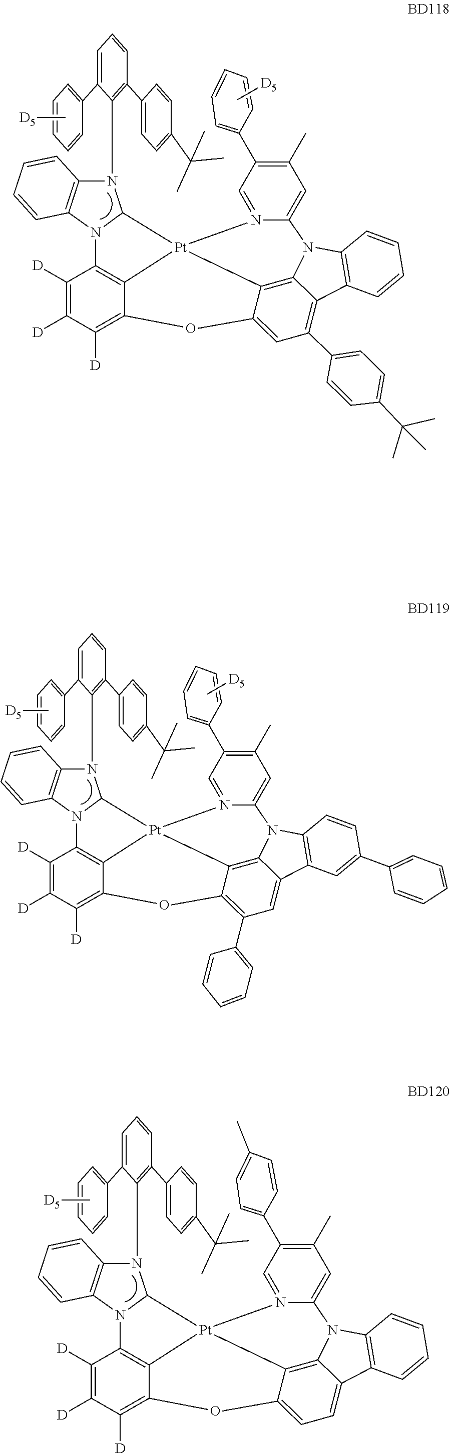

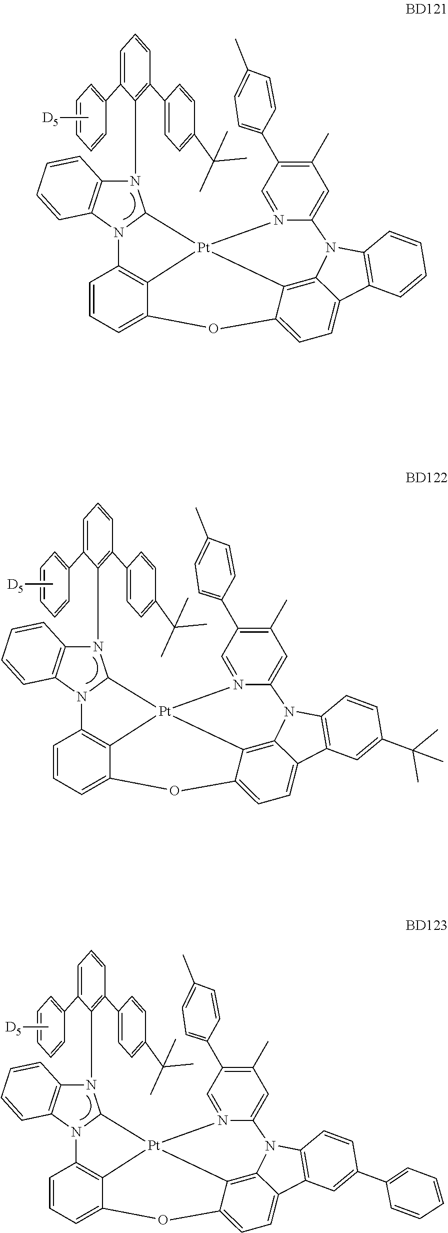

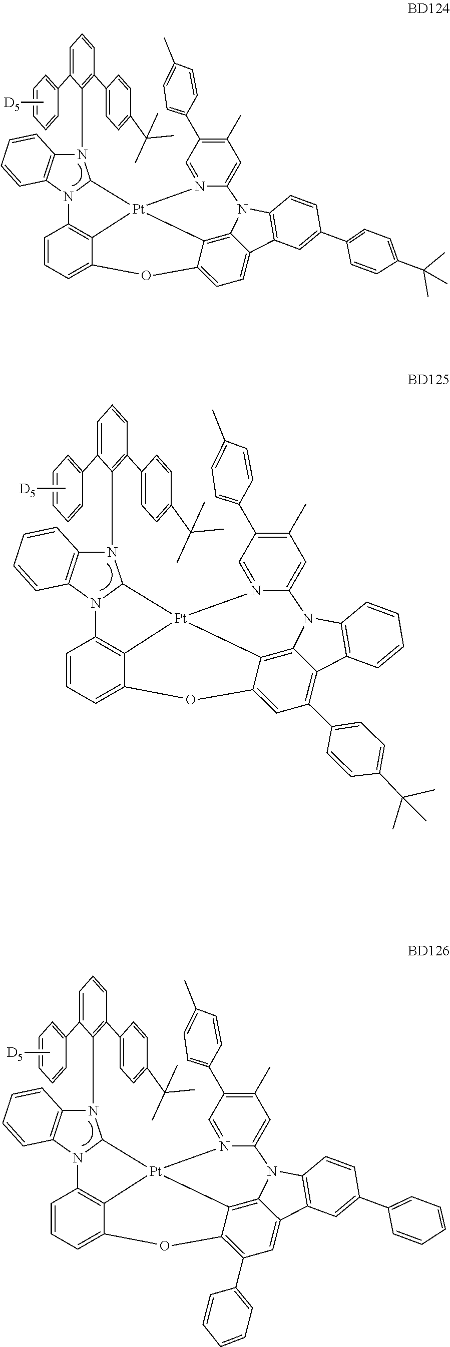

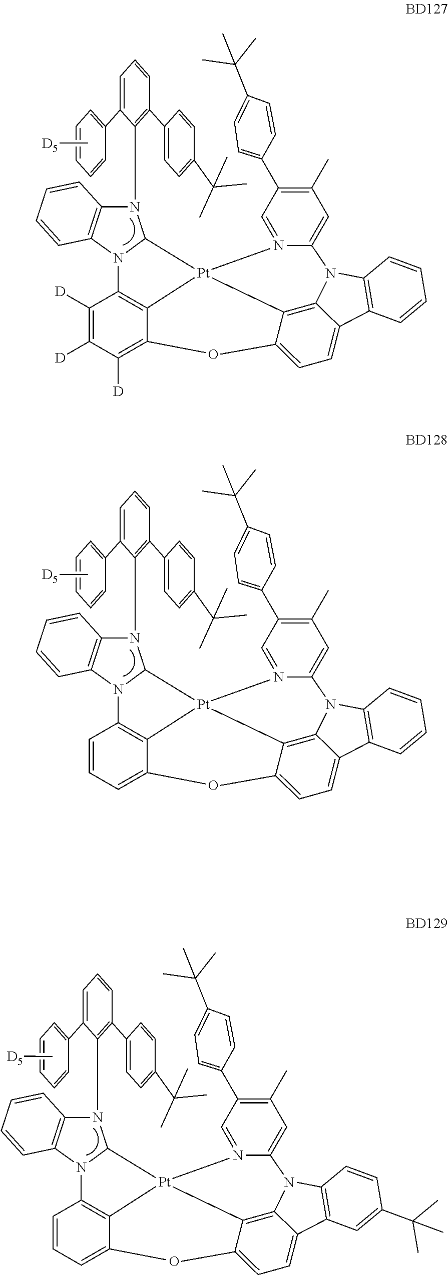

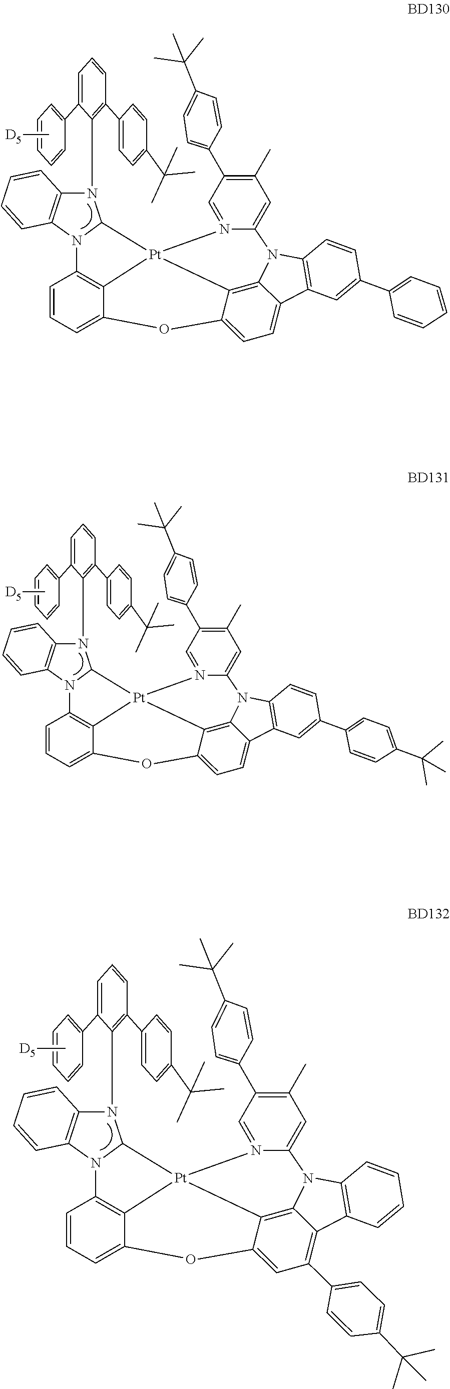

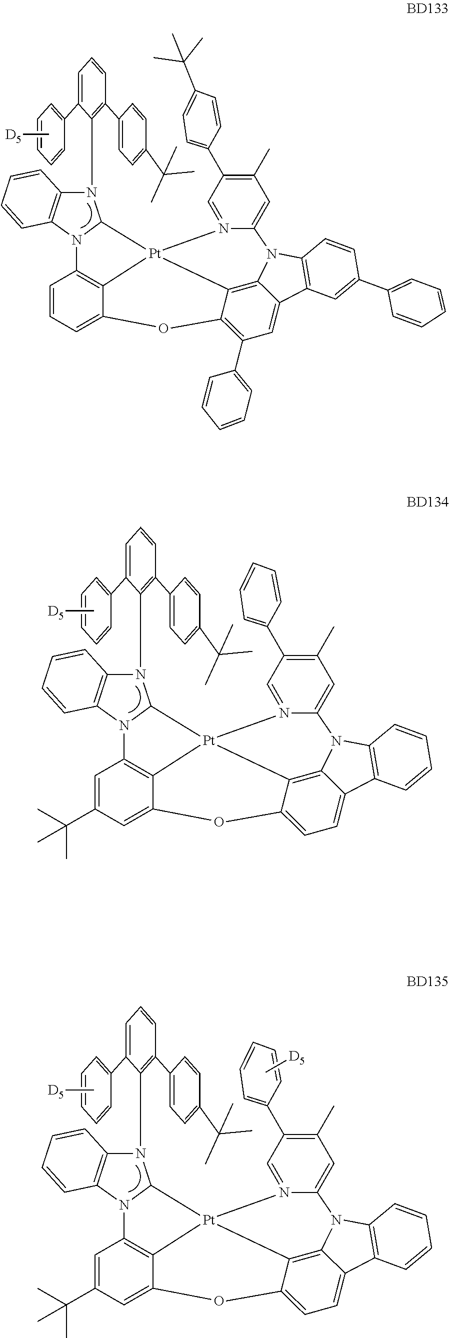

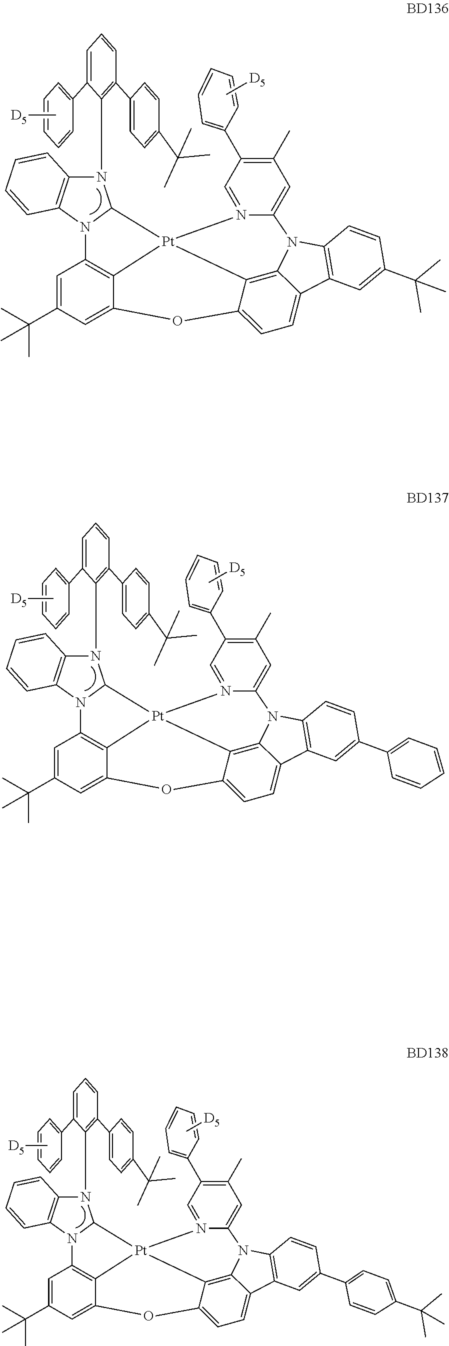

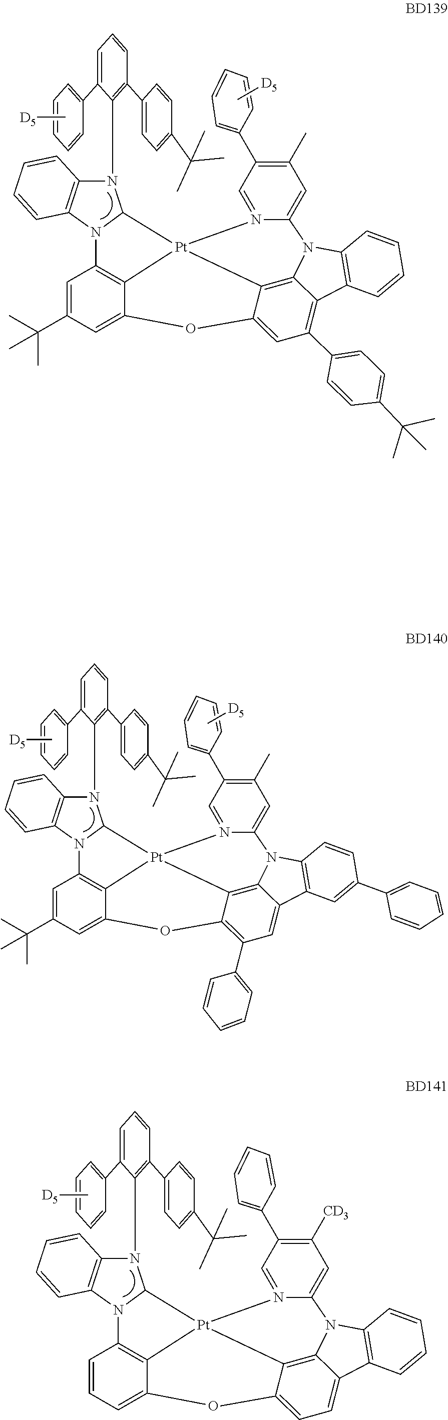

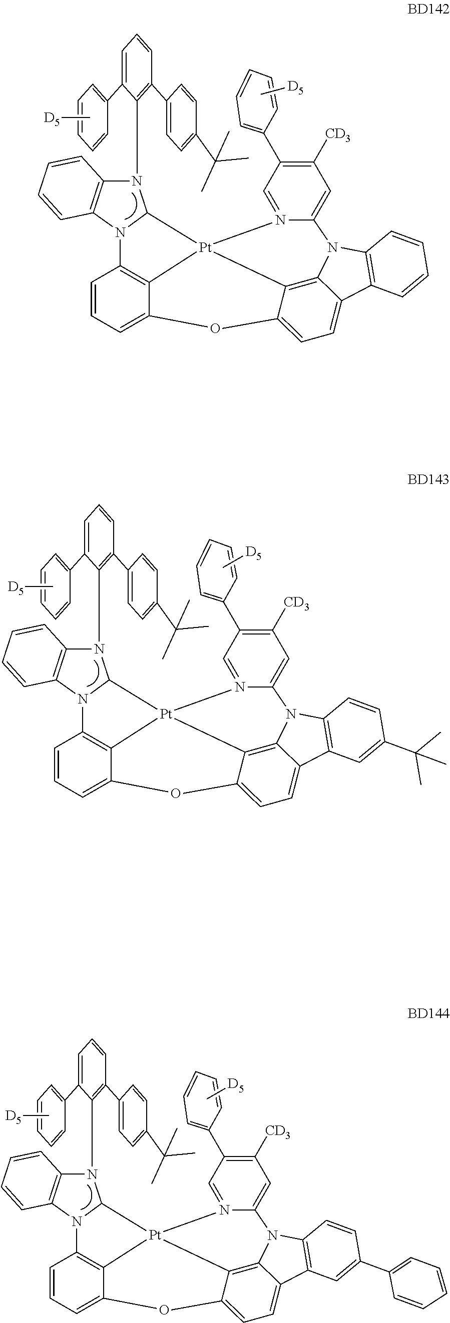

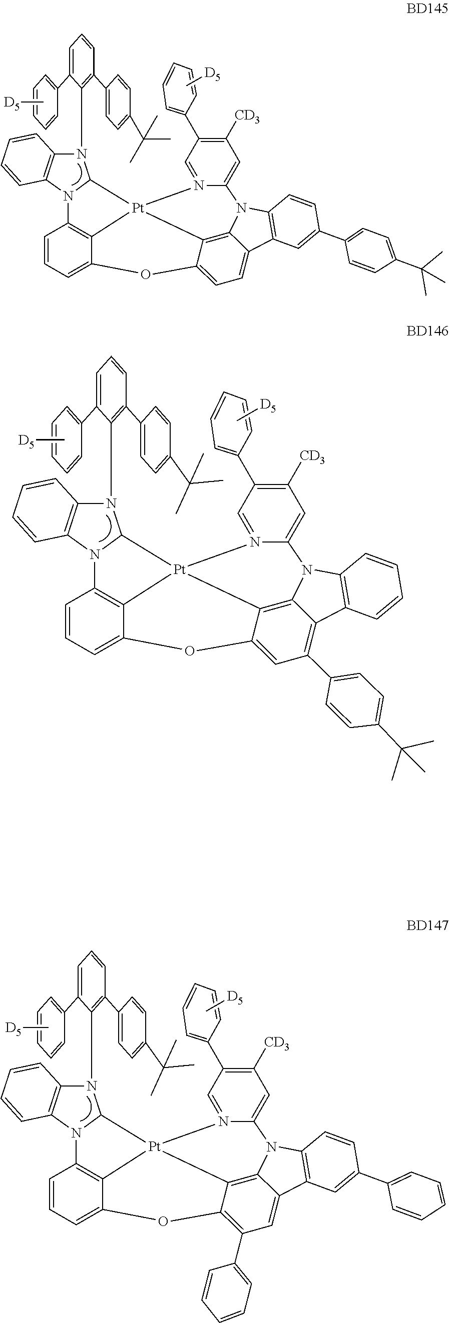

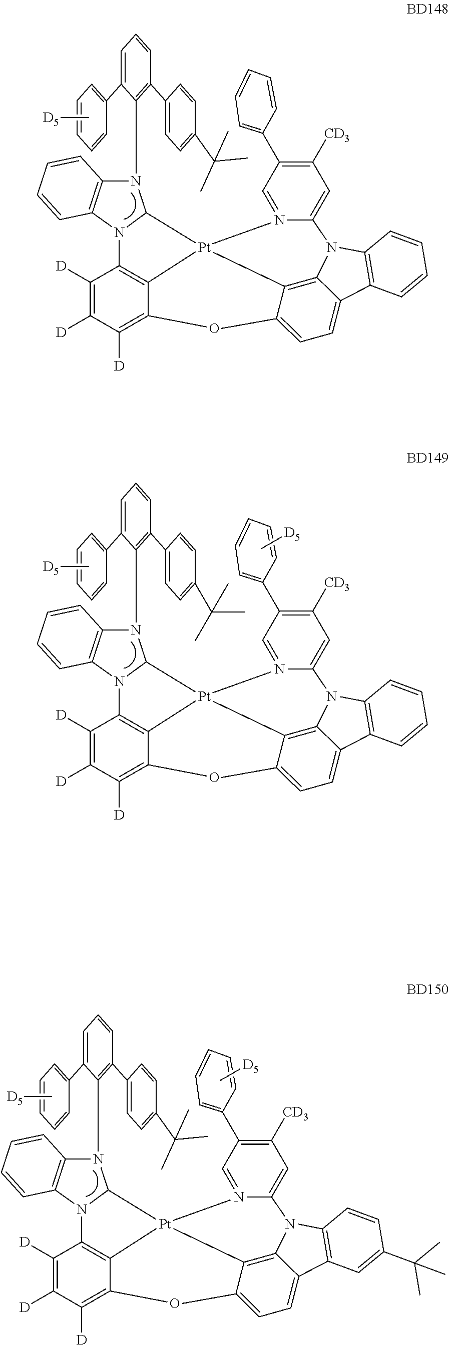

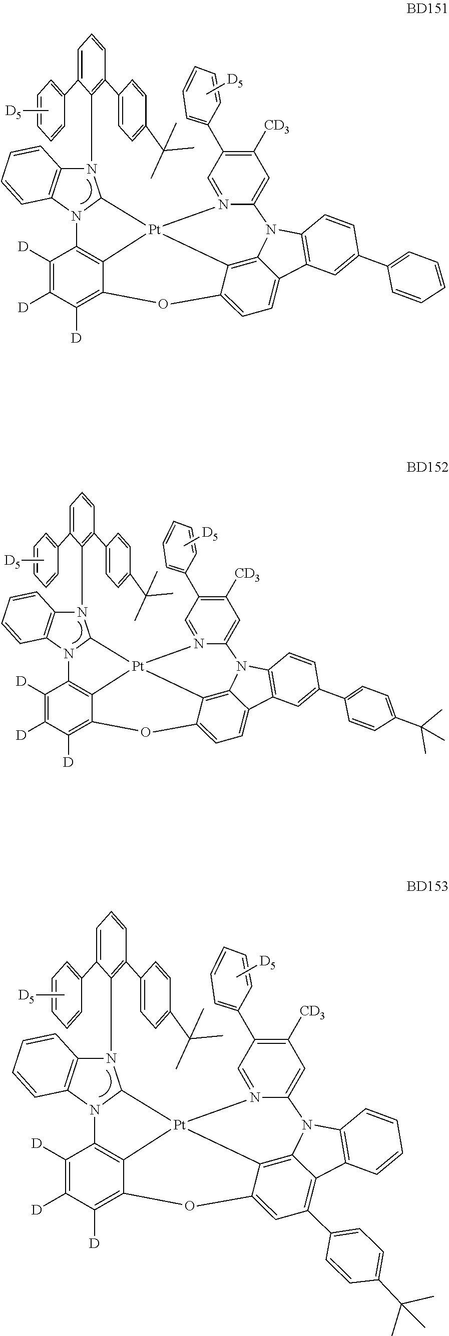

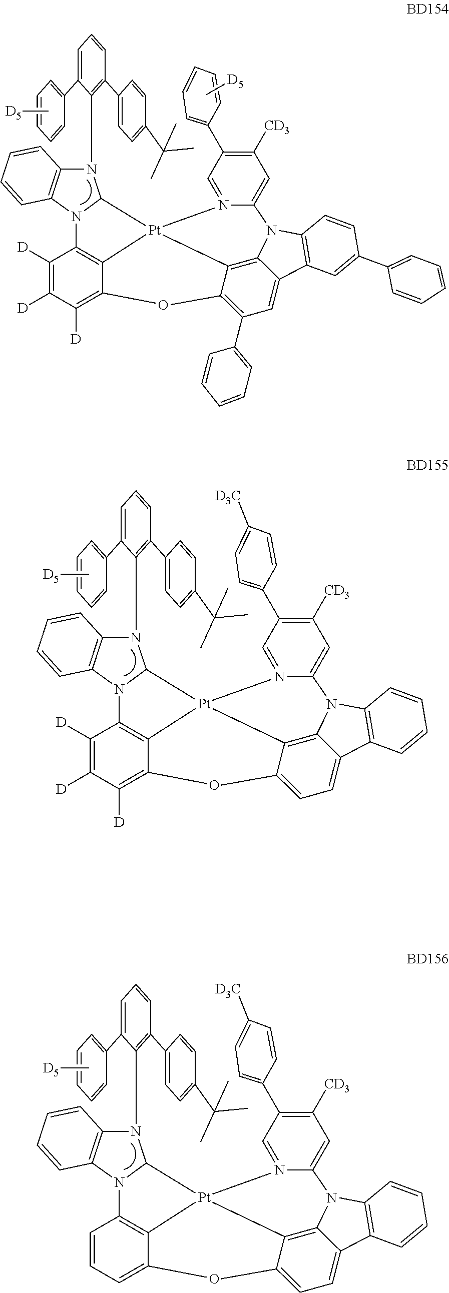

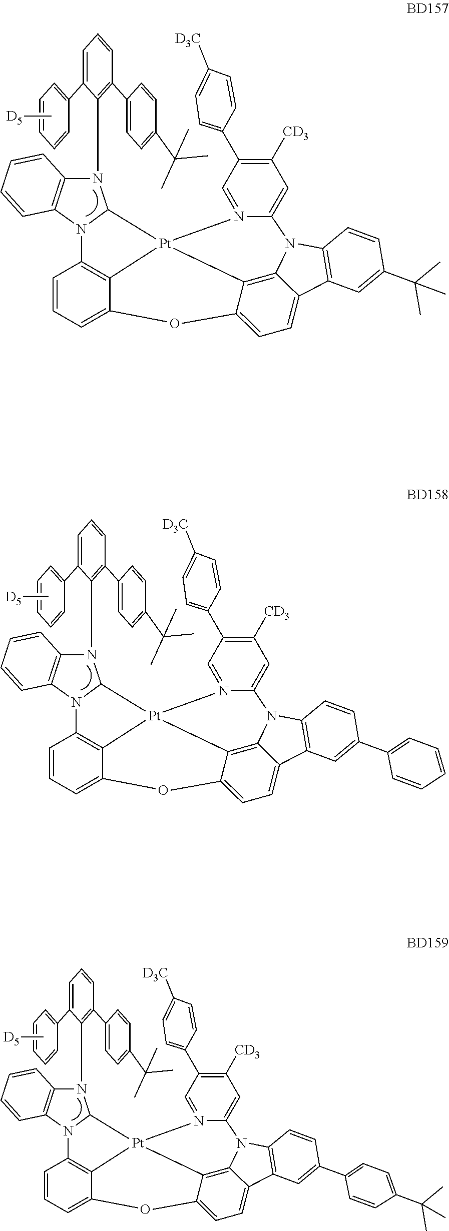

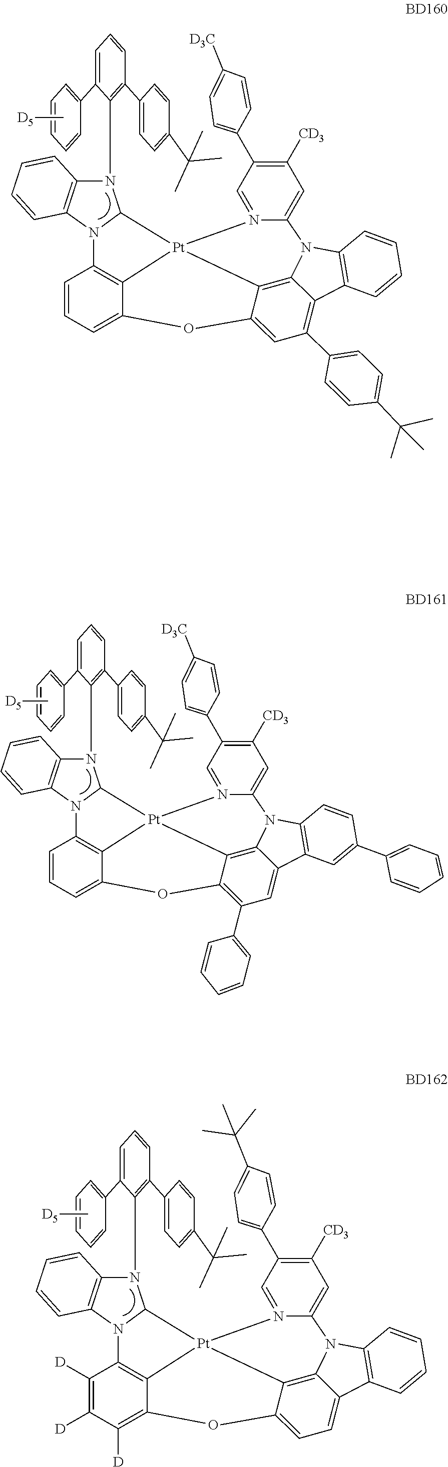

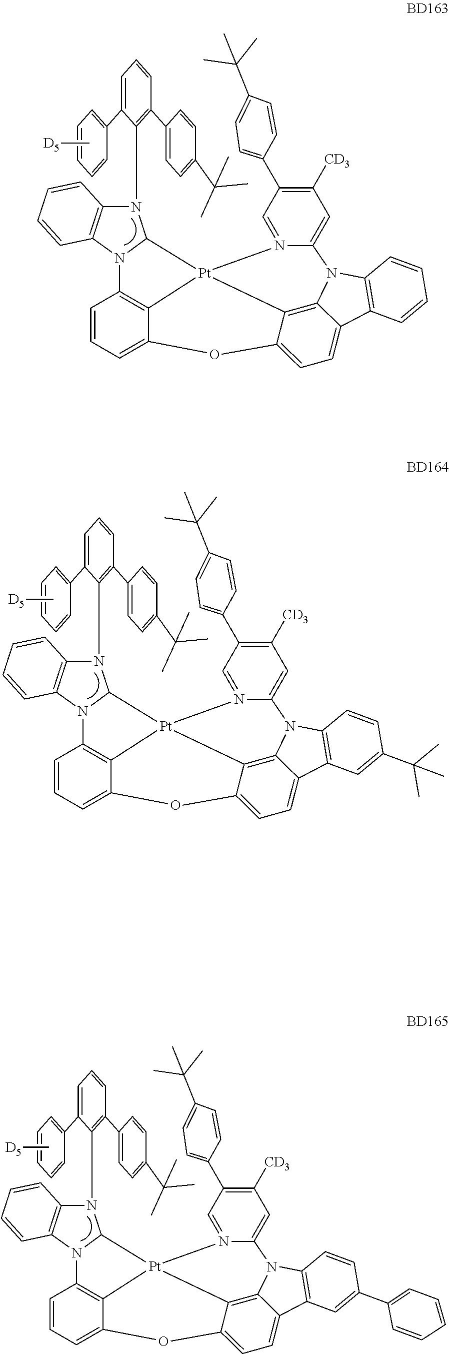

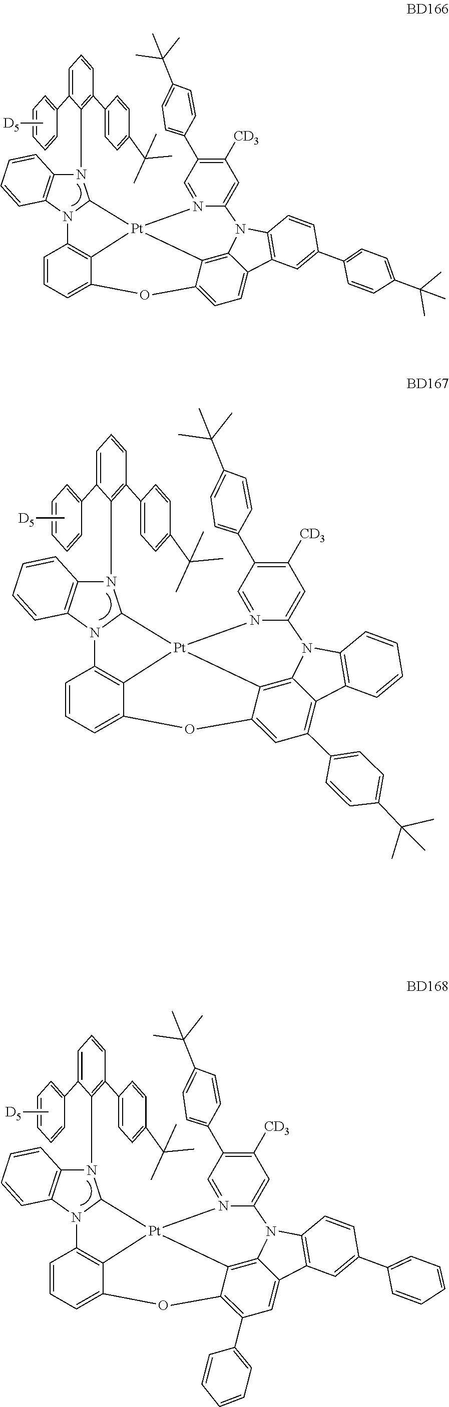

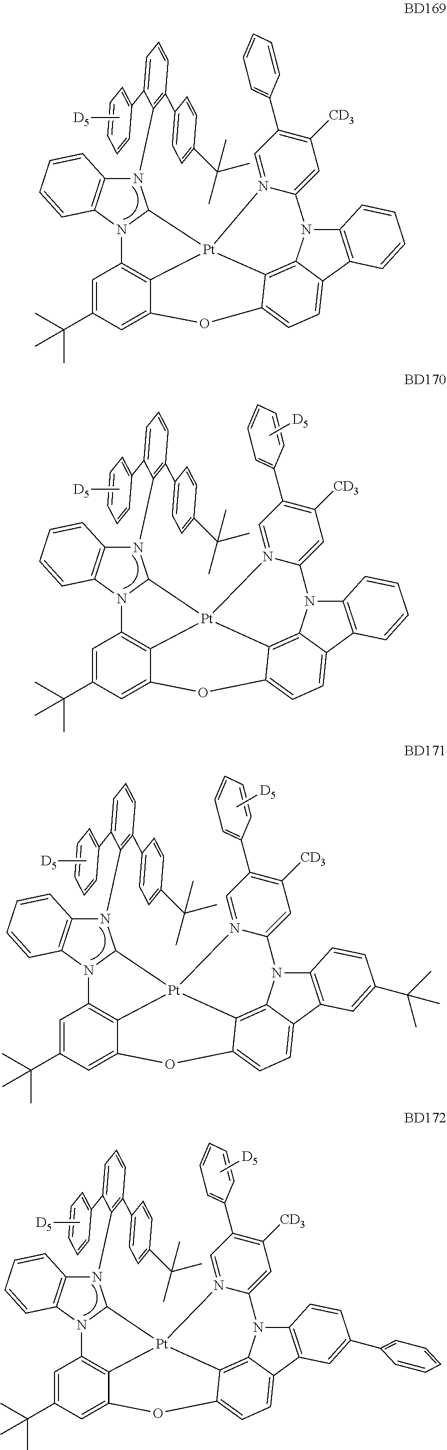

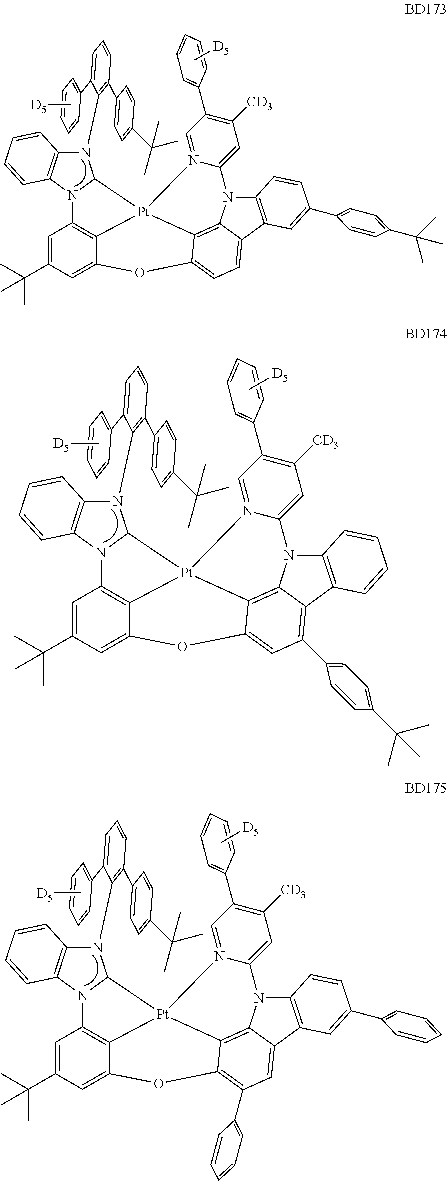

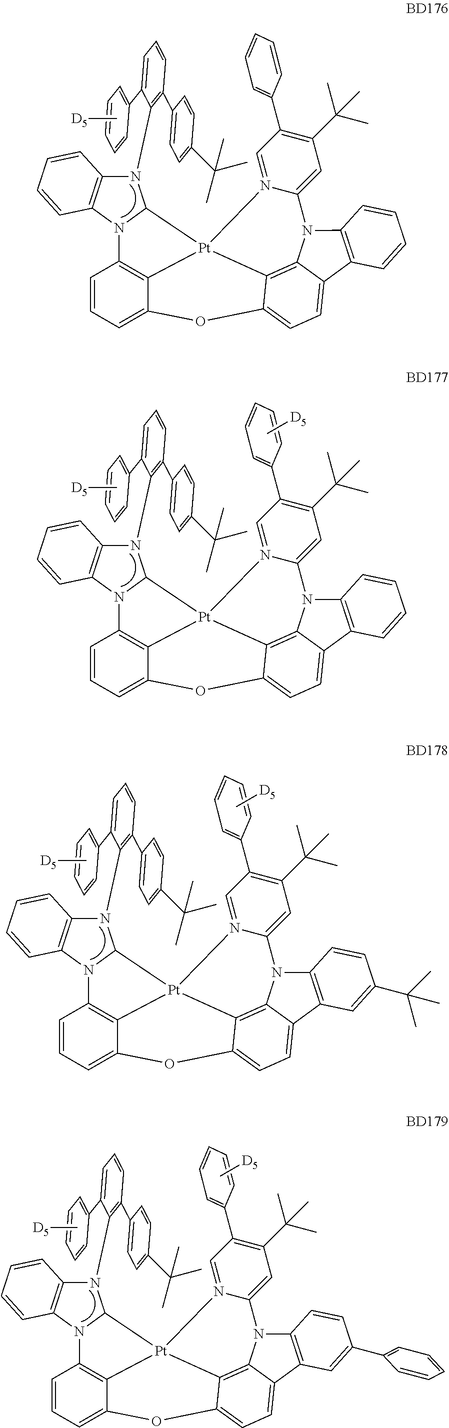

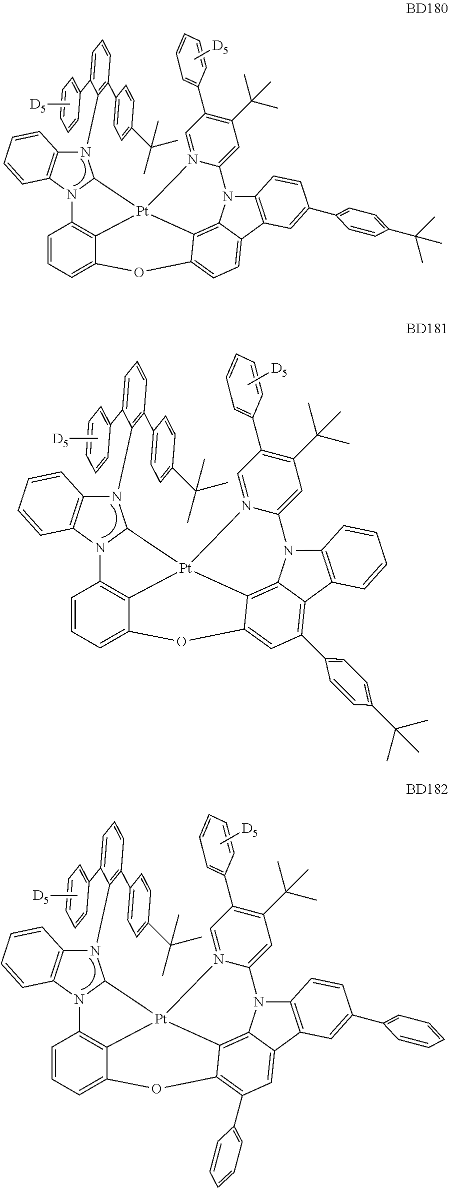

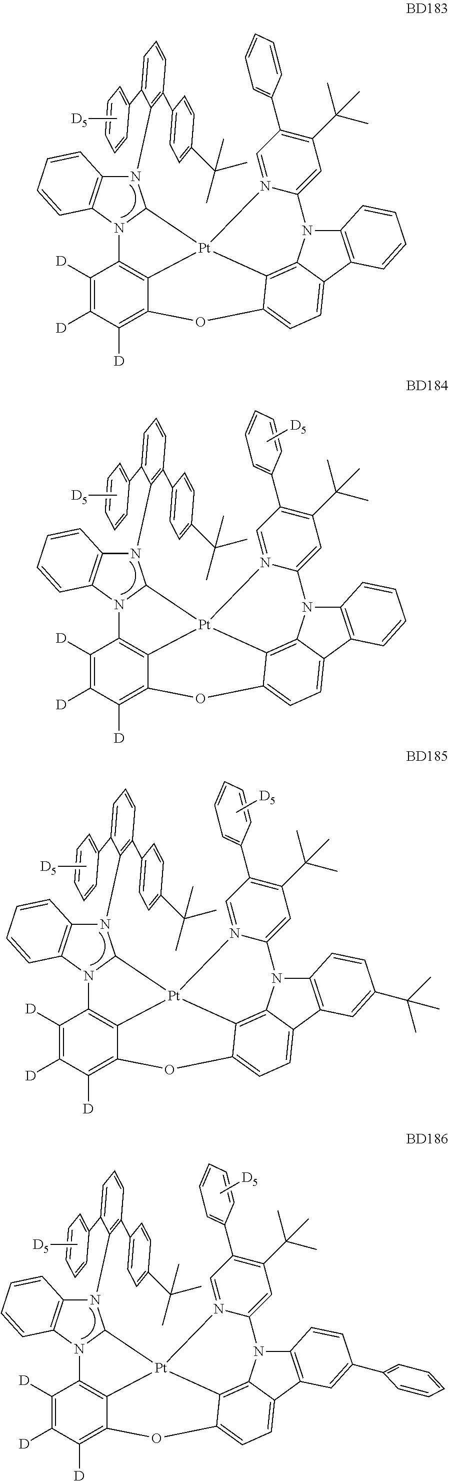

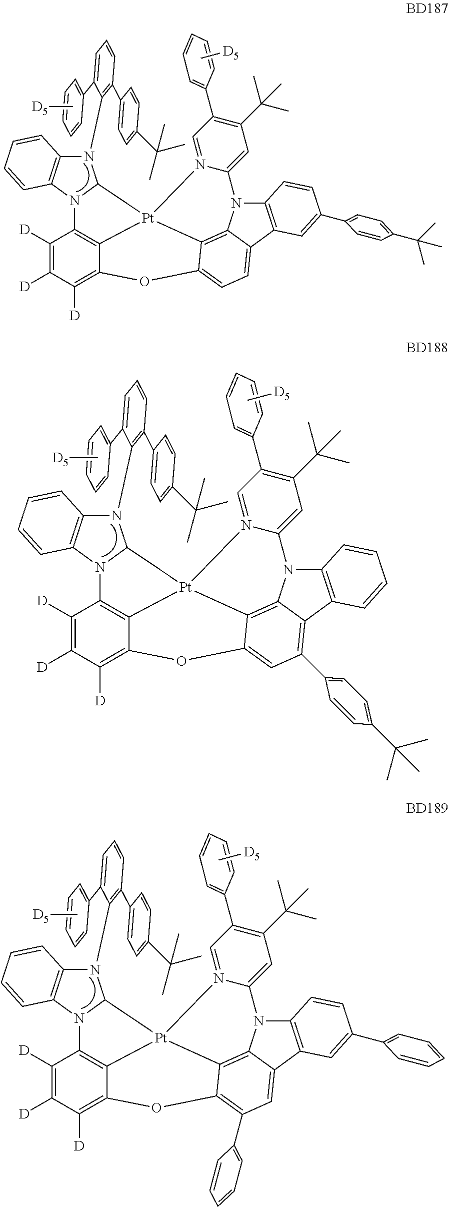

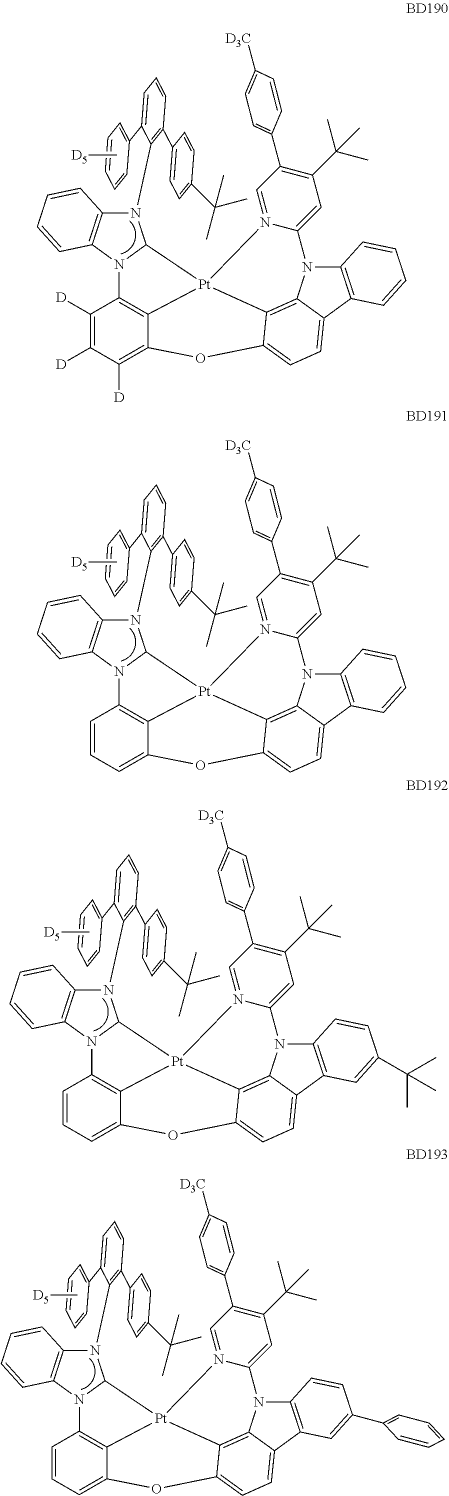

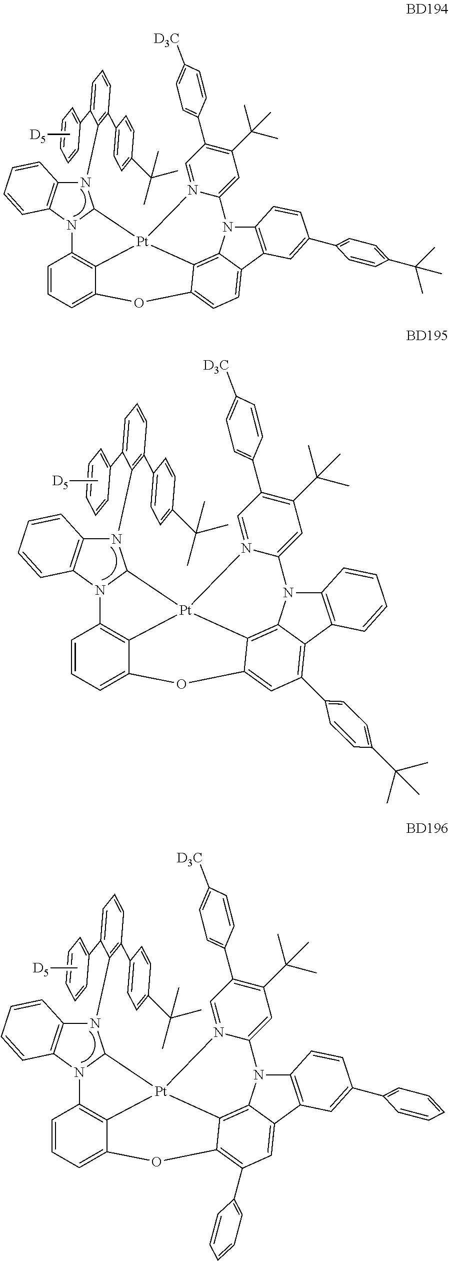

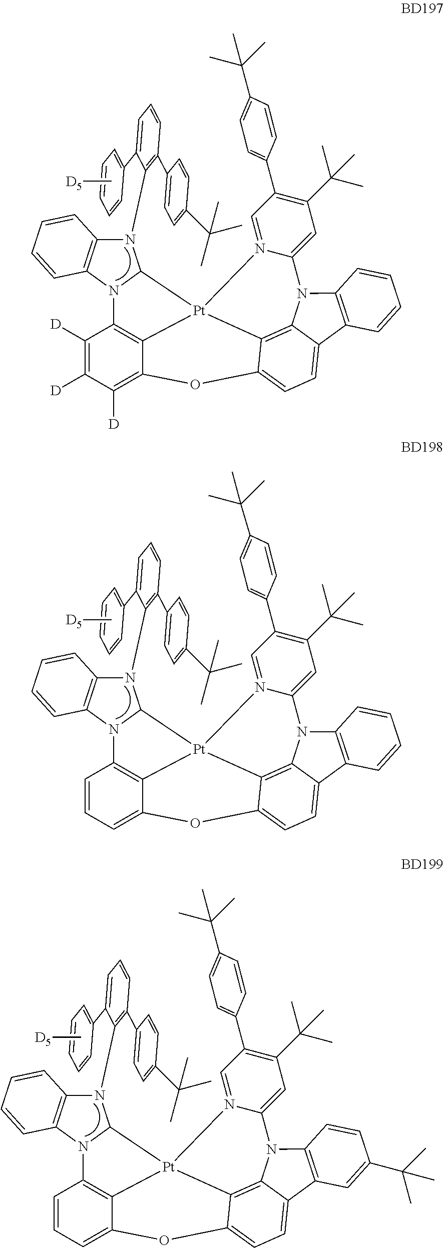

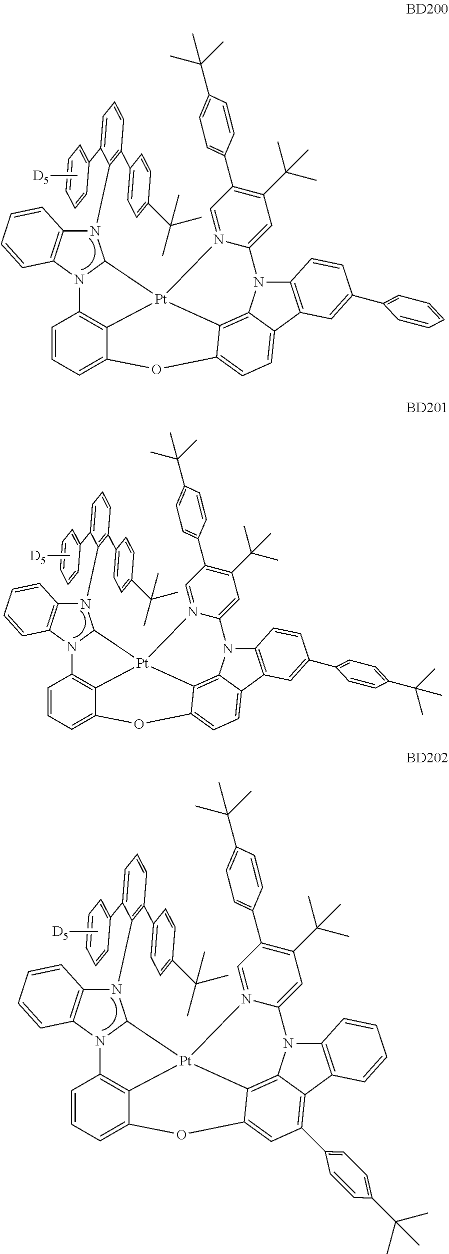

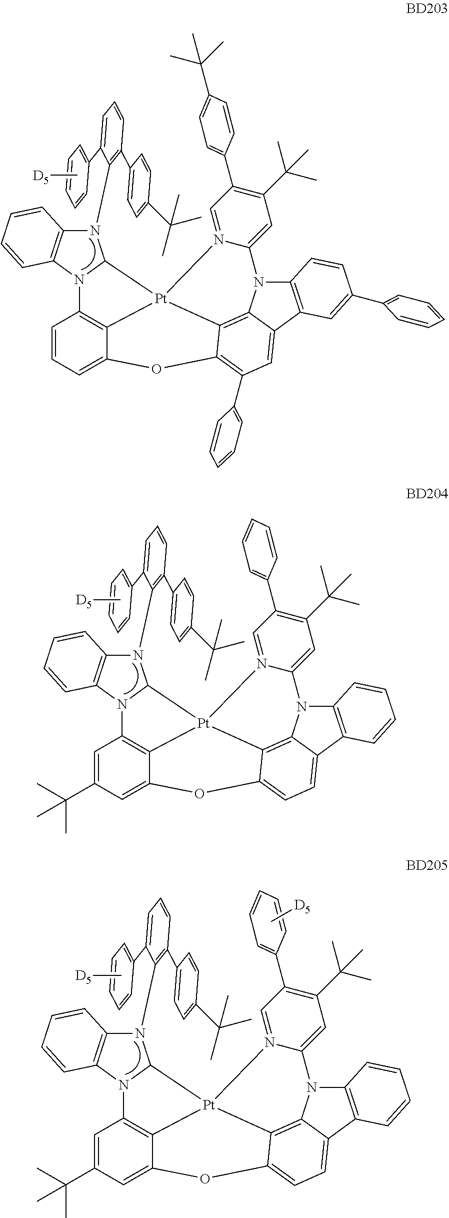

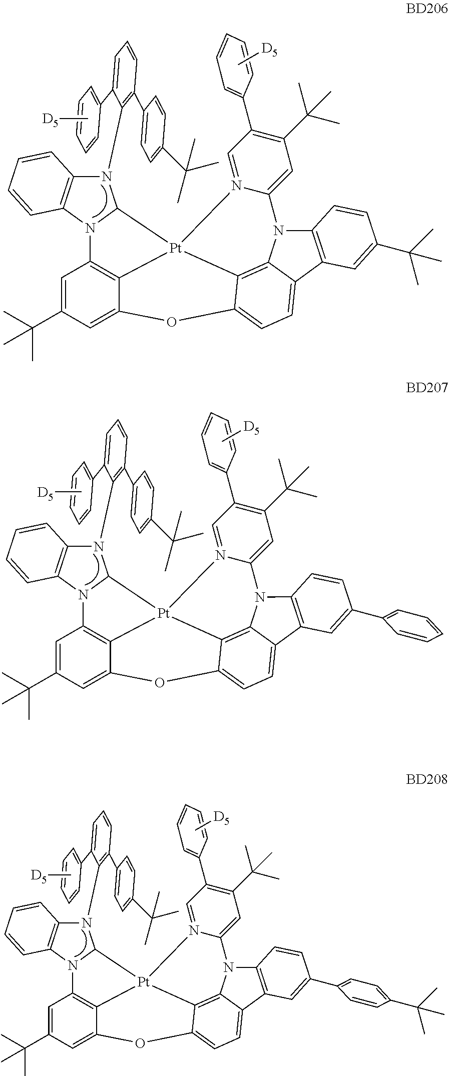

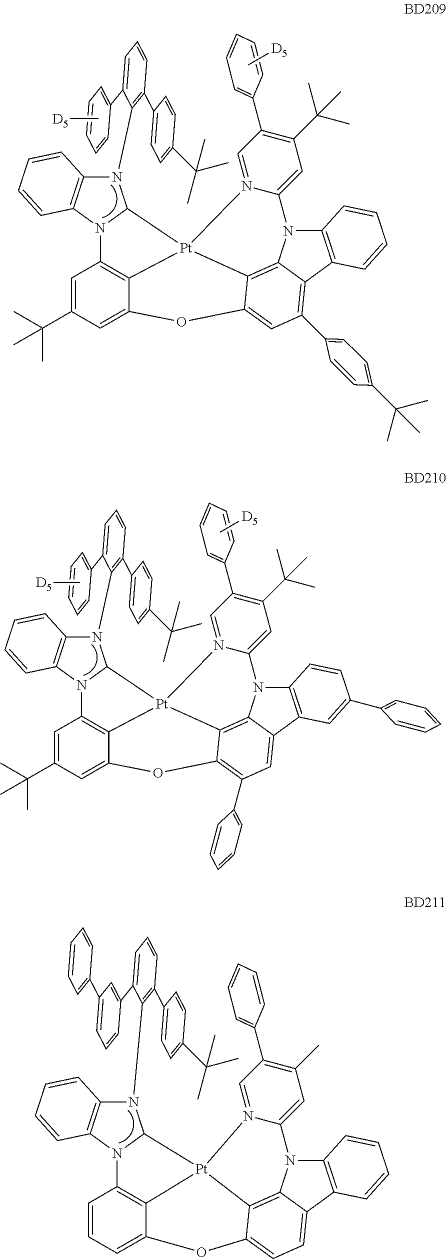

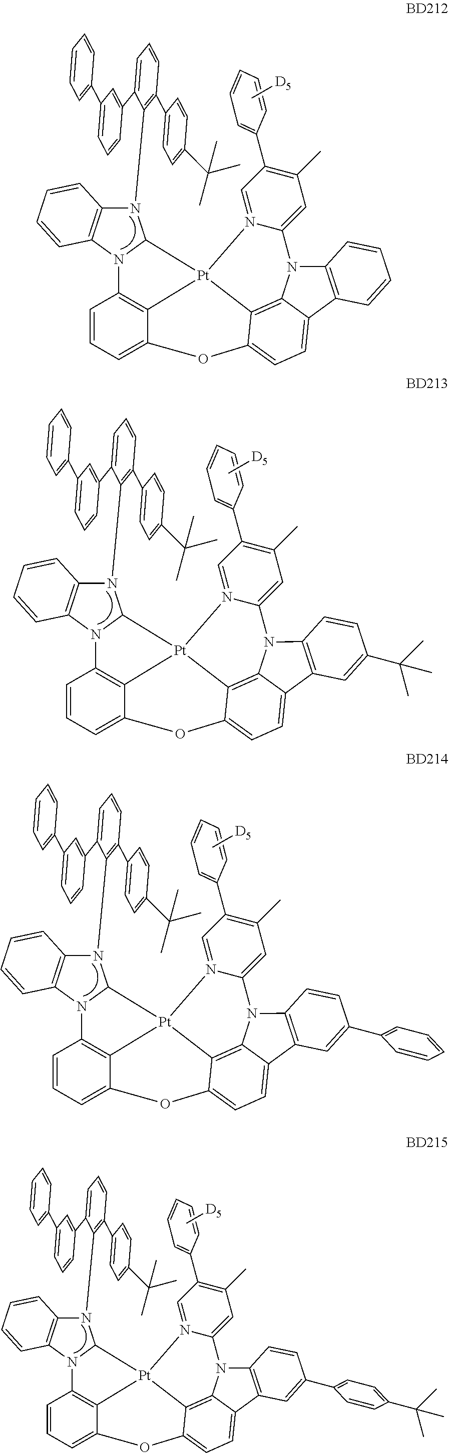

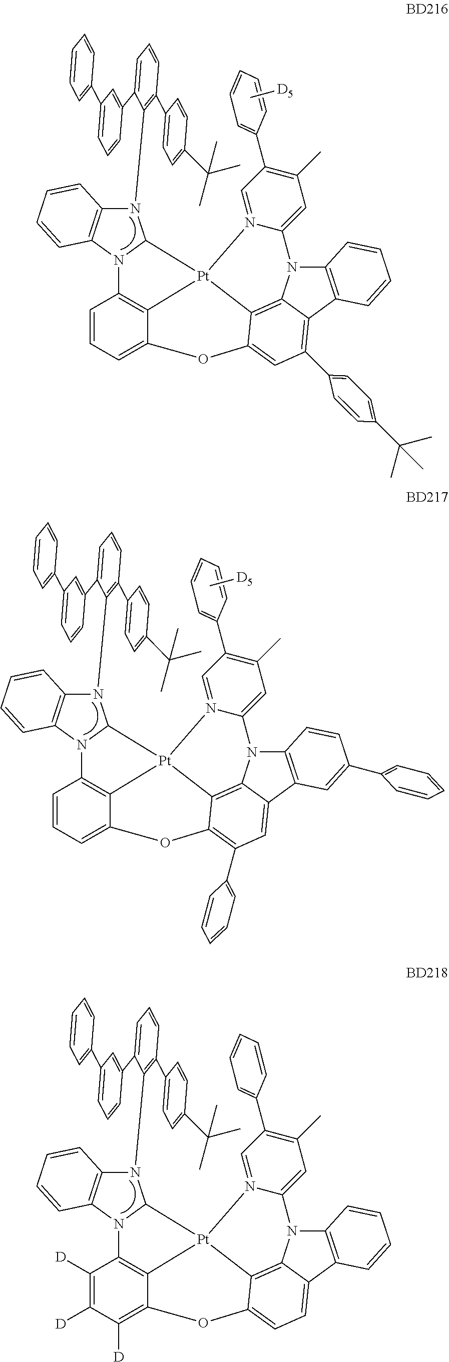

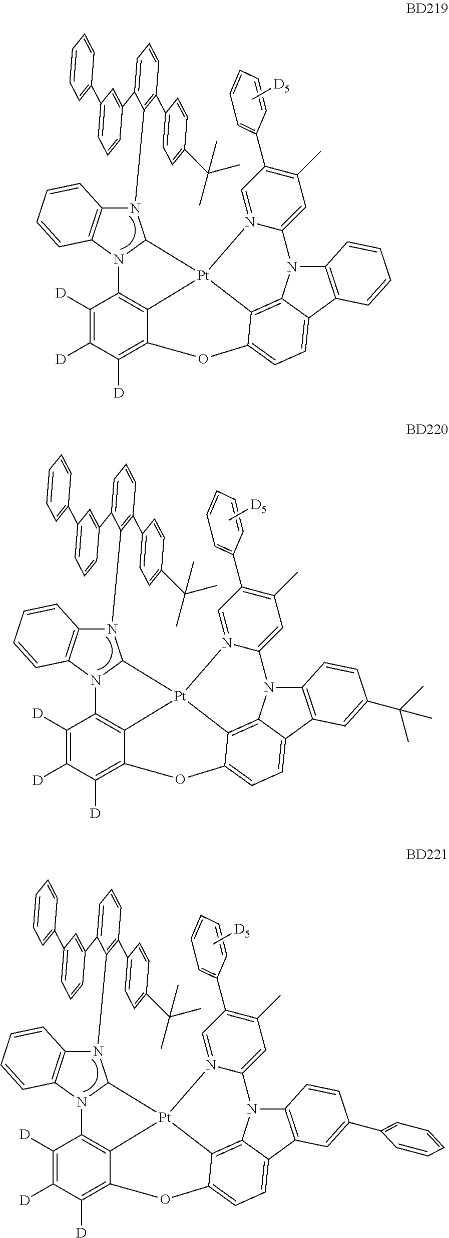

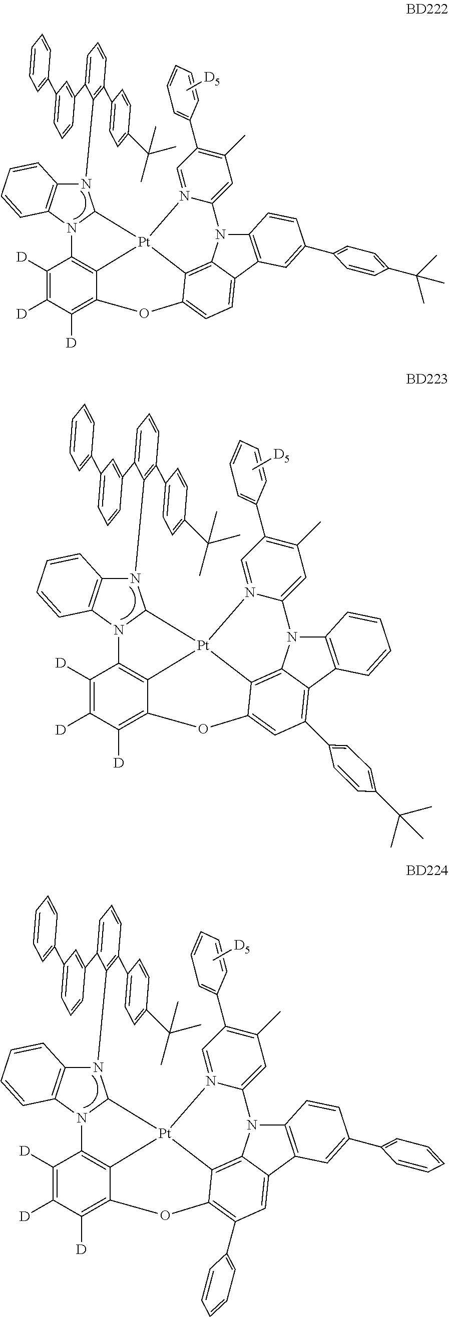

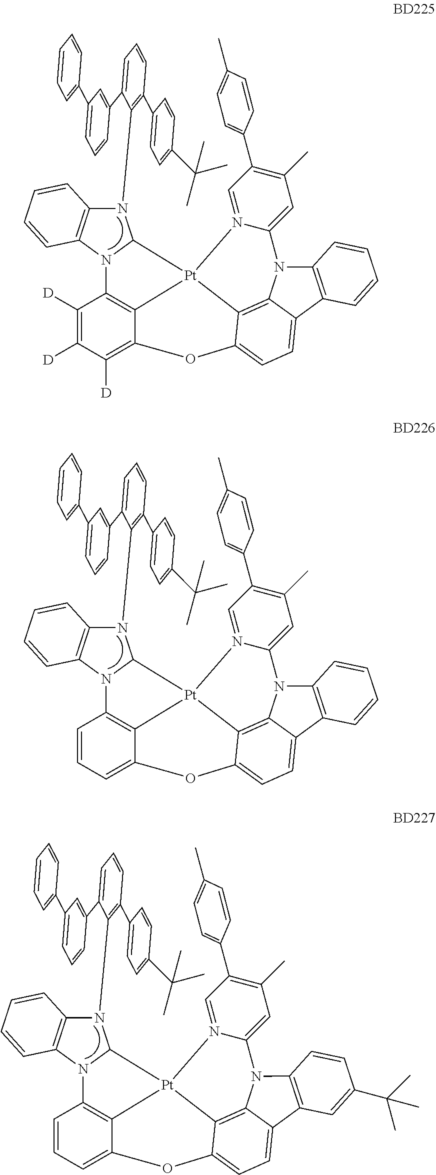

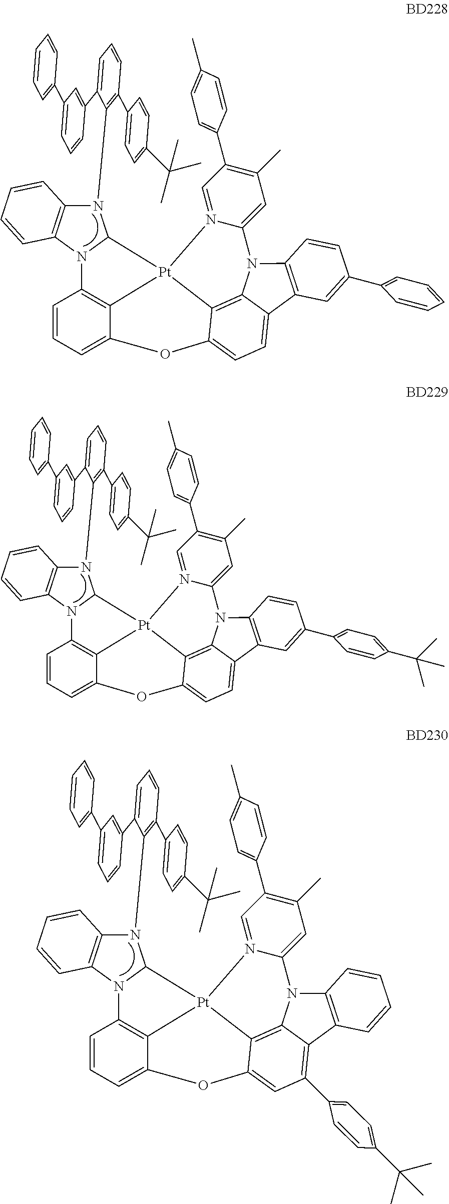

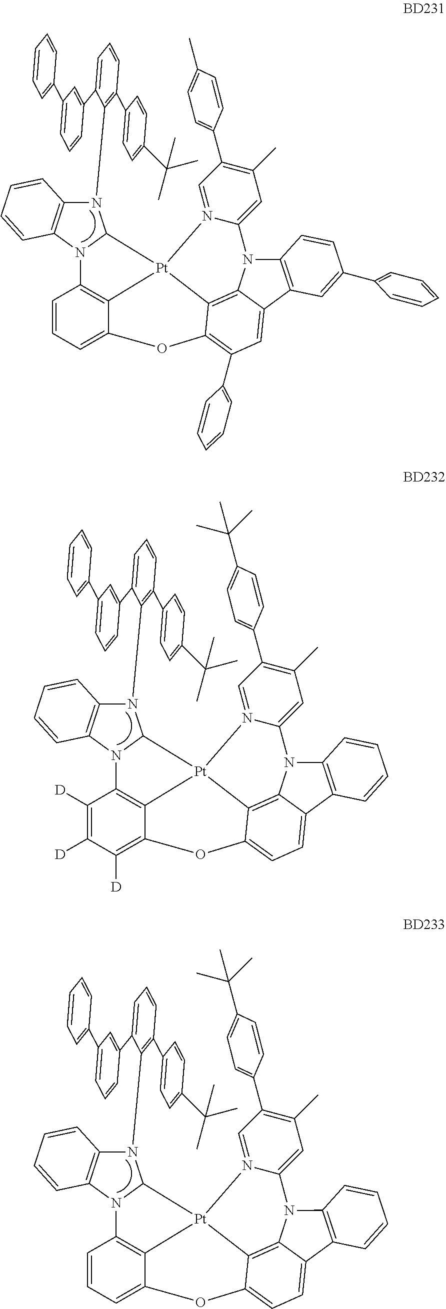

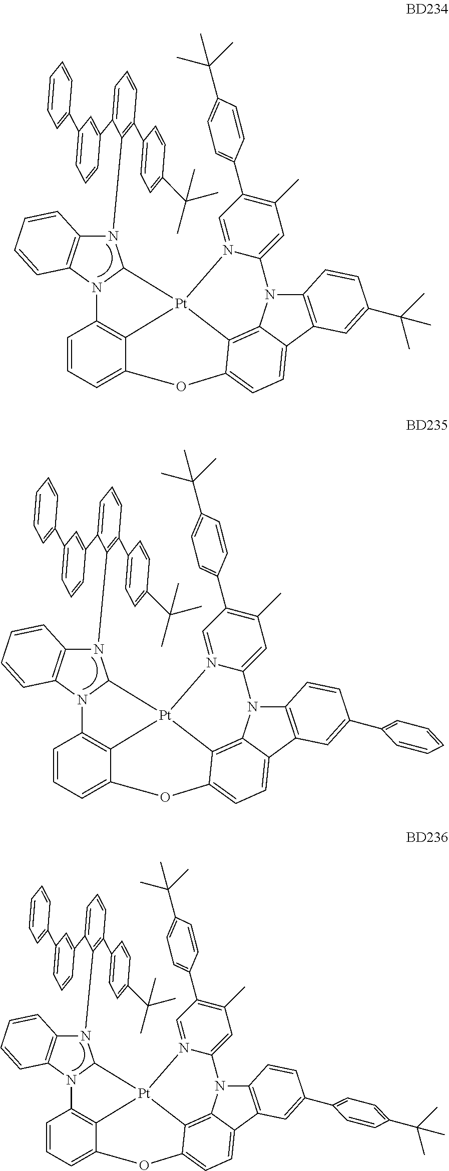

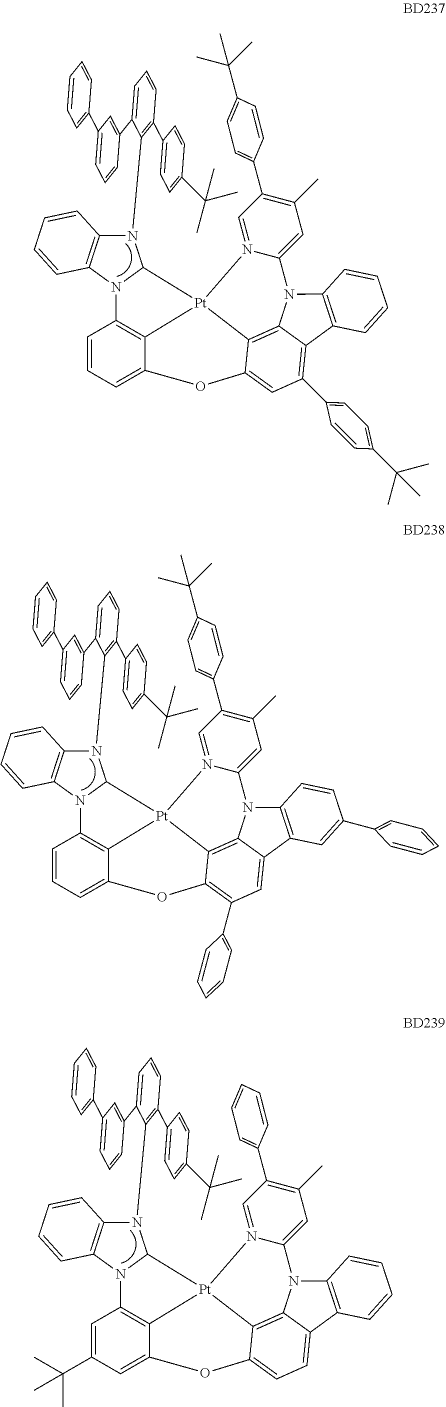

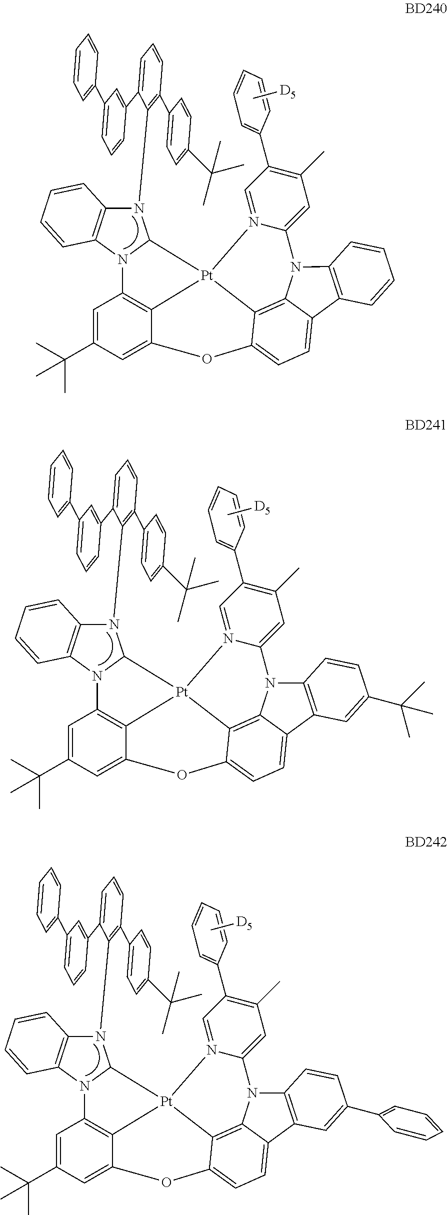

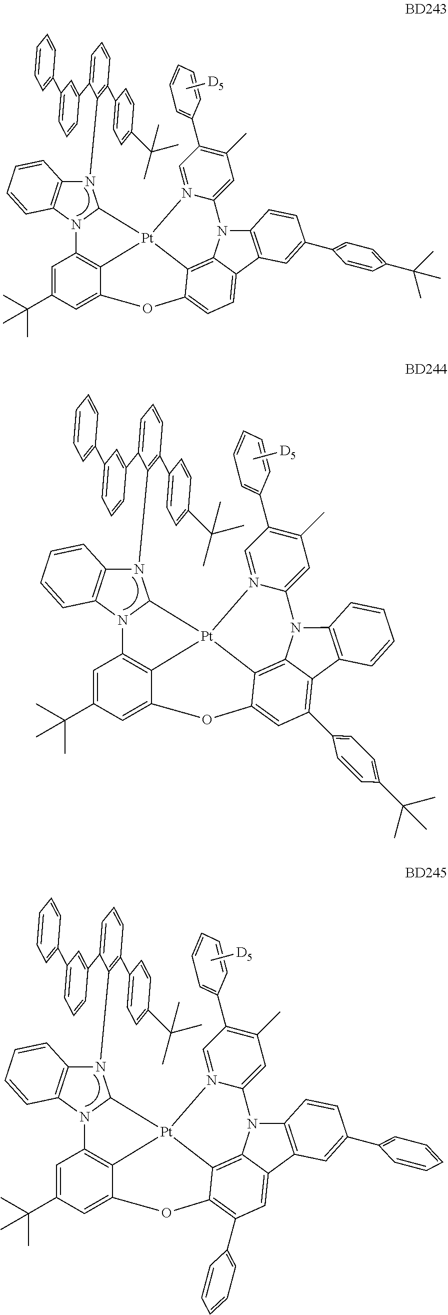

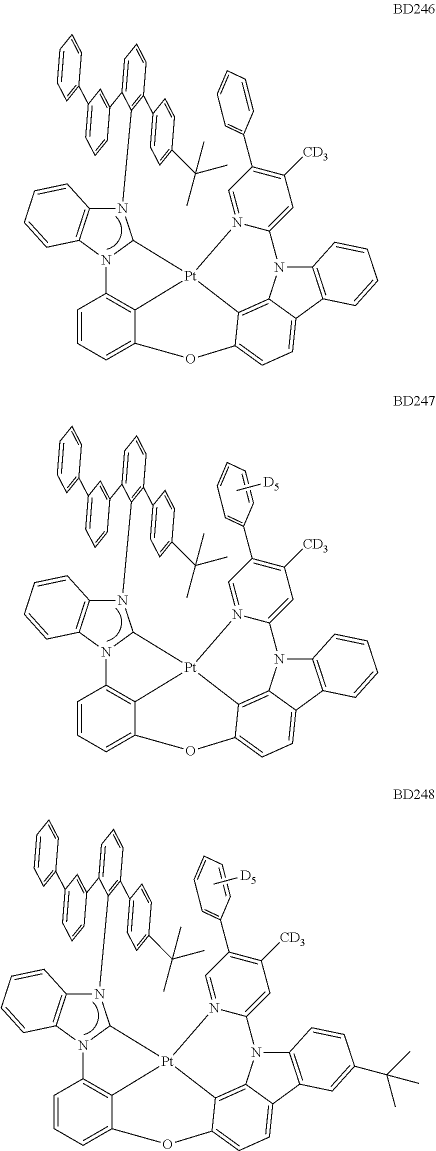

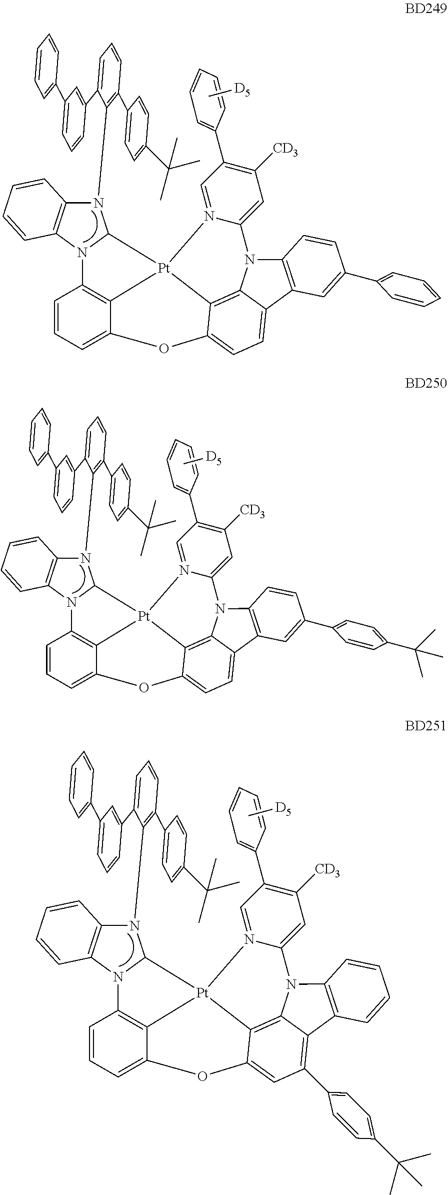

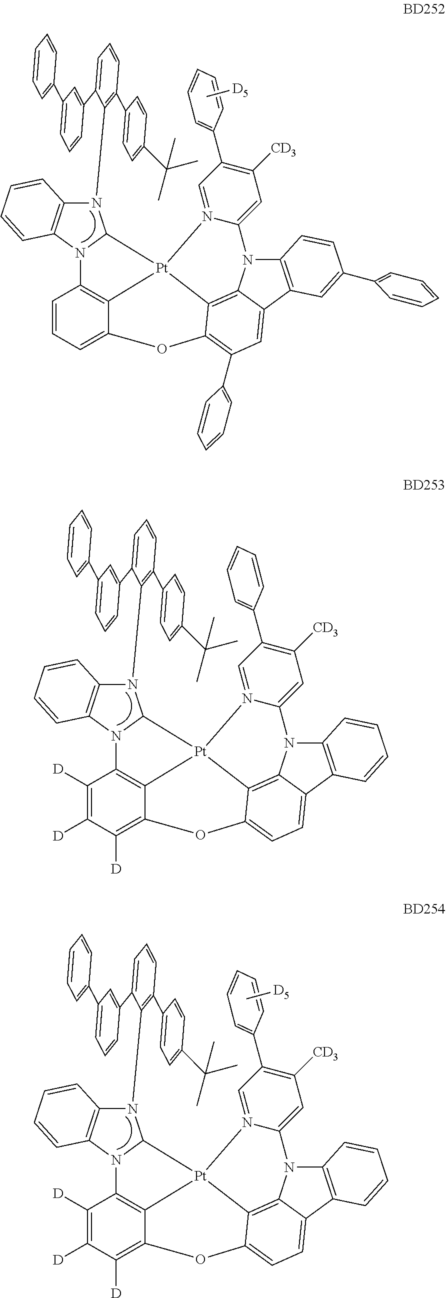

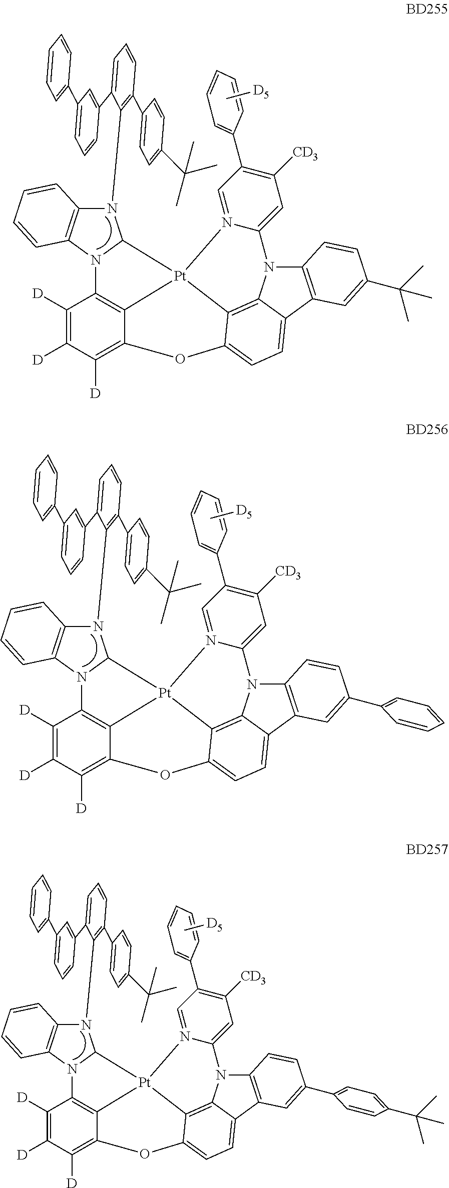

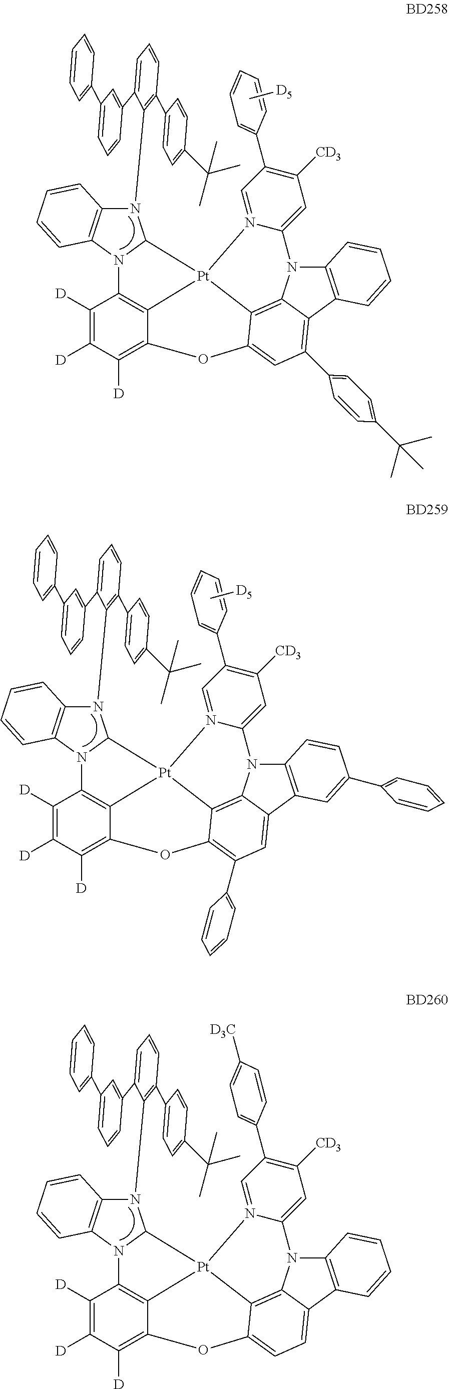

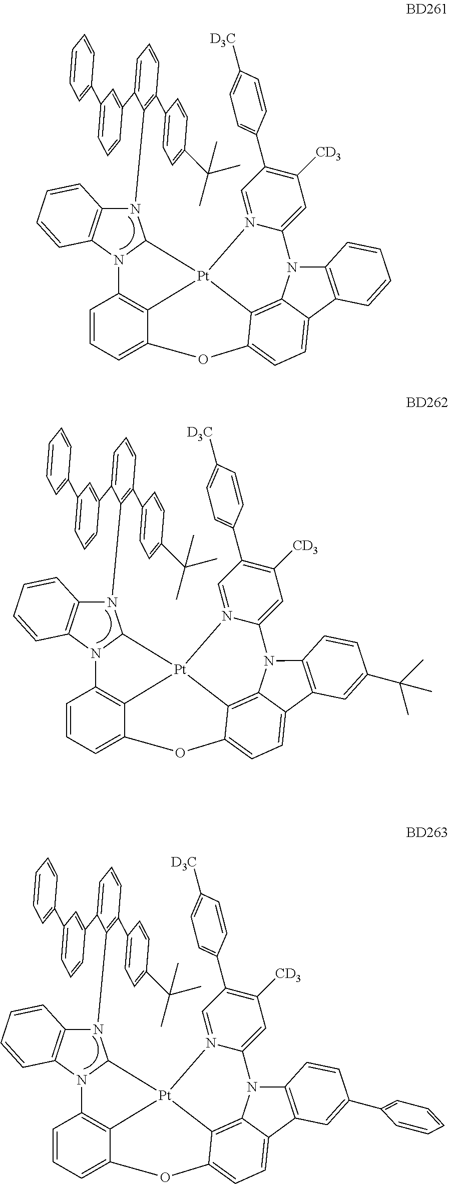

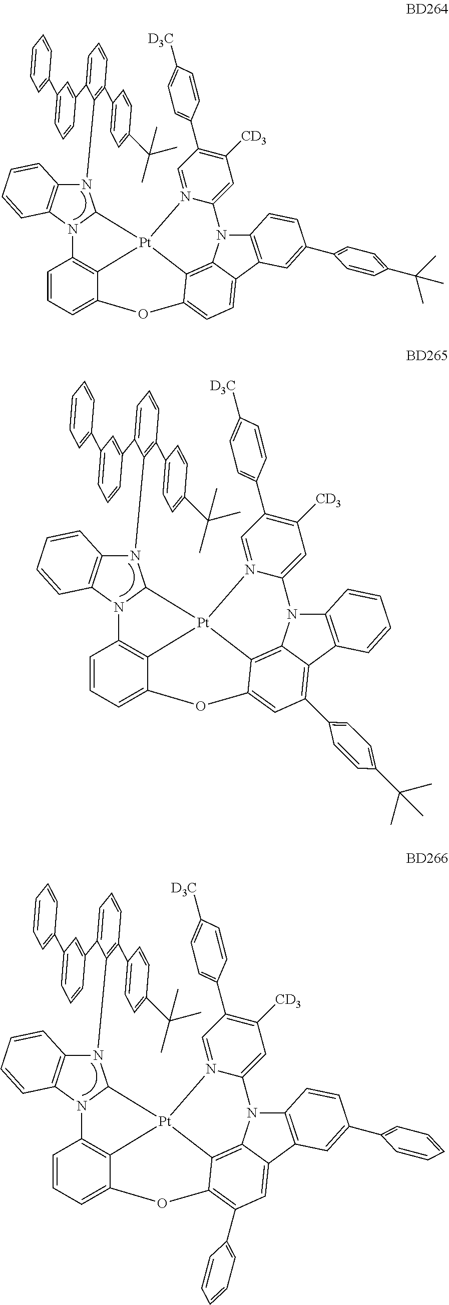

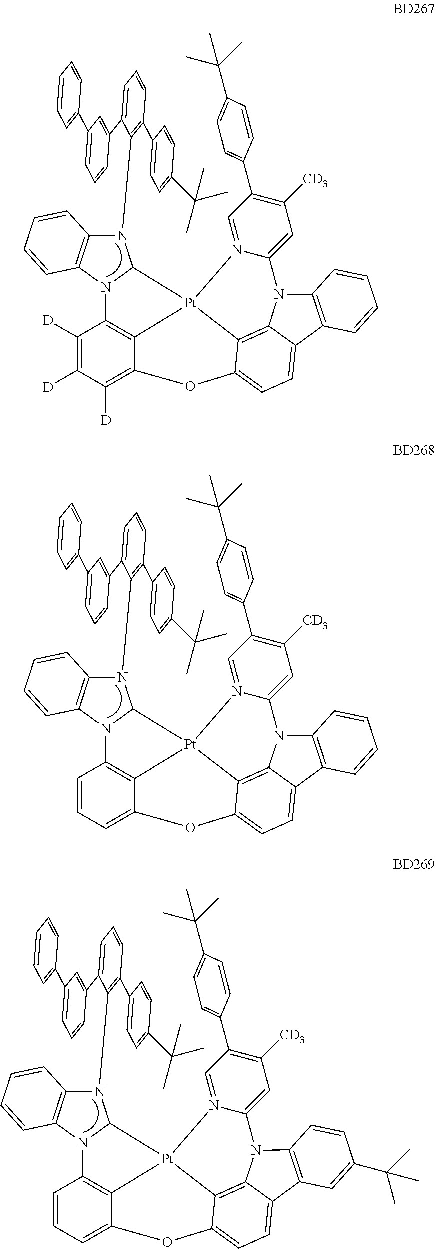

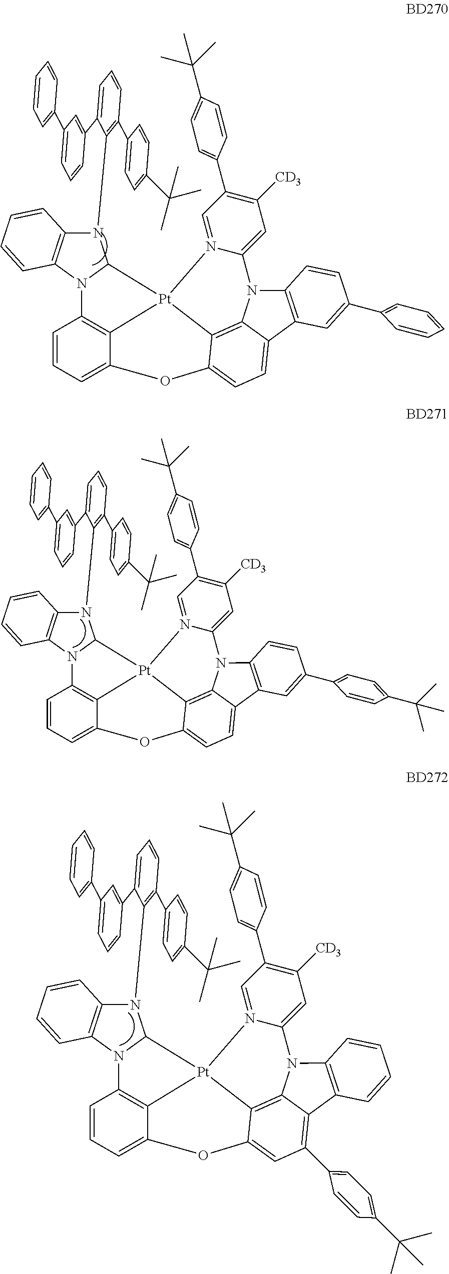

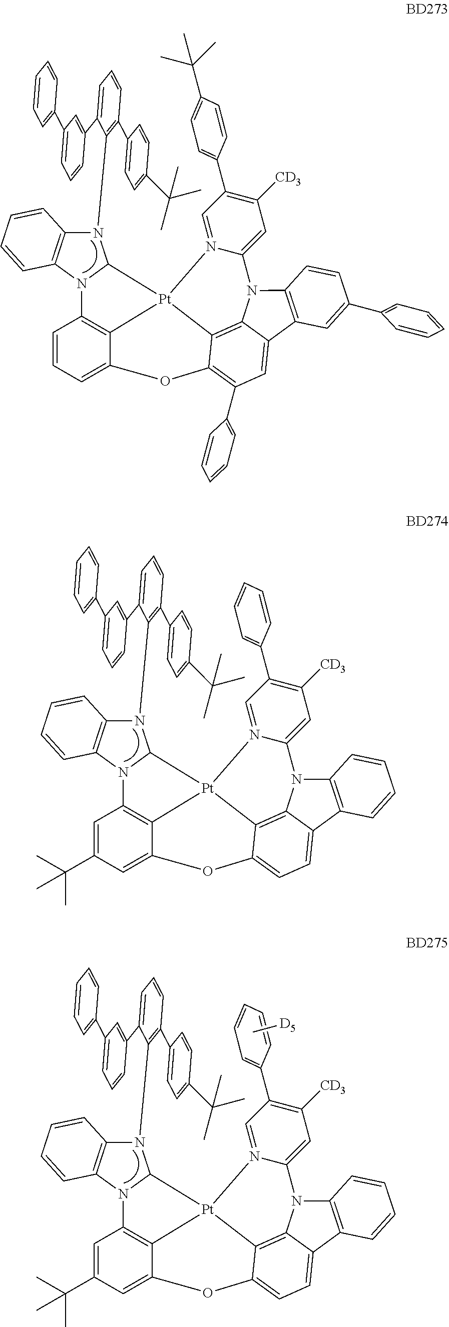

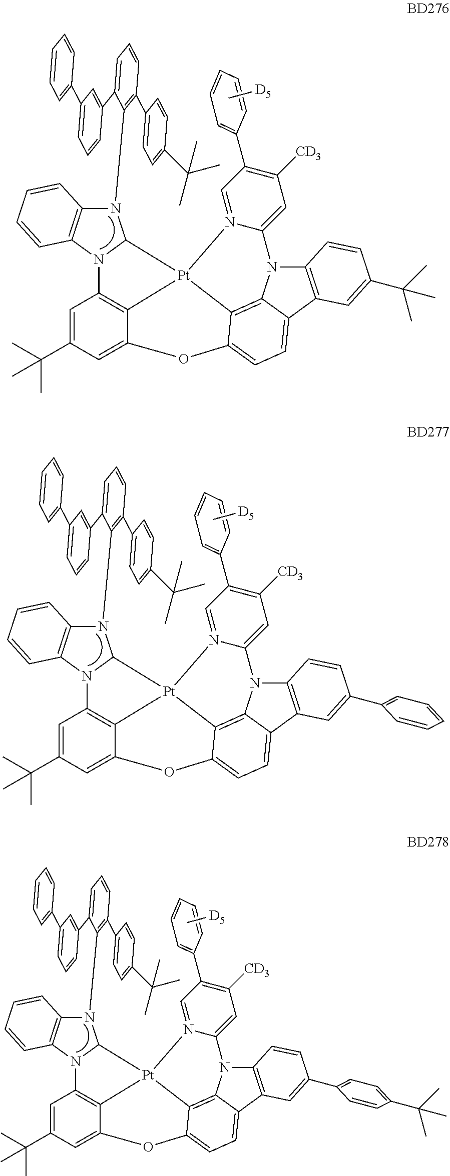

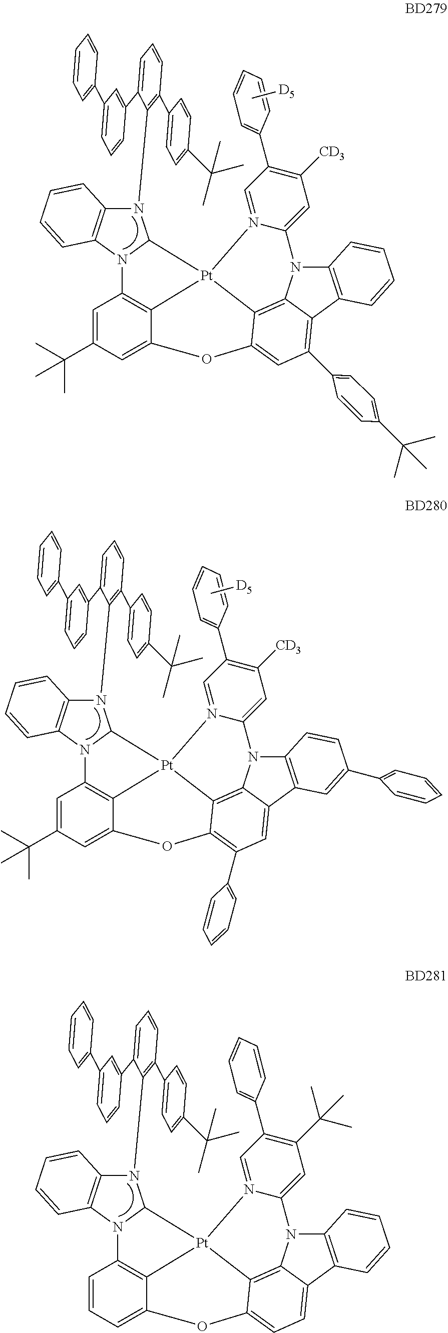

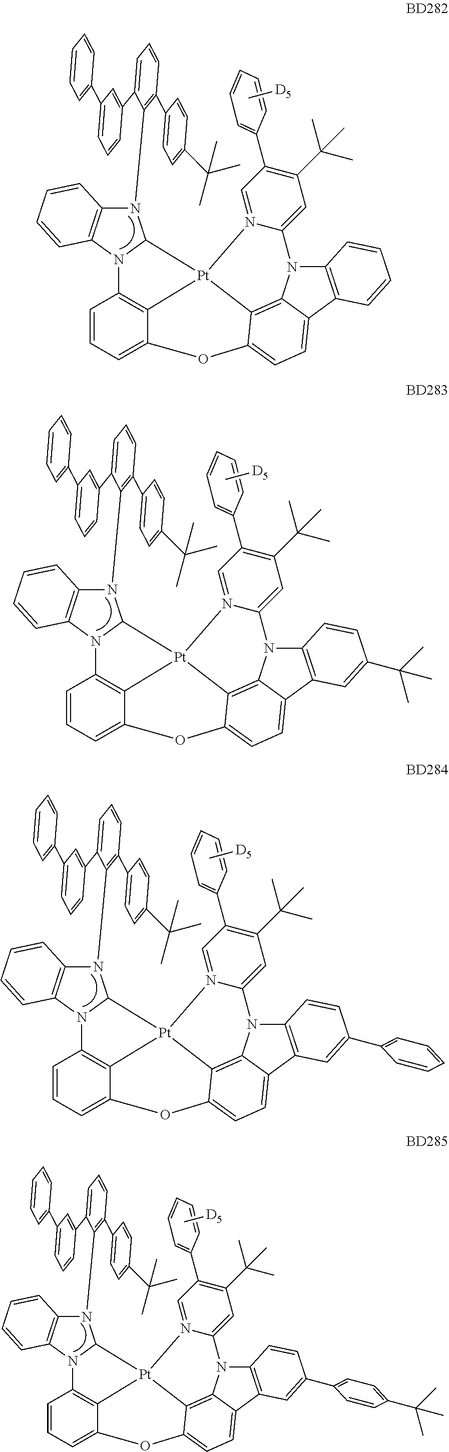

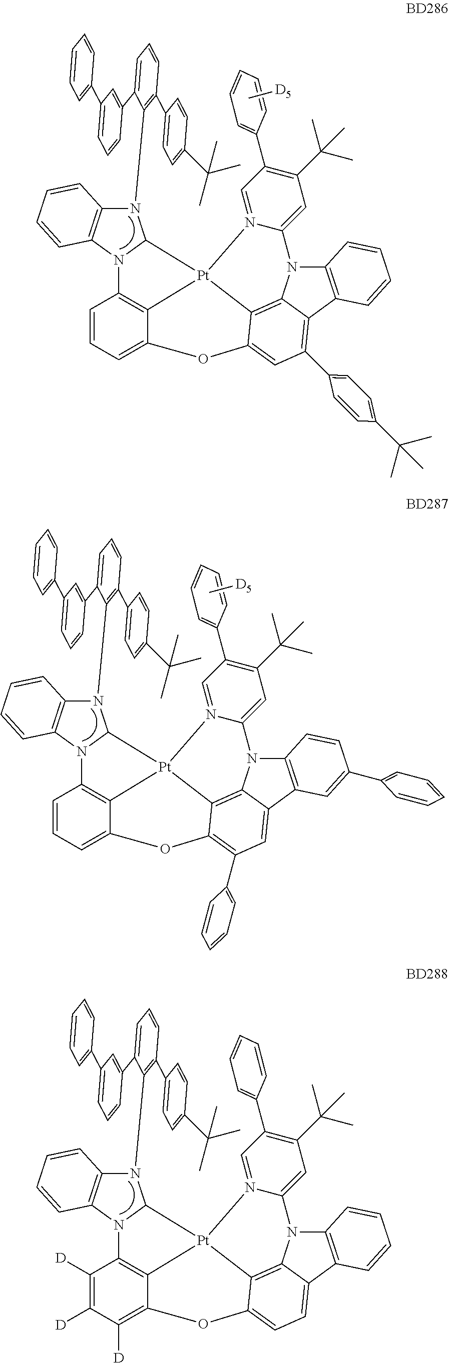

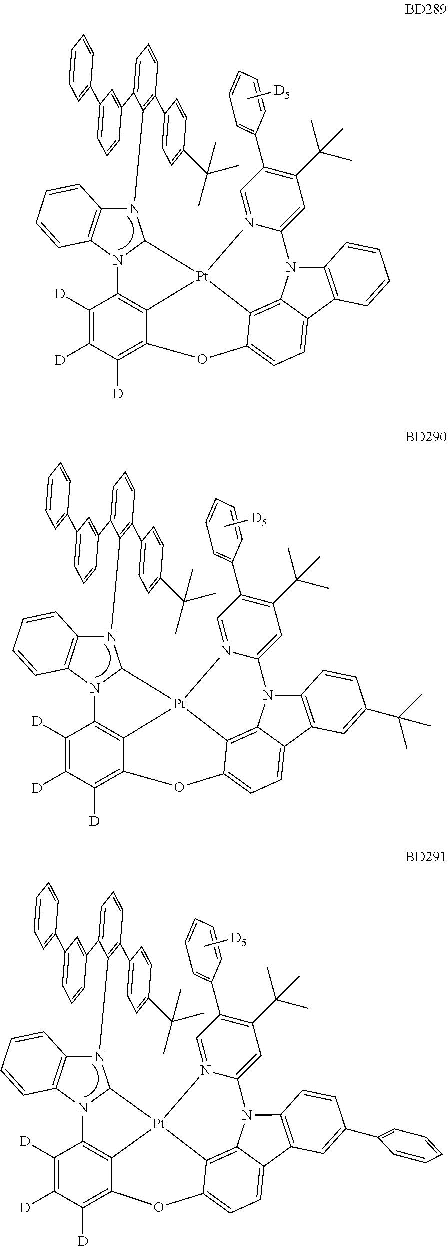

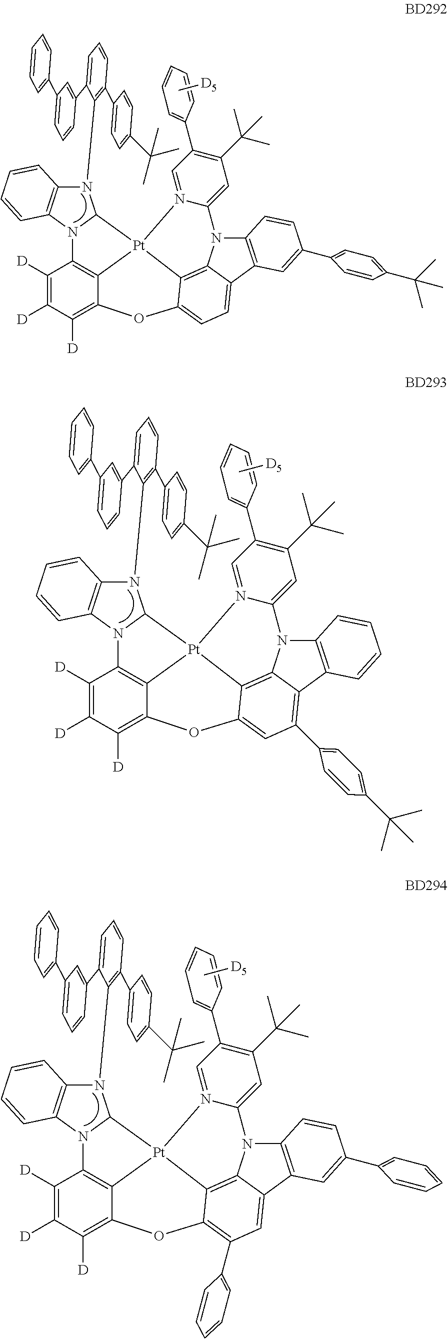

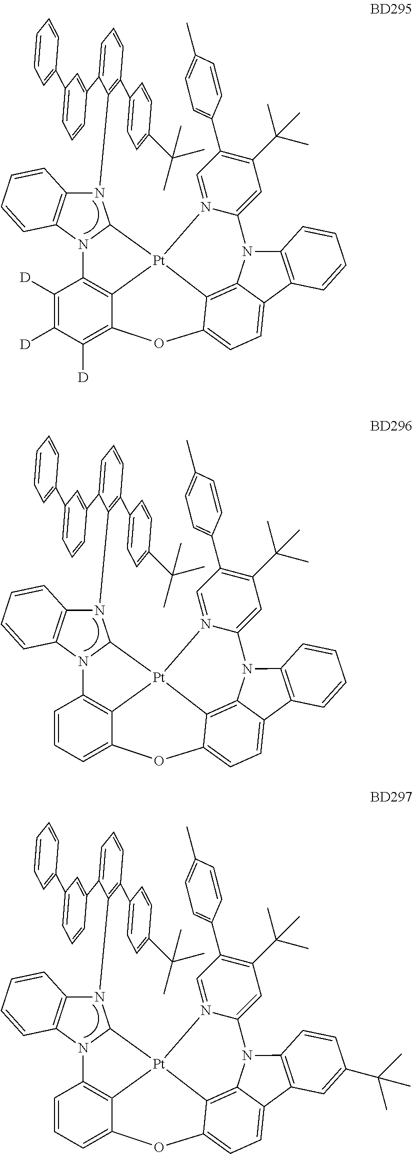

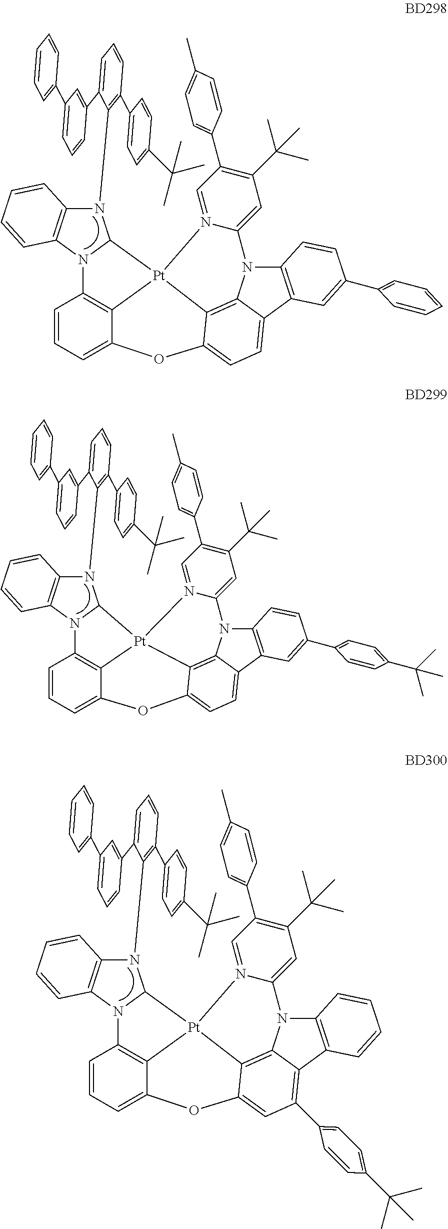

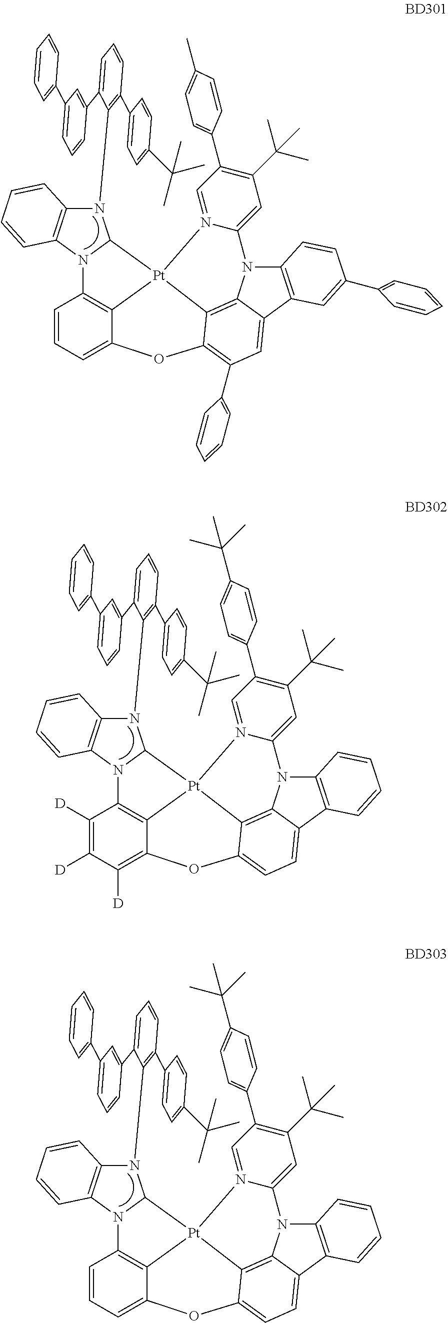

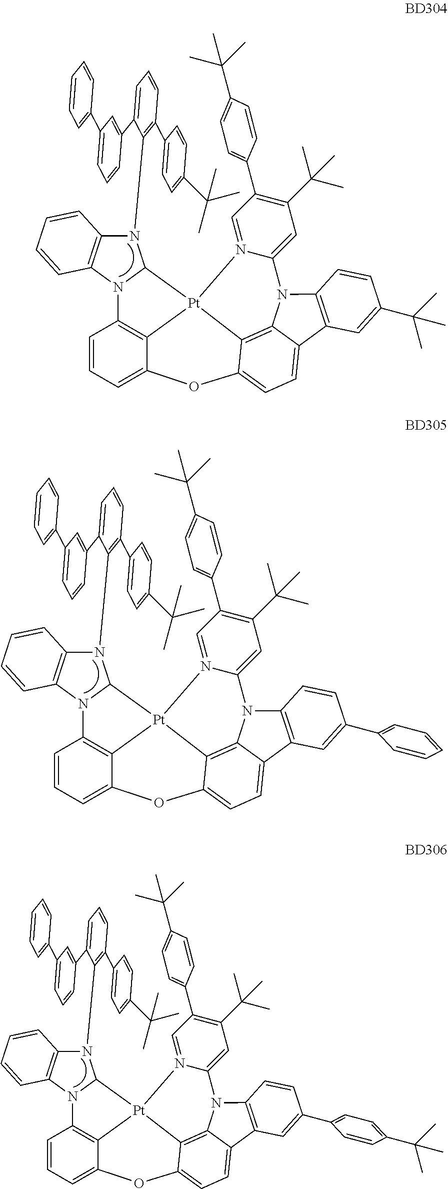

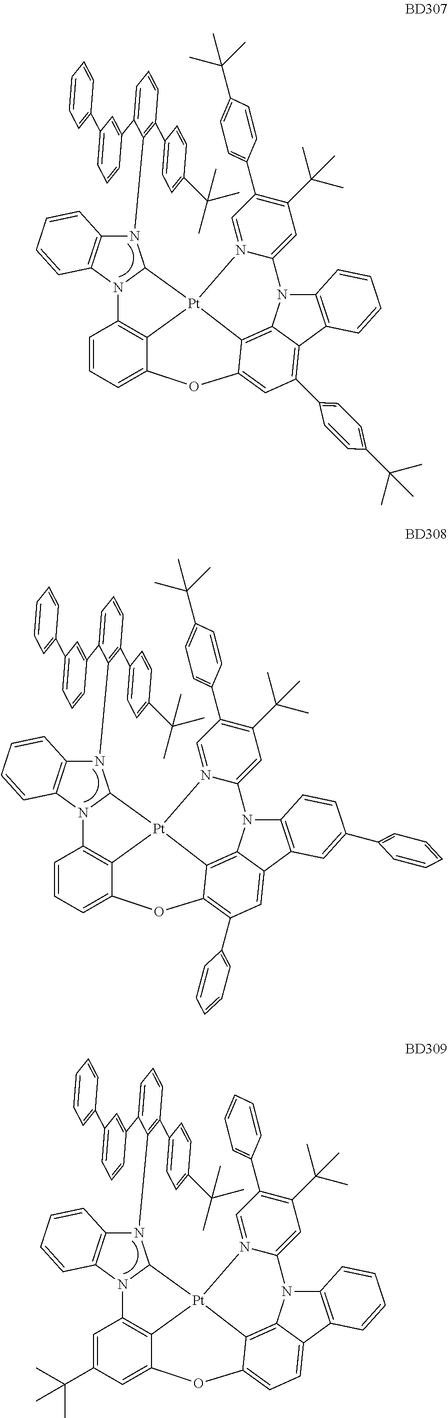

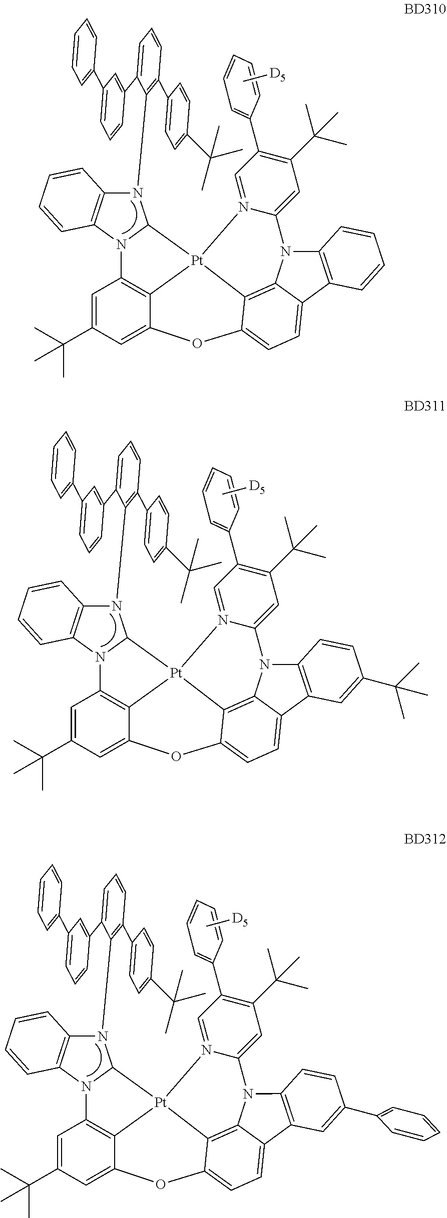

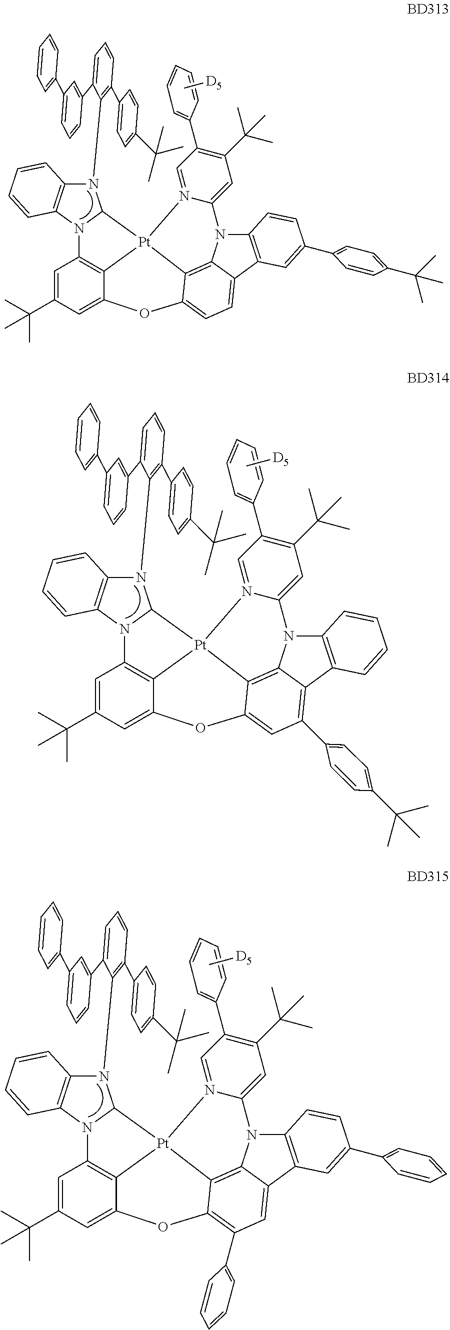

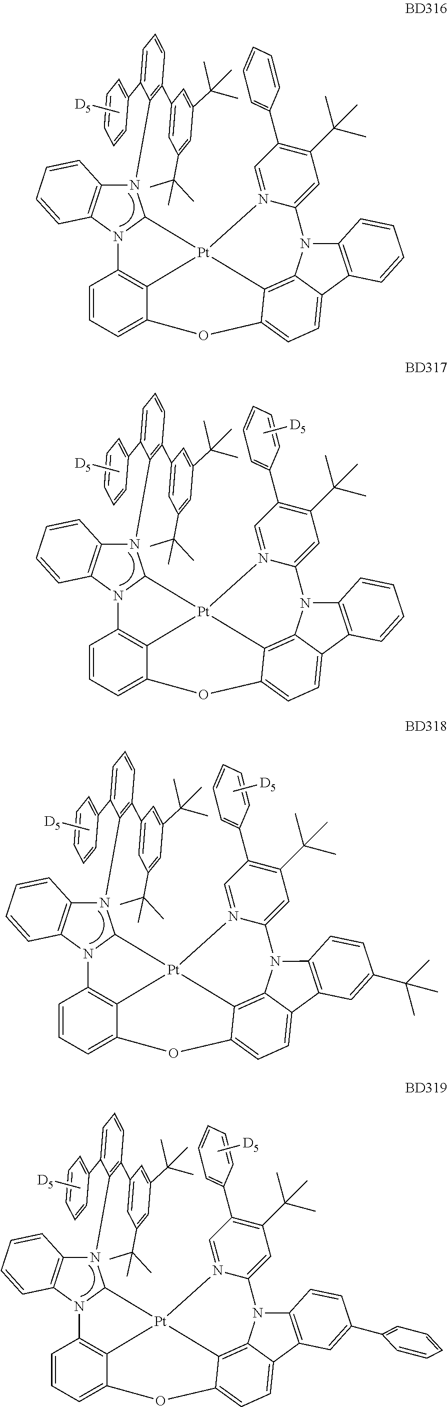

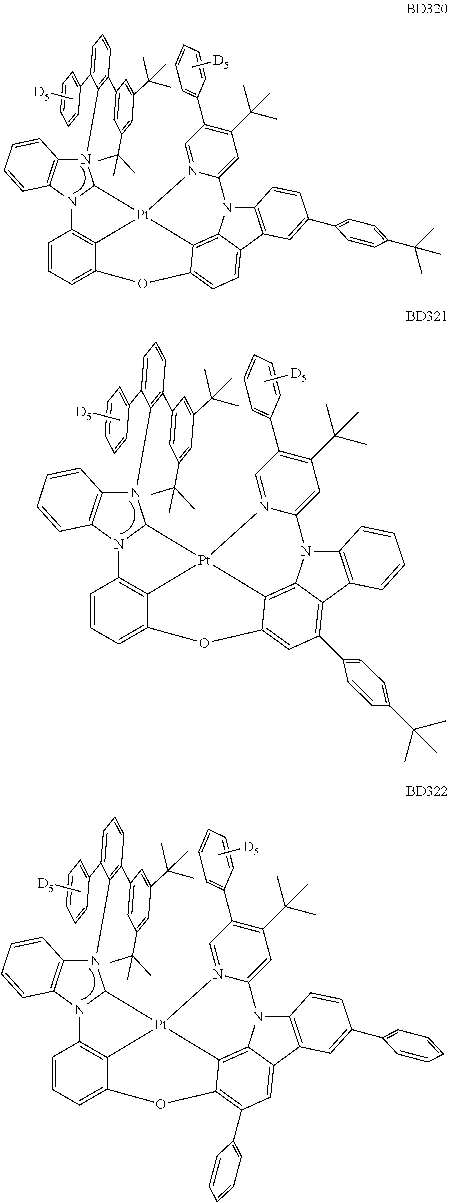

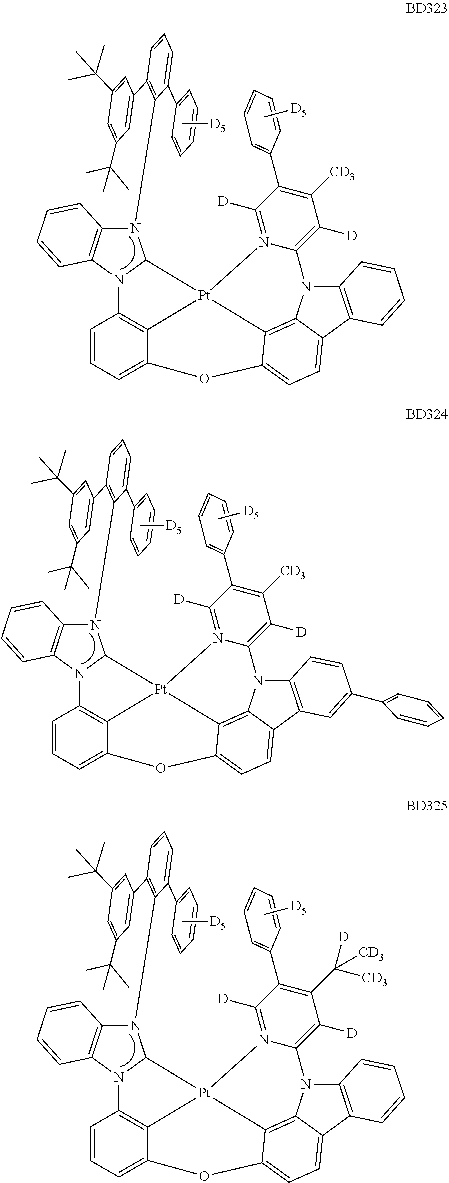

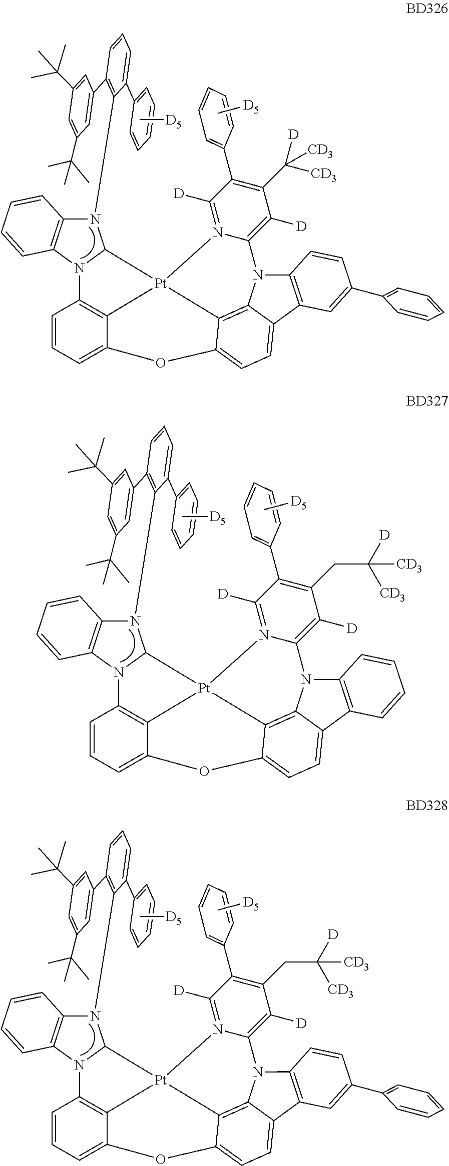

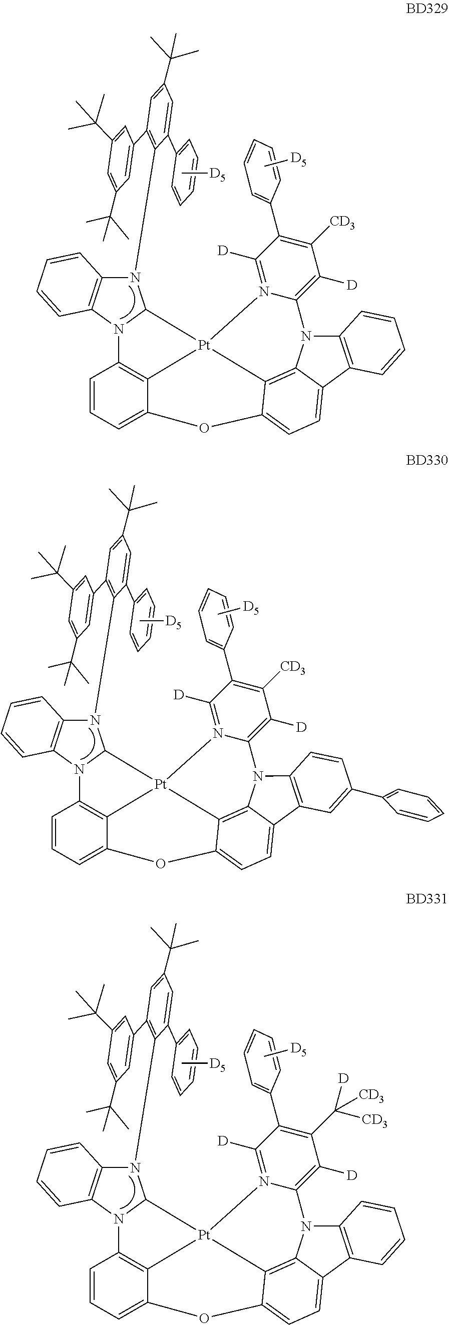

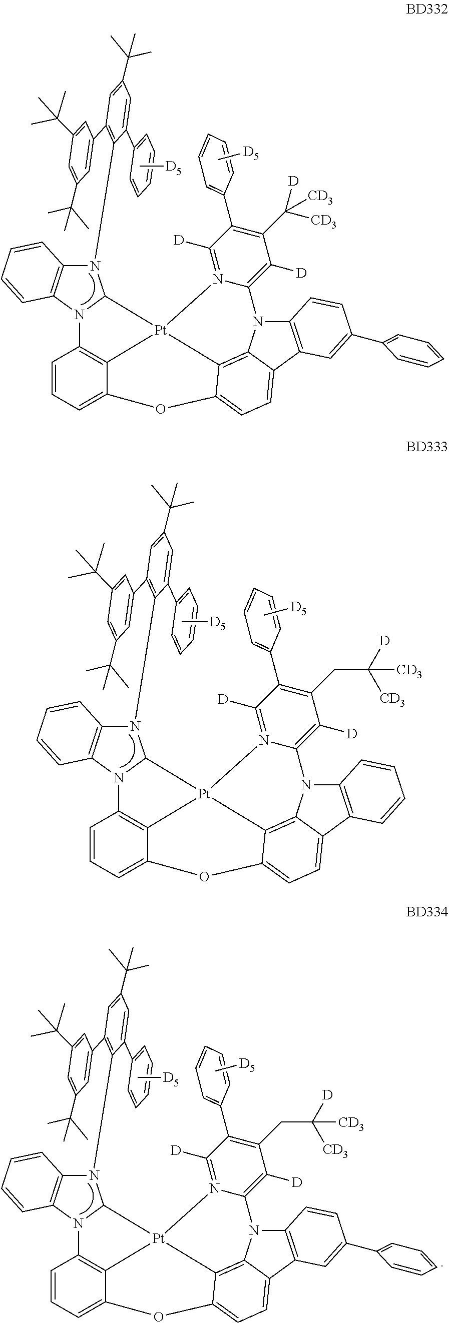

In an embodiment, the second compound may be one selected from Compounds ETH1 to ETH96 below:

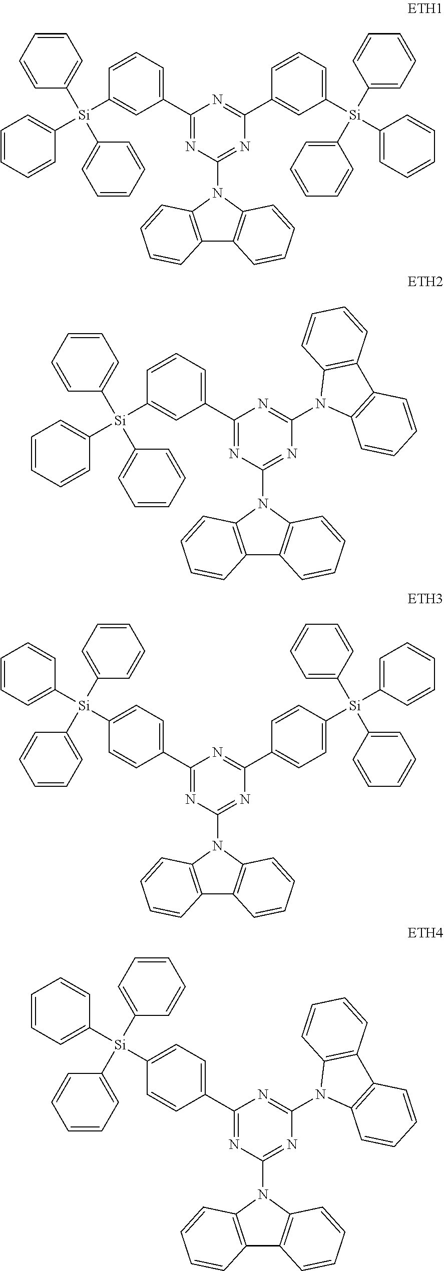

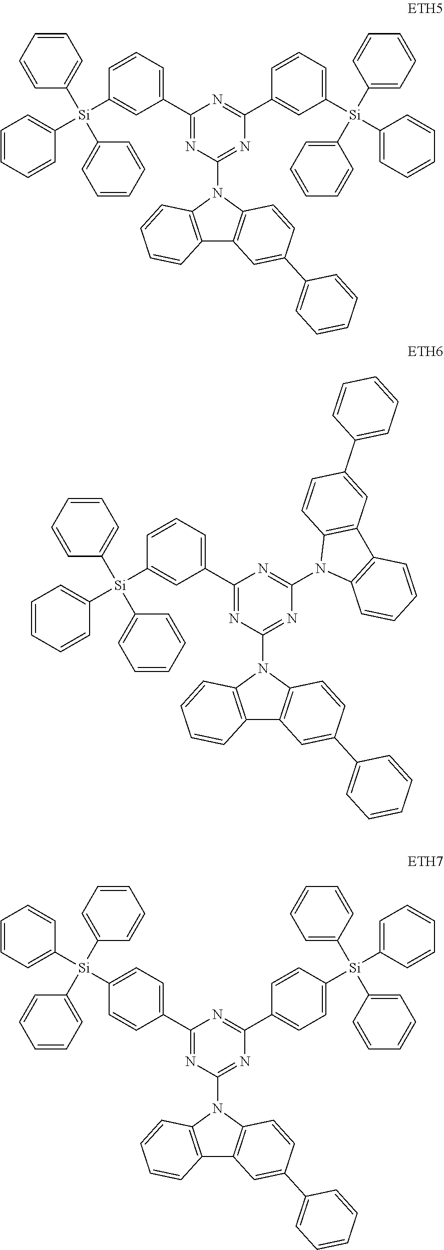 [SMILES: c1ccc(-c2ccc3c(c2)c2ccccc2n3-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; c1ccc(-c2ccc3c(c2)c2ccccc2n3-c2nc(-c3cccc([Si](c4ccccc4)(c4ccccc4)c4ccccc4)c3)nc(-n3c4ccccc4c4cc(-c5ccccc5)ccc43)n2)cc1 ; c1ccc(-c2ccc3c(c2)c2ccccc2n3-c2nc(-c3ccc([Si](c4ccccc4)(c4ccccc4)c4ccccc4)cc3)nc(-c3ccc([Si](c4ccccc4)(c4ccccc4)c4ccccc4)cc3)n2)cc1]

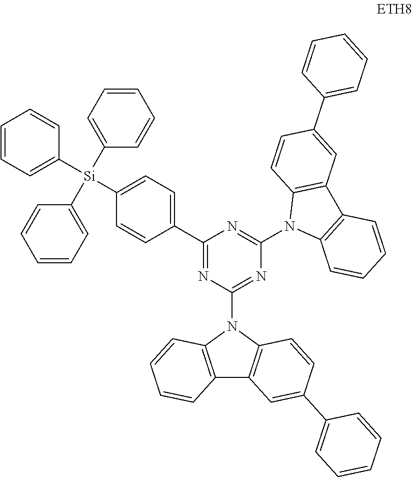 [SMILES: c1ccc(-c2ccc3c(c2)c2ccccc2n3-c2nc(-c3ccc([Si](c4ccccc4)(c4ccccc4)c4ccccc4)cc3)nc(-n3c4ccccc4c4cc(-c5ccccc5)ccc43)n2)cc1]

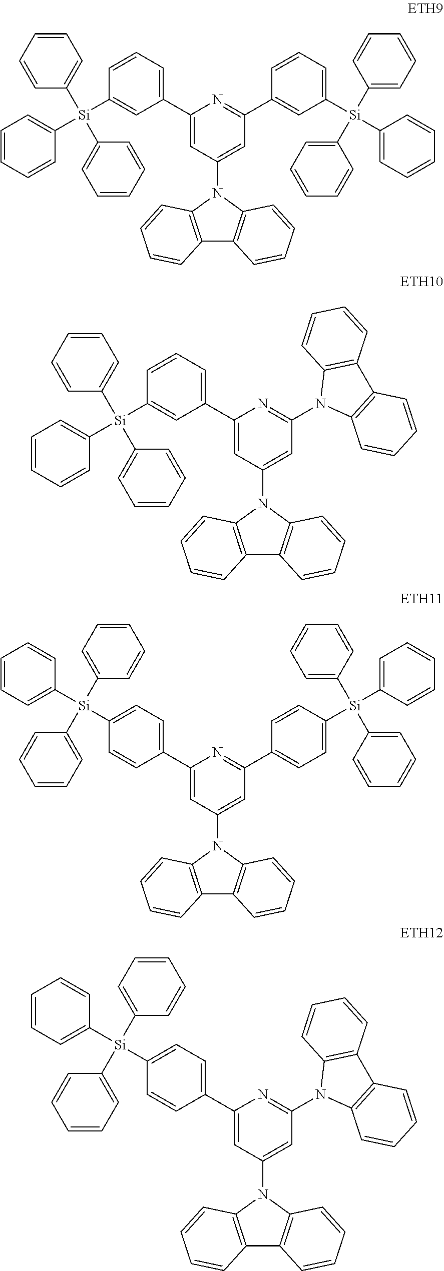

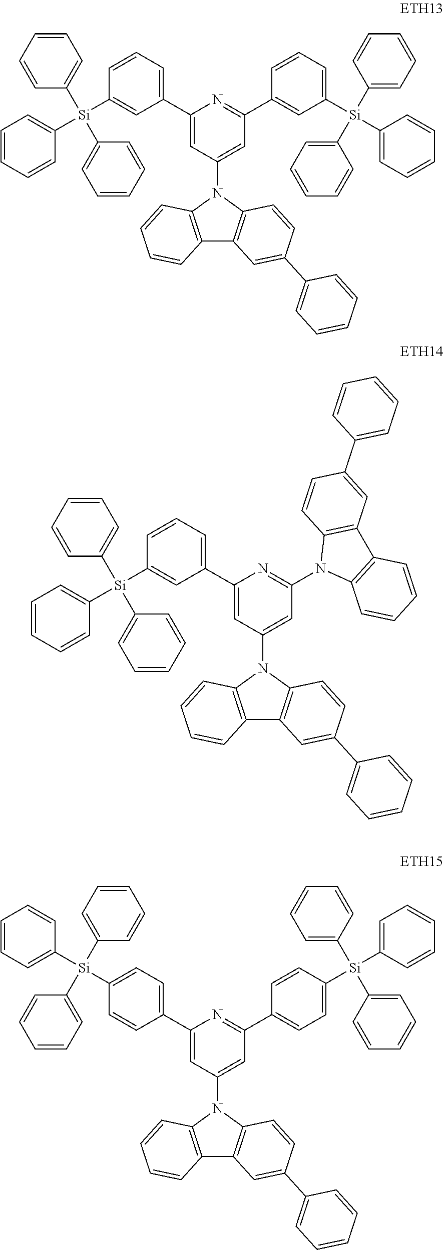 [SMILES: c1ccc(-c2ccc3c(c2)c2ccccc2n3-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; c1ccc(-c2ccc3c(c2)c2ccccc2n3-c2cc(-c3cccc([Si](c4ccccc4)(c4ccccc4)c4ccccc4)c3)nc(-n3c4ccccc4c4cc(-c5ccccc5)ccc43)c2)cc1 ; c1ccc(-c2ccc3c(c2)c2ccccc2n3-c2cc(-c3ccc([Si](c4ccccc4)(c4ccccc4)c4ccccc4)cc3)nc(-c3ccc([Si](c4ccccc4)(c4ccccc4)c4ccccc4)cc3)c2)cc1]

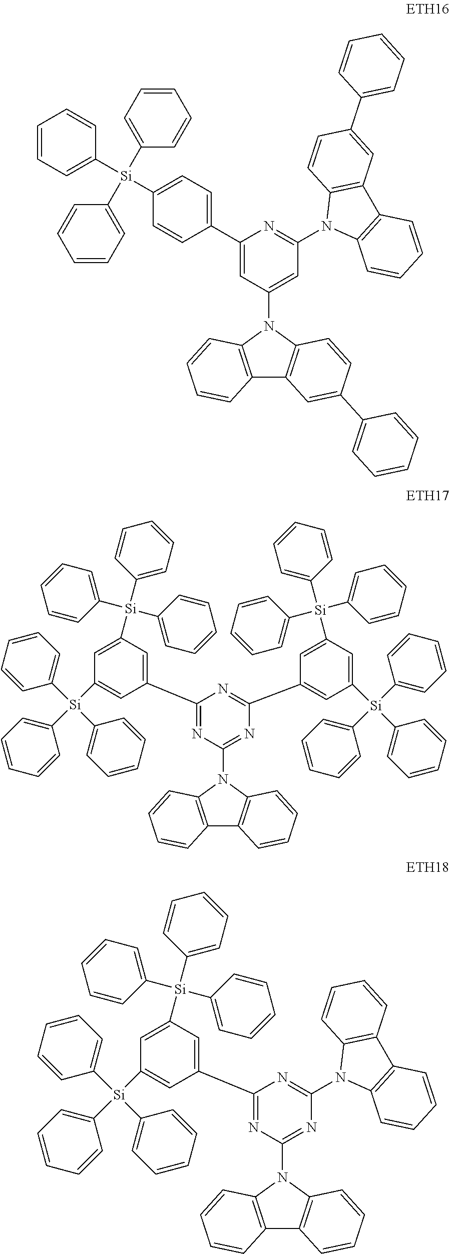 [SMILES: c1ccc(-c2ccc3c(c2)c2ccccc2n3-c2cc(-c3ccc([Si](c4ccccc4)(c4ccccc4)c4ccccc4)cc3)nc(-n3c4ccccc4c4cc(-c5ccccc5)ccc43)c2)cc1 ; c1ccc([Si](c2ccccc2)(c2ccccc2)c2cc(-c3nc(-c4cc([Si](c5ccccc5)(c5ccccc5)c5ccccc5)cc([Si](c5ccccc5)(c5ccccc5)c5ccccc5)c4)nc(-n4c5ccccc5c5ccccc54)n3)cc([Si](c3ccccc3)(c3ccccc3)c3ccccc3)c2)cc1 ; c1ccc([Si](c2ccccc2)(c2ccccc2)c2cc(-c3nc(-n4c5ccccc5c5ccccc54)nc(-n4c5ccccc5c5ccccc54)n3)cc([Si](c3ccccc3)(c3ccccc3)c3ccccc3)c2)cc1]

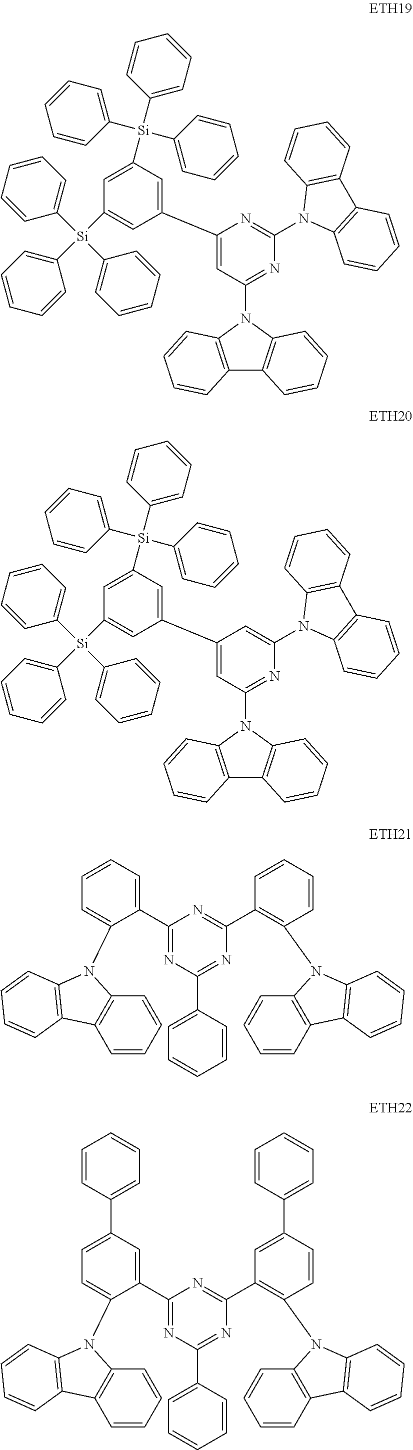 [SMILES: c1ccc([Si](c2ccccc2)(c2ccccc2)c2cc(-c3cc(-n4c5ccccc5c5ccccc54)nc(-n4c5ccccc5c5ccccc54)n3)cc([Si](c3ccccc3)(c3ccccc3)c3ccccc3)c2)cc1 ; c1ccc([Si](c2ccccc2)(c2ccccc2)c2cc(-c3cc(-n4c5ccccc5c5ccccc54)nc(-n4c5ccccc5c5ccccc54)c3)cc([Si](c3ccccc3)(c3ccccc3)c3ccccc3)c2)cc1 ; c1ccc(-c2nc(-c3ccccc3-n3c4ccccc4c4ccccc43)nc(-c3ccccc3-n3c4ccccc4c4ccccc43)n2)cc1 ; c1ccc(-c2ccc(-n3c4ccccc4c4ccccc43)c(-c3nc(-c4ccccc4)nc(-c4cc(-c5ccccc5)ccc4-n4c5ccccc5c5ccccc54)n3)c2)cc1]

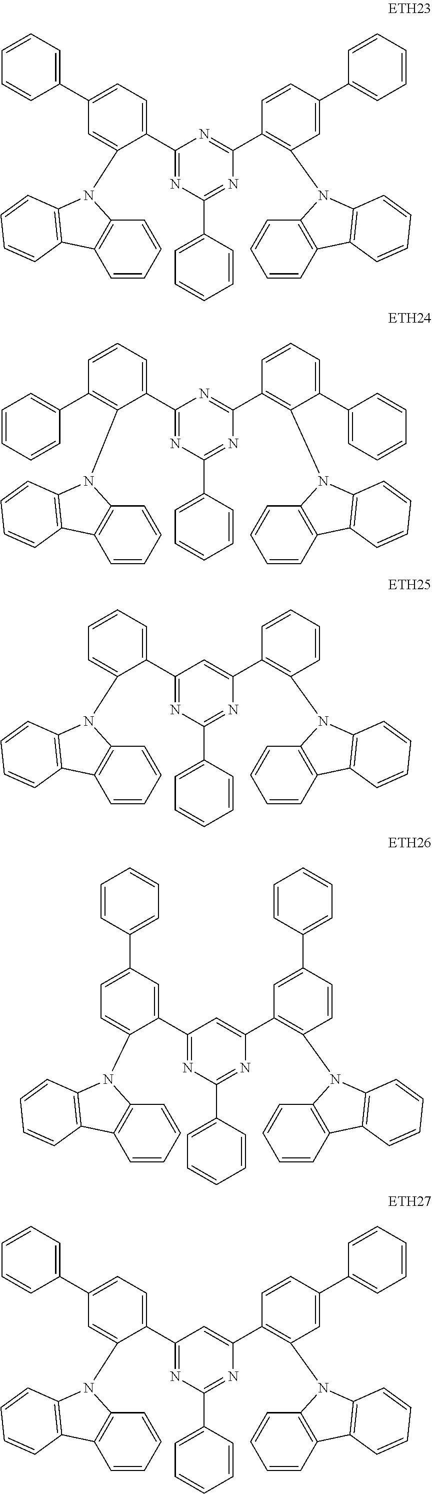

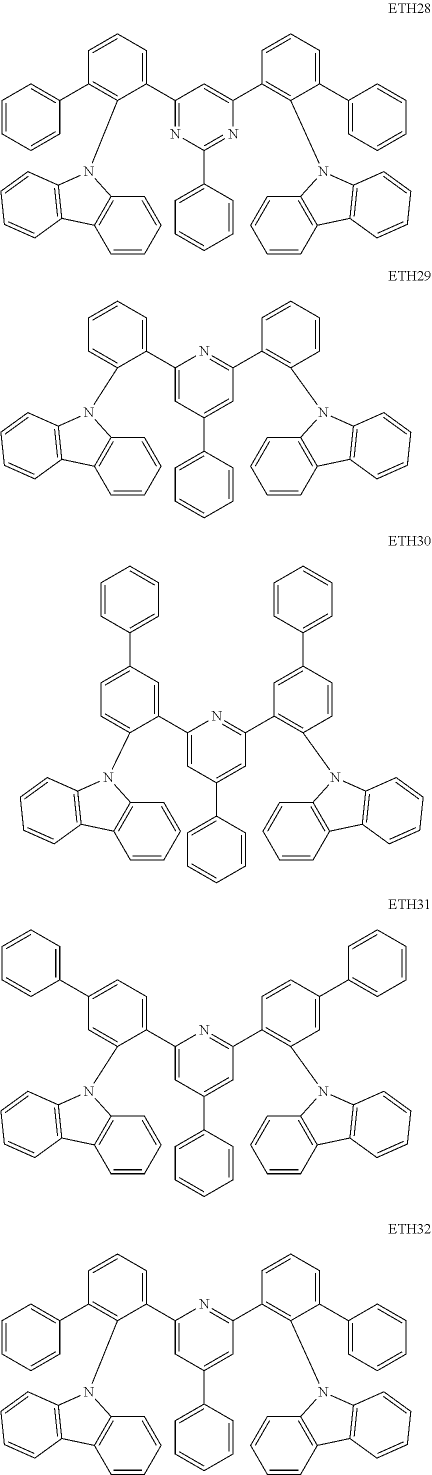

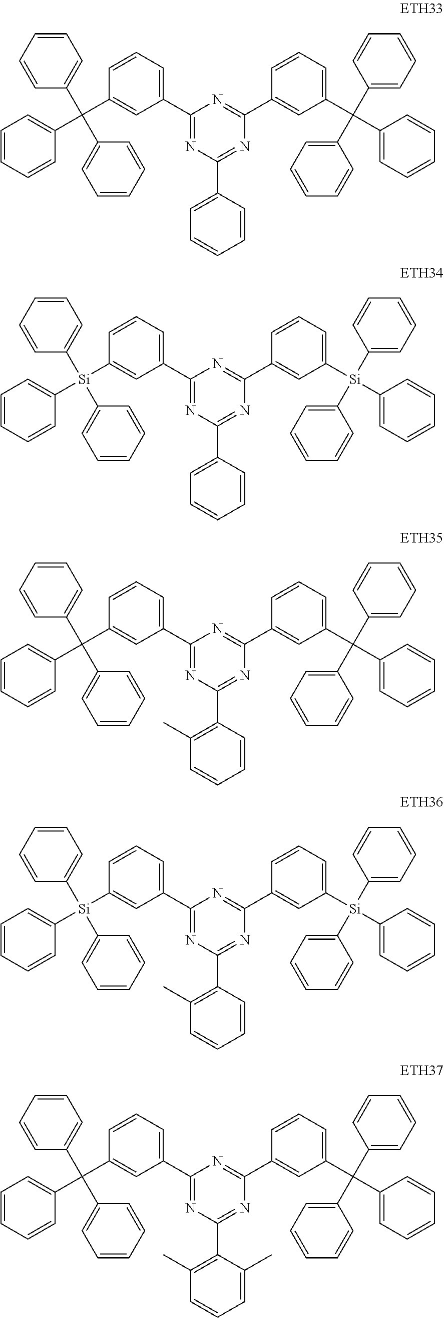

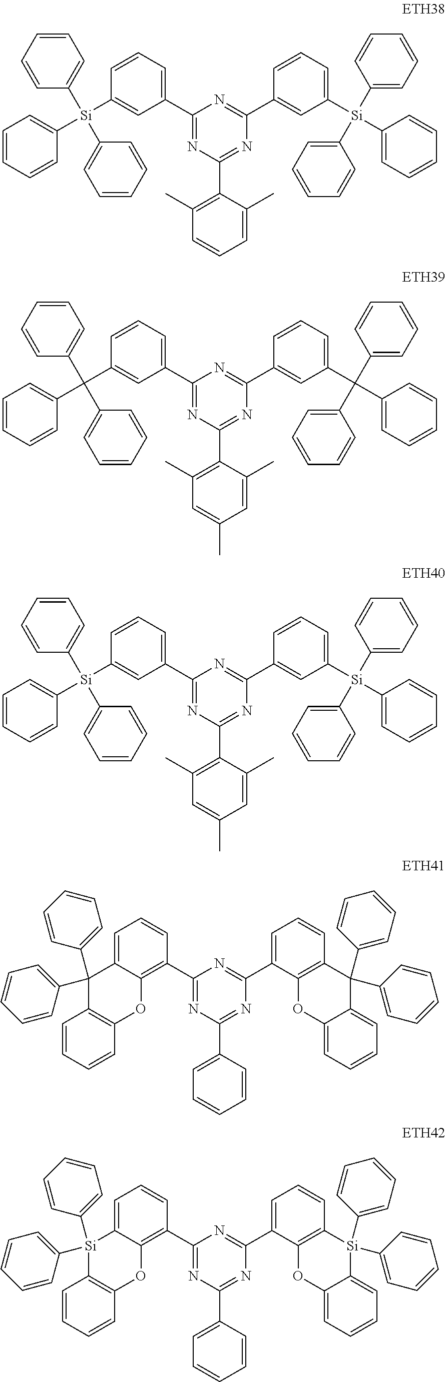

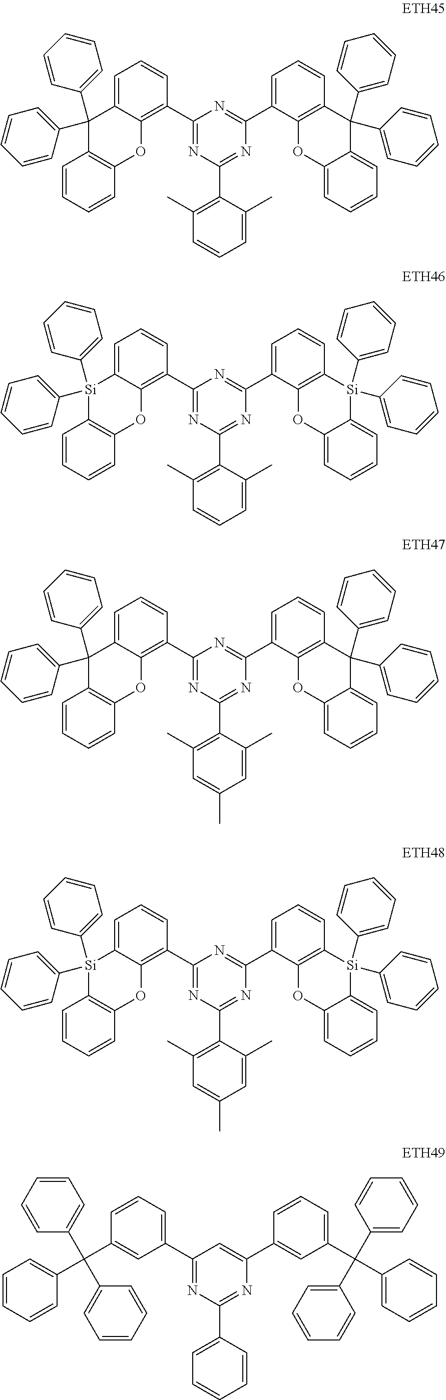

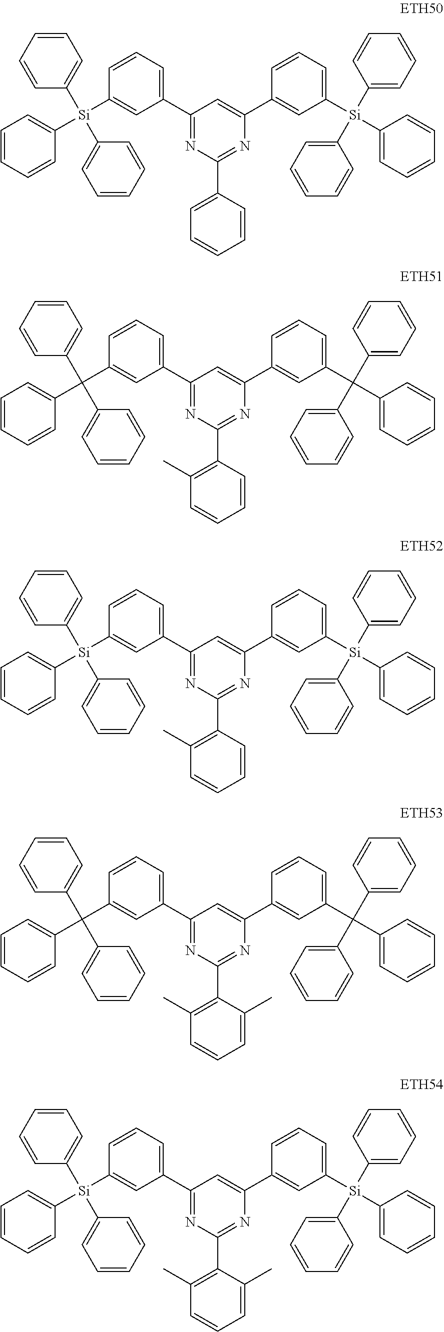

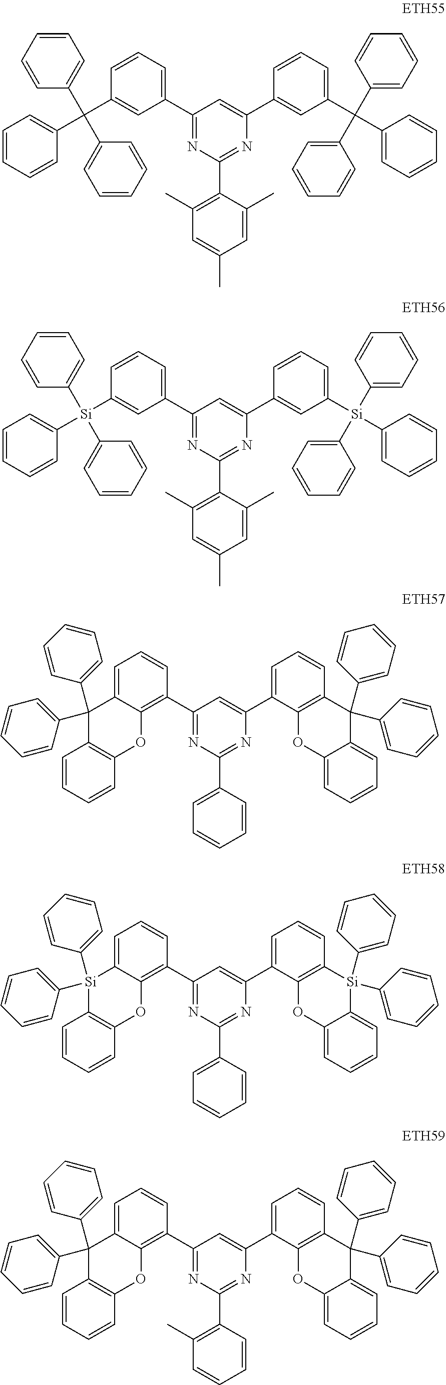

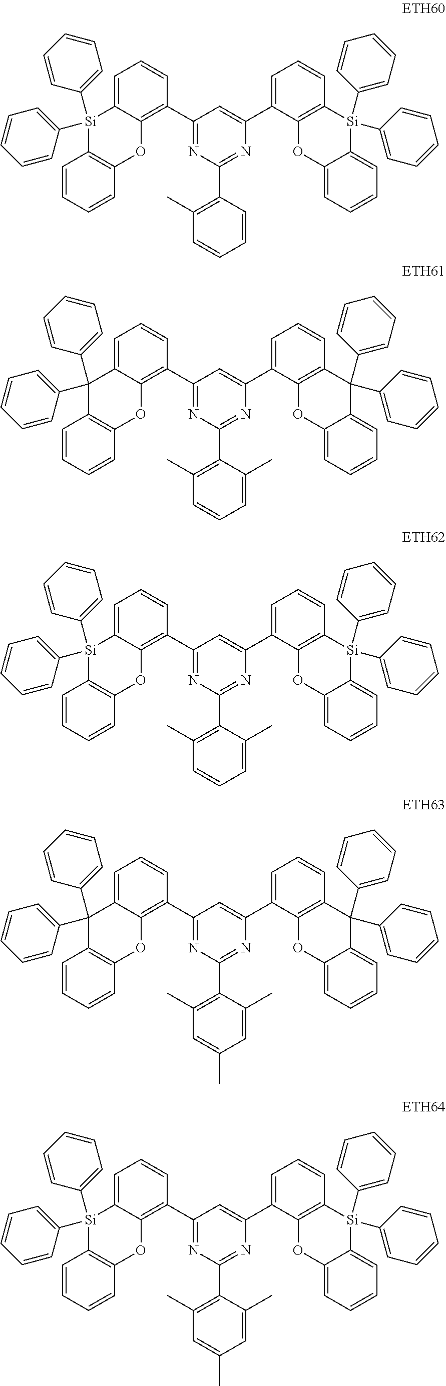

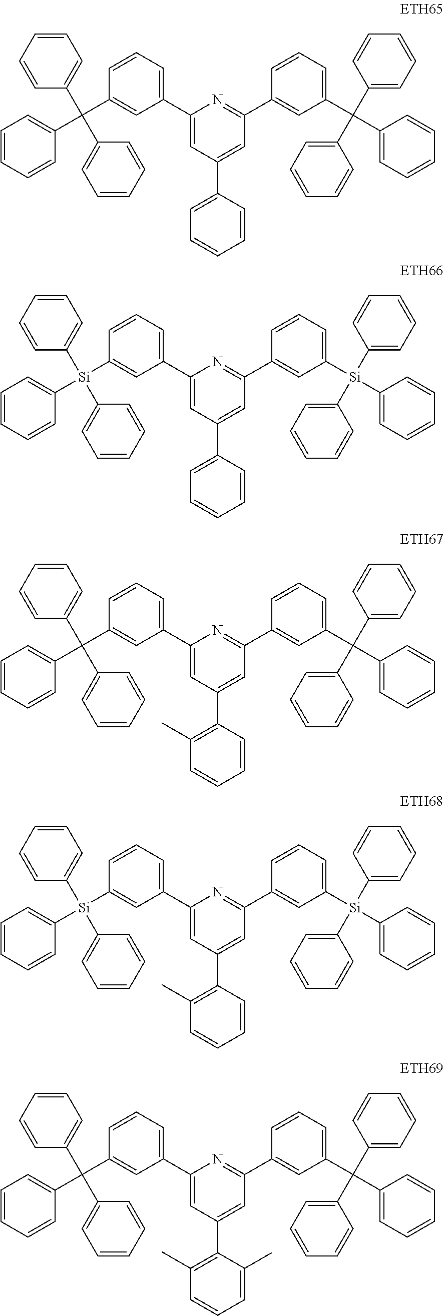

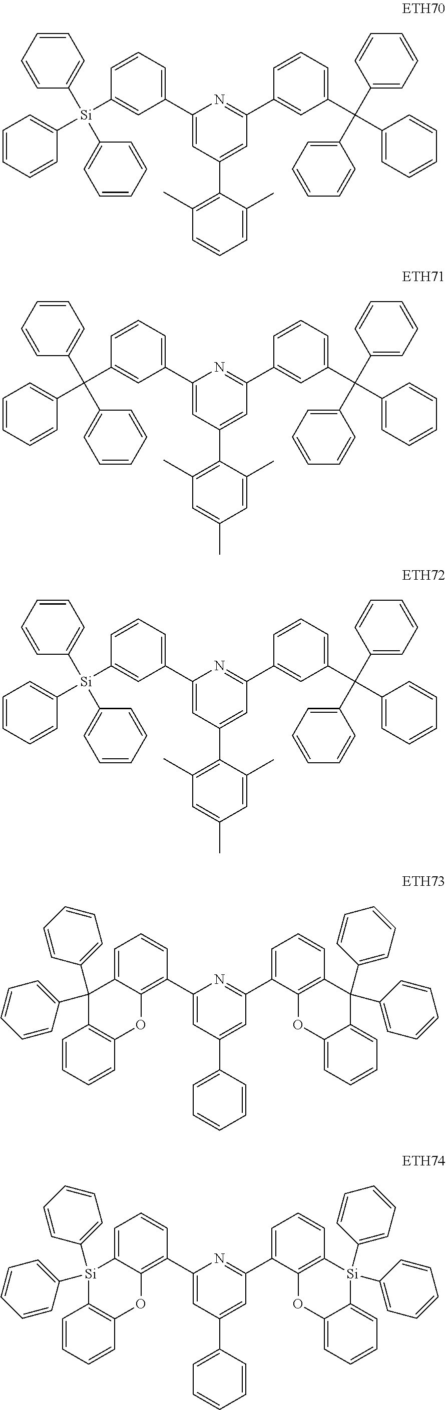

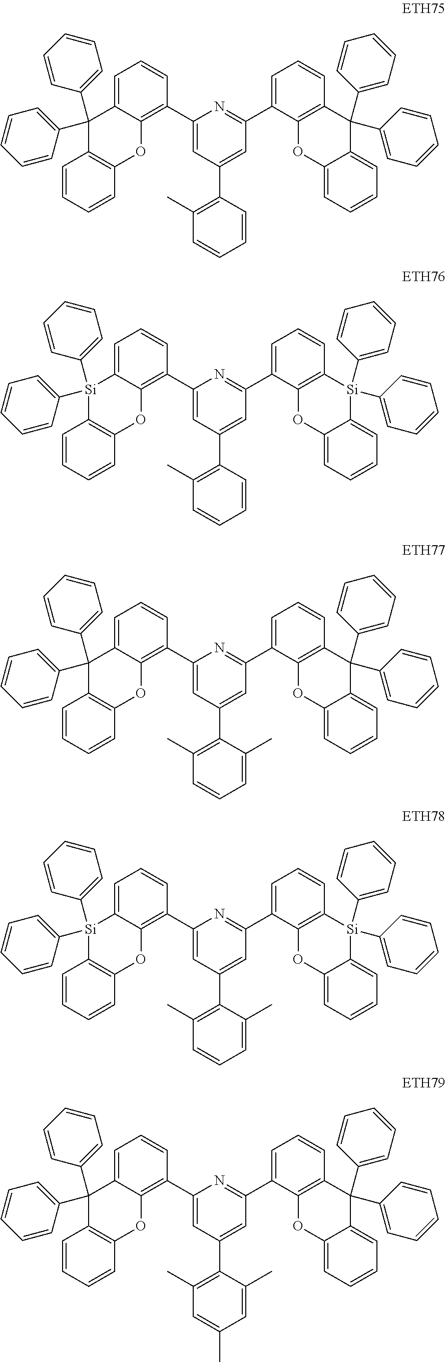

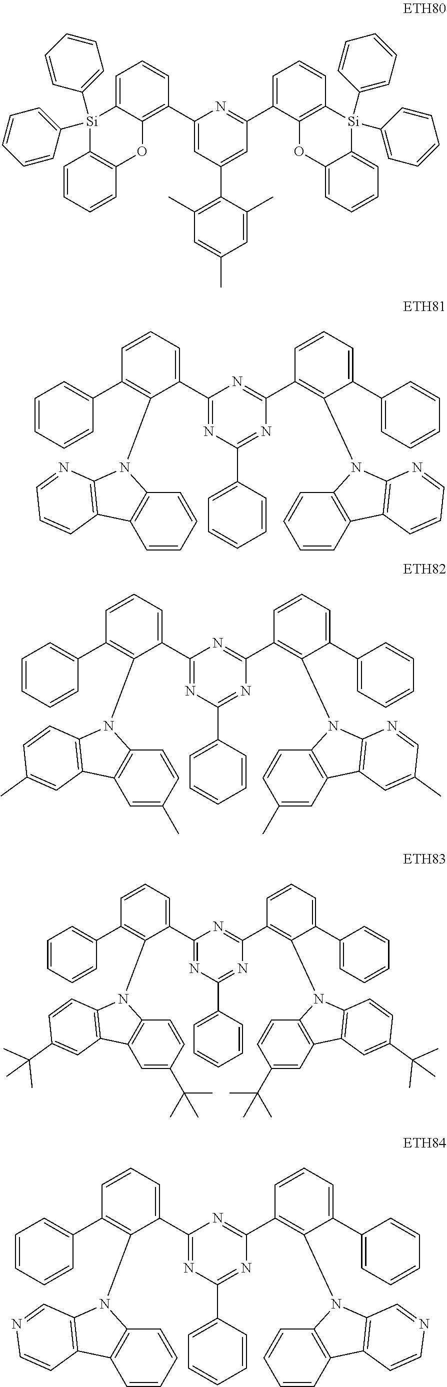

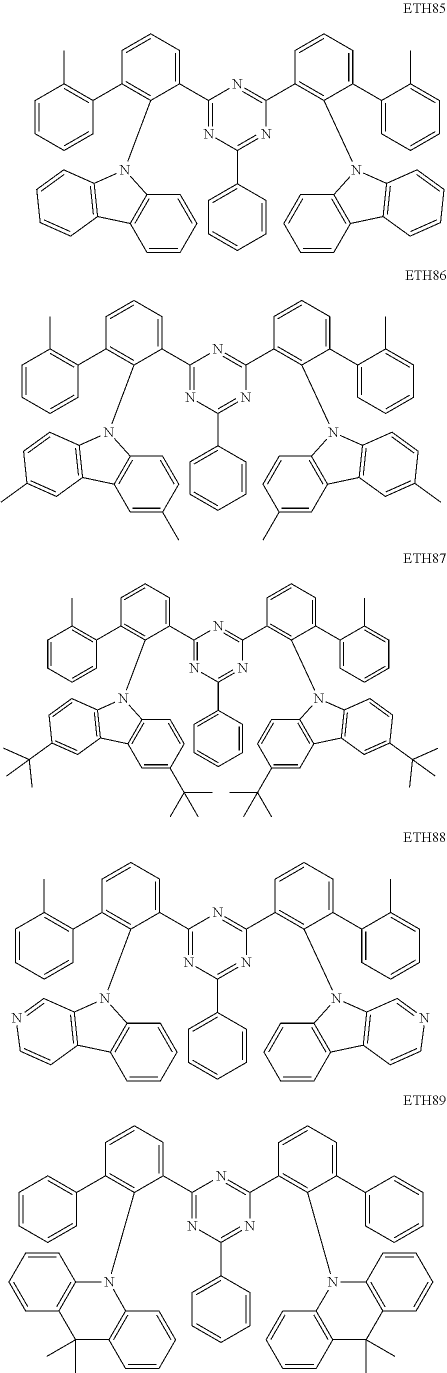

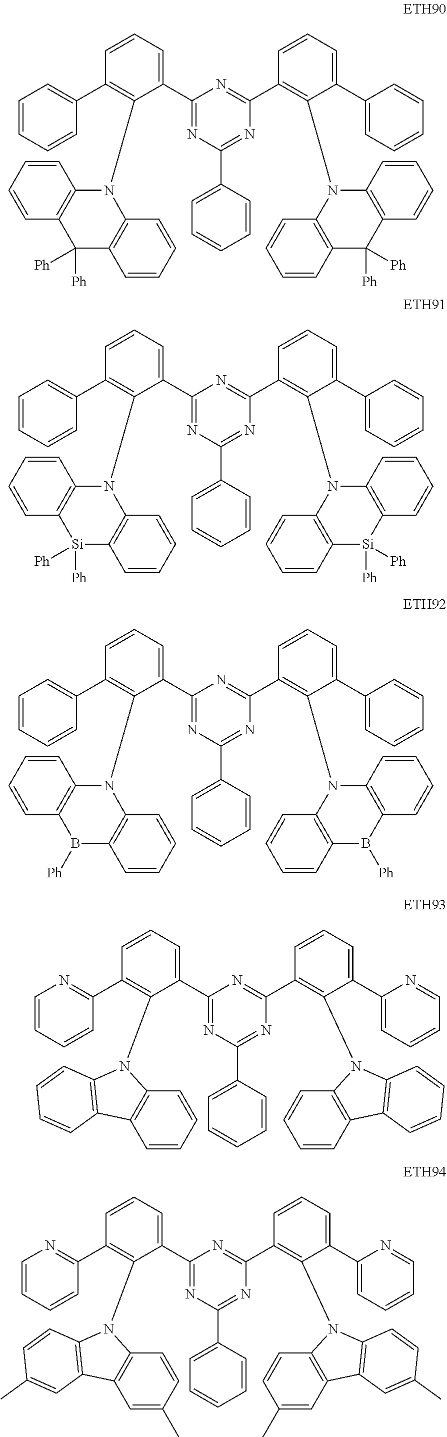

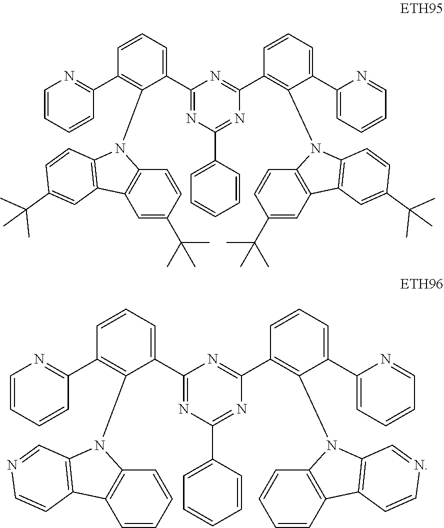 [SMILES: CC(C)(C)c1ccc2c(c1)c1cc(C(C)(C)C)ccc1n2-c1c(-c2ccccn2)cccc1-c1nc(-c2ccccc2)nc(-c2cccc(-c3ccccn3)c2-n2c3ccc(C(C)(C)C)cc3c3cc(C(C)(C)C)ccc32)n1 ; c1ccc(-c2nc(-c3cccc(-c4ccccn4)c3-n3c4ccccc4c4ccncc43)nc(-c3cccc(-c4ccccn4)c3-n3c4ccccc4c4ccncc43)n2)cc1]

In an embodiment, the third compound may be one selected from Compounds HTH1 to HTH40 below:

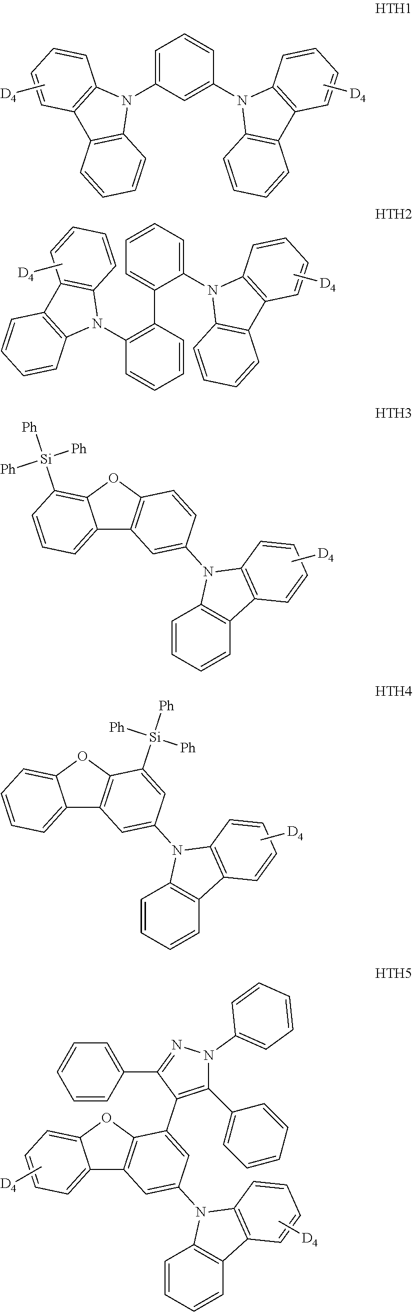

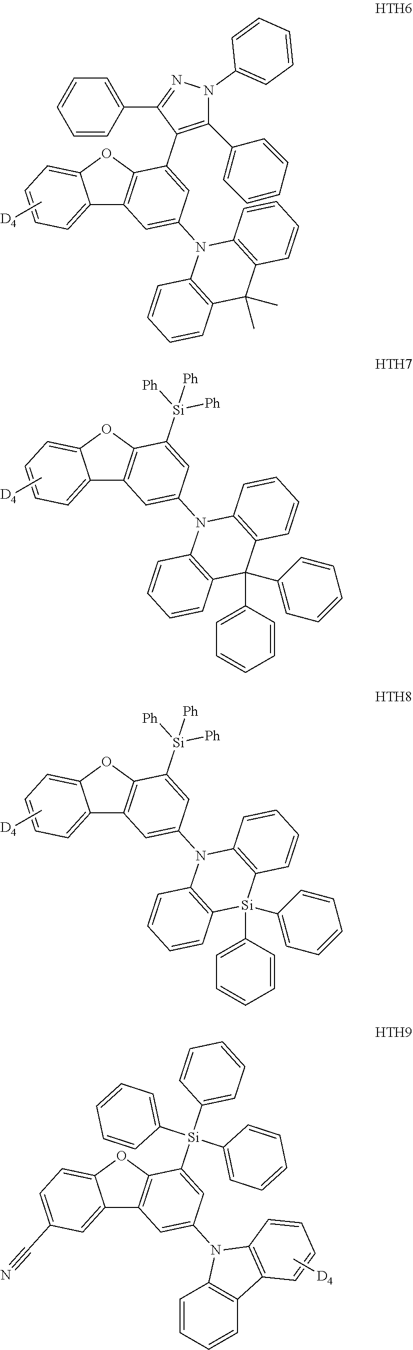

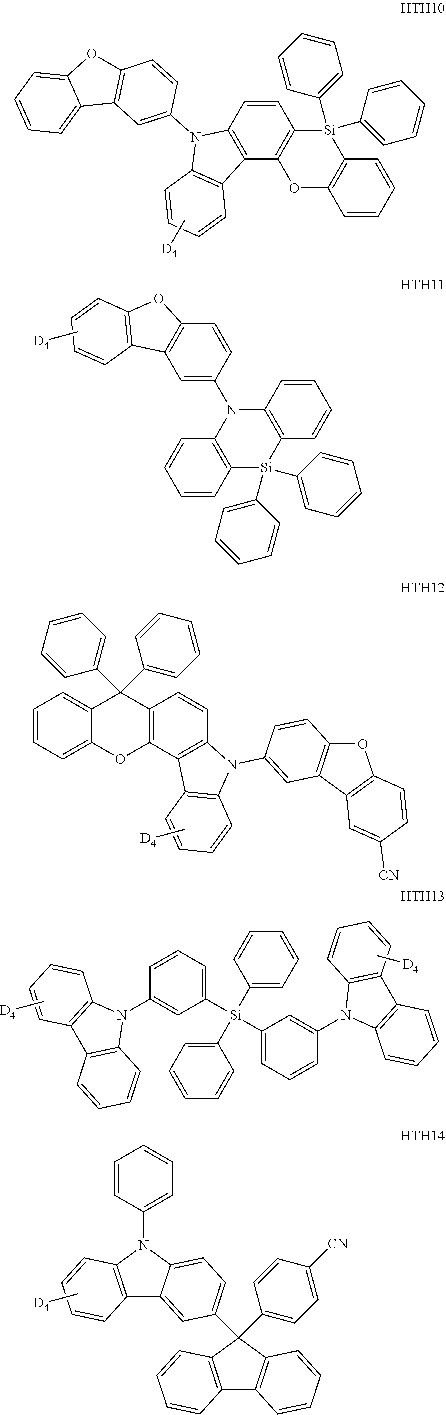

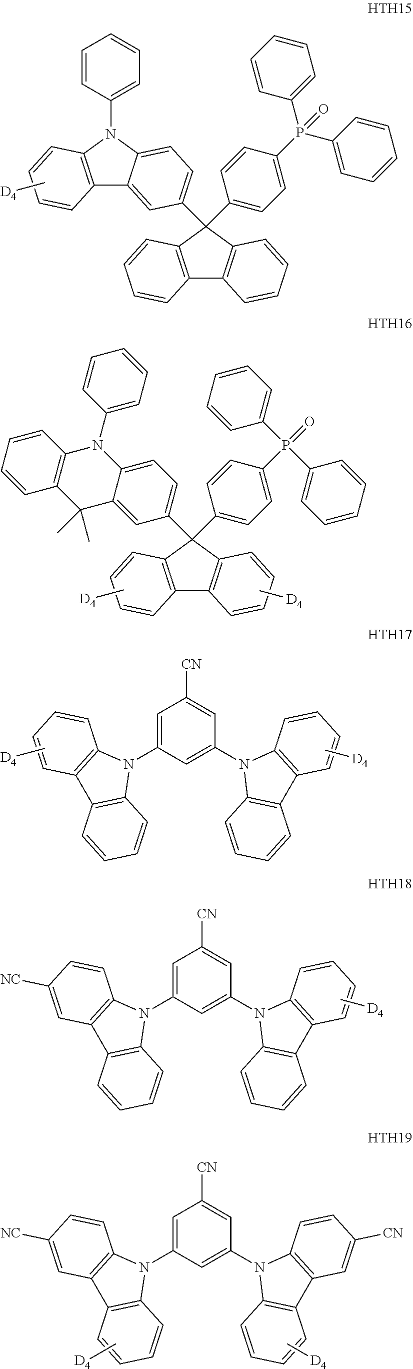

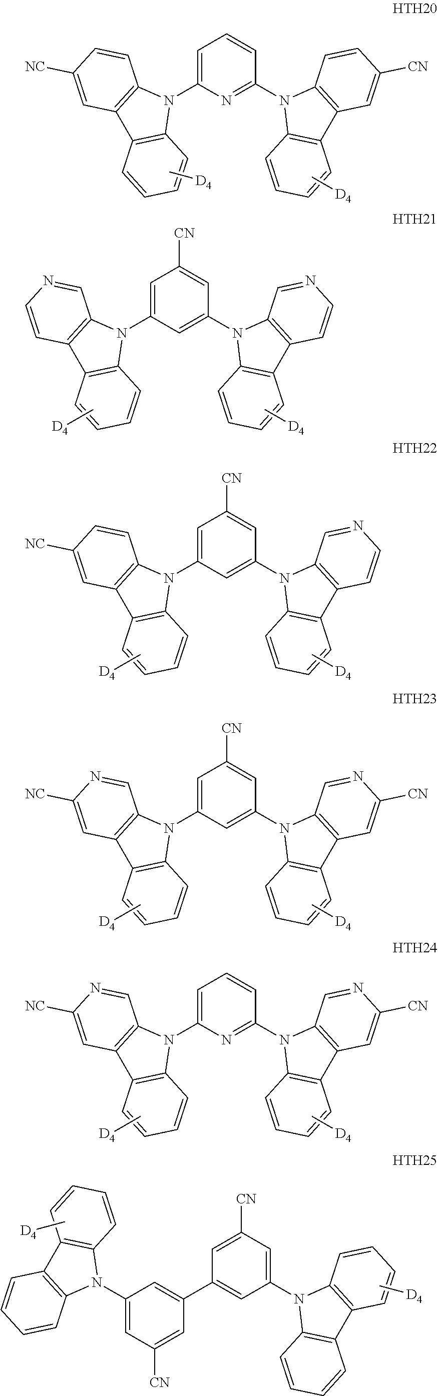

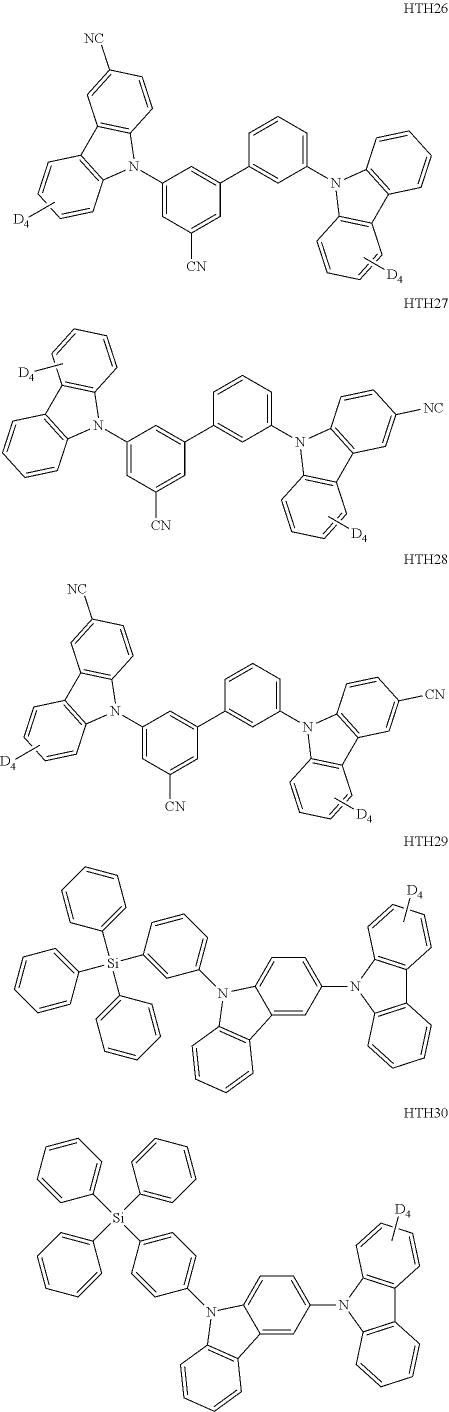

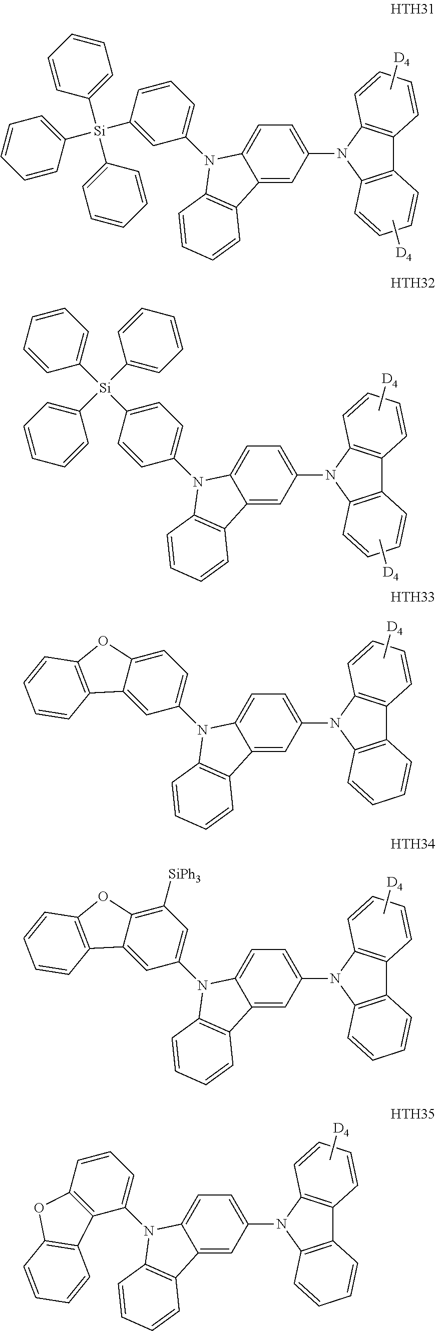

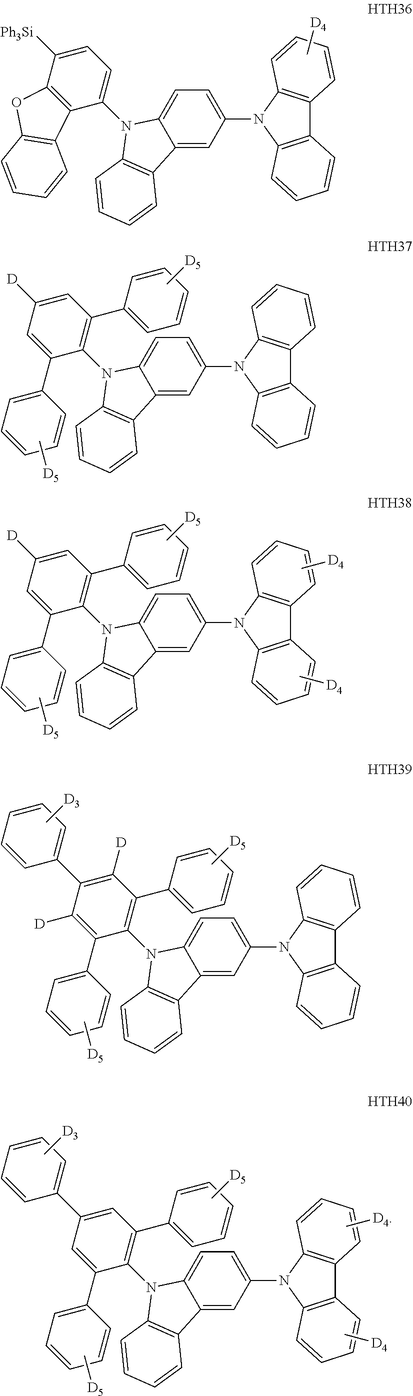

In an embodiment, the fourth compound may be one selected from Compounds DFD1 to DFD29 below:

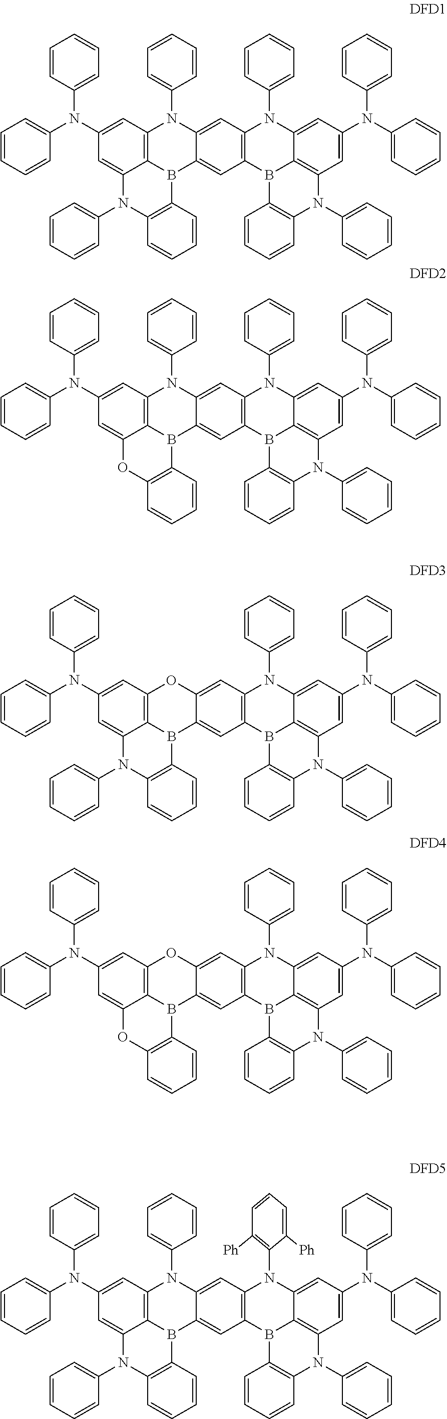

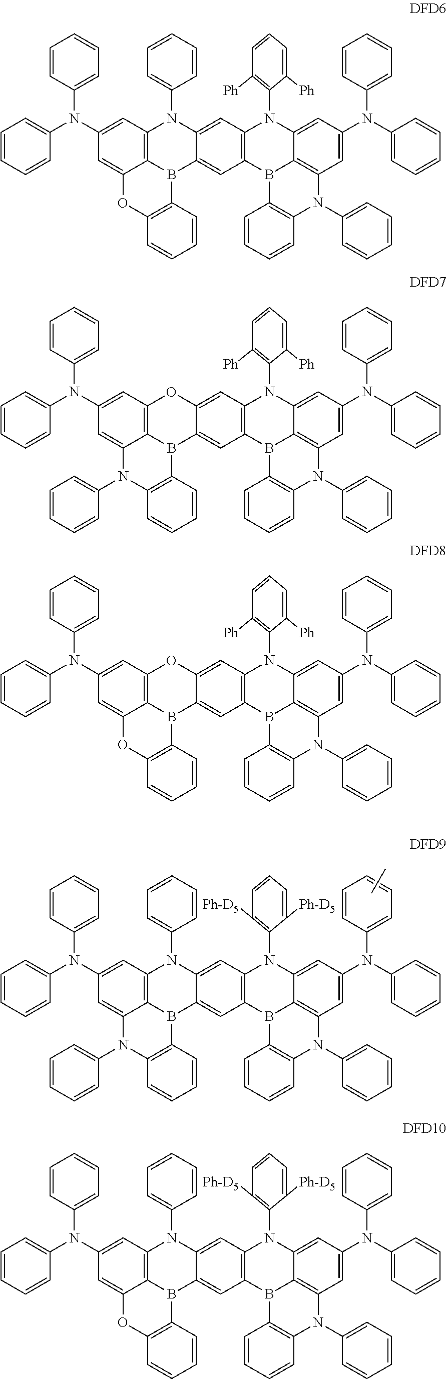

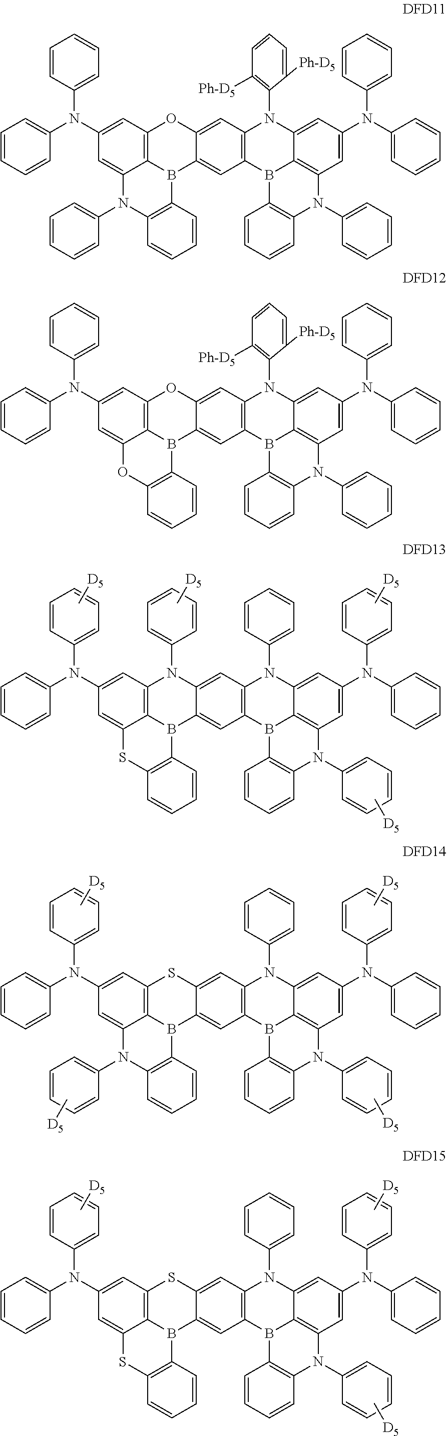

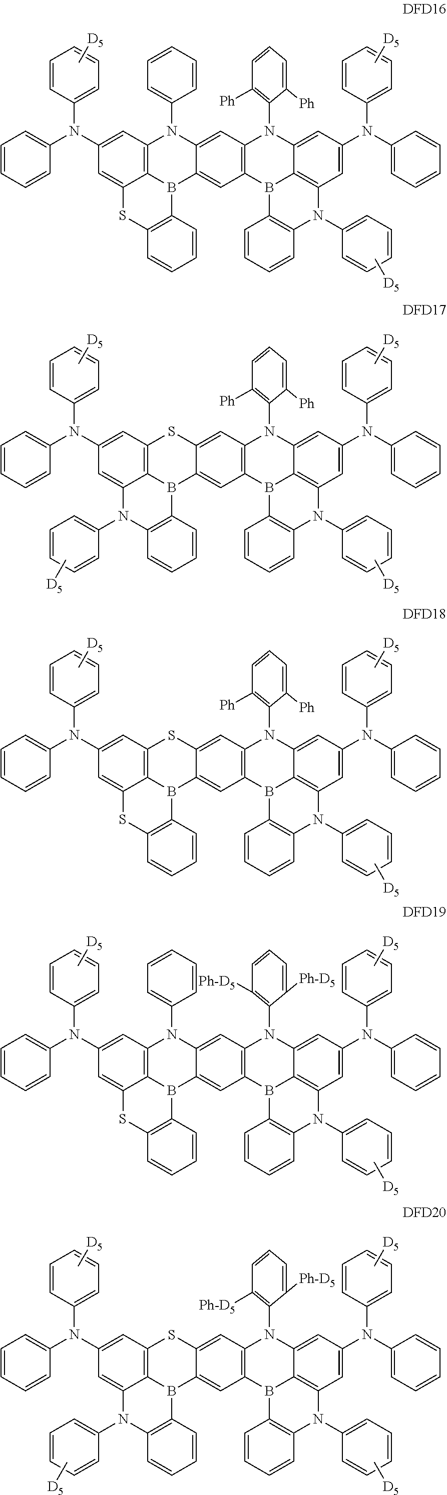

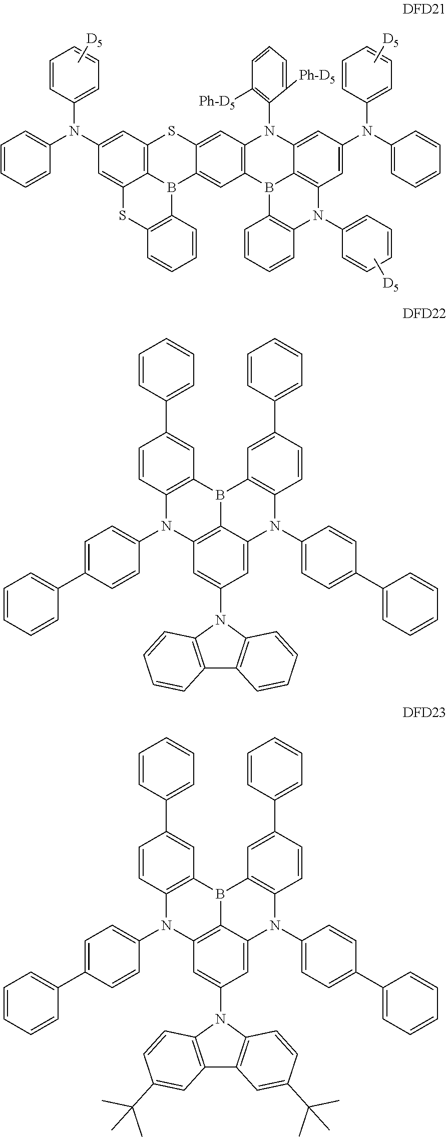

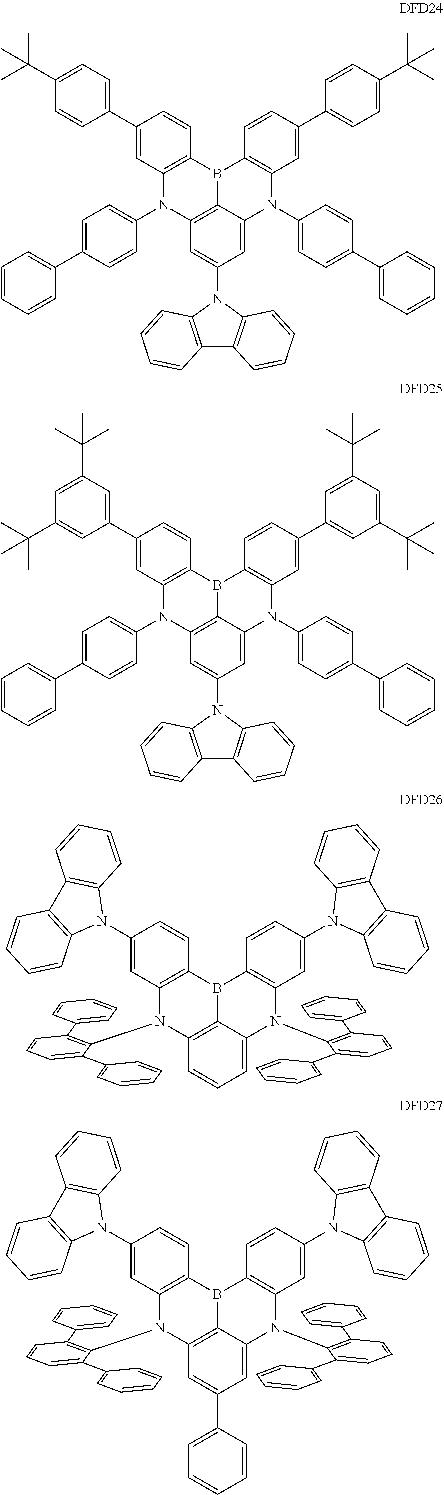

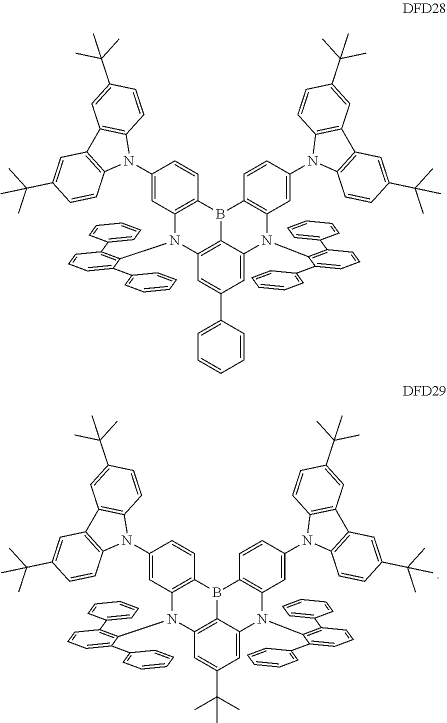

In the compounds described above, Ph represents a phenyl group, D₅ represents substitution with five deuterium, and D₄ represents substitution with four deuterium. In an embodiment, a group represented by

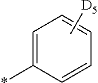

may be identical to a group represented by

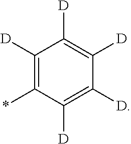

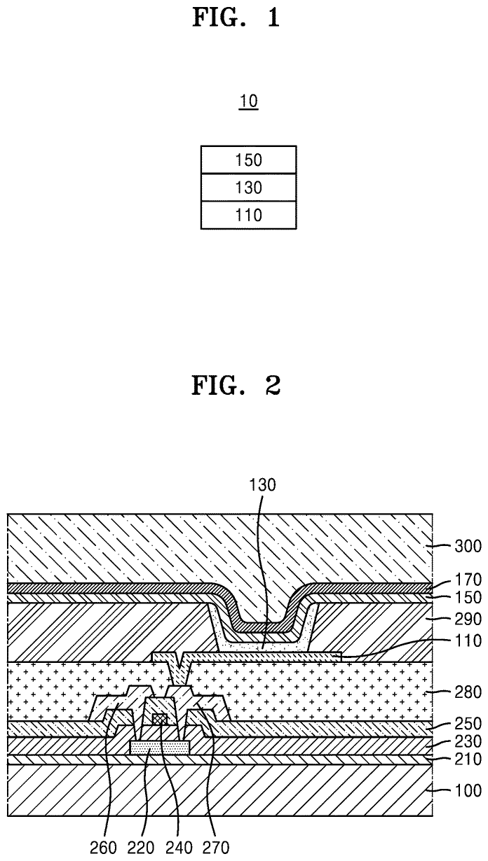

### Description of FIG. 1

FIG. 1 is a schematic cross-sectional view of a light-emitting device 10 according to an embodiment of the disclosure. The light-emitting device 10 includes a first electrode 110, an interlayer 130, and a second electrode 150.

Hereinafter, a structure of the light-emitting device 10 according to an embodiment and a method of manufacturing the light-emitting device 10 will be described in connection with FIG. 1.

### First Electrode 110

In FIG. 1, a substrate may be additionally under the first electrode 110 and/or above the second electrode 150. As the substrate, a glass substrate and/or a plastic substrate may be used. In an embodiment, the substrate may be a flexible substrate, and may include plastics having excellent heat resistance and durability, such as polyimide, polyethylene terephthalate (PET), polycarbonate, polyethylene naphthalate, polyarylate (PAR), polyetherimide, or any combination thereof.

The first electrode 110 may be formed by, for example, depositing and/or sputtering a material for forming the first electrode 110 on the substrate. When the first electrode 110 is an anode, a material for forming the first electrode 110 may be a high work function material that facilitates injection of holes.

The first electrode 110 may be a reflective electrode, a semi-transmissive electrode, or a transmissive electrode. When the first electrode 110 is a transmissive electrode, a material for forming the first electrode 110 may include indium tin oxide (ITO), indium zinc oxide (IZO), tin oxide (SnO₂), zinc oxide (ZnO), or any combinations thereof. In one or more embodiments, when the first electrode 110 is a semi-transmissive electrode or a reflective electrode, magnesium (Mg), silver (Ag), aluminum (Al), aluminum-lithium (Al-Li), calcium (Ca), magnesium-indium (Mg—In), magnesium-silver (Mg—Ag), or any combinations thereof may be used as a material for forming the first electrode 110.

The first electrode 110 may have a single-layered structure consisting of a single layer or a multilayer structure including a plurality of layers. In an embodiment, the first electrode 110 may have a three-layered structure of ITO/Ag/ITO.

### Interlayer 130

The interlayer 130 may be on the first electrode 110. The interlayer 130 may include an emission layer.

The interlayer 130 may further include a hole transport region between the first electrode 110 and the emission layer and an electron transport region between the emission layer and the second electrode 150.

The interlayer 130 may further include metal-containing compounds such as organometallic compounds, inorganic materials such as quantum dots, and/or the like, in addition to various suitable organic materials.

In an embodiment, the interlayer 130 may include i) two or more emitting units sequentially stacked between the first electrode 110 and the second electrode 150, and ii) a charge generation layer between two neighboring emitting units. When the interlayer 130 includes emitting units and a charge generation layer as described above, the light-emitting device 10 may be a tandem light-emitting device.

### Hole Transport Region in Interlayer 130

The hole transport region may have: i) a single-layered structure consisting of a single layer consisting of a single material, ii) a single-layered structure consisting of a single layer consisting of a plurality of different materials, or iii) a multi-layered structure including a plurality of layers including different materials.

The hole transport region may include a hole injection layer, a hole transport layer, an emission auxiliary layer, an electron blocking layer, or any combination thereof.

For example, the hole transport region may have a multi-layered structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron blocking layer structure, the layers of each structure being stacked sequentially from the first electrode 110.

The hole transport region may include a compound represented by Formula 201, a compound represented by Formula 202, or any combination thereof:

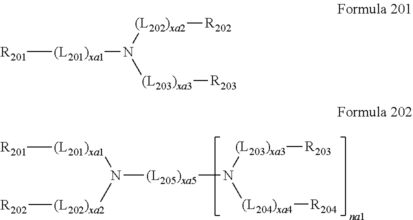

wherein, in Formulae 201 and 202,

L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

L₂₀₅ may be *—O—*′, *—S—*′, *—N(Q₂₀₁)—*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,

xa1 to xa4 may each independently be an integer selected from 0 to 5,

xa5 may be an integer selected from 1 to 10,

R₂₀₁ to R₂₀₄ and Q₂₀₁ may each independently be a C₃-C₆₀ carbocyclic group unsubstituted or substituted with at least one R₁₀ₐ, or a C₁-C₆₀ heterocyclic group unsubstituted or substituted with at least one R₁₀ₐ,

R₂₀₁ and R₂₀₂ may optionally be linked to each other via a single bond, a C₁-C₅ alkylene group unsubstituted or substituted with at least one R₁₀ₐ, or a C₂-C₅ alkenylene group unsubstituted or substituted with at least one R₁₀ₐ to form a C₂-C₅ polycyclic group (for example, a carbazole group and/or the like) unsubstituted or substituted with at least one R₁₀ₐ (for example, see Compound HT16),

R₂₀₃ and R₂₀₄ may optionally be linked to each other, via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and

na1 may be an integer selected from 1 to 4.

In an embodiment, each of Formulae 201 and 202 may include at least one selected from groups represented by Formulae CY201 to CY217.

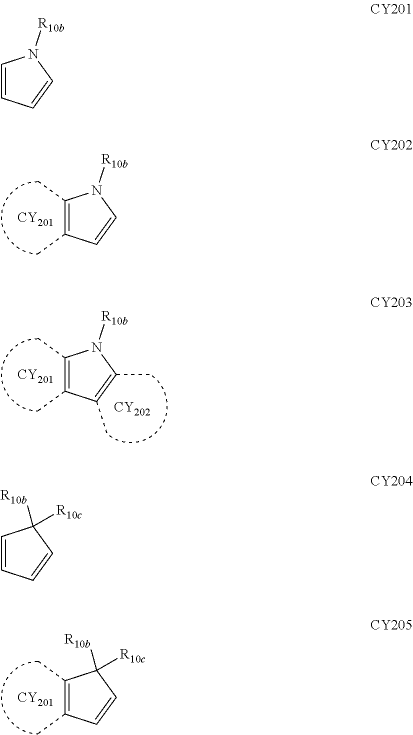

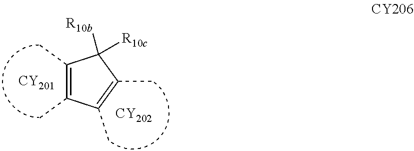

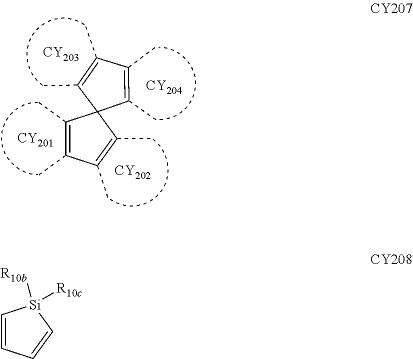

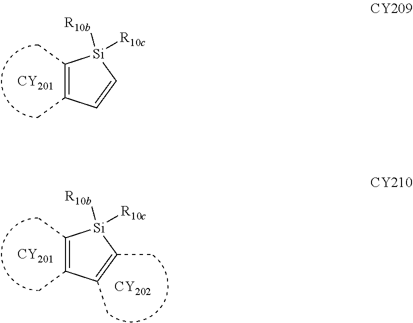

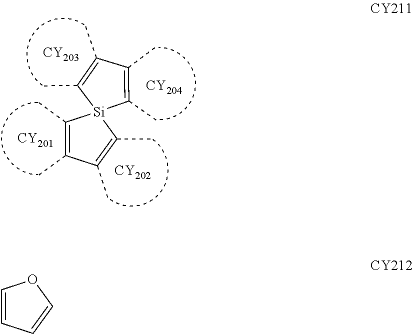

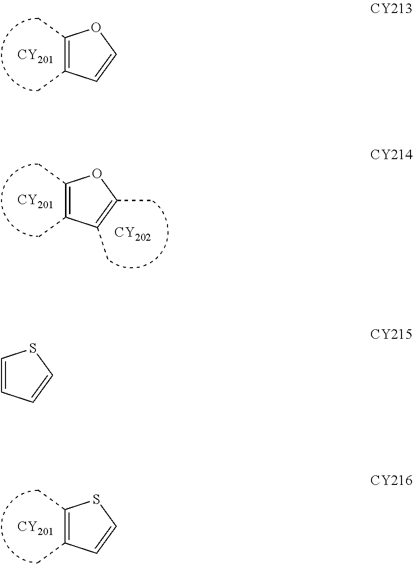

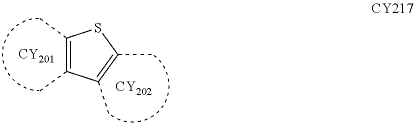

R_{10b} and R_{10c} in Formulae CY201 to CY217 are respectively the same as described in connection with R₁₀ₐ, ring CY₂₀₁ to ring CY₂₀₄ may each independently be a C₃-C₂₀ carbocyclic group or a C₁-C₂₀ heterocyclic group, and at least one hydrogen in Formulae CY201 to CY217 may be unsubstituted or substituted with R₁₀ₐ as described above.

In an embodiment, ring CY₂₀₁ to ring CY₂₀₄ in Formulae CY201 to CY217 may each independently be a benzene group, a naphthalene group, a phenanthrene group, or an anthracene group.

In an embodiment, each of Formulae 201 and 202 may include at least one selected from groups represented by Formulae CY201 to CY203.

In an embodiment, Formula 201 may include at least one selected from groups represented by Formulae CY201 to CY203 and at least one selected from groups represented by Formulae CY204 to CY217.

In an embodiment, xa1 in Formula 201 may be 1, R₂₀₁ may be a group represented by one selected from Formulae CY201 to CY203, xa2 may be 0, and R₂₀₂ may be a group represented by one selected from Formulae CY204 to CY207.

In an embodiment, each of Formulae 201 and 202 may not include groups represented by Formulae CY201 to CY203.

In an embodiment, each of Formulae 201 and 202 may not include groups represented by Formulae CY201 to CY203, and may include at least one selected from groups represented by Formulae CY204 to CY217.

In an embodiment, each of Formulae 201 and 202 may not include groups represented by Formulae CY201 to CY217.

In an embodiment, the hole transport region may include one selected from Compounds HT1 to HT46, m-MTDATA, TDATA, 2-TNATA, NPB(NPD), β-NPB, TPD, Spiro-TPD, Spiro-NPB, methylated NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), or any combination thereof:

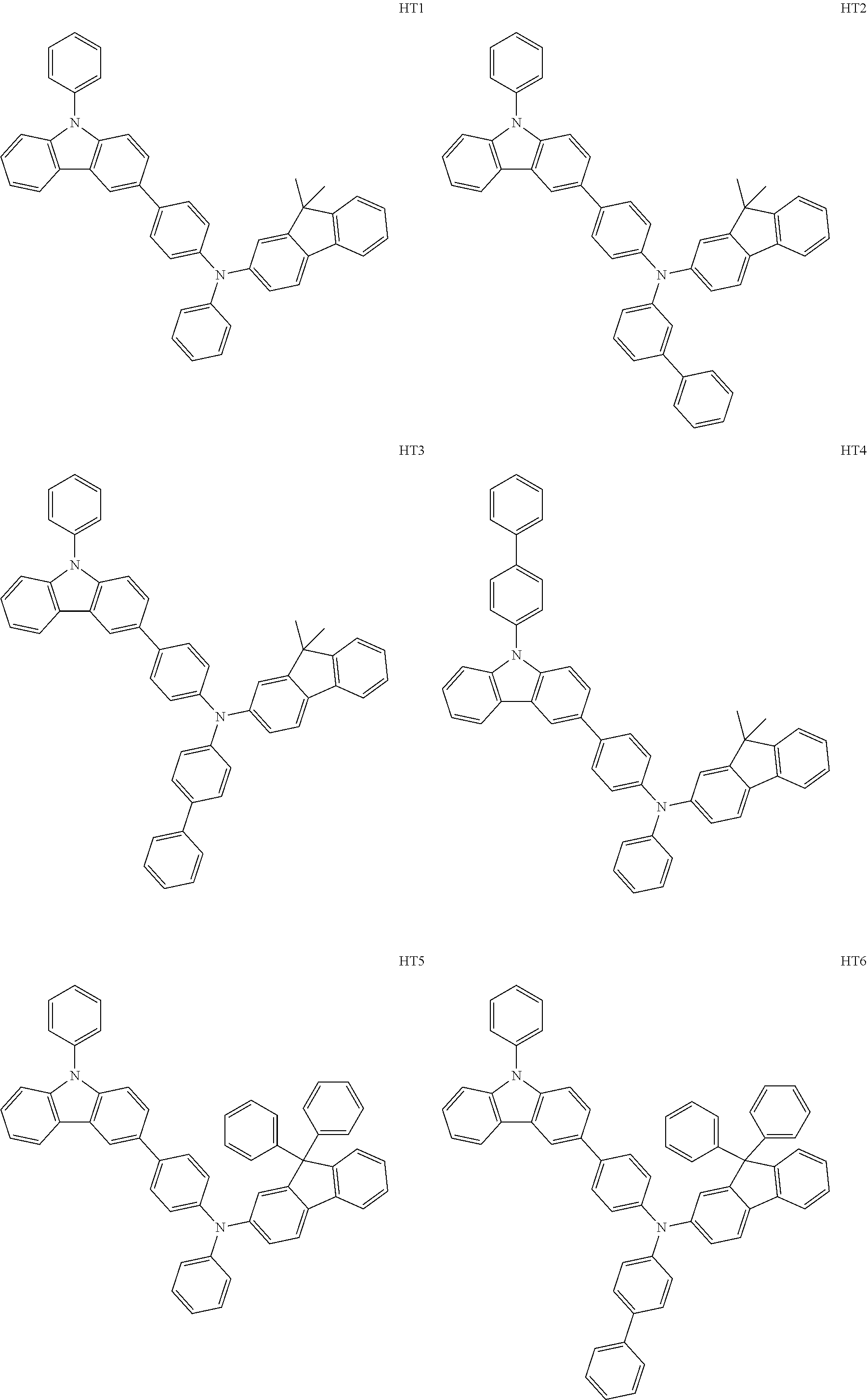

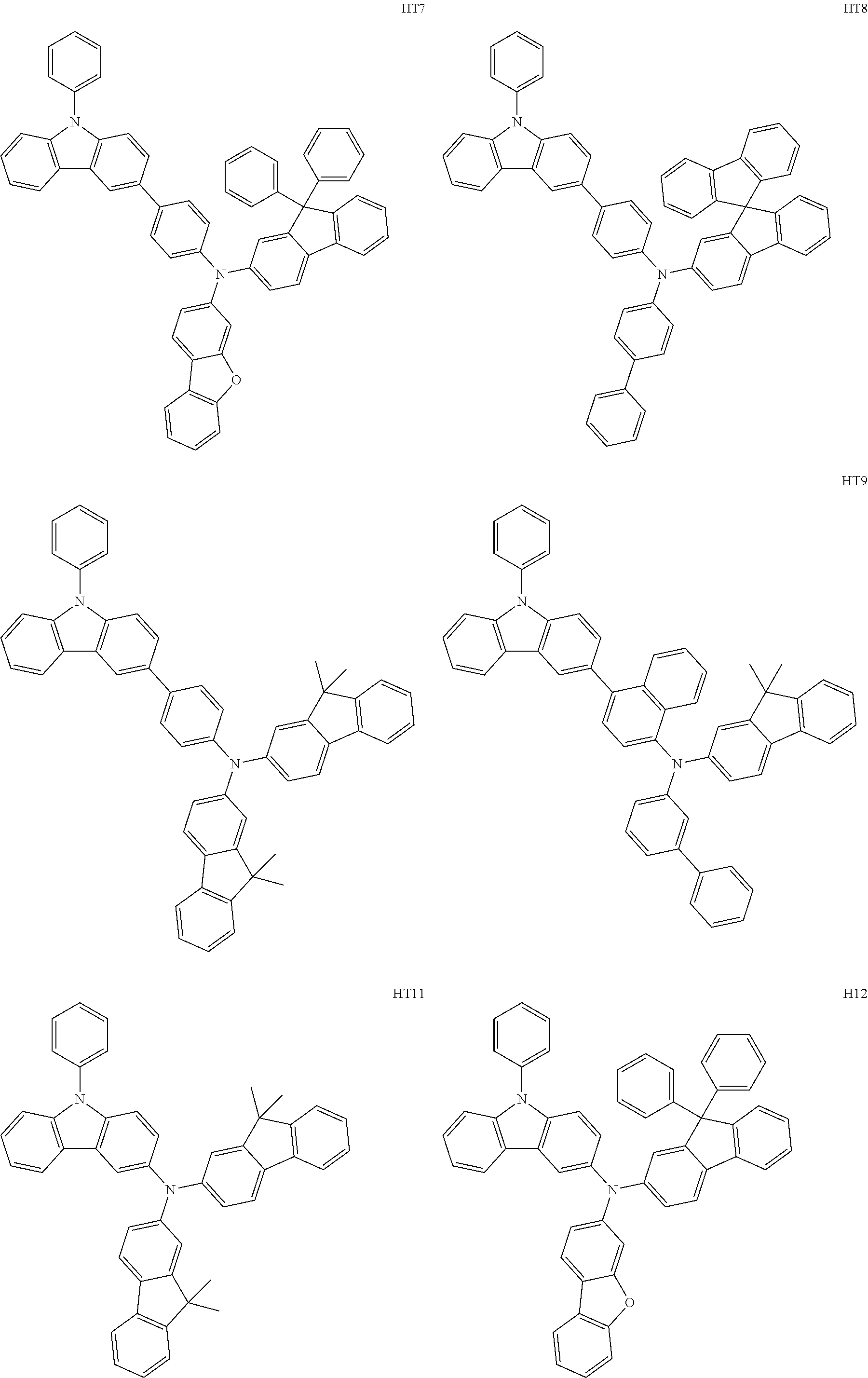

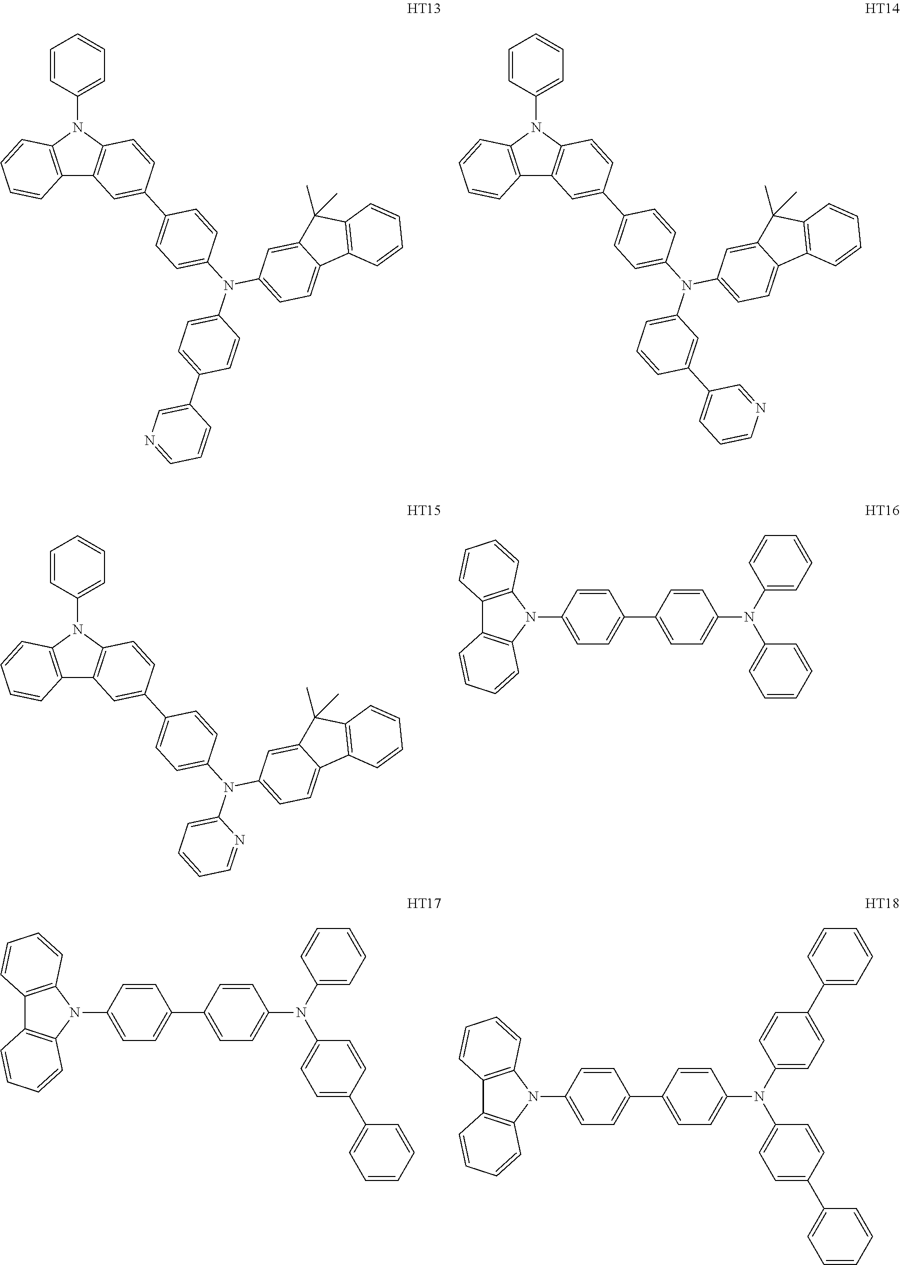 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1 ; c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

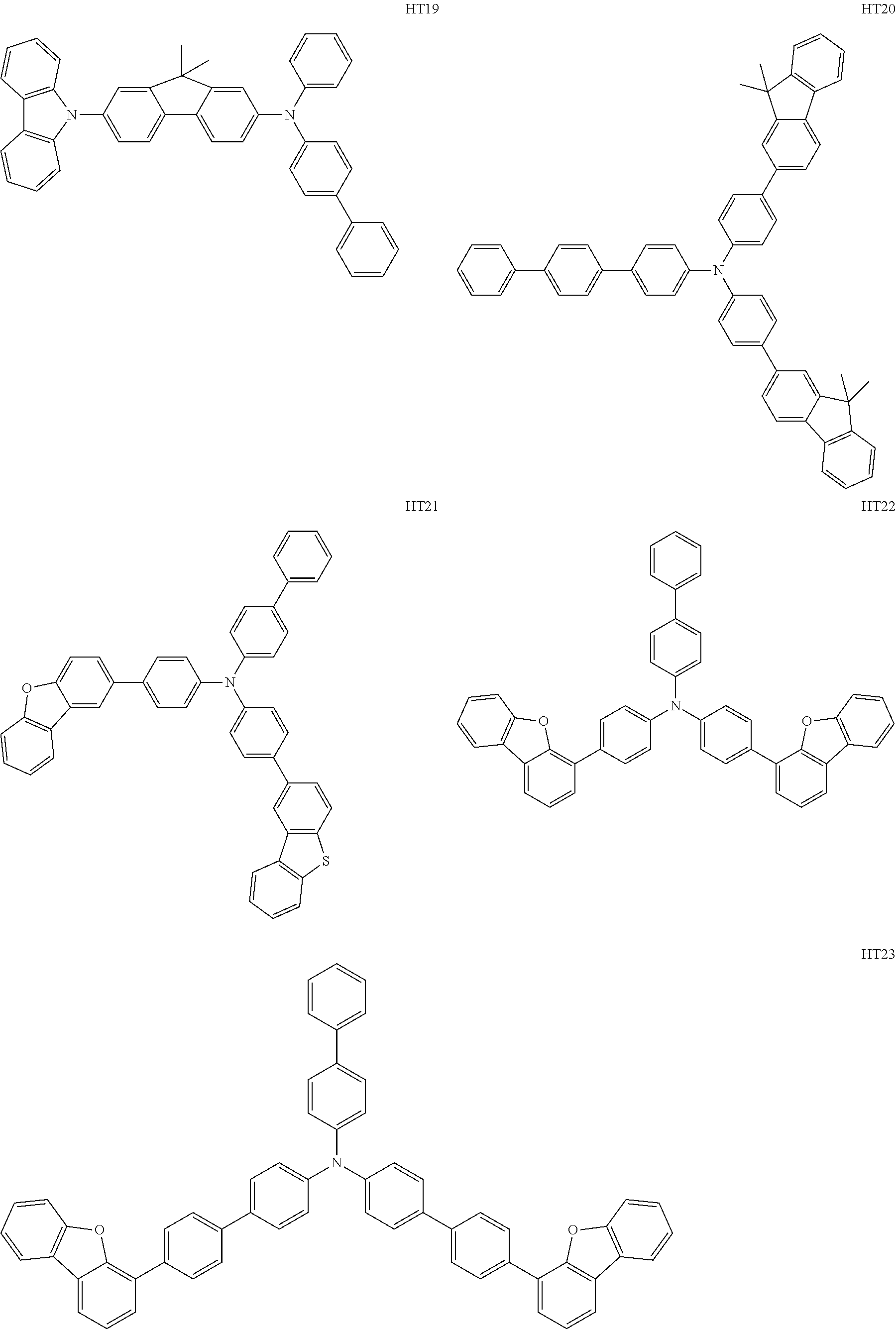 [SMILES: CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21 ; c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

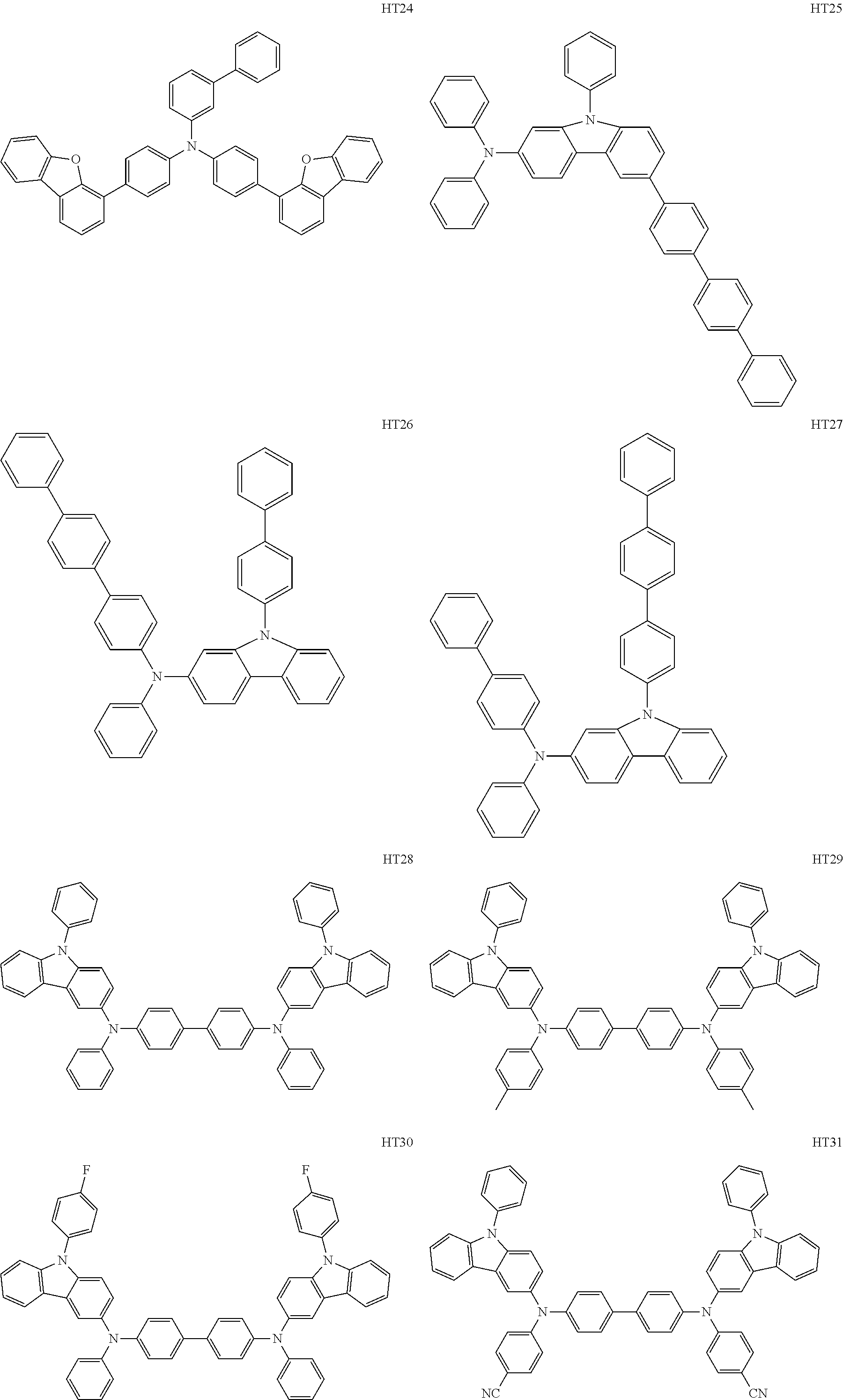

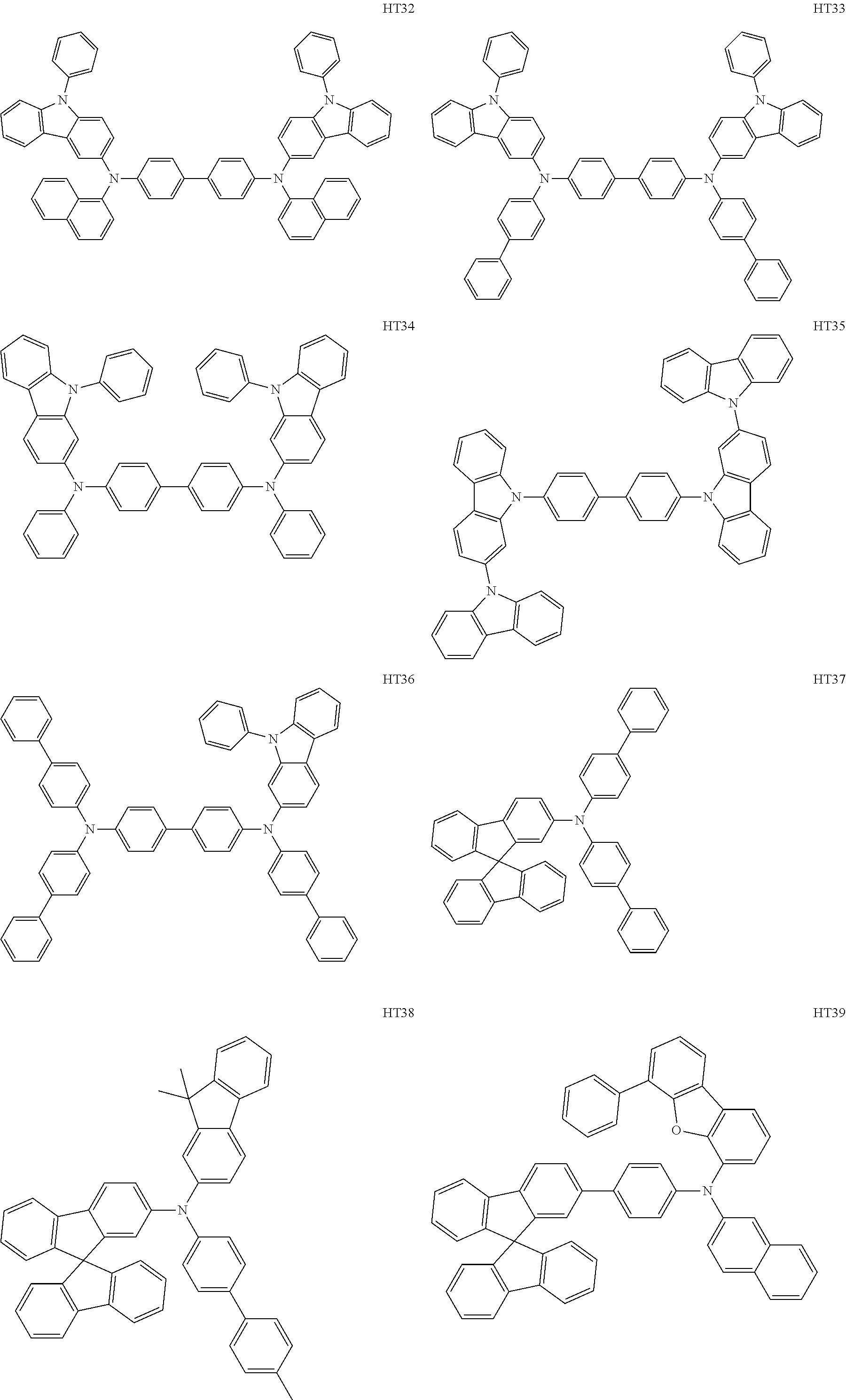

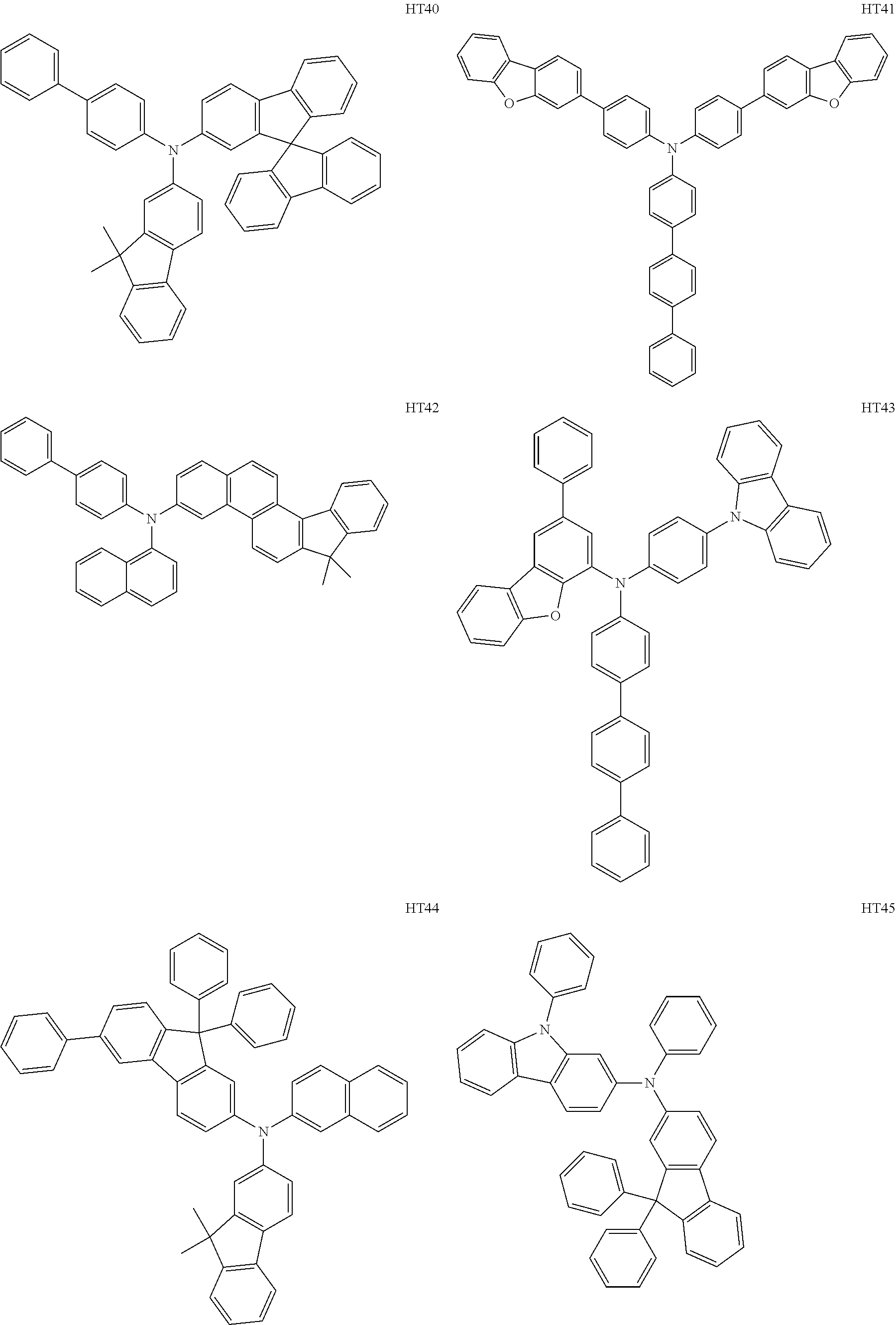

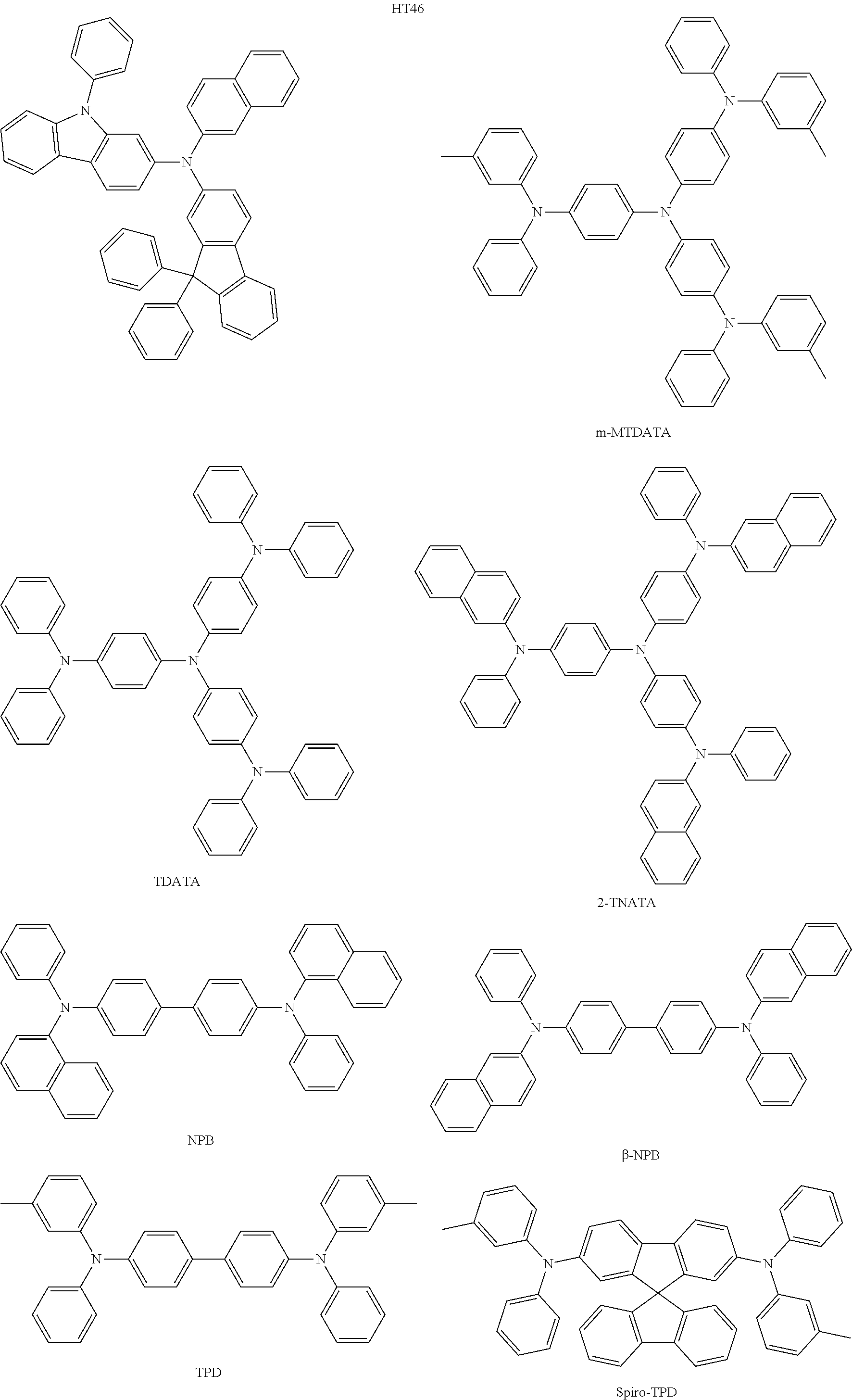

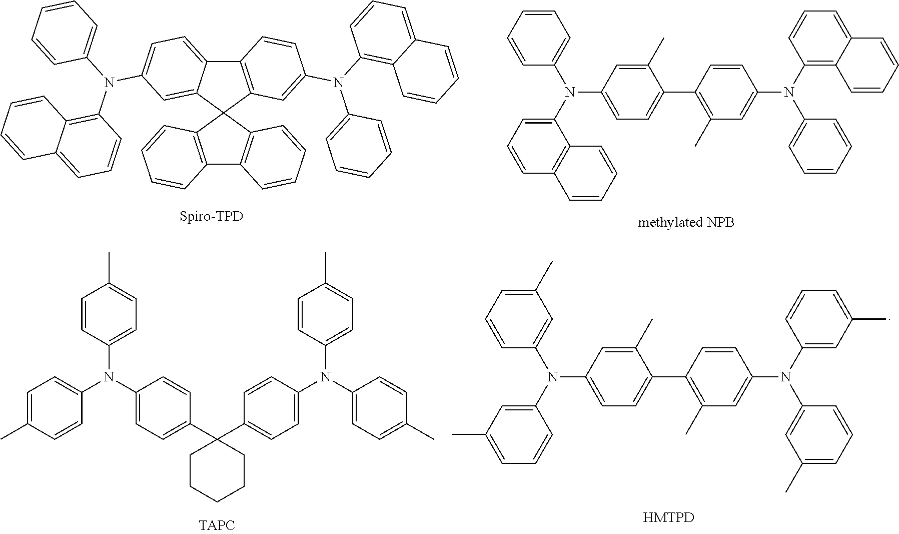

A thickness of the hole transport region may be in a range of about 50 Å to about 10,000 Å, for example, about 100 Å to about 4,000 Å. When the hole transport region includes a hole injection layer, a hole transport layer, or any combination thereof, a thickness of the hole injection layer may be in a range of about 100 Å to about 9,000 Å, for example, about 100 Å to about 1,000 Å, and a thickness of the hole transport layer may be in a range of about 50 Å to about 2,000 Å, for example, about 100 Å to about 1,500 Å. When the thicknesses of the hole transport region, the hole injection layer and the hole transport layer are within these ranges, suitable or satisfactory hole-transporting characteristics may be obtained without a substantial increase in driving voltage.

The emission auxiliary layer may increase light-emission efficiency by compensating for an optical resonance distance according to the wavelength of light emitted by an emission layer, and the electron blocking layer may block or reduce the leakage of electrons from an emission layer to a hole transport region. Materials that may be included in the hole transport region may be included in the emission auxiliary layer and the electron blocking layer.

p-dopant

The hole transport region may further include, in addition to these materials, a charge-generation material for the improvement of conductive properties (e.g., electrically conductive properties). The charge-generation material may be uniformly or non-uniformly dispersed in the hole transport region (for example, in the form of a single layer consisting of a charge-generation material).

The charge-generation material may be, for example, a p-dopant.

In an embodiment, a LUMO energy level of the p-dopant may be about −3.5 eV or less.

In an embodiment, the p-dopant may include a quinone derivative, a cyano group-containing compound, a compound containing element EL1 and element EL2, or any combination thereof.

Examples of the quinone derivative may include TCNQ, F₄-TCNQ, and the like.

Examples of the cyano group-containing compound may include HAT-CN, a compound represented by Formula 221 below, and the like.

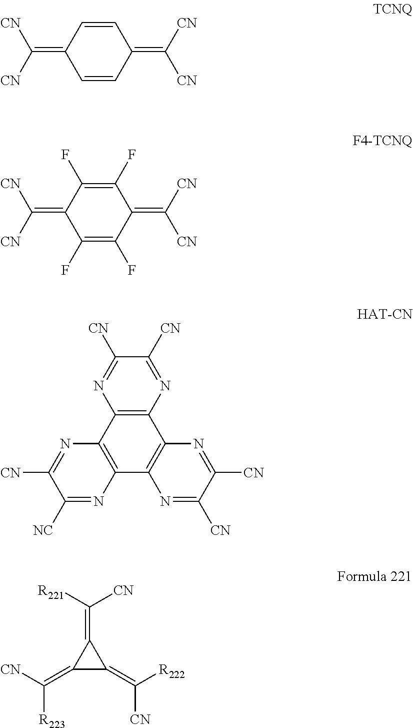

In Formula 221,

R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and

at least one selected from R₂₂₁ to R₂₂₃ may each independently be a C₃-C₆₀ carbocyclic group or a C₁-C₆₀ heterocyclic group, each substituted with: a cyano group; —F; —CI; —Br; —I; a C₁-C₂₀ alkyl group substituted with a cyano group, —F, —CI, —Br, —I, or any combination thereof; or any combination thereof.

In the compound containing element EL1 and element EL2, element EL1 may be metal, metalloid, or a combination thereof, and element EL2 may be non-metal, metalloid, or a combination thereof.

Examples of the metal may include: an alkali metal (for example, lithium (Li), sodium (Na), potassium (K), rubidium (Rb), cesium (Cs), etc.); an alkaline earth metal (for example, beryllium (Be), magnesium (Mg), calcium (Ca), strontium (Sr), barium (Ba), etc.); a transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), etc.); a post-transition metal (for example, zinc (Zn), indium (In), tin (Sn), etc.); and a lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), etc.).

Examples of the metalloid may include silicon (Si), antimony (Sb), and tellurium (Te).

Examples of the non-metal may include oxygen (O) and halogen (for example, F, CI, Br, I, etc.).

In an embodiment, examples of the compound containing element EL1 and element EL2 may include metal oxide, metal halide (for example, metal fluoride, metal chloride, metal bromide, and/or metal iodide), metalloid halide (for example, metalloid fluoride, metalloid chloride, metalloid bromide, and/or metalloid iodide), metal telluride, or any combination thereof.

Examples of the metal oxide may include tungsten oxide (for example, WO, W₂O₃, WO₂, WO₃, W₂O₅, etc.), vanadium oxide (for example, VO, V₂O₃, VO₂, V₂O₅, etc.), molybdenum oxide (MoO, Mo₂O₃, MoO₂, MoO₃, Mo₂O₅, etc.), and rhenium oxide (for example, ReO₃, etc.).

Examples of the metal halide may include alkali metal halide, alkaline earth metal halide, transition metal halide, post-transition metal halide, and lanthanide metal halide.

Examples of the alkali metal halide may include LiF, NaF, KF, RbF, CsF, LiCl, NaCl, KCl, RbCI, CsCl, LiBr, NaBr, KBr, RbBr, CsBr, LiI, NaI, KI, RbI, and CsI.

Examples of the alkaline earth metal halide may include BeF₂, MgF₂, CaF₂, SrF₂, BaF₂, BeCl₂, MgCl₂, CaCl₂, SrCl₂, BaCl₂, BeBr₂, MgBr₂, CaBr₂, SrBr₂, BaBr₂, BeI₂, MgI₂, CaI₂, SrI₂, and BaI₂.

Examples of the transition metal halide may include titanium halide (for example, TiF₄, TiCl₄, TiBr₄, TiI₄, etc.), zirconium halide (for example, ZrF₄, ZrCl₄, ZrBr₄, ZrI₄, etc.), hafnium halide (for example, Hf F₄, HfCl₄, HfBr₄, HfI₄, etc.), vanadium halide (for example, VF₃, VCI₃, VBr₃, VI₃, etc.), niobium halide (for example, NbF₃, NbCI₃, NbBr₃, NbI₃, etc.), tantalum halide (for example, TaF₃, TaCI₃, TaBr₃, TaI₃, etc.), chromium halide (for example, CrF₃, CrCI₃, CrBr₃, CrI₃, etc.), molybdenum halide (for example, MoF₃, MoCI₃, MoBr₃, MoI₃, etc.), tungsten halide (for example, WF₃, WCI₃, WBr₃, WI₃, etc.), manganese halide (for example, MnF₂, MnCl₂, MnBr₂, MnI₂, etc.), technetium halide (for example, TcF₂, TcCl₂, TcBr₂, TcI₂, etc.), rhenium halide (for example, ReF₂, ReCI₂, ReBr₂, Rel2, etc.), iron halide (for example, FeF₂, FeCl₂, FeBr₂, FeI₂, etc.), ruthenium halide (for example, RuF₂, RuCl₂, RuBr₂, RuI₂, etc.), osmium halide (for example, OsF₂, OsCl₂, OsBr₂, OsI₂, etc.), cobalt halide (for example, CoF₂, CoCl₂, CoBr₂, CoI₂, etc.), rhodium halide (for example, RhF₂, RhCl₂, RhBr₂, Rhl2, etc.), iridium halide (for example, IrF₂, IrCI₂, IrBr₂, IrI₂, etc.), nickel halide (for example, NiF₂, NiCI₂, NiBr₂, NiI₂, etc.), palladium halide (for example, PdF₂, PdCl₂, PdBr₂, Pdl₂, etc.), platinum halide (for example, PtF₂, PtCl₂, PtBr₂, PtI₂, etc.), copper halide (for example, CuF, CuCI, CuBr, Cul, etc.), silver halide (for example, AgF, AgCI, AgBr, Agl, etc.), and gold halide (for example, AuF, AuCI, AuBr, AuI, etc.).

Examples of the post-transition metal halide may include zinc halide (for example, ZnF₂, ZnCI₂, ZnBr₂, Zn₁₂, etc.), indium halide (for example, InI₃, etc.), and tin halide (for example, SnI₂, etc.).

Examples of the lanthanide metal halide may include YbF, YbF₂, YbF₃, SmF₃, YbCI, YbCl₂, YbCI₃, SmCI₃, YbBr, YbBr₂, YbBr₃, SmBr₃, YbI, YbI₂, YbI₃, SmI₃, and the like.

Examples of the metalloid halide may include antimony halide (for example, SbCI₅, etc.).

Examples of the metal telluride may include alkali metal telluride (for example, Li₂Te, Na₂Te, K₂Te, Rb₂Te, Cs₂Te, etc.), alkaline earth metal telluride (for example, BeTe, MgTe, CaTe, SrTe, BaTe, etc.), transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, etc.), post-transition metal telluride (for example, ZnTe, etc.), and lanthanide metal telluride (for example, LaTe, CeTe, PrTe, NdTe, PmTe, EuTe, GdTe, TbTe, DyTe, HoTe, ErTe, TmTe, YbTe, LuTe, etc.).

### Emission Layer in Interlayer 130

When the light-emitting device 10 is a full-color light-emitting device, the emission layer may be patterned into a red emission layer, a green emission layer, and/or a blue emission layer, according to a sub-pixel. In an embodiment, the emission layer may have a stacked structure of two or more layers of a red emission layer, a green emission layer, and a blue emission layer, in which the two or more layers contact (e.g., physically contact) each other or are spaced apart from each other. In one or more embodiments, the emission layer may include two or more materials of a red light-emitting material, a green light-emitting material, and a blue light-emitting material, in which the two or more materials are mixed together with each other in a single layer to emit white light.

In an embodiment, the emission layer may include a host and a dopant (or emitter). In an embodiment, the emission layer may further include an auxiliary dopant that promotes energy transfer to a dopant (or emitter), in addition to the host and the dopant (or emitter). When the emission layer includes the dopant (or emitter) and the auxiliary dopant, the dopant (or emitter) and the auxiliary dopant are different from each other.

The organometallic compound represented by Formula 1 in the present specification may serve as the dopant (or emitter), or may serve as the auxiliary dopant.

An amount of the dopant (or emitter) in the emission layer may be in a range of about 0.01 parts by weight to about 15 parts by weight based on 100 parts by weight of the host.

A thickness of the emission layer may be in a range of about 100 Å to about 1,000 Å, for example, about 200 Å to about 600 Å. When the thickness of the emission layer is within the range, excellent light-emission characteristics may be obtained without a substantial increase in driving voltage.

### Host

The host in the emission layer may include the second compound or the third compound described in the present specification, or any combination thereof.

In an embodiment, the host may include a compound represented by Formula 301 below:

[Ar₃₀₁]_{xb11}—[(L₃₀₁)_{xb1}—R₃₀₁]_{xb21} Formula 301

wherein, in Formula 301,

Ar₃₀₁ and L₃₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

xb₁₁ may be 1, 2, or 3,

xb₁ may be an integer selected from 0 to 5,

R₃₀₁ may be hydrogen, deuterium, —F, —CI, —Br, —I, a hydroxyl group, a cyano group, a nitro group, a C₁-C₆₀ alkyl group unsubstituted or substituted with at least one

R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₁)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),

xb21 may be an integer selected from 1 to 5, and

Q₃₀₁ to Q₃₀₃ are respectively the same as described in connection with Q₁ in the present specification.

In an embodiment, when xb₁₁ in Formula 301 is 2 or more, two or more of

Ar₃₀₁ (s) may be linked to each other via a single bond.

In an embodiment, the host may include a compound represented by Formula 301-1, a compound represented by Formula 301-2, or any combination thereof:

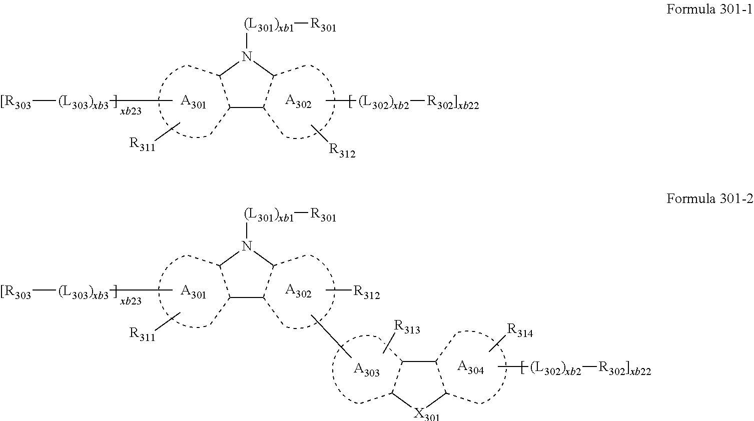

wherein, in Formulae 301-1 and 301-2,

ring A₃₀₁ to ring A₃₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

X₃₀₁ may be O, S, N—[(L₃₀₄)xm-R₃₀₄], C(R₃₀₄)(R₃₀₅), or Si(R₃₀₄)(R₃₀₅),

xb22 and xb23 may each independently be 0, 1, or 2,

L₃₀₁, xb1, and R₃₀₁ are respectively the same as described in the present specification,

L₃₀₂ to L₃₀₄ are each independently the same as described in connection with L_{301,}

xb2 to xb4 are each independently the same as described in connection with xb1, and

R₃₀₂ to R₃₀₅ and R₃₁₁ to R₃₁₄ are respectively the same as described in connection with R₃₀₁ in the present specification.

In an embodiment, the host may include an alkali earth metal complex, a post-transition metal complex, or a combination thereof. In an embodiment, the host may include a Be complex (for example, Compound H55), an Mg complex, a Zn complex, or a combination thereof.

In an embodiment, the host may include one selected from Compounds H1 to H124, 9,10-di(2-naphthyl)anthracene (ADN), 2-methyl-9,10-bis(naphthalen-2-yl)anthracene (MADN), 9,10-di(2-naphthyl)-2-t-butyl-anthracene (TBADN), 4,4′-bis(N-carbazolyl)-1,1′-biphenyl (CBP), 1,3-di-(9-carbazolyl)benzene (mCP), 1,3,5-tri(carbazol-9-yl)benzene (TCP), or any combination thereof:

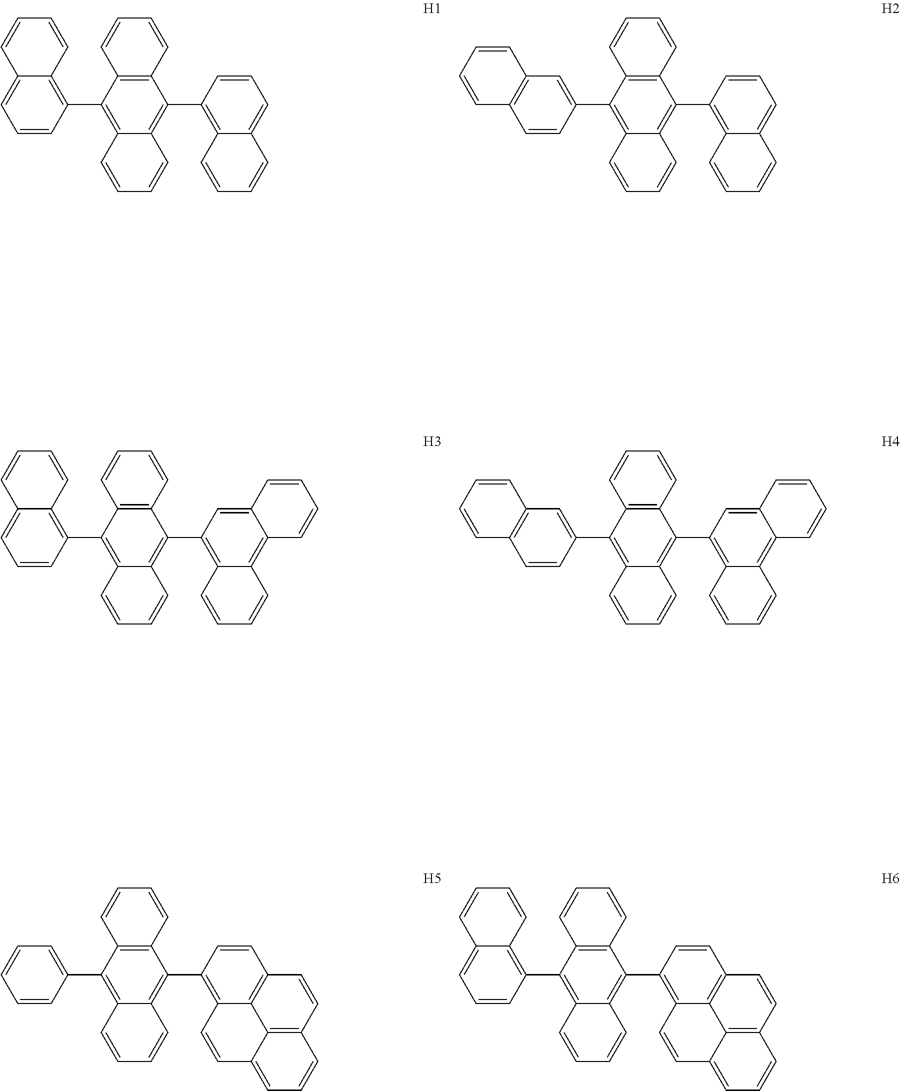

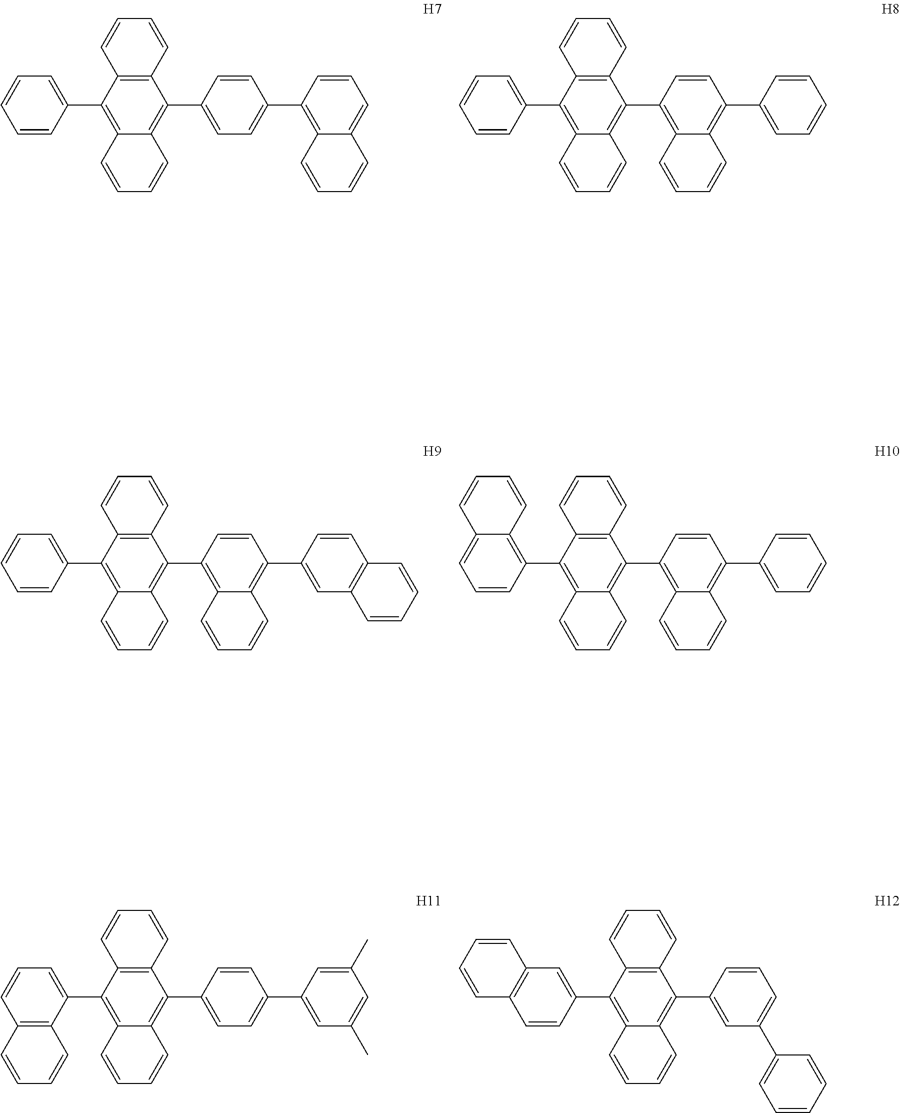

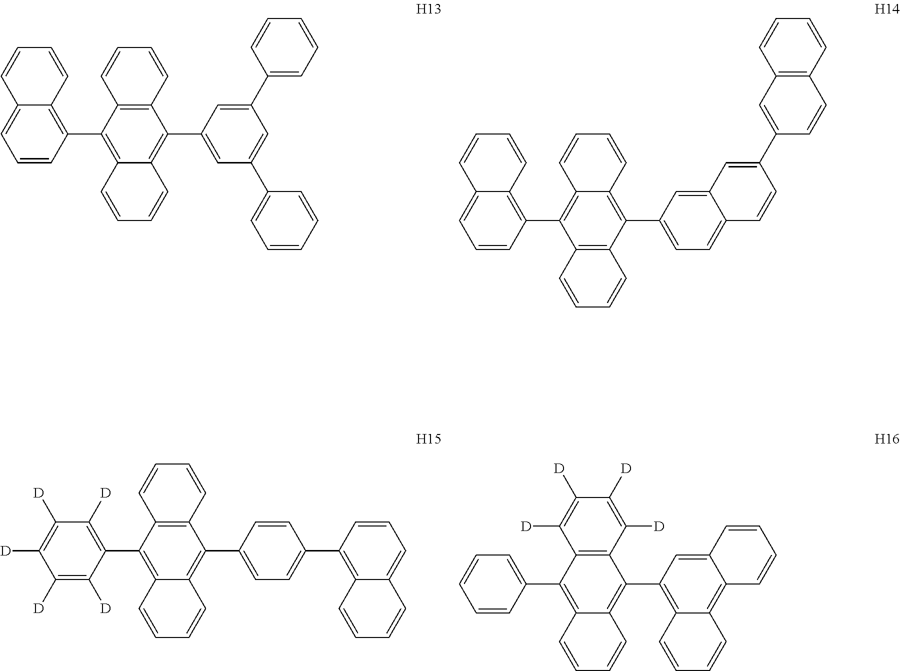

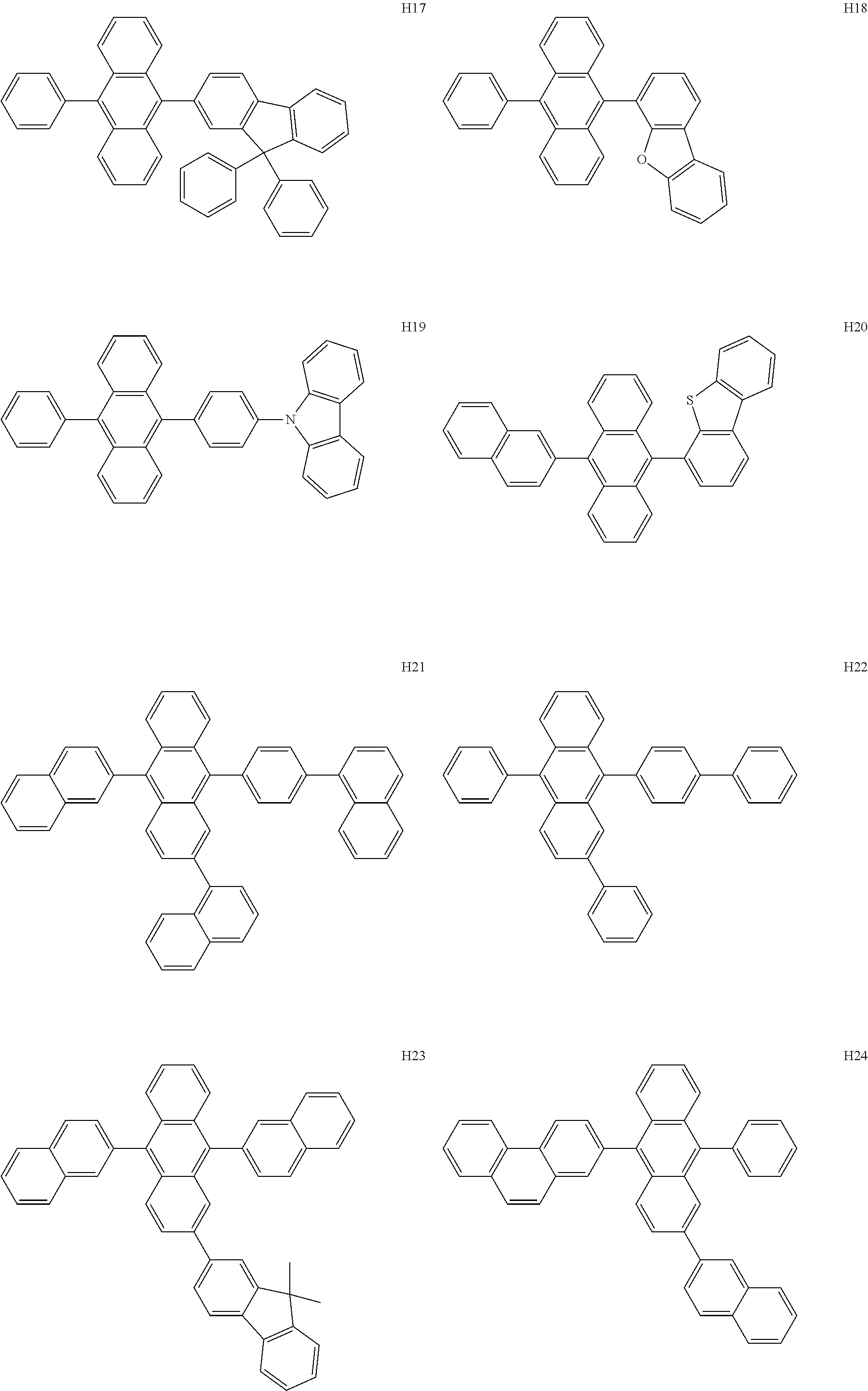

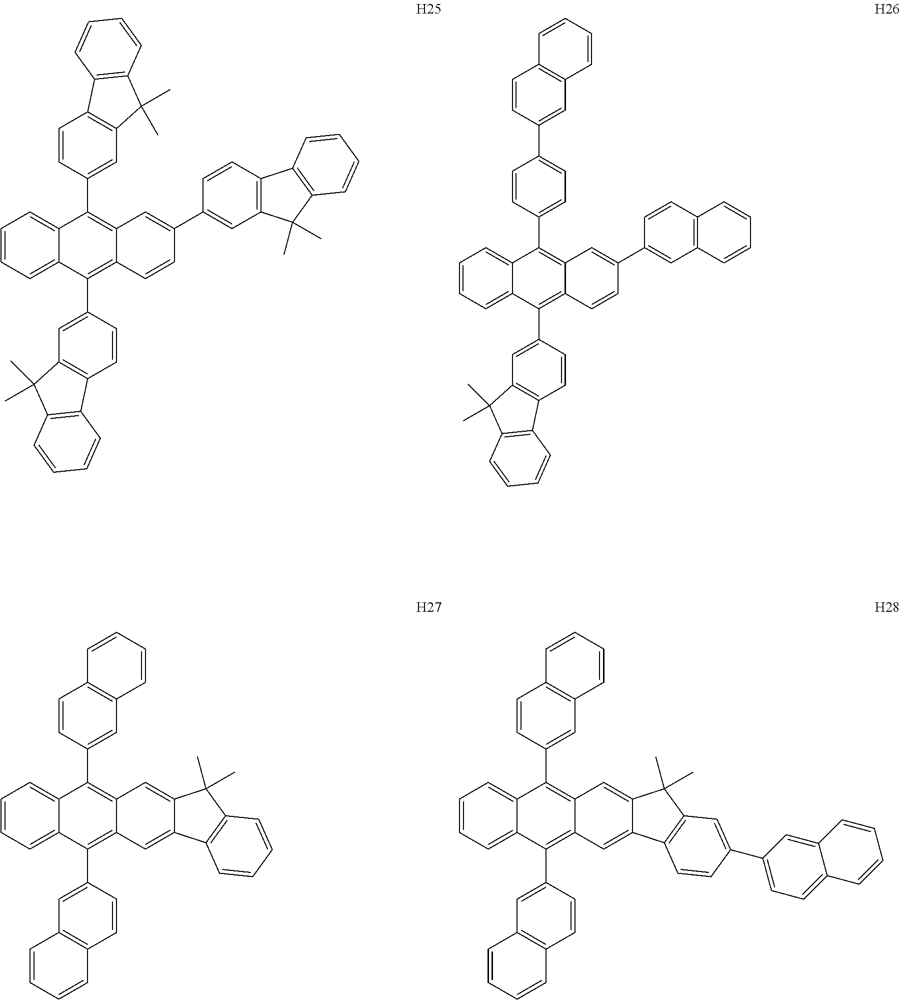

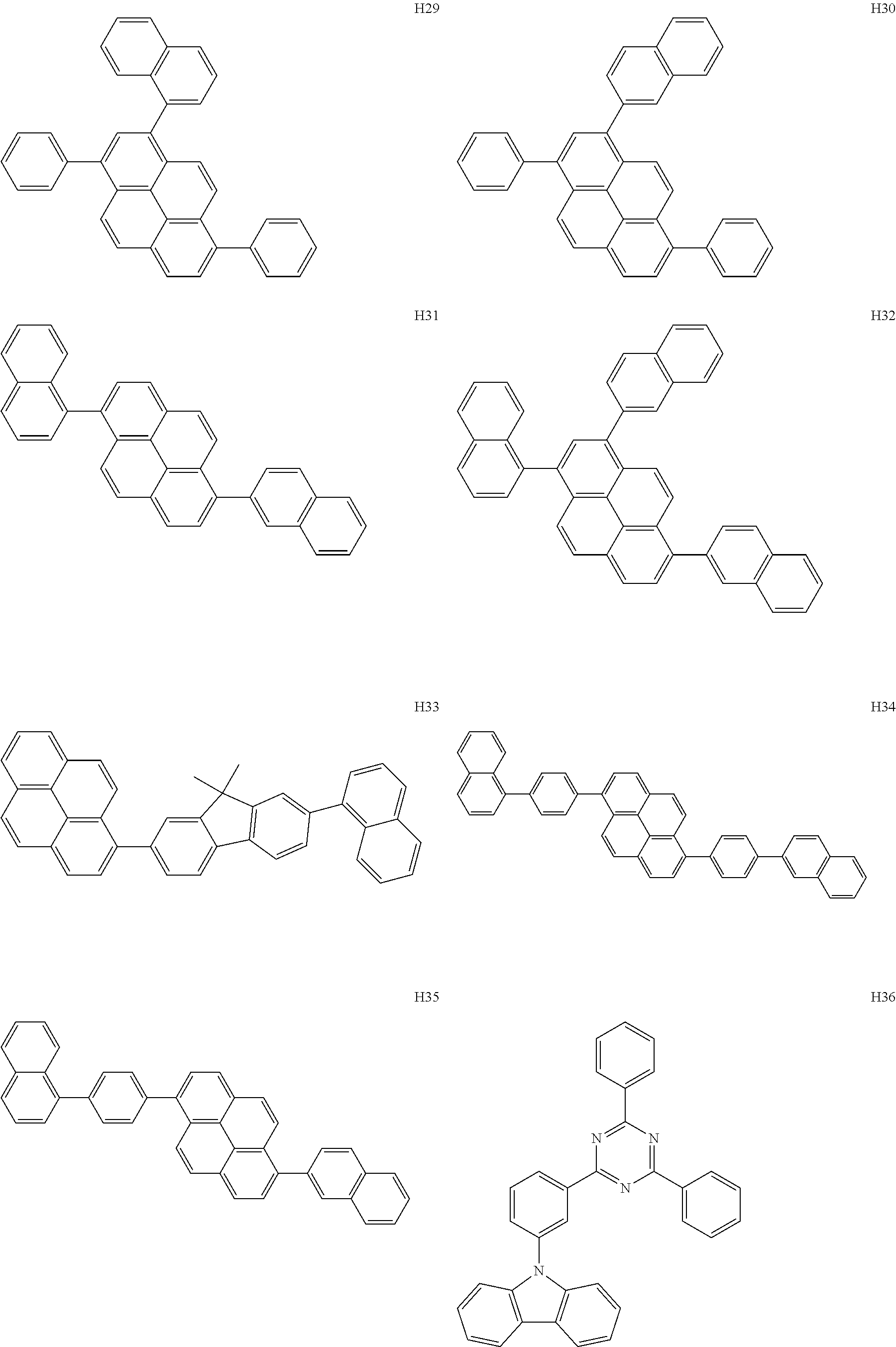

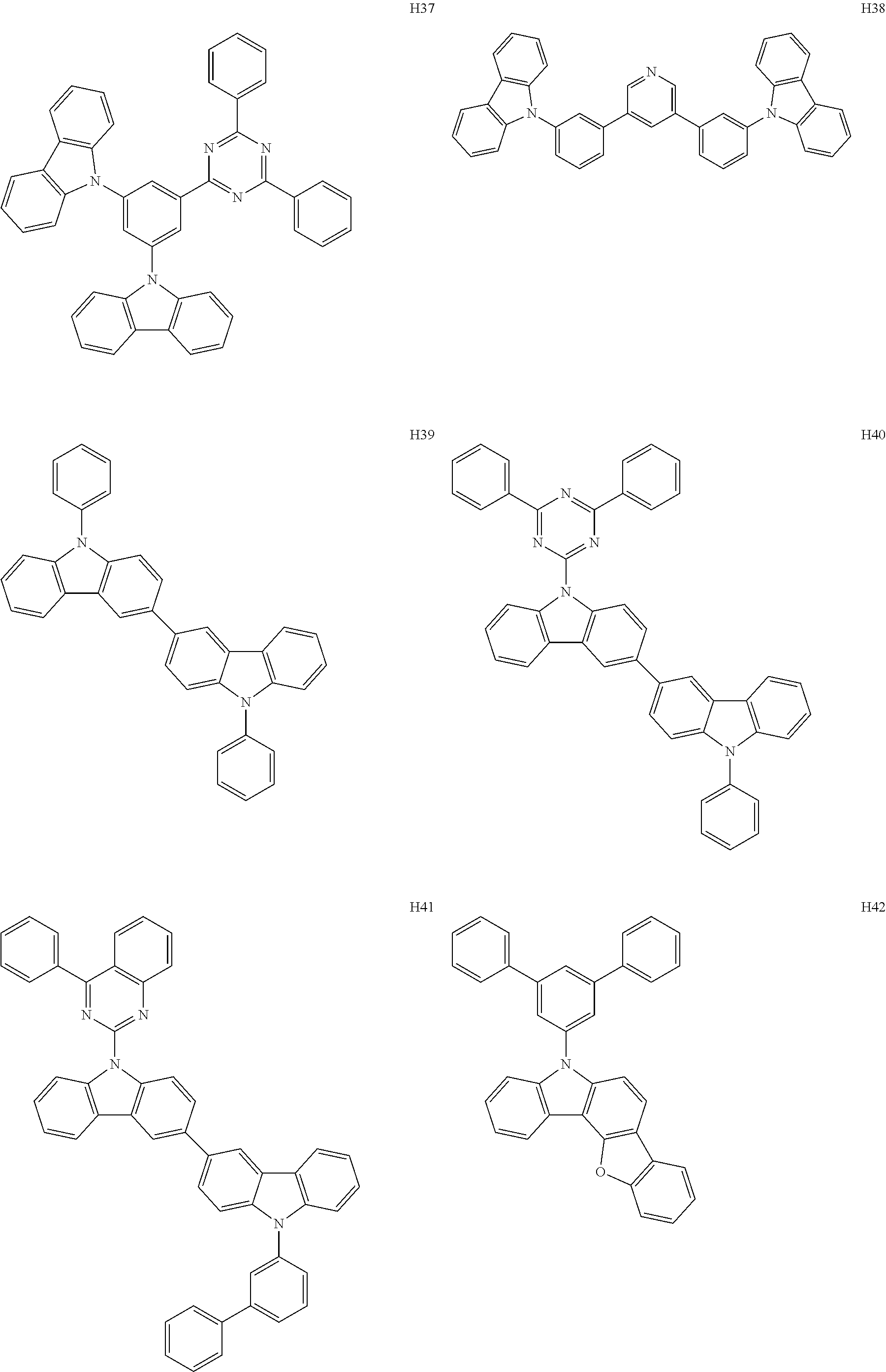 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-n2c3ccccc3c3cc(-c4ccc5c(c4)c4ccccc4n5-c4ccccc4)ccc32)cc1 ; c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2cccc(-n3c4ccccc4c4cc(-c5ccc6c(c5)c5ccccc5n6-c5nc(-c6ccccc6)c6ccccc6n5)ccc43)c2)cc1 ; c1ccc(-c2cc(-c3ccccc3)cc(-n3c4ccccc4c4c5oc6ccccc6c5ccc43)c2)cc1]

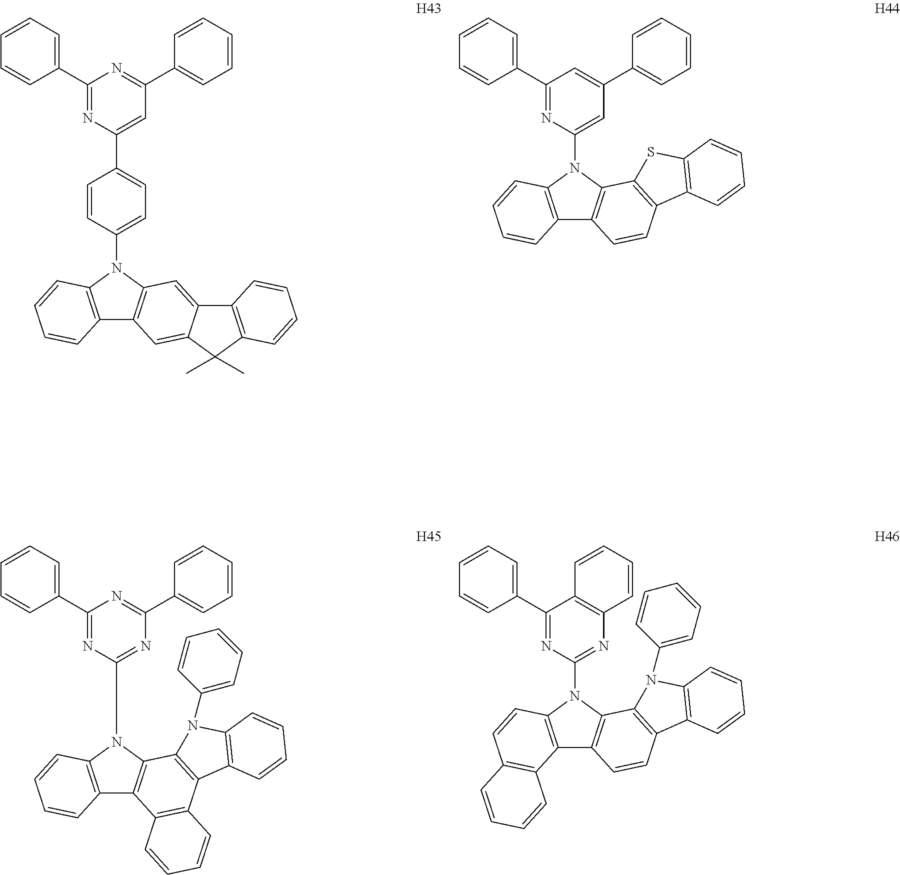 [SMILES: CC1(C)c2ccccc2-c2cc3c(cc21)c1ccccc1n3-c1ccc(-c2cc(-c3ccccc3)nc(-c3ccccc3)n2)cc1 ; c1ccc(-c2cc(-c3ccccc3)nc(-n3c4ccccc4c4ccc5c6ccccc6sc5c43)c2)cc1 ; c1ccc(-c2nc(-c3ccccc3)nc(-n3c4ccccc4c4c5ccccc5c5c6ccccc6n(-c6ccccc6)c5c43)n2)cc1 ; c1ccc(-c2nc(-n3c4ccc5ccccc5c4c4ccc5c6ccccc6n(-c6ccccc6)c5c43)nc3ccccc23)cc1]

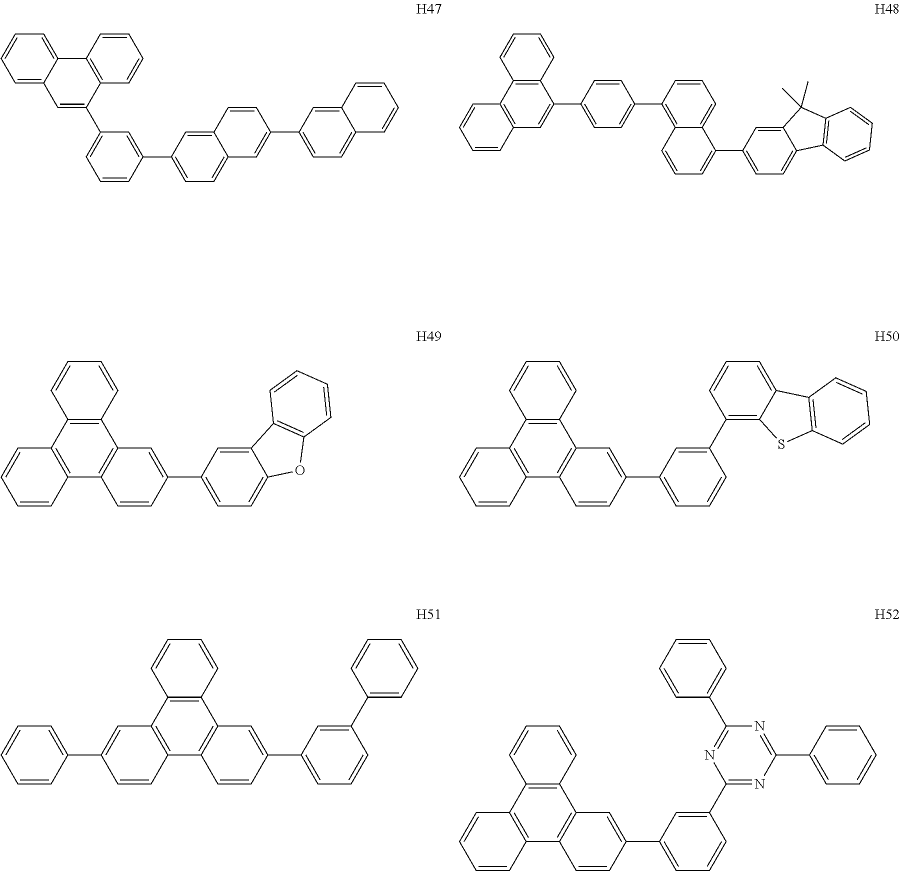

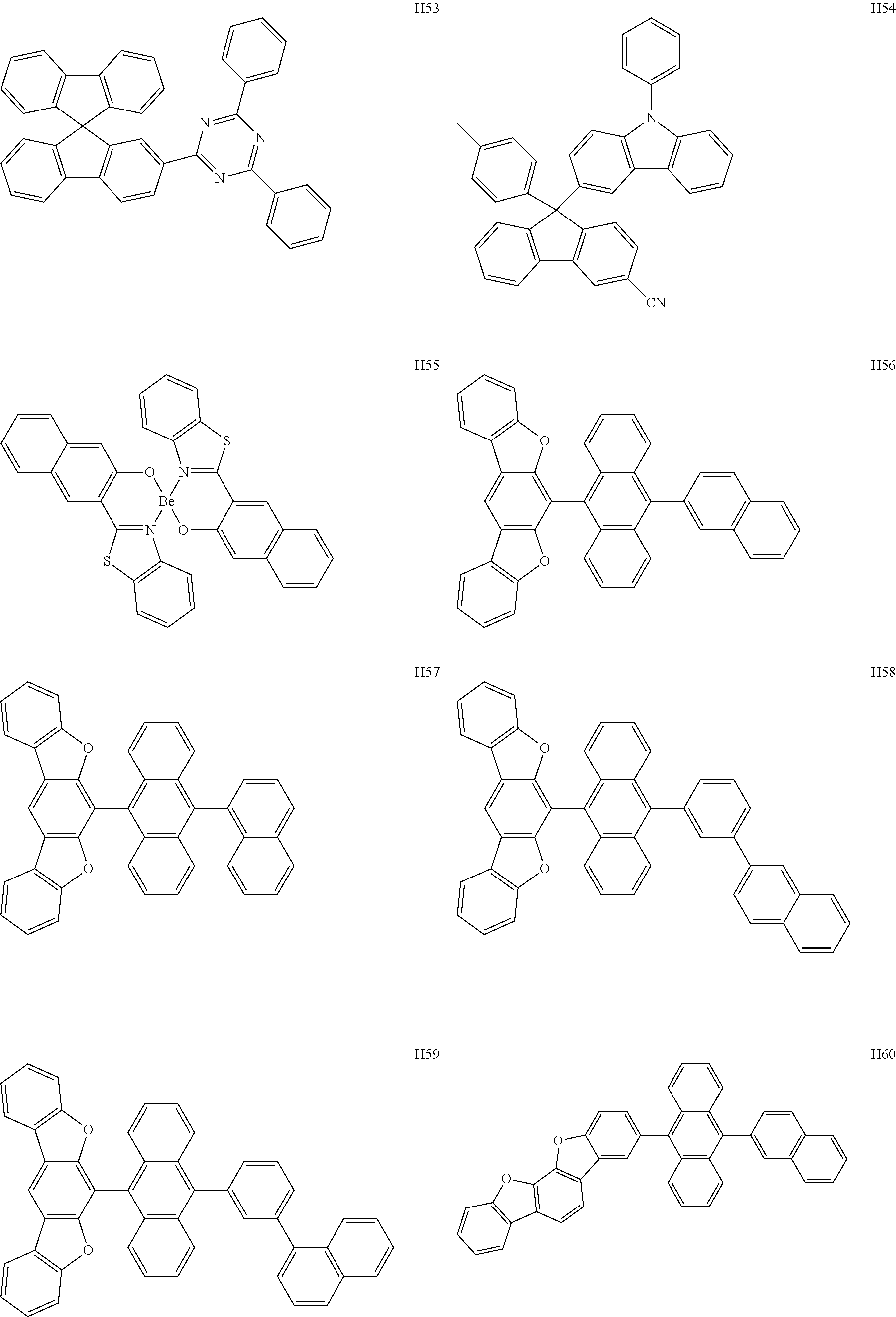

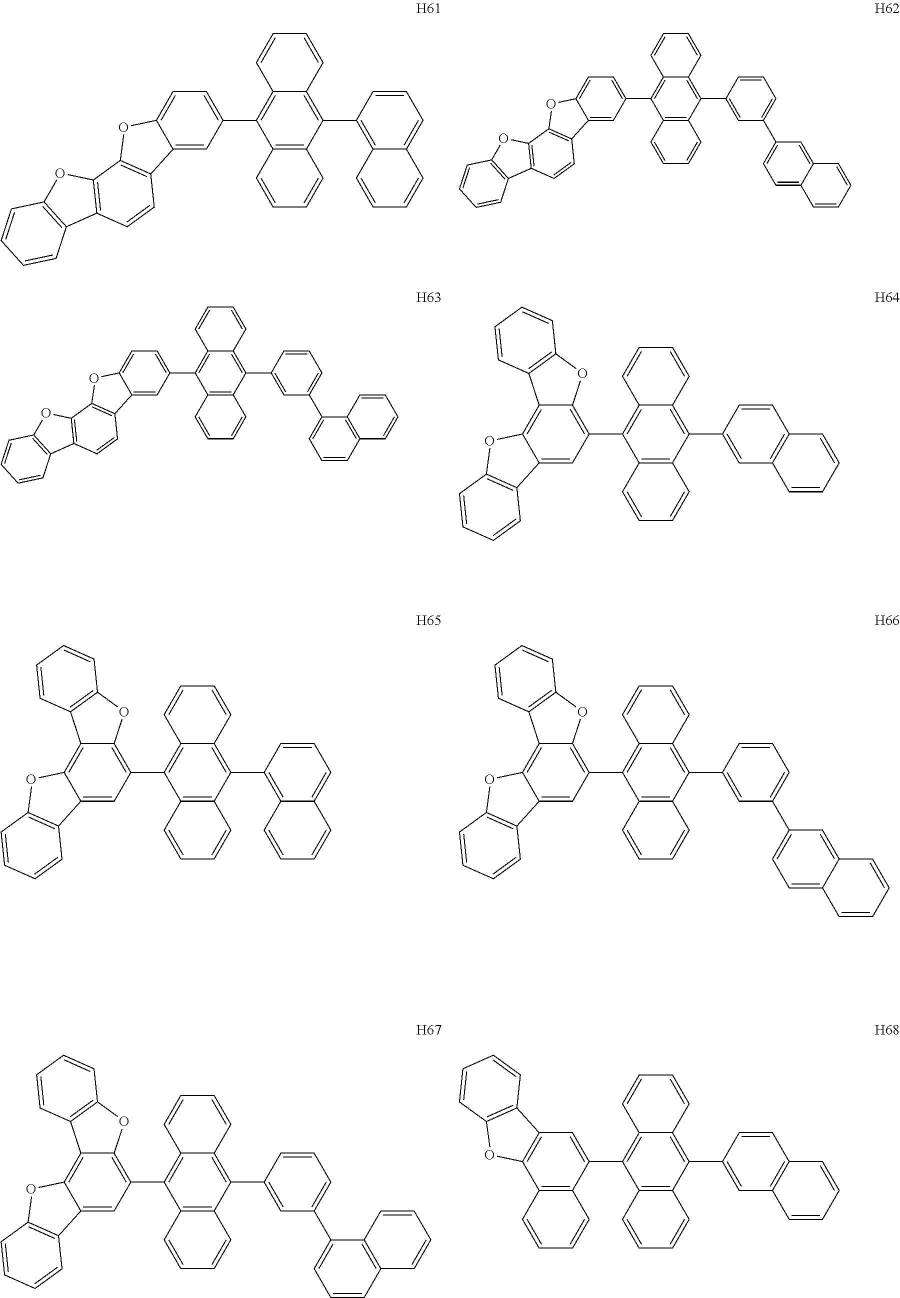

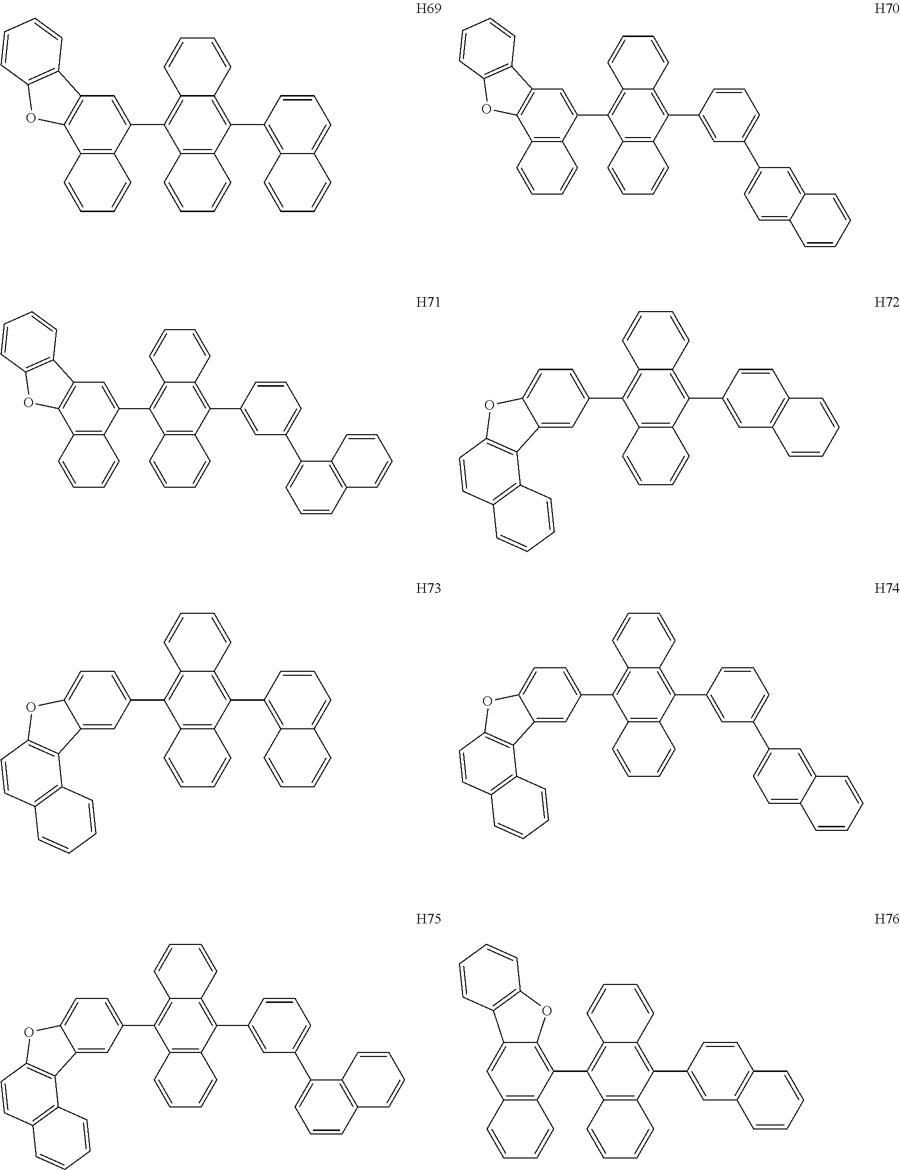

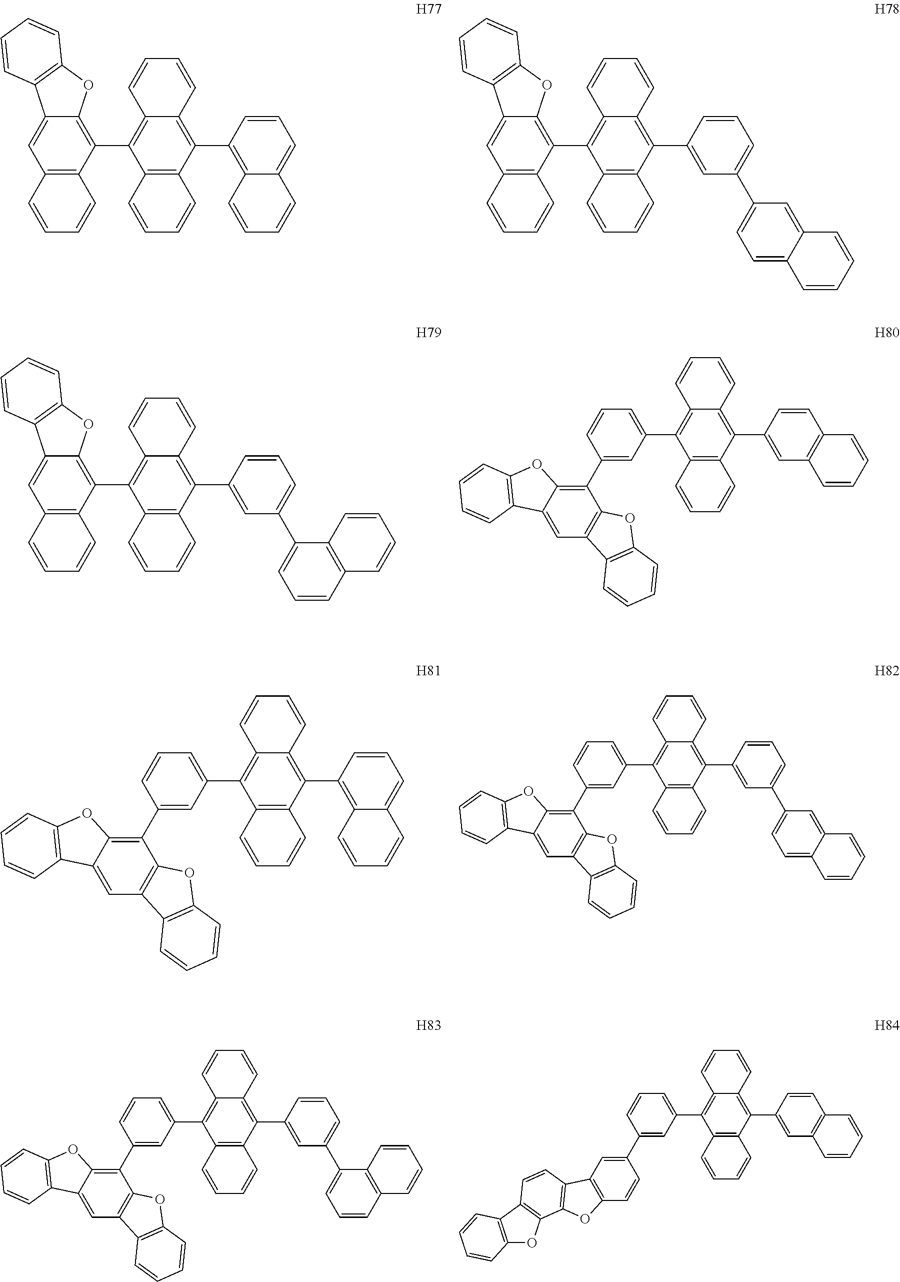

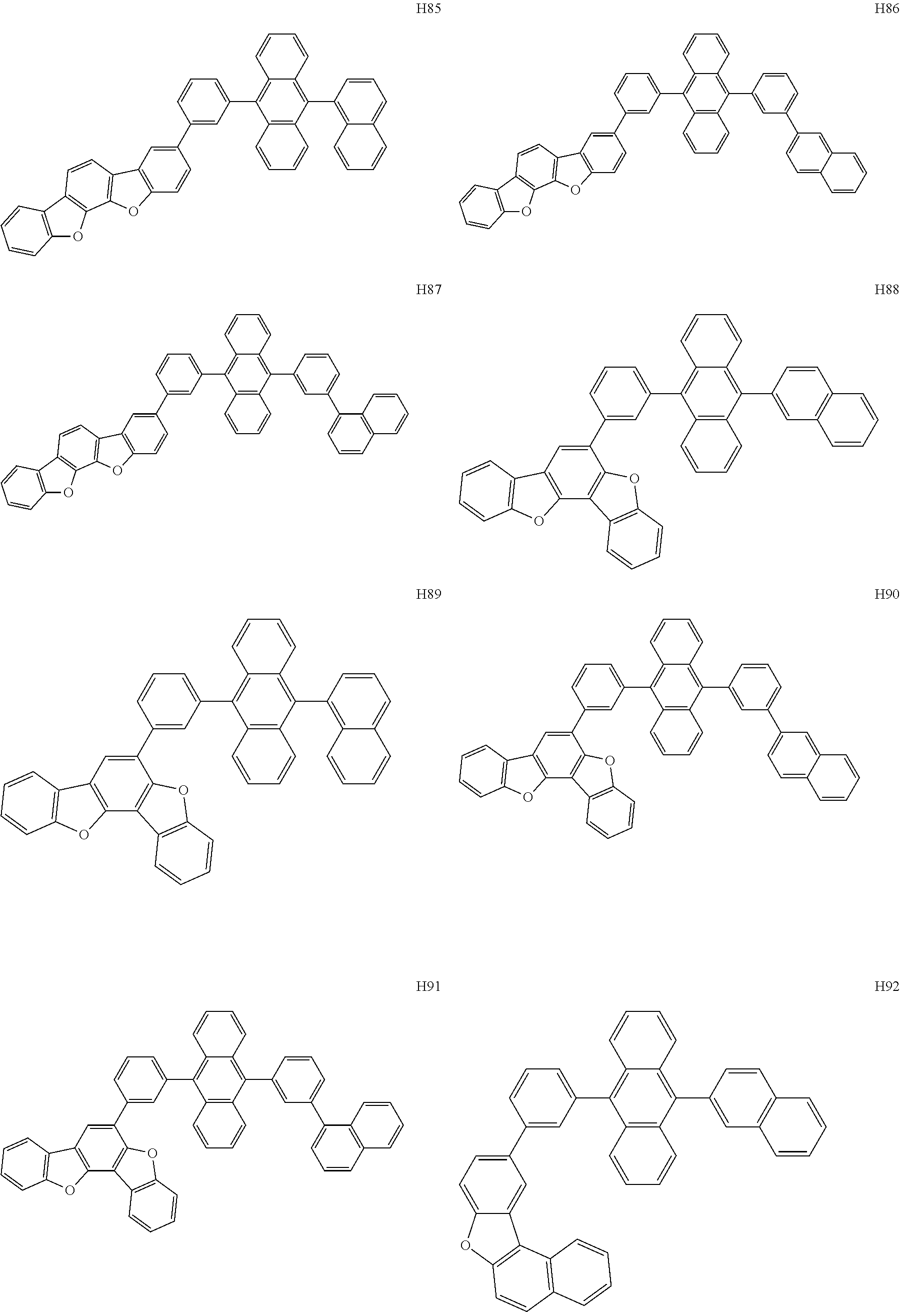

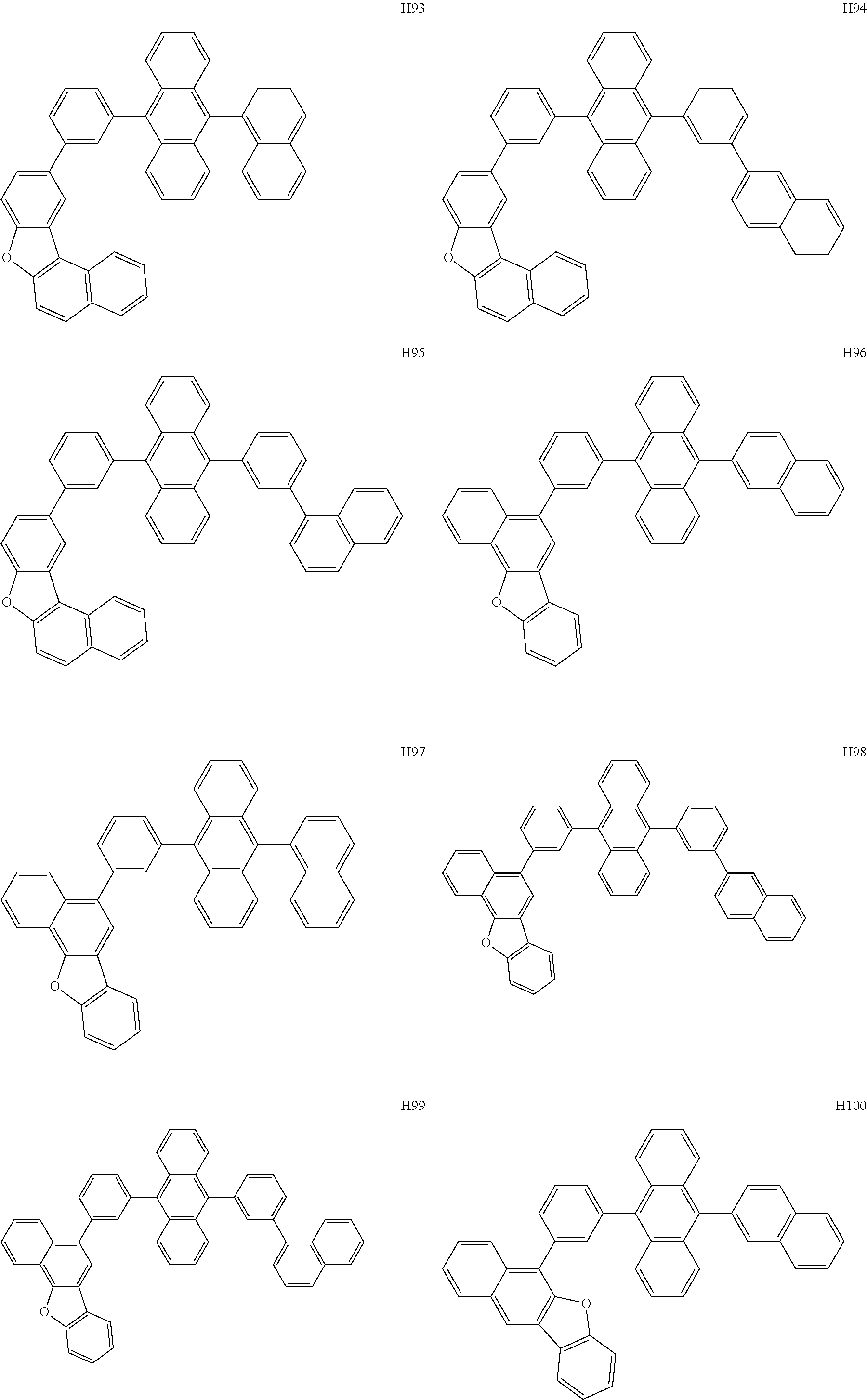

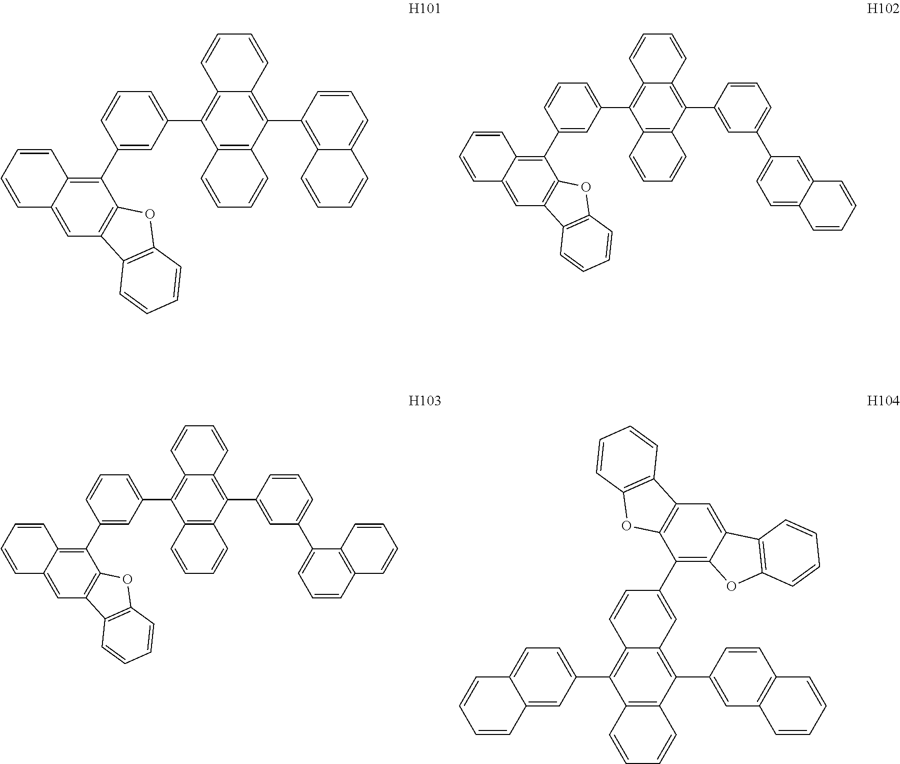 [SMILES: c1cc(-c2c3ccccc3c(-c3cccc4ccccc34)c3ccccc23)cc(-c2c3ccccc3cc3c2oc2ccccc23)c1 ; c1cc(-c2ccc3ccccc3c2)cc(-c2c3ccccc3c(-c3cccc(-c4c5ccccc5cc5c4oc4ccccc45)c3)c3ccccc23)c1 ; c1cc(-c2cccc3ccccc23)cc(-c2c3ccccc3c(-c3cccc(-c4c5ccccc5cc5c4oc4ccccc45)c3)c3ccccc23)c1 ; c1ccc2cc(-c3c4ccccc4c(-c4ccc5ccccc5c4)c4cc(-c5c6oc7ccccc7c6cc6c5oc5ccccc56)ccc34)ccc2c1]

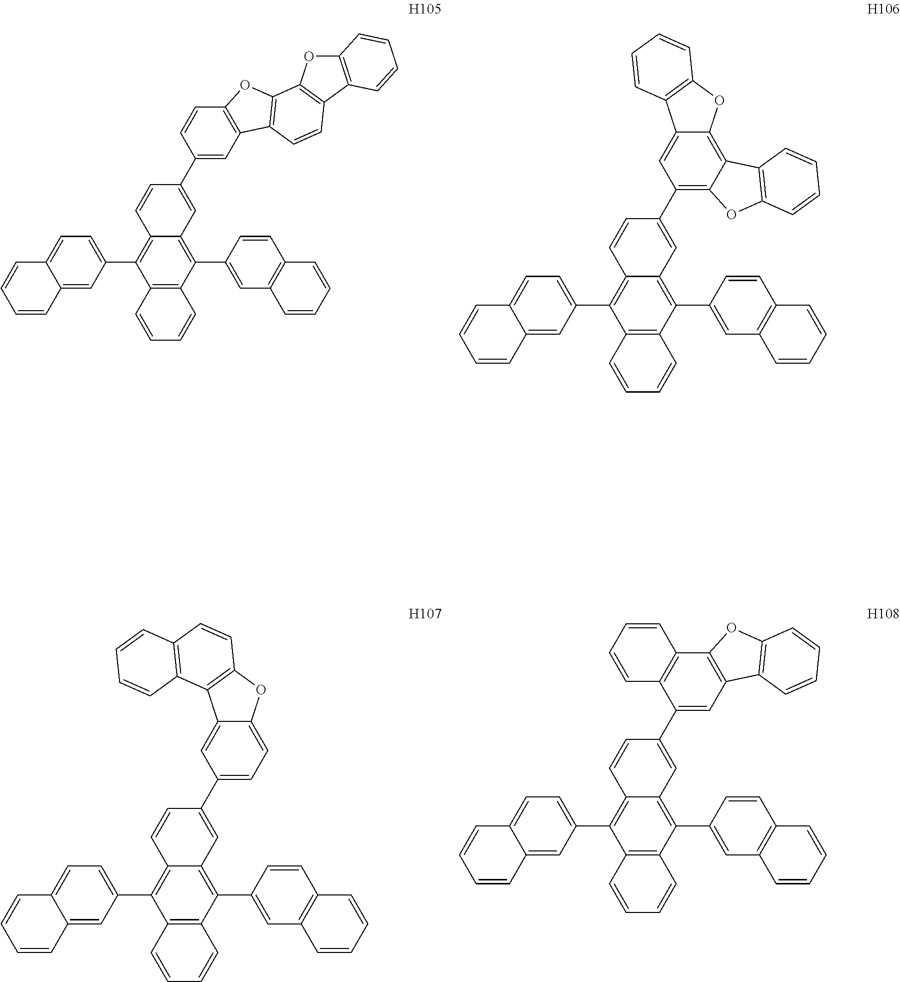 [SMILES: c1ccc2cc(-c3c4ccccc4c(-c4ccc5ccccc5c4)c4cc(-c5ccc6oc7c(ccc8c9ccccc9oc87)c6c5)ccc34)ccc2c1 ; c1ccc2cc(-c3c4ccccc4c(-c4ccc5ccccc5c4)c4cc(-c5cc6c7ccccc7oc6c6c5oc5ccccc56)ccc34)ccc2c1 ; c1ccc2cc(-c3c4ccccc4c(-c4ccc5ccccc5c4)c4cc(-c5ccc6oc7ccc8ccccc8c7c6c5)ccc34)ccc2c1 ; c1ccc2cc(-c3c4ccccc4c(-c4ccc5ccccc5c4)c4cc(-c5cc6c7ccccc7oc6c6ccccc56)ccc34)ccc2c1]

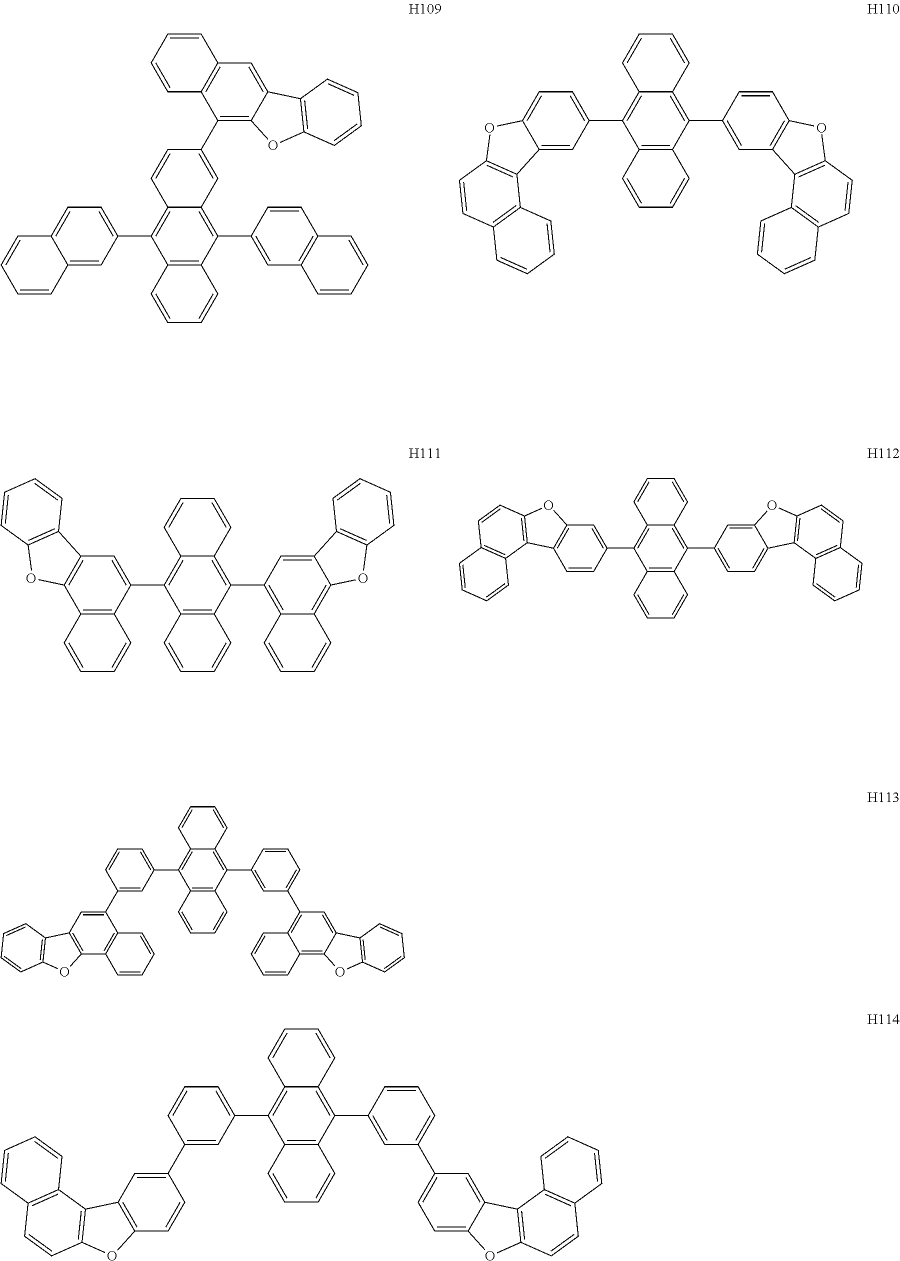

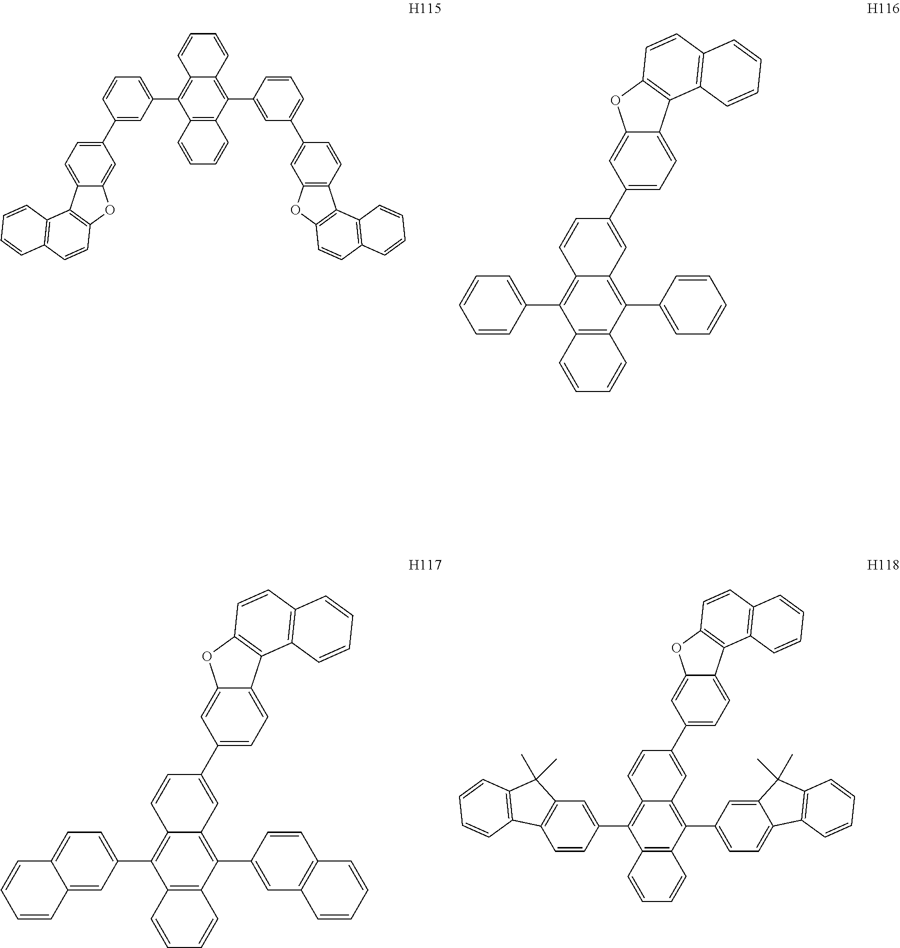 [SMILES: c1cc(-c2ccc3c(c2)oc2ccc4ccccc4c23)cc(-c2c3ccccc3c(-c3cccc(-c4ccc5c(c4)oc4ccc6ccccc6c45)c3)c3ccccc23)c1 ; c1ccc(-c2c3ccccc3c(-c3ccccc3)c3cc(-c4ccc5c(c4)oc4ccc6ccccc6c45)ccc23)cc1 ; c1ccc2cc(-c3c4ccccc4c(-c4ccc5ccccc5c4)c4cc(-c5ccc6c(c5)oc5ccc7ccccc7c56)ccc34)ccc2c1 ; CC1(C)c2ccccc2-c2ccc(-c3c4ccccc4c(-c4ccc5c(c4)C(C)(C)c4ccccc4-5)c4cc(-c5ccc6c(c5)oc5ccc7ccccc7c56)ccc34)cc21]

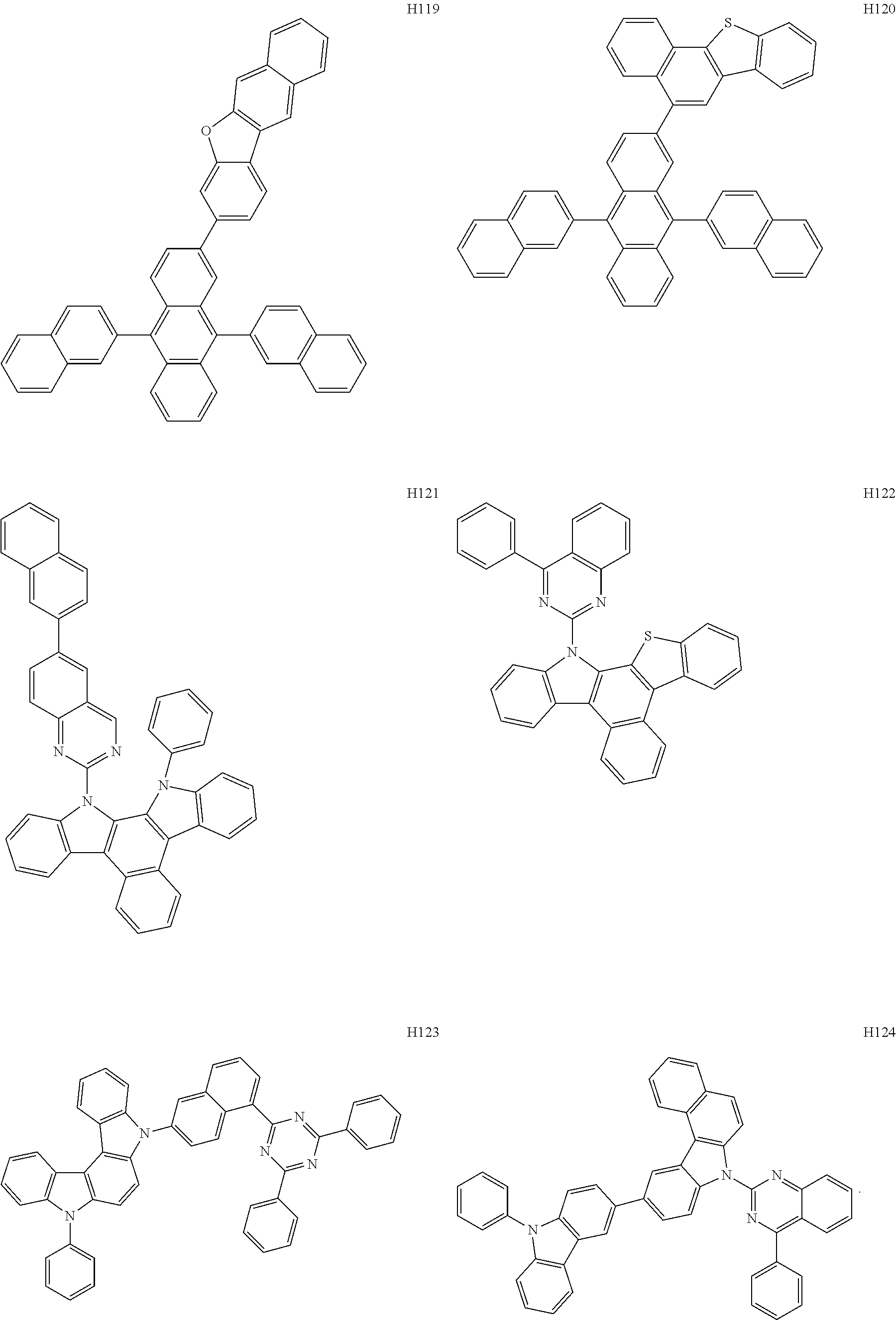

In an embodiment, the host may include a silicon-containing compound, a phosphine oxide-containing compound, or any combination thereof.

The host may have various suitable modifications. In an embodiment, the host may include only one kind of compound, or may include two or more kinds of different compounds.

### Phosphorescent Dopant

The emission layer may include, as a phosphorescent dopant, an organometallic compound represented by Formula 1 as described in the present specification or an organometallic compound including platinum and a tetradentate ligand.

In an embodiment, the emission layer may include an organometallic compound represented by Formula 1 as described in the present specification or an organometallic compound including platinum and a tetradentate ligand, and when the organometallic compound represented by Formula 1 as described in the present specification or the organometallic compound including the platinum and the tetradentate ligand serves an auxiliary dopant, the emission layer may include a phosphorescent dopant.

The phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

In an embodiment, the phosphorescent dopant may include an organometallic compound represented by Formula 401:

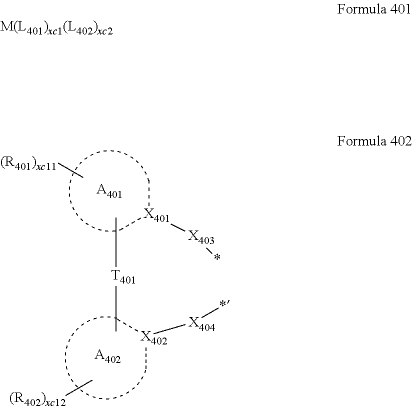

wherein, in Formulae 401 and 402,

M may be a transition metal (for example, iridium (Ir), platinum (Pt), palladium (Pd), osmium (Os), titanium (Ti), gold (Au), hafnium (Hf), europium (Eu), terbium (Tb), rhodium (Rh), rhenium (Re), or thulium (Tm)),

L₄₀₁ may be a ligand represented by Formula 402, and xc-1 may be 1, 2, or 3, wherein, when xc1 is two or more, two or more of L₄₀₁ (s) may be identical to or different from each other,

L₄₀₂ may be an organic ligand, and xc2 may be 0, 1, 2, 3, or 4, wherein, when xc2 is 2 or more, two or more of L₄₀₂(s) may be identical to or different from each other,

X₄₀₁ and X₄₀₂ may each independently be nitrogen or carbon,

ring A₄₀₁ and ring A₄₀₂ may each independently be a C₃-C₆₀ carbocyclic group or a C₁-C₆₀ heterocyclic group,

T₄₀₁ may be a single bond, *—O—*′, *—S—*′, *—C(═O)—*′, *—N(Q₄₁₁)—*′, *—C(Q₄₁₁)(Q₄₁₂)—*′, *—C(Q₄₁₁)═C(Q₄₁₂)—*′, *—C(Q₄₁₁)═*′, or *′2 C═*′,

X₄₀₃ and X₄₀₄ may each independently be a chemical bond (for example, a covalent bond or a coordinate bond), O, S, N(Q₄₁₃), B(Q₄₁₃), P(Q₄₁₃), C(Q₄₁₃)(Q₄₁₄), or Si(Q₄₁₃)(Q₄₁₄),

Q₄₁₁ to Q₄₁₄ are respectively the same as described in connection with Q₁ in the present specification,

R₄₀₁ and R₄₀₂ may each independently be hydrogen, deuterium, —F, —CI, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),

Q₄₀₁ to Q₄₀₃ are respectively the same as described in connection with Q₁ in the present specification,

xc11 and xc12 may each independently be an integer selected from 0 to 10, and

* and *′ in Formula 402 each indicate a binding site to M in Formula 401.

In an embodiment, in Formula 402, i) X₄₀₁ may be nitrogen, and X₄₀₂ may be carbon, or ii) each of X₄₀₁ and X₄₀₂ may be nitrogen.

In an embodiment, when xc1 in Formula 401 is 2 or more, two ring A₄₀₁ in two or more of L₄₀₁(s) may be optionally linked to each other via T₄₀₂, which is a linking group, and two ring A₄₀₂ may optionally be linked to each other via T₄₀₃, which is a linking group (see Compounds PD1 to PD4 and PD7). T₄₀₂ and T₄₀₃ are respectively the same as described in connection with T₄₀₁ in the present specification.

L₄₀₂ in Formula 401 may be an organic ligand. In an embodiment, L₄₀₂ may include a halogen group, a diketone group (for example, an acetylacetonate group), a carboxylic acid group (for example, a picolinate group), —C(═O), an isonitrile group, —CN group, a phosphorus-containing group (for example, a phosphine group, a phosphite group, etc.), or any combination thereof.

The phosphorescent dopant may include, for example, one selected from compounds PD1 to PD25 or any combination thereof:

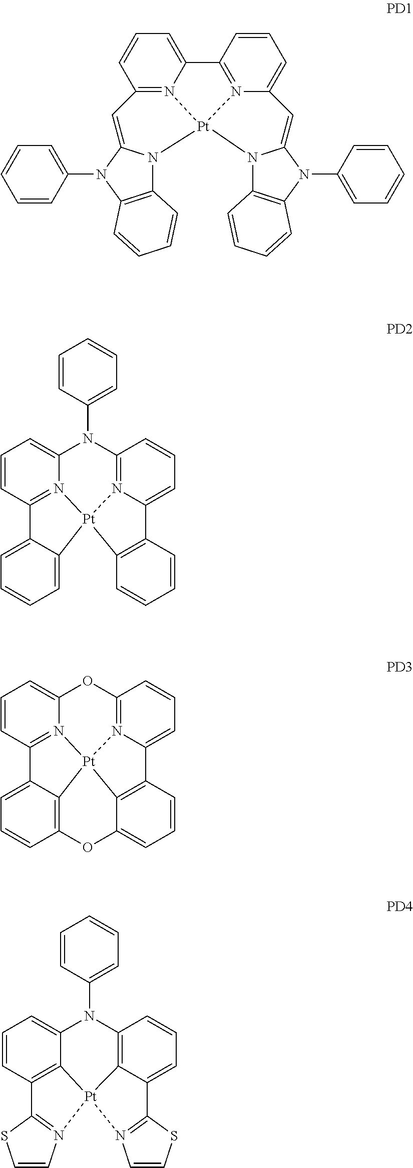

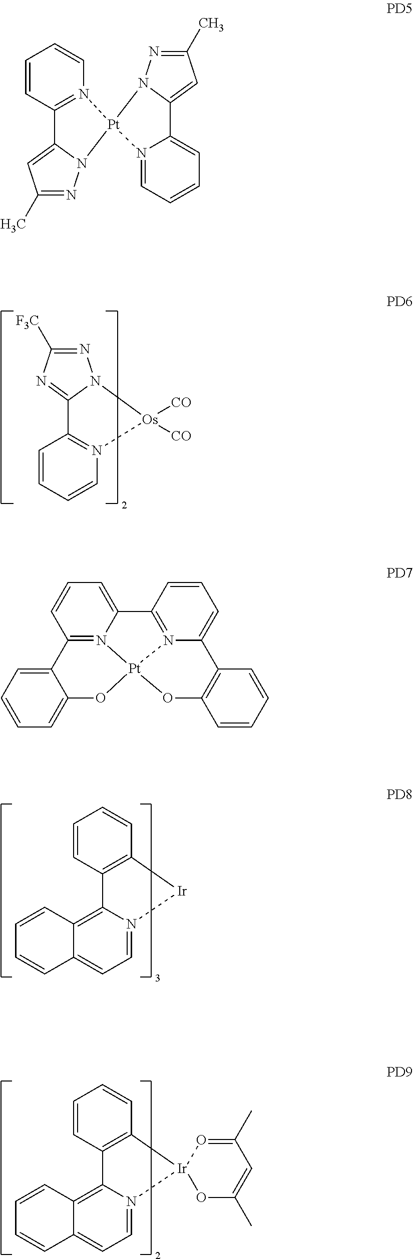

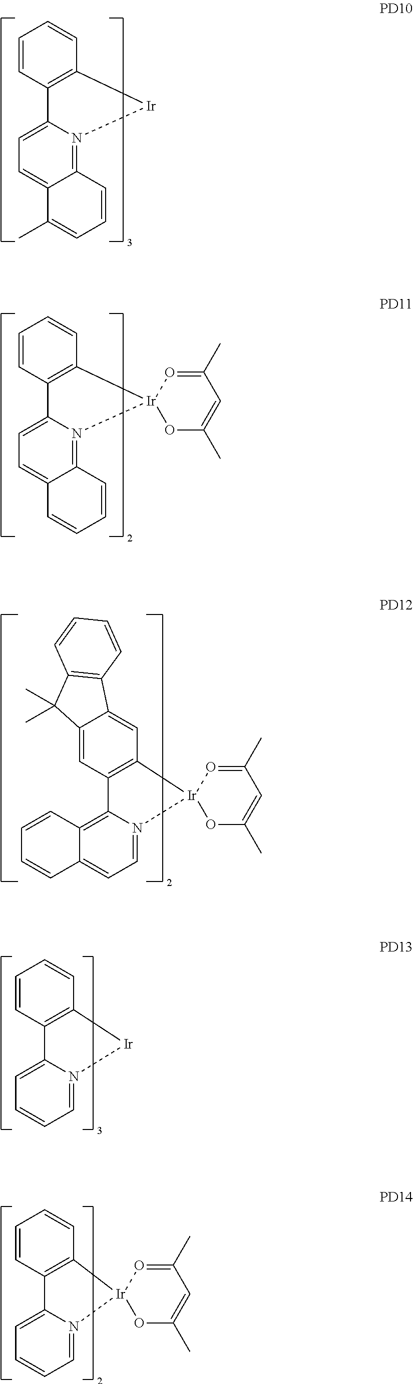

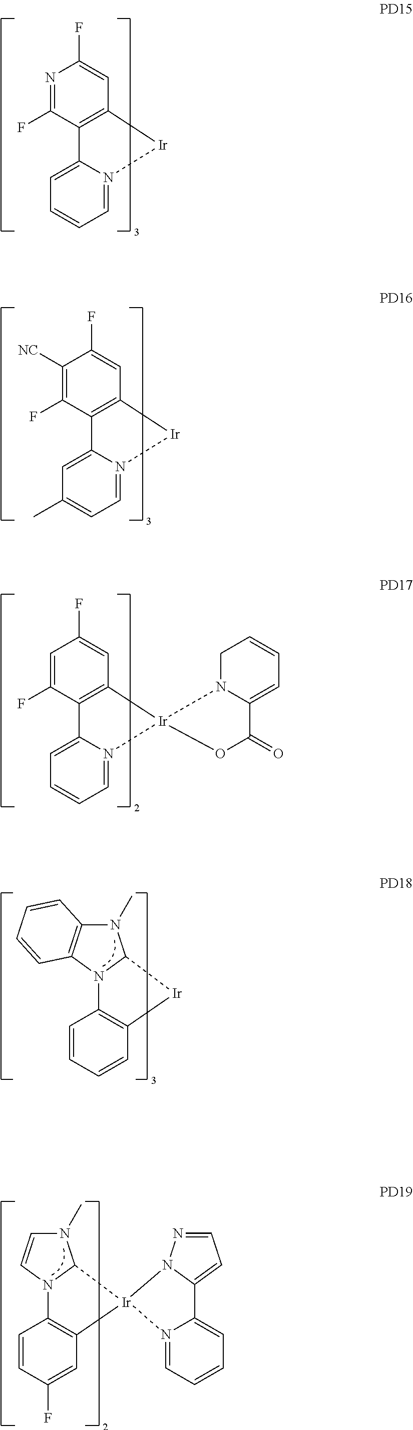

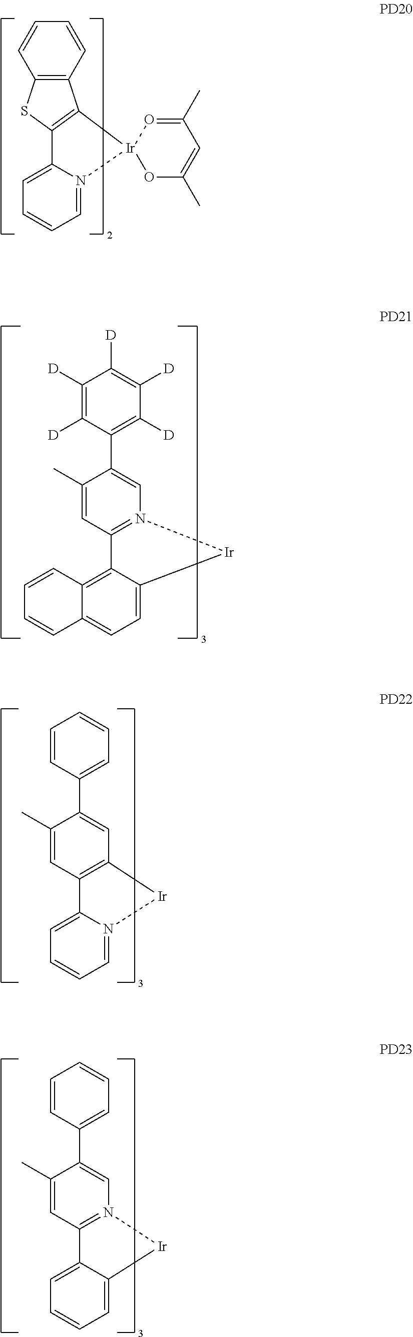

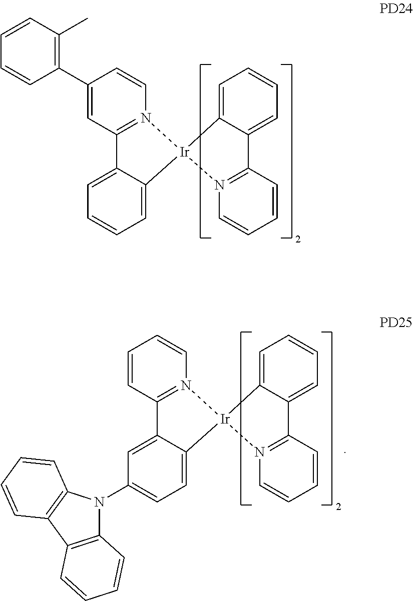

### Fluorescent Dopant

The emission layer may include an organometallic compound represented by Formula 1 as described in the present specification or an organometallic compound including platinum and a tetradentate ligand, and when the organometallic compound represented by Formula 1 as described in the present specification or the organometallic compound including the platinum and the tetradentate ligand serves an auxiliary dopant, the emission layer may further include a fluorescent dopant.

In an embodiment, the emission layer may include an organometallic compound represented by Formula 1 as described in the present specification or an organometallic compound including platinum and a tetradentate ligand, and when the organometallic compound represented by Formula 1 as described in the present specification or the organometallic compound including the platinum and the tetradentate ligand serves a phosphorescent dopant, the emission layer may further include an auxiliary dopant.

The fluorescent dopant and the auxiliary dopant may each independently include an arylamine compound, a styrylamine compound, a boron-containing compound, or any combination thereof.

In an embodiment, the fluorescent dopant and the auxiliary dopant may each independently include a compound represented by Formula 501 below:

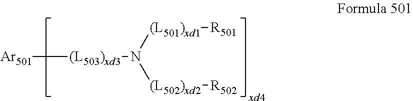

wherein, in Formula 501,

Ar₅₀₁, L₅₀₁ to L₅₀₃, R₅₀₁, and R₅₀₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

xd1 to xd3 may each independently be 0, 1, 2, or 3, and

xd4 may be 1, 2, 3, 4, 5, or 6.

In an embodiment, Ar₆₀₁ in Formula 501 may be a condensed cyclic group (for example, an anthracene group, a chrysene group, or a pyrene group) in which three or more monocyclic groups are condensed together.

In an embodiment, xd4 in Formula 501 may be 2.

In an embodiment, the fluorescent dopant and the auxiliary dopant may each include one selected from Compounds FD1 to FD36, DPVBi, DPAVBi, or any combination thereof:

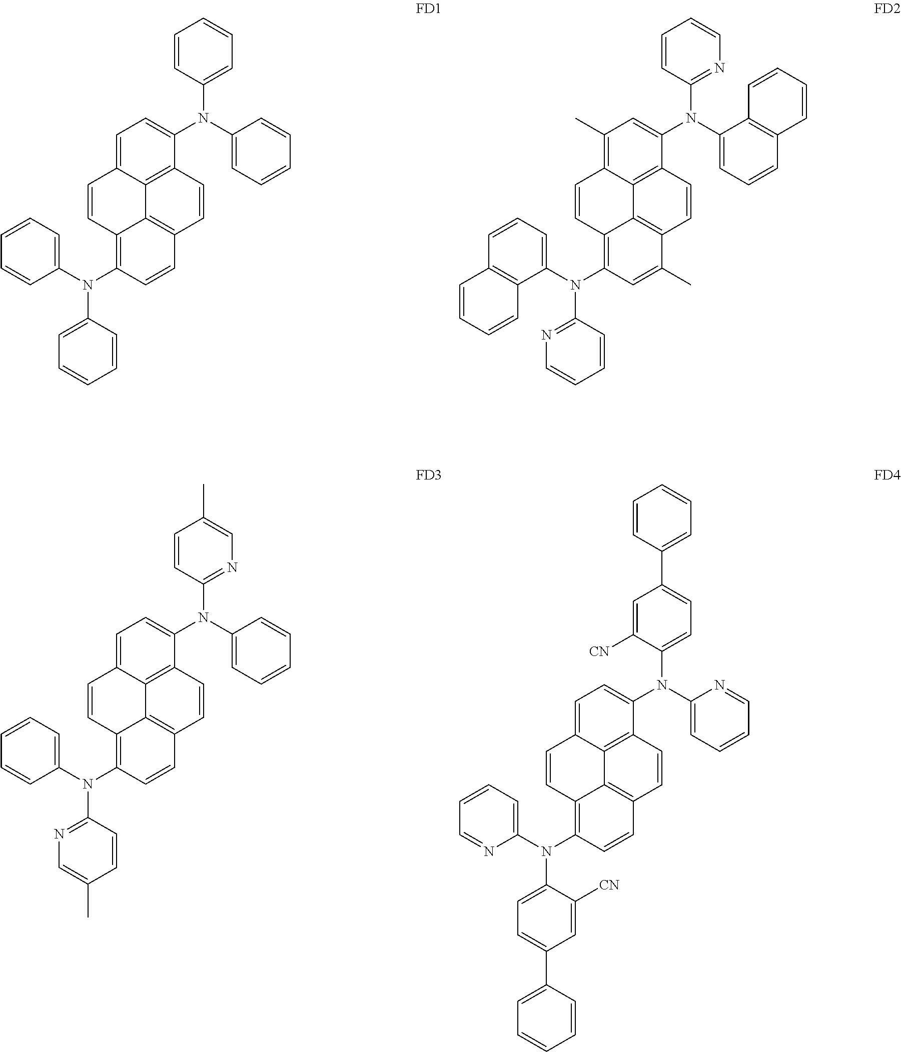

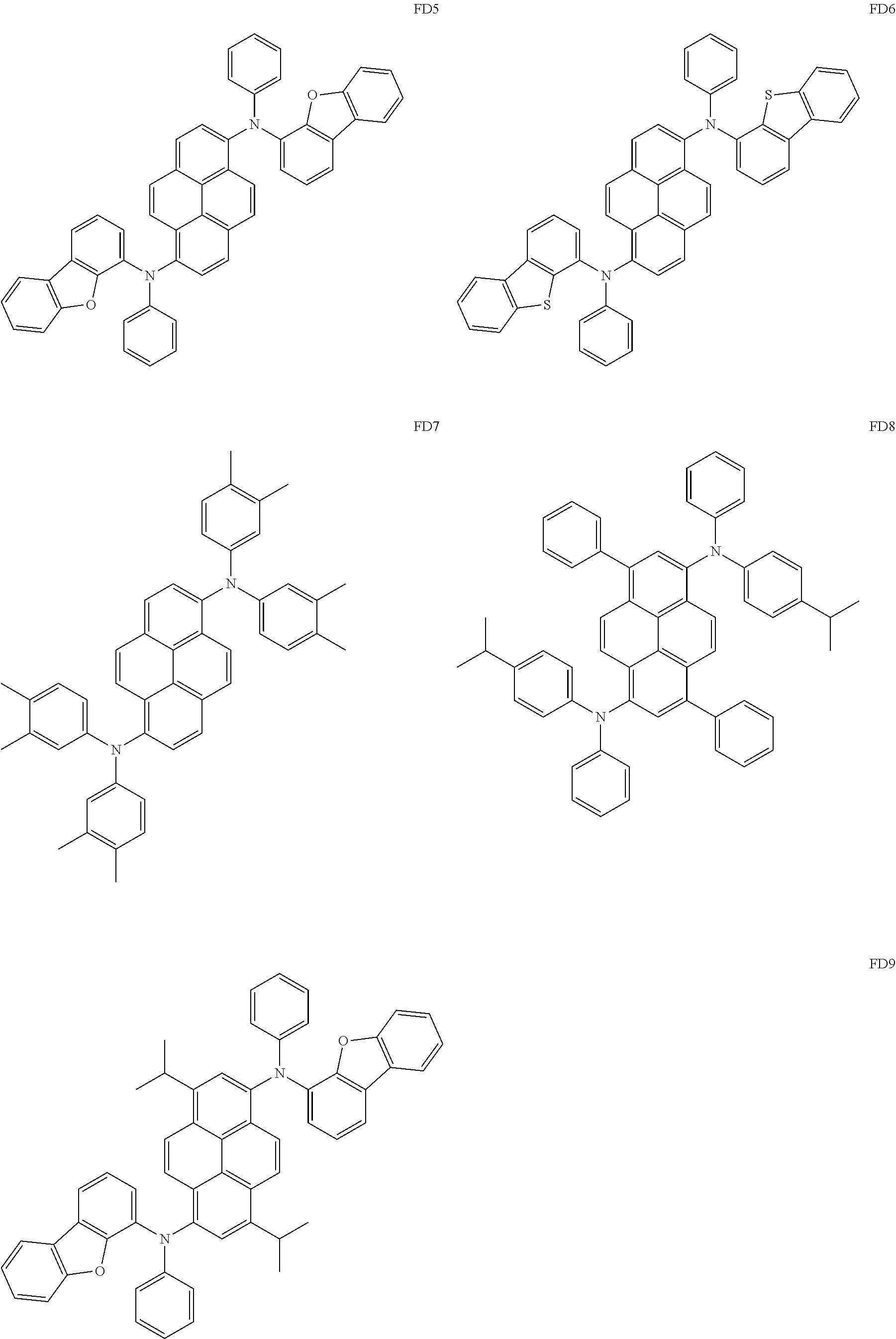

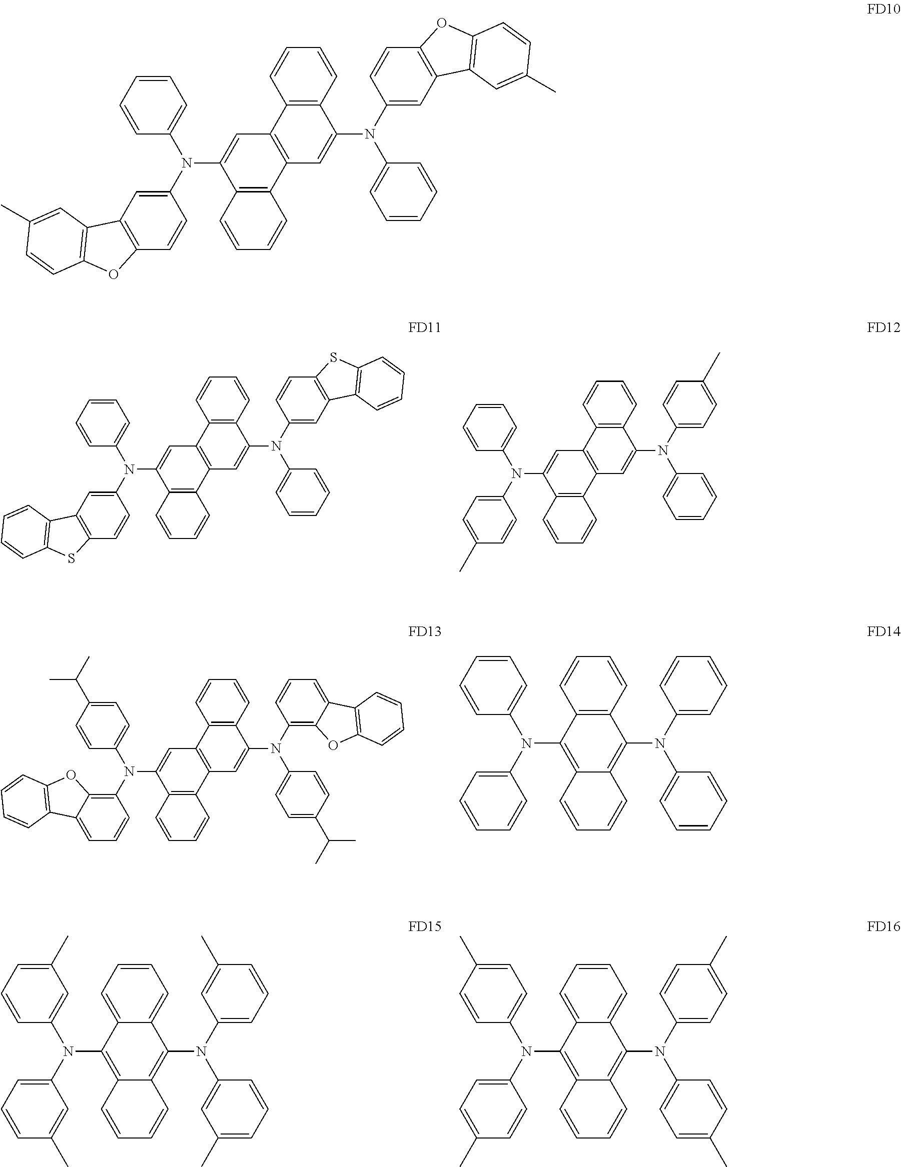

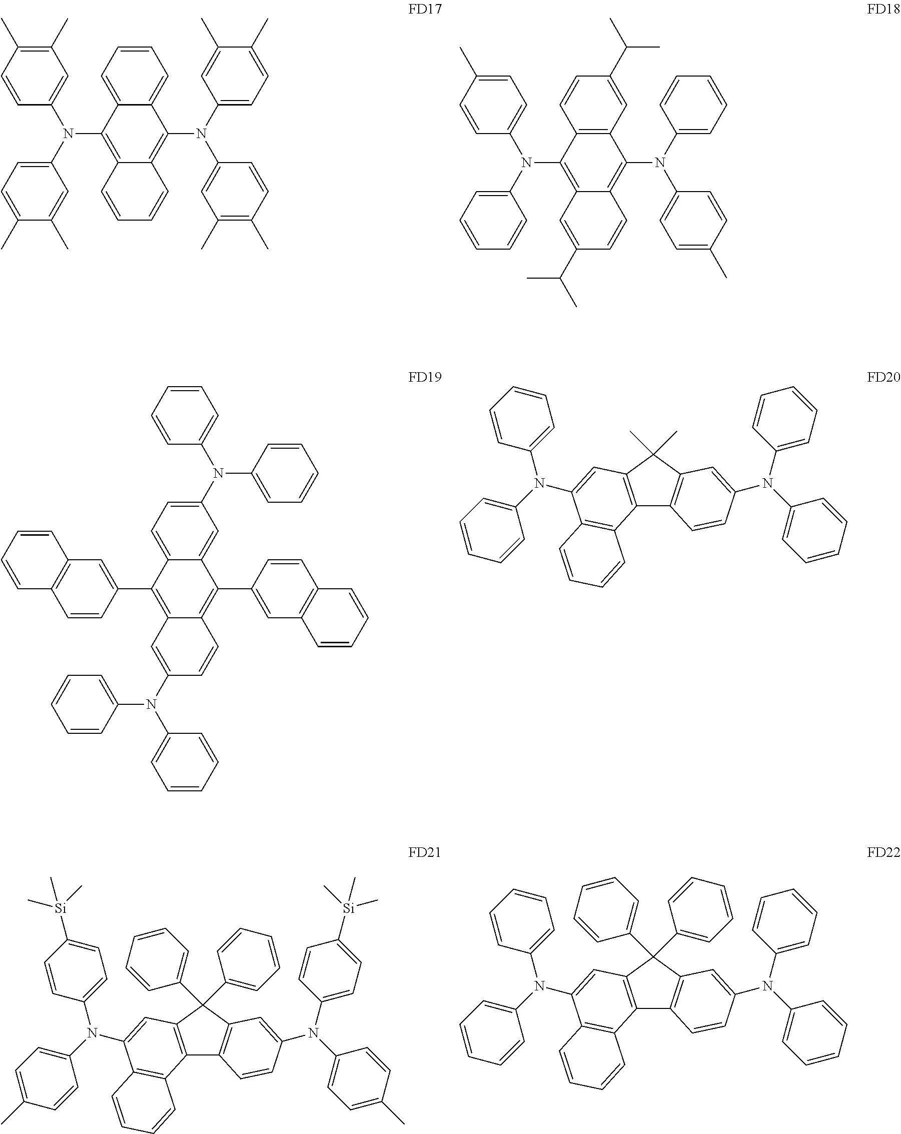

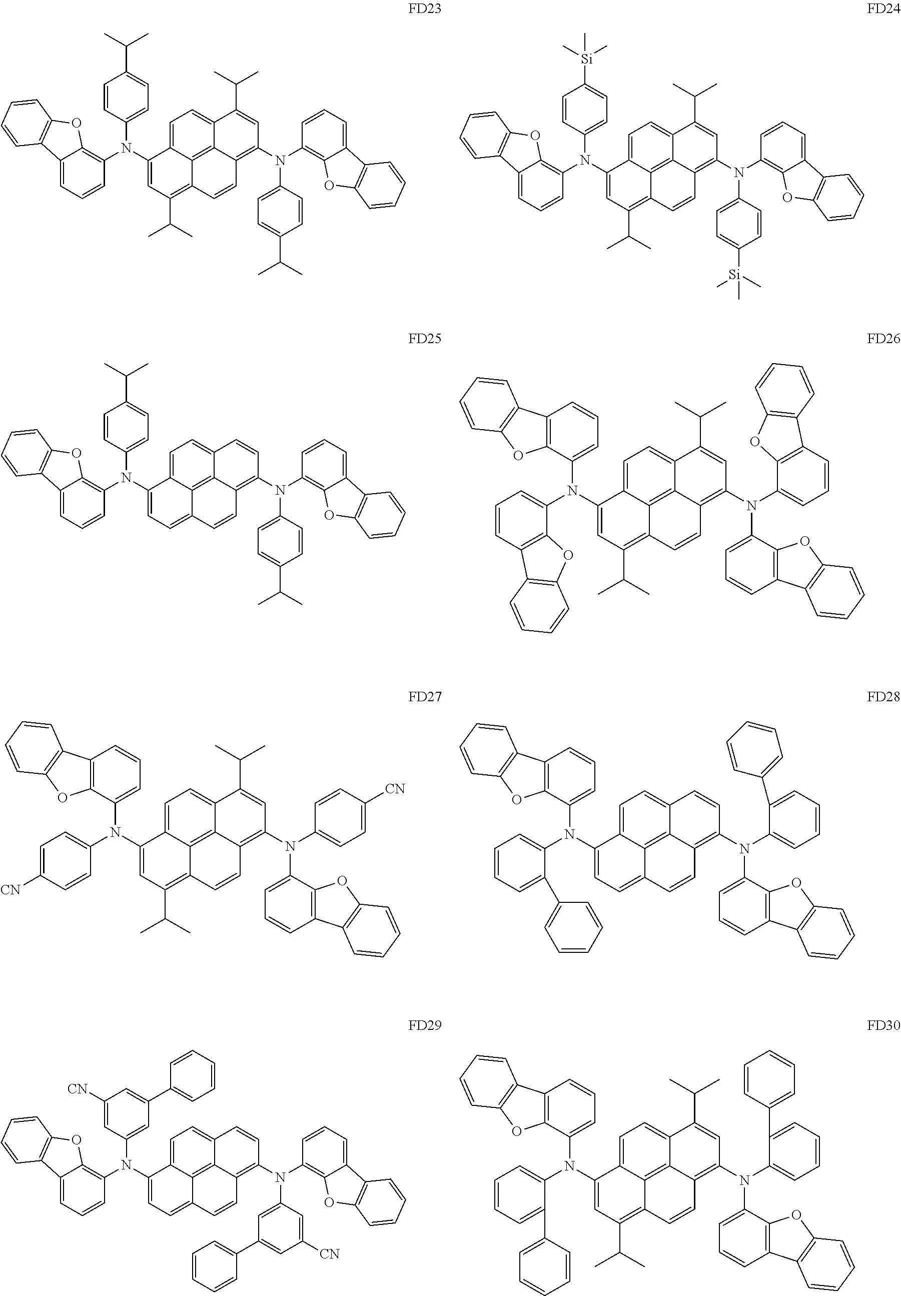

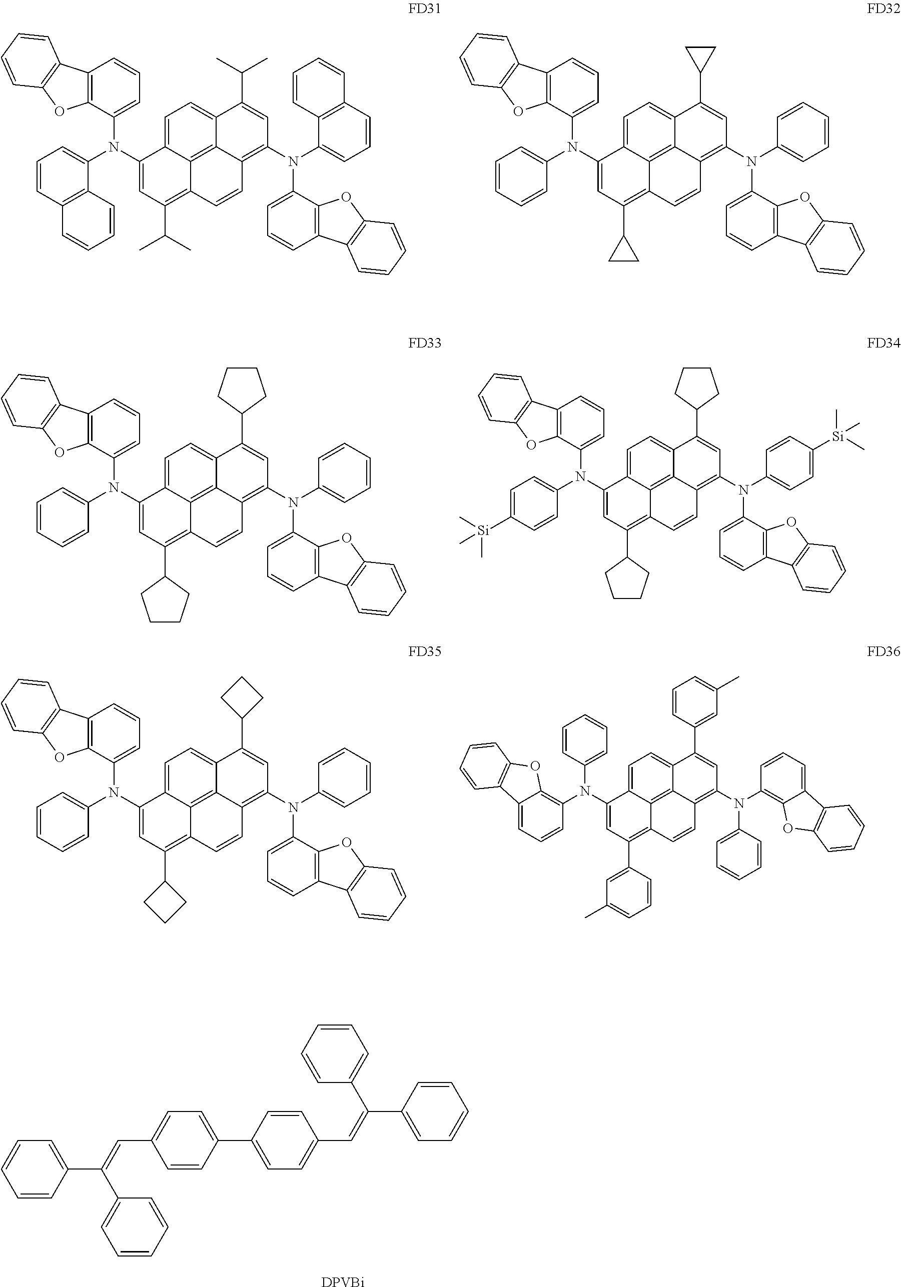

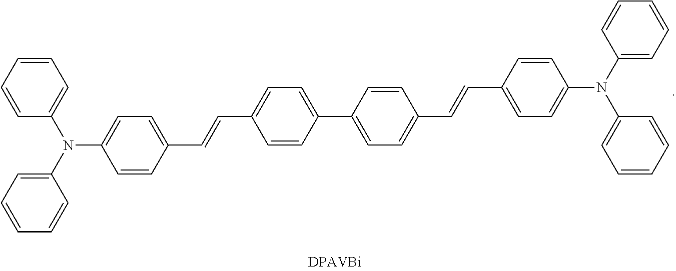 [SMILES: C(=C\c1ccc(N(c2ccccc2)c2ccccc2)cc1)/c1ccc(-c2ccc(/C=C/c3ccc(N(c4ccccc4)c4ccccc4)cc3)cc2)cc1]

In an embodiment, the fluorescent dopant and the auxiliary dopant may each independently include the fourth compound represented by Formula 502 or 503 as described in the present specification.

### Electron Transport Region in Interlayer 130

The electron transport region may have: i) a single-layered structure consisting of a single layer consisting of a single material, ii) a single-layered structure consisting of a single layer consisting of a plurality of different materials, or iii) a multi-layered structure including a plurality of layers including different materials.

The electron transport region may include a buffer layer, a hole blocking layer, an electron control layer, an electron transport layer, an electron injection layer, or any combination thereof.

For example, the electron transport region may have an electron transport layer/electron injection layer structure, a hole-blocking layer/electron transport layer/electron injection layer structure, an electron control layer/electron transport layer/electron injection layer structure, or a buffer layer/electron transport layer/electron injection layer structure, the constituting layers of each structure being sequentially stacked from an emission layer.

In an embodiment, the electron transport region (for example, the buffer layer, the hole-blocking layer, the electron control layer, or the electron transport layer in the electron transport region) may include a metal-free compound including at least one π electron-deficient nitrogen-containing C₁-C₆₀ cyclic group.

In an embodiment, the electron transport region may include a compound represented by Formula 601 below:

[Ar₆₀₁]ₓₑ₁₁—[(L₆₀₁)ₓₑ₁—R₆₀₁]ₓₑ₂₁ Formula 601

wherein, in Formula 601,

Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

xe11 may be 1, 2, or 3,

xe1 may be 0, 1, 2, 3, 4, or 5,

R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), or —S(═O)₂(Q₆₀₁), or —P(═O)(Q₆₀₁)(Q₆₀₂),

Q₆₀₁ to Q₆₀₃ are respectively the same as described in connection with Q₁,

xe21 may be 1, 2, 3, 4, or 5, and

at least one selected from Ar₆₀₁ , L₆₀₁, and R₆₀₁ may each independently be a π electron-deficient nitrogen-containing C₁-C₆₀ cyclic group unsubstituted or substituted with at least one R₁₀ₐ.

In an embodiment, when xe11 in Formula 601 is 2 or more, two or more of Ar₆₀₁ (s) may be linked via a single bond.

In an embodiment, Ar₆₀₁ in Formula 601 may be a substituted or unsubstituted anthracene group.

In an embodiment, the electron transport region may include a compound represented by Formula 601-1:

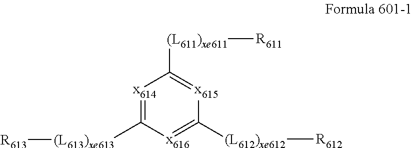

wherein, in Formula 601-1,

X₆₁₄ may be N or C(R₆₁₄), X₆₁₅ may be N or C(R₆₁₅), X₆₁₆ may be N or C(R₆₁₆), at least one selected from X₆₁₄ to X₆₁₆ may be N,

L₆₁₁ to L₆₁₃ are respectively the same as described in connection with L₆₀₁,

xe611 to xe613 are respectively the same as described in connection with xe1,

R₆₁₁ to R₆₁₃ are respectively the same as described in connection with R₆₀₁, and

R₆₁₄ to R₆₁₆ may each independently be hydrogen, deuterium, —F, —CI, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

In an embodiment, xe1 and xe611 to xe613 in Formulae 601 and 601-1 may each independently be 0, 1, or 2.

The electron transport region may include one selected from Compounds ET1 to ET46, 2,9-dimethyl-_{4,7}-diphenyl-1,10-phenanthroline (BCP), 4,7-diphenyl-1,10-phenanthroline (Bphen), Alq₃, BAIq, TAZ, NTAZ, or any combination thereof:

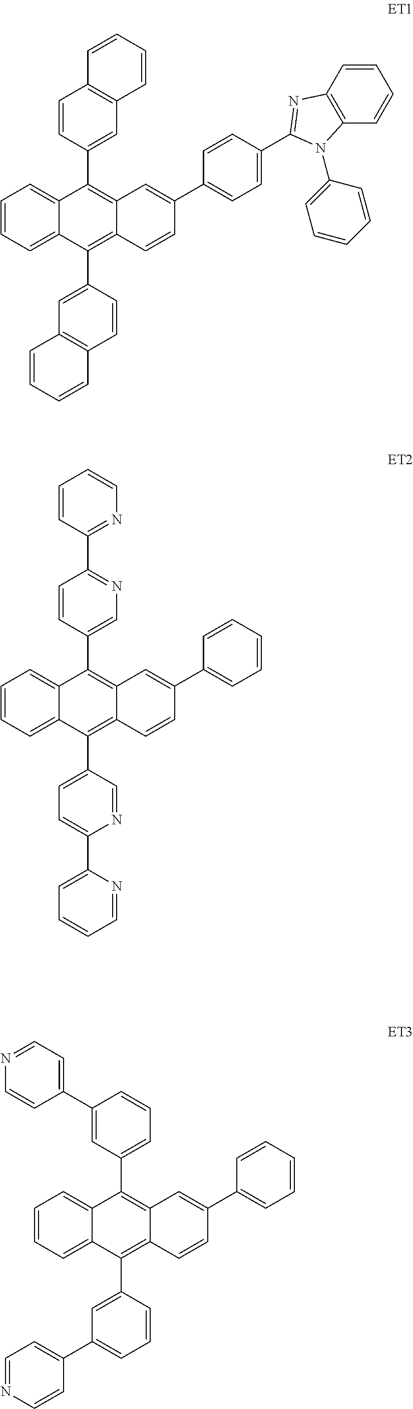 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

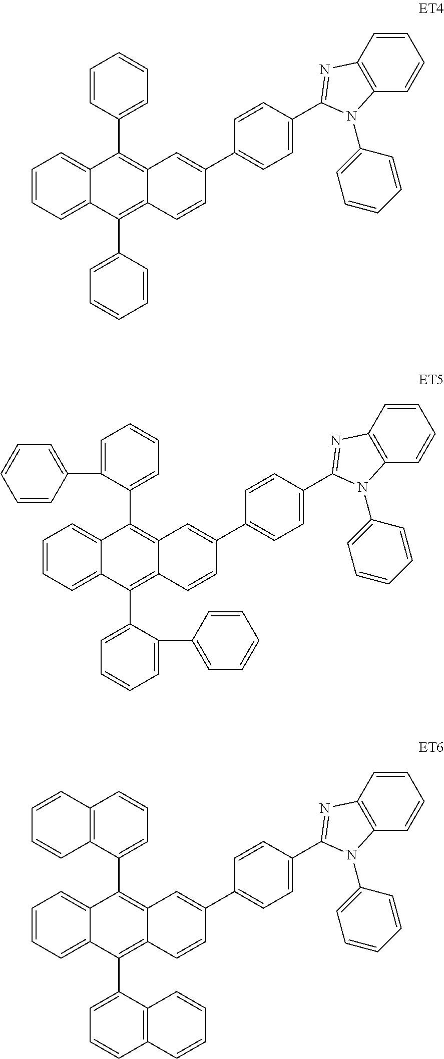 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

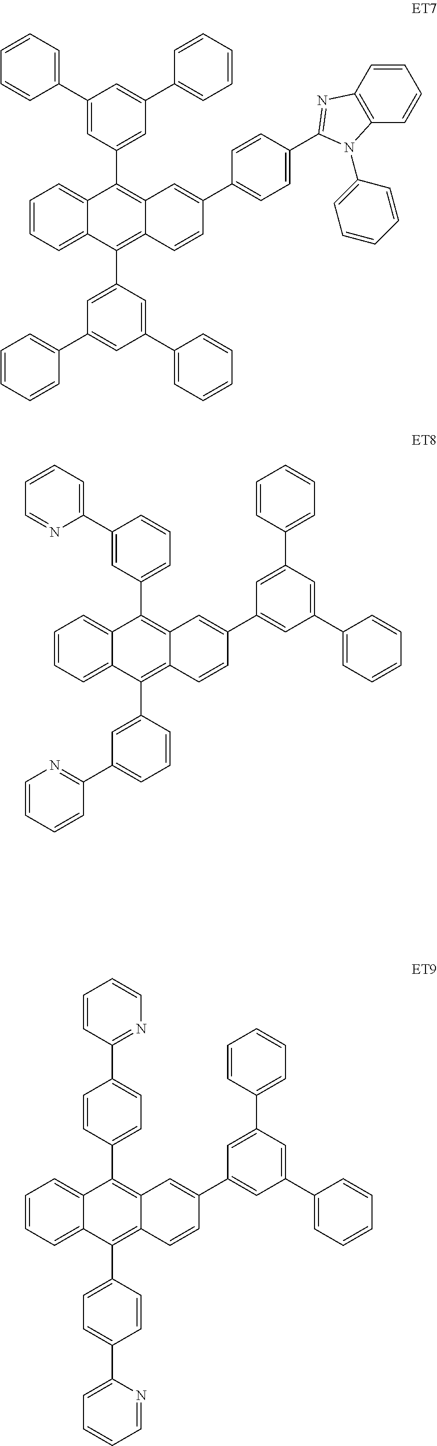 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

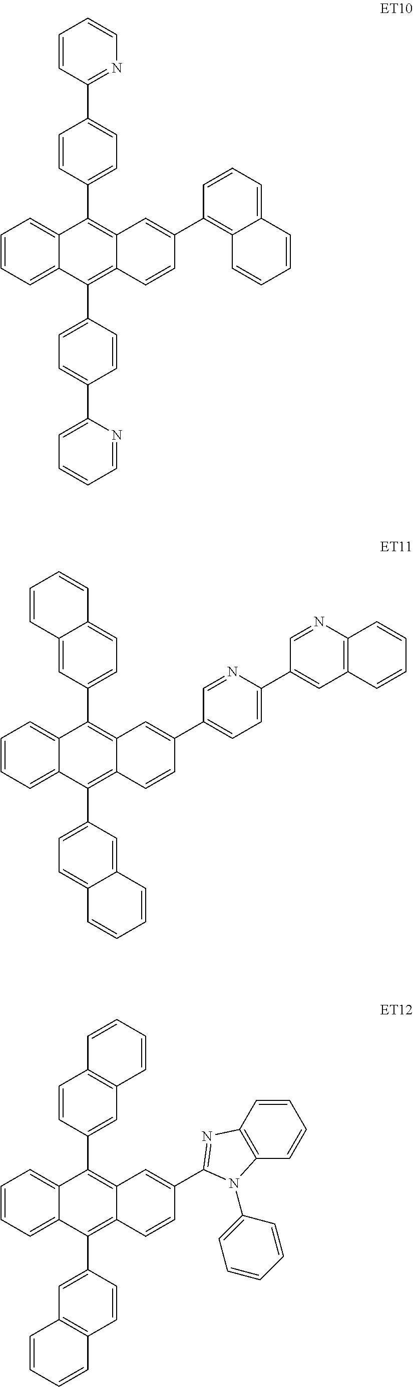 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

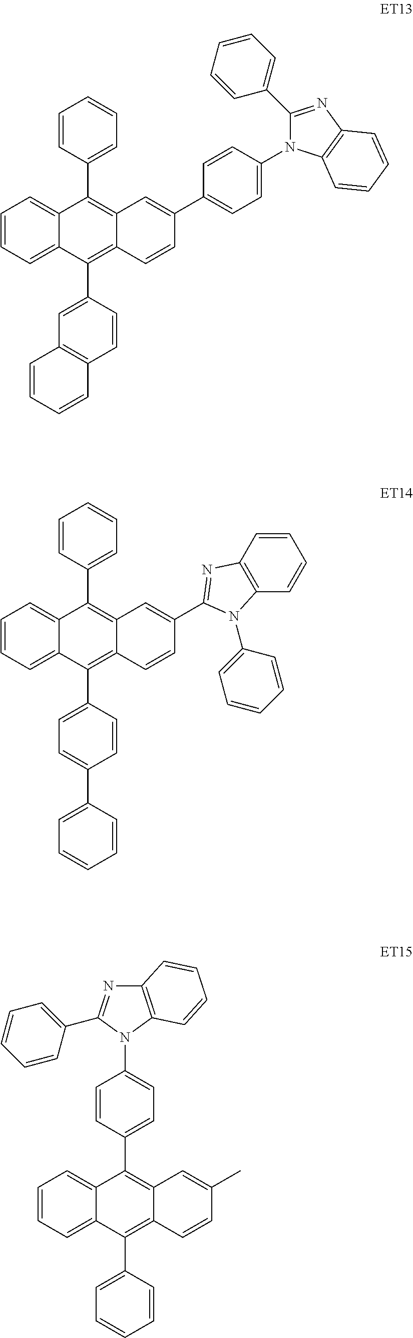 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

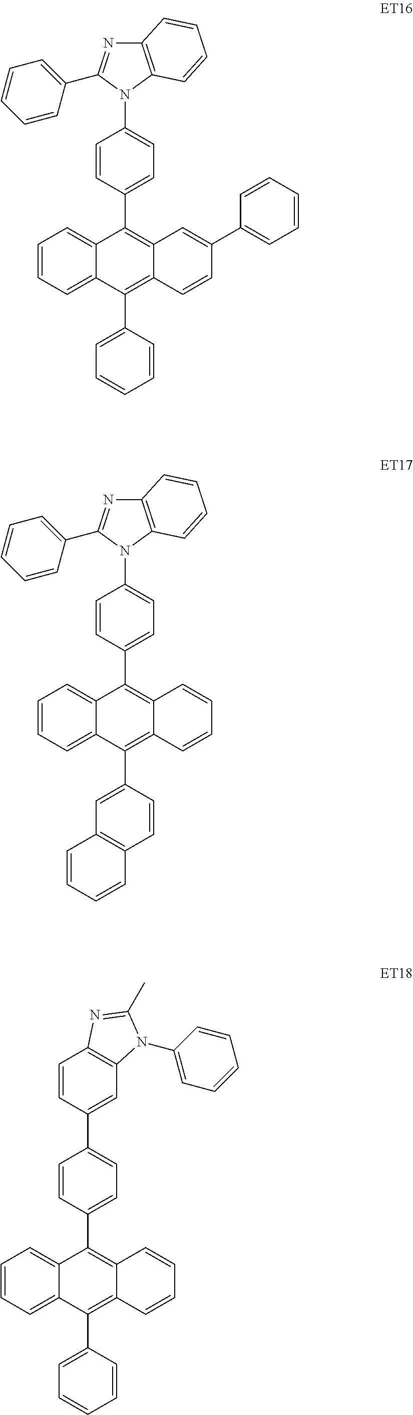 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

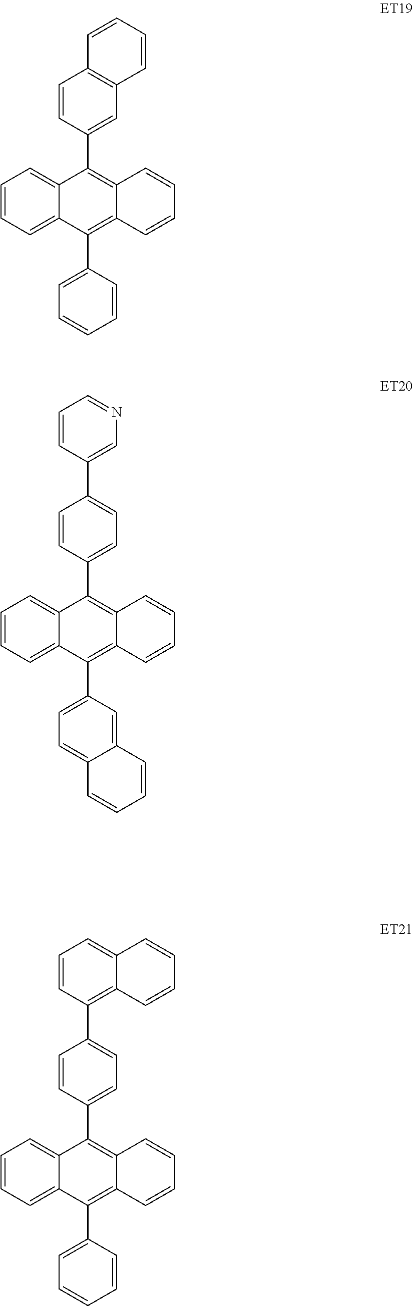

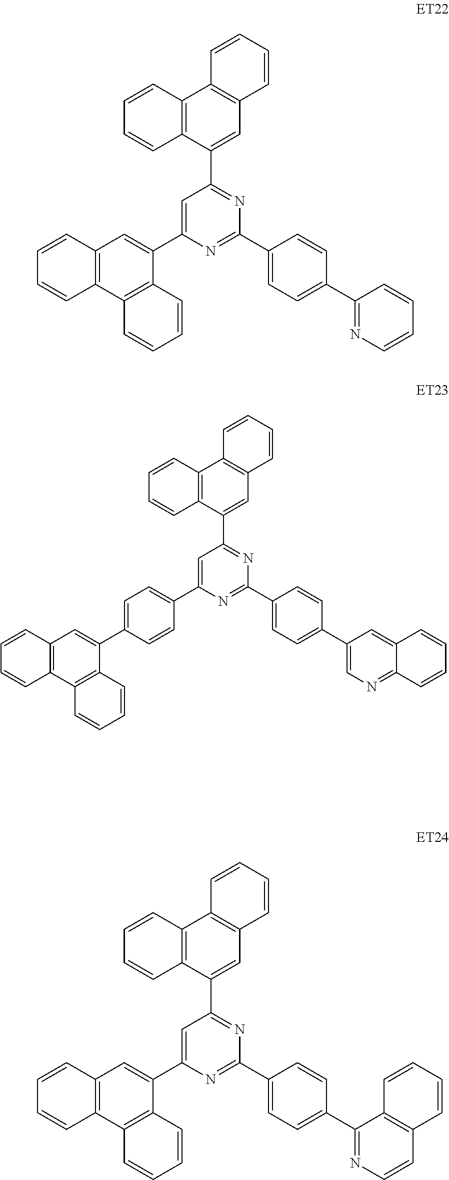 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

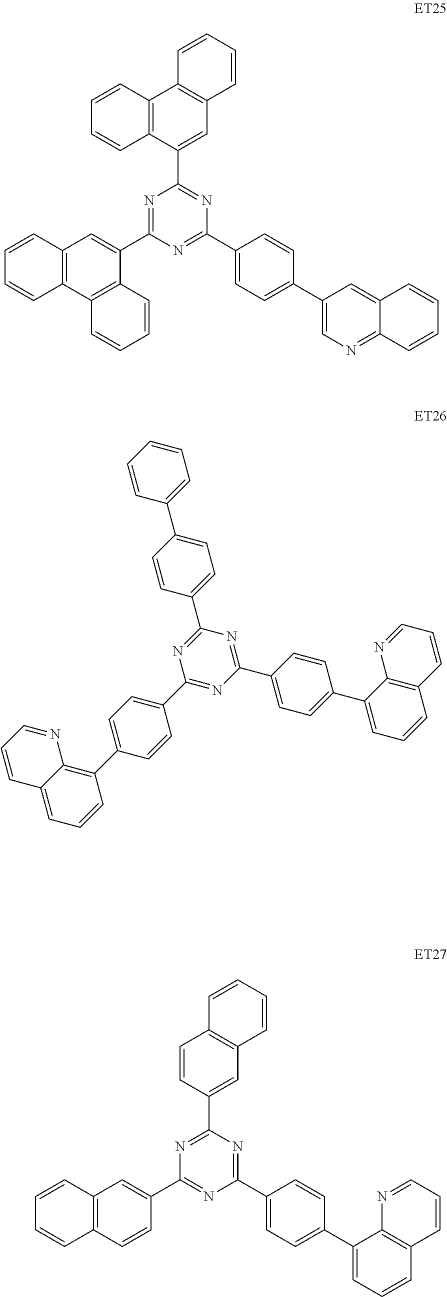 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

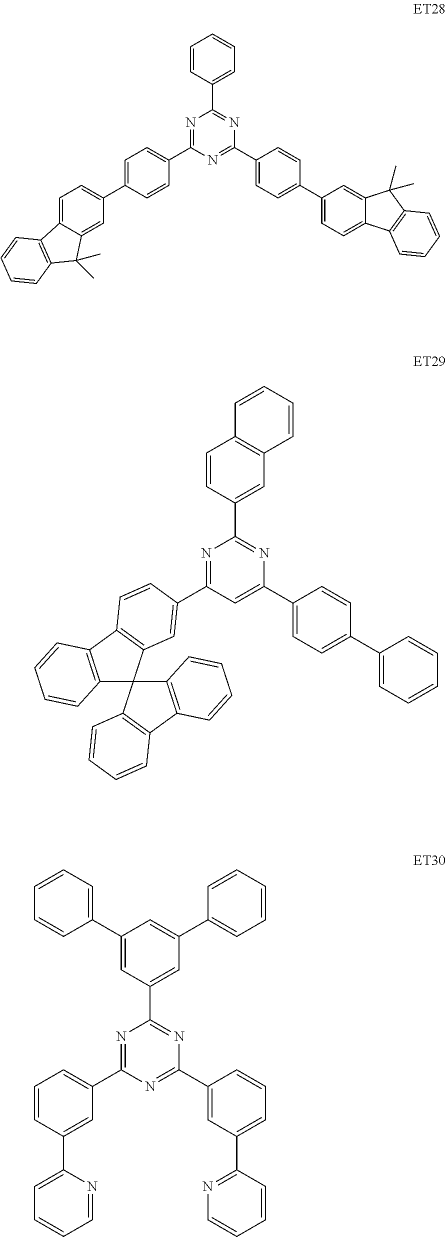 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

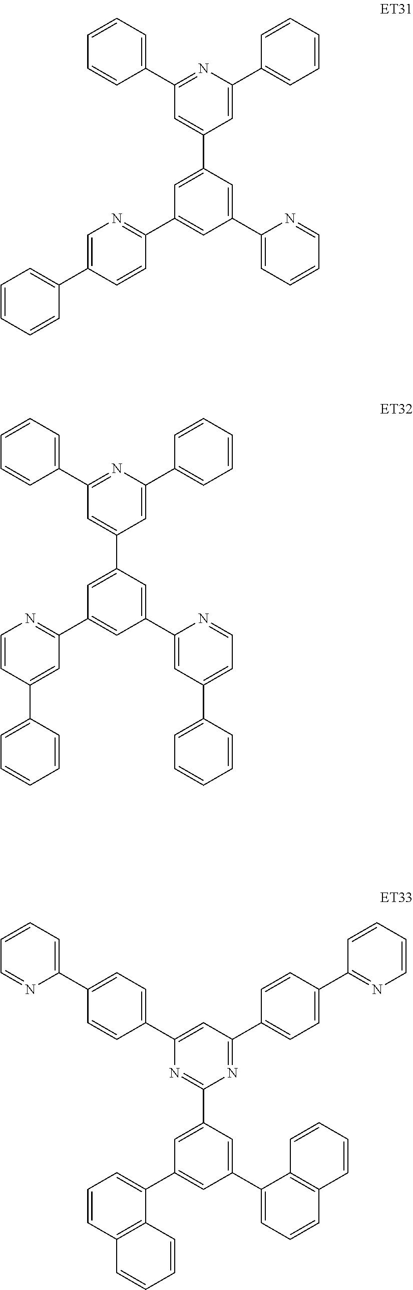 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

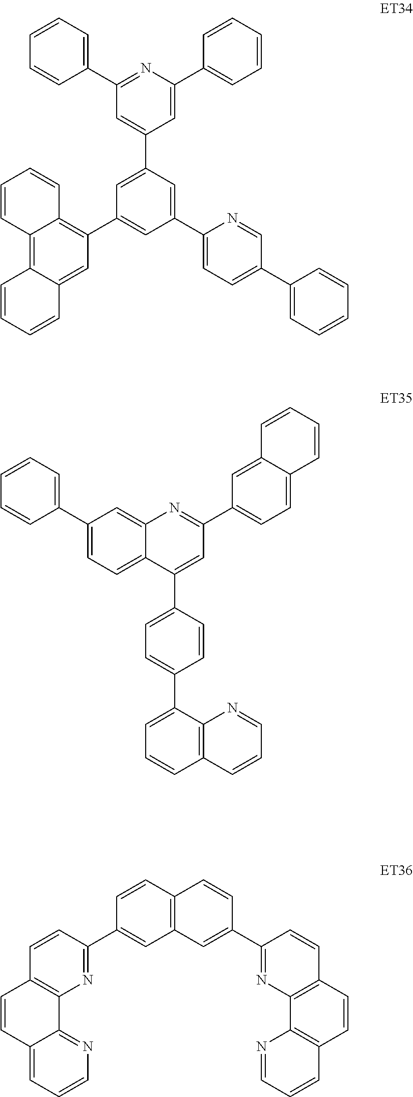 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

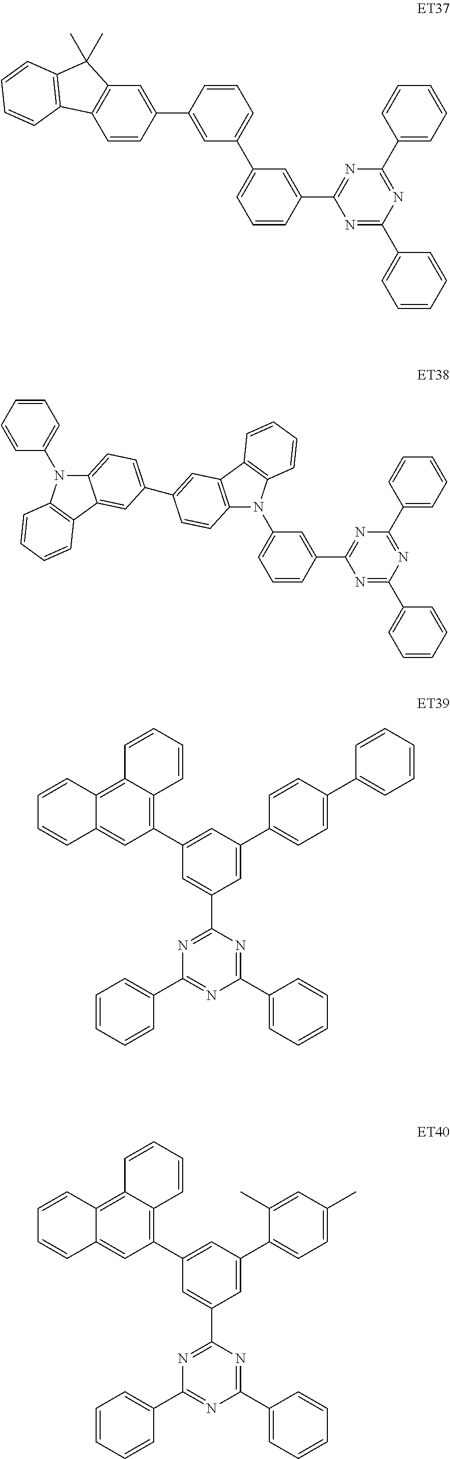 [SMILES: CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2ccc(-c3cc(-c4nc(-c5ccccc5)nc(-c5ccccc5)n4)cc(-c4cc5ccccc5c5ccccc45)c3)cc2)cc1 ; Cc1ccc(-c2cc(-c3nc(-c4ccccc4)nc(-c4ccccc4)n3)cc(-c3cc4ccccc4c4ccccc34)c2)c(C)c1]

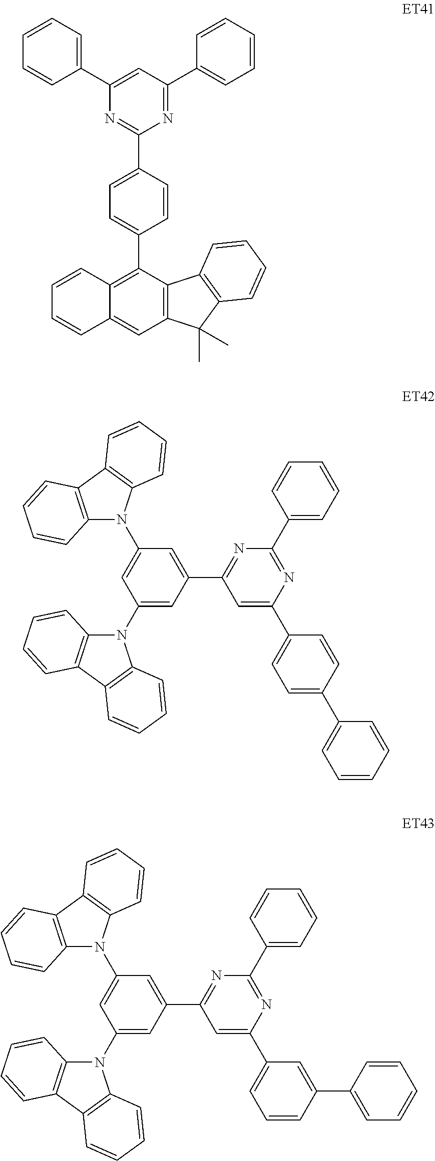 [SMILES: CC1(C)c2ccccc2-c2c1cc1ccccc1c2-c1ccc(-c2nc(-c3ccccc3)cc(-c3ccccc3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1]

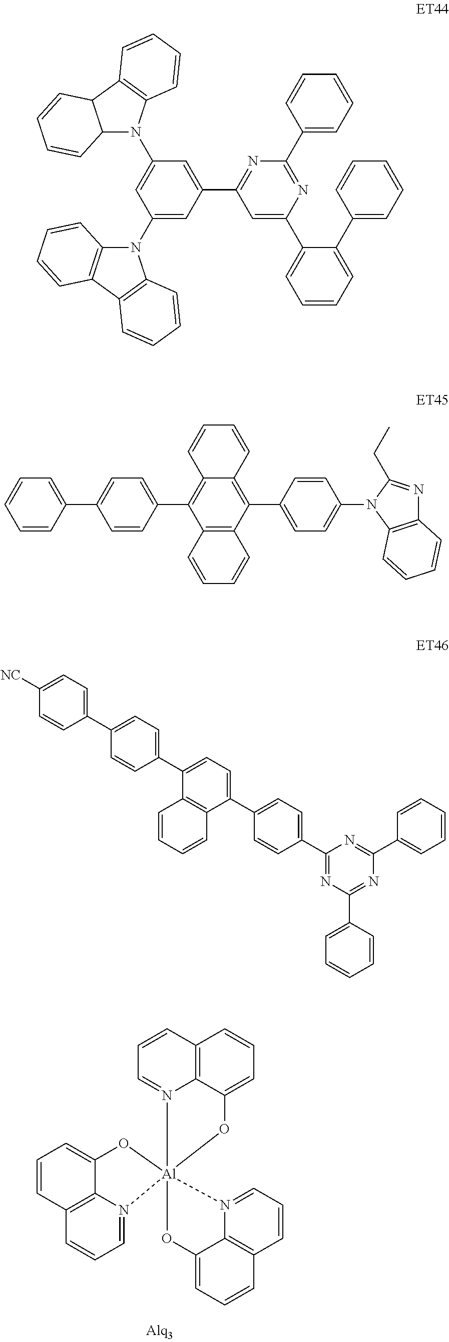

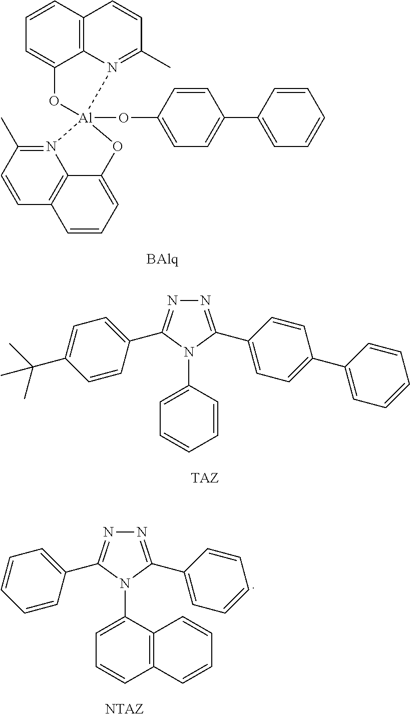

A thickness of the electron transport region may be from about 100 Å to about 5,000 Å, for example, about 160 Å to about 4,000 Å. When the electron transport region includes a buffer layer, a hole blocking layer, an electron control layer, an electron transport layer, or any combination thereof, the thickness of the buffer layer, the hole blocking layer, or the electron control layer may each independently be from about 20 Å to about 1000 Å, for example, about 30 Å to about 300 Å, and the thickness of the electron transport layer may be from about 100 Å to about 1,000 Å, for example, about 150 Å to about 500 Å. When the thickness of the buffer layer, the hole-blocking layer, the electron control layer, the electron transport layer, and/or the electron transport region are within these ranges, suitable or satisfactory electron transporting characteristics may be obtained without a substantial increase in driving voltage.

The electron transport region (for example, the electron transport layer in the electron transport region) may further include, in addition to the materials described above, a metal-containing material.

The metal-containing material may include an alkali metal complex, an alkaline earth metal complex, or any combination thereof. A metal ion of the alkali metal complex may be a Li ion, a Na ion, a K ion, a Rb ion, or a Cs ion, and a metal ion of the alkaline earth metal complex may be a Be ion, a Mg ion, a Ca ion, a Sr ion, or a Ba ion. A ligand coordinated with the metal ion of the alkali metal complex or the alkaline earth-metal complex may include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

In an embodiment, the metal-containing material may include a Li complex. The Li complex may include, for example, Compound ET-D1 (Liq) or ET-D2:

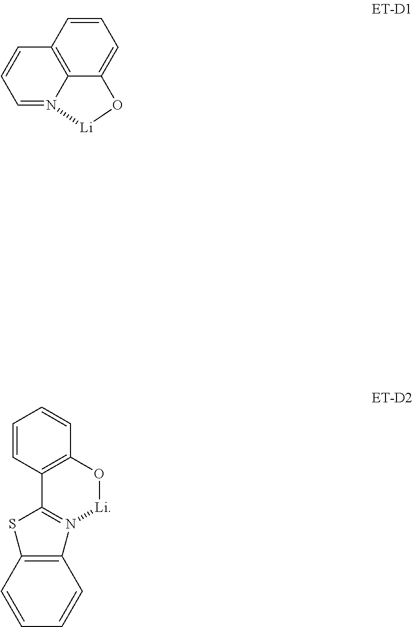

The electron transport region may include an electron injection layer that facilitates the injection of electrons from the second electrode 150. The electron injection layer may be in direct contact (e.g., physical contact) with the second electrode 150.

The electron injection layer may have: i) a single-layered structure consisting of a single layer consisting of a single material, ii) a single-layered structure consisting of a single layer consisting of a plurality of different materials, or iii) a multi-layered structure including a plurality of layers including different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof.

The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may include oxides, halides (for example, fluorides, chlorides, bromides, or iodides), or tellurides of the alkali metal, the alkaline earth metal, and the rare earth metal, or any combination thereof.

The alkali metal-containing compound may include alkali metal oxides, such as Li₂O, Cs₂O, or K₂O, alkali metal halides, such as LiF, NaF, CsF, KF, LiI, Nal, CsI, or KI, or any combination thereof. The alkaline earth metal-containing compound may include an alkaline earth metal oxide, such as BaO, SrO, CaO, BaₓSr₁₋ₓO (x is a real number satisfying the condition of 0<x<1), BaₓCa₁₋ₓO (x is a real number satisfying the condition of 0<x<1), and/or the like. The rare earth metal-containing compound may include YbF₃, ScF₃, Sc₂O₃, Y₂O₃, Ce₂O₃, GdF₃, TbF₃, YbI₃, ScI₃, Tbl₃, or any combination thereof. In an embodiment, the rare earth metal-containing compound may include lanthanide metal telluride. Examples of the lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, and Lu₂Te₃.

The alkali metal complex, the alkaline earth metal complex, and the rare earth metal complex may include i) one selected from metal ions of the alkali metal, the alkaline earth metal, and the rare earth metal and ii), as a ligand bonded to the metal ion, for example, a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenyl benzimidazole, a hydroxyphenylbenzothiazole, a bipyridine, a phenanthroline, a cyclopentadiene, or any combination thereof.

The electron injection layer may include (e.g., consist of) an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In an embodiment, the electron injection layer may further include an organic material (for example, a compound represented by Formula 601).

In an embodiment, the electron injection layer may consist of i) an alkali metal-containing compound (for example, an alkali metal halide), ii) a) an alkali metal-containing compound (for example, an alkali metal halide); and b) an alkali metal, an alkaline earth metal, a rare earth metal, or any combination thereof. For example, the electron injection layer may be a KI:Yb co-deposited layer, a Rbl:Yb co-deposited layer, a LiF:Yb co-deposited, and/or the like.

When the electron injection layer further includes an organic material, alkali metal, alkaline earth metal, rare earth metal, an alkali metal-containing compound, an alkaline earth metal-containing compound, a rare earth metal-containing compound, alkali metal complex, alkaline earth-metal complex, rare earth metal complex, or any combination thereof may be homogeneously or non-homogeneously dispersed in a matrix including the organic material.

A thickness of the electron injection layer may be in a range of about 1 Å to about 100 Å, for example, about 3 Å to about 90 Å. When the thickness of the electron injection layer is within the range described above, suitable or satisfactory electron injection characteristics may be obtained without a substantial increase in driving voltage.

### Second Electrode 150

The second electrode 150 may be on the interlayer 130 having such a structure. The second electrode 150 may be a cathode, which is an electron injection electrode, and as the material for the second electrode 150, a metal, an alloy, an electrically conductive compound, or any combination thereof, each having a low work function, may be used.

In an embodiment, the second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or a combination thereof. The second electrode 150 may be a transmissive electrode, a semi-transmissive electrode, or a reflective electrode.

The second electrode 150 may have a single-layered structure or a multi-layered structure including two or more layers.

### Capping Layer

A first capping layer may be outside the first electrode 110, and/or a second capping layer may be outside the second electrode 150. In more detail, the light-emitting device 10 may have a structure in which the first capping layer, the first electrode 110, the interlayer 130, and the second electrode 150 are sequentially stacked in this stated order, a structure in which the first electrode 110, the interlayer 130, the second electrode 150, and the second capping layer are sequentially stacked in this stated order, or a structure in which the first capping layer, the first electrode 110, the interlayer 130, the second electrode 150, and the second capping layer are sequentially stacked in this stated order.

Light generated in an emission layer of the interlayer 130 of the light-emitting device 10 may be extracted toward the outside through the first electrode 110, which is a semi-transmissive electrode or a transmissive electrode, and the first capping layer or light generated in an emission layer of the interlayer 130 of the light-emitting device 10 may be extracted toward the outside through the second electrode 150, which is a semi-transmissive electrode or a transmissive electrode, and the second capping layer.

The first capping layer and the second capping layer may increase external emission efficiency according to the principle of constructive interference. Accordingly, the light extraction efficiency of the light-emitting device 10 is increased, so that the emission efficiency of the light-emitting device 10 may be improved.

Each of the first capping layer and second capping layer may include a material having a refractive index (at a wavelength of 589 nm) of 1.6 or more.

The first capping layer and the second capping layer may each independently be an organic capping layer including an organic material, an inorganic capping layer including an inorganic material, or an organic-inorganic composite capping layer including an organic material and an inorganic material.

At least one selected from the first capping layer and the second capping layer may each independently include carbocyclic compounds, heterocyclic compounds, amine group-containing compounds, porphyrin derivatives, phthalocyanine derivatives, naphthalocyanine derivatives, alkali metal complexes, alkaline earth metal complexes, or any combination thereof. The carbocyclic compound, the heterocyclic compound, and the amine group-containing compound may be optionally substituted with a substituent containing O, N, S, Se, Si, F, CI, Br, I, or any combination thereof. In an embodiment, at least one selected from the first capping layer and the second capping layer may each independently include an amine group-containing compound.

In an embodiment, at least one selected from the first capping layer and the second capping layer may each independently include a compound represented by Formula 201, a compound represented by Formula 202, or any combination thereof.

In an embodiment, at least one selected from the first capping layer and the second capping layer may each independently include one selected from Compounds HT28 to HT33, one selected from Compounds CP1 to CP6, β-NPB, or any combination thereof:

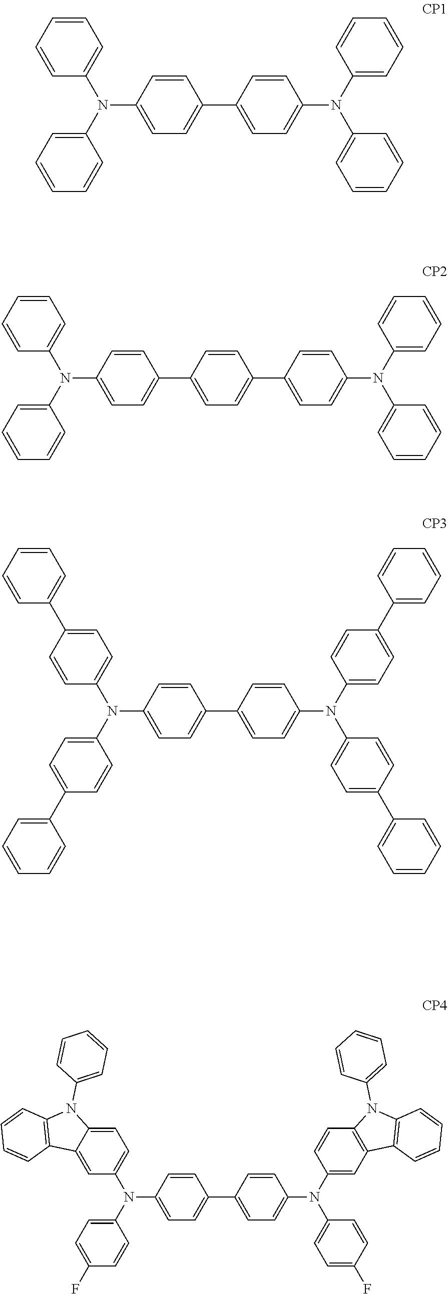 [SMILES: c1ccc(N(c2ccccc2)c2ccc(-c3ccc(N(c4ccccc4)c4ccccc4)cc3)cc2)cc1 ; c1ccc(N(c2ccccc2)c2ccc(-c3ccc(-c4ccc(N(c5ccccc5)c5ccccc5)cc4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; Fc1ccc(N(c2ccc(-c3ccc(N(c4ccc(F)cc4)c4ccc5c(c4)c4ccccc4n5-c4ccccc4)cc3)cc2)c2ccc3c(c2)c2ccccc2n3-c2ccccc2)cc1]

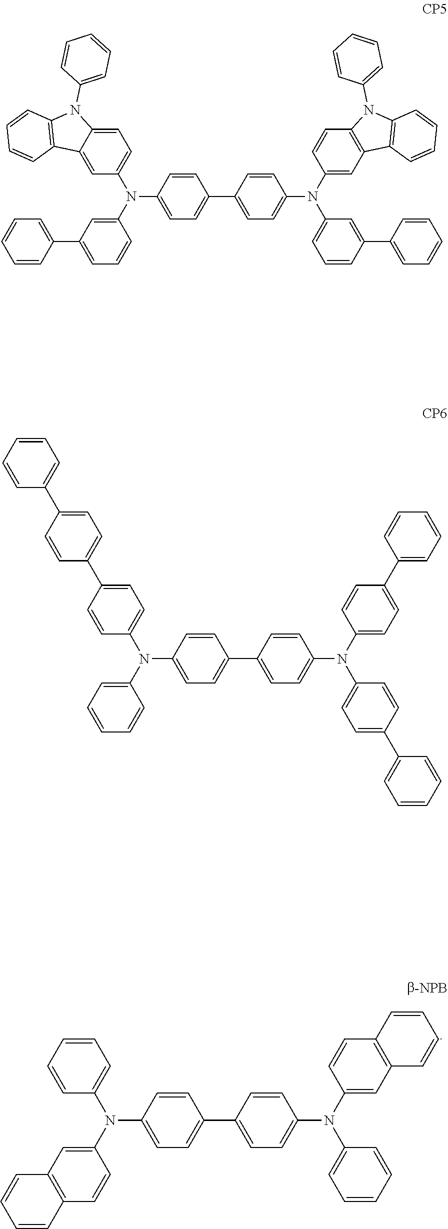 [SMILES: c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1]

### Electronic Apparatus

The light-emitting device may be included in various suitable electronic apparatuses. In an embodiment, the electronic apparatus including the light-emitting device may be a light-emitting apparatus, an authentication apparatus, and/or the like.

The electronic apparatus (for example, light-emitting apparatus) may further include, in addition to the light-emitting device, i) a color filter, ii) a color conversion layer, or iii) a color filter and a color conversion layer. The color filter and/or the color conversion layer may be in at least one traveling direction of light emitted from the light-emitting device. For example, the light emitted from the light-emitting device may be blue light or white light. The light-emitting device may be the same as described above. In an embodiment, the color conversion layer may include quantum dots.

The electronic apparatus may include a first substrate. The first substrate may include a plurality of subpixel areas, the color filter may include a plurality of color filter areas respectively corresponding to the plurality of subpixel areas, and the color conversion layer may include a plurality of color conversion areas respectively corresponding to the plurality of subpixel areas.

A pixel-defining layer may be located among the plurality of subpixel areas to define each of the plurality of subpixel areas.

The color filter may further include a plurality of color filter areas and light-shielding patterns located among the plurality of color filter areas, and the color conversion layer may include a plurality of color conversion areas and light-shielding patterns located among the plurality of color conversion areas.

The color filter areas (or the color conversion areas) may include a first area that emits a first color light, a second area that emits a second color light, and/or a third area that emits a third color light, and the first color light, the second color light, and/or the third color light may have different maximum emission wavelengths from one another. In an embodiment, the first color light may be red light, the second color light may be green light, and the third color light may be blue light. In an embodiment, the color filter areas (or the color conversion areas) may include quantum dots. In more detail, the first area may include a red quantum dot, the second area may include a green quantum dot, and the third area may not include a quantum dot. The quantum dot is the same as described in the present specification. The first area, the second area, and/or the third area may each further include a scatterer (e.g., a light scatterer).

In an embodiment, the light-emitting device may emit first light, the first area may absorb the first light to emit a first first-color light, the second area may absorb the first light to emit a second first-color light, and the third area may absorb the first light to emit a third first-color light. In this regard, the first first-color light, the second first-color light, and the third first-color light may have different maximum emission wavelengths. In more detail, the first light may be blue light, the first first-color light may be red light, the second first-color light may be green light, and the third first-color light may be blue light.

The electronic apparatus may further include a thin-film transistor in addition to the light-emitting device as described above. The thin-film transistor may include a source electrode, a drain electrode, and an activ layer, wherein any one selected from the source electrode and the drain electrode may be electrically connected to any one selected from the first electrode and the second electrode of the light-emitting device.

The thin-film transistor may further include a gate electrode, a gate insulating film, etc.

The activ layer may include crystalline silicon, amorphous silicon, organic semiconductor, oxide semiconductor, or the like.

The electronic apparatus may further include a sealing portion for sealing the light-emitting device. The sealing portion may be between the color filter and/or the color conversion layer and the light-emitting device. The sealing portion allows light from the light-emitting device to be extracted to the outside, while concurrently (e.g., simultaneously) preventing or reducing penetration of ambient air and/or moisture into the light-emitting device. The sealing portion may be a sealing substrate including a transparent glass substrate and/or a plastic substrate. The sealing portion may be a thin-film encapsulation layer including at least one layer of an organic layer and/or an inorganic layer. When the sealing portion is a thin film encapsulation layer, the electronic apparatus may be flexible.

Various suitable functional layers may be additionally on the sealing portion, in addition to the color filter and/or the color conversion layer, according to the use of the electronic apparatus. The functional layers may include a touch screen layer, a polarizing layer, and/or the like. The touch screen layer may be a pressure-sensitive touch screen layer, a capacitive touch screen layer, and/or an infrared touch screen layer. The authentication apparatus may be, for example, a biometric authentication apparatus that authenticates an individual by using biometric information of a living body (for example, fingertips, pupils, etc.).

The authentication apparatus may further include, in addition to the light-emitting device, a biometric information collector.

The electronic apparatus may be applied to various suitable displays, light sources, lighting, personal computers (for example, a mobile personal computer), mobile phones, digital cameras, electronic diaries, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, and/or endoscope displays), fish finders, various measuring instruments, meters (for example, meters for a vehicle, an aircraft, and/or a vessel), projectors, and/or the like.

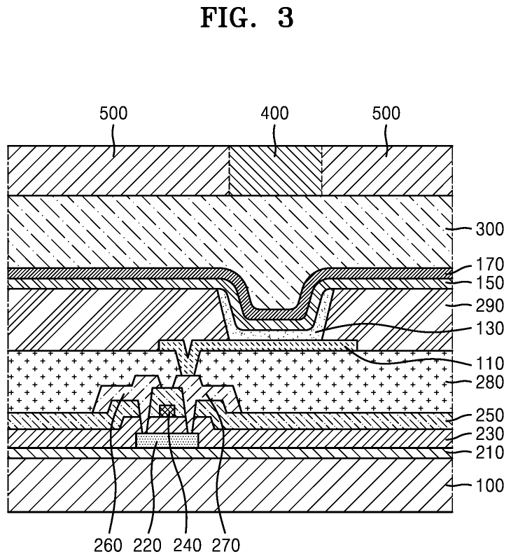

### Description of FIGS. 2 and 3

FIG. 2 is a schematic cross-sectional view of a structure of an electronic apparatus according to an embodiment of the disclosure.

The electronic apparatus of FIG. 2 includes a substrate 100, a thin-film transistor (TFT), a light-emitting device, and an encapsulation portion 300 that seals the light-emitting device.

The substrate 100 may be a flexible substrate, a glass substrate, and/or a metal substrate. A buffer layer 210 may be on the substrate 100. The buffer layer 210 may prevent or reduce penetration of impurities through the substrate 100 and may provide a flat surface on the substrate 100.

A TFT may be on the buffer layer 210. The TFT may include an activ layer 220, a gate electrode 240, a source electrode 260, and a drain electrode 270.

The active layer 220 may include an inorganic semiconductor such as silicon or polysilicon, an organic semiconductor, or an oxide semiconductor, and may include a source region, a drain region and a channel region.

A gate insulating film 230 for insulating the active layer 220 from the gate electrode 240 may be on the active layer 220, and the gate electrode 240 may be on the gate insulating film 230.

An interlayer insulating film 250 is on the gate electrode 240. The interlayer insulating film 250 may be placed between the gate electrode 240 and the source electrode 260 to insulate the gate electrode 240 from the source electrode 260 and between the gate electrode 240 and the drain electrode 270 to insulate the gate electrode 240 from the drain electrode 270.

The source electrode 260 and the drain electrode 270 may be on the interlayer insulating film 250. The interlayer insulating film 250 and the gate insulating film 230 may expose the source region and the drain region of the active layer 220, and the source electrode 260 and the drain electrode 270 may be in contact (e.g., physical contact) with the exposed portions of the source region and the drain region of the active layer 220.

The TFT is electrically connected to a light-emitting device to drive the light-emitting device, and is covered by a passivation layer 280. The passivation layer 280 may include an inorganic insulating film, an organic insulating film, or a combination thereof. A light-emitting device is provided on the passivation layer 280. The light-emitting device may include a first electrode 110, an interlayer 130, and a second electrode 150.

The first electrode 110 may be on the passivation layer 280. The passivation layer 280 does not completely cover the drain electrode 270 and exposes a portion of the drain electrode 270, and the first electrode 110 is connected to the exposed portion of the drain electrode 270.

A pixel-defining layer 290 containing an insulating material may be on the first electrode 110. The pixel-defining layer 290 exposes a region of the first electrode 110, and an interlayer 130 may be in the exposed region of the first electrode 110. The pixel-defining layer 290 may be a polyimide and/or polyacrylic organic film. In some embodiments, at least some layers of the interlayer 130 may extend beyond the upper portion of the pixel-defining layer 290 in the form of a common layer.

The second electrode 150 may be on the interlayer 130, and a capping layer 170 may be additionally on the second electrode 150. The capping layer 170 may cover the second electrode 150.

The encapsulation portion 300 may be on the capping layer 170. The encapsulation portion 300 may be on a light-emitting device to protect the light-emitting device from moisture and/or oxygen. The encapsulation portion 300 may include: an inorganic film including silicon nitride (SiNx), silicon oxide (SiOx), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic-based resin (for example, polymethyl methacrylate, polyacrylic acid, and/or the like), an epoxy-based resin (for example, aliphatic glycidyl ether (AGE), and/or the like), or a combination thereof; or a combination of the inorganic film and the organic film.

FIG. 3 is a schematic cross-sectional view of a structure of an electronic apparatus according to an embodiment of the disclosure.

The electronic apparatus of FIG. 3 is substantially the same as the electronic apparatus of FIG. 2, except that a light-shielding pattern 500 and a functional region 400 are additionally on the encapsulation portion 300. The functional region 400 may be i) a color filter area, ii) a color conversion area, or iii) a combination of the color filter area and the color conversion area. In an embodiment, the light-emitting device included in the electronic apparatus of FIG. 3 may be a tandem light-emitting device.

### Manufacture Method

Respective layers included in the hole transport region, the emission layer, and respective layers included in the electron transport region may be formed in a certain region by using one or more suitable methods selected from vacuum deposition, spin coating, casting, Langmuir-Blodgett (LB) deposition, ink-jet printing, laser-printing, and laser-induced thermal imaging.

When layers constituting the hole transport region, an emission layer, and layers constituting the electron transport region are formed by vacuum deposition, the deposition may be performed at a deposition temperature of about 100° C. to about 500° C., a vacuum degree of about 10⁻⁸ torr to about 10⁻³ torr, and a deposition speed of about 0.01 Å/sec to about 100 Å/sec, depending on a material to be included in a layer to be formed and the structure of a layer to be formed.

### Definition of Terms

The term “C₃-C₆₀ carbocyclic group,” as used herein, refers to a cyclic group consisting of carbon only as a ring-forming atom and having three to sixty carbon atoms, and the term “C₁-C₆₀ heterocyclic group,” as used herein, refers to a cyclic group that has one to sixty carbon atoms and further has, in addition to carbon, a heteroatom as a ring-forming atom. The C₃-C₆₀ carbocyclic group and the C₁-C₆₀ heterocyclic group may each be a monocyclic group consisting of one ring or a polycyclic group in which two or more rings are condensed together with each other. In an embodiment, the C₁-C₆₀ heterocyclic group has 3 to 61 ring-forming atoms.

The term “cyclic group,” as used herein, may include the C₃-C₆₀ carbocyclic group and the C₁-C₆₀ heterocyclic group.

The term “π electron-rich C₃-C₆₀ cyclic group,” as used herein, refers to a cyclic group that has three to sixty carbon atoms and does not include *—N═*′ as a ring-forming moiety, and the term “π electron-deficient nitrogen-containing C₁-C₆₀ cyclic group” as used herein refers to a heterocyclic group that has one to sixty carbon atoms and includes *—N═*′ as a ring-forming moiety.

In an embodiment,

the C₃-C₆₀ carbocyclic group may be i) group T1 or ii) a condensed cyclic group in which two or more groups T1 are condensed together with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),

the C₁-C₆₀ heterocyclic group may be i) group T2, ii) a condensed cyclic group in which two or more groups T2 are condensed together with each other, or iii) a condensed cyclic group in which at least one group T2 and at least one group T1 are condensed together with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),

the π electron-rich C₃-C₆₀ cyclic group may be i) group T1, ii) a condensed cyclic group in which two or more groups T1 are condensed together with each other, iii) group T3, iv) a condensed cyclic group in which two or more groups T3 are condensed together with each other, or v) a condensed cyclic group in which at least one group T3 and at least one group T1 are condensed together with each other (for example, the C₃-C₆₀ carbocyclic group, a 1 H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, etc.),

the π electron-deficient nitrogen-containing C₁-C₆₀ cyclic group may be i) group T4, ii) a condensed cyclic group in which two or more group T4 are condensed together with each other, iii) a condensed cyclic group in which at least one group T₄ and at least one group T1 are condensed together with each other, iv) a condensed cyclic group in which at least one group T4 and at least one group T3 are condensed together with each other, or v) a condensed cyclic group in which at least one group T4, at least one group T1, and at least one group T3 are condensed together with one another (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),

group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or a bicyclo[2.2.1]heptane) group, a norbornene group, a bicyclo[1.1.1]pentane group, a bicyclo[2.1.1]hexane group, a bicyclo[2.2.2]octane group, or a benzene group,

group T2 may be a furan group, a thiophene group, a 1 H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,

group T3 may be a furan group, a thiophene group, a 1 H-pyrrole group, a silole group, or a borole group, and

group T4 may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The term “cyclic group”, “C₃-C₆₀ carbocyclic group”, “C₁-C₆₀ heterocyclic group”, “Tr electron-rich C₃-C₆₀ cyclic group”, or “T₁ electron-deficient nitrogen-containing C₁-C₆₀ cyclic group,” as used herein, refers to a monovalent or polyvalent group (for example, a divalent group, a trivalent group, a tetravalent group, or the like) that is condensed with (e.g., combined together with) a cyclic group, depending on the structure of a formula in connection with which the terms are used. In an embodiment, “a benzene group” may be a benzo group, a phenyl group, a phenylene group, or the like, which may be easily understood by one of ordinary skill in the art according to the structure of a formula including the “benzene group.”

Examples of the monovalent C₃-C₆₀ carbocyclic group and the monovalent C₁-C₆₀ heterocyclic group may include a C₃-C₁₀ cycloalkyl group, a C₁-C₆₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group, and examples of the divalent C₃-C₆₀ carbocyclic group and the monovalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a substituted or unsubstituted divalent non-aromatic condensed heteropolycyclic group.

The term “C₁-C₆₀ alkyl group,” as used herein, refers to a linear or branched aliphatic hydrocarbon monovalent group that has one to sixty carbon atoms, for example, a C₁-C₂₀ alkyl group, and examples thereof include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group. The term “C₁-C₆₀ alkylene group,” as used herein, refers to a divalent group having substantially the same structure as the C₁-C₆₀ alkyl group.

The term “C₂-C₆₀ alkenyl group,” as used herein refers to a monovalent hydrocarbon group having at least one carbon-carbon double bond at a main chain (e.g., in the middle) or at a terminal end (e.g., the terminus) of the C₂-C₆₀ alkyl group, and examples thereof include an ethenyl group, a propenyl group, and a butenyl group. The term “C₂-C₆₀ alkenylene group,” as used herein, refers to a divalent group having substantially the same structure as the C₂-C₆₀ alkenyl group.

The term “C₂-C₆₀ alkynyl group,” as used herein, refers to a monovalent hydrocarbon group having at least one carbon-carbon triple bond at a main chain (e.g., in the middle) or at a terminal end (e.g., the terminus) of the C₂-C₆₀ alkyl group, and examples thereof include an ethynyl group and a propynyl group. The term “C₂-C₆₀ alkynylene group,” as used herein, refers to a divalent group having substantially the same structure as the C₂-C₆₀ alkynyl group.

The term “C₁-C₆₀ alkoxy group,” as used herein, refers to a monovalent group represented by —OA₁₀₁ (wherein A₁₀₁ is the C₁-C₆₀ alkyl group), and examples thereof include a methoxy group, an ethoxy group, and an isopropyloxy group.

The term “C₃-C₁₀ cycloalkyl group,” as used herein, refers to a monovalent saturated hydrocarbon cyclic group having 3 to 10 carbon atoms, and examples thereof include a cyclopropyl group, a cyclobutyl group, a cyclopentyl group, a cyclohexyl group, a cycloheptyl group, a cyclooctyl group, an adamantanyl group, a norbornanyl group (or a bicyclo[2.2.1]heptyl group), a bicyclo[1.1.1]pentyl group, a bicyclo[2.1.1]hexyl group, and a bicyclo[2.2.2]octyl group. The term “C₃-C₁₀ cycloalkylene group,” as used herein, refers to a divalent group having substantially the same structure as the C₃-C₁₀ cycloalkyl group.

The term “C₁-C₁₀ heterocycloalkyl group,” as used herein, refers to a monovalent cyclic group that further includes, in addition to a carbon atom, at least one heteroatom as a ring-forming atom and has ₁ to 10 carbon atoms, and examples thereof include a 1,2,3,4-oxatriazolidinyl group, a tetrahydrofuranyl group, and a tetrahydrothiophenyl group. The term “C₁-C₁₀ heterocycloalkylene group,” as used herein, refers to a divalent group having substantially the same structure as the C₁-C₁₀ heterocycloalkyl group.

The term “C₃-C₁₀ cycloalkenyl group,” as used herein, refers to a monovalent cyclic group that has three to ten carbon atoms and at least one carbon-carbon double bond in the ring thereof and no aromaticity (e.g., is not aromatic), and examples thereof include a cyclopentenyl group, a cyclohexenyl group, and a cycloheptenyl group. The term “C₃-C₁₀ cycloalkenylene group,” as used herein, refers to a divalent group having substantially the same structure as the C₃-C₁₀ cycloalkenyl group.

The term “C₁-C₁₀ heterocycloalkenyl group,” as used herein, refers to a monovalent cyclic group that has, in addition to a carbon atom, at least one heteroatom as a ring-forming atom, 1 to 10 carbon atoms, and at least one double bond in the cyclic structure thereof. Examples of the C₁-Cio heterocycloalkenyl group include a 4,5-dihydro-1,2,3,4-oxatriazolylgroup, a 2,3-dihydrofuranyl group, and a 2,3-dihydrothiophenyl group. The term “C₁-C₁₀ heterocycloalkenylene group,” as used herein, refers to a divalent group having substantially the same structure as the C₁-C₁₀ heterocycloalkenyl group.

The term “C₆-C₆₀ aryl group,” as used herein, refers to a monovalent group having a carbocyclic aromatic system having six to sixty carbon atoms, and the term “C₆-C₆₀ arylene group,” as used herein, refers to a divalent group having a carbocyclic aromatic system having six to sixty carbon atoms. Examples of the C₆-C₆₀ aryl group include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, and an ovalenyl group. When the C₆-C₆₀ aryl group and the C₆-C₆₀ arylene group each include two or more rings, the rings may be condensed together with each other.

The term “C₁-C₆₀ heteroaryl group,” as used herein, refers to a monovalent group having a heterocyclic aromatic system that has, in addition to a carbon atom, at least one heteroatom as a ring-forming atom, and 1 to 60 carbon atoms. The term “C₁-C₆₀ heteroarylene group,” as used herein, refers to a divalent group having a heterocyclic aromatic system that has, in addition to a carbon atom, at least one heteroatom as a ring-forming atom, and 1 to 60 carbon atoms. Examples of the C₁-C₆₀ heteroaryl group include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and a naphthyridinyl group. When the C₁-C₆₀ heteroaryl group and the C₁-C₆₀ heteroarylene group each include two or more rings, the rings may be condensed together with each other.

The term “monovalent non-aromatic condensed polycyclic group,” as used herein, refers to a monovalent group having two or more rings condensed to each other, only carbon atoms (for example, having 8 to 60 carbon atoms) as ring-forming atoms, and non-aromaticity in its molecular structure when considered as a whole (e.g., is not aromatic when considered as a whole). Examples of the monovalent non-aromatic condensed polycyclic group include an indenyl group, a fluorenyl group, a spiro-bifluorenyl group, a benzofluorenyl group, an indenophenanthrenyl group, and an indeno anthracenyl group. The term “divalent non-aromatic condensed polycyclic group,” as used herein, refers to a divalent group having substantially the same structure as a monovalent non-aromatic condensed polycyclic group.

The term “monovalent non-aromatic condensed heteropolycyclic group,” as used herein, refers to a monovalent group having two or more rings condensed to each other, at least one heteroatom other than carbon atoms (for example, having 1 to 60 carbon atoms), as a ring-forming atom, and non-aromaticity in its molecular structure when considered as a whole (e.g., is not aromatic when considered as a whole). Examples of the monovalent non-aromatic condensed heteropolycyclic group include a pyrrolyl group, a thiophenyl group, a furanyl group, an indolyl group, a benzoindolyl group, a naphtho indolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, and a benzothienodibenzothiophenyl group. The term “divalent non-aromatic condensed heteropolycyclic group,” as used herein, refers to a divalent group having substantially the same structure as a monovalent non-aromatic condensed heteropolycyclic group.

The term “C₆-C₆₀ aryloxy group,” as used herein, indicates —OA₁₀₂ (wherein A₁₀₂ is the C₆-C₆₀ aryl group), and the term “C₆-C₆₀ arylthio group,” as used herein, indicates —SA₁₀₃ (wherein A₁₀₃ is the C₆-C₆₀ aryl group).

The term “C₇-C₆₀ aryl alkyl group,” as used herein, refers to —A₁₀₄A₁₀₆ (where A₁₀₄ may be a C₁-C₅₄ alkylene group, and A₁₀₅ may be a C₆-C₅₉ aryl group), and the term “C₂-C₆₀ heteroaryl alkyl group,” as used herein, refers to —A₁₀₆A₁₀₇ (where A₁₀₆ may be a C₁-C₆₀ alkylene group, and A₁₀₇ may be a C₁-C₆₀ heteroaryl group). R₁₀ₐ may be:

deuterium (—D), —F, —CI, —Br, —I, a hydroxyl group, a cyano group, or a nitro group;

a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —CI, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;

a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —CI, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(₀₂₁)(₀₂₂), —B(Q₂₁)(Q₂₂), —C(═O)(Q₂₁), —S(═O)₂(Q₂₁), —P(═O)(Q₂₁)(Q₂₂), or any combination thereof; or

—O(Q₃₁), —S(Q₃₁), —Si(Q₃₁)(Q₃₂) —B(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), or —P(═O)(Q₃₁)(Q₃₂).

Q₁ to Q₃, Q₁₁ to Q₁₃, Q₂₁ to Q₂₃, and Q₃₁ to Q₃₃ in the present specification may each independently be: hydrogen; deuterium; —F; —CI; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, a pyridinyl group, a pyrimidinyl group, a pyridazinyl group, a pyrazinyl group, a triazinyl group, or any combination thereof.

The term “hetero atom,” as used herein, refers to any atom other than a carbon atom. Examples of the heteroatom include O, S, N, P, Si, B, Ge, Se, or any combination thereof.

The term “the third-row transition metal,” as used herein, includes hafnium (Hf), tantalum (Ta), tungsten (W), rhenium (Re), osmium (Os), iridium (Ir), platinum (Pt), gold (Au), and the like.

The term “Ph,” as used herein, refers to a phenyl group, the term “Me,” as used herein, refers to a methyl group, the term “Et,” as used herein, refers to an ethyl group, the term “tert-Bu” or “Bu^{t},” as used herein, refers to a tert-butyl group, and the term “OMe,” as used herein, refers to a methoxy group.

The term “biphenyl group,” as used herein, refers to “a phenyl group substituted with a phenyl group.” In other words, the “biphenyl group” is a substituted phenyl group having a C₆-C₆₀ aryl group as a substituent.

The term “terphenyl group,” as used herein, refers to “a phenyl group substituted with a biphenyl group”. The “terphenyl group” is a substituted phenyl group having, as a substituent, a C₆-C₆₀ aryl group substituted with a C₆-C₆₀ aryl group.

*, *′, and *″, as used herein, unless defined otherwise, each refer to a binding site to a neighboring atom in a corresponding formula or moiety.

Hereinafter, compounds according to embodiments and light-emitting devices according to embodiments will be described in more detail with reference to the following synthesis examples and examples. The wording “B was used instead of A” used in describing Synthesis Examples means that an identical molar equivalent of B was used in place of A.

### EXAMPLES

### Synthesis Example 1 (Synthesis of Compound BD₀₂)

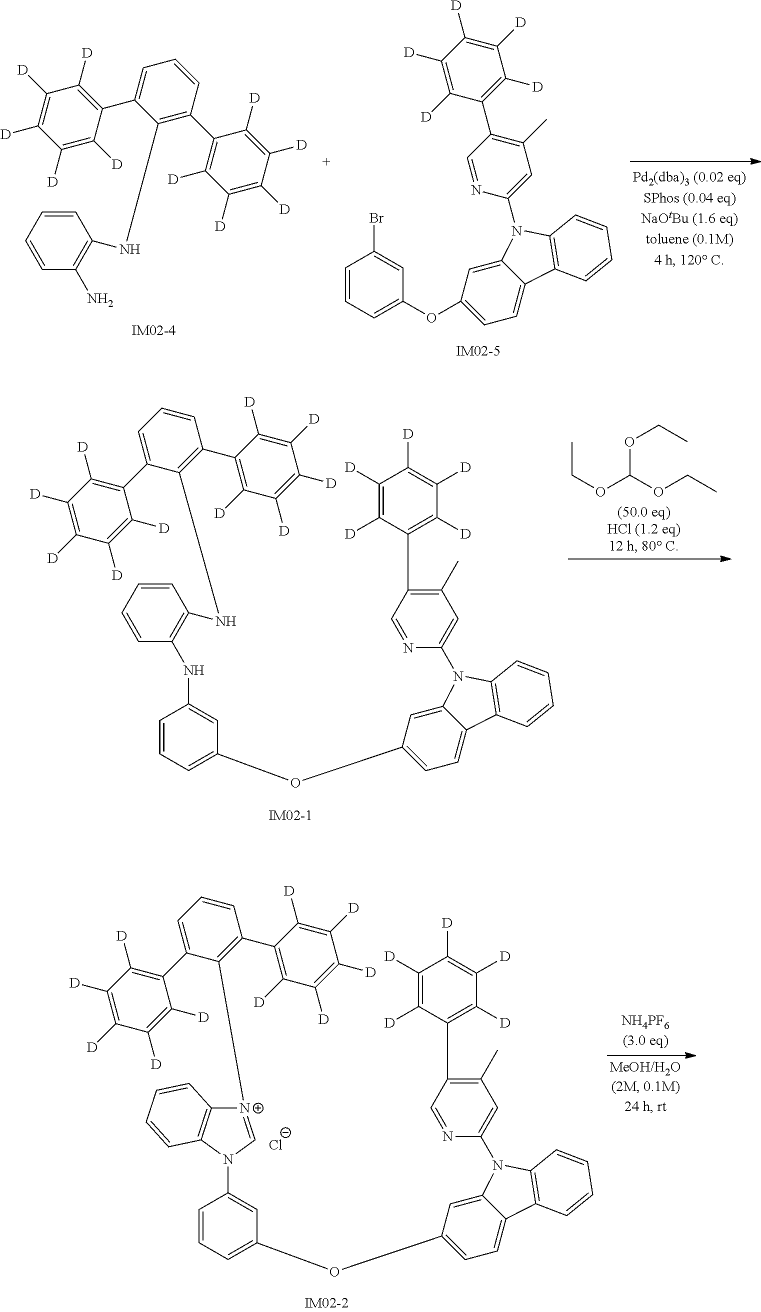

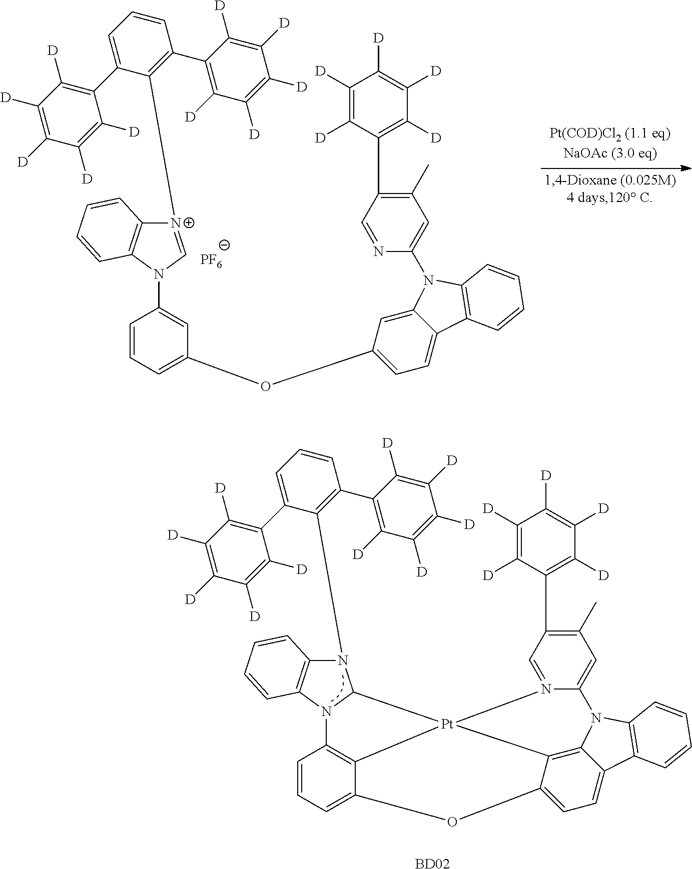

### Synthesis of Intermediate IM02-1

N¹-([_{1,1′:3′,1}″-terphenyl]-2′-yl-2,2″,3,3″,4,4″,5,5″,6,6″-d₁₀)benzene-_{1,2}-diamine (Intermediate IM02-4) (3.9 g, 11.4 mmol), 2-(3-bromophenoxy)-₉-(4-methyl-5-(phenyl-d₅)pyridin-2-yl)-9H-carbazole (Intermediate IM02-5) (5.8 g, 11.4 mmol), Pd₂(dba)₃ (0.2 g, 0.2 mmol), SPhos (1.9 g, 4.6 mmol), and NaO^{t}Bu (1.7 g, 18.2 mmol) were placed in a reaction vessel and suspended in ₁₁₄ ml of toluene, and then heated and stirred for 4 hours at 120° C. After the reaction was terminated, the resultant mixture was cooled to room temperature, 300 ml of distilled water was added thereto, and an organic layer was extracted therefrom using ethylacetate, and the extracted organic layer was washed with a saturated sodium chloride aqueous solution and dried using sodium sulfate. The obtained result was subjected to column chromatography to obtain Intermediate IM02-1 (6.7 g, 8.6 mmol) in the yield of 75%.

### Synthesis of Intermediate IM02-2

Intermediate IM02-1 (6.7 g, 8.6 mmol), 86 ml (516 mmol) of triethyl orthoformate, and 1.0 ml (10.3 mmol) of HCI (37%) were placed in a reaction vessel, and then heated and stirred for 12 hours at 80° C. After the reaction was terminated, the resultant mixture was cooled to room temperature, a solid thus generated therefrom was subjected to filtration and washed using ether, and then the washed solid was dried to obtain Intermediate IM02-2 (6.3 g, 7.7 mmol) in the yield of 90%.

### Synthesis of Intermediate 1M02-3

Intermediate IM02-2 (6.3 g, 7.7 mmol) and NH₄PF₆ (3.8 g, 23.1 mmol) were placed in a reaction vessel and suspended in a mixed solution including 100 ml of methyl alcohol and 50 ml of water, and then stirred for 24 hours at room temperature. After the reaction was terminated, a solid thus generated therefrom was subjected to filtration and washed using ether, and then the washed solid was dried to obtain Intermediate IM02-3 (6.4 g, 6.9 mmol) in the yield of 90%.

### Synthesis of Compound BD02

Intermediate IM02-3 (6.4 g, 6.9 mmol), dichloro(1,5-cyclooctadiene)platinum (Pt(COD)Cl₂, 2.8 g, 7.6 mmol), and NaOAc (1.7 g, 20.7 mmol) were suspended in 150 ml of 1,4-dioxane, and then heated and stirred for 4 days at 120° C. After the reaction was terminated, the resultant mixture was cooled to room temperature, 150 mL of distilled water was added thereto, an organic layer was extracted therefrom using ethylacetate, and then, the extracted organic layer was washed with a NaCI aqueous solution and dried using MgSO₄. The obtained result was subjected to column chromatography to obtain Compound BD02 (2.3 g, 2.4 mmol) in the yield of 35%.

### Synthesis Example 2 (Synthesis of Compound BD04)

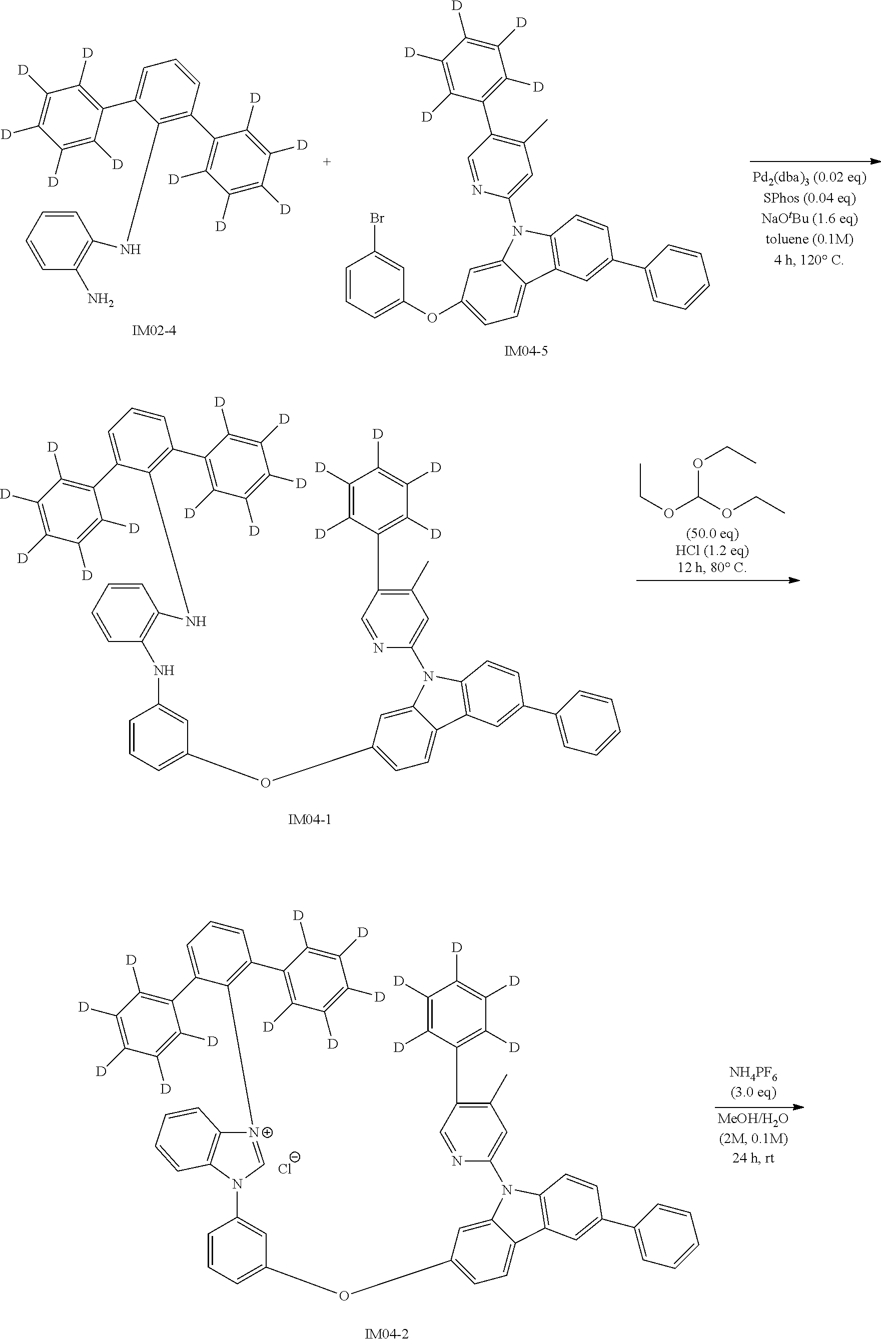

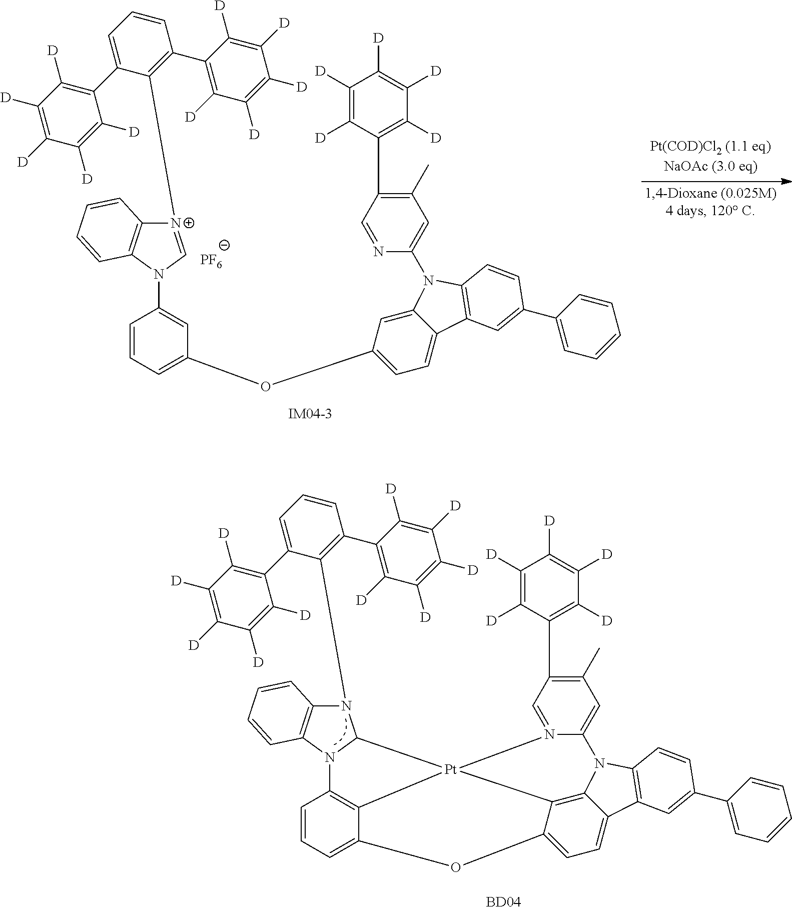

Compound BD04 (2.3 g, 2.2 mmol) was obtained in the yield of 32% in substantially the same manner as in Synthesis Example 1, except that 2-(3-bromophenoxy)-9-(4-methyl-5-(phenyl-d₅)pyridin-2-yl)-6-phenyl-9H-carbazole (Intermediate IM04-5) (6.7 g, 11.4 mmol), Intermediate IM04-1, Intermediate IM04-2, and Intermediate IM04-3 were sequentially used instead of Intermediate IM02-5, Intermediate IM02-1, Intermediate IM02-2, and Intermediate IM02-3, respectively.

### Synthesis Example 3 (Synthesis of Compound BD23)

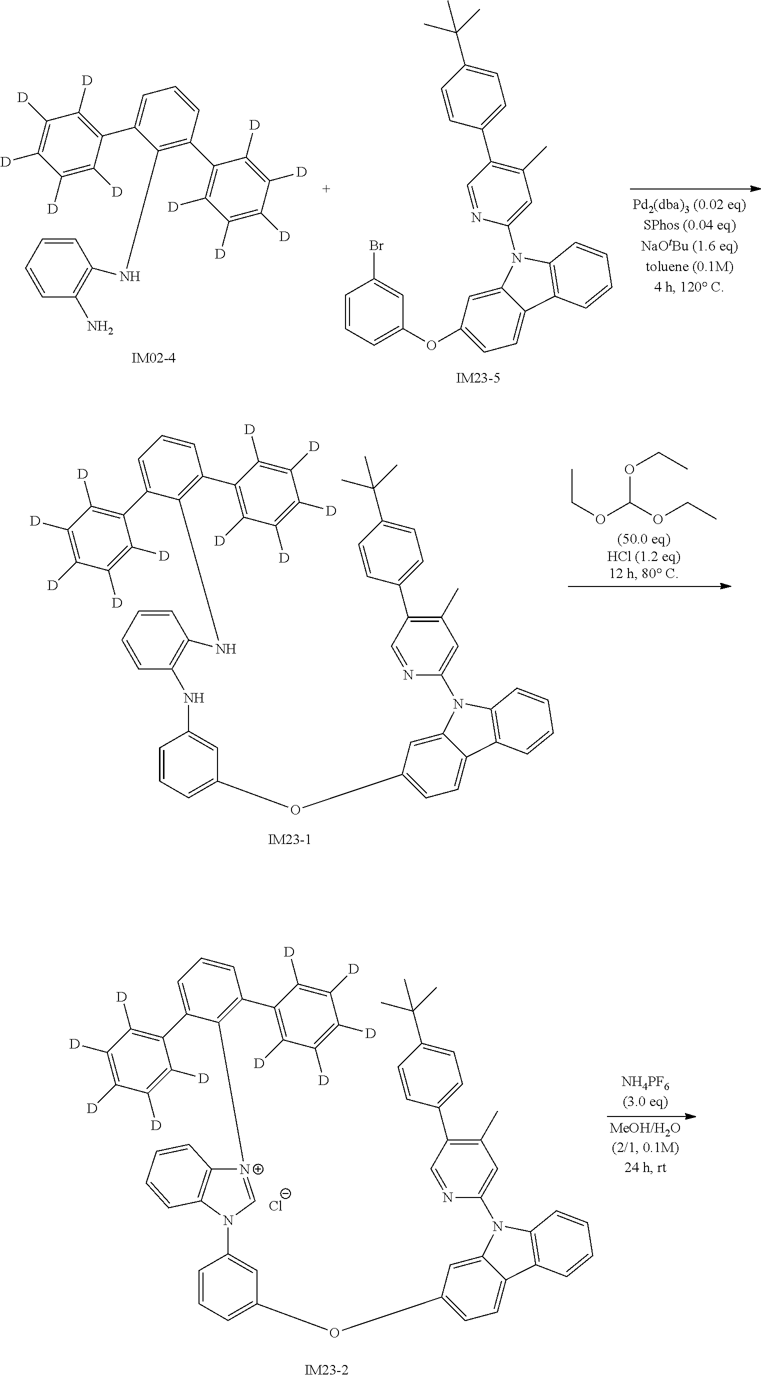

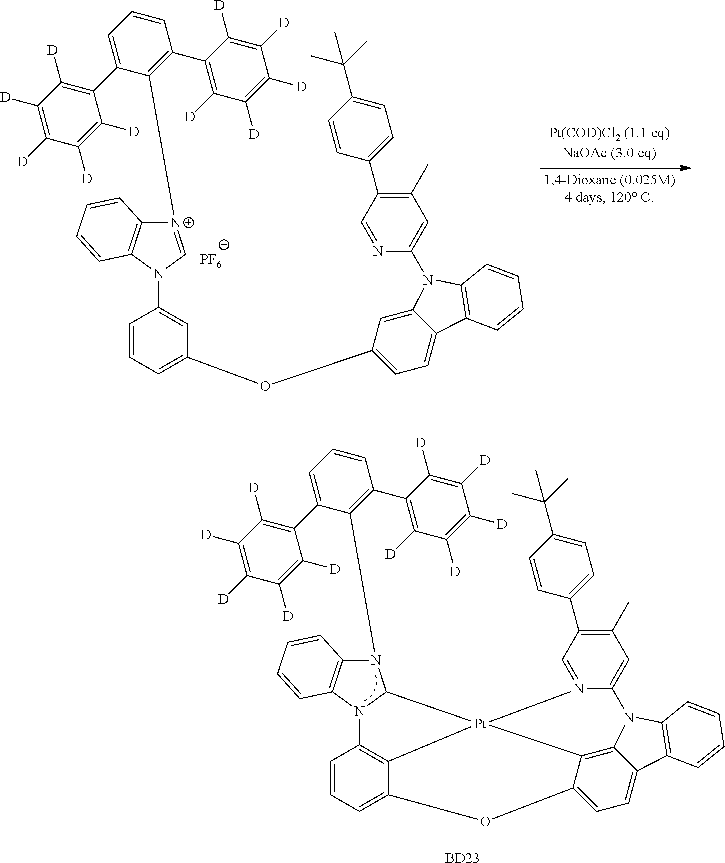

Compound BD23 (2.5 g, 2.4 mmol) was obtained in the yield of 35% in substantially the same manner as in Synthesis Example 1, except that 2-(3-bromophenoxy)-9-(5-(4-(tert-butyl)phenyl)-4-methylpyridin-2-yl)-9H-carbazole (Intermediate IM23-5) (6.4 g, 11.4 mmol), Intermediate IM23-1, Intermediate IM23-2, and Intermediate IM23-3 were sequentially used instead of Intermediate IM02-5, Intermediate IM02-1, Intermediate IM02-2, and Intermediate IM02-3, respectively.

### Synthesis Example 4 (Synthesis of Compound BD58)

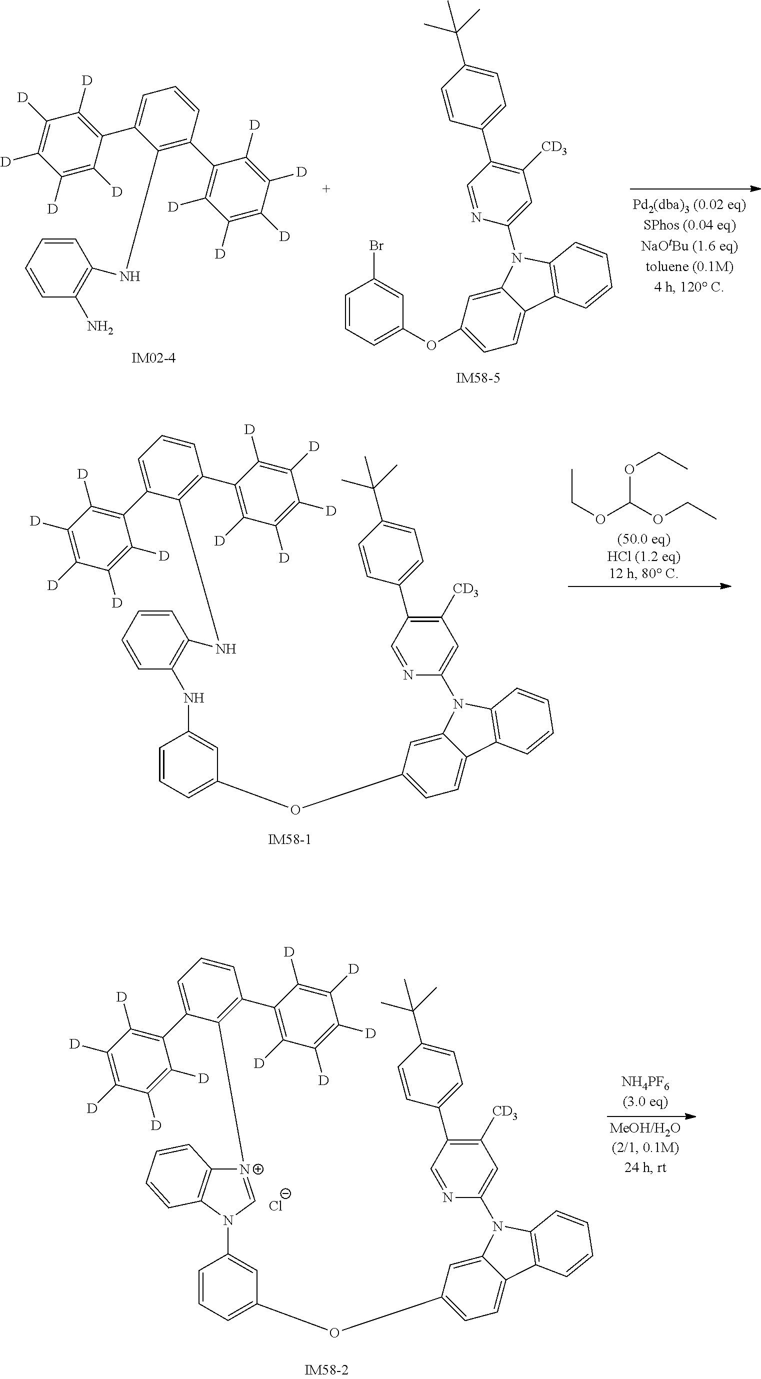

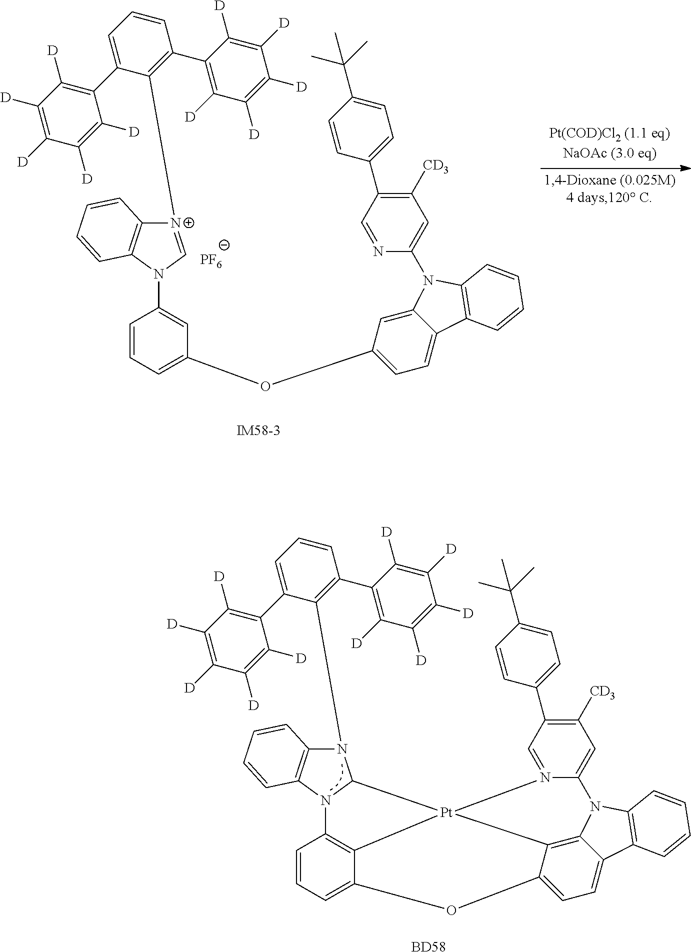

Compound BD58 (2.6 g, 2.6 mmol) was obtained in the yield of 37% in substantially the same manner as in Synthesis Example 1, except that 2-(3-bromophenoxy)-9-(5-(4-(tert-butyl)phenyl)-4-(methyl-d₃)pyridin-2-yl)-9H-carbazole (Intermediate IM58-5) (6.4 g, 11.4 mmol), Intermediate IM58-1, Intermediate IM58-2, and Intermediate IM58-3 were sequentially used instead of Intermediate IM02-5, Intermediate IM02-1, Intermediate IM02-2, and Intermediate IM02-3, respectively.

### Synthesis Example 5 (Synthesis of Compound BD71)

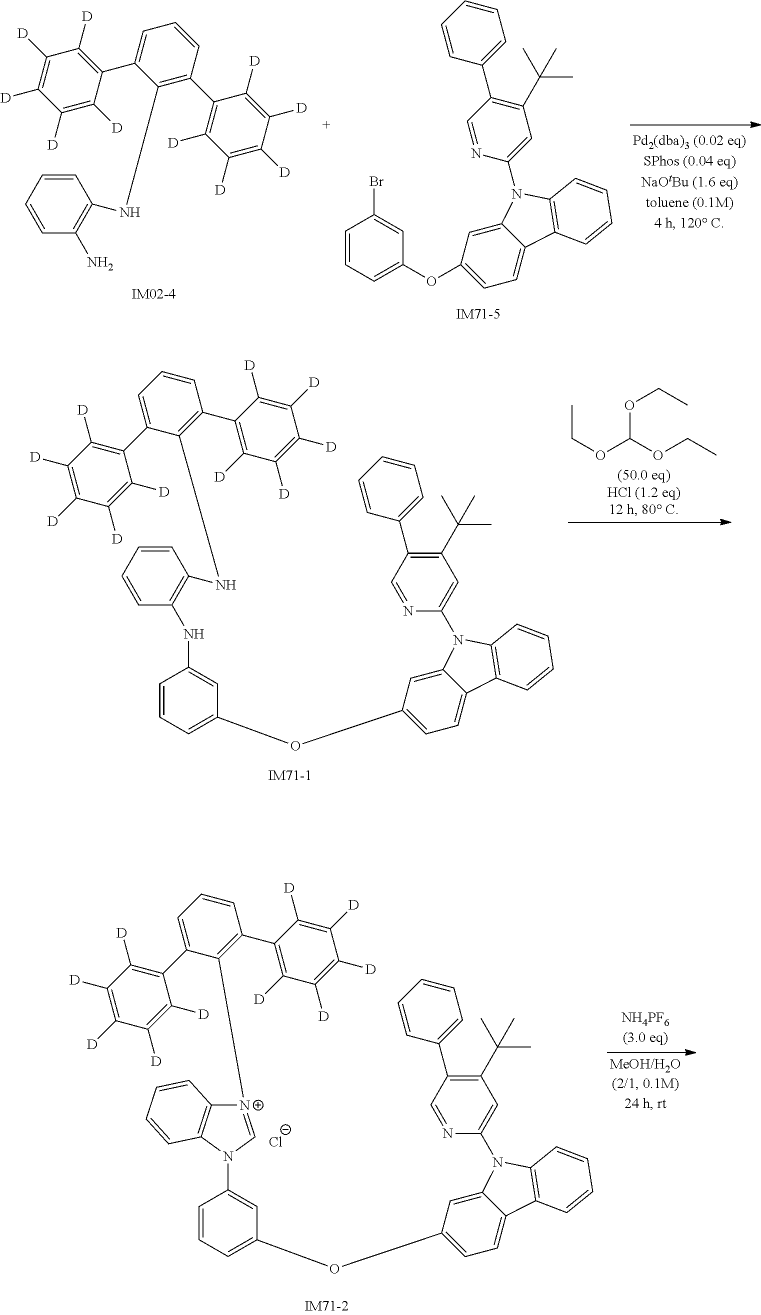

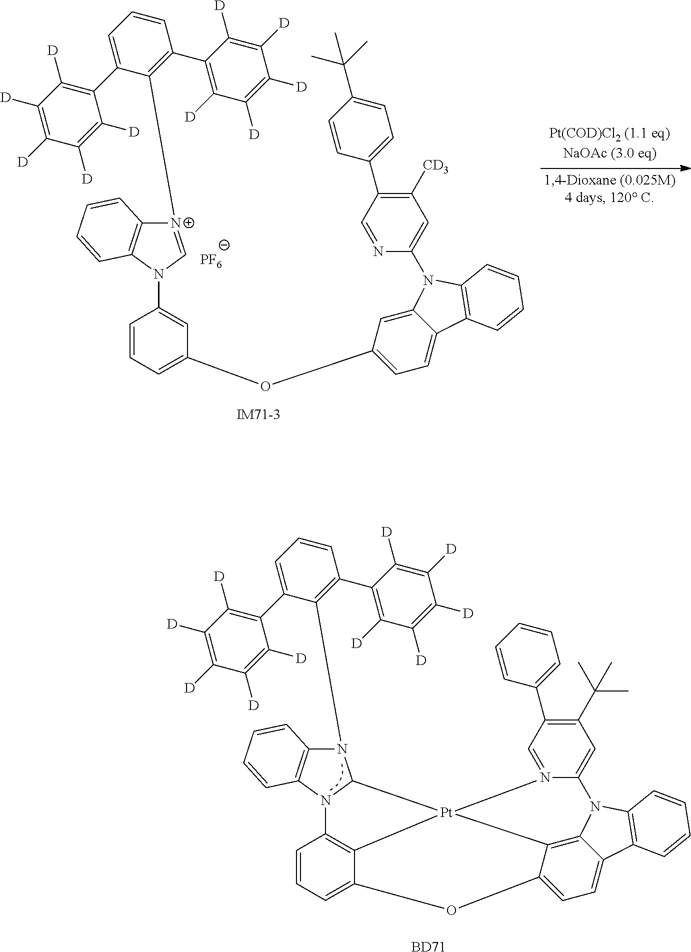

Compound BD71 (1.6 g, 1.6 mmol) was obtained in the yield of 23% in substantially the same manner as in Synthesis Example 1, except that 2-(3-bromophenoxy)-9-(4-(tert-butyl)-5-phenylpyridin-2-yl)-9H-carbazole (Intermediate IM71-5) (6.4 g, 11.4 mmol), Intermediate IM71-1, Intermediate IM71-2, and Intermediate IM71-3 were sequentially used instead of Intermediate IM02-5, Intermediate IM02-1, Intermediate IM02-2, and Intermediate IM02-3, respectively.

### Synthesis Example 6 (Synthesis of Compound BD72)

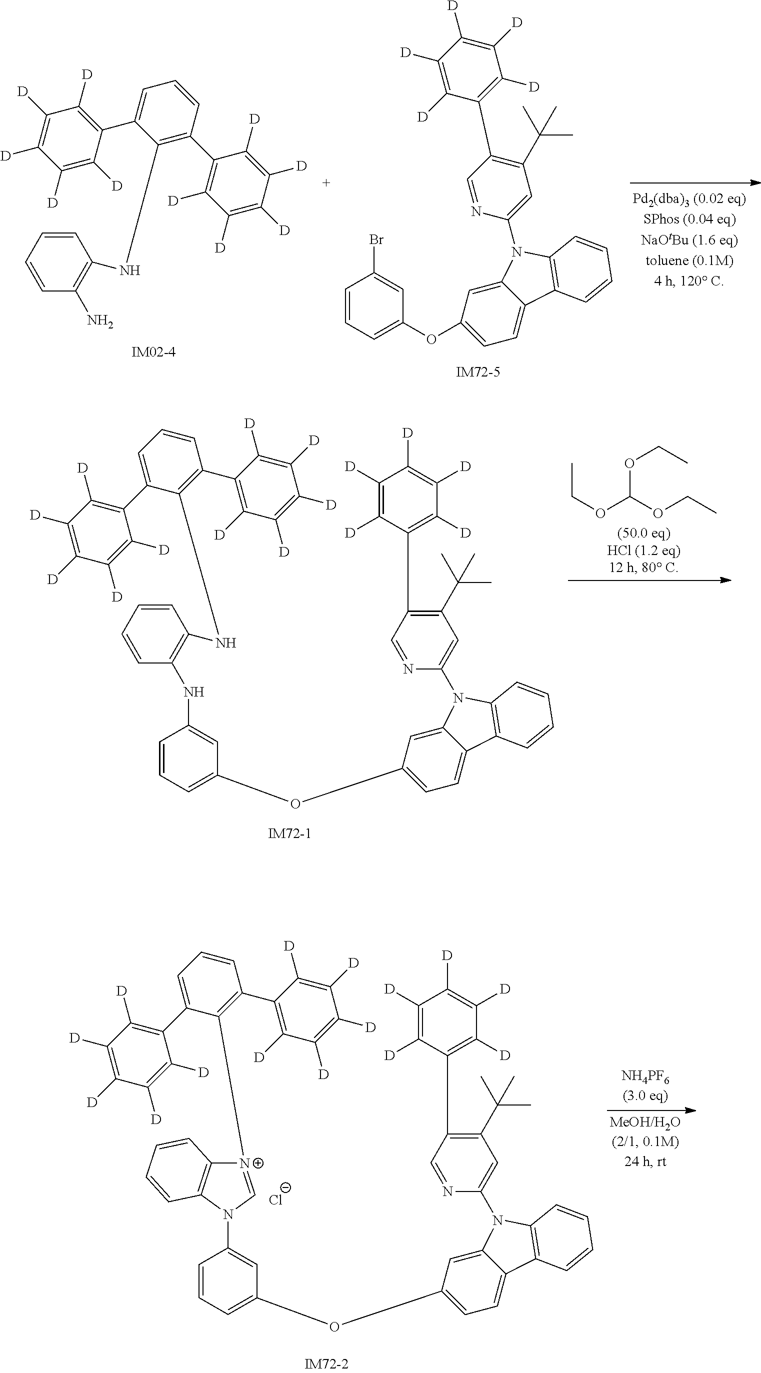

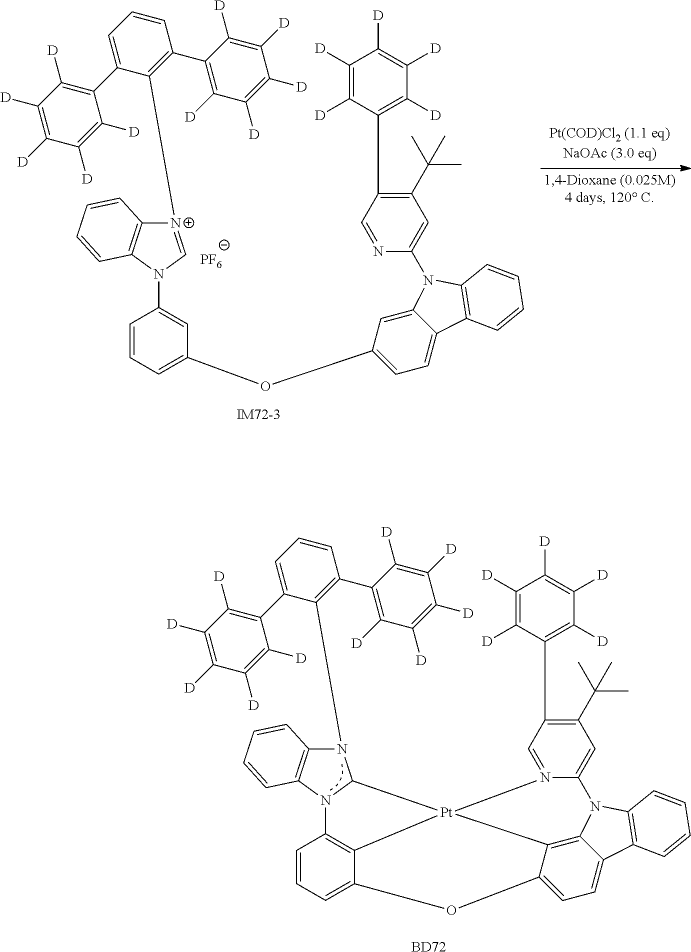

Compound BD72 (1.8 g, 1.7 mmol) was obtained in the yield of 25% in substantially the same manner as in Synthesis Example 1, except that 2-(3-bromophenoxy)-9-(4-(tert-butyl)-5-(phenyl-d5)pyridin-2-yl)-9H-carbazole (Intermediate IM72-5) (6.3 g, 11.4 mmol), Intermediate IM72-1, Intermediate IM72-2, and Intermediate IM72-3 were sequentially used instead of Intermediate IM02-5, Intermediate IM02-1, Intermediate IM02-2, and Intermediate IM02-3, respectively.

### Synthesis Example 7 (Synthesis of Compound BD323)

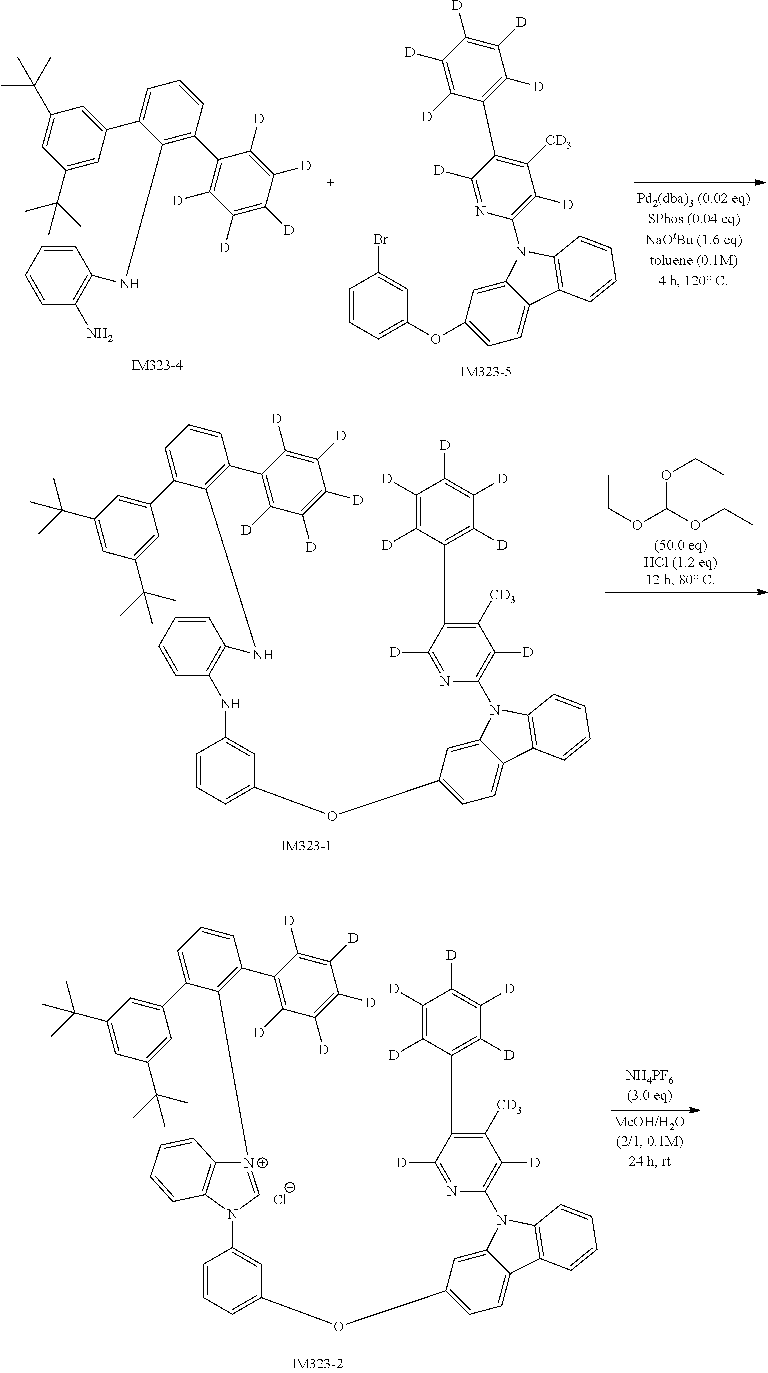

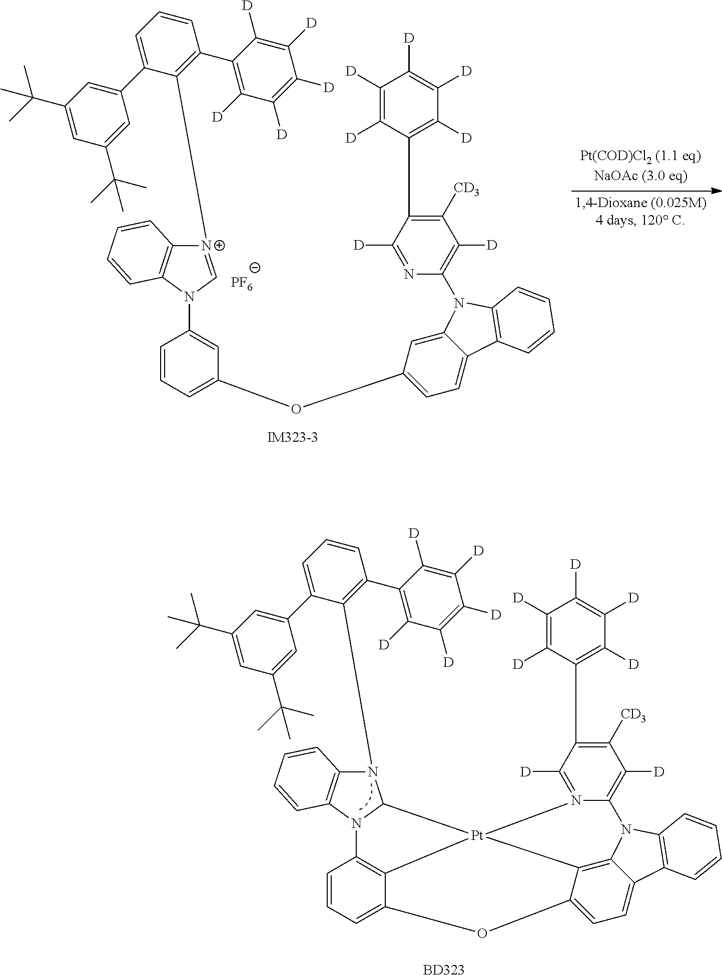

Compound BD323 (2.8 g, 2.6 mmol) was obtained in the yield of 37% in substantially the same manner as in Synthesis Example 1, except that N¹-(3,5-di-tert-butyl-[1,1′:3′,1″-terphenyl]-2′-yl-2″,3″,4″,5″,6″-d5)benzene-1,2-diamine (Intermediate IM323-4) (5.2 g, 11.4 mmol), 2-(3-bromophenoxy)-9-(4-(methyl-d3)-5-(phenyl-d5)pyridin-2-yl-3,6-d₂)-9H-carbazole (Intermediate IM323-5) (5.9 g, 11.4 mmol), Intermediate IM323-1, Intermediate IM323-2, and Intermediate IM323-3 were sequentially used instead of Intermediate IM02-4, Intermediate IM02-5, Intermediate IM02-1, Intermediate IM02-2, and Intermediate IM02-3, respectively.

### Synthesis Example 8 (Synthesis of Compound BD325)

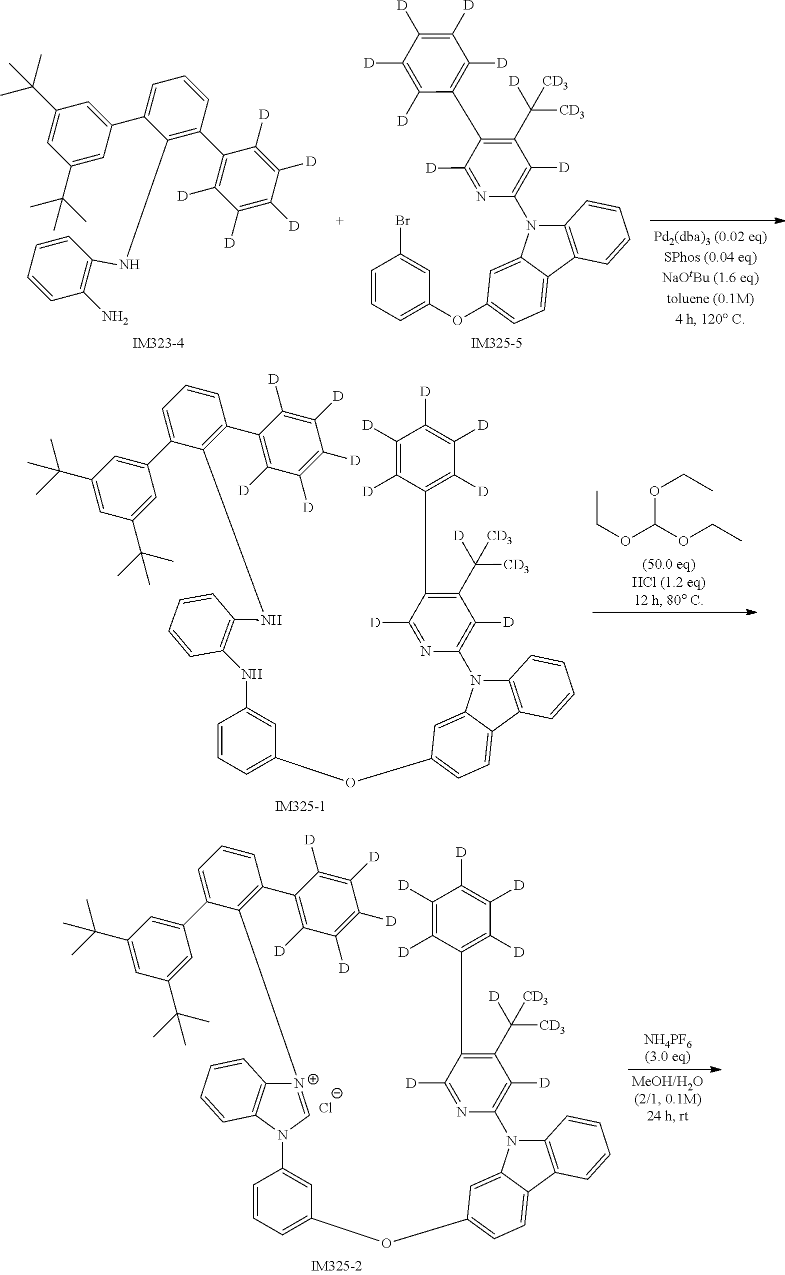

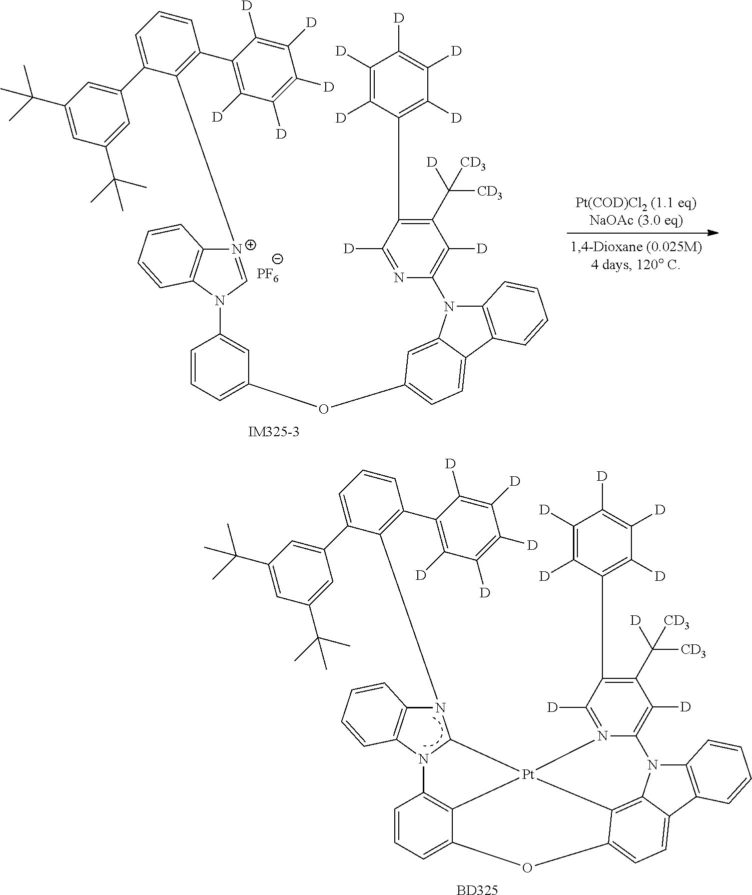

Compound BD325 (2.7 g, 2.4 mmol) was obtained in the yield of 35% in substantially the same manner as in Synthesis Example 7, except that 2-(3-bromophenoxy)-9-(5-(phenyl-d₅)-4-(propan-2-yl-ch)pyridin-2-yl-3,6-d2)-9H-carbazole (Intermediate IM325-5) (6.2 g, 11.4 mmol), Intermediate IM325-1, Intermediate IM325-2, and Intermediate IM325-3 were sequentially used instead of Intermediate IM323-5, Intermediate IM323-1, Intermediate IM323-2, and Intermediate IM323-3, respectively.

### Synthesis Example 9 (Synthesis of Compound BD327)

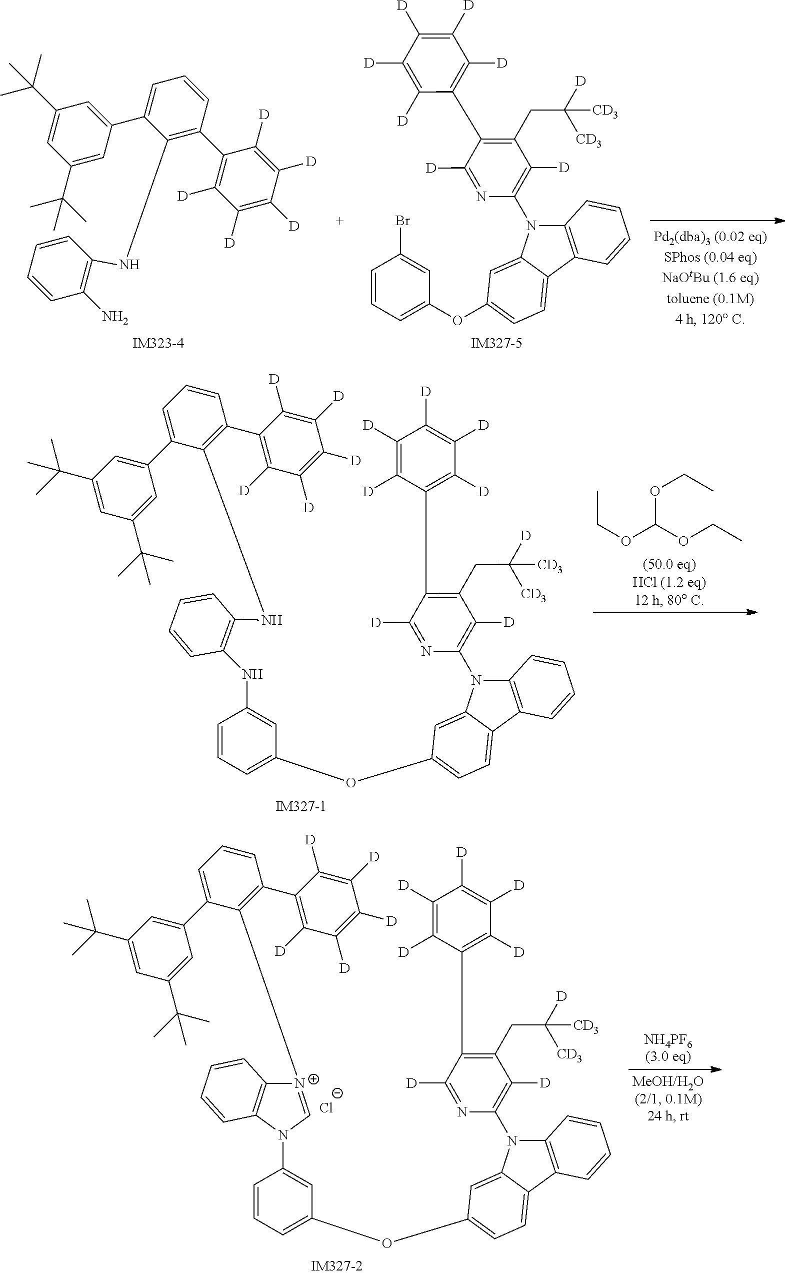

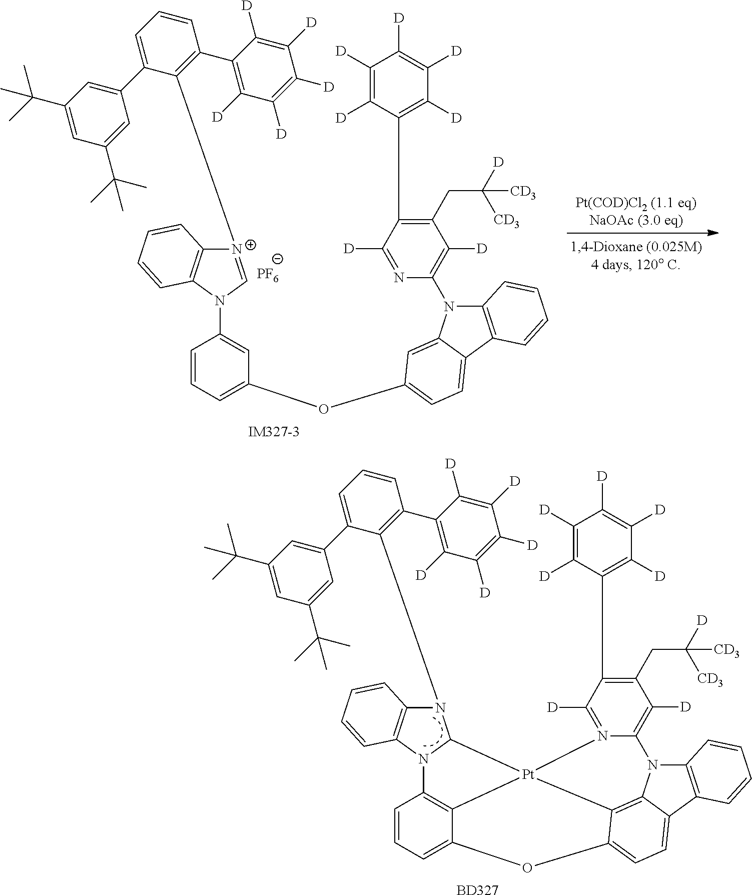

Compound BD327 (3.0 g, 2.6 mmol) was obtained in the yield of 38% in substantially the same manner as in Synthesis Example 7, except that 2-(3-bromophenoxy)-9-(4-(2-(methyl-d3)propyl-2,3,3,3-d4)-5-(phenyl-d5)pyridin-2-yl-3,6-d₂)-9H-carbazole (Intermediate IM327-5) (6.4 g, 11.4 mmol), Intermediate IM327-1, Intermediate IM327-2, and Intermediate IM327-3 were sequentially used instead of Intermediate IM323-5, Intermediate IM323-1, Intermediate IM323-2, and Intermediate IM323-3, respectively.

### Synthesis Example 10 (Synthesis of Compound BD329)

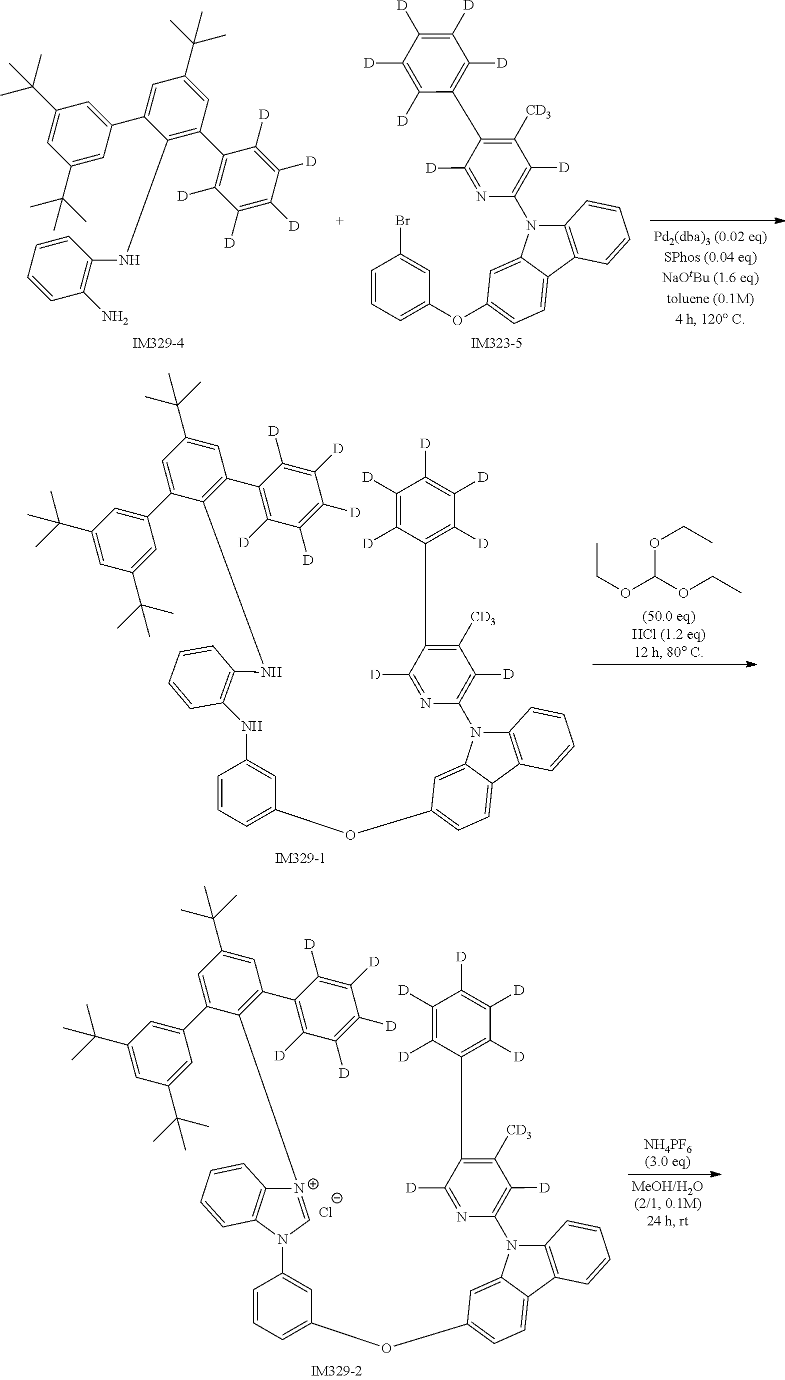

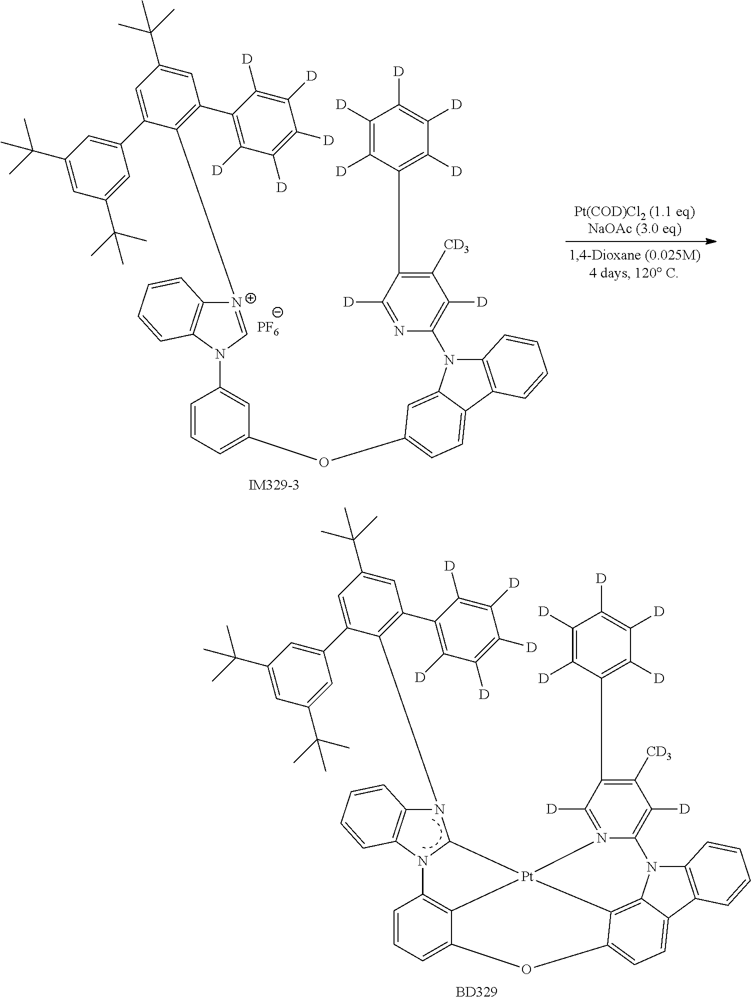

Compound BD329 (3.0 g, 2.6 mmol) was obtained in the yield of 38% in substantially the same manner as in Synthesis Example 1, except that N¹—(3,5,5′-tri-tert-butyl-[1,1′:3′,1″-terpheny]-2′-yl-2″,3″,4″,5″,6″-d₅)benzene-1,2-diamine (Intermediate IM329-4) (5.8 g, 11.4 mmol), 2-(3-bromophenoxy)-9-(4-(methyl-d₃)-5-(phenyl-d₅)pyridin-2-yl-3,6-d₂)-9H-carbazole (Intermediate IM323-5) (5.9 g, 11.4 mmol), Intermediate IM329-1, Intermediate IM329-2, and Intermediate IM329-3 were sequentially used instead of Intermediate IM02-4, Intermediate IM02-5, Intermediate IM02-1, Intermediate IM02-2, and Intermediate IM02-3, respectively.

### Synthesis Example 11 (Synthesis of Compound BD331)

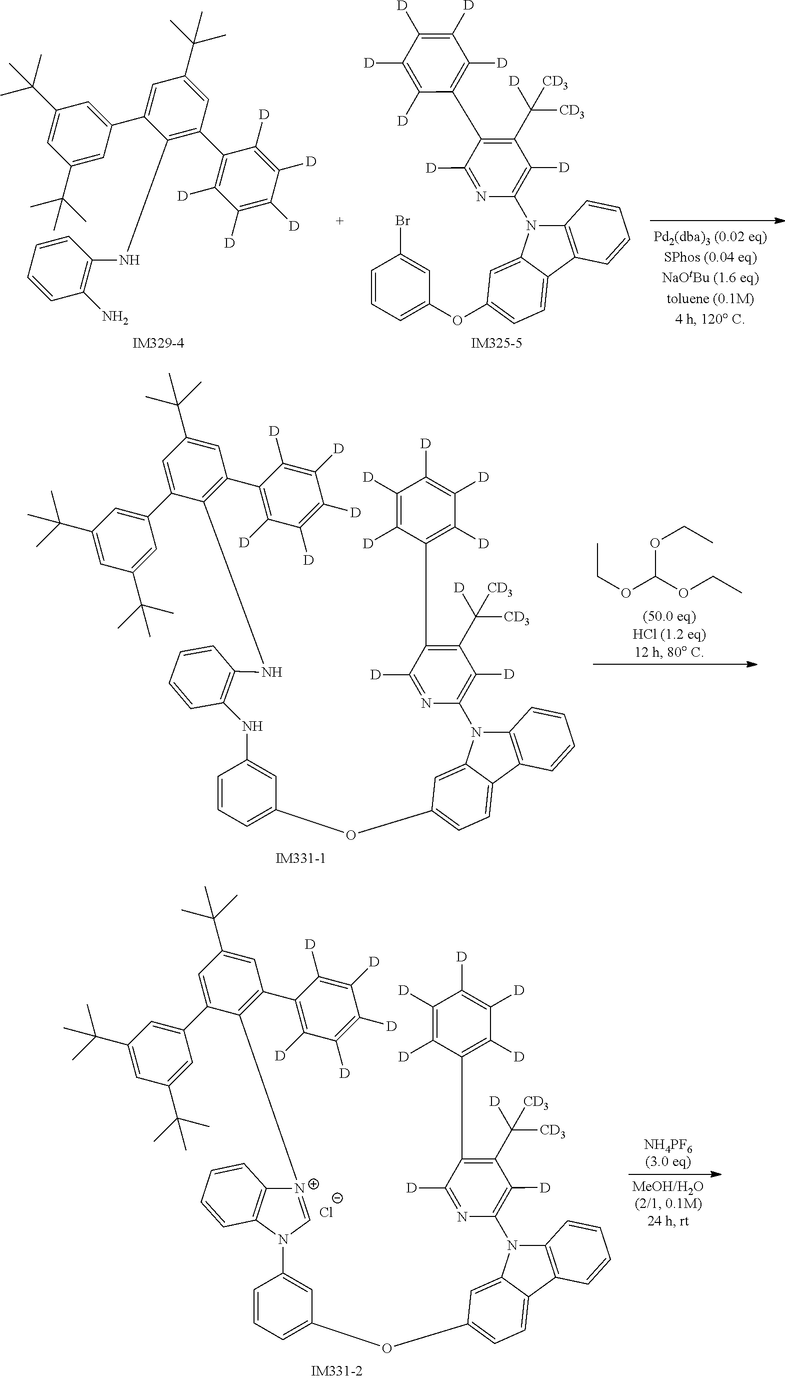

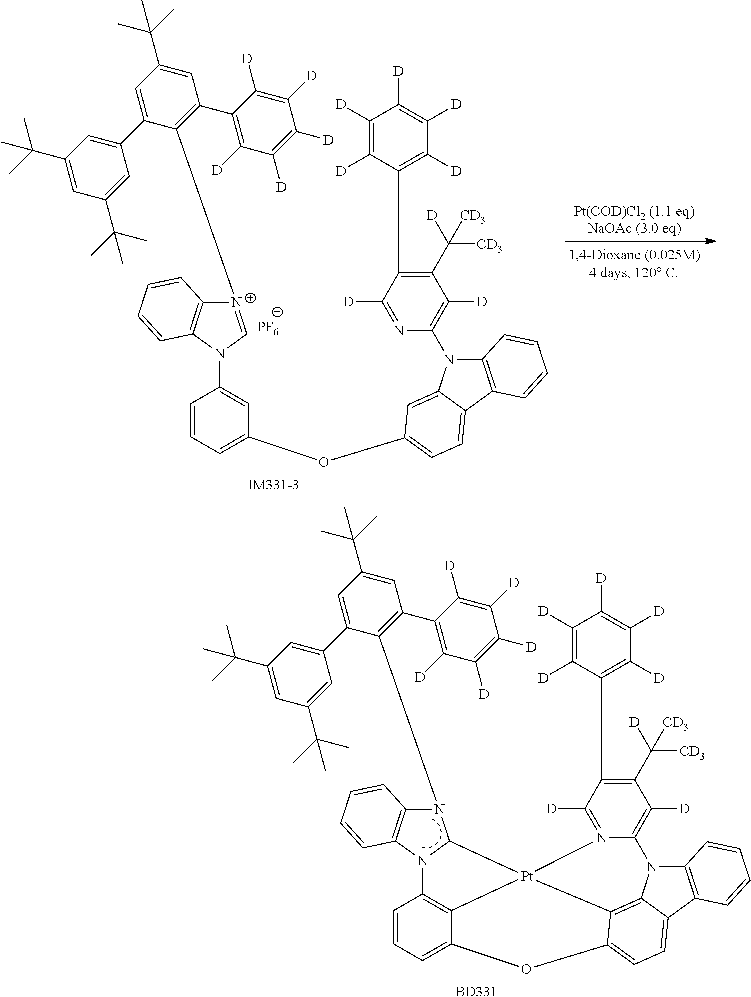

Compound BD331 (3.0 g, 2.6 mmol) was obtained in the yield of 37% in substantially the same manner as in Synthesis Example 10, except that 2-(3-bromophenoxy)-9-(5-(phenyl-d₅)-4-(propan-2-yl-d₇)pyridin-2-yl-3,6-d2)-9H-carbazole (Intermediate IM325-5) (6.2 g, 11.4 mmol), Intermediate IM331-1, Intermediate IM331-2, and Intermediate IM331-3 were sequentially used instead of Intermediate IM323-5, Intermediate IM329-1, Intermediate IM329-2, and Intermediate IM329-3, respectively.

### Synthesis Example 12 (Synthesis of Compound BD333)

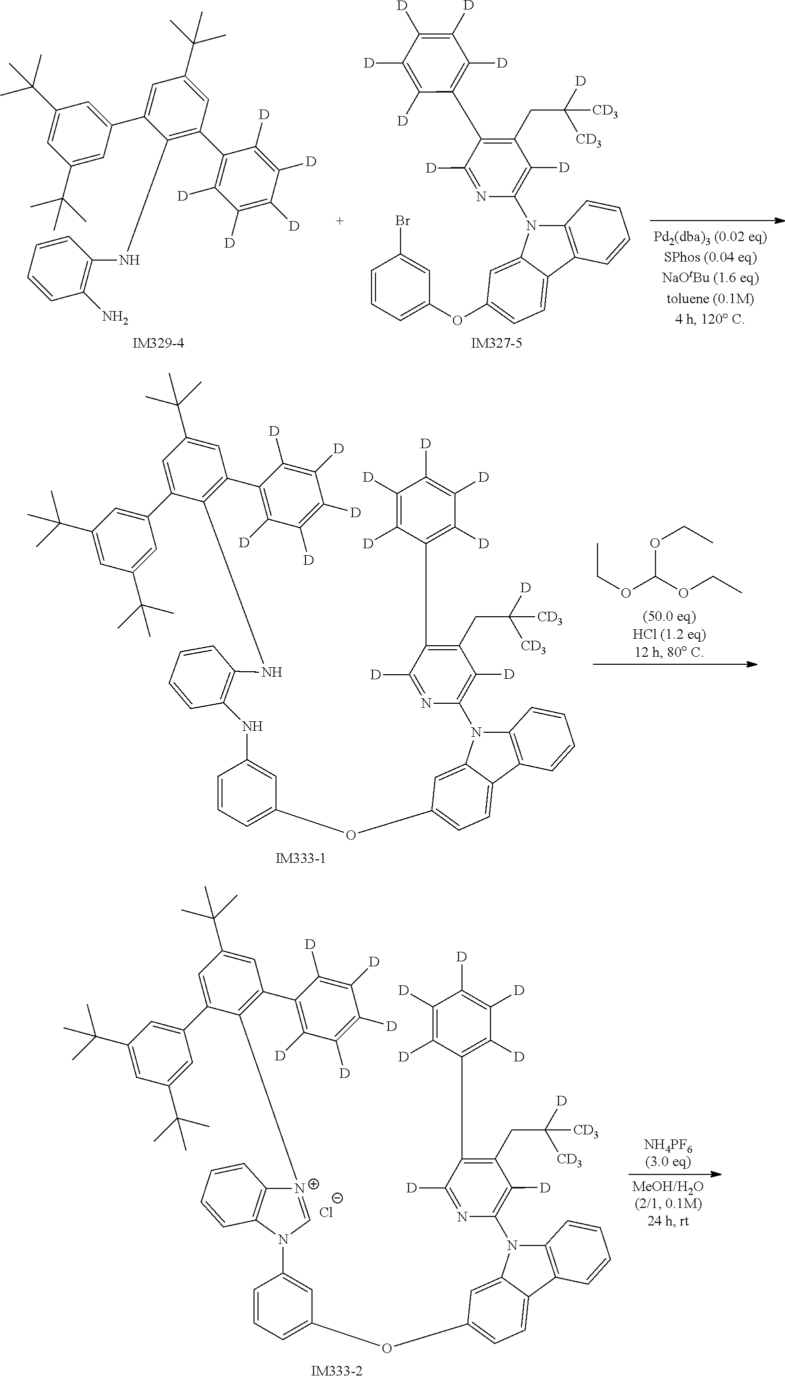

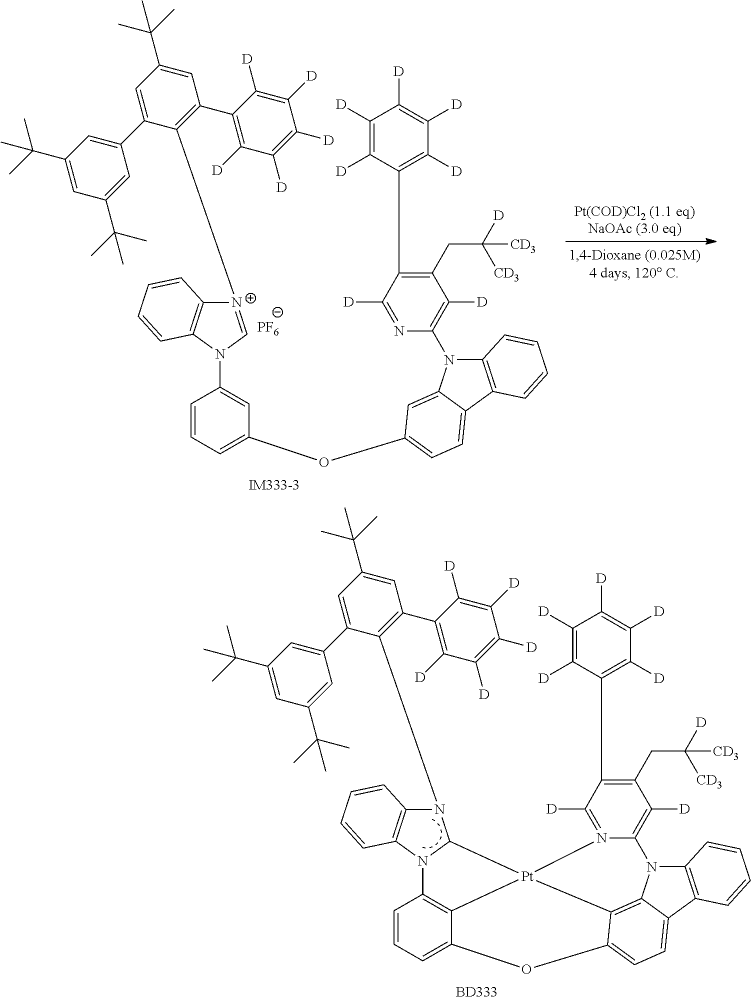

Compound BD333 (3.0 g, 2.5 mmol) was obtained in the yield of 36% in substantially the same manner as in Synthesis Example 10, except that 2-(3-bromophenoxy)-9-(4-(2-(methyl-d₃)propyl-2,3,3,3-d4)-5-(phenyl-d5)pyridin-2-yl-3,6-d₂)-9H-carbazole (Intermediate IM327-5) (6.4 g, 11.4 mmol), Intermediate IM333-1, Intermediate IM333-2, and Intermediate IM333-3 were sequentially used instead of Intermediate IM323-5, Intermediate IM329-1, Intermediate IM329-2, and Intermediate IM329-3, respectively.

### Comparative Synthesis Example A (Synthesis of Compound A)

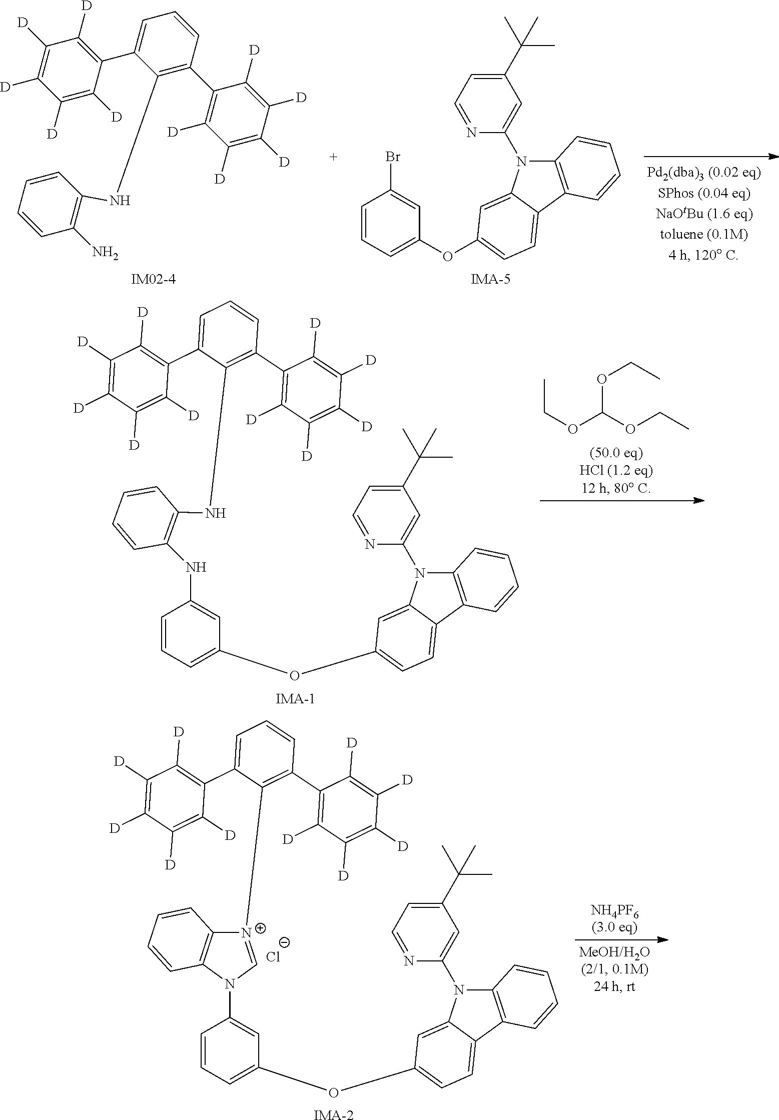

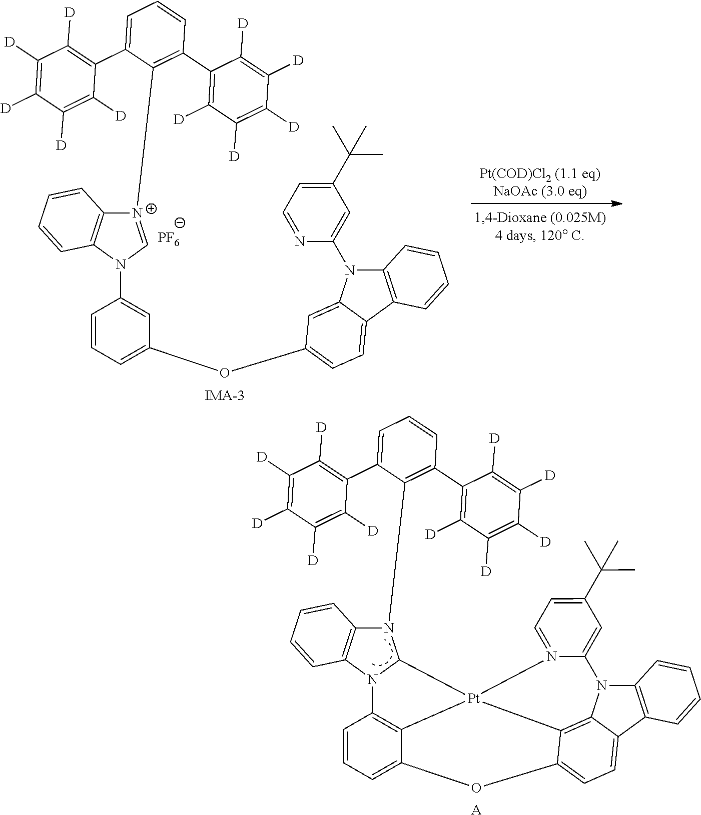

Compound A (2.1 g, 2.3 mmol) was obtained in the yield of 33% in substantially the same manner as in Synthesis Example 1, except that 2-(3-bromophenoxy)-9-(4-(tert-butyl)pyridin-2-yl)-9H-carbazole (Intermediate IMA-5) (5.4 g, 11.4 mmol), Intermediate IMA-1, Intermediate IMA-2, and Intermediate IMA-3 were sequentially used instead of Intermediate IM02-5, Intermediate IM02-1, Intermediate IM02-2, and Intermediate IM02-3, respectively.

### Comparative Synthesis Example B (Synthesis of Compound B)

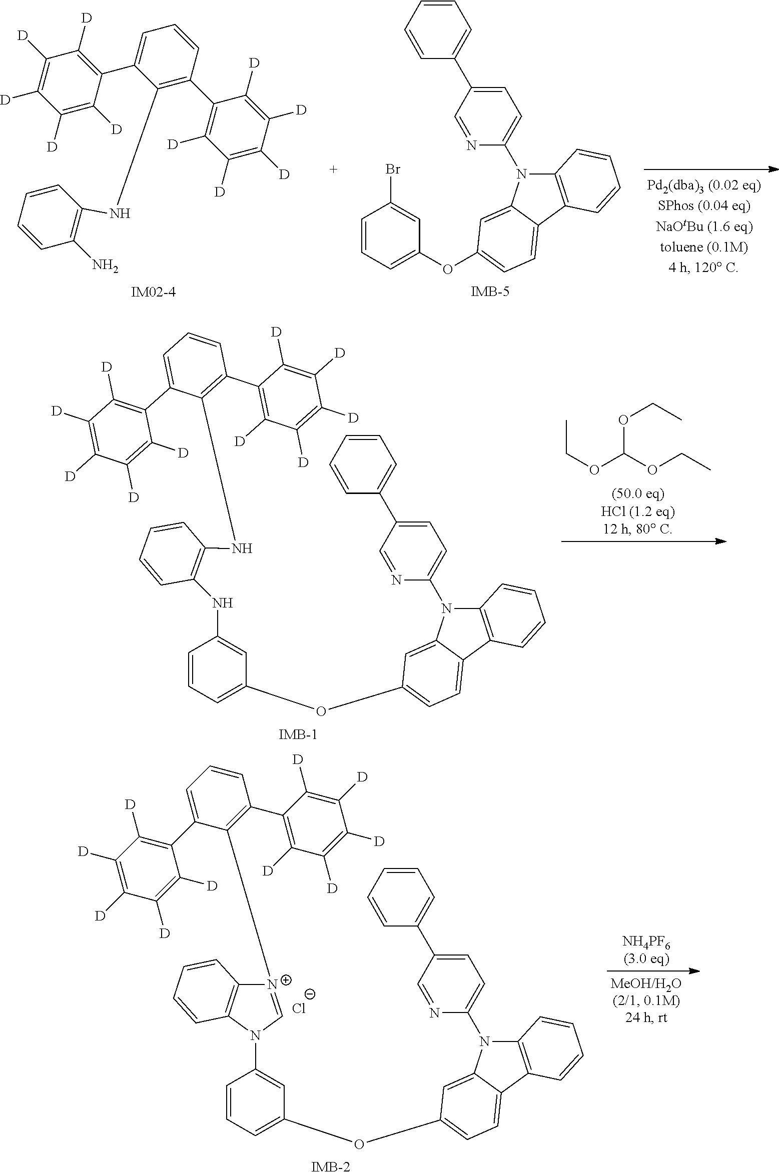

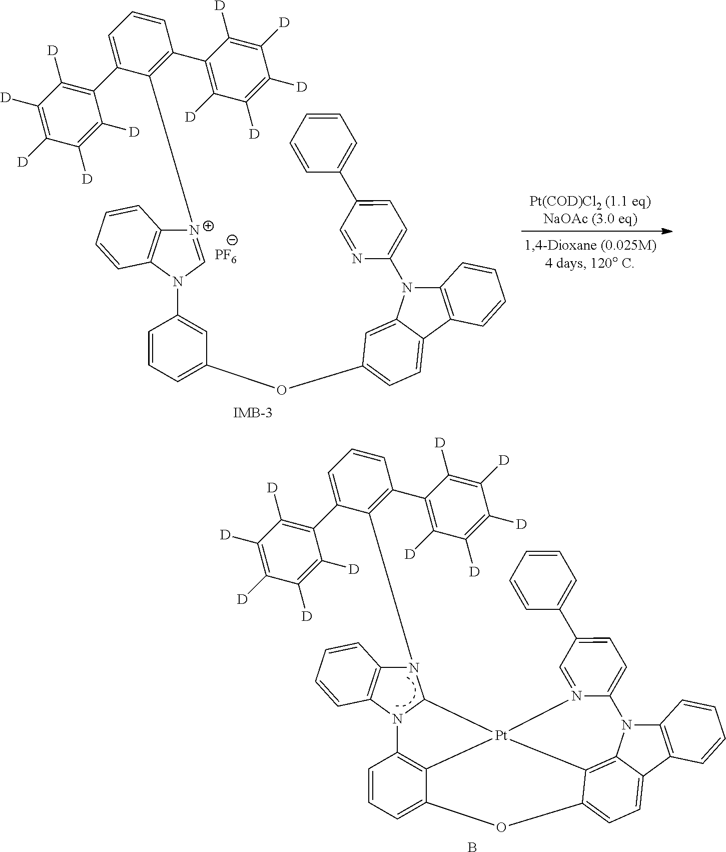

Compound B (2.3 g, 2.4 mmol) was obtained in the yield of 35% in substantially the same manner as in Synthesis Example 1, except that 2-(3-bromophenoxy)-9-(5-phenylpyridin-2-yl)-9H-carbazole (Intermediate IMB-5) (5.6 g, 11.4 mmol), Intermediate IMB-1, Intermediate IMB-2, and Intermediate IMB-3 were sequentially used instead of Intermediate IM02-5, Intermediate IM02-1, Intermediate IM02-2, and Intermediate IM02-3, respectively.

### Comparative Synthesis Example C (Synthesis of Compound C)

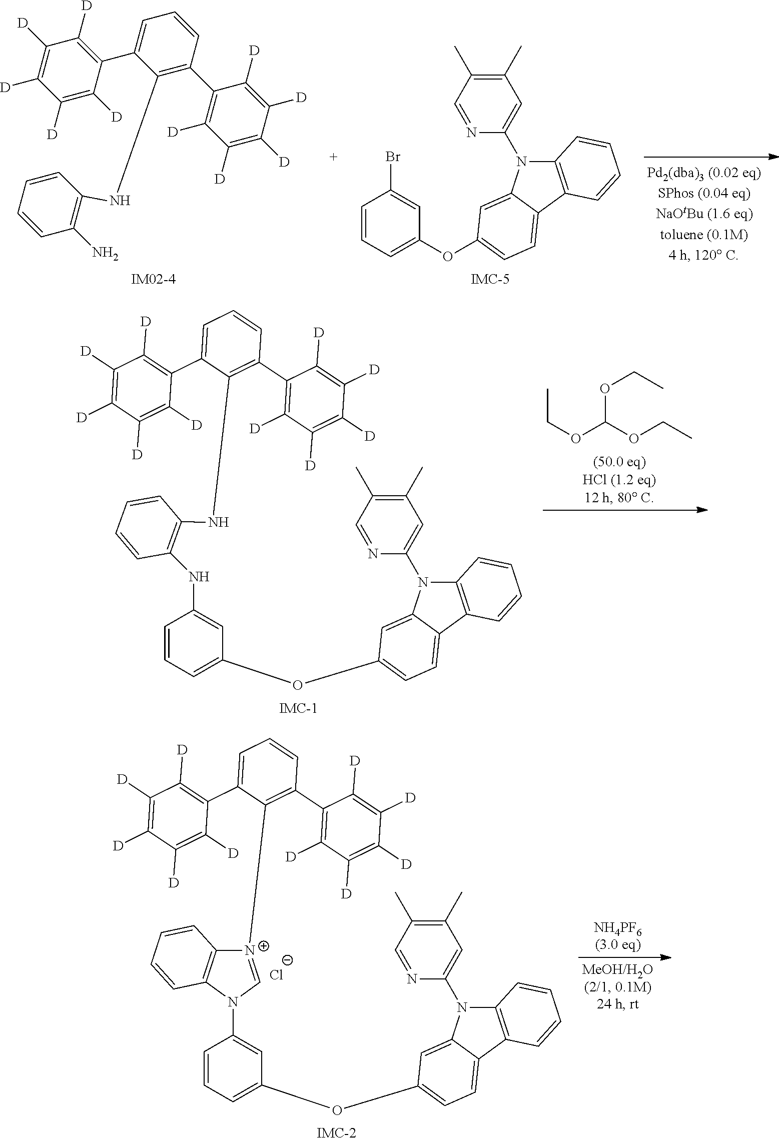

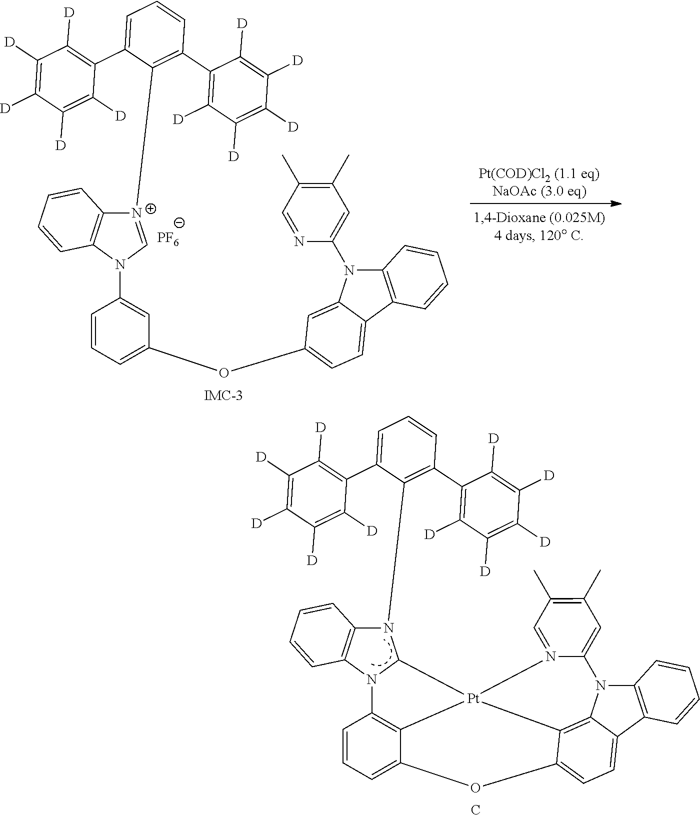

Compound C (1.9 g, 2.1 mmol) was obtained in the yield of 31% in substantially the same manner as in Synthesis Example 1, except that 2-(3-bromophenoxy)-9-(4,5-dimethylpyridin-2-yl)-9H-carbazole (Intermediate IMC-5) (5.1 g, 11.4 mmol), Intermediate IMC-1, Intermediate IMC-2, and Intermediate IMC-3 were sequentially used instead of Intermediate IM02-5, Intermediate IM02-1, Intermediate IM02-2, and Intermediate IM02-3, respectively.

Results of measuring ¹H NMR and high-resolution mass (HR-MS) of compounds synthesized in Synthesis Examples 1 to 12 and Comparative Synthesis Examples A to C were shown in Table 1. Synthesis methods of other compounds in addition to the compounds synthesized in Synthesis Examples 1 to 12 may be easily recognized by those skilled in the art by referring to the synthesis paths and source materials.

TABLE 1

| | | HR-MS (m/z) | |
|---|---|---|---|
| | | [M⁺] | |
| Compound | ¹H NMR (CDCl₃, 500 MHz) | found | calc. |
| BD02 | δ 9.02 (s, 1H), 8.15 (d, ³J_{H-H} = 8.1 Hz, 1H), | 979.35379 | 979.35511 |
| | 8.11 (d, ³J_{H-H} = 7.0 Hz, 1H), 7.97 (d, ³J_{H-H} = | | |
| | 8.3 Hz, 1H), 7.91 (s, 1H), 7.79 (d, ³J_{H-H} = 8.2 | | |
| | Hz, 1H), 7.52-7.37 (m, 4H), 7.33-7.23 (m, 3H), | | |
| | 7.20 (t, ³J_{H-H} = 7.8 Hz, ⁴J_{H-H} = 1.0 Hz, 1H), | | |
| | 7.07 (dd, ³J_{H-H} = 8.2 Hz, ⁴J_{H-H} = 0.9 Hz, 1H), | | |
| | 6.98 (t, ³J_{H-H} = 7.4 Hz, 1H), 6.74 (d, ³J_{H-H} = 7.8 | | |
| | Hz, 1H), 6.72 (dd, ³J_{H-H} = 7.7 Hz, ⁴J_{H-H} = 1.5 | | |
| | Hz, 1H), 2.27 (s, 3H). | | |
| BD04 | δ 9.03 (s, 1H), 8.31 (d, ⁴J_{H-H} = 1.4 Hz, 1H), | 1055.38752 | 1054.37914 |
| | 8.20 (d, ³J_{H-H} = 8.4 Hz, 1H), 7.97 (d, ³J_{H-H} = | | |
| | 8.3 Hz, 1H), 7.93 (s, 1H), 7.84-7.82 (m, 3H), | | |
| | 7.75 (dd, ³J_{H-H} = 8.4 Hz, ⁴J_{H-H} = 1.6 Hz, 1H), | | |
| | 7.54 (t, ³J_{H-H} = 7.5 Hz, 2H), 7.49 (d, ³J_{H-H} = 7.5 | | |
| | Hz, 1H), 7.42-7.38 (m, 2H), 7.35-7.31 (m, 1H), | | |
| | 7.27-7.24 (m, 1H), 7.19 (t, ³J_{H-H} = 7.5 Hz, 2H), | | |
| | 7.08 (d, ³J_{H-H} = 8.1 Hz, 1H), 6.97 (t, ³J_{H-H} = 7.6 | | |
| | Hz, 1H), 6.74 (d, ³J_{H-H} = 8.2 Hz, 1H), 6.72 (d, | | |
| | 3 J_{H-H} = 7.5 Hz, 1H), 2.28 (s, 3H). | | |
| BD23 | δ 9.02 (s, 1H), 8.15 (d, ³J_{H-H} = 8.1 Hz, 1H), | 1030.38623 | 1029.38633 |
| | 8.11 (dd, ³J_{H-H} = 7.6 Hz, ⁴J_{H-H} = 0.6 Hz, 1H), | | |
| | 7.97 (d, ³J_{H-H} = 8.4 Hz, 1H), 7.89 (s, 1H), 7.78 | | |
| | (d, ³J_{H-H} = 8.2 Hz, 1H), 7.52-7.48 (m, 2H), | | |
| | 7.43 (td, ³J_{H-H} = 7.6 Hz, ⁴J_{H-H} = 0.8 Hz, 1H), | | |
| | 7.39 (t, ³J_{H-H} = 7.7 Hz, 1H), 7.32 (d, ³J_{H-H} = 8.2 | | |
| | Hz, 1H), 7.28-7.24 (m, 3H), 7.18 (td, ³J_{H-H} = | | |
| | 8.2 Hz, ⁴J_{H-H} = 1.0 Hz, 1H), 7.07 (td, ³J_{H-H} = | | |
| | 7.6 Hz, ⁴J_{H-H} = 0.8 Hz, 1H), 6.98-6.94 (m, 4H), | | |
| | 6.73 (d, ³J_{H-H} = 8.1 Hz, 1H), 6.62 (dd, ³J_{H-H} = | | |
| | 7.6 Hz, ⁴J_{H-H} = 1.5 Hz, 1H), 2.29 (s, 3H), 1.12 | | |
| | (s, 9H). | | |
| BD58 | δ 9.02 (s, 1H), 8.15 (d, ³J_{H-H} = 8.1 Hz, 1H), | 1033.38733 | 1032.39788 |
| | 8.11 (dd, ³J_{H-H} = 7.6 Hz, ⁴J_{H-H} = 0.6 Hz, 1H), | | |
| | 7.97 (5, ³J_{H-H} = 8.4 Hz, 1H), 7.89 (s, 1H), 7.78 | | |
| | (d, ³J_{H-H} = 8.2 Hz, 1H), 7.52-7.48 (m, 2H), | | |
| | 7.43 (td, ³J_{H-H} = 7.6 Hz, ⁴J_{H-H} = 0.8 Hz, 1H), | | |
| | 7.39 (t, ³J_{H-H} = 7.7 Hz, 1H), 7.32 (d, ³J_{H-H} = 8.2 | | |
| | Hz, 1H), 7.28-7.24 (m, 3H), 7.18 (td, ³J_{H-H} = | | |
| | 8.2 Hz, ⁴J_{H-H} = 1.0 Hz, 1H), 7.07 (td, ³J_{H-H} = | | |
| | 7.6 Hz, ⁴J_{H-H} = 0.8 Hz, 1H), 6.98-6.94 (m, 4H), | | |
| | 6.73 (d, ³J_{H-H} = 8.1 Hz, 1H), 6.62 (dd, ³J_{H-H} = | | |
| | 7.6 Hz, ⁴J_{H-H} = 1.5 Hz, 1H), 1.12 (s, 9H). | | |
| BD71 | δ 8.85 (s, 1H), 8.15 (d, ³J_{H-H} = 7.1 Hz, 1H), | 1016.36847 | 1015.36340 |
| | 8.11 (s, 1H), 8.09 (d, ³J_{H-H} = 8.1 Hz, 1H), 7.94 | | |
| | (d, ³J_{H-H} = 8.3 Hz, 1H), 7.82 (d, ³J_{H-H} = 8.2 Hz, | | |
| | 1H), 7.60 (t, ³J_{H-H} = 7.6 Hz, 1H), 7.56-7.48 (m, | | |
| | 4H), 7.43 (d, ³J_{H-H} = 8.1 Hz, ⁴J_{H-H} = 0.7 Hz, | | |
| | 2H), 7.37-7.33 (m, 3H), 7.32 (m, 2H), 7.22 (t, | | |
| | 3 J_{H-H} = 8.0 Hz, 1H), 7.18 (td, ³J_{H-H} = 7.8 Hz, | | |
| | ⁴J_{H-H} = 1.0 Hz, 1H), 7.04 (dd, ³J_{H-H} = 8.1 Hz, | | |
| | 4 J_{H-H} = 0.8 Hz, 1H), 6.97 (td, ³J_{H-H} = 7.6 Hz, | | |
| | 4 J_{H-H} = 0.6 Hz, 1H), 6.76 (d, ³J_{H-H} = 8.0 Hz, | | |
| | 1H), 1.10 (s, 9H). | | |
| BD72 | δ 8.85 (s, 1H), 8.15 (d, ³J_{H-H} = 7.1 Hz, 1H), | 1021.40159 | 1021.40206 |
| | 8.11 (s, 1H), 8.09 (d, ³J_{H-H} = 8.1 Hz, 1H), 7.94 | | |
| | (d, ³J_{H-H} = 8.3 Hz, 1H), 7.82 (d, ³J_{H-H} = 8.2 Hz, | | |
| | 1H), 7.60 (t, ³J_{H-H} = 7.6 Hz, 1H), 7.56-7.51 (m, | | |
| | 2H), 7.43 (d, ³J_{H-H} = 8.1 Hz, ⁴J_{H-H} = 0.7 Hz, | | |
| | 2H), 7.37 (dd, ³J_{H-H} = 7.5 Hz, ⁴J_{H-H} = 1.7 Hz, | | |
| | 1H), 7.32 (d, ³J_{H-H} = 7.1 Hz, 1H), 7.22 (t, ³J_{H-H} = | | |
| | 8.0 Hz, 1H), 7.18 (td, ³J_{H-H} = 7.8 Hz, ⁴J_{H-H} = | | |
| | 1.0 Hz, 1H), 7.04 (dd, ³J_{H-H} = 8.1 Hz, ⁴J_{H-H} = | | |
| | 0.8 Hz, 1H), 6.97 (td, ³J_{H-H} = 7.6 Hz, ⁴J_{H-H} = | | |
| | 0.6 Hz, 1H), 6.76 (d, ³J_{H-H} = 8.0 Hz, 1H), 1.10 | | |
| | (s, 9H). | | |
| BD323 | δ 8.05 (d, ³J_{H-H} = 7.5 Hz, 1H), 7.96 (d, ³J_{H-H} = | 1090.47312 | 1090.47194 |
| | 8.3 Hz, 1H), 7.85-7.83 (m, 2H), 7.77 (d, ³J_{H-H} = | | |
| | 8.2 Hz, 1H), 7.53 (t, ³J_{H-H} = 7.2 Hz, 1H), | | |
| | 7.47-7.46 (m, 1H), 7.40-7.37 (m, 1H), 7.34- | | |
| | 7.33 (m, 1H), 7.31 (d, ³J_{H-H} = 8.2 Hz, 1H), | | |
| | 7.24-7.18 (m, 1H), 7.13 (t, ³J_{H-H} = 7.6 Hz, 1H), | | |
| | 7.06-6.93 (m, 2H), 6.81 (t, ³J_{H-H} = 7.5 Hz, 1H), | | |
| | 6.76 (s, 1H), 6.73 (d, ³J_{H-H} = 8.1 Hz, 1H), 6.49 | | |
| | (s (br), 2H), 1.27 (s, 18H). | | |
| BD325 | δ 8.04 (d, ³J_{H-H} = 7.6 Hz, 1H), 7.93 (d, ³J_{H-H} = | 1122.52968 | 1122.52835 |
| | 8.3 Hz, 1H), 7.86-7.83 (m, 2H), 7.77 (d, ³J_{H-H} = | | |
| | 8.2 Hz, 1H), 7.53 (t, ³J_{H-H} = 7.2 Hz, 1H), | | |
| | 7.47-7.46 (m, 1H), 7.40-7.37 (m, 1H), 7.34- | | |
| | 7.33 (m, 1H), 7.29 (d, ³J_{H-H} = 8.2 Hz, 1H), | | |
| | 7.23-7.17 (m, 1H), 7.10 (t, ³J_{H-H} = 7.6 Hz, 1H), | | |
| | 7.05-6.96 (m, 2H), 6.82 (t, ³J_{H-H} = 7.5 Hz, 1H), | | |
| | 6.76 (s, 1H), 6.73 (d, ³J_{H-H} = 8.1 Hz, 1H), 6.43 | | |
| | (s (br), 2H), 1.26 (s, 18H). | | |
| BD327 | δ 8.05 (d, ³J_{H-H} = 7.6 Hz, 1H), 7.91 (d, ³J_{H-H} = | 1136.54515 | 1136.54400 |
| | 8.3 Hz, 1H), 7.88-7.81 (m, 2H), 7.78 (d, ³J_{H-H} = | | |
| | 8.2 Hz, 1H), 7.54 (t, ³J_{H-H} = 7.2 Hz, 1H), | | |
| | 7.49-7.46 (m, 1H), 7.40-7.37 (m, 1H), 7.36- | | |
| | 7.34 (m, 1H), 7.25 (d, ³J_{H-H} = 8.2 Hz, 1H), | | |
| | 7.23-7.17 (m, 1H), 7.11 (t, ³J_{H-H} = 7.6 Hz, 1H), | | |
| | 7.06-6.96 (m, 2H), 6.82 (t, ³J_{H-H} = 7.5 Hz, 1H), | | |
| | 6.76 (s, 1H), 6.73 (d, ³J_{H-H} = 8.1 Hz, 1H), 6.43 | | |
| | (s (br), 2H), 2.49 (d, ³J_{H-H} = 0.7 Hz, 2H), 1.25 | | |
| | (s, 18H). | | |
| BD329 | δ 8.05 (d, ³J_{H-H} = 7.5 Hz, 1H), 7.95 (d, ³J_{H-H} = | 1146.53467 | 1146.53454 |
| | 8.3 Hz, 1H), 7.89 (t, ³J_{H-H} = 8.5 Hz, 1H), 7.77 | | |
| | (d, ³J_{H-H} = 8.2 Hz, 1H), 7.53 (t, ³J_{H-H} = 7.2 Hz, | | |
| | 1H), 7.47-7.43 (m, 1H), 7.40-7.37 (m, 1H), | | |
| | 7.34-7.33 (m, 1H), 7.31 (d, ³J_{H-H} = 8.2 Hz, | | |
| | 1H), 7.24-7.18 (m, 1H), 7.13 (t, ³J_{H-H} = 7.6 Hz, | | |
| | 1H), 7.05-6.93 (m, 2H), 6.81 (t, ³J_{H-H} = 7.5 Hz, | | |
| | 1H), 6.76 (s, 1H), 6.73 (d, ³J_{H-H} = 8.1 Hz, 1H), | | |
| | 6.49 (s (br), 2H), 1.47 (s, 9H), 1.06 (s, 9H), | | |
| | 0.34 (s, 9H). | | |
| BD331 | δ 8.04 (d, ³J_{H-H} = 7.5 Hz, 1H), 7.96 (d, ³J_{H-H} = | 1178.59216 | 1178.59095 |
| | 8.3 Hz, 1H), 7.90 (t, ³J_{H-H} = 8.5 Hz, 1H), 7.77 | | |
| | (d, ³J_{H-H} = 8.2 Hz, 1H), 7.53 (t, ³J_{H-H} = 7.2 Hz, | | |
| | 1H), 7.48-7.43 (m, 1H), 7.40-7.37 (m, 1H), | | |
| | 7.35-7.33 (m, 1H), 7.32 (d, ³J_{H-H} = 8.2 Hz, | | |
| | 1H), 7.25-7.19 (m, 1H), 7.12 (t, ³J_{H-H} = 7.6 Hz, | | |
| | 1H), 7.04-6.92 (m, 2H), 6.80 (t, ³J_{H-H} = 7.5 Hz, | | |
| | 1H), 6.78 (s, 1H), 6.74 (d, ³J_{H-H} = 8.1 Hz, 1H), | | |
| | 6.48 (s (br), 2H), 1.47 (s, 9H), 1.06 (s, 9H), | | |
| | 0.34 (s, 9H). | | |
| BD333 | δ 8.06 (d, ³J_{H-H} = 7.5 Hz, 1H), 7.94 (d, ³J_{H-H} = | 1192.60701 | 1192.60660 |
| | 8.3 Hz, 1H), 7.90 (t, ³J_{H-H} = 8.5 Hz, 1H), 7.77 | | |
| | (d, ³J_{H-H} = 8.2 Hz, 1H), 7.53 (t, ³J_{H-H} = 7.2 Hz, | | |
| | 1H), 7.47-7.43 (m, 1H), 7.40-7.37 (m, 1H), | | |
| | 7.37-7.36 (m, 1H), 7.30 (d, ³J_{H-H} = 8.2 Hz, | | |
| | 1H), 7.24-7.18 (m, 1H), 7.13 (t, ³J_{H-H} = 7.6 Hz, | | |
| | 1H), 7.05-6.93 (m, 2H), 6.81 (t, ³J_{H-H} = 7.5 Hz, | | |
| | 1H), 6.77 (s, 1H), 6.72 (d, ³J_{H-H} = 8.1 Hz, 1H), | | |
| | 6.49 (s (br), 2H), 2.50 (d, ³J_{H-H} = 0.7 Hz, 2H), | | |
| | 1.47 (s, 9H), 1.06 (s, 9H), 0.34 (s, 9H). | | |
| A | δ 9.00 (d, ³J_{H-H} = 5.9 Hz, 1H), 8.09-8.08 (m, | 939.33591 | 939.33210 |
| | 3H), 7.99 (d, ³J_{H-H} = 8.2 Hz, 1H), 7.76 (d, ³J_{H-H} = | | |
| | 5.9 Hz, 1H), 7.52-7.48 (m, 3H), 7.42 (t, ³J_{H-H} = | | |
| | 7.1 Hz, 1H), 7.32 (d, ³J_{H-H} = 8.6 Hz, 1H), | | |
| | 7.26-7.23 (m, 4H), 7.07 (d, ³J_{H-H} = 8.8 Hz, | | |
| | 1H), 7.04 (d, ³J_{H-H} = 7.1 Hz, 1H), 6.87 (d, ³J_{H-H} = | | |
| | 8.1 Hz, 1H), 6.19 (d, ³J_{H-H} = 6.2 Hz, 1H), | | |
| | 1.29 (s, 9H). | | |
| B | δ 9.01 (s, 1H), 8.04-8.00 (m, 3H), 7.98 (d, ³J_{H-H} = | 959.30066 | 959.30025 |
| | 8.2 Hz, 1H), 7.76 (d, ³J_{H-H} = 5.9 Hz, 1H), | | |
| | 7.52-7.48 (m, 5H), 7.41-7.32 (m, 3H), 7.26- | | |
| | 7.23 (m, 6H), 7.07 (d, ³J_{H-H} = 8.8 Hz, 1H), | | |
| | 7.04 (d, ³J_{H-H} = 7.1 Hz, 1H), 6.87 (d, ³J_{H-H} = | | |
| | 8.1 Hz, 1H), 6.19 (d, ³J_{H-H} = 6.2 Hz, 1H). | | |
| C | δ 8.7 (d, ³J_{H-H} = 6.0 Hz, 1H), 8.07-8.05 (m, | 910.30478 | 910.30080 |
| | 2H), 7.98 (d, ³J_{H-H} = 8.2 Hz, 1H), 7.76 (d, ³J_{H-H} = | | |
| | 5.9 Hz, 1H), 7.75 (s, 1H) 7.51-7.48 (m, 2H), | | |
| | 7.40 (t, ³J_{H-H} = 7.1 Hz, 1H), 7.33 (d, ³J_{H-H} = 8.6 | | |
| | Hz, 1H), 7.26-7.23 (m, 4H), 7.08 (d, ³J_{H-H} = | | |
| | 8.8 Hz, 1H), 7.04 (d, ³J_{H-H} = 7.1 Hz, 1H), 6.86 | | |
| | (d, ³J_{H-H} = 8.1 Hz, 1H), 6.19 (d, ³J_{H-H} = 6.2 Hz, | | |
| | 1H), 2.40 (s, 3H), 2.37 (s, 3H). | | |

### Evaluation Example 1

HOMO and LUMO energy levels of each of Compounds BD02, BD04, BD23, BD58, BD71, BD72, BD323, BD325, BD327, BD329, BD331, BD333, A, B, and C were evaluated according to methods in Table 2, and results are shown in Table 3.

TABLE 2

| | |
|---|---|
| HOMO energy | By using cyclic voltammetry (CV) (electrolyte: 0.1M |
| level evaluation | Bu₄NPF₆/solvent: dimethylforamide (DMF)/electrode: |
| method | 3-electrode system (working electrode: GC, reference |
| | electrode: Ag/AgCl, and auxiliary electrode: Pt)), the |
| | potential (V)-current (A) graph of each compound was |
| | obtained, and then, from the oxidation onset of the |
| | graph, the hOMO energy level of each compound was |
| | calculated. |
| LUMO energy | By using cyclic voltammetry (CV) (electrolyte: 0.1M |
| level evaluation | Bu₄NPF₆/solvent: dimethylforamide (DMF)/electrode: |
| method | 3-electrode system (working electrode: GC, reference |
| | electrode: Ag/AgCl, and auxiliary electrode: Pt)), the |
| | potential (V)-current (A) graph of each compound was |
| | obtained, and then, from the reduction onset of the |
| | graph, the LUMO energy level of each compound was |
| | calculated. |

TABLE 3

| Compound No. | HOMO (eV) | LUMO (eV) |
|---|---|---|
| BD02 | −5.28 | −2.12 |
| BD04 | −5.29 | −2.13 |
| BD23 | −5.28 | −1.97 |
| BD58 | −5.28 | −1.97 |
| BD71 | −5.29 | −2.06 |
| BD72 | −5.29 | −2.06 |
| BD323 | −5.29 | −1.96 |
| BD325 | −5.30 | −2.11 |
| BD327 | −5.29 | −2.14 |
| BD329 | −5.28 | −1.93 |
| BD331 | −5.30 | −2.11 |
| BD333 | −5.29 | −2.13 |
| A | −5.28 | −2.11 |
| B | −5.30 | −2.15 |
| C | −5.29 | −2.08 |

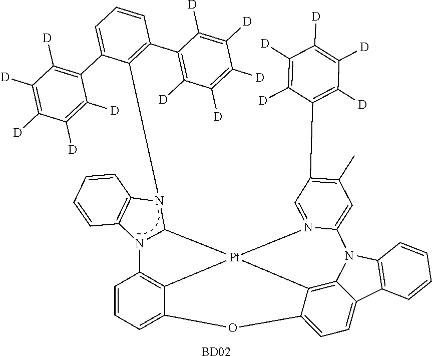

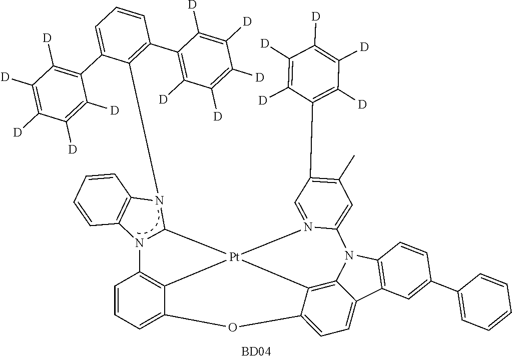

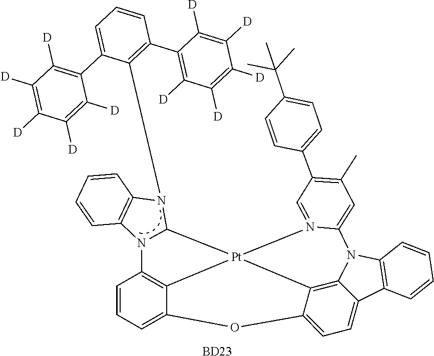

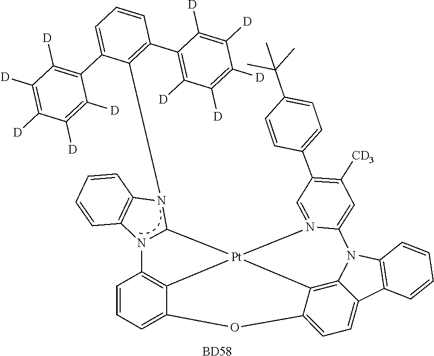

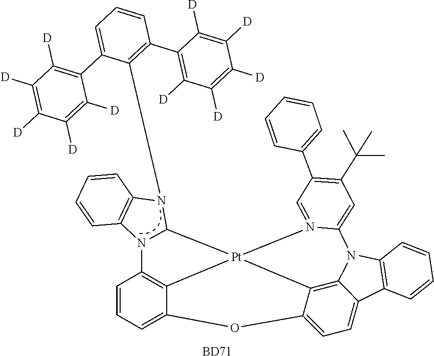

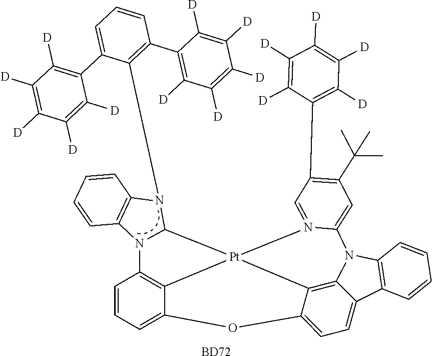

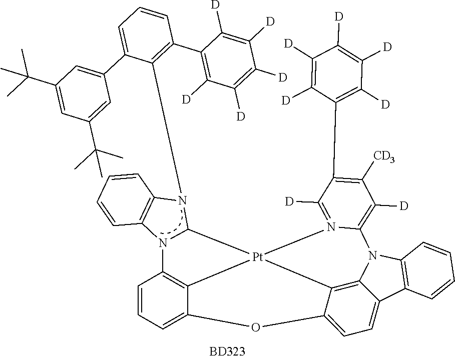

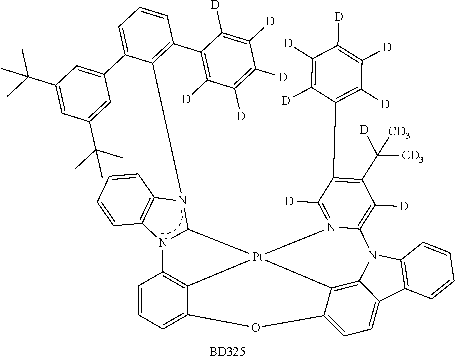

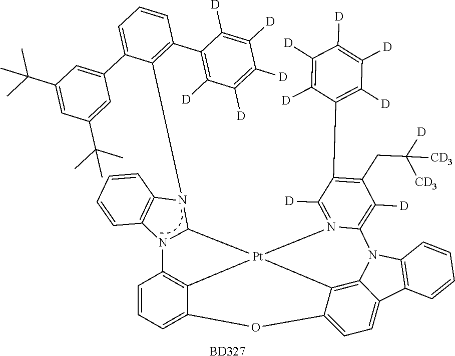

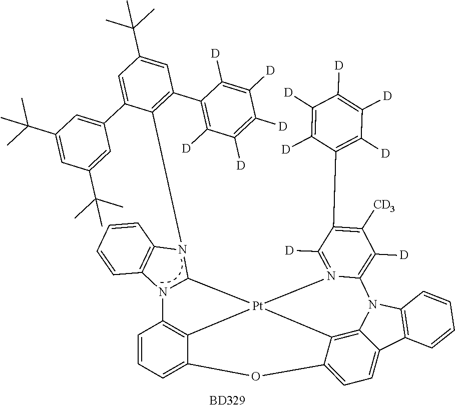

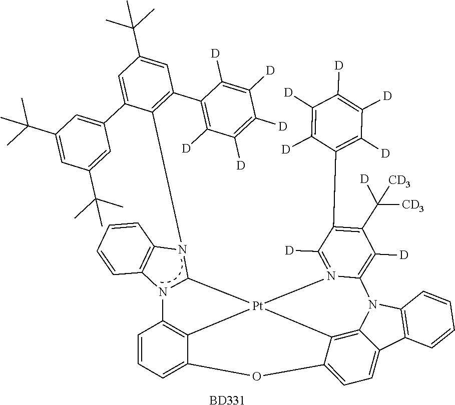

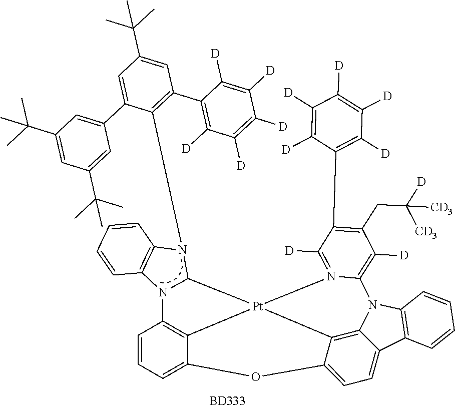

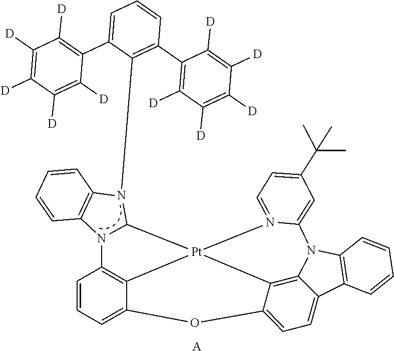

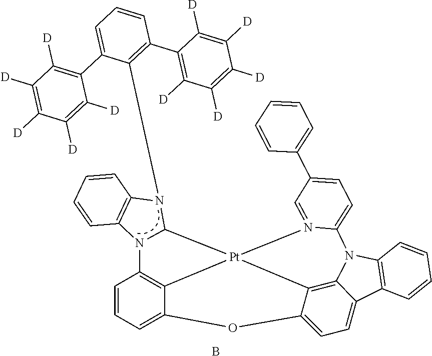

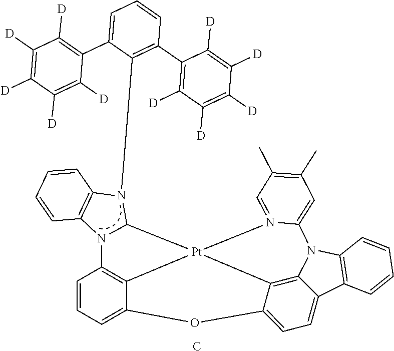

### Evaluation Example 2

After PMMA in CH₂Cl₂ solution and Compound BD02 (4 wt % in PMMA) were mixed, the result obtained therefrom was coated on a quartz substrate by using a spin coater and then heat-treated in an oven at 80° C., followed by cooling to room temperature, thereby manufacturing Film BD02 having a thickness of 40 nm. Next, Films BD04, BD23, BD58, BD71, BD72, BD323, BD325, BD327, BD329, BD331, BD333, A, B, and C were manufactured in substantially the same manner as used to obtain Film BD02, except that each of Compounds BD04, BD23, BD58, BD71, BD72, BD323, BD325, BD327, BD329, BD331, BD333, A, B, and C were used instead of Compound BD02.

A photoluminescence (PL) spectrum of each of Films BD02, BD04, BD23, BD58, BD71, BD72, BD323, BD325, BD327, BD329, BD331, BD333, A, B, and C were measured by using a quantaurus-QY absolute PL quantum yield spectrometer (on which a xenon light source, a monochromator, a photonic multichannel analyzer, and an integrating sphere were mounted and which includes photoluminescence quantum yield (PLQY) measurement software (Hamamatsu Photonics, Ltd., Shizuoka)) manufactured by Hamamatsu Inc. During the measurement, an excitation wavelength was scanned from 320 nm to 380 nm at intervals of 10 nm, and a spectrum measured at the excitation wavelength of 340 nm was taken to obtain a maximum emission wavelength (emission peak wavelength) and emission FWHM of an organometallic compound included in each film, which were shown in Table 4 below.

Next, a photoluminescence quantum yield (PLQY) of each of Films BD02, BD04, BD23, BD58, BD71, BD72, BD323, BD325, BD327, BD329, BD331, BD333, A, B, and C were measured by scanning an excitation wavelength from 320 nm to 380 nm at intervals of 10 nm by using the quantaurus-QY absolute PL quantum yield spectrometer manufactured by Hamamatsu Inc., and then the PLQY measured at the excitation wavelength of 340 nm was taken to obtain a PLQY of the organometallic compound included in each film, which were shown in Table 4.

TABLE 4

| | Organometallic | Maximum | | |
|---|---|---|---|---|
| | compound included | emission | Emission | |
| | in film | wavelength | FWHM | PLQY |
| Film no. | (4 wt % in PMMA) | (nm) | (nm) | (%) |
| BD02 | BD02 | 455 | 21 | 91 |
| BD04 | BD04 | 457 | 21 | 95 |
| BD23 | BD23 | 455 | 21 | 93 |
| BD58 | BD58 | 455 | 21 | 96 |
| BD71 | BD71 | 456 | 21 | 90 |
| BD72 | BD72 | 456 | 21 | 91 |
| BD323 | BD323 | 455 | 20 | 93 |
| BD325 | BD325 | 456 | 20 | 96 |
| BD327 | BD327 | 456 | 20 | 97 |
| BD329 | BD329 | 455 | 20 | 96 |
| BD331 | BD331 | 456 | 20 | 97 |
| BD333 | BD333 | 456 | 20 | 97 |
| A | A | 456 | 41 | 90 |
| B | B | 458 | 48 | 82 |
| C | C | 456 | 43 | 87 |

From Table 4, it can be seen that Compounds BD02, BD04, BD23, BD58, BD71, BD72, BD323, BD325, BD327, BD329, BD331, and BD333 had equal or excellent PLQY and emitted blue light having relatively smaller emission FWHM as compared to those of Compounds A to C.

### Evaluation Example 3

Compound BD02, Compound ETH2, and Compound HTH29 were vacuum-codeposited on a quartz substrate at a vacuum degree of 10⁻⁷ torr to prepare Film 1 having a thickness of 40 nm. Here, an amount of each compound was adjusted so that a weight ratio of Compound ETH2 to Compound HTH29 was 3:7, and an amount of Compound BD02 was 10 parts by weight based on 100 parts by weight of a film. Next, Films 2 to 12, A1, B1, and C1 were manufactured in substantially the same manner as used to obtain Film 1, except that each of Compounds BD04, BD23, BD58, BD71, BD72, BD323, BD325, BD327, BD329, BD331, BD333, A, B, and C was used instead of Compound BD02.

A PL spectrum of each of Films 1 to 12, A1, B1, and C1 was measured at room temperature by using FluoTime 300, which is a TRPL measurement system manufactured by PicoQuant Inc. and PLS340 (excitation wavelength=340 nm, spectral width=20 nm), which is a pumping source of PicoQuant Inc. Then, the wavelength of the main peak of each spectrum was identified, and the number of photons emitted at the wavelength of the main peak from each of Films 1 to 12, A1, B1, and C1 by photon pulse (pulse width=500 picoseconds) applied by PLS340 to each of Films 1 to 12, A1, B1, and C1 was repeatedly measured based on time-correlated single photon counting (TCSPC) according to time, thereby obtaining a TRPL curve sufficient for fitting. One or more exponential decay functions were fitted to the result obtained therefrom, thereby obtaining T_{decay}(Ex), that is, decay time, of each of Films 1 to 12, A1, B1, and C1, and results thereof are shown in Table 5. A function used for fitting is as shown in Equation 20, and from among T_{decay} values obtained from each exponential decay function used for fitting, the largest T_{decay} was obtained as T_{decay} (Ex). In this regard, the same measurement was performed during the same measurement time as that for obtaining TRPL curve in the dark state (in which pumping signals entering each of the films are blocked) to obtain a baseline or a background signal curve for use as a baseline for fitting.

$$f ( t ) = {\sum }_{i = 1}^{n} {A}_{i} exp ( - t / {T}_{decay , i} ) \qquad Equation 20$$

TABLE 5

| Film no. | Organometallic compound included in film | T (μS) |
|---|---|---|
| 1 | BD02 | 2.42 |
| 2 | BD04 | 2.64 |
| 3 | BD23 | 2.87 |
| 4 | BD58 | 2.64 |
| 5 | BD71 | 2.68 |
| 6 | BD72 | 2.67 |
| 7 | BD323 | 2.61 |
| 8 | BD325 | 2.66 |
| 9 | BD327 | 2.62 |
| 10 | BD329 | 2.63 |
| 11 | BD331 | 2.62 |
| 12 | BD333 | 2.61 |
| A1 | A | 2.40 |
| B1 | B | 2.13 |
| C1 | C | 2.42 |

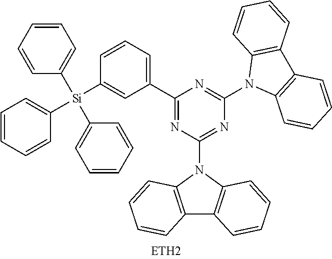 [SMILES: c1ccc([Si](c2ccccc2)(c2ccccc2)c2cccc(-c3nc(-n4c5ccccc5c5ccccc54)nc(-n4c5ccccc5c5ccccc54)n3)c2)cc1]

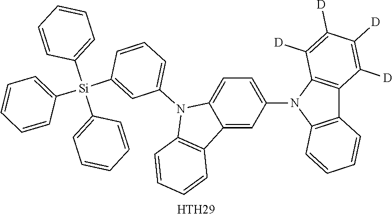

From Table 5, it can be seen that Compounds BD04, BD23, BD58, BD71, BD72, BD323, BD325, BD327, BD329, BD331, and BD333 had longer decay time (that is, higher radiative decay rate (Kr)) as compared to that of Compounds A to C.

### Evaluation Example 4

TS_{M(migration)} energy (kcal/mol) that is energy barrier for ligand migration of each of Compounds BD23, BD58, BD323, BD325, BD327, BD329, BD331, BD333, A, B, and C was calculated (using a density functional theory (DFT) method of the Gaussian program (with the structure optimization at the level of M06/6-311g**/LAN2DZ, that is, using the Gaussian program from Gaussian, Inc. with an M06 functional and a 6-311g** and LAN2DZ mixed basis set) based on the lowest excitation triplet (T₁) energy of each compound, and results are shown in Table 6.

TABLE 6

| | TS_{M(migration)} energy |
|---|---|
| Compound No. | (kcal/mol) |
| BD23 | 30.57 |
| BD58 | 29.10 |
| BD323 | 29.83 |
| BD325 | 29.36 |
| BD327 | 29.67 |
| BD329 | 29.32 |
| BD331 | 29.48 |
| BD333 | 29.11 |
| A | 27.14 |
| B | 20.74 |
| C | 20.04 |

From Table 6, it can be seen that each of Compounds BD23, BD58, BD323, BD325, BD327, BD329, BD331, and BD333 had higher TS_{M(migration)} energy than that of each of Compounds A, B, and C.

### Evaluation Example 5

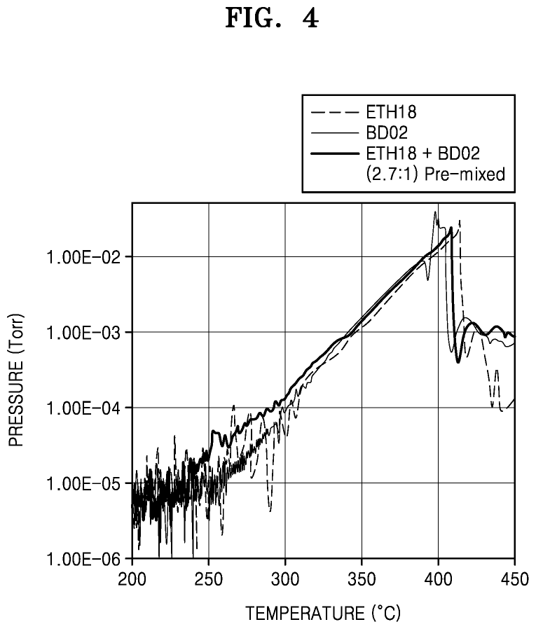

A phase transition diagram (see FIG. 4) of each of i) Compound ETH18, ii) Compound BD02, and iii) a mixture in which Compound ETH18 and Compound BD02 were mixed together at a weight ratio of 2.7:1 was evaluated using the SETSYS evolution TG-DTA device manufactured by Setaram, and a phase transition temperature (at 3.5×10⁻³ torr) of each of i) Compound ETH18, ii) Compound BD02, and iii) the mixture in which Compound ETH18 and Compound BD02 were mixed together at a weight ratio of 2.7:1 was evaluated and shown in Table 7.

TABLE 7

| | Phase transition temperature |
|---|---|
| | (Tp, at 3.5 × 10⁻³ torr) |
| | (° C.) |
| Compound ETH18 | 372.7 |
| Compound BD02 | 368.4 |
| Mixture in which Compound ETH18 and | 368.6 |
| Compound BD02 were mixed together at a | |
| weight ratio of 2.7:1 | |

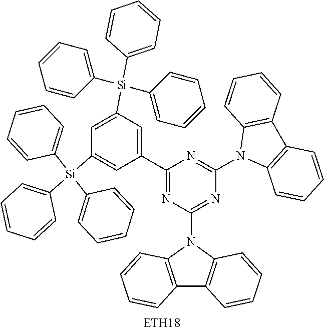 [SMILES: c1ccc([Si](c2ccccc2)(c2ccccc2)c2cc(-c3nc(-n4c5ccccc5c5ccccc54)nc(-n4c5ccccc5c5ccccc54)n3)cc([Si](c3ccccc3)(c3ccccc3)c3ccccc3)c2)cc1]

From Table 7, an absolute value of a difference between phase transition temperatures of Compound ETH18 and Compound BD02 was 4.3° C., and thus, Compound ETH18 and Compound BD02 in the mixture in which Compound ETH18 and Compound BD02 were mixed together at a weight ratio of 2.7:1 may be expected to vaporize at substantially the same temperature.

### Example 1

As an anode, a glass substrate with a 15 Ω/cm² (1,200 Å) ITO formed thereon (available from Corning Co., Ltd) was cut to a size of 50 mm×50 mm×0.7 mm, sonicated by using isopropyl alcohol and pure water for 5 minutes in each solvent, washed by irradiation of ultraviolet rays and exposure of ozone thereto for 30 minutes, and was mounted on a vacuum deposition apparatus.

2-TNATA was vacuum-deposited on the anode to form a hole injection layer having a thickness of 600 Å, and 4,4′-bis[N-(1-naphthyl)-N-phenylamino]biphenyl (hereinafter, referred as “NPB”) was vacuum-deposited on the hole injection layer to form a hole transport layer having a thickness of 300 Å.

Compound BD02 (organometallic compound represented by Formula 1), Compound ETH2 (second compound), and Compound HTH29 (third compound) were vacuum-deposited on the hole transport layer to form an emission layer having a thickness of 350 Å. Here, an amount of Compound BD02 was 13 wt % based on the total weight (100 wt %) of the emission layer, and a weight ratio of Compound ETH2 to Compound HTH29 was adjusted to 3.5:6.5.

Compound ETH34 was vacuum-deposited on the emission layer to form a hole blocking layer having a thickness of 50 Å, and ET46 and Liq were vacuum-deposited on the hole blocking layer at a weight ratio of 4:6 to form an electron transport layer having a thickness of 310 Å. Next, Yb was vacuum-deposited on the electron transport layer to form an electron injection layer having a thickness of 15 A, and then Mg was vacuum-deposited thereon to form a cathode having a thickness of 800 Å, thereby completing manufacture of an organic light-emitting device.

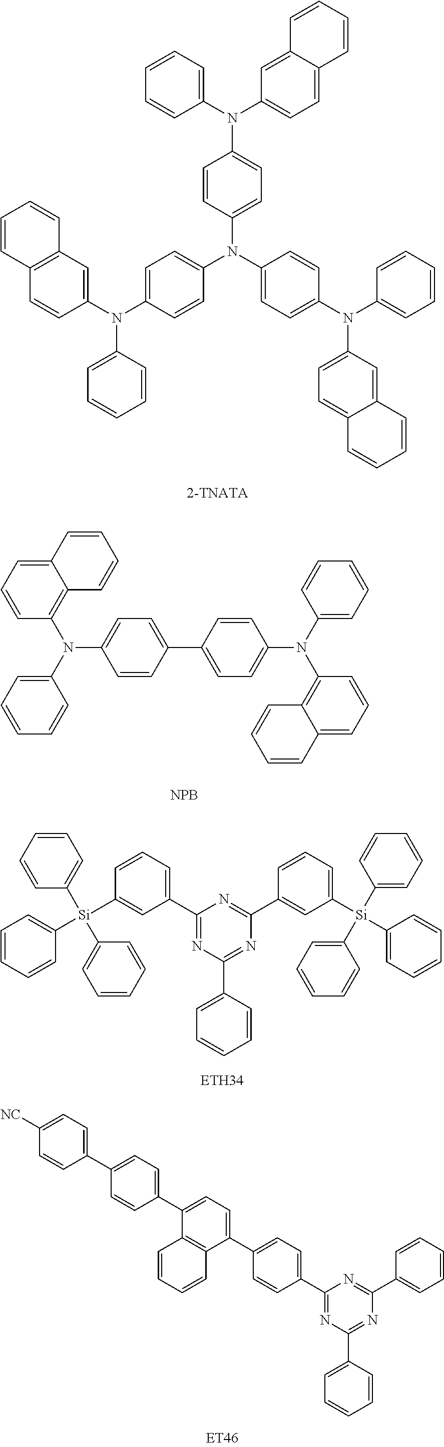 [SMILES: c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1 ; c1ccc(N(c2ccc(-c3ccc(N(c4ccccc4)c4cccc5ccccc45)cc3)cc2)c2cccc3ccccc23)cc1 ; "NPB" ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; N#Cc1ccc(-c2ccc(-c3ccc(-c4ccc(-c5nc(-c6ccccc6)nc(-c6ccccc6)n5)cc4)c4ccccc34)cc2)cc1]

### Examples 2 to 13 and Comparative Examples A to C

Organic light-emitting devices were manufactured in substantially the same manner as in Example 1, except that, in forming the emission layer, compounds shown in Table 8 were used as the organometallic compound represented by Formula 1, the second compound, the third compound, and/or the fourth compound.

### Evaluation Example 6

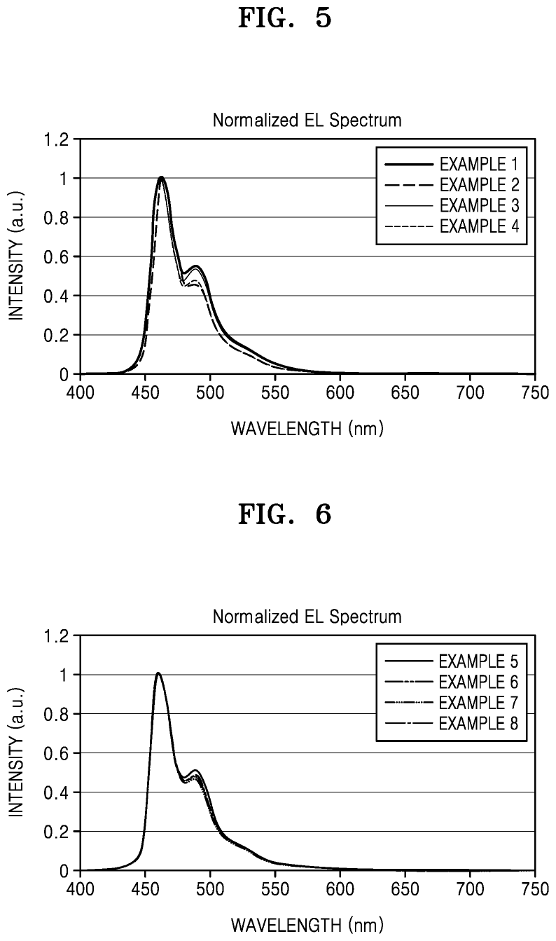

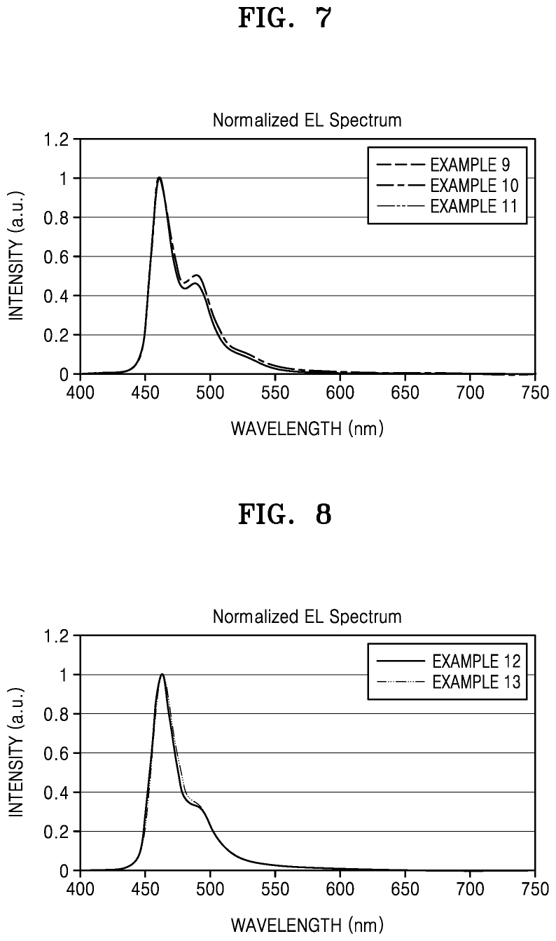

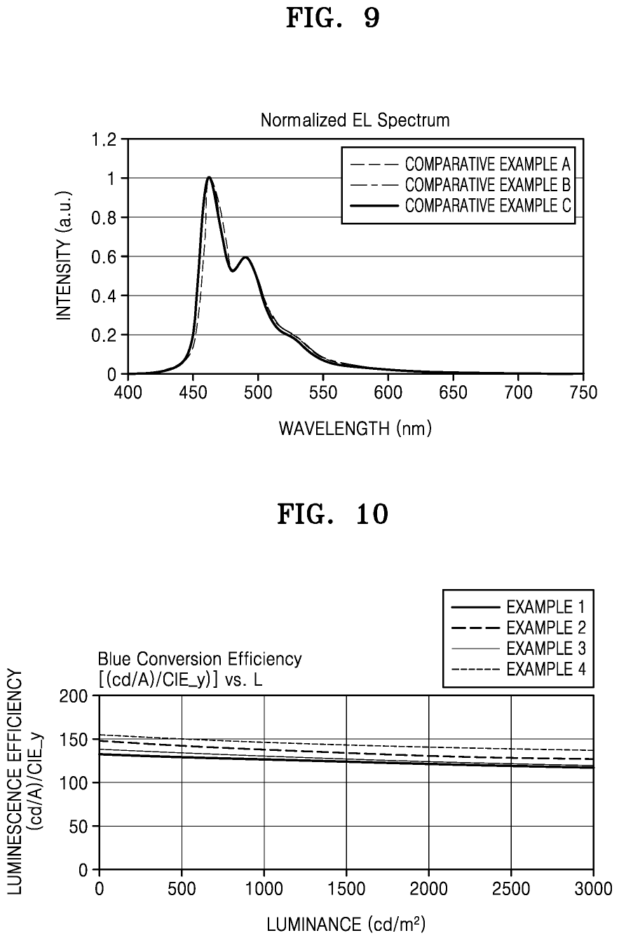

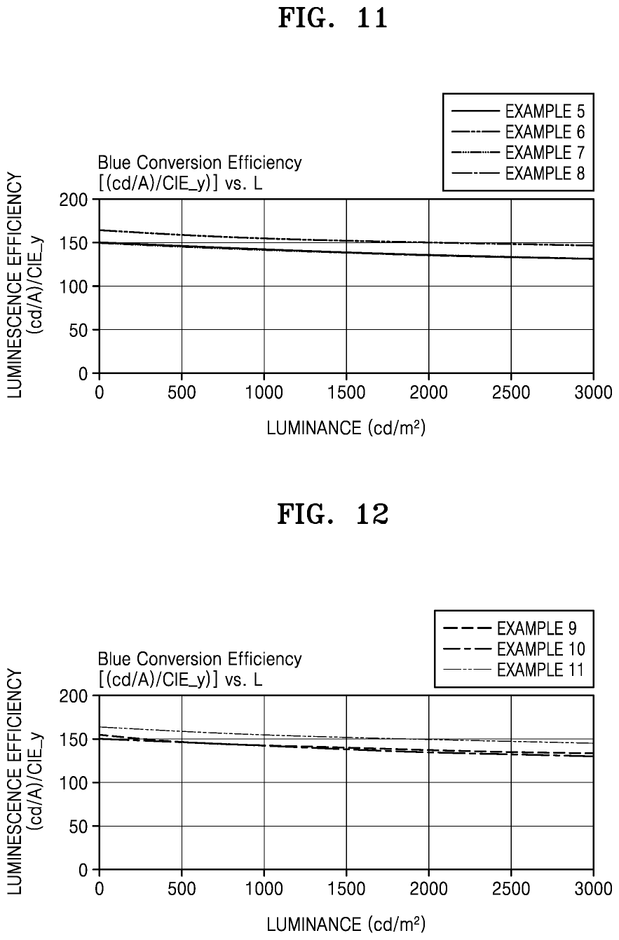

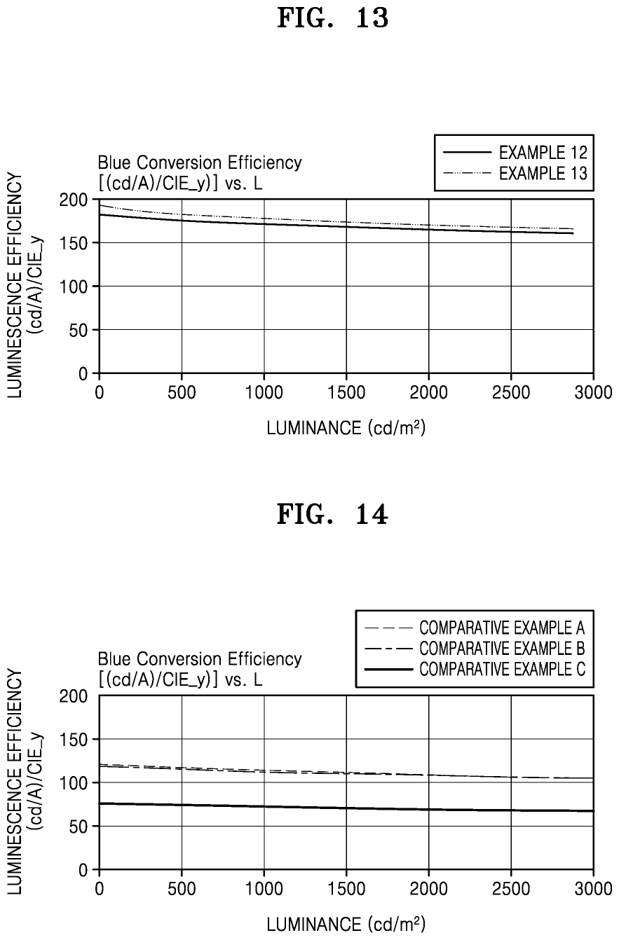

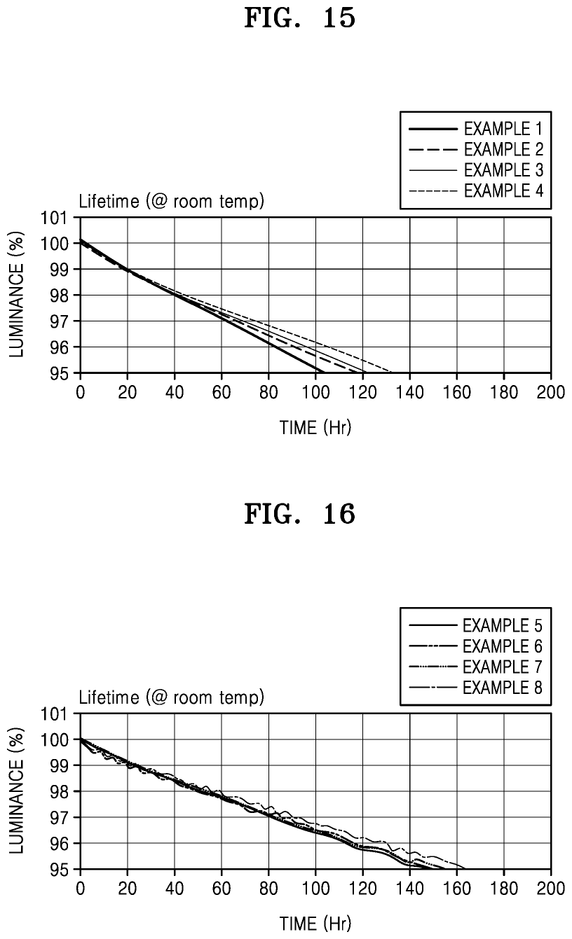

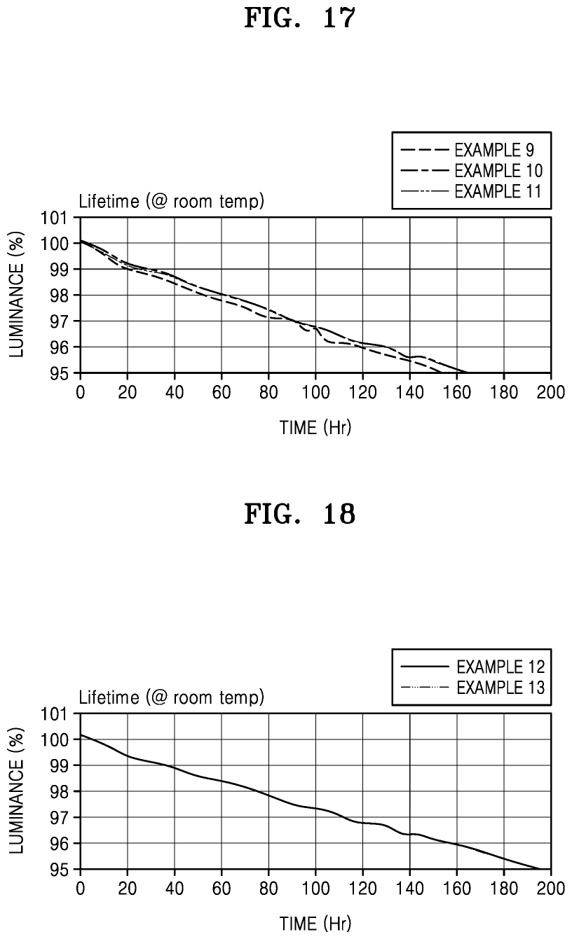

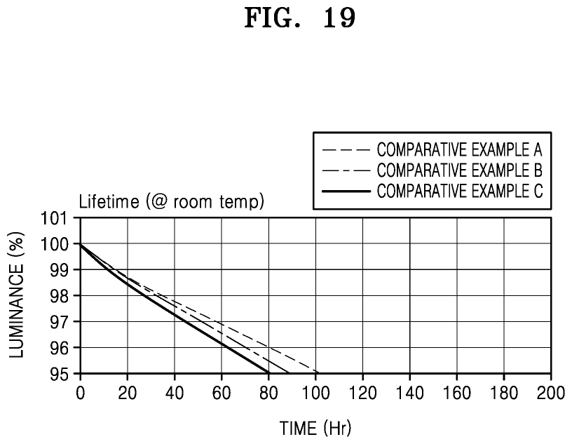

The color purity CIE(x,y), luminescence efficiency (cd/A), color conversion efficiency (cd/A/y), maximum emission wavelength (nm), lifespan (T₉₅), and driving voltage (V) at 1,000 cd/m² of the organic light-emitting devices manufactured in Examples 1 to 13 and Comparative Examples A to C were measured using the Keithley MU 236 and the luminance meter PR650, and results are shown in Tables 8 and 9. The lifespan (T₉₅) in Table 9 indicates a time (hr) for the luminance to decline to 95% of its initial luminance. In Table 8, a weight (wt %) per 100 wt % of emission layer of each of the organometallic compound represented by Formula 1 and the fourth compound and an absolute value (ΔCS, Hz) of a difference between a chemical shift value of R₄₄ and a chemical shift value of R₄₁, as measured by proton nuclear magnetic resonance (NMR) spectroscopy, in the organometallic compound represented by Formula 1 were also shown. Electroluminescence spectra, graphs of luminance versus luminescence efficiency, and graphs of time versus luminance of Examples 1 to 13 and Comparative Examples A to C are understood by referring to FIGS. 5 to 19. Some graphs of FIGS. 5 to 19 are substantially the same, and thus may be indistinguishable as they overlap each other (for example, EL spectra of Examples 9 and 11 of FIG. 7).

TABLE 8

| | | | | | | Weight |
|---|---|---|---|---|---|---|
| | | | | | | ratio of |
| | Organometallic | | | | | Second |
| | compound | | | | | compound |
| | represented by | Second | Third | Fourth | ΔCS | to Third |
| No. | Formula 1 | compound | compound | compound | (Hz) | compound |
| Example 1 | BD02 | ETH2 | HTH29 | — | 559 | 3.5:6.5 |
| | (13 wt %) | | | | | |
| Example 2 | BD04 | ETH2 | HTH29 | — | 553 | 3.5:6.5 |
| | (13 wt %) | | | | | |
| Example 3 | BD23 | ETH2 | HTH29 | — | 565 | 3.5:6.5 |
| | (13 wt %) | | | | | |
| Example 4 | BD58 | ETH2 | HTH29 | — | 565 | 3.5:6.5 |
| | (13 wt %) | | | | | |
| Example 5 | BD327 | ETH2 | HTH29 | — | 570 | 3.5:6.5 |
| | (13 wt %) | | | | | |
| Example 6 | BD325 | ETH2 | HTH29 | — | 517 | 3.5:6.5 |
| | (13 wt %) | | | | | |
| Example 7 | BD323 | ETH2 | HTH29 | — | 584 | 3.5:6.5 |
| | (13 wt %) | | | | | |
| Example 8 | BD333 | ETH2 | HTH29 | — | 573 | 3.5:6.5 |
| | (13 wt %) | | | | | |
| Example 9 | BD331 | ETH2 | HTH29 | — | 520 | 3.5:6.5 |
| | (13 wt %) | | | | | |
| Example 10 | BD329 | ETH2 | HTH29 | — | 590 | 3.5:6.5 |
| | (13 wt %) | | | | | |
| Example 11 | BD329 | ETH18 | HTH29 | — | 590 | 4:6 |
| | (13 wt %) | | | | | |
| Example 12 | BD329 | ETH18 | HTH29 | DFD7 | 590 | 4:6 |
| | (13 wt %) | | | (0.4 wt %) | | |
| Example 13 | BD329 | ETH18 | HTH29 | DFD29 | 590 | 4:6 |
| | (13 wt %) | | | (1.2 wt %) | | |
| Comparative | A | ETH2 | HTH29 | — | 460 | 3.5:6.5 |
| Example A | (13 wt %) | | | | | |
| Comparative | B | ETH2 | HTH29 | — | 452 | 3.5:6.5 |
| Example B | (13 wt %) | | | | | |
| Comparative | C | ETH2 | HTH29 | — | 474 | 3.5:6.5 |
| Example C | (13 wt %) | | | | | |

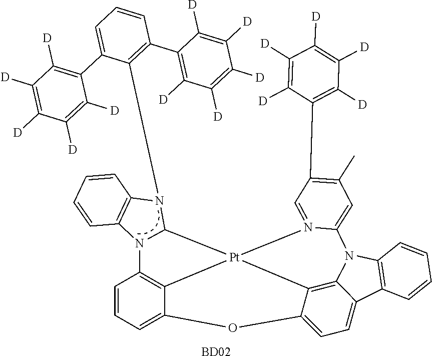

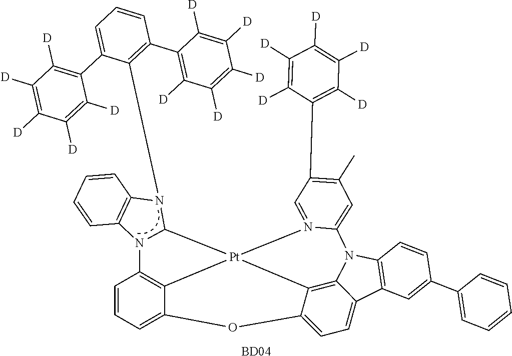

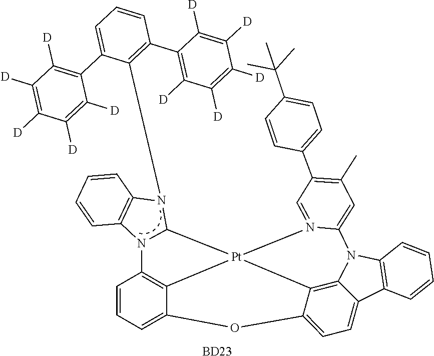

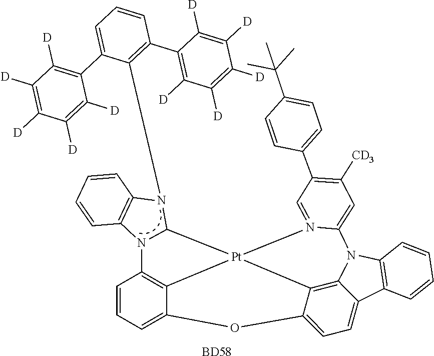

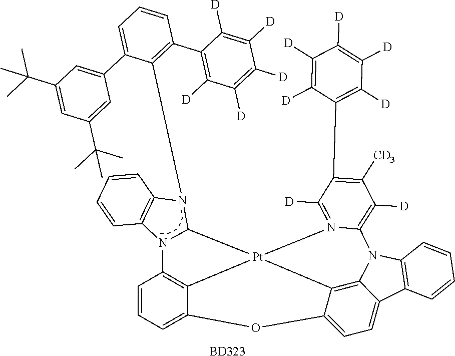

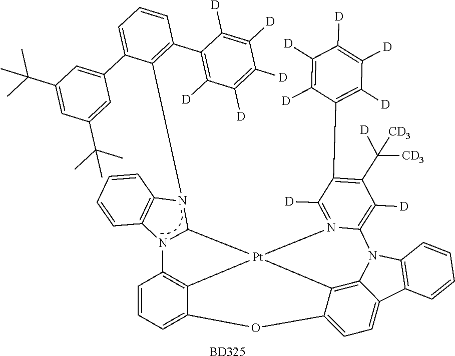

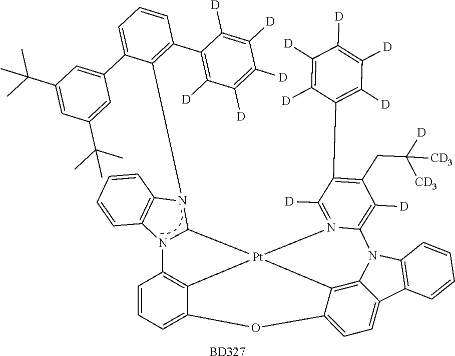

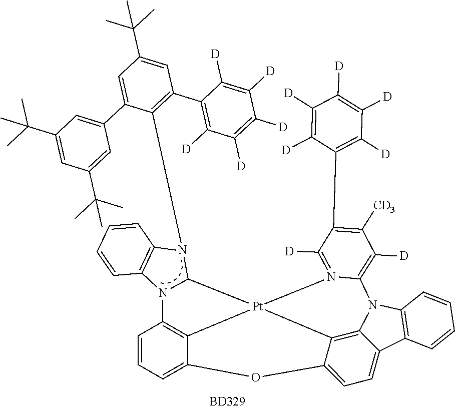

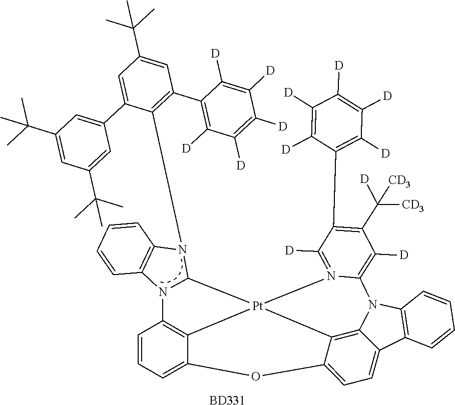

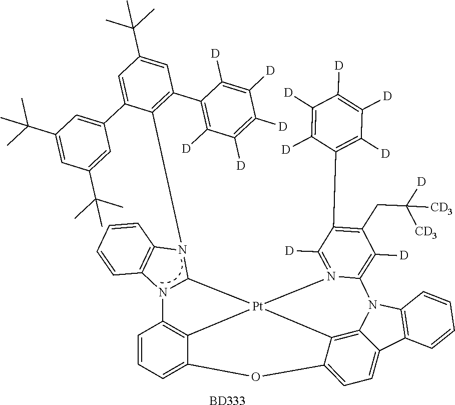

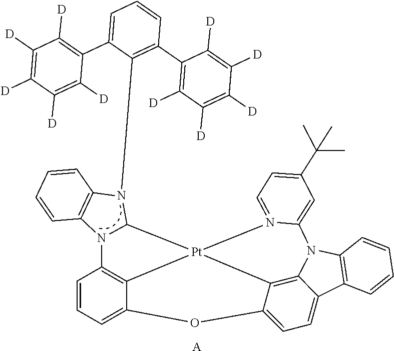

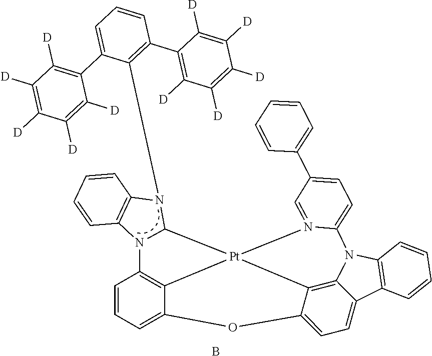

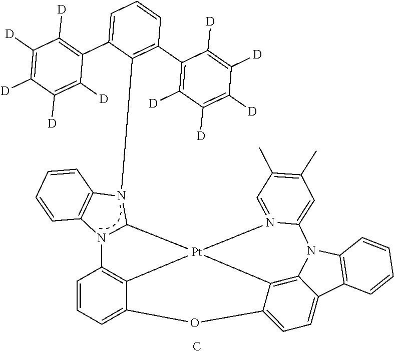

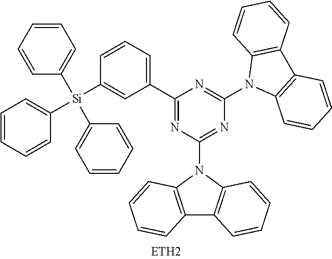 [SMILES: c1ccc([Si](c2ccccc2)(c2ccccc2)c2cccc(-c3nc(-n4c5ccccc5c5ccccc54)nc(-n4c5ccccc5c5ccccc54)n3)c2)cc1]

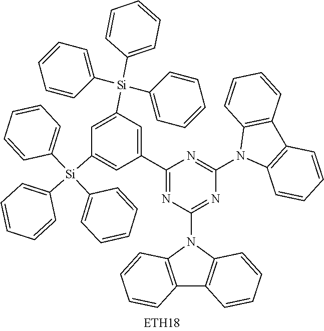 [SMILES: c1ccc([Si](c2ccccc2)(c2ccccc2)c2cc(-c3nc(-n4c5ccccc5c5ccccc54)nc(-n4c5ccccc5c5ccccc54)n3)cc([Si](c3ccccc3)(c3ccccc3)c3ccccc3)c2)cc1]

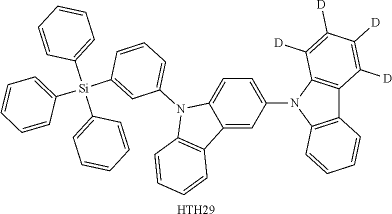

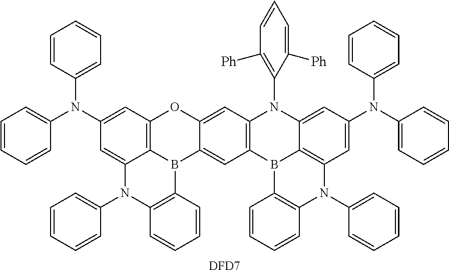

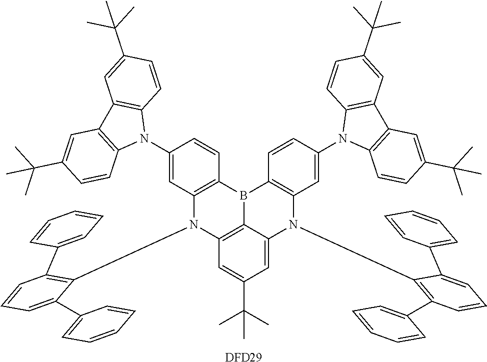

TABLE 9

| | | | | | Color | Maximum | |
|---|---|---|---|---|---|---|---|
| | | Driving | | Luminiscence | conversion | emission | |
| | ΔCS | voltage | CIE | Efficiency | efficiency | wavelength | Lifespan |
| No. | (Hz) | (V) | (x, y) | (cd/A) | (cd/A/y) | (nm) | (T₉₅, hr) |
| Example 1 | 559 | 4.4 | 0.137, | 22.7 | 126.0 | 462 | 103.8 |
| | | | 0.180 | | | | |
| Example 2 | 553 | 4.3 | 0.133, | 23.0 | 137.6 | 464 | 119.0 |
| | | | 0.167 | | | | |
| Example 3 | 565 | 4.1 | 0.136, | 22.6 | 129.8 | 462 | 121.0 |
| | | | 0.174 | | | | |
| Example 4 | 565 | 4.0 | 0.136, | 22.8 | 145.9 | 461 | 131.0 |
| | | | 0.156 | | | | |
| Example 5 | 570 | 4.0 | 0.137, | 21.8 | 142.0 | 461 | 145.0 |
| | | | 0.154 | | | | |
| Example 6 | 517 | 4.1 | 0.133, | 23.1 | 156.1 | 461 | 149.0 |
| | | | 0.148 | | | | |
| Example 7 | 584 | 4.1 | 0.134, | 23.3 | 142.2 | 462 | 154.8 |
| | | | 0.164 | | | | |
| Example 8 | 573 | 4.0 | 0.137, | 22.2 | 141.0 | 461 | 163.0 |
| | | | 0.157 | | | | |
| Example 9 | 520 | 4.1 | 0.132, | 22.1 | 142.9 | 461 | 152.0 |
| | | | 0.154 | | | | |
| Example 10 | 590 | 4.1 | 0.134, | 23.2 | 141.8 | 462 | 163.0 |
| | | | 0.164 | | | | |
| Example 11 | 590 | 4.1 | 0.133, | 22.8 | 154.7 | 461 | 164.4 |
| | | | 0.147 | | | | |
| Example 12 | 590 | 4.1 | 0.136, | 23.8 | 171.1 | 461 | 192.4 |
| | | | 0.119 | | | | |
| Example 13 | 590 | 4.1 | 0.132, | 25.2 | 177.9 | 464 | 195.0 |
| | | | 0.121 | | | | |
| Comparative | 460 | 4.2 | 0.137, | 23.4 | 114.8 | 463 | 99.4 |
| Example A | | | 0.204 | | | | |
| Comparative | 452 | 4.8 | 0.141, | 15.4 | 72.4 | 463 | 87.4 |
| Example B | | | 0.213 | | | | |
| Comparative | 474 | 4.5 | 0.136, | 22.3 | 112.3 | 463 | 81.4 |
| Example C | | | 0.199 | | | | |

From Table 9, it can be seen that the organic light-emitting device of Example 1 to 13 emitted deep blue light and had excellent driving voltage, color purity, luminescence efficiency, color conversion efficiency, and lifespan characteristics, as compared to the organic light-emitting devices of Comparative Examples A to C.

The organometallic compound has excellent electrical characteristics, and thus, a light-emitting device including the organometallic compound may have high luminescence efficiency and long lifespan.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the present disclosure as defined by the following claims, and equivalents thereof.

What is claimed is:

1. A composition comprising: i) an organometallic compound represented by Formula 1 below; and
a second compound comprising at least one π electron-deficient nitrogen-containing C₁-C₆₀ cyclic group, a third compound comprising a group represented by Formula 3 below, a fourth compound capable of emitting delayed fluorescence, or any combination thereof,
wherein the organometallic compound, the second compound, the third compound, and the fourth compound are different from each other: 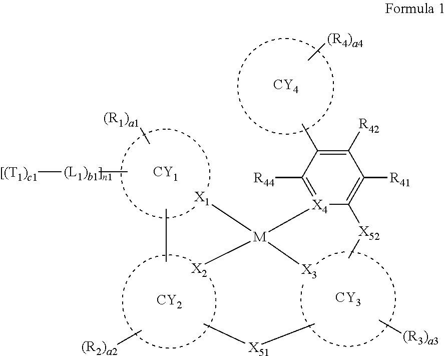
wherein, in Formula 1,
M is platinum (Pt), palladium (Pd), gold (Au), nickel (Ni), silver (Ag), or copper (Cu),
X₁ to X4 are each independently C or N,
i) a bond between X₁ and M is a coordinate bond, and ii) one selected from a bond between X₂ and M, a bond between X₃ and M, and a bond between X₄ and M is a coordinate bond, and the other two are each a covalent bond,
rings CY₁, CY₂, CY₃, and CY₄ are each independently a C₃-C₆₀ carbocyclic group or a C₁-C₆₀ heterocyclic group,
X51 is a single bond, *—N(R₅₁ₐ)—*′, *—B(R₅₁ₐ)—*′, *—P(R₅₁ₐ)—*′, *—C(R₅₁ₐ)(R_{51b})—*′, *—Si(R₅₁ₐ)(R_{51b})—*′, *—Ge(R₅₁ₐ)(R_{51b})—*′, *—S—*′, *—Se—*′, *—O—*′, *—C(═O)—*′, *—S(═O)—*′, *—S(═O)₂—*′, *—C(R₅₁ₐ)═*′, *′═C(R₅₁ₐ)—*′, *—C(R₅₁ₐ)═C(R_{51b})—*′, *—C(═S)—*′, or *—C≡C—*′,
X₅₂ is a single bond, *—N(R₅₂ₐ)—*′, *—B(R₅₂ₐ)—*′, *—P(R₅₂ₐ)—*′, *—C(R₅₂ₐ)(R_{52b})—*′, *—Si(R₅₂ₐ)(R_{52b})—*′, *—Ge(R₅₂ₐ)(R_{52b})—*′, *—S—*′, *—Se—*′, *—O—*′, *—C(═O)—*′, *—S(═O)—*′, *—S(═O)₂—*′, *—C(R₅₂ₐ)═*′, *═C(R₅₂ₐ)—*′, *—C(R₅₂ₐ)═C(R_{52b})—*′, *—C(═S)—*′, or *—C≡C—*′,
L₁ is a C₃-C₆₀ carbocyclic group unsubstituted or substituted with at least one R₁₀ₐ or a C₁-C₆₀ heterocyclic group unsubstituted or substituted with at least one R₁₀ₐ,
b₁ is an integer selected from 1 to 5,
R₁ to R₄, R₄₂, R₅₁ₐ, R_{51b}, R₅₂ₐ, R_{52b}, and T₁ are each independently hydrogen, deuterium, —F, —CI, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ aryl alkyl group unsubstituted or substituted with at least one R₁₀ₐ, a C₂-C₆₀ heteroaryl alkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), wherein R₄₂ is neither hydrogen nor deuterium,
R₄₁ and R₄₄ are each independently hydrogen or deuterium,
a1, a2, a3, a4, c1, and n1 are each independently an integer selected from 0 to 20,
two or more of R₁(s) in the number of al are optionally bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,
two or more of R₂(s) in the number of a2 are optionally bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,
two or more of R₃(s) in the number of a3 are optionally bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,
two or more of R₄(s) in the number of a4 are optionally bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,
two or more of R₁ to R₄, R₅₁ₐ, R_{51b}, R₅₂ₐ, and R_{52b} are optionally bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,
R₁₀ₐ is:
deuterium (—D), —F, —CI, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —CI, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —CI, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—O(Q₃₁), —S(Q₃₁), —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ are each independently: hydrogen; deuterium; —F; —CI; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof: 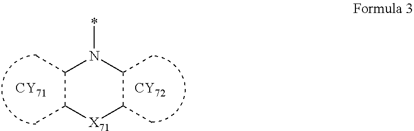
wherein, in Formula 3,
ring CY₇₁ and ring CY₇₂ are each independently a π electron-rich C₃-C₆₀ cyclic group or a pyridine group,
X₇₁ is a single bond or a linking group including O, S, N, B, C, Si, or any combination thereof, and
* indicates a binding site to a neighboring atom in Formula 3.

2. The composition of claim 1, comprising:
the organometallic compound represented by Formula 1; and
the second compound.

3. The composition of claim 1, wherein an absolute value of a difference between a phase transition temperature of the organometallic compound represented by Formula 1 under a pressure of 5.0×10⁻⁵ torr to 1.0×10⁻³ torr and a phase transition temperature of the second compound under a pressure of 5.0×10⁻⁵ torr to 1.0×10⁻³ torr is 10° C. or less.

4. A light-emitting device comprising: a first electrode;
a second electrode facing the first electrode;
an interlayer between the first electrode and the second electrode and comprising an emission layer; and
an organometallic compound represented by Formula 1 below: 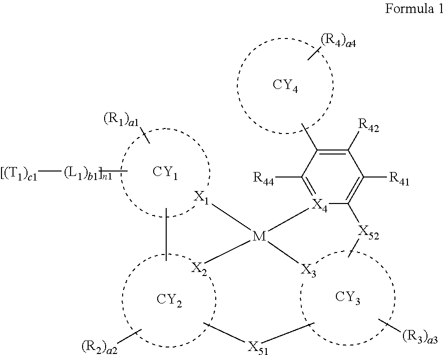
wherein, in Formula 1,
M is platinum (Pt), palladium (Pd), gold (Au), nickel (Ni), silver (Ag), or copper(Cu),
X₁ to X₄ are each independently C or N,
i) a bond between X₁ and M is a coordinate bond, and ii) one selected from a bond between X₂ and M, a bond between X₃ and M, and a bond between X₄ and M is a coordinate bond, and the other two are each a covalent bond,
rings CY₁, CY₂, CY₃, and CY₄ are each independently a C₃-C₆₀ carbocyclic group or a C₁-C₆₀ heterocyclic group,
X₅₁ is a single bond, *—N(R₅₁ₐ)—*′, *—B(R₅₁ₐ)—*′, *—P(R₅₁ₐ)—*′, *—C(R₅₁ₐ)(R_{51b})—*′, *—Si(R₅₁ₐ)(R_{51b})—*′, *—Ge(R₅₁ₐ)(R_{51b})—*′, *—S—*′, *—Se—*′, *—O—*′, *—C(═O)—*′, *—S(═O)—*′, *—S(═O)₂—*′, *—C(R₅₁ₐ)═*′, *—C(R₅₁ₐ)—*′, *—C(R₅₁ₐ)═C(R_{51b})—*′, *—C(═S)—*′, or *—C≡C—*′,
X₅₂ is a single bond, *—N(R₅₂ₐ)—*′, *—B(R₅₂ₐ)—*′, *—P(R₅₂ₐ)—*′, *—C(R₅₂ₐ)(R_{52b})—*′, *—Si(R₅₂ₐ)(R_{52b})—*′, *—Ge(R₅₂ₐ)(R_{52b})—*′, *—S—*′, *—Se—*′, *—O—*′, *—C(═O)—*′, *—S(═O)—*′, *—S(═O)₂—*′, *—C(R₅₂ₐ)═*′, *═C(R₅₂ₐ)—*′, *—C(R₅₂ₐ)═C(R_{52b})—*′, *—C(═S)—*′, or *—C≡C—*′,
L₁ is a C₃-C₆₀ carbocyclic group unsubstituted or substituted with at least one R₁₀ₐ or a C₁-C₆₀ heterocyclic group unsubstituted or substituted with at least one R₁₀ₐ,
b₁ is an integer selected from 1 to 5,
R₁ to R₄, R₄₂, R₅₁ₐ, R_{51b}, R₅₂ₐ, R_{52b}, and T₁ are each independently hydrogen, deuterium, —F, —CI, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ aryl alkyl group unsubstituted or substituted with at least one R₁₀ₐ, a C₂-C₆₀ heteroaryl alkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), wherein R₄₂ is neither hydrogen nor deuterium,
R₄₁ and R₄₄ are each independently hydrogen or deuterium,
a1, a2, a3, a4, c1, and n1 are each independently an integer selected from 0 to 20,
two or more of R₁(s) in the number of al are optionally bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,
two or more of R₂(s) in the number of a2 are optionally bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,
two or more of R₃(s) in the number of a3 are optionally bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,
two or more of R₄(s) in the number of a4 are optionally bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,
two or more of R₁ to R₄, R₅₁ₐ, R_{51b}, R₅₂ₐ, and R_{52b} are optionally bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,
R₁₀ₐ is:
deuterium (-D), —F, —CI, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —CI, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —CI, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(₀₂₁)(₀₂₂), —B(Q₂₁)(Q₂₂), —C(═O)(Q₂₁), —S(═O)₂(Q₂₁), —P(═O)(Q₂₁)(Q₂₂), or any combination thereof; or
—O(Q₃₁), —S(Q₃₁), —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), or —P(═O)(Q₃₁)(Q₃₂), and Q₁ to Q₃, Q₁₁ to Q₁₃, Q₂₁ to Q₂₃, and Q₃₁ to Q₃₃ are each independently:
hydrogen; deuterium; —F; —CI; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

5. The light-emitting device of claim 4, further comprising a second compound including at least one π electron-deficient nitrogen-containing C₁-C₆₀ cyclic group, a third compound including a group represented by Formula ₃, a fourth compound capable of emitting delayed fluorescence, or any combination thereof,
wherein the organometallic compound, the second compound, the third compound, and the fourth compound are different from each other: 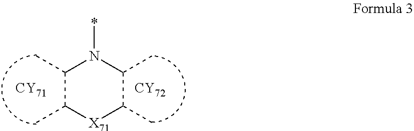
wherein, in Formula 3,
ring CY₇₁ and ring CY₇₂ are each independently a π electron-rich C₃-C₆₀ cyclic group or a pyridine group,
X₇₁ is a single bond or a linking group including O, S, N, B, C, Si, or any combination thereof, and
* indicates a binding site to a neighboring atom in Formula 3.

6. The light-emitting device of claim 5, wherein the second compound comprises a pyridine group, a pyrimidine group, a pyrazine group, a pyridazine group, a triazine group, or any combination thereof.

7. The light-emitting device of claim 5, wherein the fourth compound is a compound comprising at least one cyclic group comprising each of boron (B) and nitrogen (N) as a ring-forming atom.

8. The light-emitting device of claim 5, wherein the emission layer comprises: i) the organometallic compound; and ii) the second compound, the third compound, the fourth compound, or any combination thereof, and
the emission layer emits blue light.

9. The light-emitting device of claim 8, wherein the emission layer emits blue light, and
a maximum emission wavelength of the blue light is in a range of 430 nm to 475 nm, and an emission full width at half maximum (FWHM) of the blue light is less than or equal to 40 nm.

10. An electronic apparatus comprising the light-emitting device of claim 4.

11. The electronic apparatus of claim 10, further comprising a thin-film transistor,
wherein the thin-film transistor comprises a source electrode and a drain electrode, and
the first electrode of the light-emitting device is electrically connected to at least one selected from the source electrode and the drain electrode of the thin-film transistor.

12. The electronic apparatus of claim 11, further comprising a color filter, a color conversion layer, a touch screen layer, a polarizing layer, or any combination thereof.

13. A consumer product comprising the light-emitting device of claim 4.

14. The consumer product of claim 13, wherein the consumer product is one selected from a flat panel display, a curved display, a computer monitor, a medical monitor, a television, a billboard, an indoor or outdoor light and/or light for signal, a head-up display, a fully or partially transparent display, a flexible display, a rollable display, a foldable display, a stretchable display, a laser printer, a telephone, a portable phone, a tablet personal computer, a phablet, a personal digital assistant (PDA), a wearable device, a laptop computer, a digital camera, a camcorder, a viewfinder, a micro display, a three-dimensional (3D) display, a virtual reality or augmented reality display, a vehicle, a video wall with multiple displays tiled together, a theater or stadium screen, a phototherapy device, and a signboard.

15. An organometallic compound represented by Formula 1 below: 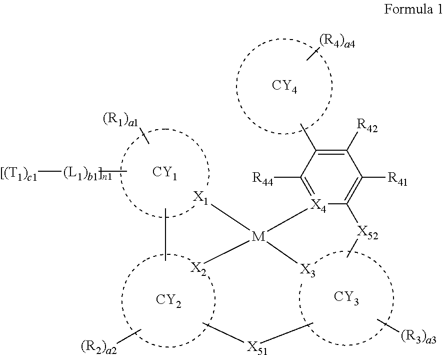
wherein, in Formula 1,
M is platinum (Pt), palladium (Pd), gold (Au), nickel (Ni), silver (Ag), or copper (Cu),
X₁ to X₄ are each independently C or N,
i) a bond between X₁ and M is a coordinate bond, and ii) one selected from a bond between X₂ and M, a bond between X₃ and M, and a bond between X₄ and M is a coordinate bond, and the other two are each a covalent bond,
rings CY₁, CY₂, CY₃, and CY₄ are each independently a C₃-C₆₀ carbocyclic group or a C₁-C₆₀ heterocyclic group,
X₅₁ is a single bond, *—N(R₅₁ₐ)—*′, *—B(R₅₁ₐ)—*′, *—P(R₅₁ₐ)—*′, *—C(R₅₁ₐ)(R_{51b})—*′, *—Si(R₅₁ₐ)(R_{51b})—*′, *—Ge(R₅₁ₐ)(R_{51b})—*′, *—S—*′, *—Se—*′, *—O—*′, *—C(═O)—*′, *—S(═O)—*′, *—S(═O)₂—*′, *—C(R₅₁ₐ)═*′, *′2 C(R₅₁ₐ)—*′, *—C(R₅₁ₐ)═C(R_{51b})—*′, *—C(═S)—*′, or *—C≡C—*′,
X₅₂ is a single bond, *—N(R₅₂ₐ)—*′, *—B(R₅₂ₐ)—*′, *—P(R₅₂ₐ)—*′, *—C(R₅₂ₐ)(R_{52b})—*′, *—Si(R₅₂ₐ)(R_{52b})—*′, *—Ge(R₅₂ₐ)(R_{52b})—*′, *—S—*′, *—Se—*′, *—O—*′, *—C(═O)—*′, *—S(═O)—*′, *—S(═O)₂—*′, *—C(R₅₂ₐ)═*′, *═C(R₅₂ₐ)—*′, *—C(R₅₂ₐ)═C(R_{52b})—*′, *—C(═S)—*′, or *—C≡C—*′,
L₁ is a C₃-C₆₀ carbocyclic group unsubstituted or substituted with at least one R₁₀ₐ or a C₁-C₆₀ heterocyclic group unsubstituted or substituted with at least one R₁₀ₐ,
b1 is an integer selected from 1 to 5,
R₁ to R₄, R₄₂, R₅₁ₐ, R_{51b}, R₅₂ₐ, R_{52b}, and T₁ are each independently hydrogen, deuterium, —F, —CI, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, a C₇-C₆₀ aryl alkyl group unsubstituted or substituted with at least one R₁₀ₐ, a C₂-C₆₀ heteroaryl alkyl group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), wherein R₄₂ is neither hydrogen nor deuterium,
R₄₁ and R₄₄ are each independently hydrogen or deuterium,
a1, a2, a3, a4, c1, and n1 are each independently an integer selected from 0 to 20,
two or more of R₁(s) in the number of al are optionally bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,
two or more of R₂(s) in the number of a2 are optionally bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,
two or more of R₃(s) in the number of a3 are optionally bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,
two or more of R₄(s) in the number of a4 are optionally bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,
two or more of R₁ to R₄, R₅₁ₐ, R_{51b}, R₅₂ₐ, and R_{52b} are optionally bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,
R₁₀ₐ is:
deuterium (—D), —F, —CI, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —CI, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, or a C₂-C₆₀ heteroaryl alkyl group, each unsubstituted or substituted with deuterium, —F, —CI, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ aryl alkyl group, a C₂-C₆₀ heteroaryl alkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—O(Q₃₁), —S(Q₃₁), —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ are each independently: hydrogen; deuterium; —F; —CI; —Br; —I; a hydroxyl group; a cyano group; a nitro group; or a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

16. The organometallic compound of claim 15, wherein ring CYi is i) an X₁-containing 5-membered ring, ii) an X₁-containing 5-membered ring in which at least one 6-membered ring is condensed, or iii) an X₁-containing 6-membered ring,
the X₁-containing 5-membered ring is a pyrrole group, a pyrazole group, an imidazole group, a triazole group, an oxazole group, an iso-oxazole group, a thiazole group, an isothiazole group, an oxadiazole group, or a thiadiazole group, and
the X₁-containing 6-membered ring and the 6-membered ring which is optionally condensed to the X₁-containing 5-membered ring are each independently a benzene group, a pyridine group, or a pyrimidine group.

17. The organometallic compound of claim 15, wherein ring CY₁ is an imidazole group, a triazole group, a benzimidazole group, or an imidazopyridine group.

18. The organometallic compound of claim 15, wherein rings CY₂, CY₃, and CY₄ are each independently a benzene group, a pyridine group, a pyrimidine group, a naphthalene group, a dibenzofuran group, a dibenzothiophene group, a carbazole group, a fluorene group, a dibenzosilole group, a naphthobenzofuran group, a naphthobenzothiophene group, a benzocarbazole group, a benzofluorene group, a naphthobenzosilole group, a dinaphthofuran group, a dinaphthothiophene group, a dibenzocarbazole group, a dibenzofluorene group, a dinaphthosilole group, an azadibenzofuran group, an azadibenzothiophene group, an azacarbazole group, an azafluorene group, an azadibenzosilole group, an azanaphthobenzofuran group, an azanaphthobenzothiophene group, an azabenzocarbazole group, an azabenzofluorene group, an azanaphthobenzosilole group, an azadinaphthofuran group, an azadinaphthothiophene group, an azadibenzocarbazole group, an azadibenzofluorene group, or an azadinaphthosilole group.

19. The organometallic compound of claim 15, wherein
i) X₅₂ is a single bond, and a group represented by 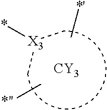
in Formula 1 is a group represented by Formula CY3A or CY3B below,
ii) X₅₂ is not a single bond, and a group represented by 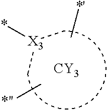
in Formula 1 is a group represented by Formula CY3C below, or
iii) X₅₂ is *—N(R₅₂ₐ)—*′, and R₅₂ₐ and R₃ are bonded to form a C₃-C₆₀ carbocyclic group unsubstituted or substituted with at least one R₁₀ₐ or a C₁-C₆₀ heterocyclic group unsubstituted or substituted with at least one R₁₀ₐ: 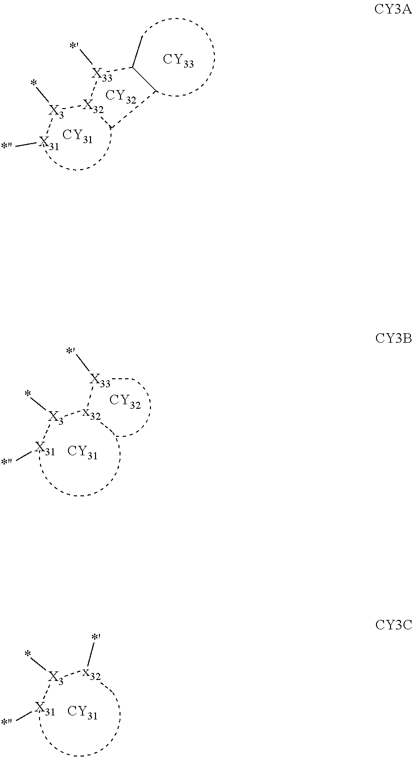
wherein, in Formulae CY3A to CY3C,
X₃ and X₃₁ to X₃₃ are each independently C or N,
rings CY₃₁, CY₃₂, and CY₃₃ are respectively the same as described in connection with ring CY₃ in claim 15,
a bond between X₃₁ and X₃, a bond between X₃ and X₃₂, and a bond between X₃₂ and X₃₃ are each a chemical bond,
*′ indicates a binding site to X₅₁,
*indicates a binding site to M in Formula 1, and
*′ indicates a binding site to X₅₂.

20. The organometallic compound of claim 15, wherein R₁ to R₄, R₅₁ₐ, R_{51b}, R₅₂ₐ, R_{52b}, and T₁ are each independently:
hydrogen, deuterium, —F, or a cyano group;
a C₁-C₂₀ alkyl group or a C₃-C₁₀ cycloalkyl group, each unsubstituted or substituted with deuterium, —F, a cyano group, or any combination thereof; or
a phenyl group, a naphthyl group, a dibenzofuranyl group, or a dibenzothiophenyl group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl) phenyl group, or any combination thereof.

21. The organometallic compound of claim 15, wherein R₄₂ is a C₁-C₂₀ alkyl group unsubstituted or substituted with deuterium, —F, a cyano group, or any combination thereof.

22. The organometallic compound of claim 15, wherein R₄₂ is a group represented by *—C(R₄₂ₐ)(R_{42b})(R_{42c}), and
R₄₂ₐ, R_{42b}, and R_{42c}are each independently a C₁-C₂₀ alkyl group unsubstituted or substituted with deuterium, —F, a cyano group, or any combination thereof, and at least one selected from R₄₂ₐ, R_{42b}, and R_{42c}is hydrogen or deuterium.

23. The organometallic compound of claim 15, wherein a group represented by *—(L₁)_{b1}—(T₁)_{c1} in Formula 1 is a group represented by Formula CY1A below: 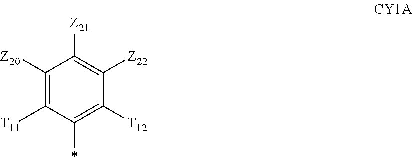
wherein, in Formula CY1A,
Z₂₀ to Z₂₂ are each independently hydrogen, or are respectively the same as described in connection with R₁₀ₐ in claim 15,
T₁₁ and T₁₂ are respectively the same as described in connection with T₁ in claim 15, and
*indicates a binding site to ring CY₁.

24. The organometallic compound of claim 23, wherein T₁₁ and T₁₂ are each independently a phenyl group, a naphthyl group, a dibenzofuranyl group, or a dibenzothiophenyl group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, or any combination thereof.

25. The organometallic compound of claim 15, wherein the organometallic compound is represented by Formula 1-1 or 1-2 below: 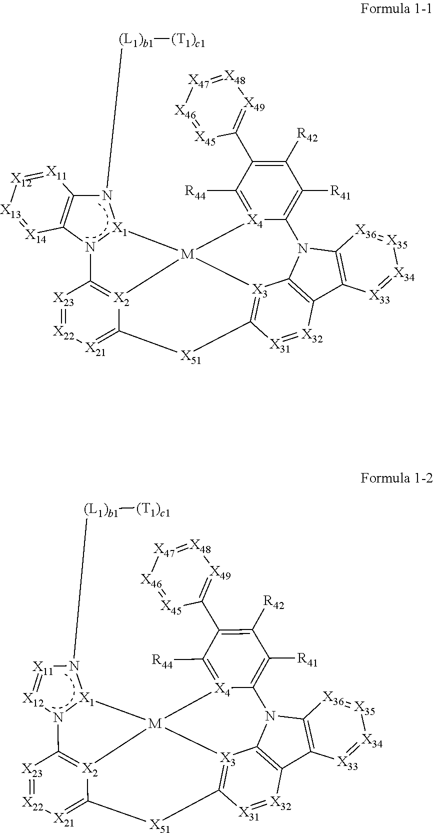
wherein, in Formulae 1-1 and 1-2,
M, X₁ to X₄, X₅₁, L₁, b1, T₁, c1, R₄₁, R₄₂, and R₄₄ are respectively the same as described in claim 15,
X₁₁ is C(R₁₁) or N, X₁₂ is C(R₁₂) or N, X₁₃ is C(R₁₃) or N, and X₁₄ is C(R₁₄) or N,
R₁₁ to R₁₄ are respectively the same as described in connection with R₁ in claim 15, and two or more of R₁₁ to R₁₄ are optionally bonded together to form a C₃-C₆₀ carbocyclic group unsubstituted or substituted with at least one R₁₀ₐ or a C₁-C₆₀ heterocyclic group unsubstituted or substituted with at least one R₁₀ₐ,
X₂₁ is C(R₂₁) or N, X₂₂ is C(R₂₂) or N, and X₂₃ is C(R₂₃) or N,
R₂₁ to R₂₃ are respectively the same as described in connection with R₂ in claim 15, and two or more of R₂₁ to R₂₃ are optionally bonded together to form a C₃-C₆₀ carbocyclic group unsubstituted or substituted with at least one R₁₀ₐ or a C₁-C₆₀ heterocyclic group unsubstituted or substituted with at least one R₁₀ₐ,
X₃₁ is C(R₃₁) or N, X₃₂ is C(R₃₂) or N, X₃₃ is C(R₃₃) or N, X₃₄ is C(R₃₄) or N, X₃₅ is C(R₃₅) or N, and X₃₆ is C(R₃₆) or N,
R₃₁ to R₃₆ are respectively the same as described in connection with R₃ in claim 15, and two or more of R₃₁ to R₃₆ are optionally bonded together to form a C₃-C₆₀ carbocyclic group unsubstituted or substituted with at least one R₁₀ₐ or a C₁-C₆₀ heterocyclic group unsubstituted or substituted with at least one R₁₀ₐ,
X₄₅ is C(R₄₅) or N, X₄₆ is C(R₄₆) or N, X₄₇ iS C(R₄₇) or N, X₄₈ iS C(R₄₈) or N, and X₄₉ is C(R₄₉) or N, and
R₄₅ to R₄₉ are respectively the same as described in connection with R₄ in claim 15, and two or more of R₄₅ to R₄₉ are optionally bonded together to form a C₃-C₆₀ carbocyclic group unsubstituted or substituted with at least one R₁₀ₐ or a C₁-C₆₀ heterocyclic group unsubstituted or substituted with at least one R₁₀ₐ.

26. The organometallic compound of claim 15, wherein an absolute value of a difference between a chemical shift value of R₄₄ and a chemical shift value of R₄₁ of the organometallic compound, as measured by proton nuclear magnetic resonance (NMR) spectroscopy, is in a range of 480 Hz to 600 Hz.

27. The organometallic compound of claim 15, wherein TS_{M(migration)} energy, which is an energy barrier for ligand migration of the organometallic compound, is greater than or equal to 28 kcal/mol, and the TS_{M(migration)} energy is evaluated based on a lowest excitation triplet (T₁) energy of the organometallic compound.

28. An organometallic compound comprising: platinum (Pt); and
a tetradentate ligand,
wherein the tetradentate ligand comprises:
a pyridine group; and
a carbazole group or an azacarbazole group,
N in the pyridine group is bonded to the platinum,
N in the carbazole group or the azacarbazole group is bonded to a carbon in the 2-position of the pyridine group,
a carbon in the 3-position and a carbon in the 6-position of the pyridine group are each bonded to hydrogen or deuterium,
a substituent bonded to a carbon in the 4-position of the pyridine group is neither hydrogen nor deuterium,
a substituent bonded to a carbon in the 5-position of the pyridine group is a phenyl group, a naphthyl group, a dibenzofuranyl group, or a dibenzothiophenyl group, each unsubstituted or substituted with deuterium, —F, a cyano group, a C₁-C₂₀ alkyl group, a deuterated C₁-C₂₀ alkyl group, a fluorinated C₁-C₂₀ alkyl group, a phenyl group, a deuterated phenyl group, a fluorinated phenyl group, a (C₁-C₂₀ alkyl)phenyl group, or any combination thereof, and
an absolute value (ΔCS) of a difference between a chemical shift value of hydrogen or deuterium bonded to the carbon in the 6-position of the pyridine group and a chemical shift value of hydrogen or deuterium bonded to the carbon of the 3-position of the pyridine group of the organometallic compound, as measured by proton nuclear magnetic resonance (NMR) spectroscopy, is in a range of 480 Hz to 600 Hz.

29. The organometallic compound of claim 28, wherein the tetradentate ligand further comprises a carbene-containing cyclic group having 3 to 60 carbon 5 atoms, and C of carbene in the carbene-containing cyclic group having 3 to 60 carbon atoms is bonded to the platinum.
